(19) United States
(12) Patent Application Publication
(10) Pub. No.: US 2025/0098536 A1
(43) Pub. Date: Mar. 20, 2025

(54) LIGHT-EMITTING ELEMENT, FUSED POLYCYCLIC COMPOUND FOR THE LIGHT-EMITTING ELEMENT, AND DISPLAY DEVICE INCLUDING THE LIGHT-EMITTING ELEMENT

(71) Applicant: Samsung Display Co., Ltd., Yongin-si (KR)

(72) Inventors: MUN-KI SIM, Yongin-si (KR); SUN YOUNG PAK, Yongin-si (KR); TAEIL KIM, Yongin-si (KR); JUNHA PARK, Yongin-si (KR); HYUN SHIN, Yongin-si (KR); Chihyun RYOO, Yongin-si (KR); MINJUNG JUNG, Yongin-si (KR); Giwoong HAN, Yongin-si (KR)

(73) Assignee: Samsung Display Co., Ltd., Yongin-si (KR)

(21) Appl. No.: 18/658,026

(22) Filed: May 8, 2024

(30) Foreign Application Priority Data
Aug. 30, 2023 (KR) 10-2023-0114461

(51) Int. Cl. H10K 85/60; C07F 5/02; C09K 11/06; H10K 50/11

(52) U.S. Cl. CPC H10K 85/658; C07F 5/027; C09K 11/06; C07B 2200/05; C09K 2211/1018; H10K 50/11

(57) ABSTRACT

Embodiments provide a fused polycyclic compound, a light-emitting element including the fused polycyclic compound, and a display device including the light-emitting element. The light-emitting element includes a first electrode, a second electrode disposed on the first electrode, and an emission layer disposed between the first electrode and the second electrode, wherein the emission layer includes the fused polycyclic compound. The fused polycyclic compound is represented by Formula 1, which is explained in the specification:

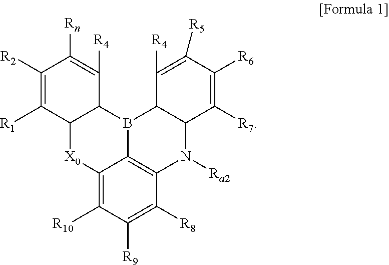

### CROSS-REFERENCE TO RELATED APPLICATION(S)

This application claims priority to and benefits of Korean Patent Application No. 10-2023-0114461 under 35 U.S.C. § 119, filed on Aug. 30, 2023 in the Korean Intellectual Property Office, the entire contents of which are incorporated herein by reference.

### BACKGROUND

### 1. Technical Field

The disclosure herein relates to a light-emitting element, a fused polycyclic compound used in the light-emitting element, and a display device including the light-emitting element.

### 2. Description of the Related Art

Active development continues for organic electroluminescence display devices and the like as image display devices. Organic electroluminescence display devices and the like are display devices including so-called self-luminous light-emitting elements that recombine, in an emission layer, holes and electrons respectively injected from a first electrode and a second electrode, thereby causing a light-emitting material of the emission layer, to emit light to implement displays.

For application of light-emitting elements to display devices, there is a demand for an organic electroluminescence display device having a long lifespan, and continuous development is required on materials for light-emitting elements that is capable of stably attaining such characteristics.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments include a light-emitting element having an improved lifespan and a display device including the same.

Embodiments also include a fused polycyclic compound that may be a material for a light-emitting element, improving the lifespan of the light-emitting element.

An embodiment provides a light-emitting element which may include a first electrode, a second electrode disposed on the first electrode, and an emission layer disposed between the first electrode and the second electrode, wherein the emission layer may include a first compound represented by Formula 1.

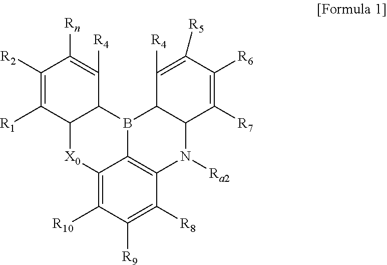

In Formula 1, Rₙ may be a group represented by Formula 2; X₀ may S or N(Rₐ₁); Rₐ₁ and Rₐ₂ may each independently be a group represented by Formula 3; and R₁ to R₁₀ may each independently be a hydrogen atom, a deuterium atom, a cyano group, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

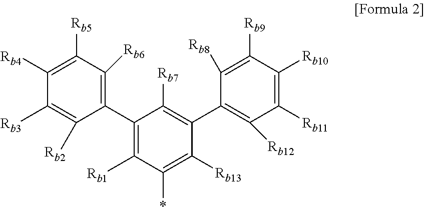

In Formula 2, R_{b1} to R_{b13} may each independently be a hydrogen atom, a deuterium atom, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

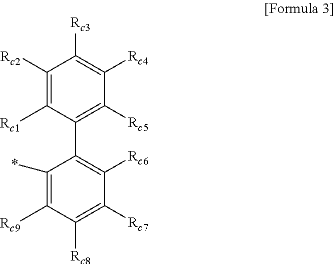

In Formula 3, R_{c1} to R_{c9} may each independently be a hydrogen atom, a deuterium atom, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In an embodiment, the emission layer may further include at least one of a second compound represented by Formula HT-1, a third compound represented by Formula ET-1, and a fourth compound represented by Formula D-1.

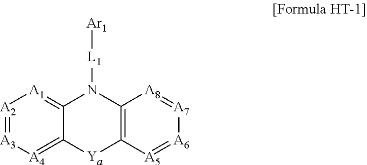

In Formula HT-1, A₁ to A₈ may each independently be N or C(R₅₁); L₁ may be a direct linkage, a substituted or unsubstituted arylene group having 6 to 30 ring-forming carbon atoms, or a substituted or unsubstituted heteroarylene group having 2 to 30 ring-forming carbon atoms; Yₐ may a direct linkage, C(R₅₂)(R₅₃), or Si(R₅₄)(R₅₅); Ar₁ may a substituted or unsubstituted aryl group having 6 to 30 ring-forming carbon atoms, or a substituted or unsubstituted heteroaryl group having 2 to 30 ring-forming carbon atoms; and R₅₁ to R₅₅ may each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring.

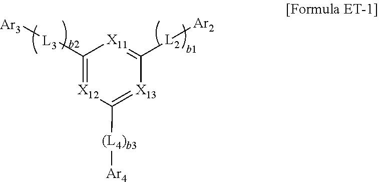

In Formula ET-1, at least one of X₁₁ to X₁₃ may each be N; the remainder of X₁₁ to X₁₃ may each independently be C(R₅₆); R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; b1 to b3 may each independently be an integer from 0 to 10; Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

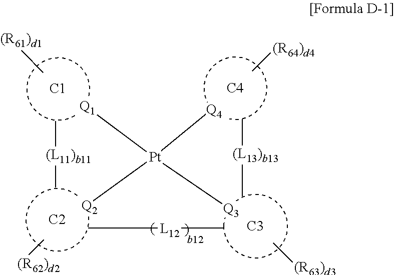

In Formula D-1, Q₁ to Q₄ may each independently be C or N; C1 to C4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted hetero ring having 2 to 30 ring-forming carbon atoms; L₁₁ to L₁₃ may each independently be a direct linkage,

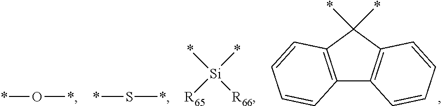

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; b11 to b13 may each independently be 0 or 1; R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms; and d1 to d4 may each independently be an integer from 0 to 4.

In an embodiment, the first compound may be represented by Formula 1-1 or Formula 1-2.

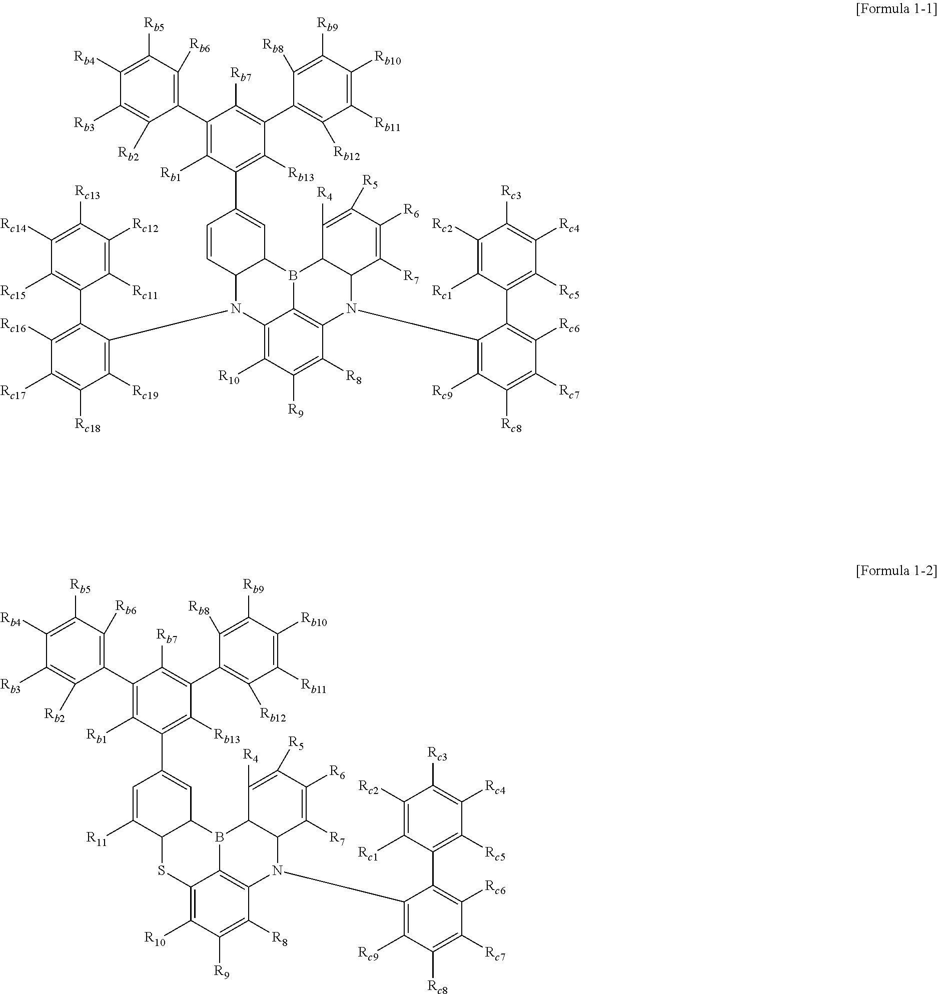

In Formula 1-1, R_{c11} to R_{c19} may each independently be a hydrogen atom, a deuterium atom, a substituted or unsubstituted oxy group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

In Formula 1-2, R₁₁ may be a hydrogen atom, a deuterium atom, a substituted or unsubstituted aryl group having 6 to 30 ring-forming carbon atoms, or a substituted or unsubstituted heteroaryl group having 2 to 30 ring-forming carbon atoms.

In Formula 1-1 and Formula 1-2, R₄ to R₁₀, R_{b1} to R_{b13}, and R_{c1} to R_{c9} may be the same as defined in Formula 1, Formula 2, and Formula 3.

In an embodiment, in Formula 1-2, R₁₁ may be a substituted or unsubstituted phenyl group, a substituted or unsubstituted dibenzofuran group, or a substituted or unsubstituted carbazole group.

In an embodiment, in Formula 1-2, R₁₁ may be a group represented by any one of Formula R11-1 to Formula R11-13, which are described below.

In an embodiment, the first compound may be represented by Formula 1-A or Formula 1-B.

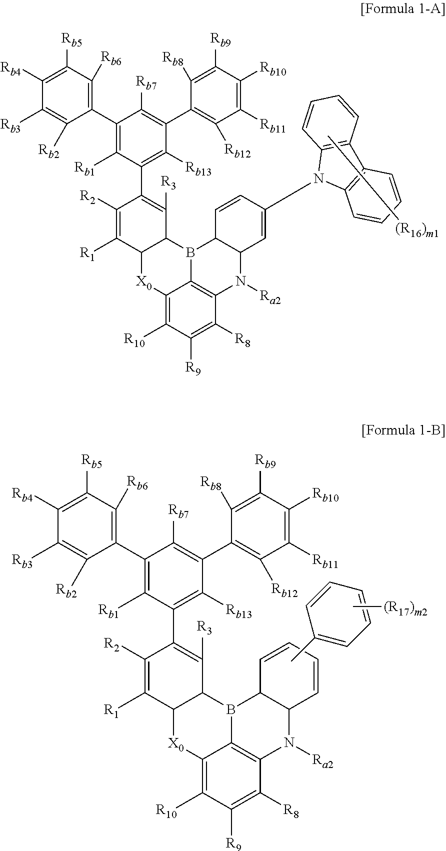

In Formula 1-A, m1 may be an integer from 0 to 8; and R₁₆ may be a hydrogen atom, a deuterium atom, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In Formula 1-B, m2 may be an integer of 0 to 5; and R₁₇ may be a hydrogen atom, a deuterium atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

In Formula 1-A and Formula 1-B, R₁ to R₃, R₈ to R₁₀, R_{b1} to R_{b13}, X₀, and Rₐ₂ may be the same as defined in Formula 1 and Formula 2.

In an embodiment, the group represented by Formula 2 may be a group represented by any one of Formula 2-1 to Formula 2-6, which are described below.

In an embodiment, the group represented by Formula 3 may be a group represented by any one of Formula 3-1 to Formula 3-18, which are described below.

In an embodiment, in Formula 1, R₉ may be a group represented by any one of Formula R9-1 to Formula R9-18, which are described below.

In an embodiment, wherein the first compound may include at least one compound selected from Compound Group 1, which is described below.

An embodiment provides a fused polycyclic compound which may be represented by Formula 1, which is described herein.

In an embodiment, the fused polycyclic compound represented by Formula 1 may be represented by Formula 1-1 or Formula 1-2, which are described herein.

In an embodiment, in Formula 1-2, R₁₁ may be a substituted or unsubstituted phenyl group, a substituted or unsubstituted dibenzofuran group, or a substituted or unsubstituted carbazole group.

In an embodiment, in Formula 1-2, R₁₁ may be a group represented by one of Formula R11-1 to Formula R11-13, which are described below.

In an embodiment, the fused polycyclic compound represented by Formula 1 may be represented by Formula 1-A or Formula 1-B, which are described below.

In an embodiment, the group represented by Formula 2 may be a group represented by one of Formula 2-1 to Formula 2-6, which are described below.

In an embodiment, the group represented by Formula 3 may be a group represented by one of Formula 3-1 to Formula 3-18, which are described below.

In an embodiment, in Formula 1, R₉ may be a group represented by one of Formula R9-1 to Formula R9-18, which are described below.

In an embodiment, the fused polycyclic compound represented by Formula 1 may be selected from Compound Group 1, which are described below.

An embodiment provides a display device which may include a circuit layer disposed on a base layer, and a display element layer disposed on the circuit layer and including a light-emitting element, wherein
the light-emitting element may include a first electrode, a second electrode disposed on the first electrode, and an emission layer disposed between the first electrode and the second electrode; and the emission layer may include a fused polycyclic compound represented by Formula 1, which is described herein.

In an embodiment, the light-emitting element may include a first light-emitting element that emits red light, a second light-emitting element that emits green light, and a third light-emitting element that emits blue light, and the third light-emitting element may include the fused polycyclic compound.

In an embodiment, the light-emitting element may emit blue light.

In an embodiment, the display device may further include a light control layer disposed on the display element layer and including quantum dots.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a portion taken along line I-I′ in FIG. 1;

FIG. 3 is a schematic cross-sectional view of a light-emitting element according to an embodiment;

FIG. 4 is a schematic cross-sectional view of a light-emitting element according to an embodiment;

FIG. 5 is a schematic cross-sectional view of a light-emitting element according to an embodiment;

FIG. 6 is a schematic cross-sectional view of a light-emitting element according to an embodiment;

FIG. 7 is a schematic cross-sectional view of a light-emitting element according to an embodiment;

FIG. 8A shows a state of a lowest unoccupied molecular orbital (LUMO) of Experimental Example Compound B-2;

FIG. 8B shows a state of a LUMO of Experimental Example Compound C-1;

FIG. 9 is a schematic cross-sectional view of a display device according to an embodiment;

FIG. 10 is a schematic cross-sectional view of a display device according to an embodiment;

FIG. 11 is a schematic cross-sectional view of a display device according to an embodiment;

FIG. 12 is a schematic cross-sectional view of a display device according to an embodiment; and

FIG. 13 is a schematic perspective view of an interior of a vehicle including a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/of” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring or a substituted or unsubstituted heterocycle. The hydrocarbon ring may be an aliphatic or an aromatic. The heterocycle may be aliphatic or an aromatic. The hydrocarbon ring and the heterocycle may be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of an cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group including at least one carbon-carbon double bond in the middle or at a terminus of an alkyl group having 2 or more carbon atoms. An alkenyl group may be linear or branched. The number of carbon atoms in an alkenyl group is not particularly limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group including at least one carbon-carbon triple bond in the middle or at a terminus of an alkyl group having 2 or more carbon atoms. An alkynyl group may be linear or branched. The number of carbon atoms in an alkynyl group is not particularly limited, but may be 2 to 30, 2 to 20, or 2 to 10. Examples of an alkynyl group may include an ethynyl group, a propynyl group, etc., but embodiments are not limited thereto.

In the specification, the hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be a monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are limited thereto.

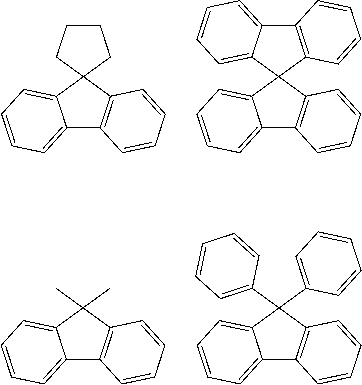

In the specification, a heterocyclic group may be any functional group or substituent derived from a ring including at least one of B, O, N, P, Si, S, and Se as a heteroatom. A heterocyclic group may be an aliphatic heterocyclic group or an aromatic heterocyclic group. An aromatic heterocyclic group may be a heteroaryl group. An aliphatic heterocycle and an aromatic heterocycle may each independently be monocyclic or polycyclic.

In the specification, a heterocyclic group may include at least one of B, O, N, P, Si, S, and Se as a heteroatom. If a heterocyclic group include two or more heteroatoms, the two or more heteroatoms may be the same as or different from each other. A heterocyclic group may be monocyclic heterocyclic or polycyclic heterocyclic. A heterocyclic group may be a heteroaryl group. The number of ring-forming carbon atoms in a heterocyclic group may be 2 to 30, 2 to 20, or 2 to 10.

In the specification, an aliphatic heterocyclic group may include at least one of B, O, N, P, Si, S, and Se as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may include at least one of B, O, N, P, Si, S, and Se as a heteroatom. If a heteroaryl group includes two or more heteroatoms, the two or more heteroatoms may be the same as or different from each other. A heteroaryl group may be monocyclic or polycyclic. The number of ring-forming carbon atoms in a heteroaryl group may be 2 to 30, 2 to 20, or 2 to 10. Examples of an heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. The description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, but may be 1 to 40, 1 to 30, or 1 to 20. For example, a carbonyl group may have one of the following structures, but embodiments are not limited thereto.

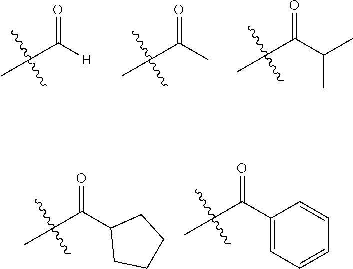

In the specification, the number of carbon atoms in a sulfinyl group or a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, or a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not particularly limited, but may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group herein may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not particularly limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group in an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols

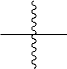

and [symbol] each represent a bond to a neighboring atom in a corresponding formula or moiety.

Hereinafter, embodiments will be described with reference to the accompanying drawings.

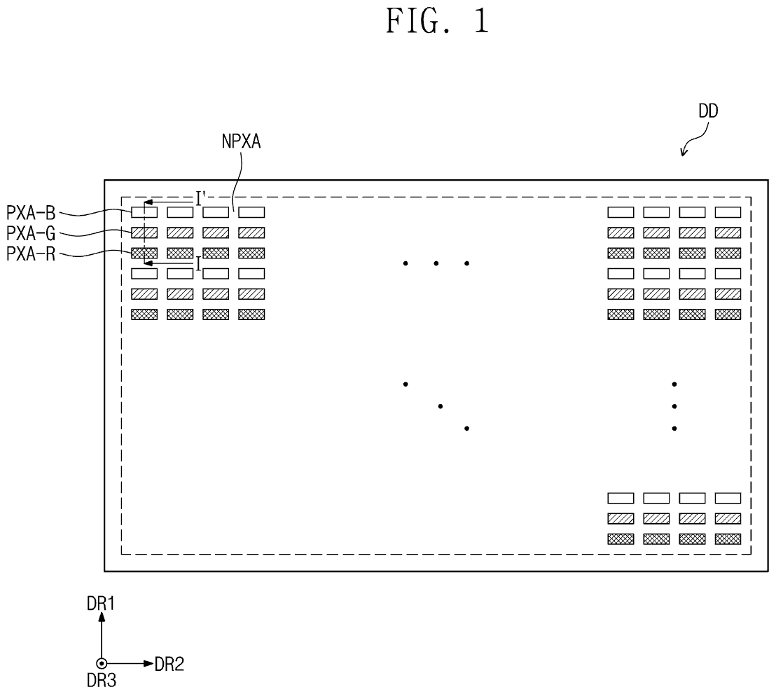

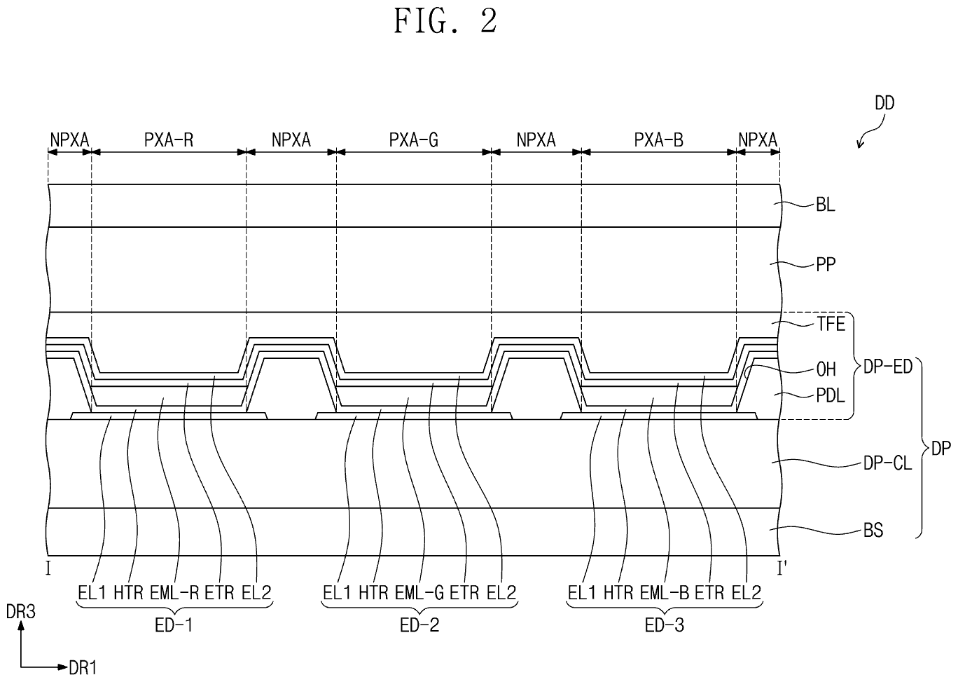

FIG. 1 is a schematic plan view of a display device DD according to an embodiment. FIG. 2 is a schematic cross-sectional view of a display device DD of a portion taken along line I-I′ in FIG. 1.

The display device DD may include a display panel DP and an optical layer PP disposed on the display panel DP. The display panel DP includes light-emitting elements ED-1, ED-2, and ED-3. The display device DD may include multiple of each of the light-emitting elements ED-1, ED-2, and ED-3. The optical layer PP may be disposed on the display panel DP to control light that is reflected light at the display panel DP from an external light. The optical layer PP may include, for example, a polarization layer or a color filter layer. Although not shown in the drawings, in embodiments, the optical layer PP may be omitted from the display device DD.

In an embodiment, a base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic-based resin, a silicone-based resin, and an epoxy-based resin.

In an embodiment, the display panel DP may include a circuit layer DP-CL provided on the base layer BS and the display element layer DP-ED. The display element layer DP-ED may include a pixel defining film PDL, light-emitting elements ED-1, ED-2, and ED-3 disposed between portions of the pixel defining film PDL, and an encapsulation layer TFE disposed on the light-emitting elements ED-1, ED-2, and ED-3.

In an embodiment, the base layer BS may provide abase surface on which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light-emitting elements ED-1, ED-2, and ED-3 of the display element layer DP-ED.

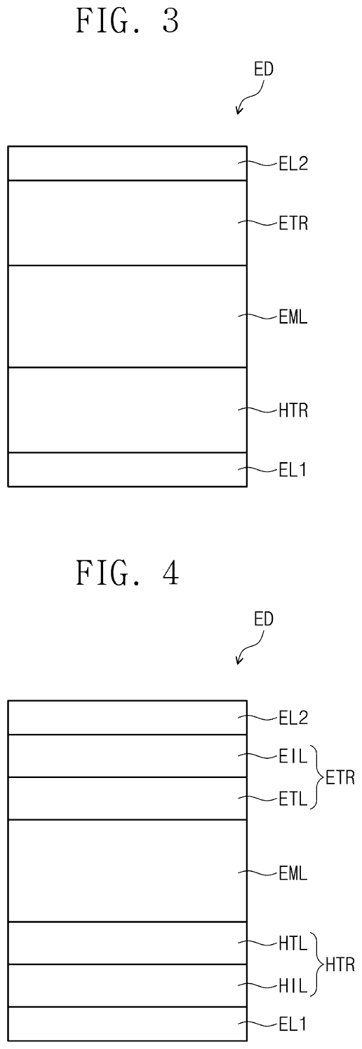

The light-emitting elements ED-1, ED-2, and ED-3 may each have a structure of a light-emitting elements according to an embodiment according to any of FIGS. 3 to 7, which will be described later. The light-emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 shows an embodiment in which the emission layers EML-R, EML-G, and EML-B of the light-emitting elements ED-1, ED-2, and ED-3 are disposed in openings OH defined in the pixel defining film PDL, and the hole transport region HTR, the electron transport region ETR, and the second electrode EL2 are each provided as a common layer for all of the light-emitting elements ED-1, ED-2, and ED-3. However, embodiments are not limited thereto. Although not shown in FIG. 2, in an embodiment, the hole transport region HTR and the electron transport region ETR may each be provided by being patterned in the openings OH defined in the pixel defining film PDL. In an embodiment, the hole transport region HTR, the emission layers EML-R, EML-G, and EML-B, and the electron transport region ETR of the light-emitting elements ED-1, ED-2, and ED-3 may each be provided by being patterned through an inkjet printing method.

The encapsulation layer TFE may cover the light-emitting elements ED-1, ED-2, and ED-3. The encapsulation layer TFE may seal the display element layer DP-ED. The encapsulation layer TFE may be a thin film encapsulation layer. The encapsulation layer TFE may be formed of a single layer or multiple layers. The encapsulation layer TFE may include at least one insulation layer. The encapsulation layer TFE may include at least one inorganic film (hereinafter, an encapsulation-inorganic film). In an embodiment, the encapsulation layer TFE may include at least one organic film (hereinafter, an encapsulation-organic film) and at least one encapsulation-inorganic film.

The encapsulation-inorganic film protects the display element layer DP-ED from moisture and/or oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, or the like, but the embodiment is not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region that emits light generated from each of the light-emitting elements ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining film PDL. The non-light emitting regions NPXA may be areas between the adjacent light emitting areas PXA-R, PXA-G, and PXA-B, and which correspond to the pixel defining film PDL. In embodiments, the light emitting regions PXA-R, PXA-G, and PXA-B may each correspond to a pixel. The pixel defining film PDL may separate the light-emitting elements ED-1, ED-2, and ED-3. The emission layers EML-R, EML-G, and EML-B of the light-emitting elements ED-1, ED-2, and ED-3 may be disposed in openings OH defined by the pixel defining film PDL and separated from each other.

The light emitting regions PXA-R, PXA-G, and PXA-B may be arranged into groups according to the color of light generated from the light-emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light, are illustrated as an example. For example, the display device DD may include a red light emitting region PXA-R, a green light emitting region PXA-G, and a blue light emitting region PXA-B, which are distinct from one another.

In the display device DD according to an embodiment, the light-emitting elements ED-1, ED-2 and ED-3 may emit light having wavelengths that are different from each other. For example, in an embodiment, the display device DD may include a first light-emitting elements ED-1 that emits red light, a second light-emitting element ED-2 that emits green light, and a third light-emitting element ED-3 that emits blue light. For example, the red light emitting region PXA-R, the green light emitting region PXA-G, and the blue light emitting region PXA-B of the display device DD may respectively correspond to the first light-emitting element ED-1, the second light-emitting element ED-2, and the third light-emitting element ED-3.

However, embodiments are not limited thereto, and the first to third light-emitting elements ED-1, ED-2, and ED-3 may emit light in a same wavelength range or at least one light-emitting element may emit a light in a wavelength range that is different from the remainder. For example, the first to third light-emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be alternately arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R, PXA-G, and PXA-B may be different in size or shape from each other, according to a wavelength range of emitted light. The areas of the light emitting regions PXA-R, PXA-G, and PXA-B may be areas in a plan view that are defined by the first directional axis DR1 and the second directional axis DR2.

An arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics that are required for the display device DD. For example, the light emitting regions PXA-R, PXA-G, and PXA-B may be arranged in a pentile configuration (such as PENTILE®) or in a diamond configuration (such as Diamond Pixel®).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

FIG. 3 to FIG. 7 are each a schematic cross-sectional view of a light-emitting element according to an embodiment. A light-emitting element ED according to an embodiment may include a first electrode EL1, a hole transport region HTR, an emission layer EML, an electron transport region ETR, and a second electrode EL2, which are sequentially stacked.

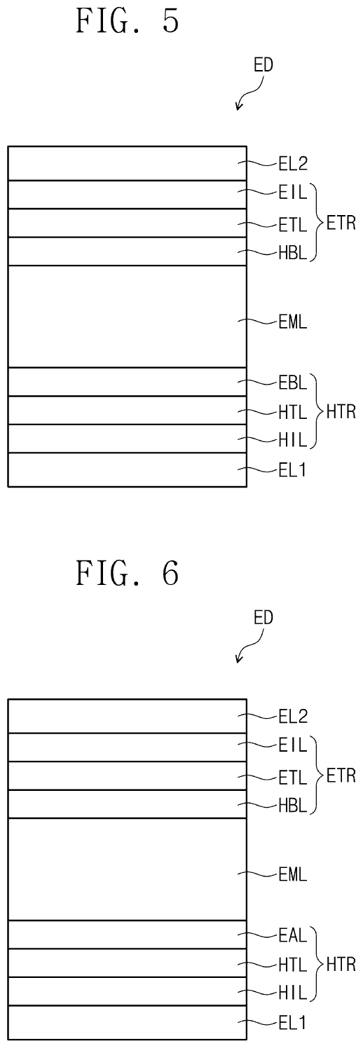

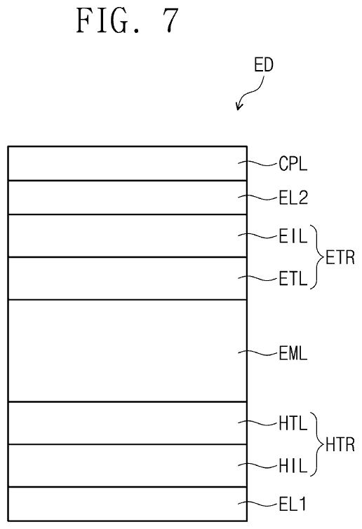

In comparison to FIG. 3, FIG. 4 is a schematic cross-sectional view of the light-emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 is a schematic cross-sectional view of a light-emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 3, FIG. 6 is a schematic cross-sectional view of a light-emitting element ED according to an embodiment, in which a hole transport region HTR includes a hole injection layer HIL, a hole transport layer HTL, and an emission auxiliary layer EAL, and an electron transport region ETR includes an electron injection layer EIL, an electron transport layer ETL, and a hole blocking layer HBL. In comparison to FIG. 4, FIG. 7 is a schematic embodiment that includes a capping layer CPL disposed on the second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another example, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. In an embodiment, the first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), emission auxiliary layer EAL, or an electron blocking layer EBL. A thickness of the hole transport region HTR may be in a range of from about 50 Å to about 15,000 Å.

The hole transport region HTR may be a layer consisting of a single material, a layer including different materials, or a structure including multiple including different materials.

In embodiments, the hole transport region HTR may have a single layer structure of a hole injection layer HIL or a hole transport layer HTL, or may have a single layer structure formed of a hole injection material and a hole transport material. In embodiments, the hole transport region HTR may have a single layer structure formed of different materials, or may have a structure in which a hole injection layer HIL/hole transport layer HTL, a hole injection layer HIL/hole transport layer HTL/emission auxiliary layer EAL, a hole injection layer HIL/emission auxiliary layer EAL, a hole transport layer HTL/emission auxiliary layer EAL, or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light-emitting element ED according to an embodiment, the hole transport region HTR may include a compound represented by Formula H-1:

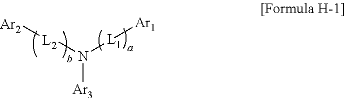

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. A and b may each independently be an integer from 0 to 10. When a or b is 2 or greater, multiple L₁ group or L₂ group may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

In an embodiment, a compound represented by Formula H-1 may be a monoamine compound. In an embodiment, a compound represented by Formula H-1 may be a diamine compound in which at least one of Ar₁ to Ar₃ includes an amine group as a substituent. In another embodiment, a compound represented by Formula H-1 may be a carbazole-based compound in which at least one of Ar₁ and Ar₂ includes a substituted or unsubstituted carbazole group, or may be a fluorene-based compound in which in at least one of Ar₁ and Ar₂ includes a substituted or unsubstituted fluorene group.

The compound represented by Formula H-1 may be any compound selected from Compound Group H. However, the compounds listed in Compound Group H are only examples, and the compound represented by Formula H-1 is not limited to Compound Group H:

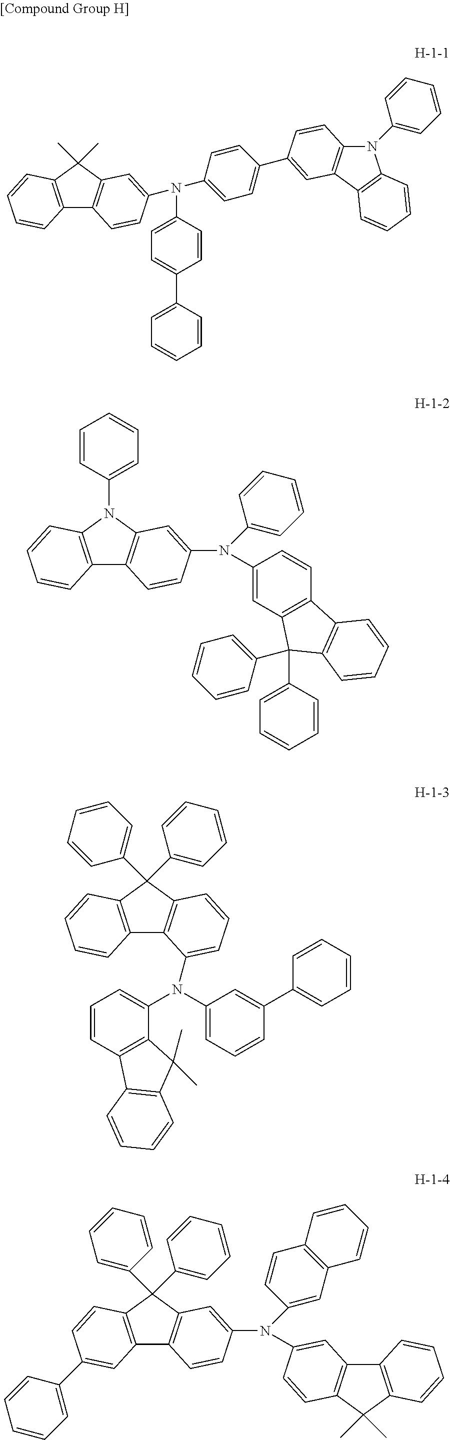 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

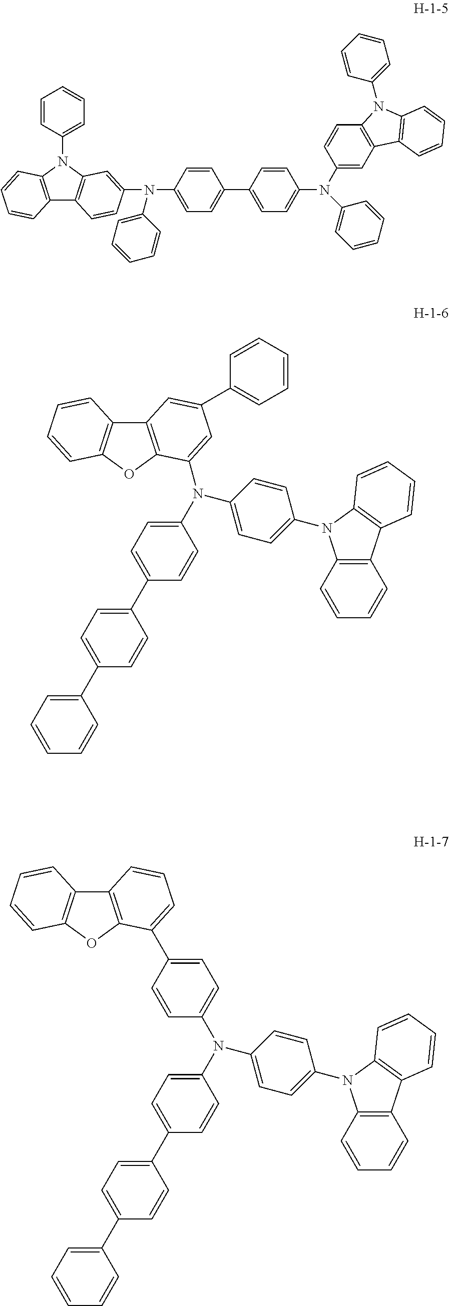 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

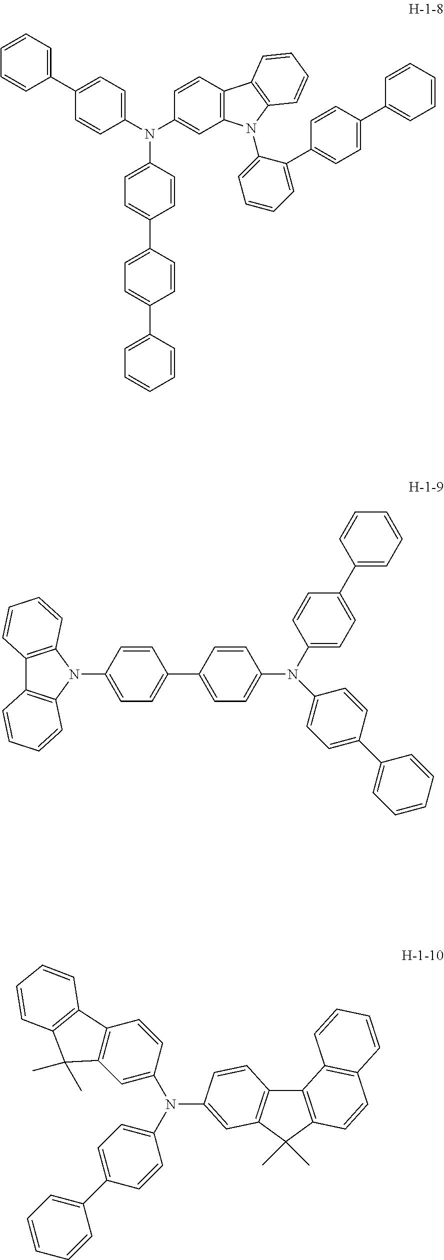 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

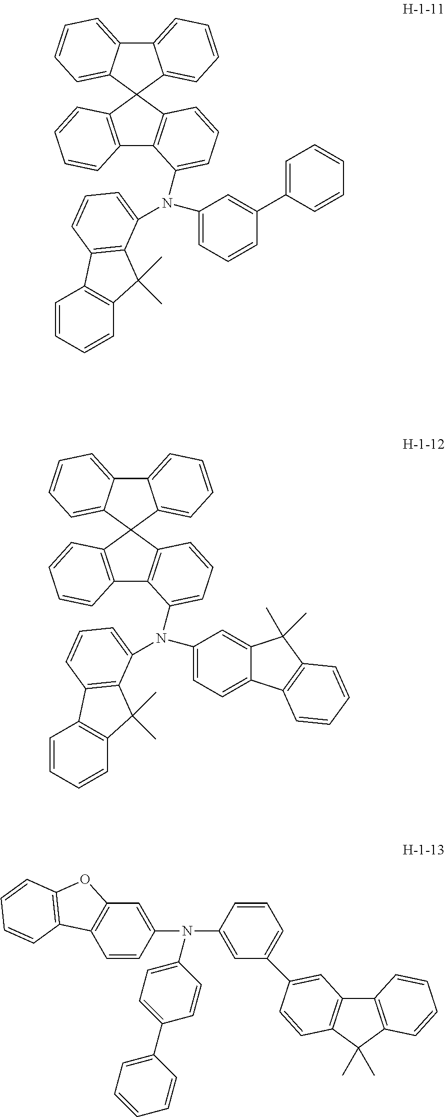 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

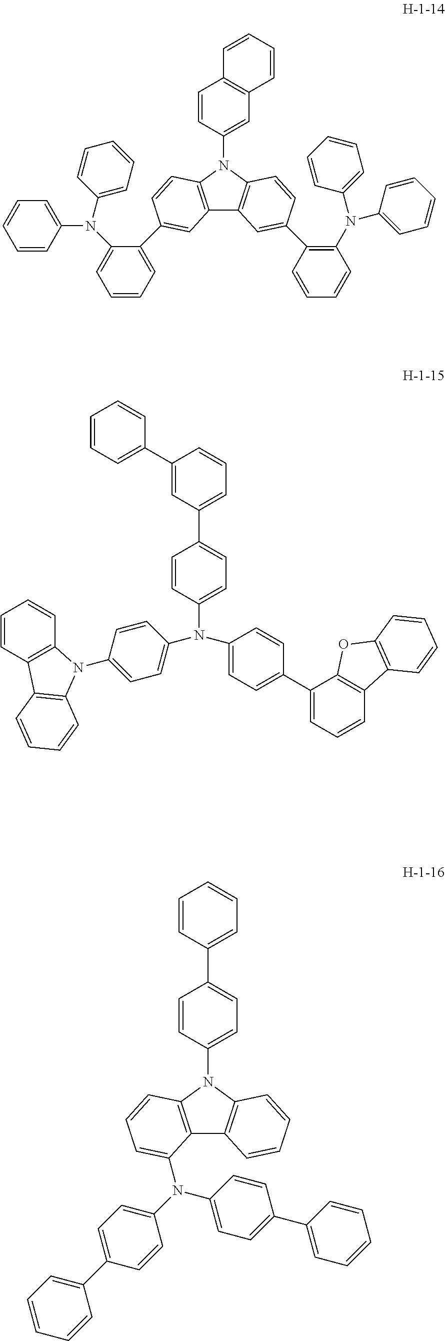 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

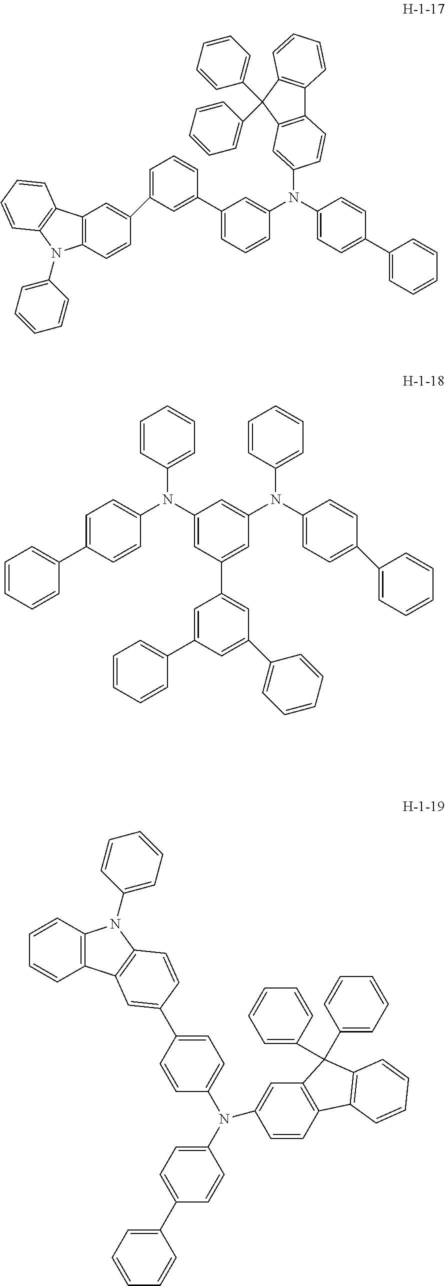 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, an emission auxiliary layer EAL, or an electron blocking layer EBL.

A thickness of the hole transport region HTR may be in a range of about 100 Å to about 10,000 Å. For example, a thickness of the hole transport region HTR may be in a range of about 100 Å to about 5,000 Å. When the hole transport region HTR includes the hole injection layer HIL, the hole injection layer HIL may have a thickness in a range of about 30 Å to about 1,000 Å. When the hole transport region HTR includes the hole transport layer HTL, the hole transport layer HTL may have a thickness in a range of about 250 Å to about 1,000 Å. For example, when the hole transport region HTR includes the electron blocking layer EBL, the electron blocking layer EBL may have a thickness in a range of about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity in addition to the above-described materials. The charge generating material may be dispersed uniformly or non-uniformly in the hole transport region HTR. For example, the charge generating material may be a p-dopant. The p-dopant may include at least one of a halogenated metal compound, a quinone derivative, a metal oxide, or a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7,8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of the emission auxiliary layer EAL and the electron blocking layer EBL, in addition to the hole injection layer HIL and the hole transport layer HTL. The emission auxiliary layer EAL compensates for a resonance distance depending on a wavelength of light emitted in the emission layer EML and adjusts a hole charge balance, and thus emission efficiency may increase. The emission auxiliary layer EAL may serve to prevent electrons from being injected into the hole transport region HTR. As materials that are included in the emission auxiliary layer EAL, materials that may be included in the hole transport region HTR may be used. The electron blocking layer EBL may serve to prevent electrons from being injected from the electron transport region ETR to the hole transport region HTR.

In the light-emitting element ED according to an embodiment, the emission layer EML may include a first compound according to an embodiment. The emission layer EML according to an embodiment may further include at least one of a second compound, a third compound, and a fourth compound. The second compound may include a tricyclic fused ring including a nitrogen atom as a ring-forming atom. The third compound may include a hexagonal ring group containing at least one nitrogen atom as a ring-forming atom. The fourth compound may include an organometallic complex. The second, third, and fourth compounds will be described later in more detail.

In the specification, the first compound may be referred to as a fused polycyclic compound according to an embodiment. The fused polycyclic compound according to an embodiment may include, as a core structure, a pentacyclic fused ring containing three heteroatoms as ring-forming atoms. Any one of the three heteroatoms may be a boron atom, another one may be a nitrogen atom, and the third one may be a nitrogen atom or a sulfur atom. The fused polycyclic compound according to an embodiment may include a meta-terphenyl (m-terphenyl) moiety bonded at a meta position with respect to the boron atom, which is a ring-forming atom of the core structure. The m-terphenyl moiety may be a bulky substituent. The fused polycyclic compound according to an embodiment may include a biphenyl moiety bonded (for example, directly bonded) to the nitrogen atom, which is a ring-forming atom of the core structure. Therefore, the fused polycyclic compound according to an embodiment may have a relatively large volume, and emit light with a shortened emission wavelength, and Dexter energy transfer may be inhibited. The light-emitting element ED including the fused polycyclic compound according to an embodiment may exhibit long lifespan characteristics.

In an embodiment, the light-emitting element ED may include the fused polycyclic compound according to an embodiment. The fused polycyclic compound according to an embodiment may be represented by Formula 1.

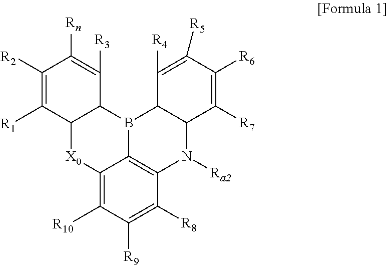

In Formula 1, R₁ to R₁₀ may each independently be a hydrogen atom, a deuterium atom, a cyano group, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms. For example, R₁ to R₁₀ may each independently be a hydrogen atom, a substituted or unsubstituted t-butyl group, a substituted or unsubstituted phenyl group, a substituted or unsubstituted fluorenyl group, a substituted or unsubstituted dibenzofuran group, a substituted or unsubstituted carbazole group, a substituted or unsubstituted dibenzothiophene group, a substituted or unsubstituted acridine group, or a substituted or unsubstituted xanthene group.

In an embodiment, in Formula 1, R₉ may be a group represented by anyone of Formula R9-1 to Formula R9-18. In Formula R9-15, D represents a deuterium atom.

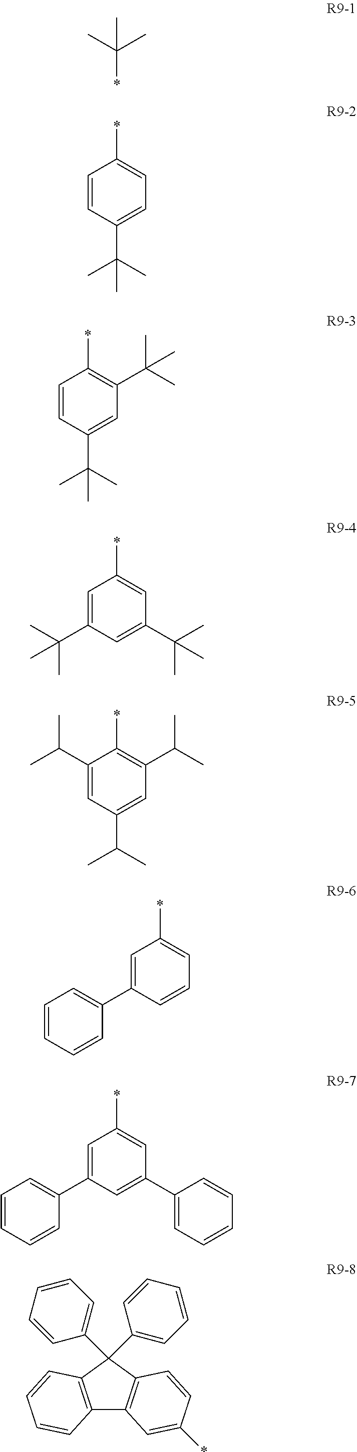

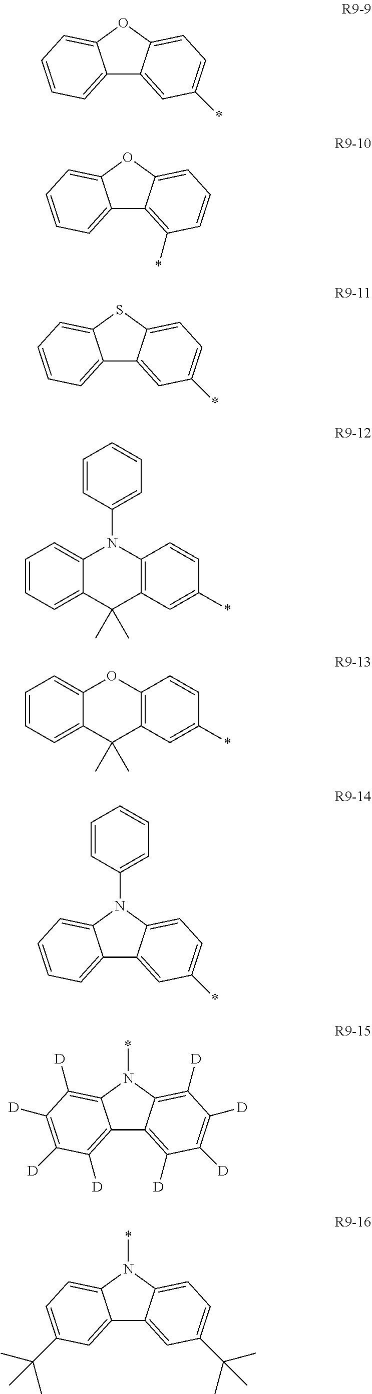

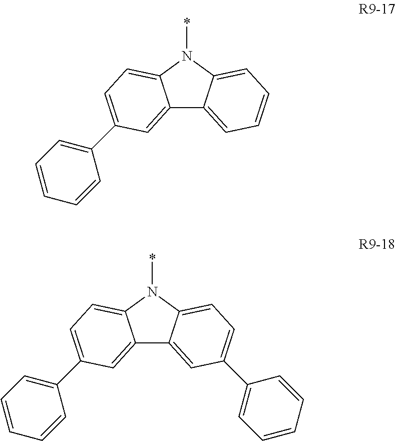 [SMILES: *n1c2ccccc2c2cc(-c3ccccc3)ccc21 ; *n1c2ccc(-c3ccccc3)cc2c2cc(-c3ccccc3)ccc21]

In Formula 1, Rₙ may be a group represented by Formula 2. The group represented by Formula 2 may be an m-terphenyl moiety.

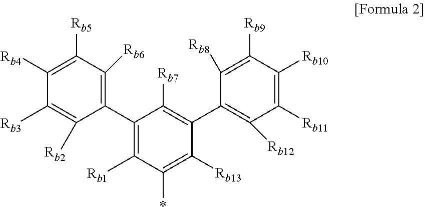

In Formula 2, R_{b1} to R_{b13} may each independently be a hydrogen atom, a deuterium atom, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. For example, R_{b1} to R_{b13} may each independently be a hydrogen atom, a substituted or unsubstituted t-butyl group, a substituted or unsubstituted aryl oxy group, or a substituted or unsubstituted phenyl group.

In Formula 1, X₀ may be S or N(Rₐ₁).

In Formula 1, Rₐ₁ and Rₐ₂ may each independently be a group represented by Formula 3. The group represented by Formula 3 may be a biphenyl moiety.

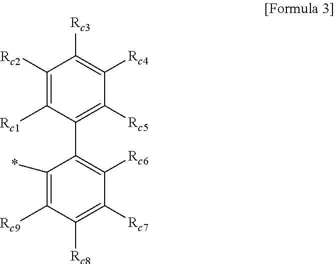

In Formula 3, R_{c1} to R_{c9} may each independently be a hydrogen atom, a deuterium atom, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. For example, R_{c1} to R_{c9} may each independently be a hydrogen atom, a substituted or unsubstituted t-butyl group, a substituted or unsubstituted aryl oxy group, or a substituted or unsubstituted phenyl group.

In an embodiment, the group represented by Formula 2 may be a group represented by any one of Formula 2-1 to Formula 2-6. Formula 2-1 to Formula 2-6 represent embodiments of Formula 2 where R_{b1} to R_{b13} are further defined.

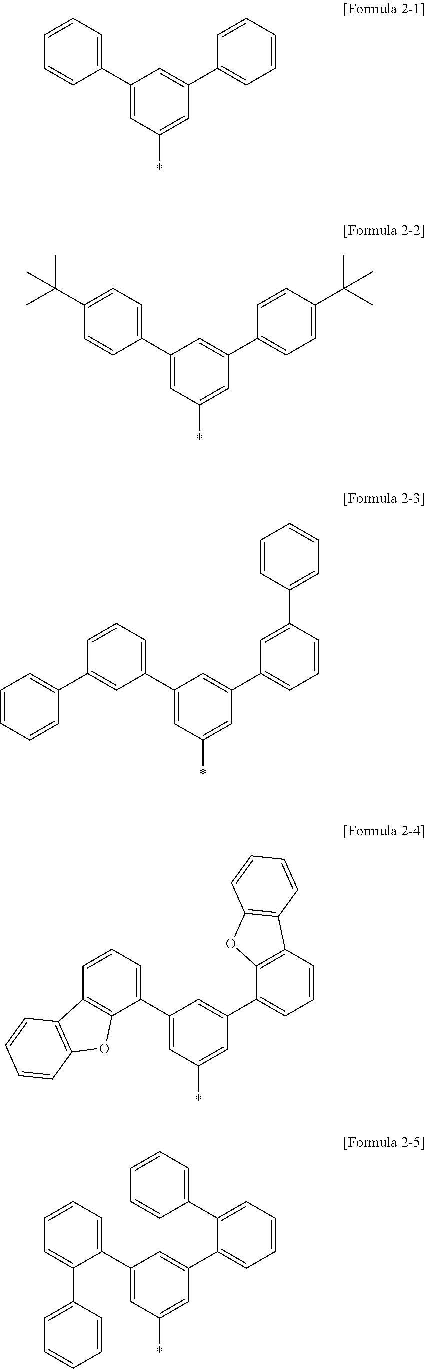 [SMILES: *c1cc(-c2ccccc2)cc(-c2ccccc2)c1 ; *c1cc(-c2ccc(C(C)(C)C)cc2)cc(-c2ccc(C(C)(C)C)cc2)c1 ; *c1cc(-c2cccc(-c3ccccc3)c2)cc(-c2cccc(-c3ccccc3)c2)c1 ; *c1cc(-c2cccc3c2oc2ccccc23)cc(-c2cccc3c2oc2ccccc23)c1 ; *c1cc(-c2ccccc2-c2ccccc2)cc(-c2ccccc2-c2ccccc2)c1]

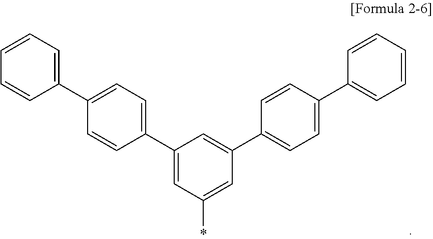 [SMILES: *c1cc(-c2ccc(-c3ccccc3)cc2)cc(-c2ccc(-c3ccccc3)cc2)c1]

In an embodiment, the group represented by Formula 3 may be a group represented by any one of Formula 3-1 to Formula 3-18. Formula 3-1 to Formula 3-18 represent embodiments of Formula 3 where R_{c1} to R_{c9} are further defined.

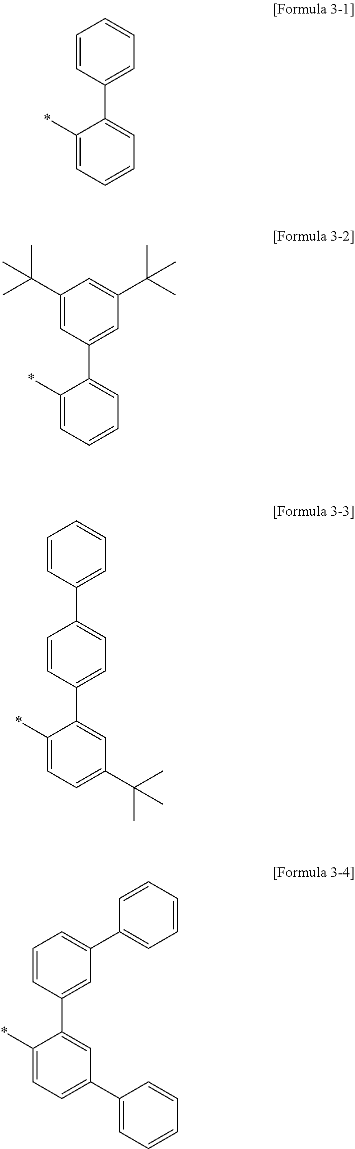 [SMILES: *c1ccccc1-c1ccccc1 ; *c1ccccc1-c1cc(C(C)(C)C)cc(C(C)(C)C)c1 ; *c1ccc(C(C)(C)C)cc1-c1ccc(-c2ccccc2)cc1 ; *c1ccc(-c2ccccc2)cc1-c1cccc(-c2ccccc2)c1]

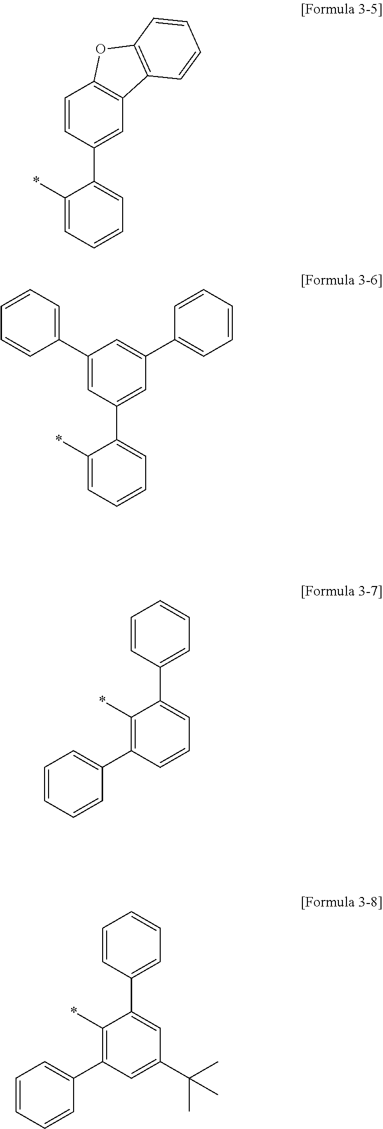 [SMILES: *c1ccccc1-c1ccc2oc3ccccc3c2c1 ; *c1ccccc1-c1cc(-c2ccccc2)cc(-c2ccccc2)c1 ; *c1c(-c2ccccc2)cccc1-c1ccccc1 ; *c1c(-c2ccccc2)cc(C(C)(C)C)cc1-c1ccccc1]

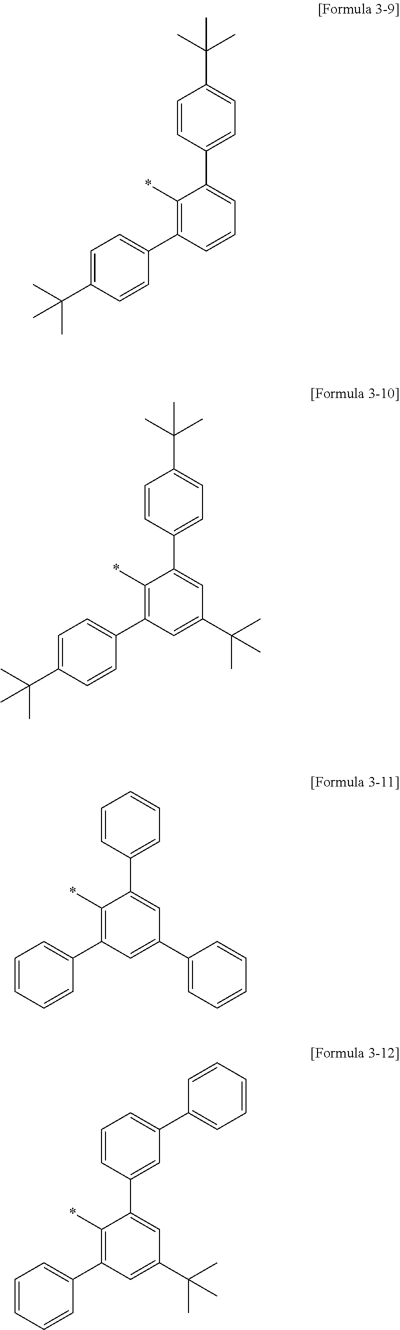

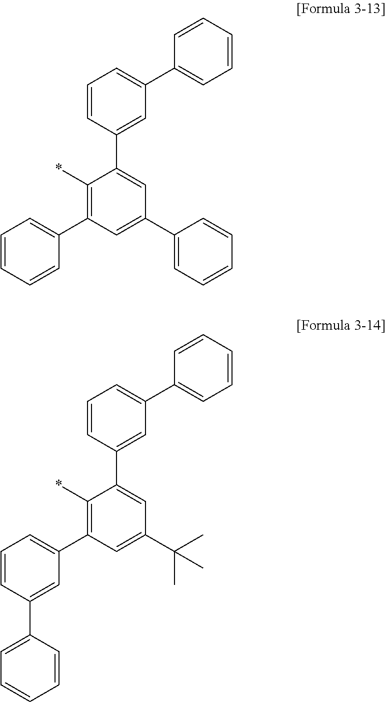 [SMILES: *c1c(-c2ccccc2)cc(-c2ccccc2)cc1-c1cccc(-c2ccccc2)c1 ; *c1c(-c2cccc(-c3ccccc3)c2)cc(C(C)(C)C)cc1-c1cccc(-c2ccccc2)c1]

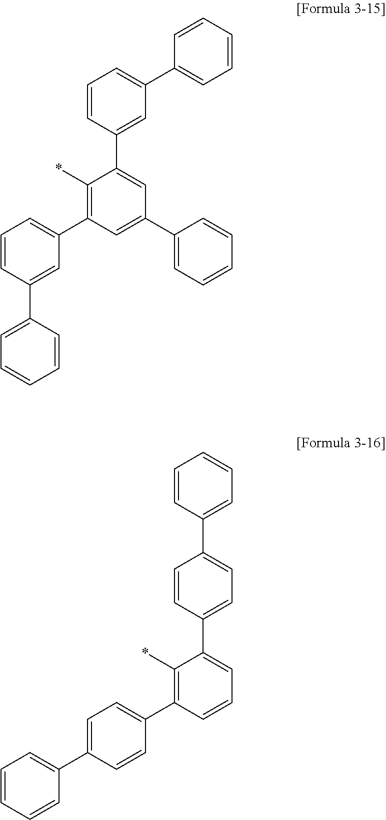 [SMILES: *c1c(-c2cccc(-c3ccccc3)c2)cc(-c2ccccc2)cc1-c1cccc(-c2ccccc2)c1 ; *c1c(-c2ccc(-c3ccccc3)cc2)cccc1-c1ccc(-c2ccccc2)cc1]

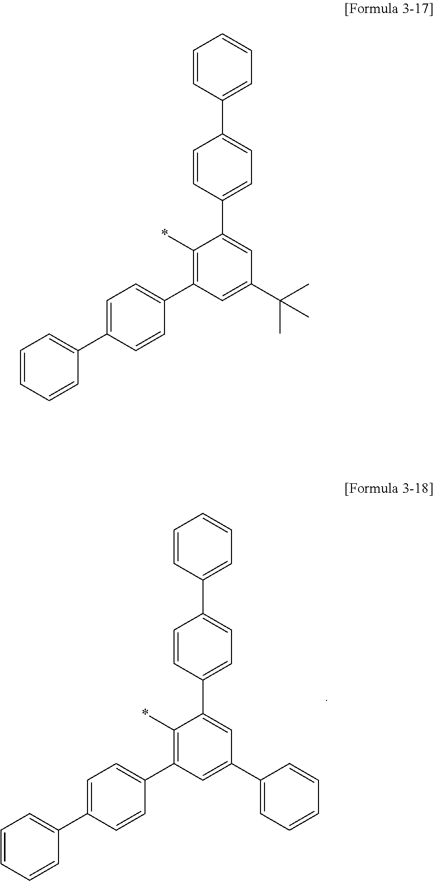 [SMILES: *c1c(-c2ccc(-c3ccccc3)cc2)cc(C(C)(C)C)cc1-c1ccc(-c2ccccc2)cc1 ; *c1c(-c2ccc(-c3ccccc3)cc2)cc(-c2ccccc2)cc1-c1ccc(-c2ccccc2)cc1]

The fused polycyclic compound according to an embodiment may be substituted with a deuterium atom or may include a substituent that is substituted with a deuterium atom. For example, in Formula 1, at least one of R₁ to R₁₀ may include a deuterium atom as a substituent.

In an embodiment, the fused polycyclic compound represented by Formula 1 may be represented by Formula 1-1 or Formula 1-2. Formula 1-1 represents a case where X₀ is N(Rₐ) in Formula 1. Formula 1-2 represents a case where X₀ is S in Formula 1.

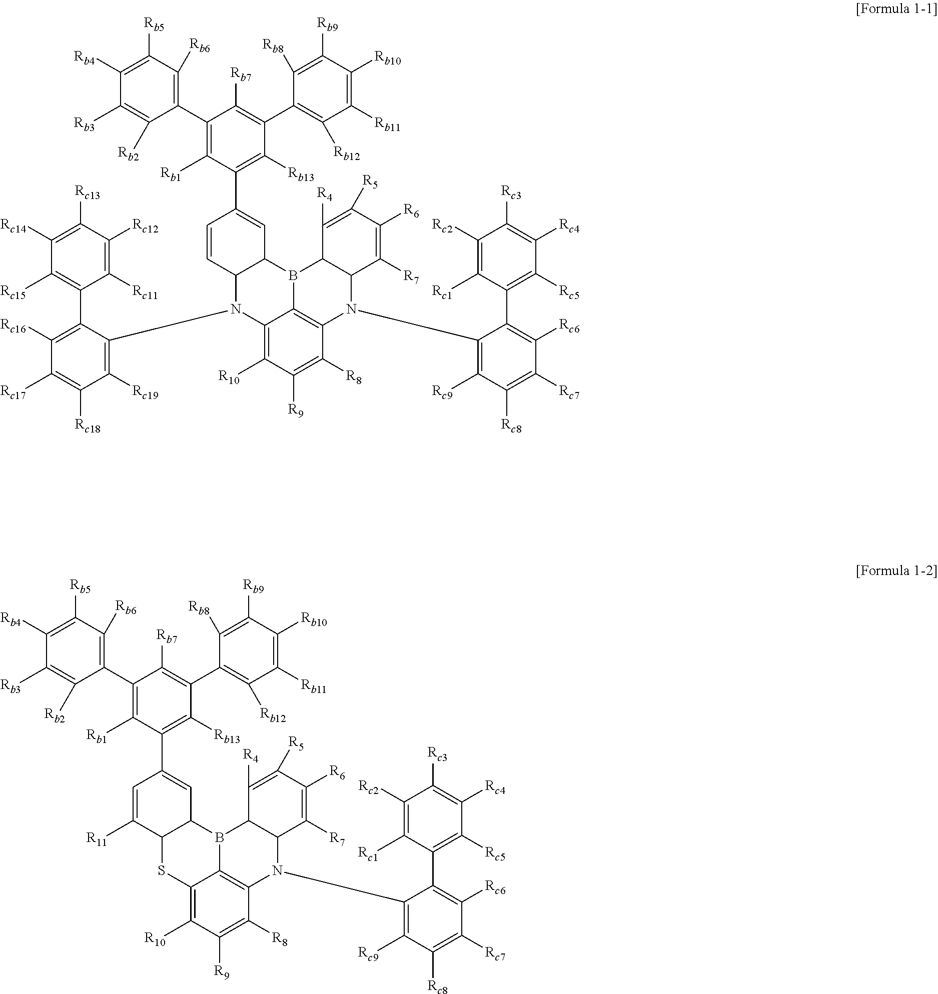

In Formula 1-1 and Formula 1-2, R₄ to R₁₀, R_{b1} to R_{b13}, and R_{c1} to R_{c9} are the same as defined in Formula 1, Formula 2, and Formula 3.

In Formula 1-1, R_{c11} to R_{c19} may each independently be a hydrogen atom, a deuterium atom, a substituted or unsubstituted oxy group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

In Formula 1-2, R₁₁ may be a hydrogen atom, a deuterium atom, a substituted or unsubstituted aryl group having 6 to 30 ring-forming carbon atoms, or a substituted or unsubstituted heteroaryl group having 2 to 30 ring-forming carbon atoms. For example, R₁₁ may be a substituted or unsubstituted phenyl group, a substituted or unsubstituted dibenzofuran group, or a substituted or unsubstituted carbazole group.

In an embodiment, in Formula 1-2, R₁₁ may be a group represented by any one of Formula R11-1 to Formula R11-13.

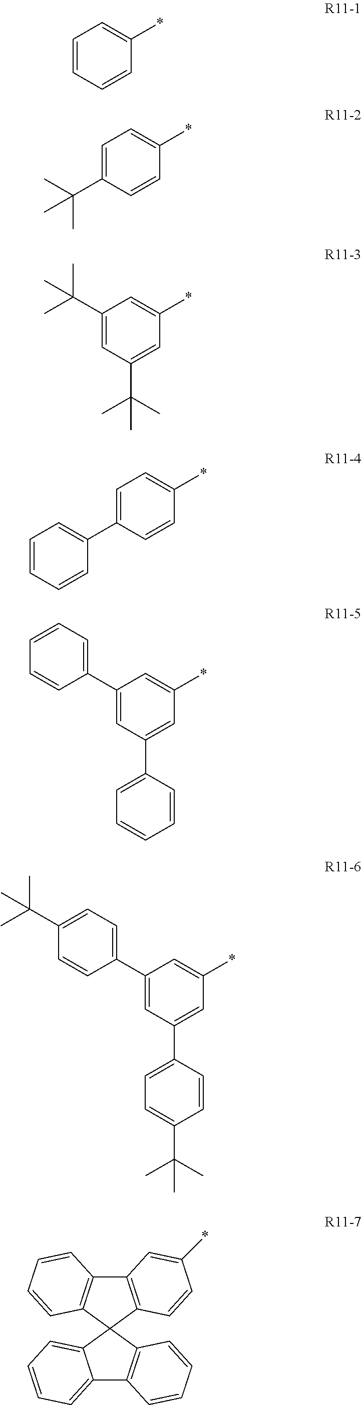

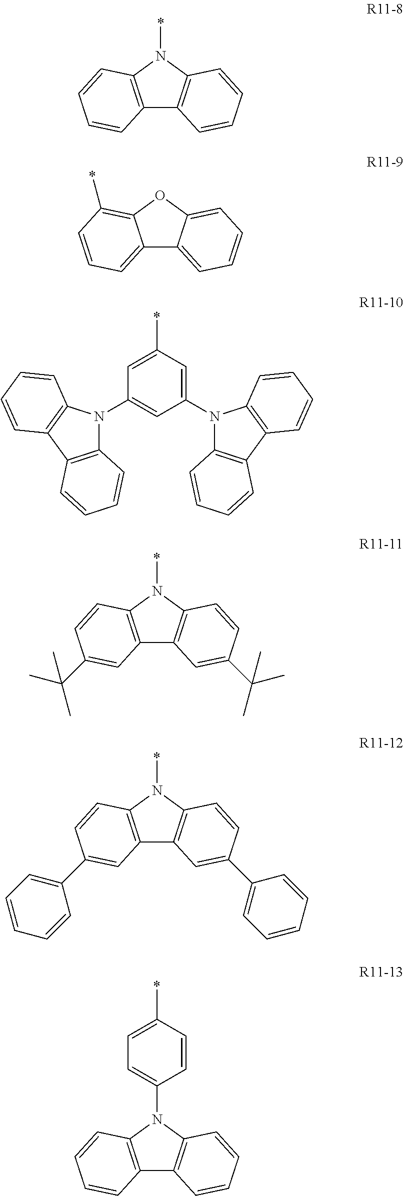 [SMILES: *n1c2ccccc2c2ccccc21 ; *c1cccc2c1oc1ccccc12 ; *c1cc(-n2c3ccccc3c3ccccc32)cc(-n2c3ccccc3c3ccccc32)c1 ; *n1c2ccc(C(C)(C)C)cc2c2cc(C(C)(C)C)ccc21 ; *n1c2ccc(-c3ccccc3)cc2c2cc(-c3ccccc3)ccc21 ; *c1ccc(-n2c3ccccc3c3ccccc32)cc1]

In an embodiment, the fused polycyclic compound represented by Formula 1 may be represented by Formula 1-A or Formula 1-B. Formula 1-A represents a case where R₄, R₅, and R₇ in Formula 1 are hydrogen atoms, and R₆ is a substituted or unsubstituted carbazole group. Formula 1-B represents a case where any one of R₄ to R₇ in Formula 1 is a substituted or unsubstituted phenyl group, and the remainder of R₄ to R₇ are hydrogen atoms.

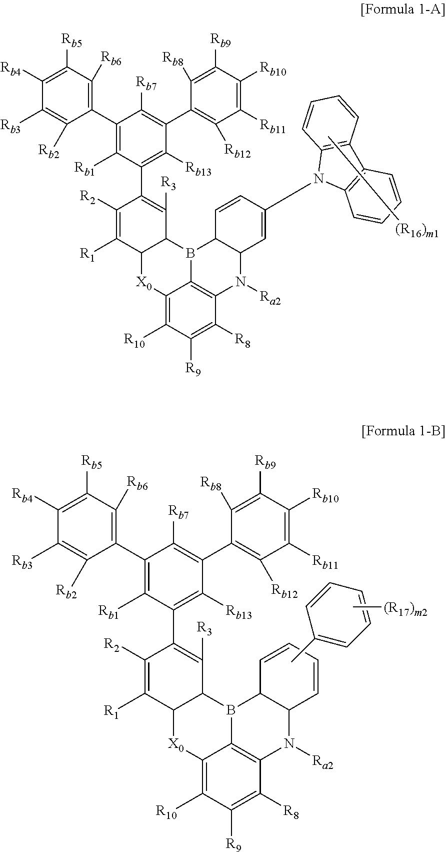

In Formula 1-A and Formula 1-B, R₁ to R₃, R₈ to R₁₀, R_{b1} to R_{b13}, X₀ and Rₐ₂ are the same as defined in Formula 1 and Formula 2.

In Formula 1-A, m1 may be an integer from 0 to 8; and R₁₆ may be a hydrogen atom, a deuterium atom, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

If m1 is 2 or more, multiple R₁₆ groups may be the same or at least one may be different. A case where m1 is 0 may be the same as a case where m1 is 8 and eight R₁₆ groups are hydrogen atoms.

In Formula 1-B, m2 may be an integer from 0 to 5; and R₁₇ may be a hydrogen atom, a deuterium atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

If m2 is 2 or more, multiple R₁₇ groups may be the same or at least one may be different. A case where m2 is 0 may be the same as a case where m2 is 5 and five R₁₇ groups are hydrogen atoms.

In an embodiment, in Formula 1-A, a carbazole group that includes R₁₆ may be a group represented by any one of Formula R16-1 to Formula R16-11. In Formula R16-5 to Formula R16-11, D represents a deuterium atom.

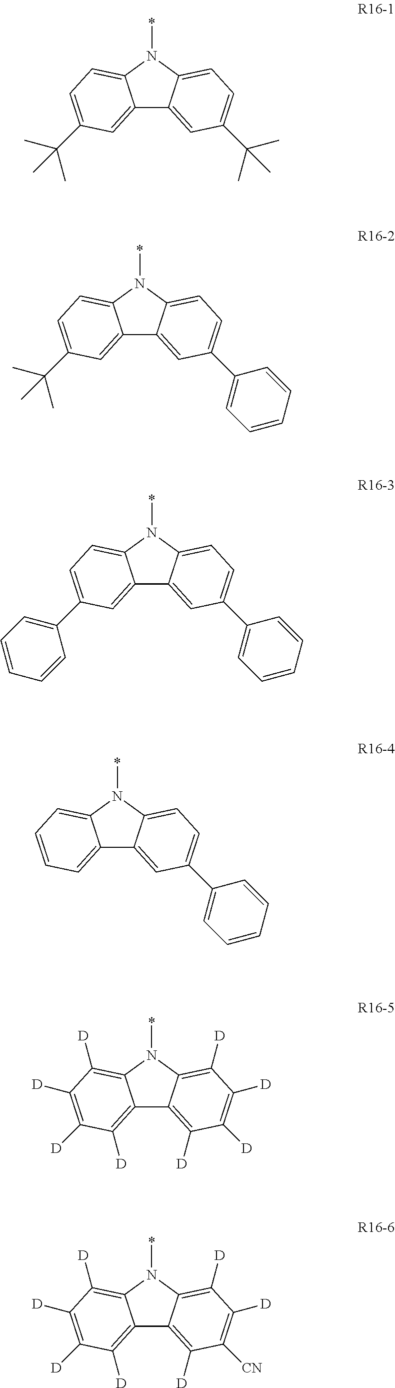

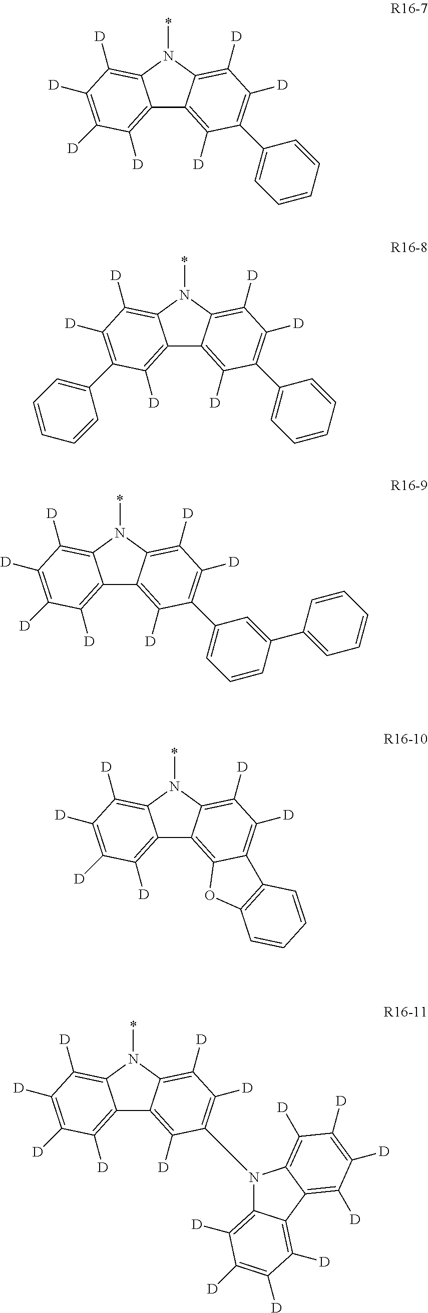 [SMILES: *n1c2c([2H])c([2H])c([2H])c([2H])c2c2c([2H])c(-c3ccccc3)c([2H])c([2H])c21 ; *n1c2c([2H])c([2H])c(-c3ccccc3)c([2H])c2c2c([2H])c(-c3ccccc3)c([2H])c([2H])c21 ; *n1c2c([2H])c([2H])c([2H])c([2H])c2c2c([2H])c(-c3cccc(-c4ccccc4)c3)c([2H])c([2H])c21 ; *n1c2c([2H])c([2H])c([2H])c([2H])c2c2c3oc4ccccc4c3c([2H])c([2H])c21 ; *n1c2c([2H])c([2H])c([2H])c([2H])c2c2c([2H])c(-n3c4c([2H])c([2H])c([2H])c([2H])c4c4c([2H])c([2H])c([2H])c([2H])c43)c([2H])c([2H])c21]

In an embodiment, in Formula 1-B, a phenyl group that includes R₁₇ may be a group represented by any one of Formula R17-1 to Formula R17-5.

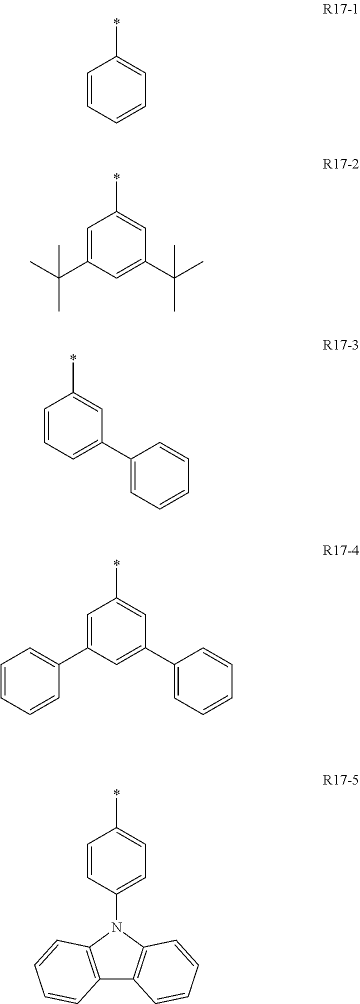 [SMILES: *c1ccccc1 ; *c1cc(C(C)(C)C)cc(C(C)(C)C)c1 ; *c1cccc(-c2ccccc2)c1 ; *c1cc(-c2ccccc2)cc(-c2ccccc2)c1 ; *c1ccc(-n2c3ccccc3c3ccccc32)cc1]

In an embodiment, the fused polycyclic compound represented by Formula 1-B may be represented by Formula 1-B1 or Formula 1-B2. Formula 1-B1 and Formula 1-B2 represent embodiments of Formula 1-B where a bonding site of the phenyl group including R₁₇ is further defined.

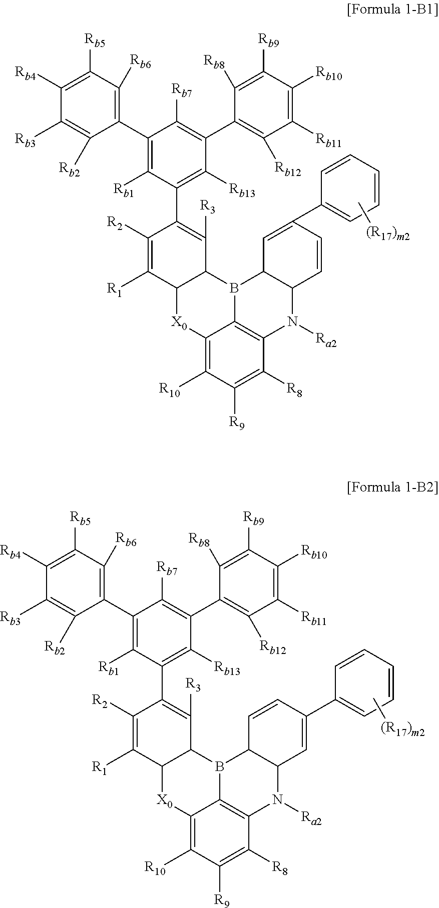

In Formula 1-B1 and Formula 1-B2, R₁ to R₃, R₈ to R₁₀, R_{b1} to R_{b13}, X₀, Rₐ₂, R₁₇, and m2 are the same as defined in Formula 1-B.

In an embodiment, the fused polycyclic compound may be any compound selected from Compound Group 1. In an embodiment, the light-emitting element ED (for example, in the emission layer EML) may include at least one fused polycyclic compound selected from Compound Group 1. In Compound Group 1, D represents a deuterium atom.

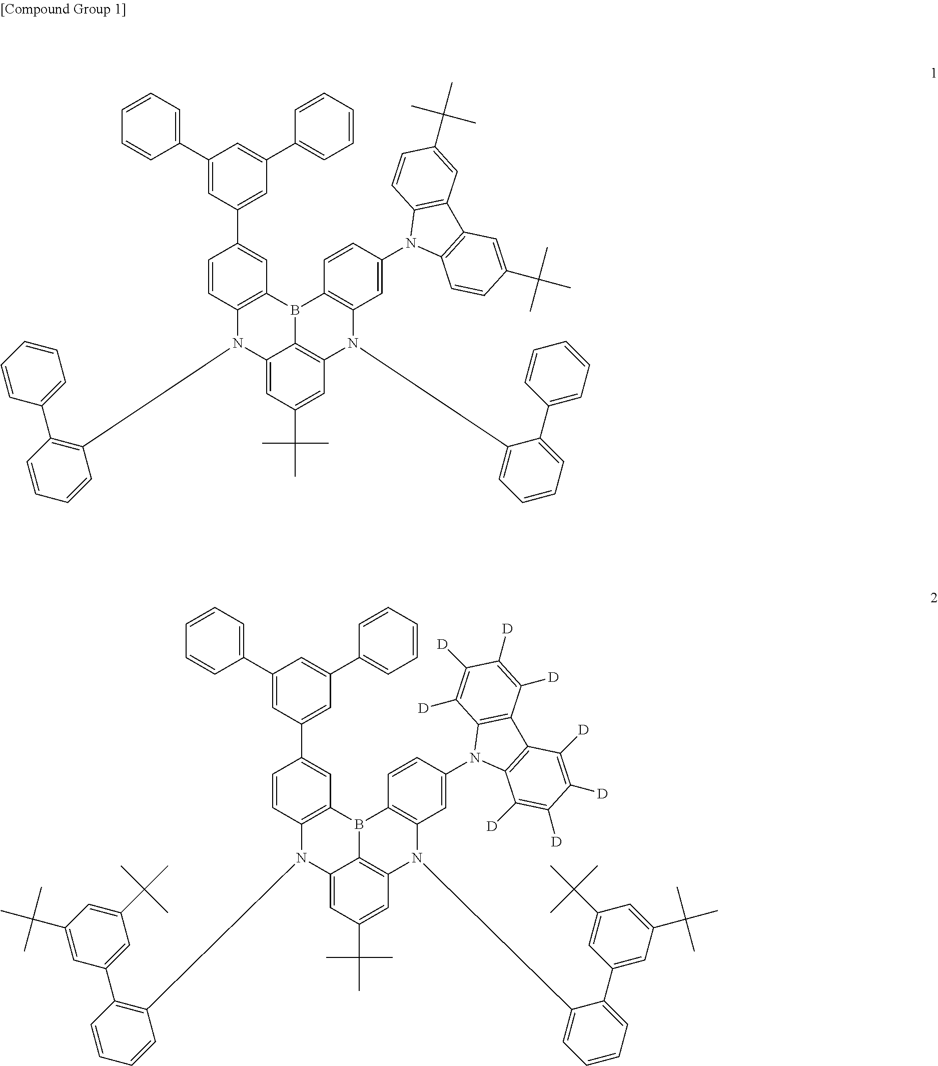 [SMILES: CC(C)(C)c1cc2c3c(c1)N(c1ccccc1-c1ccccc1)c1cc(-n4c5ccc(C(C)(C)C)cc5c5cc(C(C)(C)C)ccc54)ccc1B3c1cc(-c3cc(-c4ccccc4)cc(-c4ccccc4)c3)ccc1N2c1ccccc1-c1ccccc1 ; [2H]c1c([2H])c([2H])c2c(c1[2H])c1c([2H])c([2H])c([2H])c([2H])c1n2-c1ccc2c(c1)N(c1ccccc1-c1cc(C(C)(C)C)cc(C(C)(C)C)c1)c1cc(C(C)(C)C)cc3c1B2c1cc(-c2cc(-c4ccccc4)cc(-c4ccccc4)c2)ccc1N3c1ccccc1-c1cc(C(C)(C)C)cc(C(C)(C)C)c1]

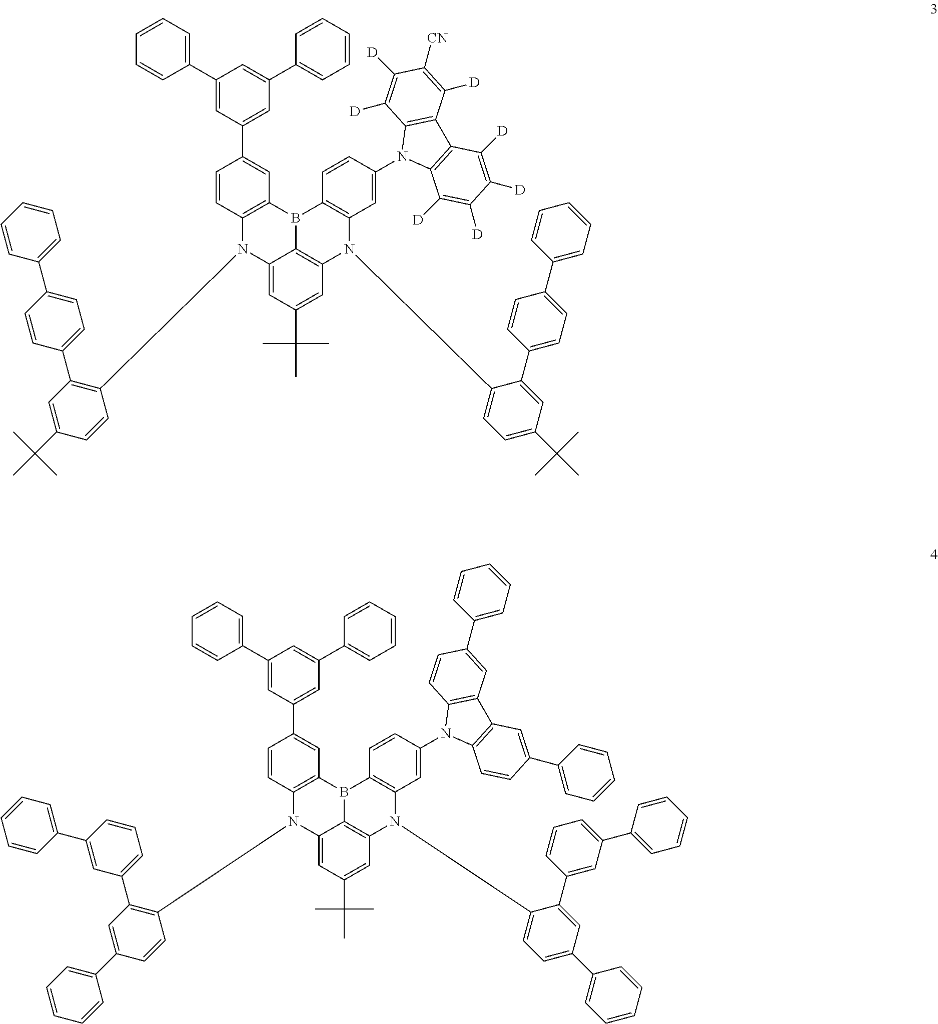 [SMILES: [2H]c1c([2H])c([2H])c2c(c1[2H])c1c([2H])c(C#N)c([2H])c([2H])c1n2-c1ccc2c(c1)N(c1ccc(C(C)(C)C)cc1-c1ccc(-c3ccccc3)cc1)c1cc(C(C)(C)C)cc3c1B2c1cc(-c2cc(-c4ccccc4)cc(-c4ccccc4)c2)ccc1N3c1ccc(C(C)(C)C)cc1-c1ccc(-c2ccccc2)cc1 ; CC(C)(C)c1cc2c3c(c1)N(c1ccc(-c4ccccc4)cc1-c1cccc(-c4ccccc4)c1)c1cc(-n4c5ccc(-c6ccccc6)cc5c5cc(-c6ccccc6)ccc54)ccc1B3c1cc(-c3cc(-c4ccccc4)cc(-c4ccccc4)c3)ccc1N2c1ccc(-c2ccccc2)cc1-c1cccc(-c2ccccc2)c1]

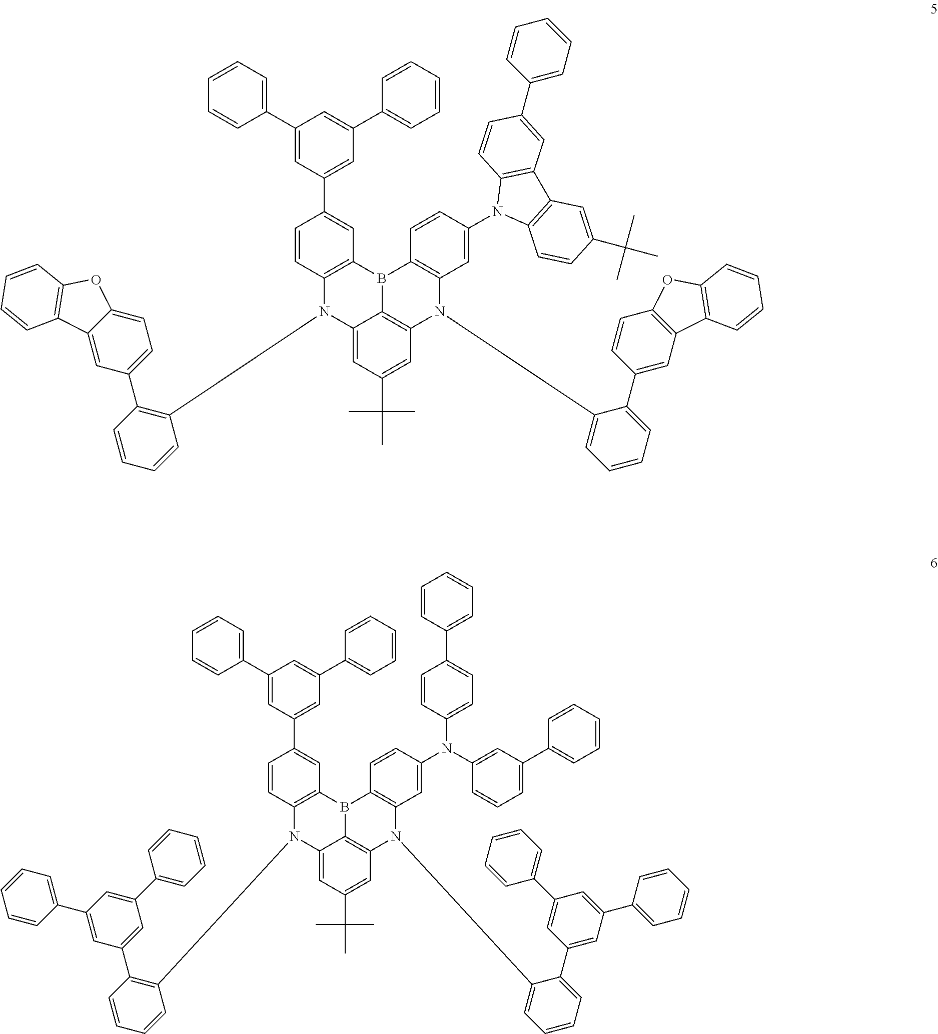 [SMILES: CC(C)(C)c1cc2c3c(c1)N(c1ccccc1-c1ccc4oc5ccccc5c4c1)c1cc(-n4c5ccc(-c6ccccc6)cc5c5cc(C(C)(C)C)ccc54)ccc1B3c1cc(-c3cc(-c4ccccc4)cc(-c4ccccc4)c3)ccc1N2c1ccccc1-c1ccc2oc3ccccc3c2c1 ; CC(C)(C)c1cc2c3c(c1)N(c1ccccc1-c1cc(-c4ccccc4)cc(-c4ccccc4)c1)c1cc(N(c4ccc(-c5ccccc5)cc4)c4cccc(-c5ccccc5)c4)ccc1B3c1cc(-c3cc(-c4ccccc4)cc(-c4ccccc4)c3)ccc1N2c1ccccc1-c1cc(-c2ccccc2)cc(-c2ccccc2)c1]

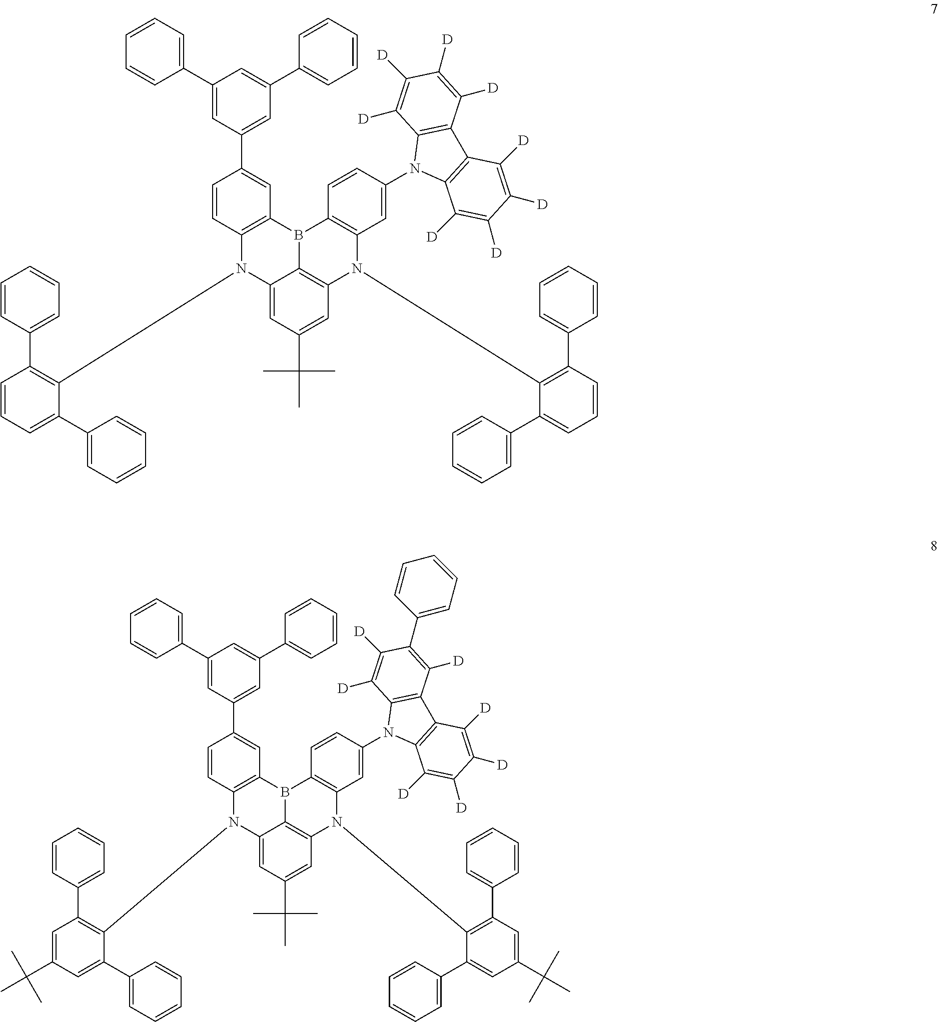 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1cc(-c2cc(-c4ccccc4)cc(-c4ccccc4)c2)ccc1N3c1c(-c2ccccc2)cccc1-c1ccccc1 ; [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cc(-c4ccccc4)cc(-c4ccccc4)c2)ccc1N3c1c(-c2ccccc2)cc(C(C)(C)C)cc1-c1ccccc1]

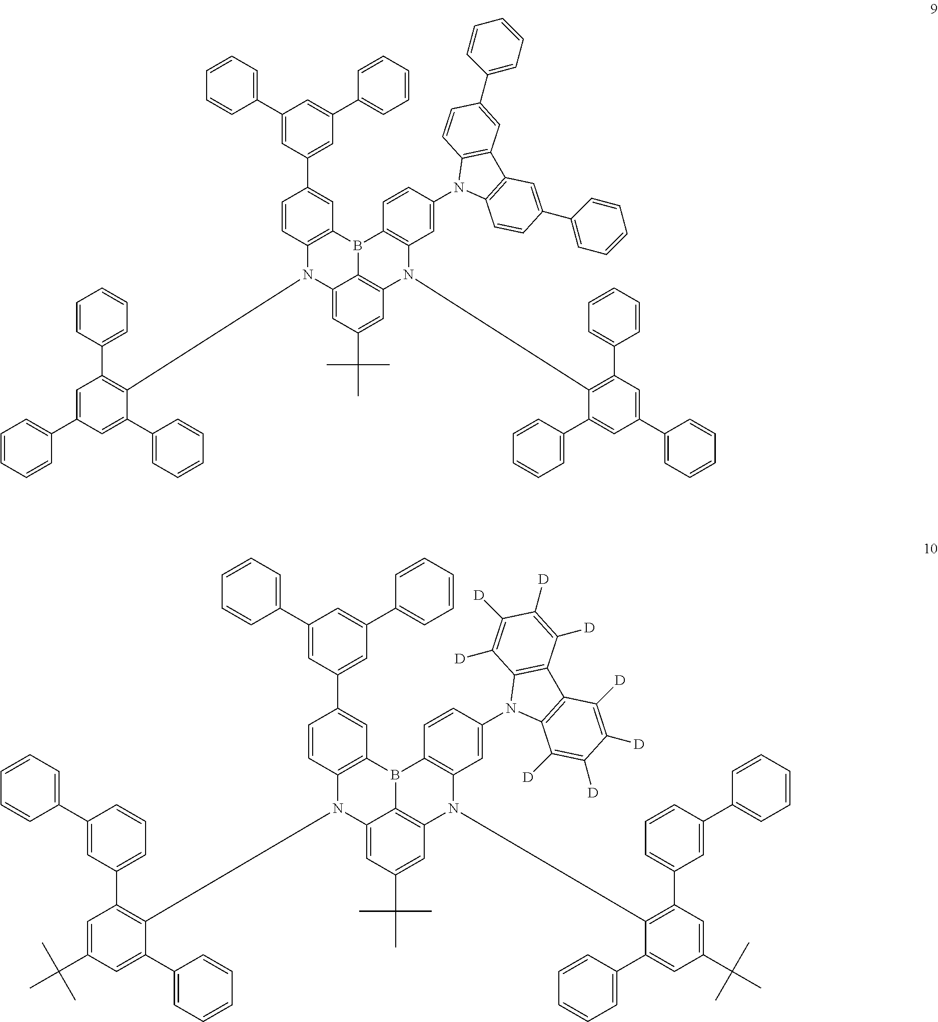 [SMILES: CC(C)(C)c1cc2c3c(c1)N(c1c(-c4ccccc4)cc(-c4ccccc4)cc1-c1ccccc1)c1cc(-n4c5ccc(-c6ccccc6)cc5c5cc(-c6ccccc6)ccc54)ccc1B3c1cc(-c3cc(-c4ccccc4)cc(-c4ccccc4)c3)ccc1N2c1c(-c2ccccc2)cc(-c2ccccc2)cc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc(-c3ccccc3)c1)c1cc(C(C)(C)C)cc3c1B2c1cc(-c2cc(-c4ccccc4)cc(-c4ccccc4)c2)ccc1N3c1c(-c2ccccc2)cc(C(C)(C)C)cc1-c1cccc(-c2ccccc2)c1]

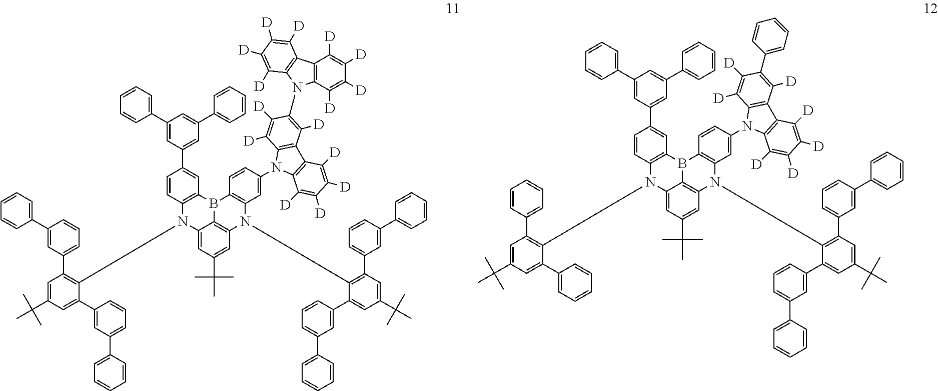

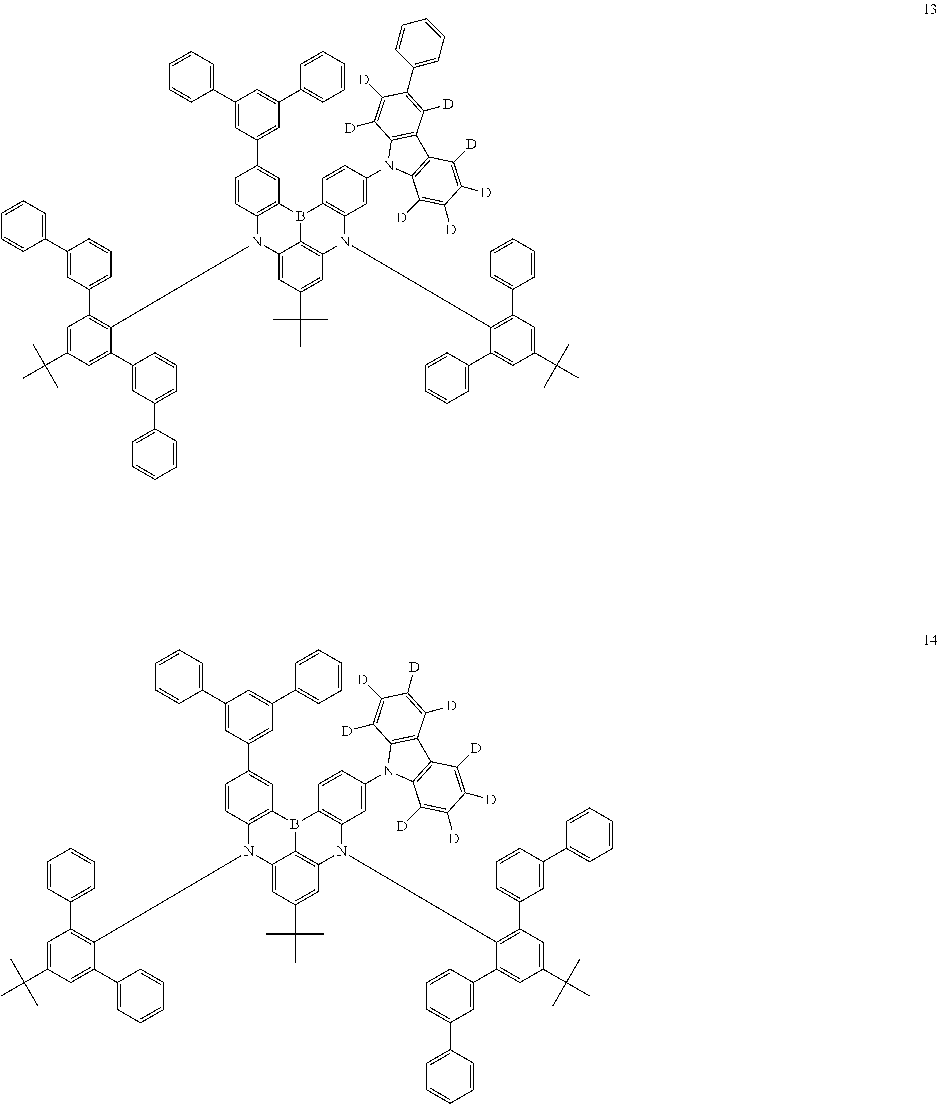

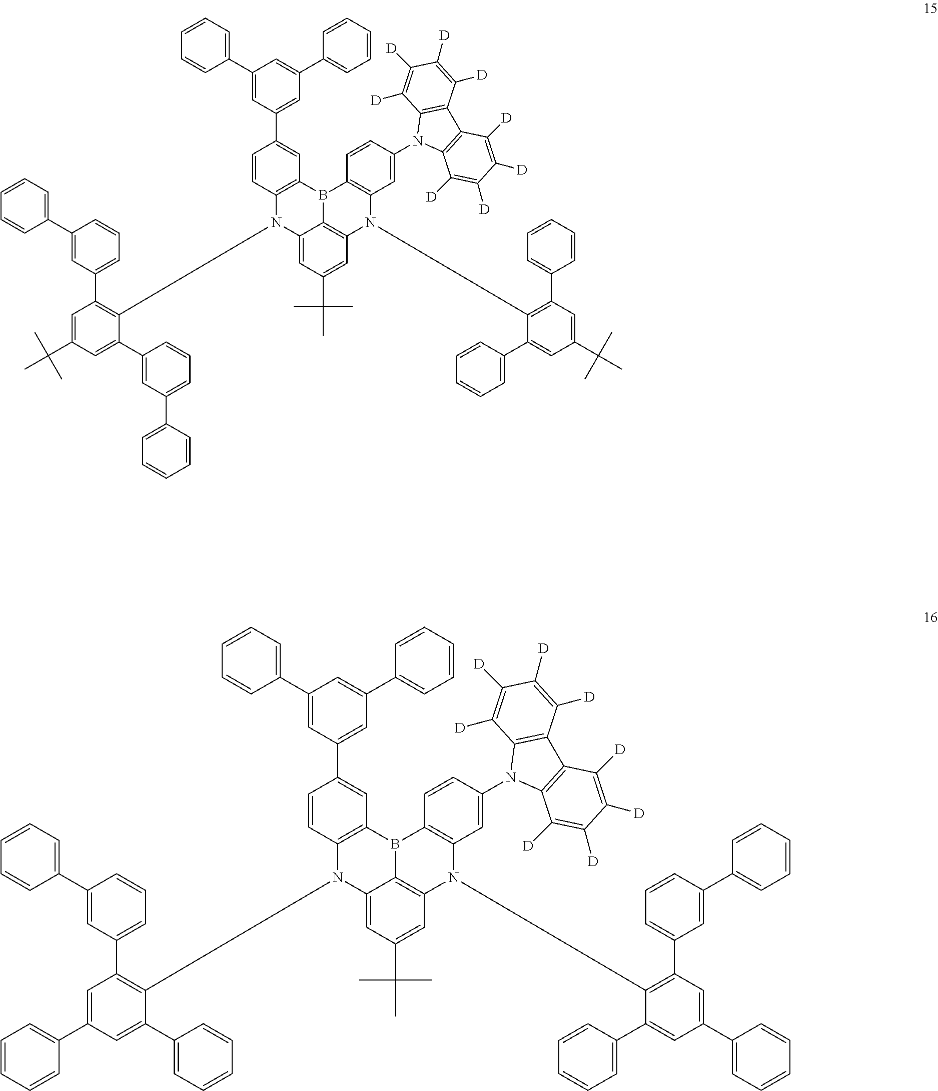 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cc(-c4ccccc4)cc(-c4ccccc4)c2)ccc1N3c1c(-c2cccc(-c3ccccc3)c2)cc(C(C)(C)C)cc1-c1cccc(-c2ccccc2)c1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc(-c3ccccc3)c1)c1cc(C(C)(C)C)cc3c1B2c1cc(-c2cc(-c4ccccc4)cc(-c4ccccc4)c2)ccc1N3c1c(-c2ccccc2)cc(-c2ccccc2)cc1-c1cccc(-c2ccccc2)c1]

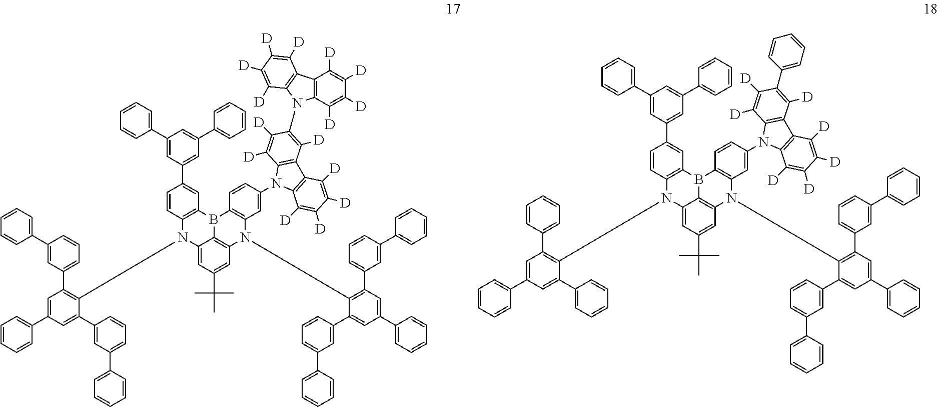

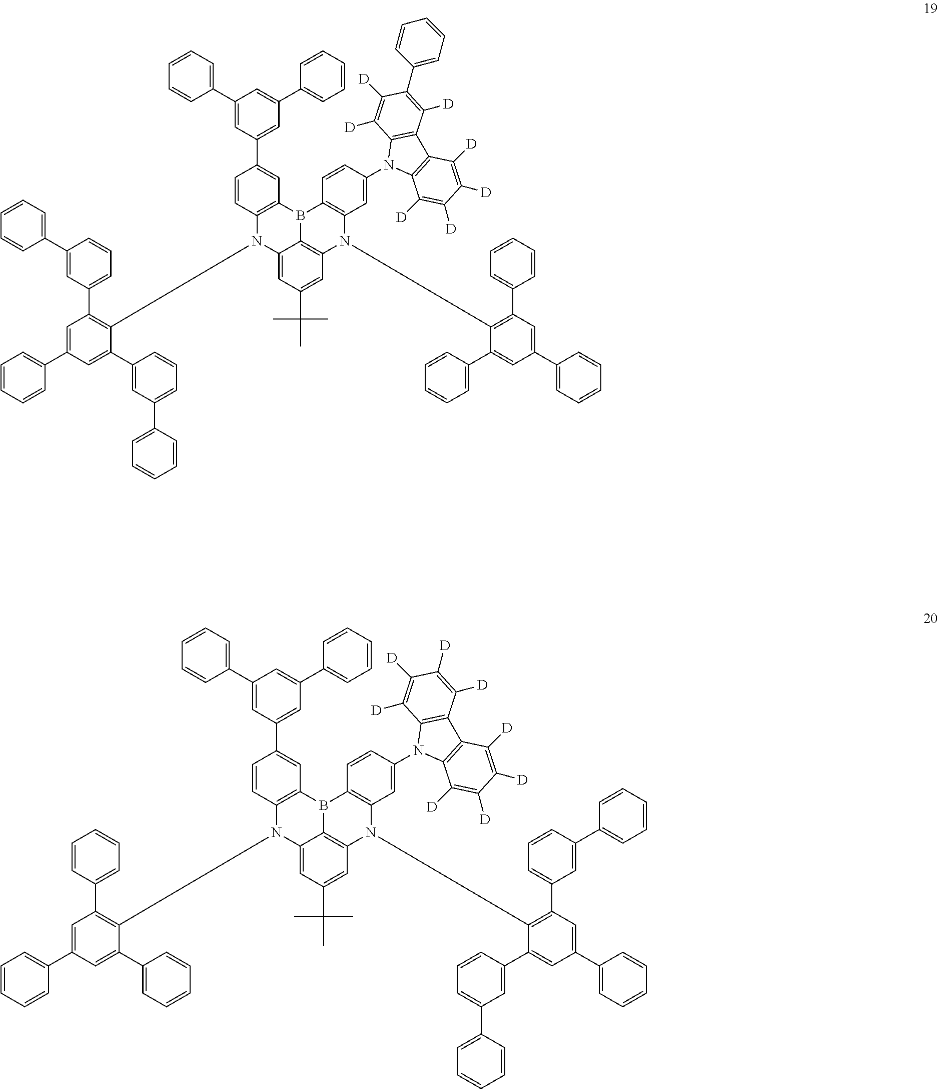 [SMILES: [2H]c1c([2H])c([2H])c2c(c1[2H])c1c([2H])c(-c3ccccc3)c([2H])c([2H])c1n2-c1ccc2c(c1)N(c1c(-c3ccccc3)cc(-c3ccccc3)cc1-c1ccccc1)c1cc(C(C)(C)C)cc3c1B2c1cc(-c2cc(-c4ccccc4)cc(-c4ccccc4)c2)ccc1N3c1c(-c2cccc(-c3ccccc3)c2)cc(-c2ccccc2)cc1-c1cccc(-c2ccccc2)c1 ; [2H]c1c([2H])c([2H])c2c(c1[2H])c1c([2H])c([2H])c([2H])c([2H])c1n2-c1ccc2c(c1)N(c1c(-c3cccc(-c4ccccc4)c3)cc(-c3ccccc3)cc1-c1cccc(-c3ccccc3)c1)c1cc(C(C)(C)C)cc3c1B2c1cc(-c2cc(-c4ccccc4)cc(-c4ccccc4)c2)ccc1N3c1c(-c2ccccc2)cc(-c2ccccc2)cc1-c1ccccc1]

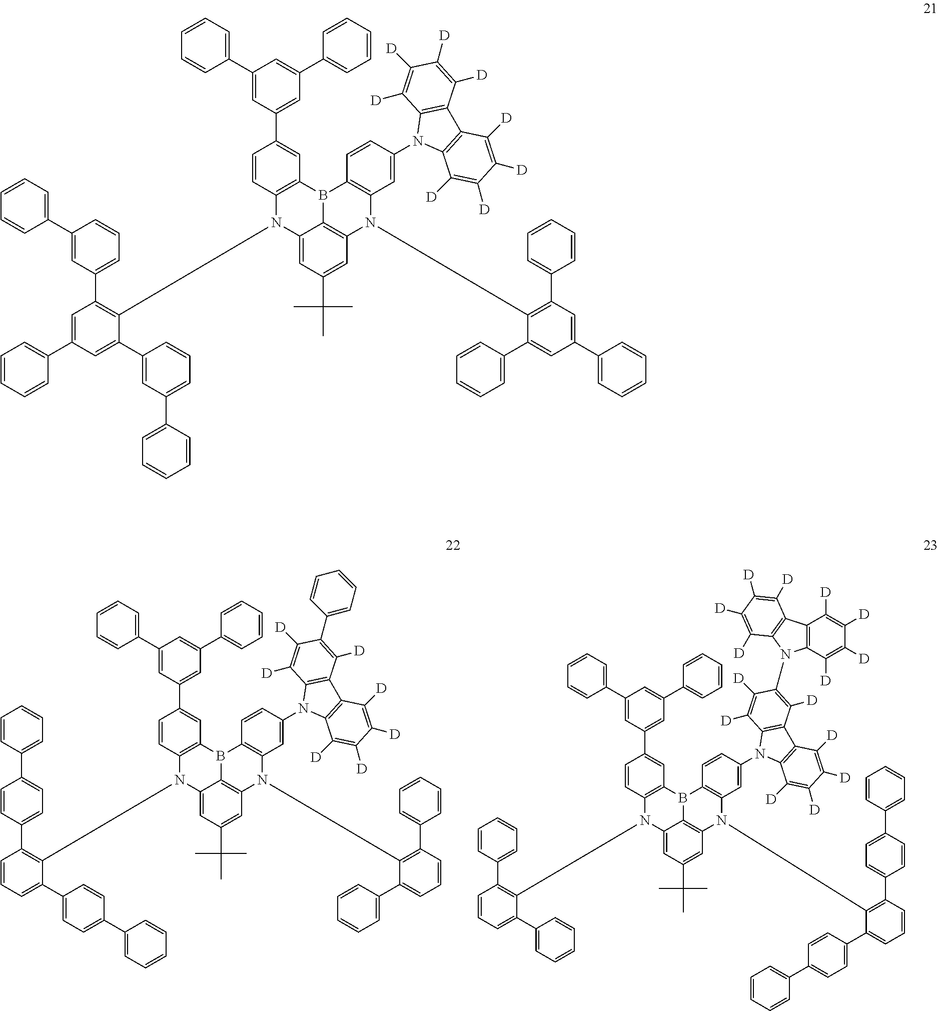

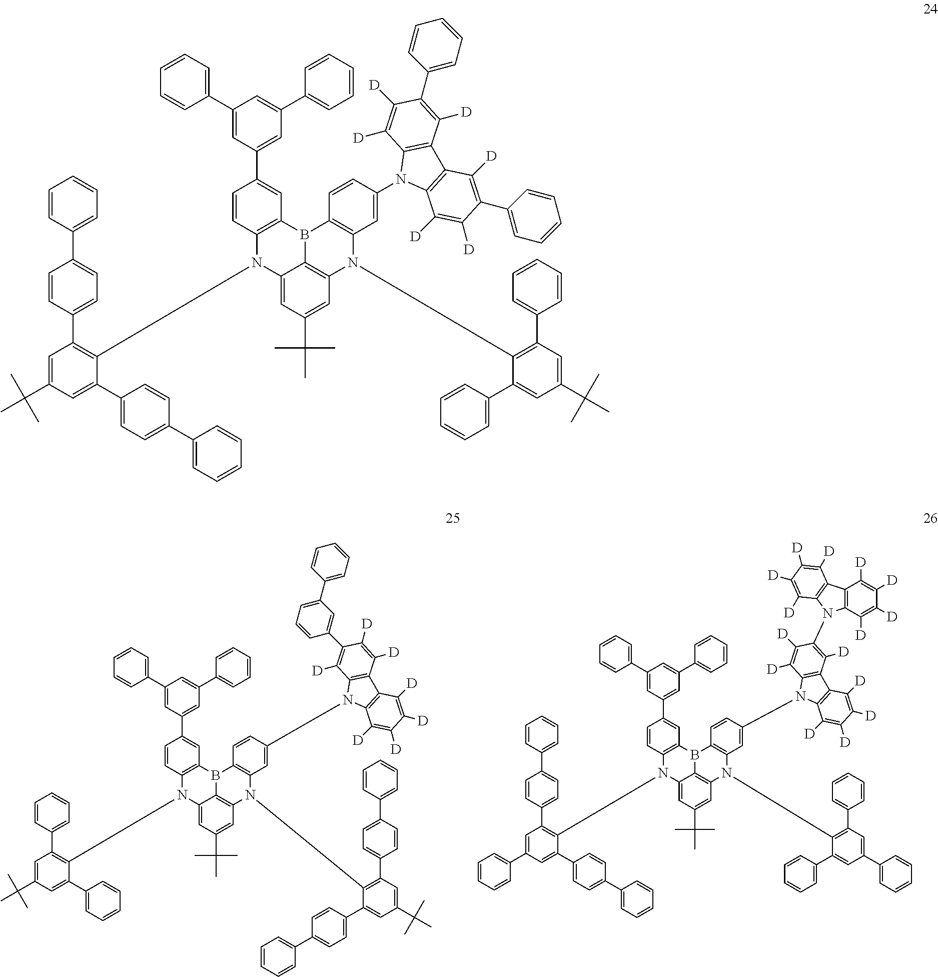

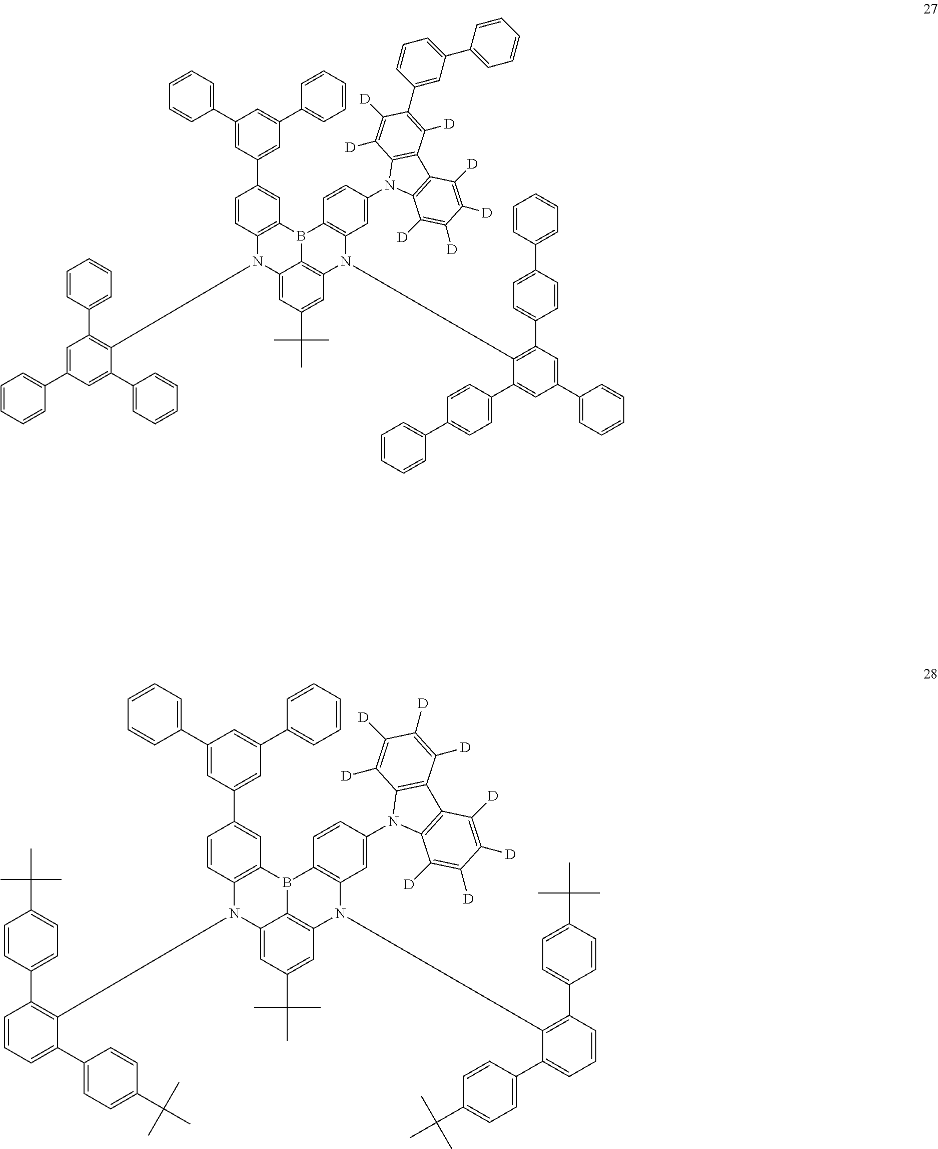

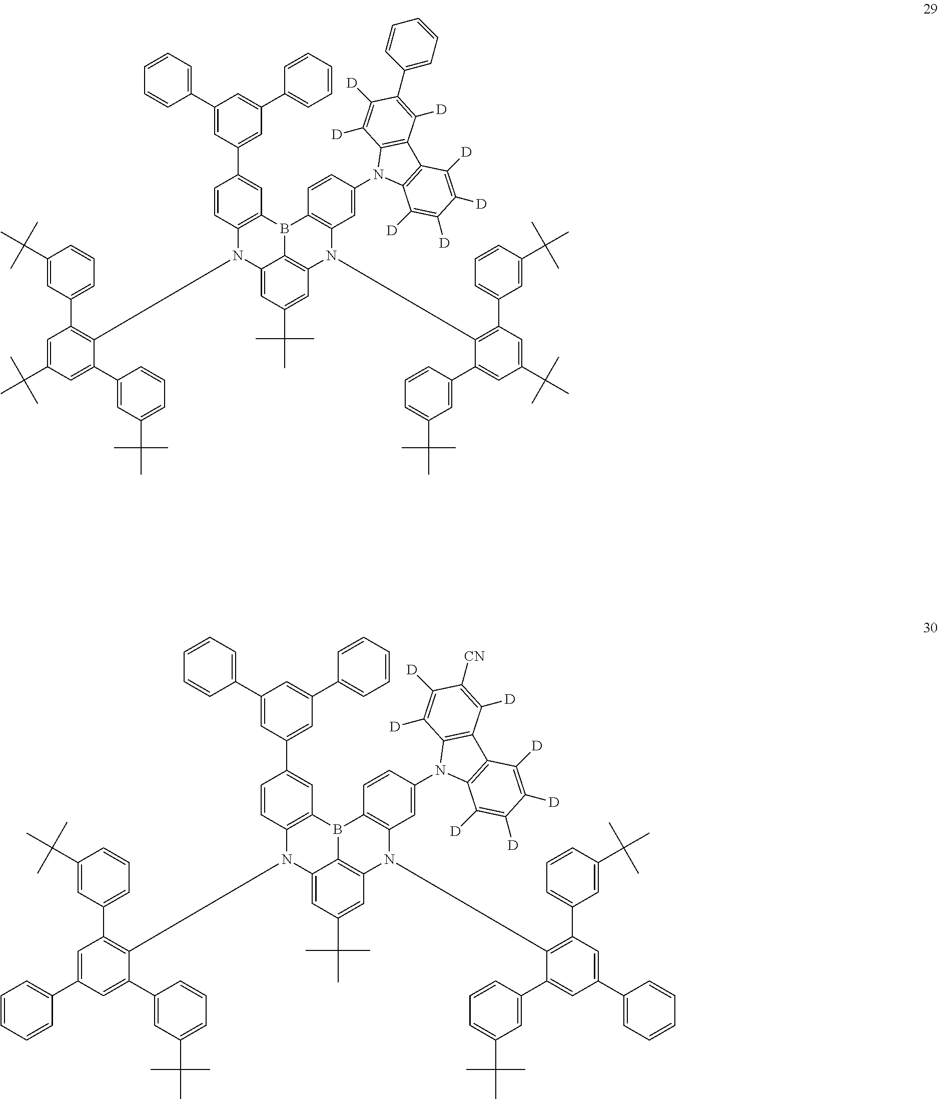

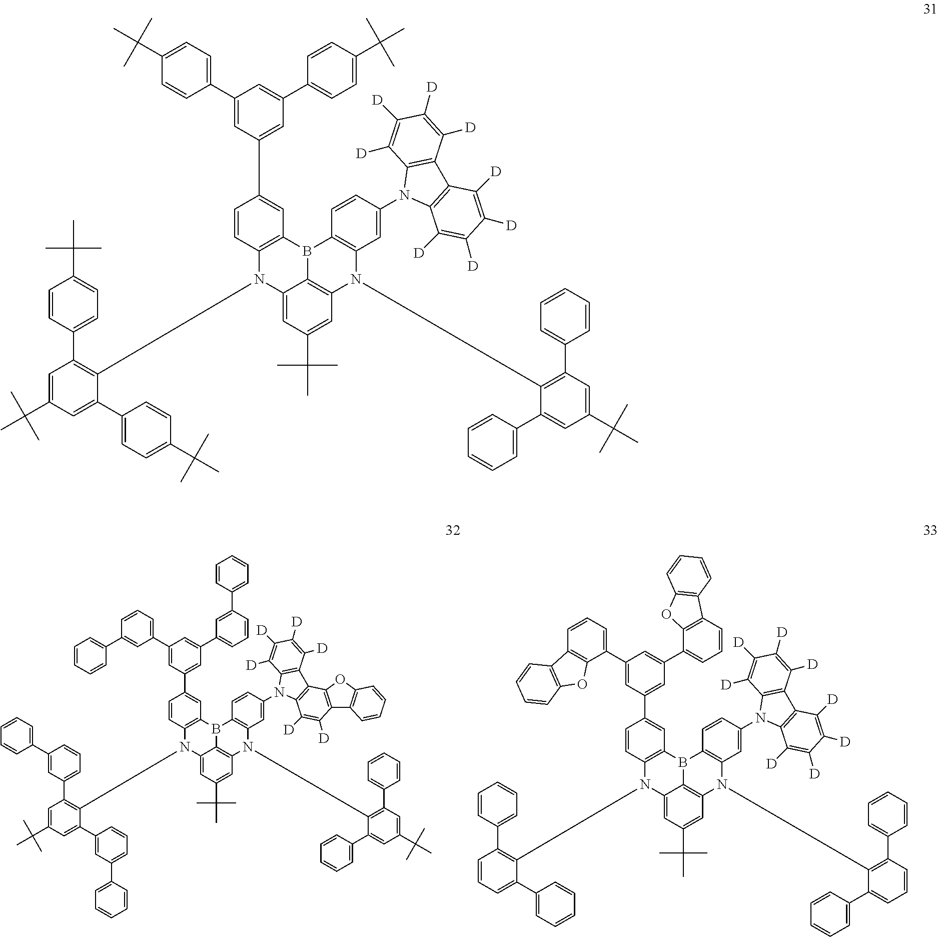

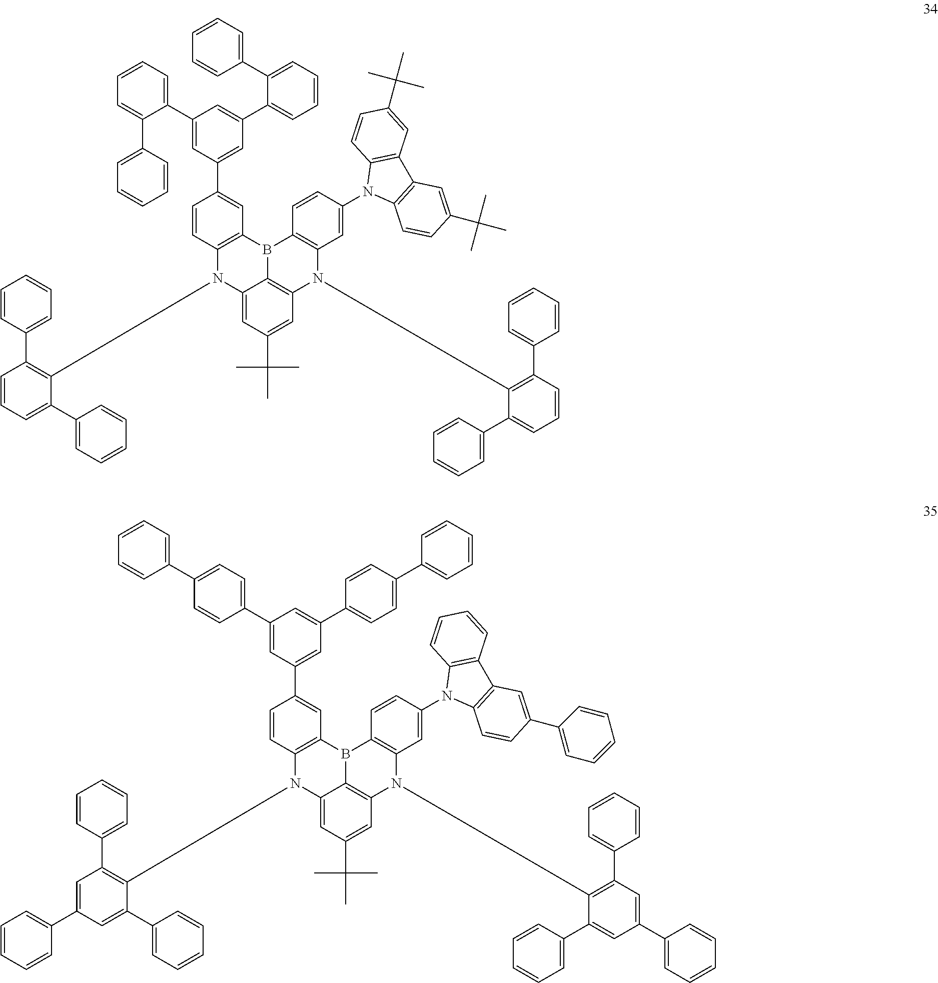 [SMILES: CC(C)(C)c1cc2c3c(c1)N(c1c(-c4ccccc4)cccc1-c1ccccc1)c1cc(-n4c5ccc(C(C)(C)C)cc5c5cc(C(C)(C)C)ccc54)ccc1B3c1cc(-c3cc(-c4ccccc4-c4ccccc4)cc(-c4ccccc4-c4ccccc4)c3)ccc1N2c1c(-c2ccccc2)cccc1-c1ccccc1 ; CC(C)(C)c1cc2c3c(c1)N(c1c(-c4ccccc4)cc(-c4ccccc4)cc1-c1ccccc1)c1cc(-n4c5ccccc5c5cc(-c6ccccc6)ccc54)ccc1B3c1cc(-c3cc(-c4ccc(-c5ccccc5)cc4)cc(-c4ccc(-c5ccccc5)cc4)c3)ccc1N2c1c(-c2ccccc2)cc(-c2ccccc2)cc1-c1ccccc1]

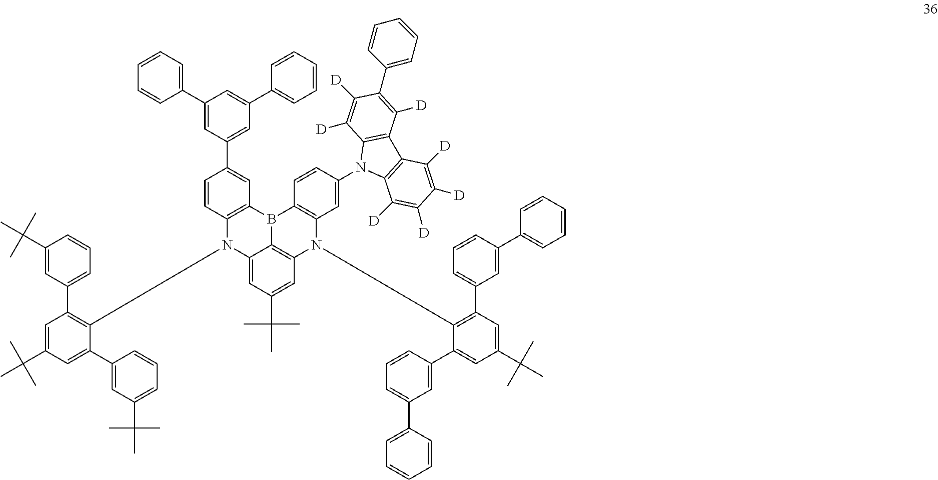 [SMILES: [2H]c1c([2H])c([2H])c2c(c1[2H])c1c([2H])c(-c3ccccc3)c([2H])c([2H])c1n2-c1ccc2c(c1)N(c1c(-c3cccc(-c4ccccc4)c3)cc(C(C)(C)C)cc1-c1cccc(-c3ccccc3)c1)c1cc(C(C)(C)C)cc3c1B2c1cc(-c2cc(-c4ccccc4)cc(-c4ccccc4)c2)ccc1N3c1c(-c2cccc(C(C)(C)C)c2)cc(C(C)(C)C)cc1-c1cccc(C(C)(C)C)c1]

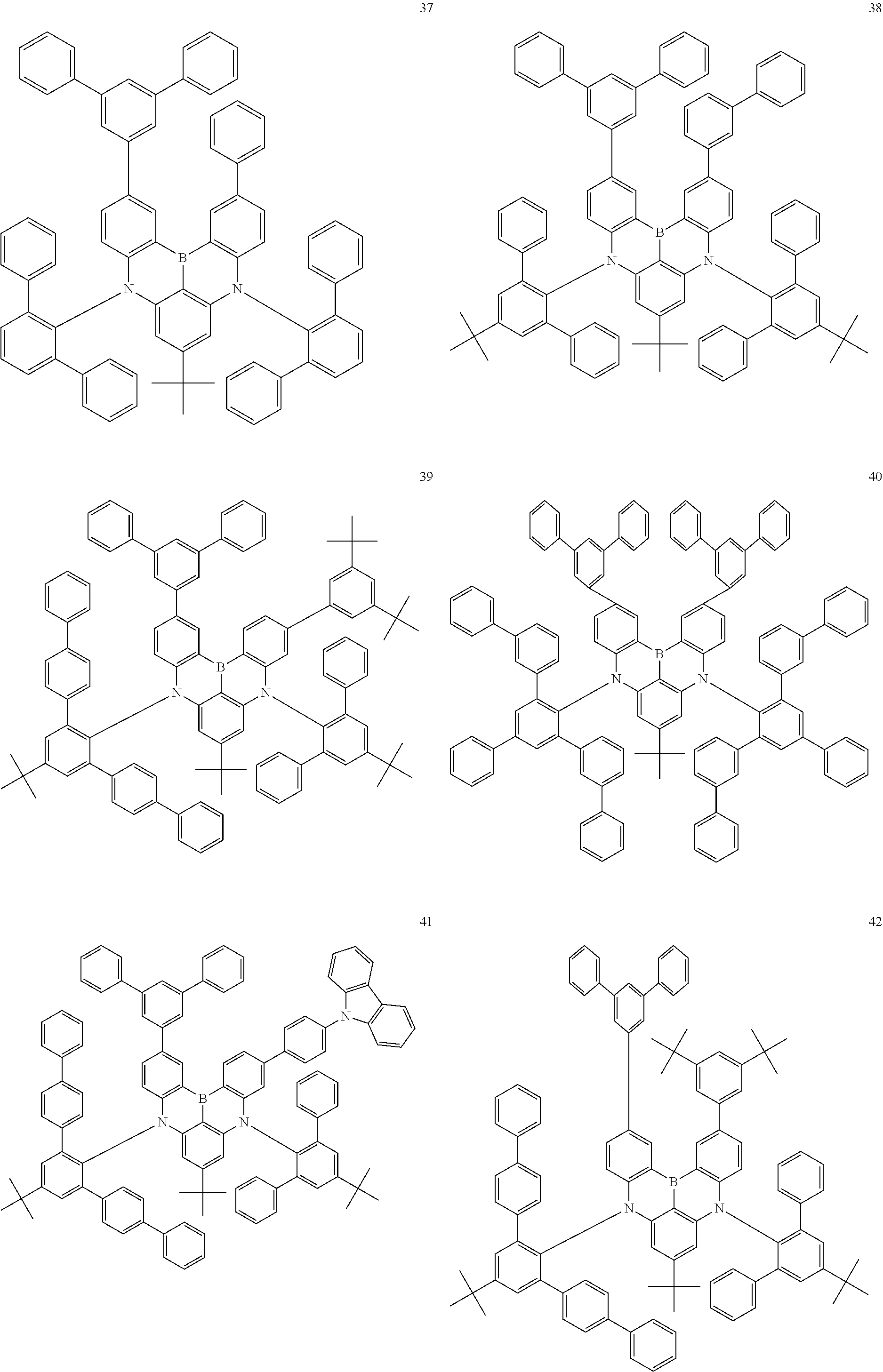

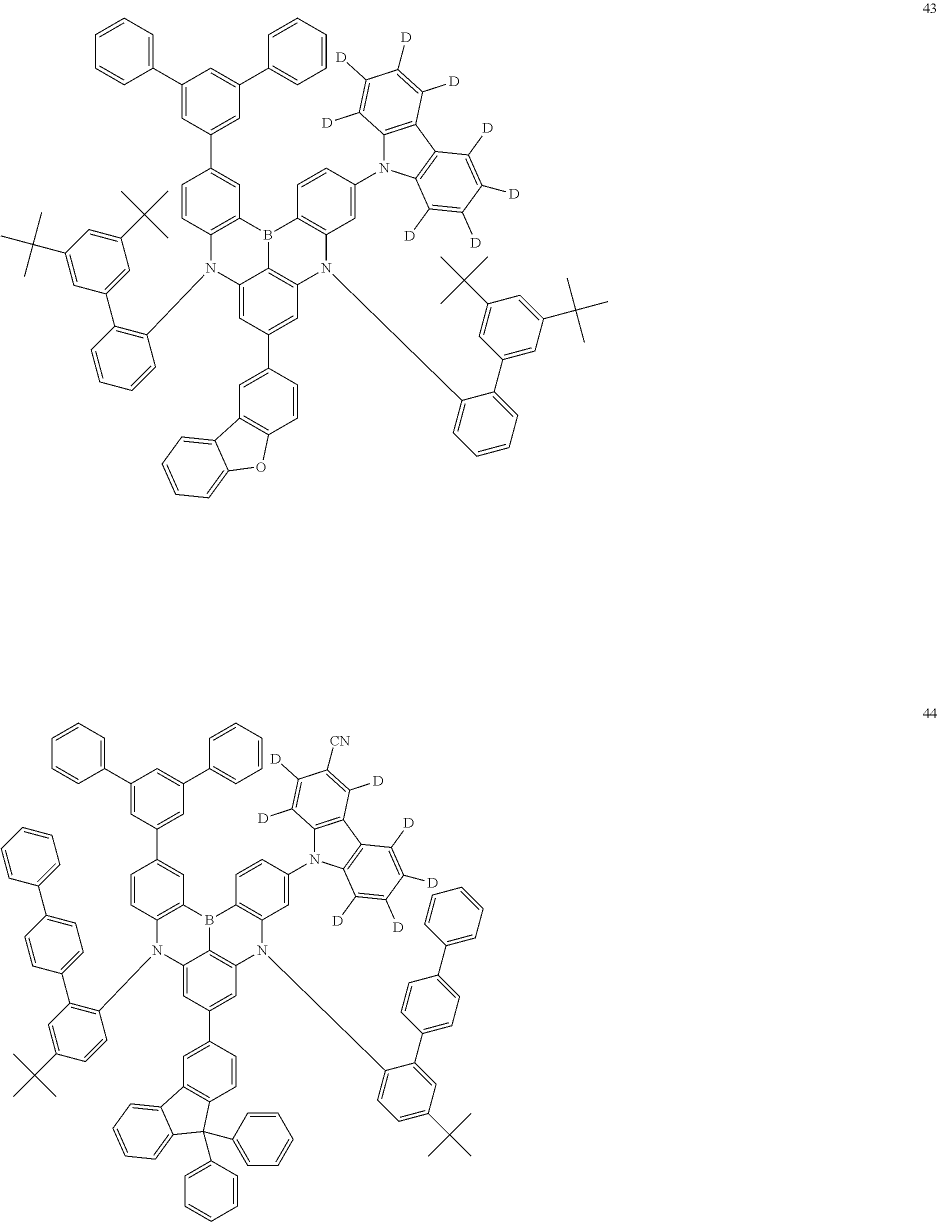 [SMILES: [2H]c1c([2H])c([2H])c2c(c1[2H])c1c([2H])c([2H])c([2H])c([2H])c1n2-c1ccc2c(c1)N(c1ccccc1-c1cc(C(C)(C)C)cc(C(C)(C)C)c1)c1cc(-c3ccc4oc5ccccc5c4c3)cc3c1B2c1cc(-c2cc(-c4ccccc4)cc(-c4ccccc4)c2)ccc1N3c1ccccc1-c1cc(C(C)(C)C)cc(C(C)(C)C)c1 ; [2H]c1c([2H])c([2H])c2c(c1[2H])c1c([2H])c(C#N)c([2H])c([2H])c1n2-c1ccc2c(c1)N(c1ccc(C(C)(C)C)cc1-c1ccc(-c3ccccc3)cc1)c1cc(-c3ccc4c(c3)-c3ccccc3C4(c3ccccc3)c3ccccc3)cc3c1B2c1cc(-c2cc(-c4ccccc4)cc(-c4ccccc4)c2)ccc1N3c1ccc(C(C)(C)C)cc1-c1ccc(-c2ccccc2)cc1]

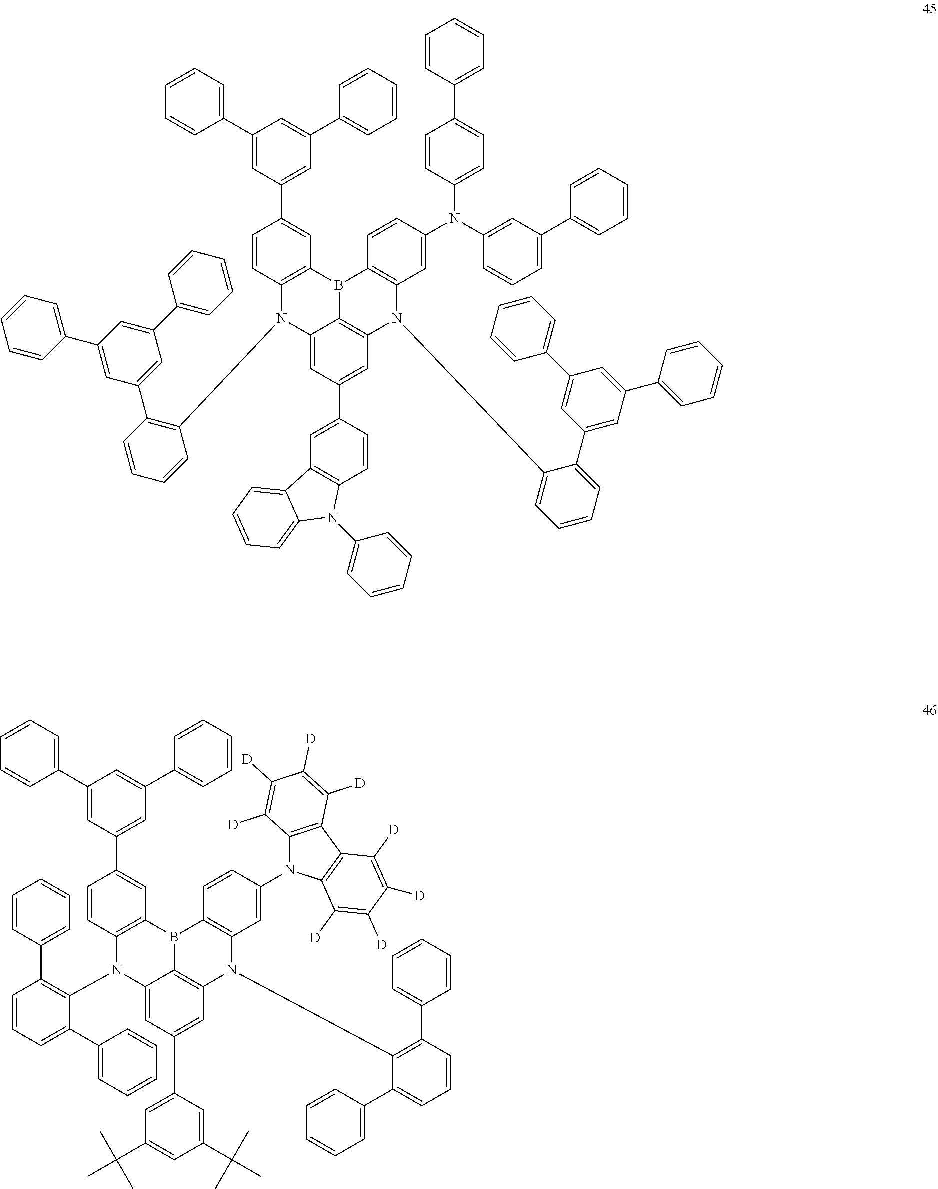 [SMILES: c1ccc(-c2ccc(N(c3cccc(-c4ccccc4)c3)c3ccc4c(c3)N(c3ccccc3-c3cc(-c5ccccc5)cc(-c5ccccc5)c3)c3cc(-c5ccc6c(c5)c5ccccc5n6-c5ccccc5)cc5c3B4c3cc(-c4cc(-c6ccccc6)cc(-c6ccccc6)c4)ccc3N5c3ccccc3-c3cc(-c4ccccc4)cc(-c4ccccc4)c3)cc2)cc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3cc(C(C)(C)C)cc(C(C)(C)C)c3)cc3c1B2c1cc(-c2cc(-c4ccccc4)cc(-c4ccccc4)c2)ccc1N3c1c(-c2ccccc2)cccc1-c1ccccc1]

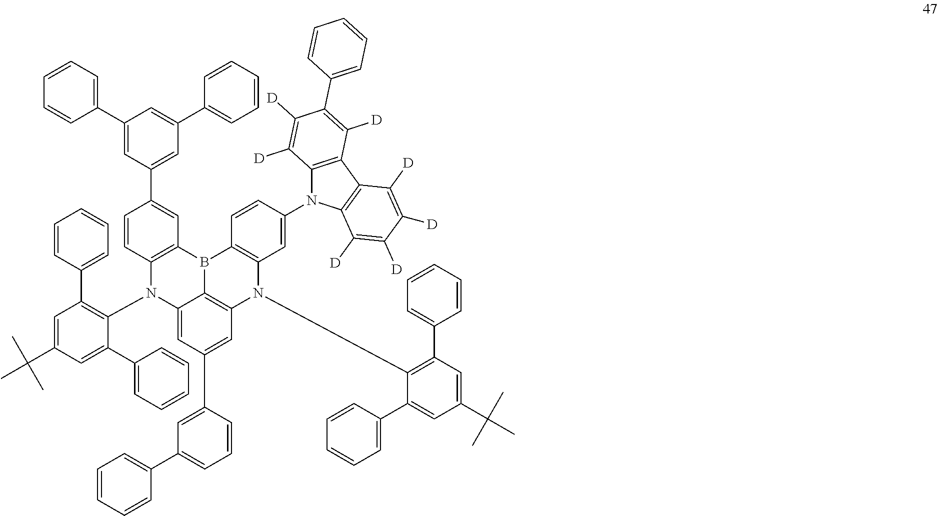 [SMILES: [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccccc1)c1cc(-c3cccc(-c4ccccc4)c3)cc3c1B2c1cc(-c2cc(-c4ccccc4)cc(-c4ccccc4)c2)ccc1N3c1c(-c2ccccc2)cc(C(C)(C)C)cc1-c1ccccc1]

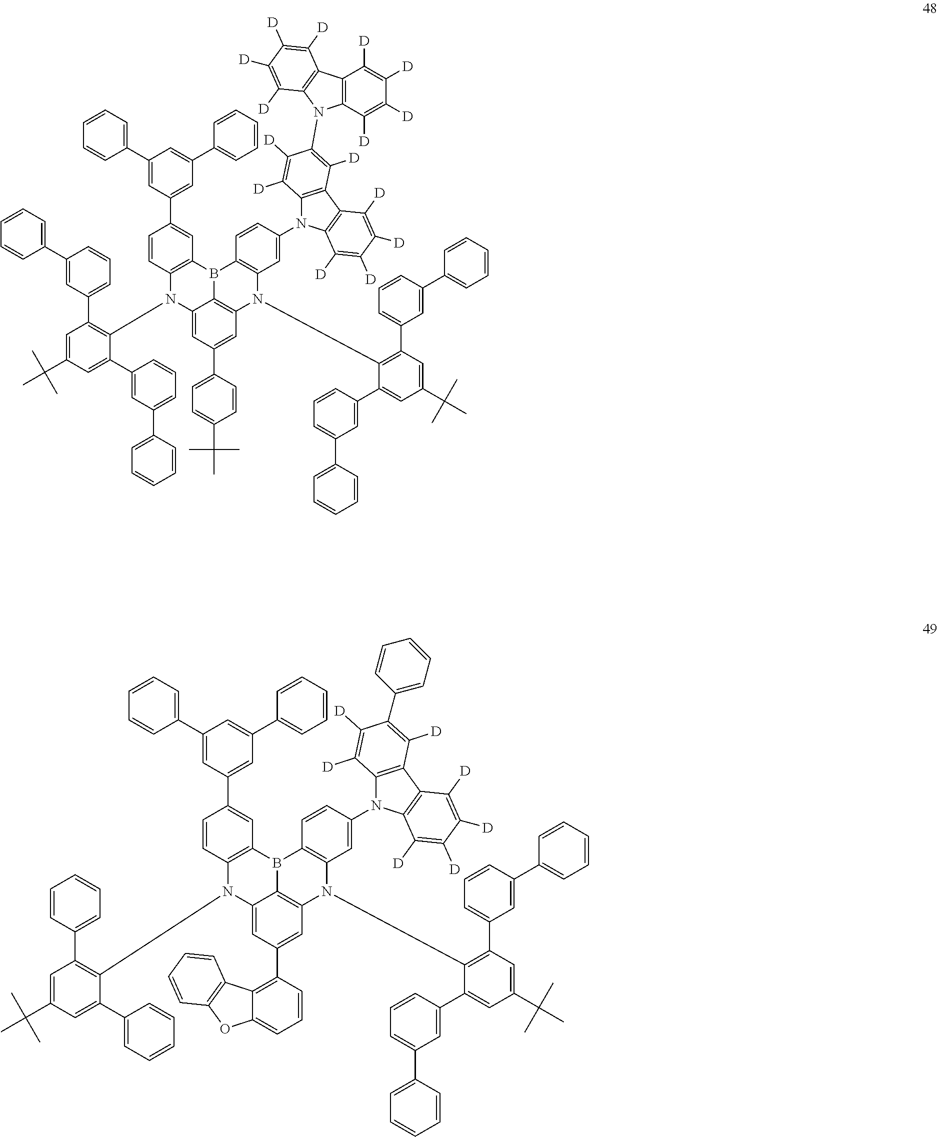

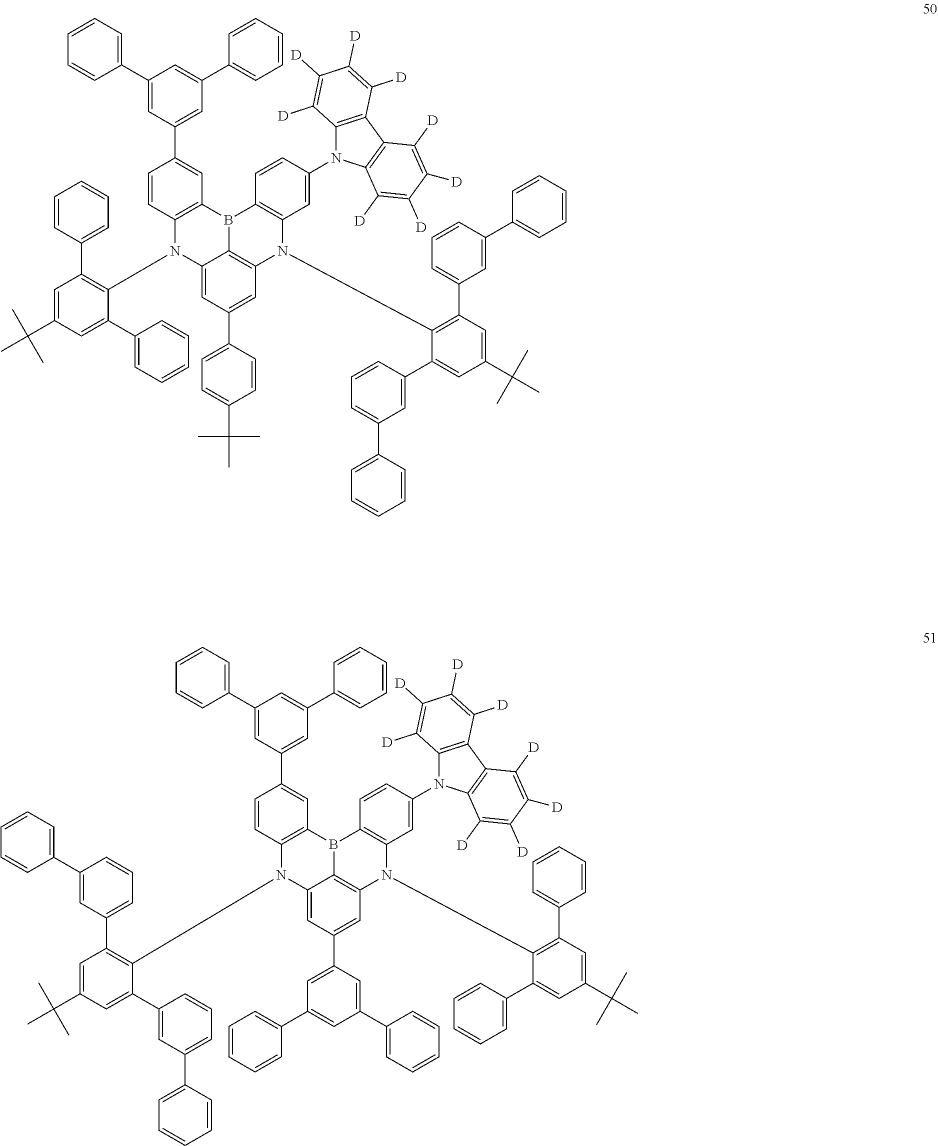

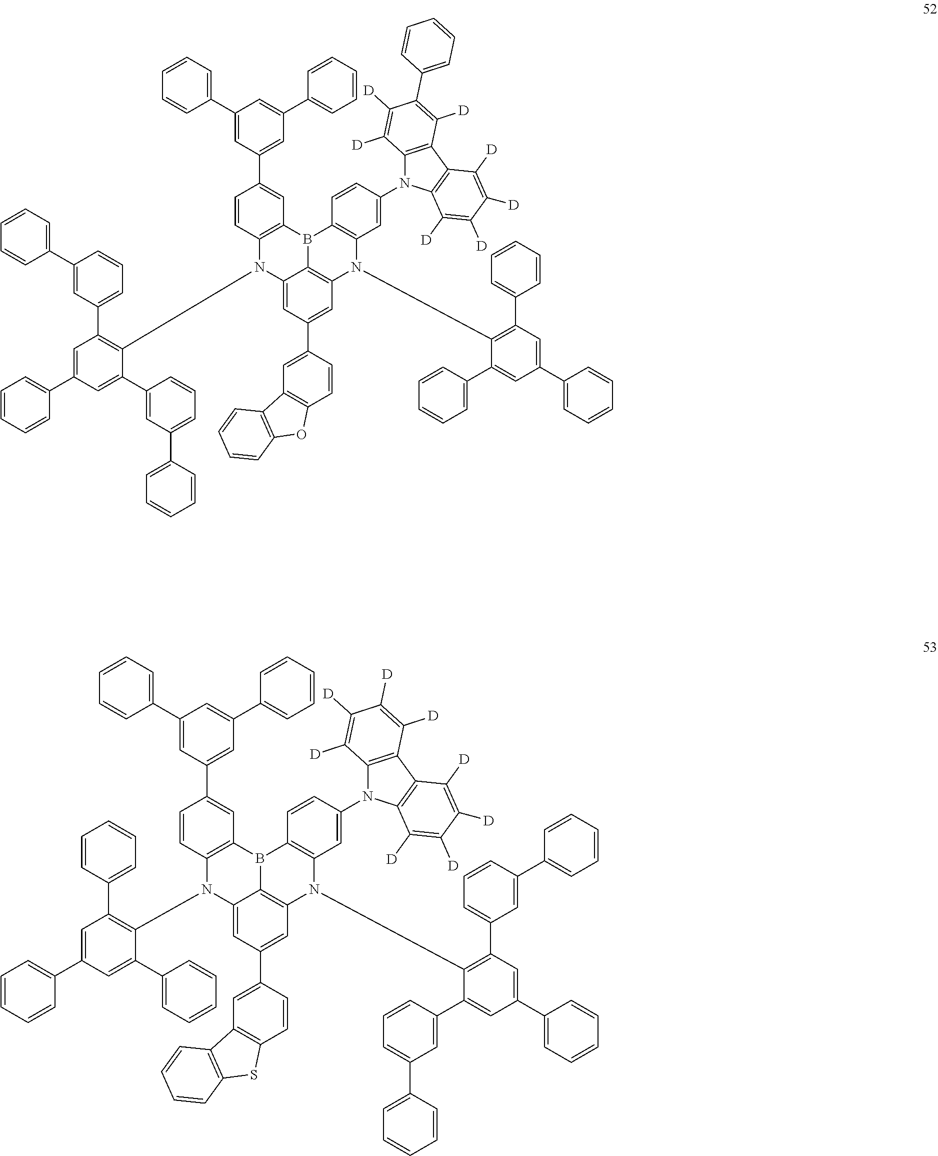

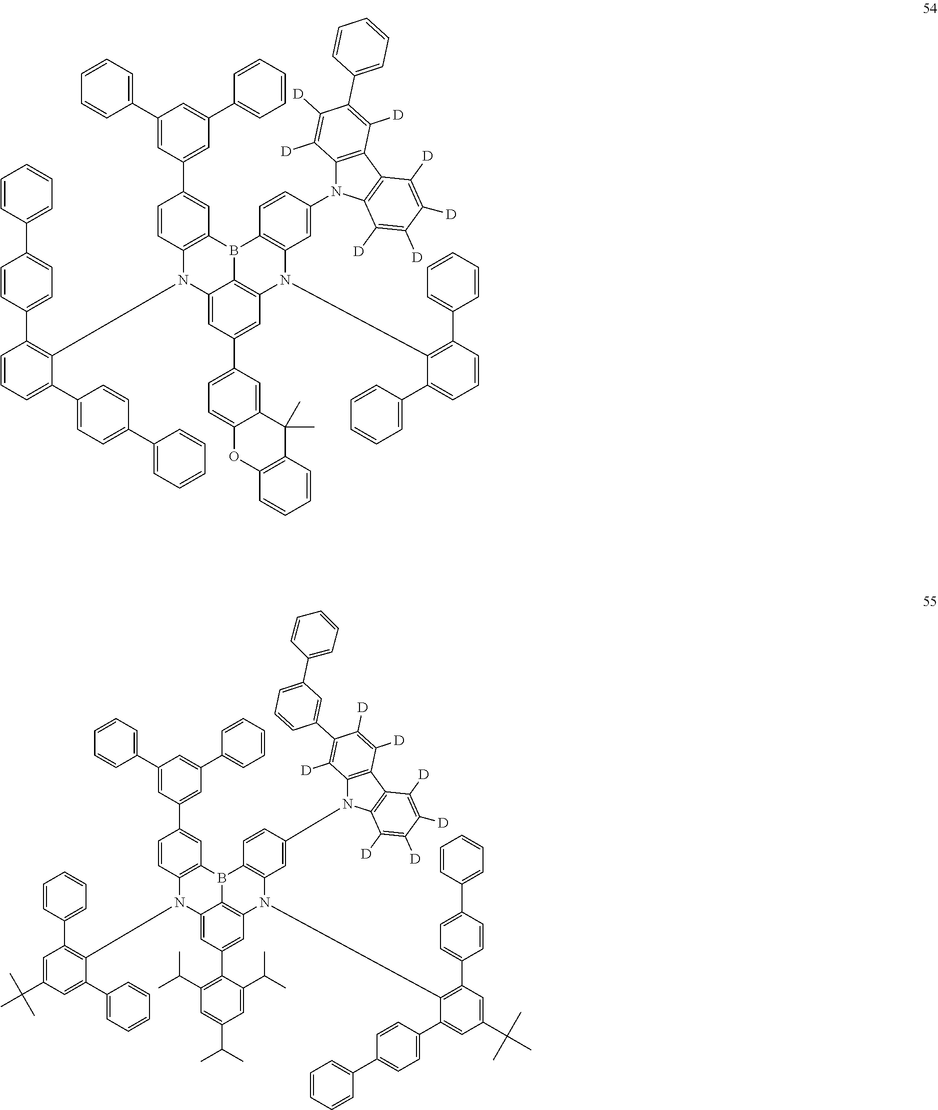

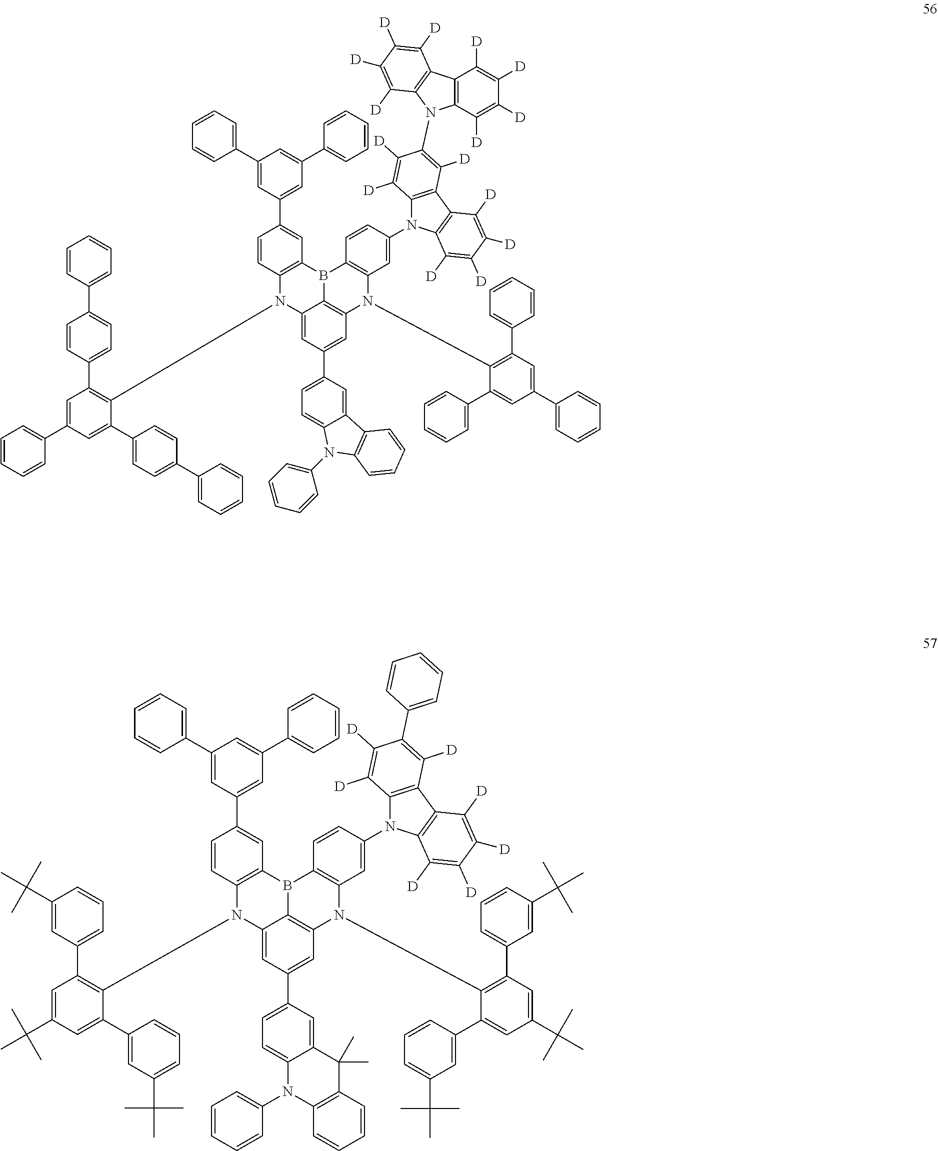

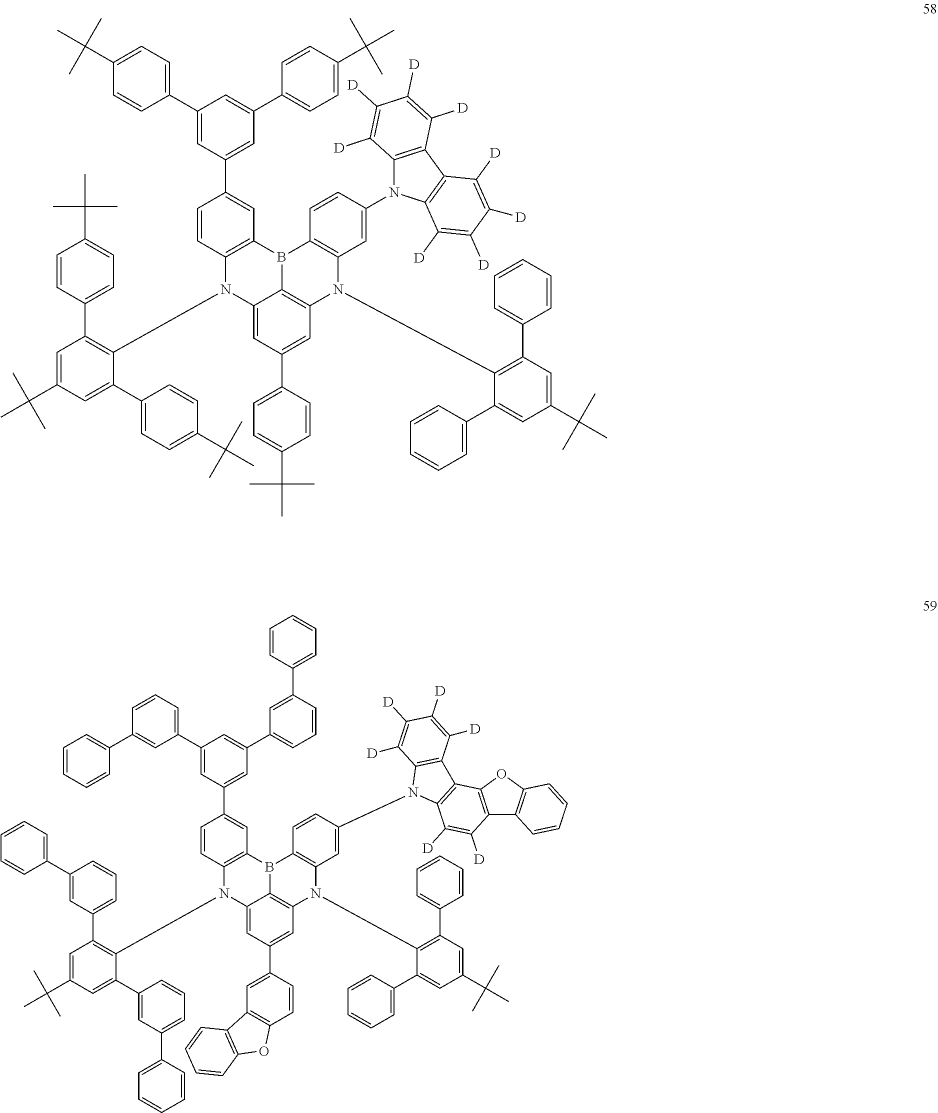

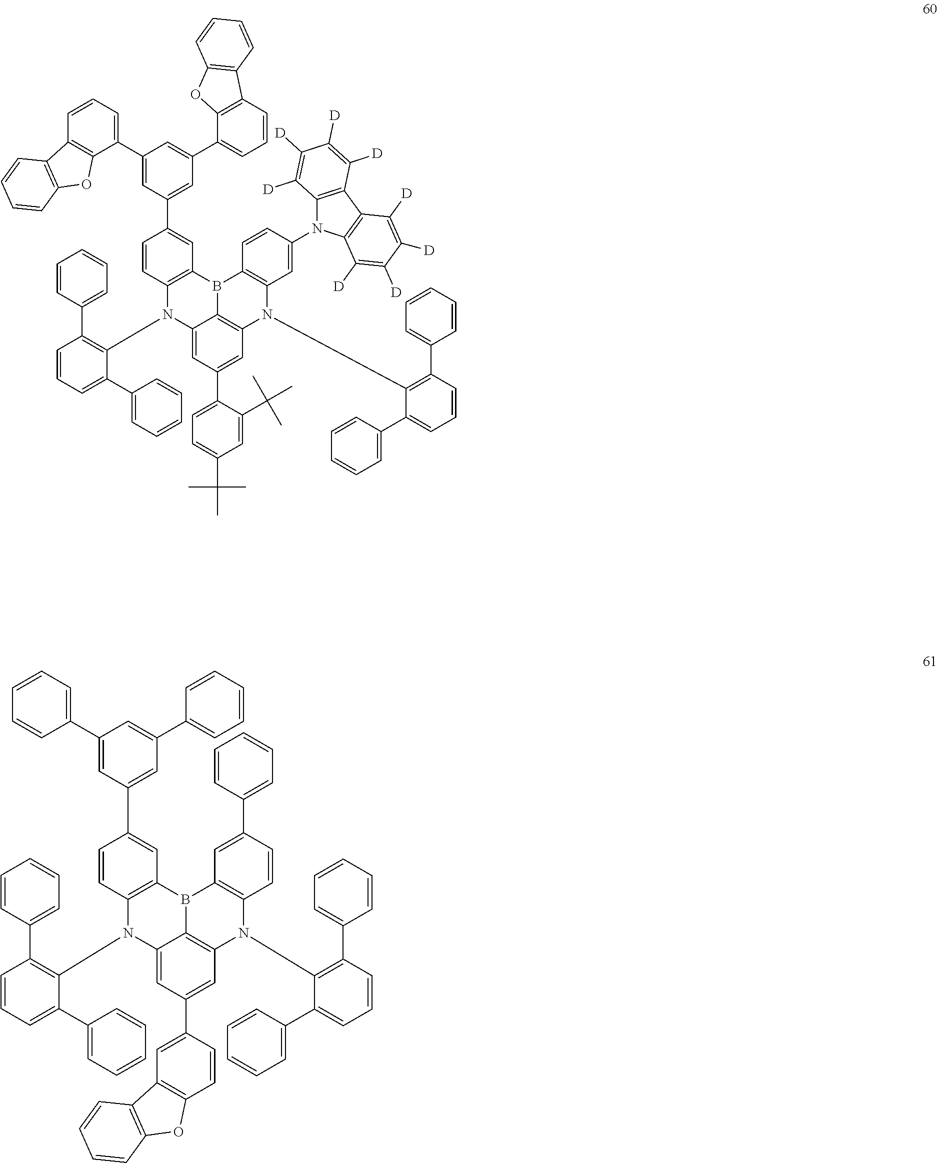 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc(C(C)(C)C)cc3C(C)(C)C)cc3c1B2c1cc(-c2cc(-c4cccc5c4oc4ccccc45)cc(-c4cccc5c4oc4ccccc45)c2)ccc1N3c1c(-c2ccccc2)cccc1-c1ccccc1 ; c1ccc(-c2cc(-c3ccccc3)cc(-c3ccc4c(c3)B3c5cc(-c6ccccc6)ccc5N(c5c(-c6ccccc6)cccc5-c5ccccc5)c5cc(-c6ccc7oc8ccccc8c7c6)cc(c53)N4c3c(-c4ccccc4)cccc3-c3ccccc3)c2)cc1]

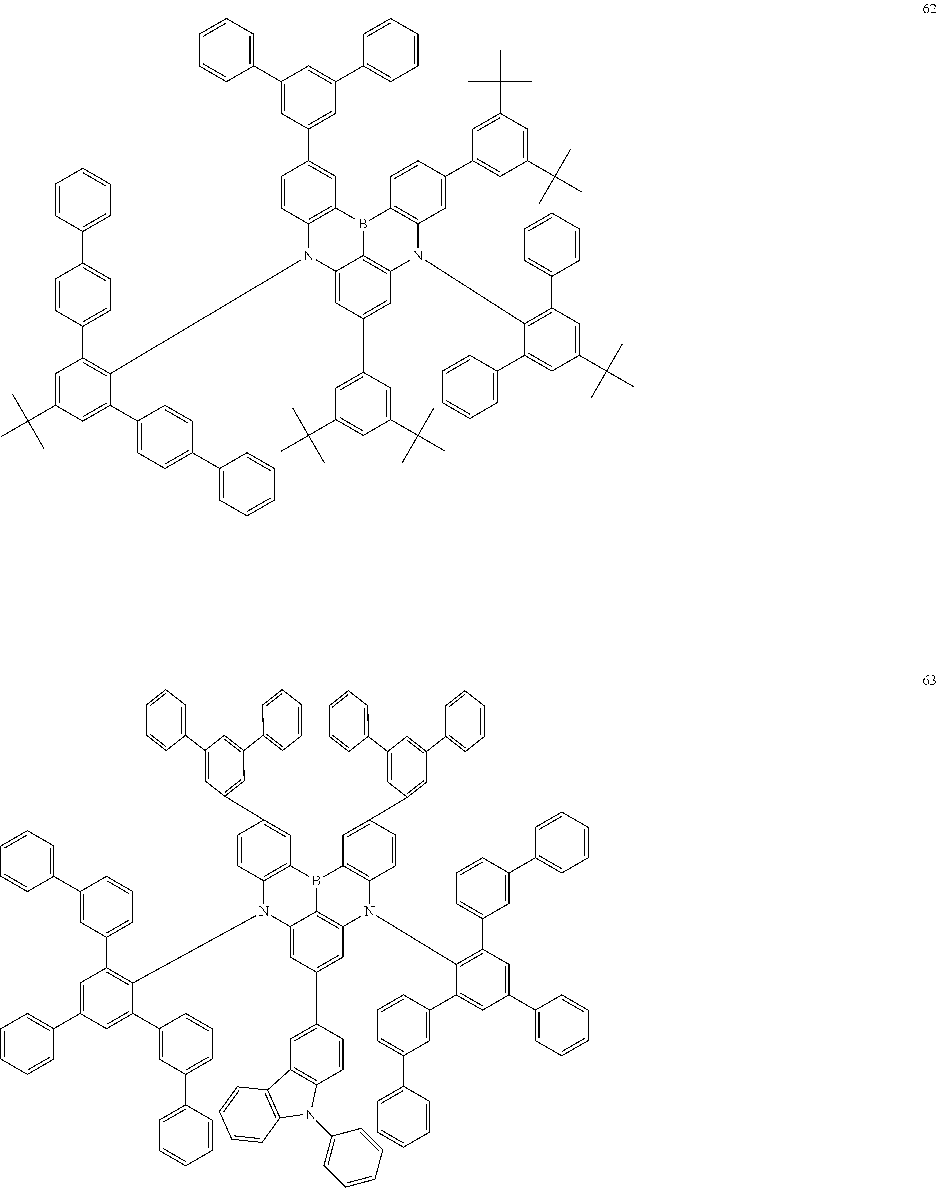 [SMILES: CC(C)(C)c1cc(-c2ccc3c(c2)N(c2c(-c4ccccc4)cc(C(C)(C)C)cc2-c2ccccc2)c2cc(-c4cc(C(C)(C)C)cc(C(C)(C)C)c4)cc4c2B3c2cc(-c3cc(-c5ccccc5)cc(-c5ccccc5)c3)ccc2N4c2c(-c3ccc(-c4ccccc4)cc3)cc(C(C)(C)C)cc2-c2ccc(-c3ccccc3)cc2)cc(C(C)(C)C)c1 ; c1ccc(-c2cc(-c3ccccc3)cc(-c3ccc4c(c3)B3c5cc(-c6cc(-c7ccccc7)cc(-c7ccccc7)c6)ccc5N(c5c(-c6cccc(-c7ccccc7)c6)cc(-c6ccccc6)cc5-c5cccc(-c6ccccc6)c5)c5cc(-c6ccc7c(c6)c6ccccc6n7-c6ccccc6)cc(c53)N4c3c(-c4cccc(-c5ccccc5)c4)cc(-c4ccccc4)cc3-c3cccc(-c4ccccc4)c3)c2)cc1]

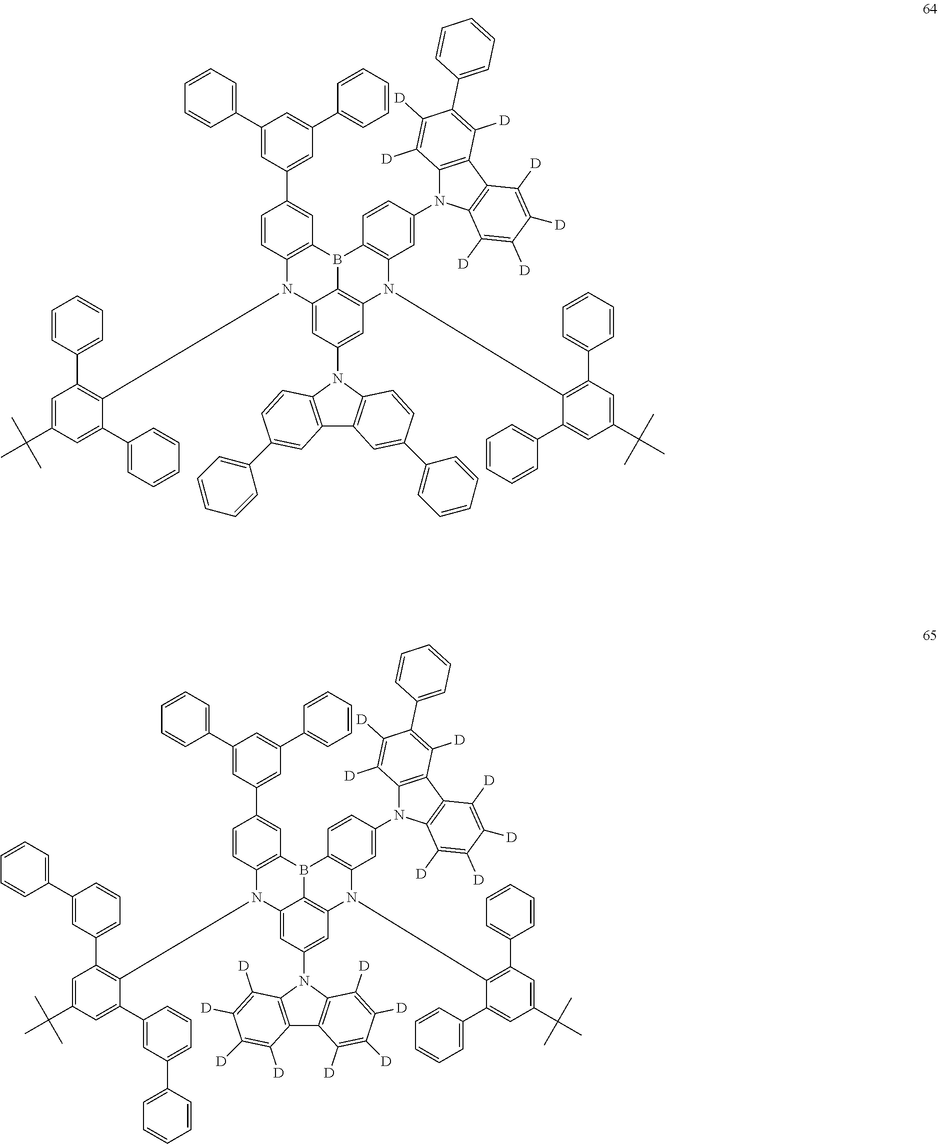

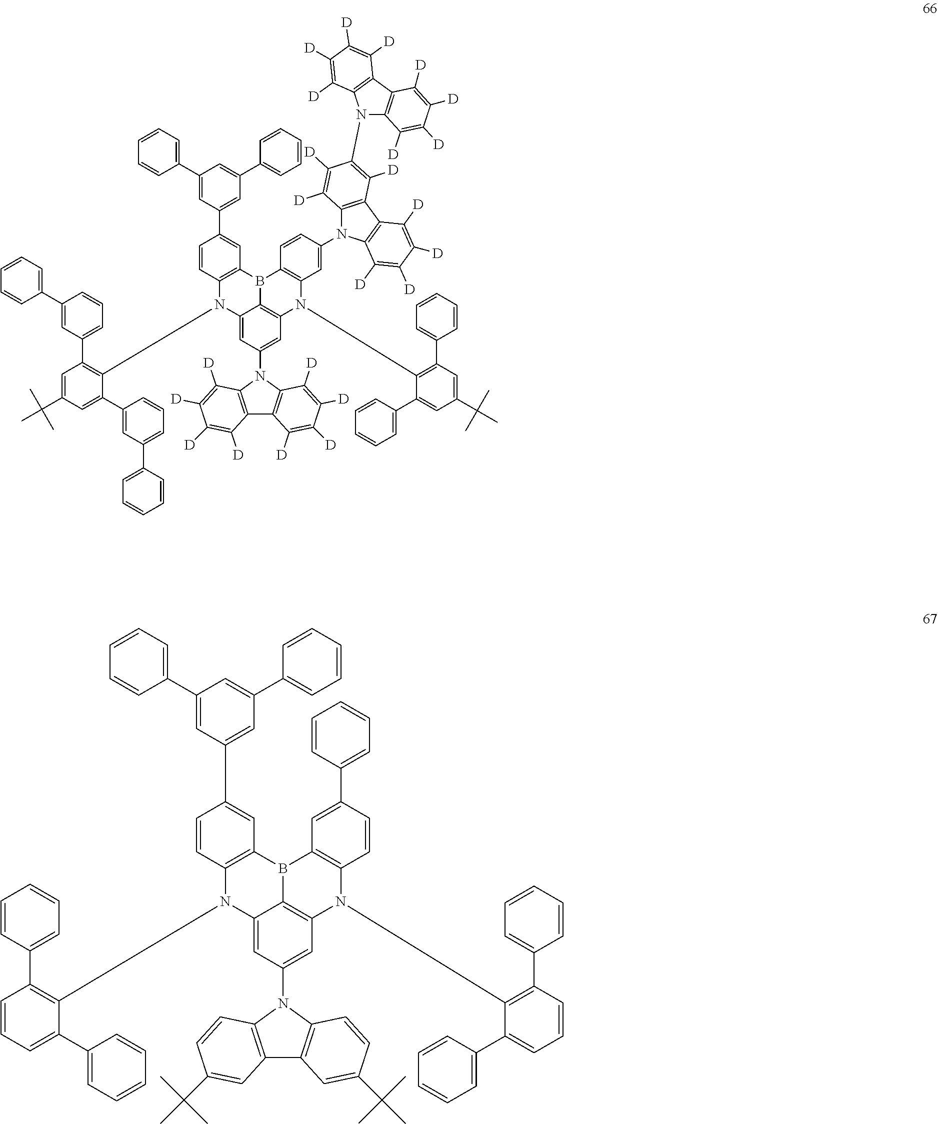

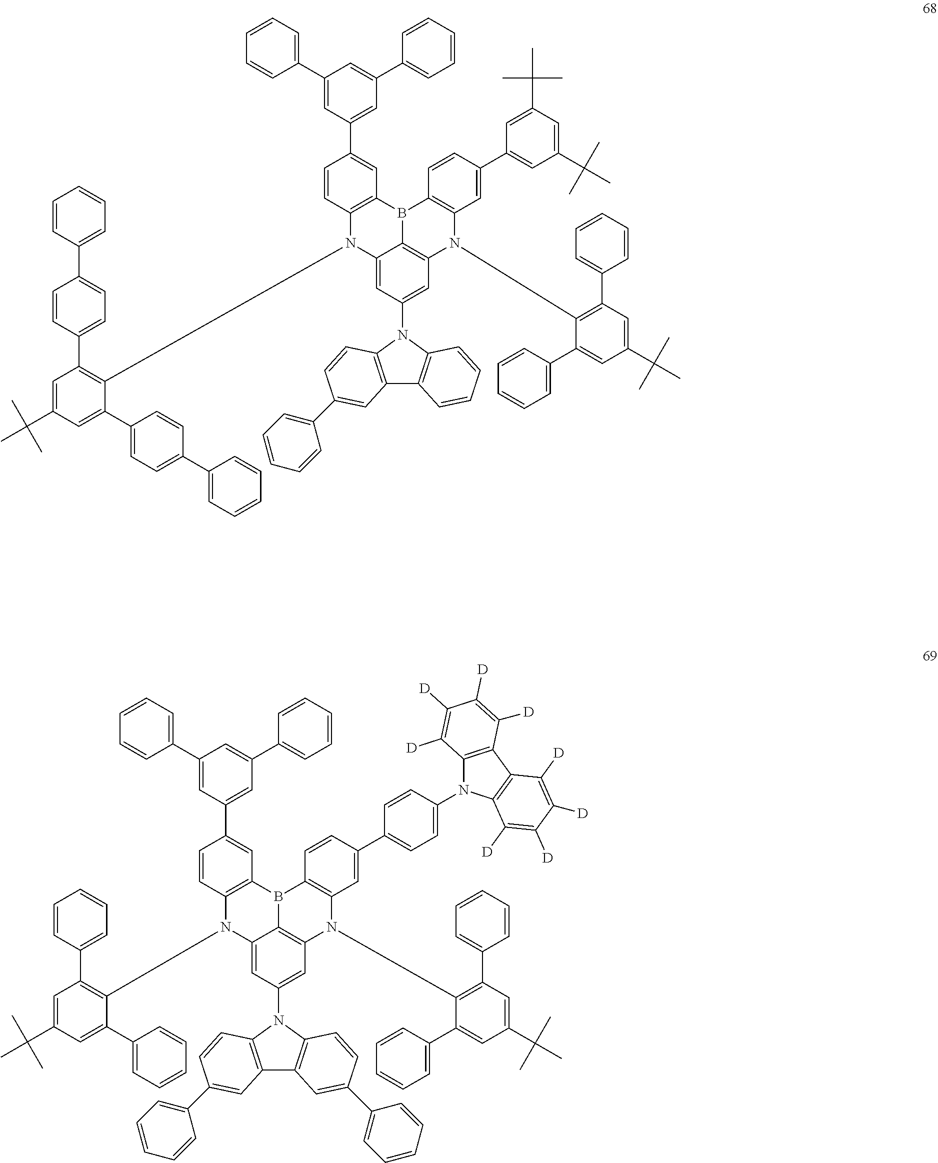

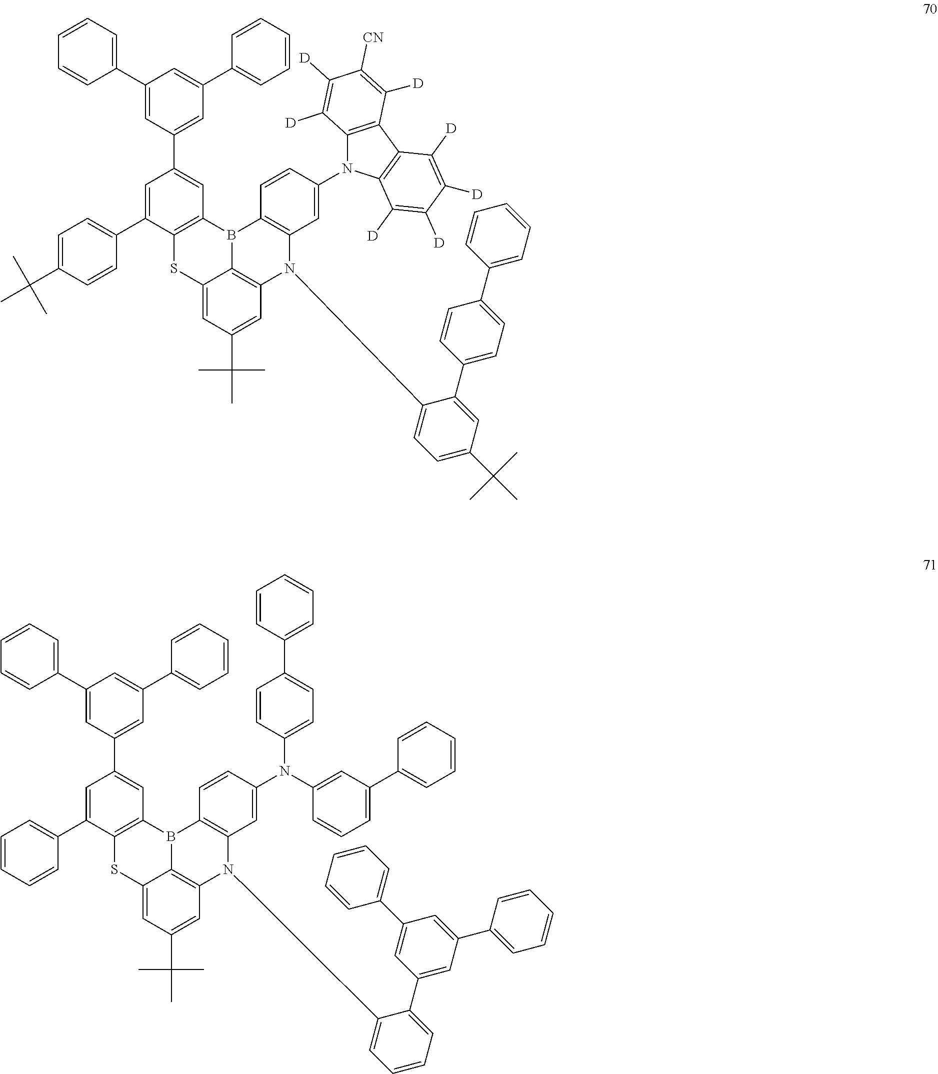 [SMILES: [2H]c1c([2H])c([2H])c2c(c1[2H])c1c([2H])c(C#N)c([2H])c([2H])c1n2-c1ccc2c(c1)N(c1ccc(C(C)(C)C)cc1-c1ccc(-c3ccccc3)cc1)c1cc(C(C)(C)C)cc3c1B2c1cc(-c2cc(-c4ccccc4)cc(-c4ccccc4)c2)cc(-c2ccc(C(C)(C)C)cc2)c1S3 ; CC(C)(C)c1cc2c3c(c1)N(c1ccccc1-c1cc(-c4ccccc4)cc(-c4ccccc4)c1)c1cc(N(c4ccc(-c5ccccc5)cc4)c4cccc(-c5ccccc5)c4)ccc1B3c1cc(-c3cc(-c4ccccc4)cc(-c4ccccc4)c3)cc(-c3ccccc3)c1S2]

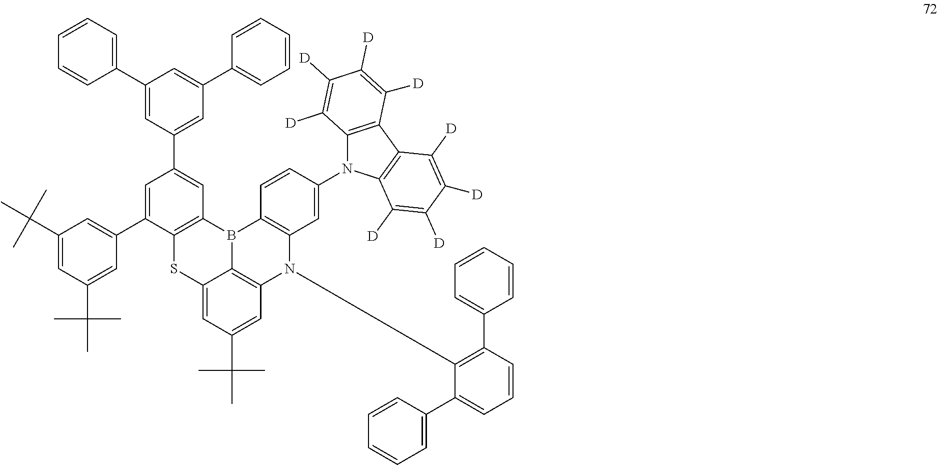 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1cc(-c2cc(-c4ccccc4)cc(-c4ccccc4)c2)cc(-c2cc(C(C)(C)C)cc(C(C)(C)C)c2)c1S3]

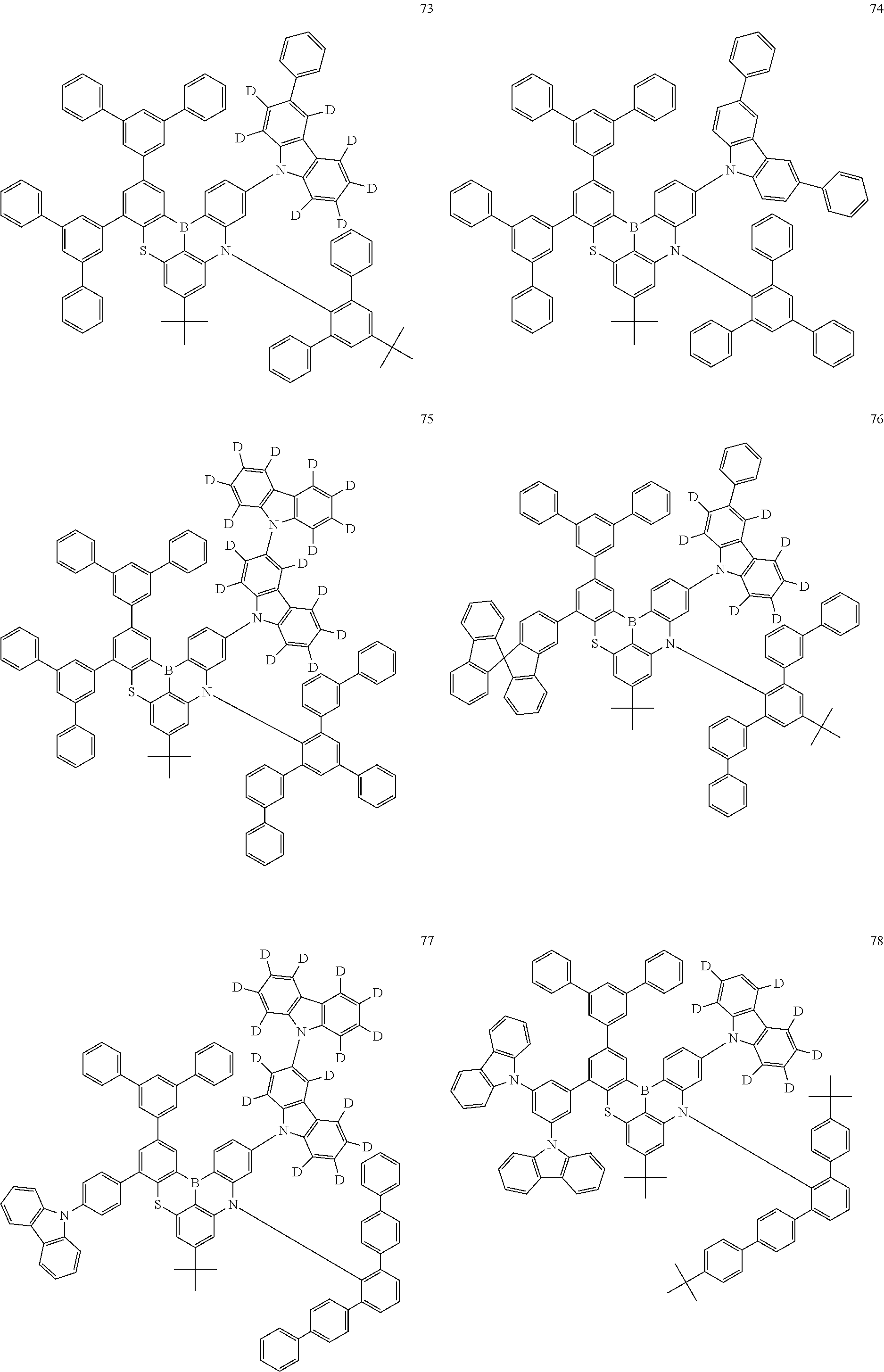

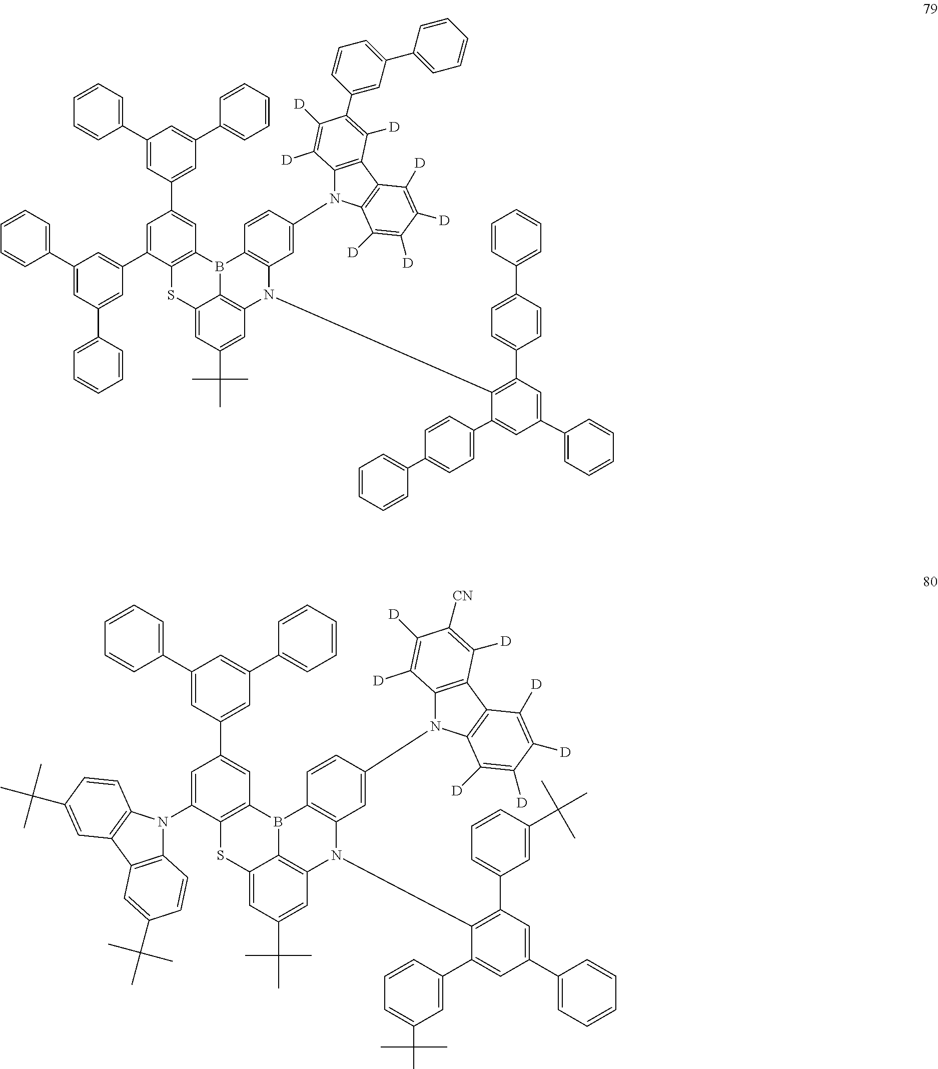

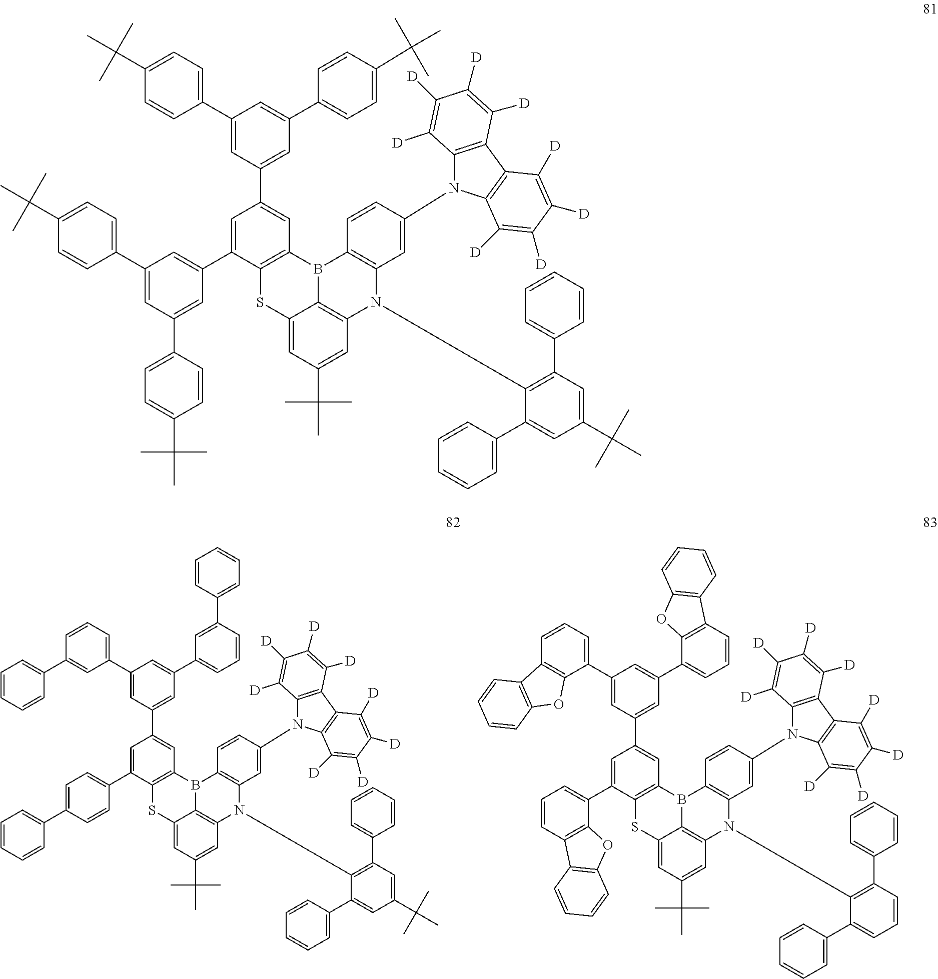

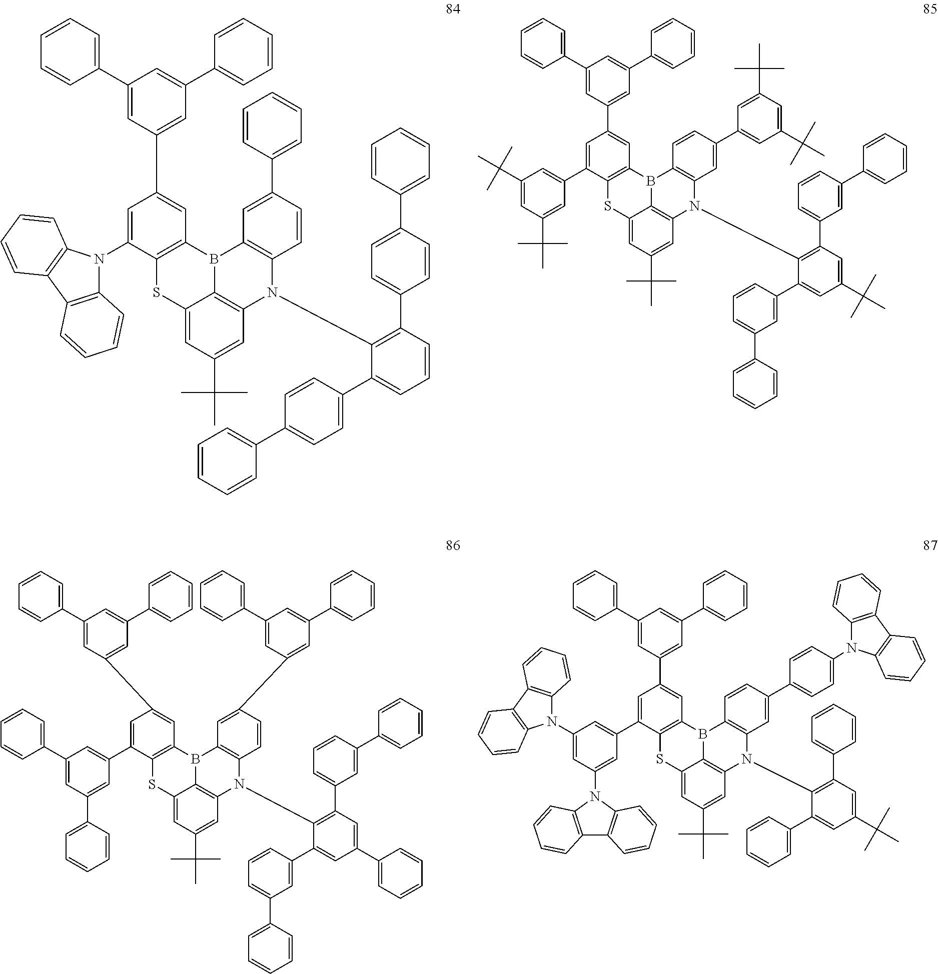

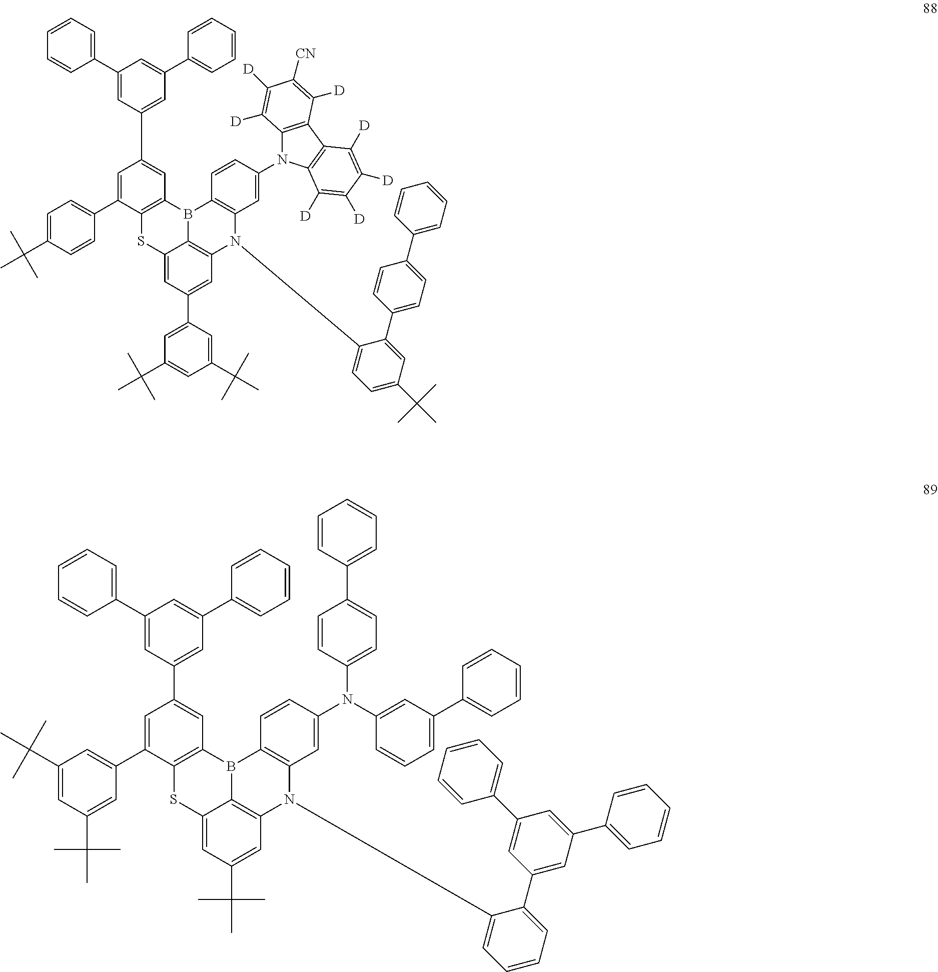 [SMILES: [2H]c1c([2H])c([2H])c2c(c1[2H])c1c([2H])c(C#N)c([2H])c([2H])c1n2-c1ccc2c(c1)N(c1ccc(C(C)(C)C)cc1-c1ccc(-c3ccccc3)cc1)c1cc(-c3cc(C(C)(C)C)cc(C(C)(C)C)c3)cc3c1B2c1cc(-c2cc(-c4ccccc4)cc(-c4ccccc4)c2)cc(-c2ccc(C(C)(C)C)cc2)c1S3 ; CC(C)(C)c1cc(-c2cc(-c3cc(-c4ccccc4)cc(-c4ccccc4)c3)cc3c2Sc2cc(C(C)(C)C)cc4c2B3c2ccc(N(c3ccc(-c5ccccc5)cc3)c3cccc(-c5ccccc5)c3)cc2N4c2ccccc2-c2cc(-c3ccccc3)cc(-c3ccccc3)c2)cc(C(C)(C)C)c1]

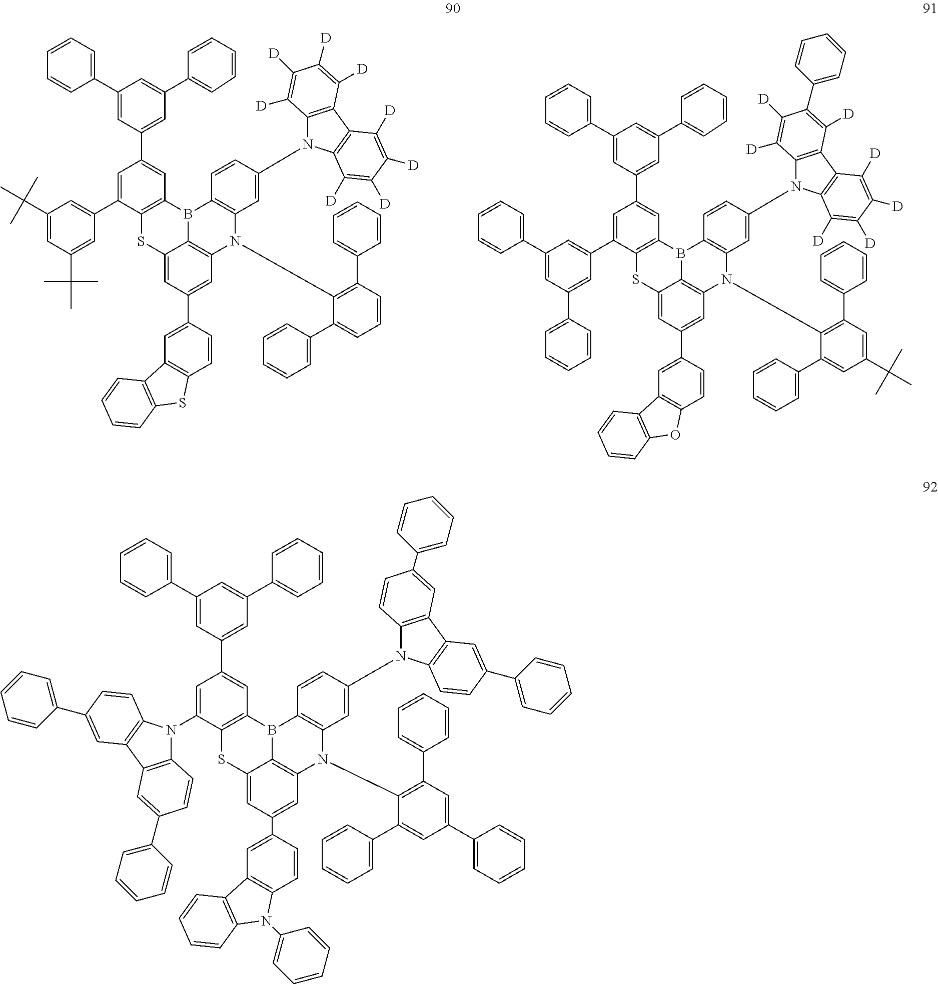

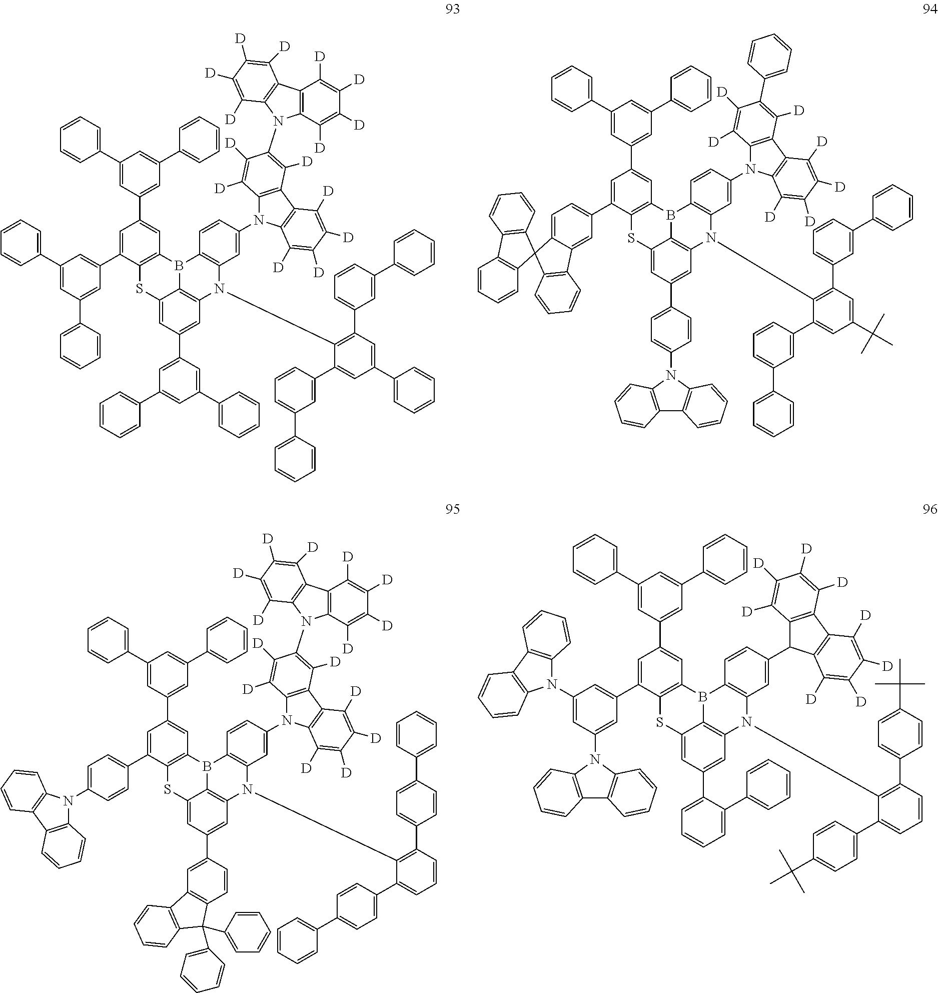

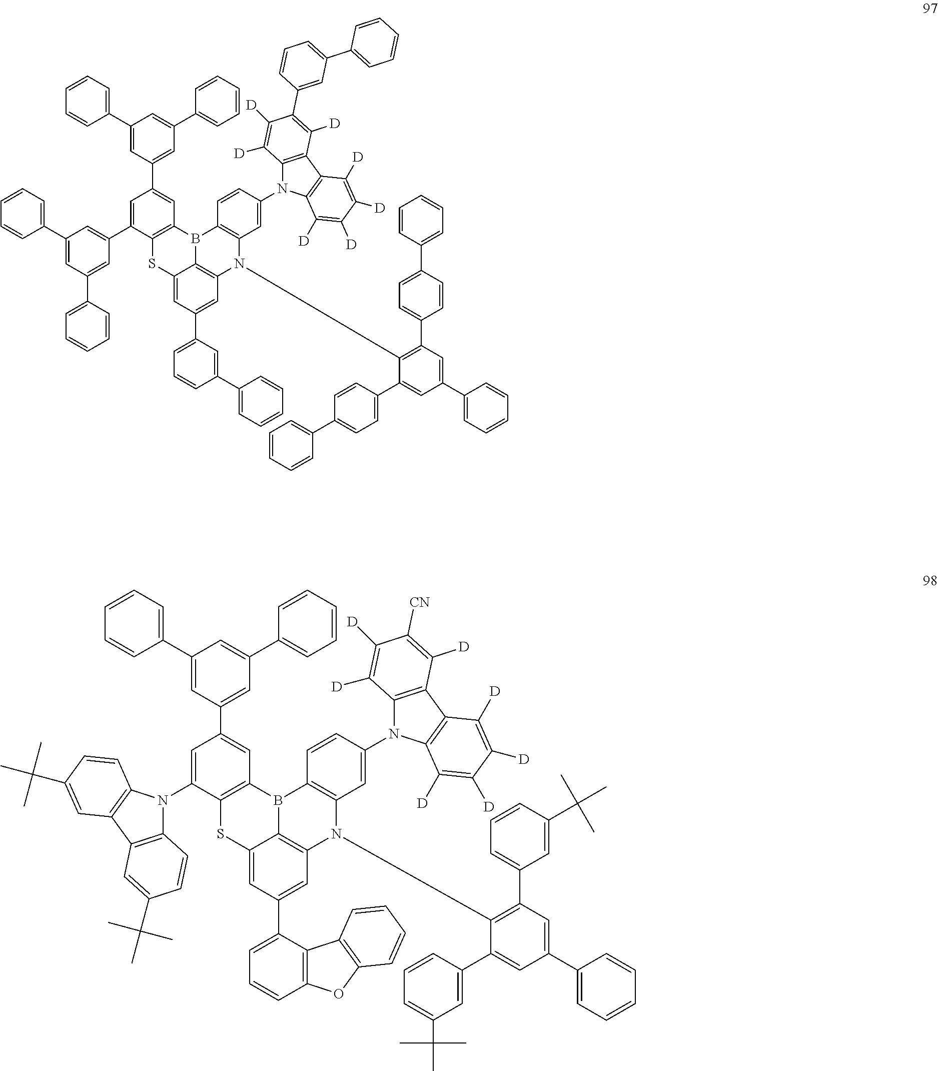

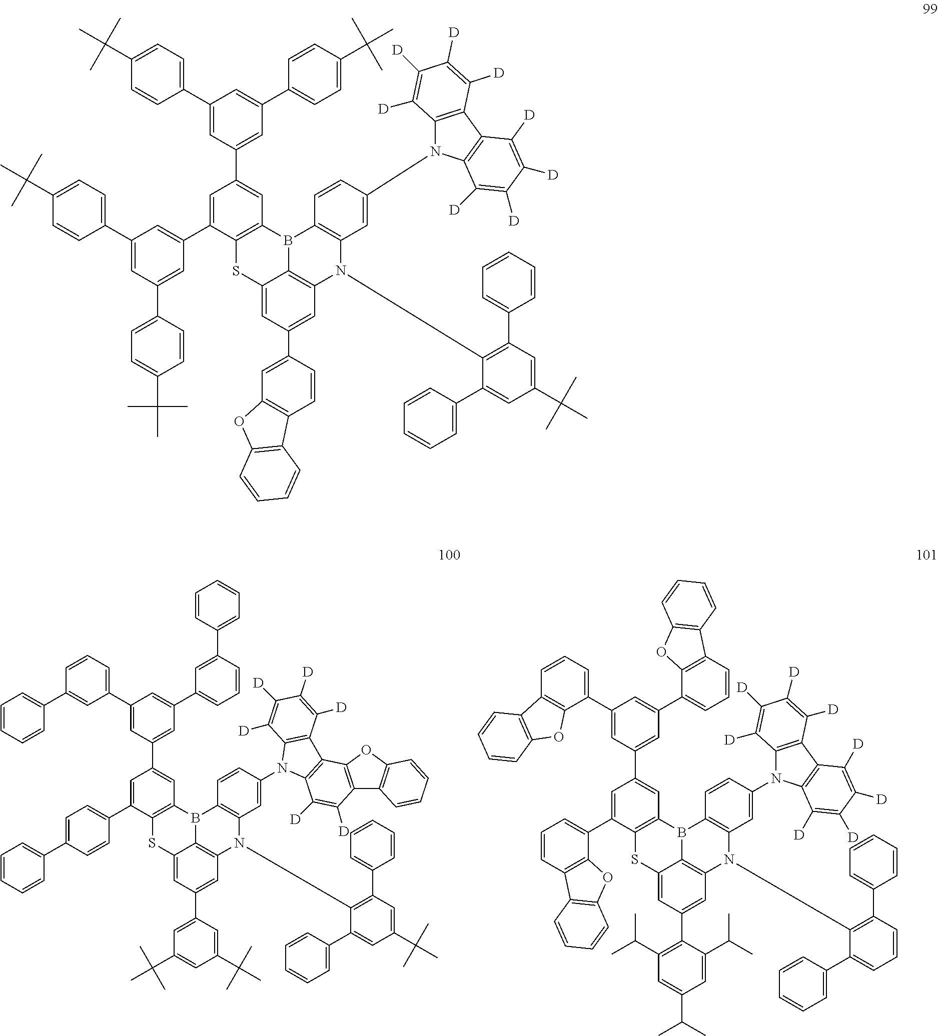

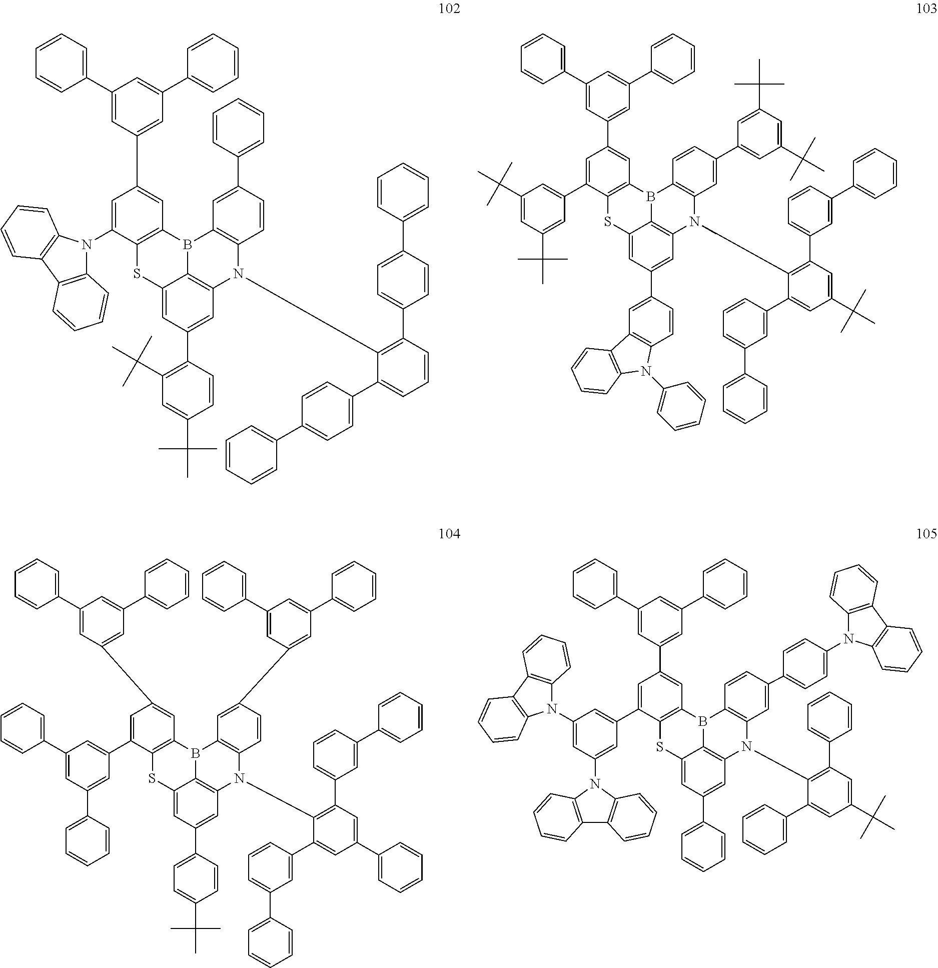

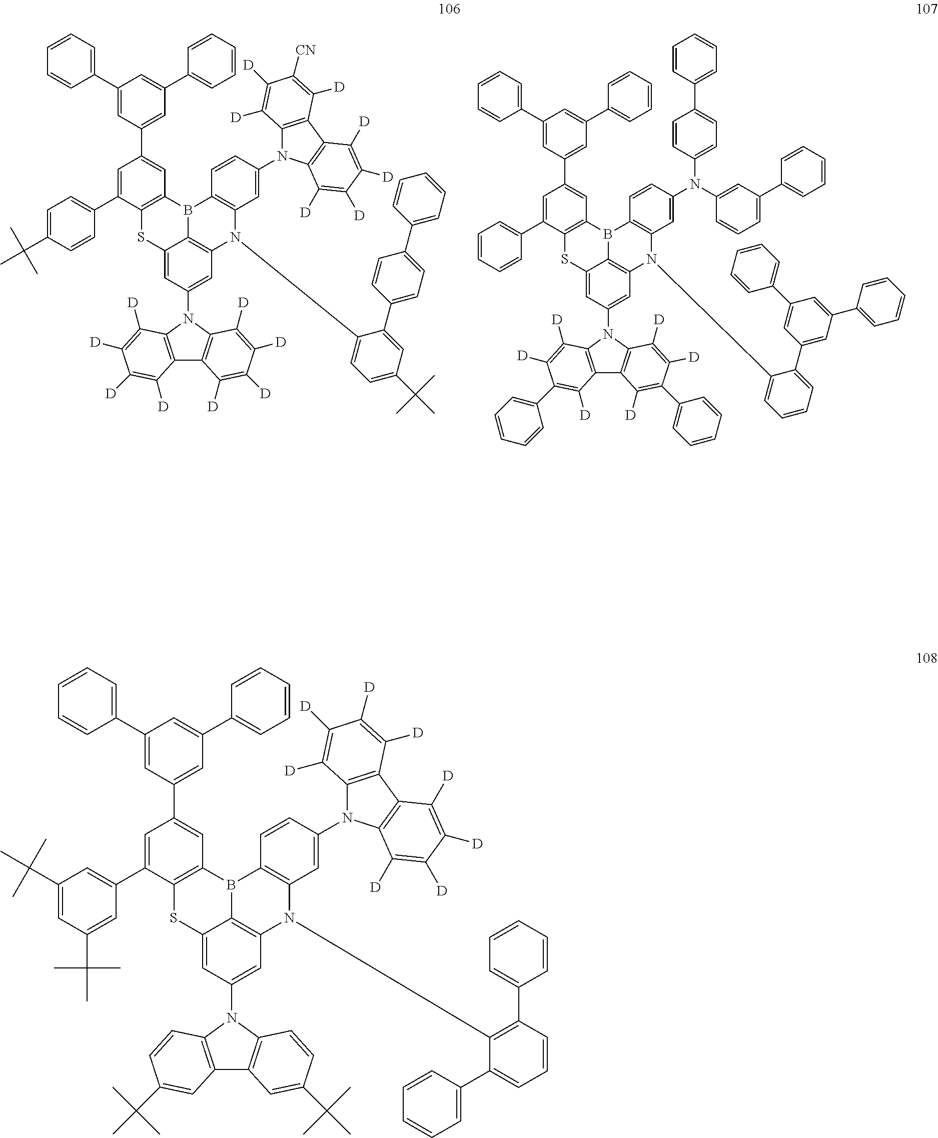

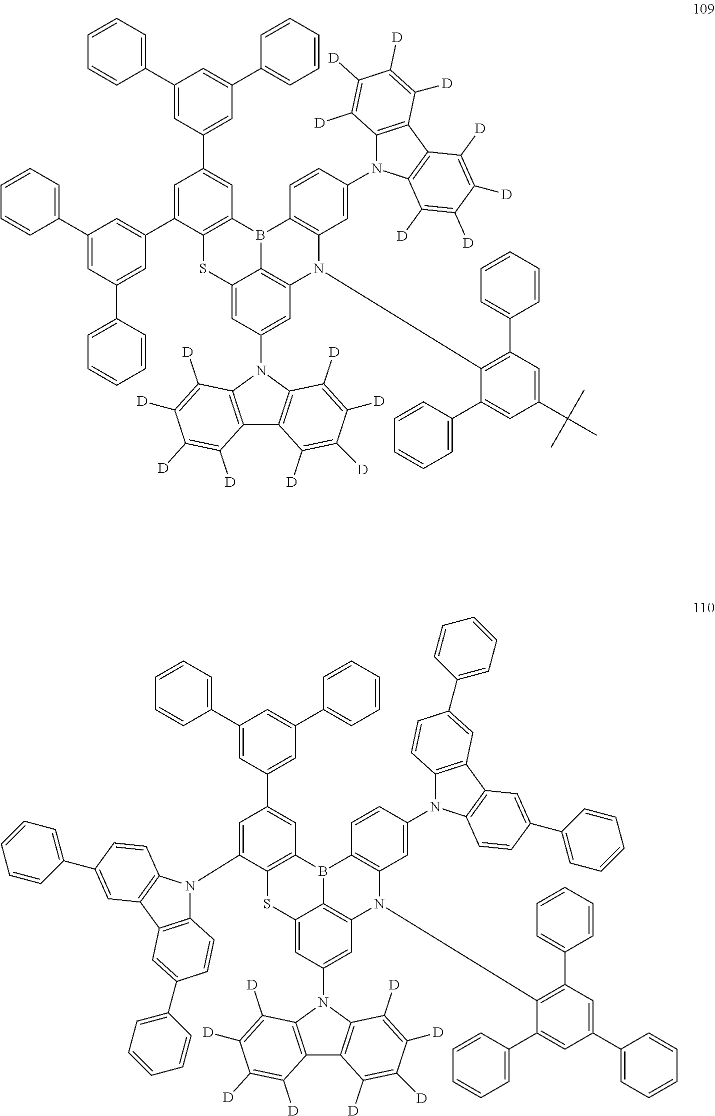

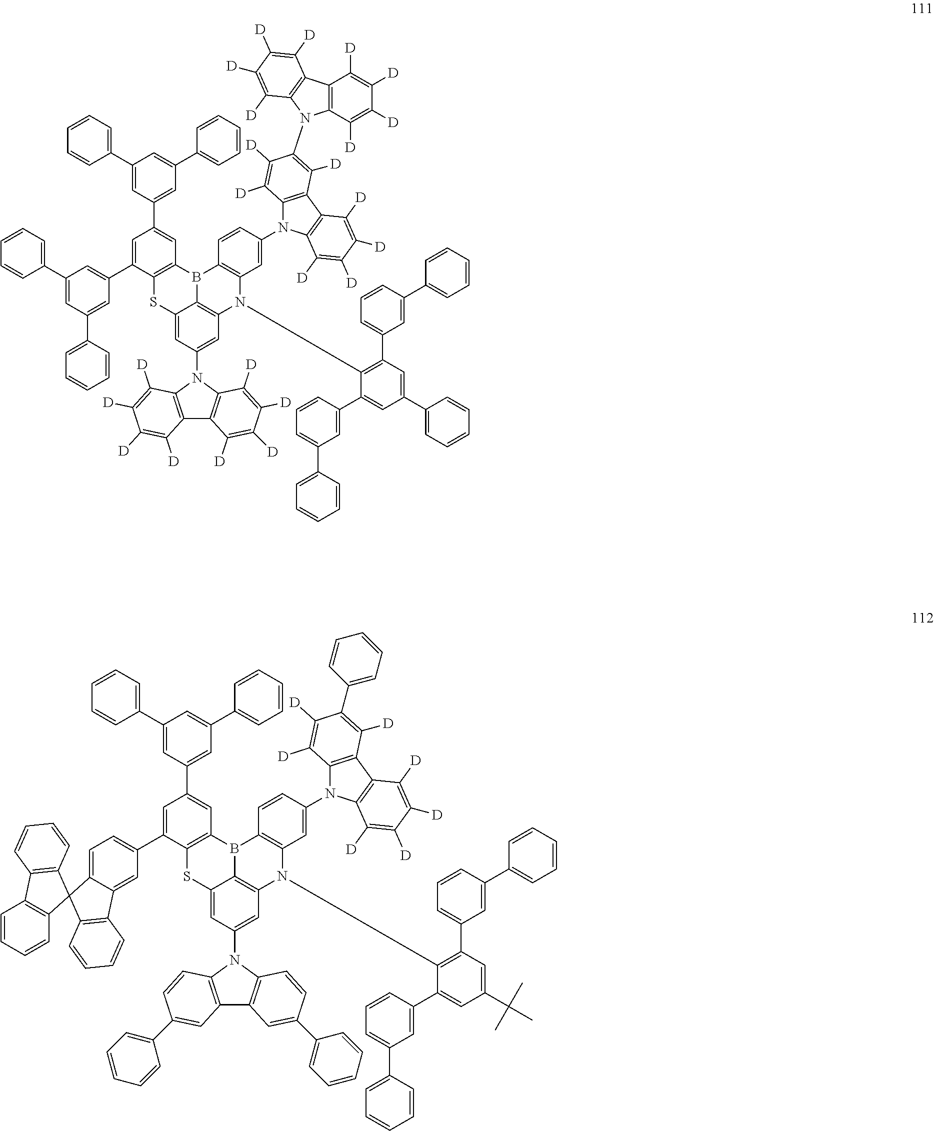

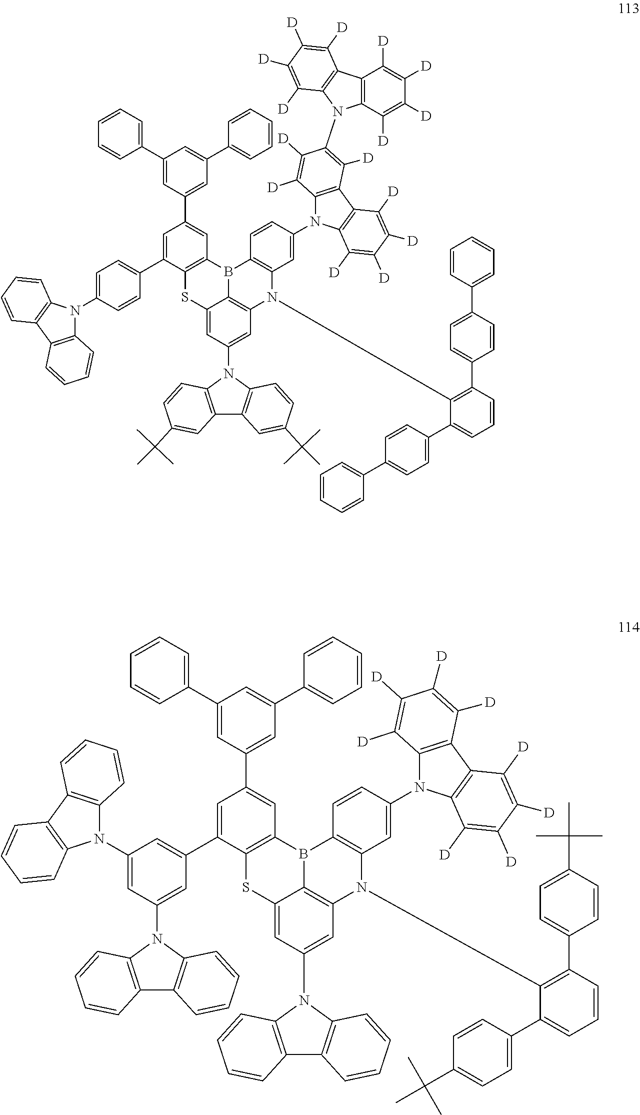

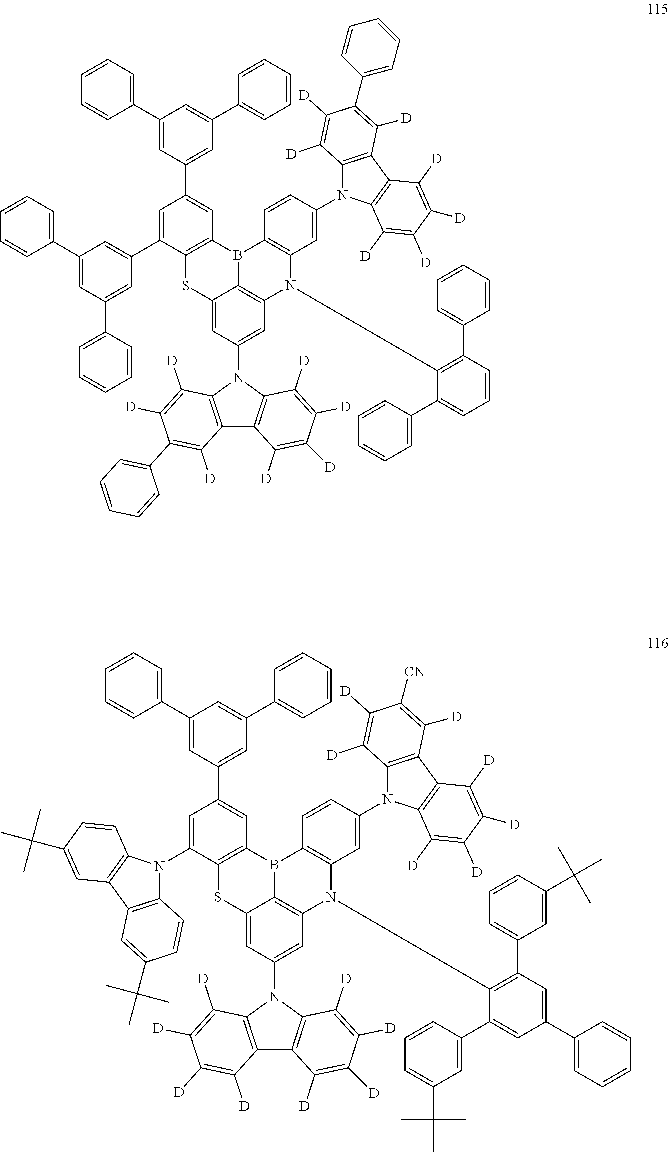

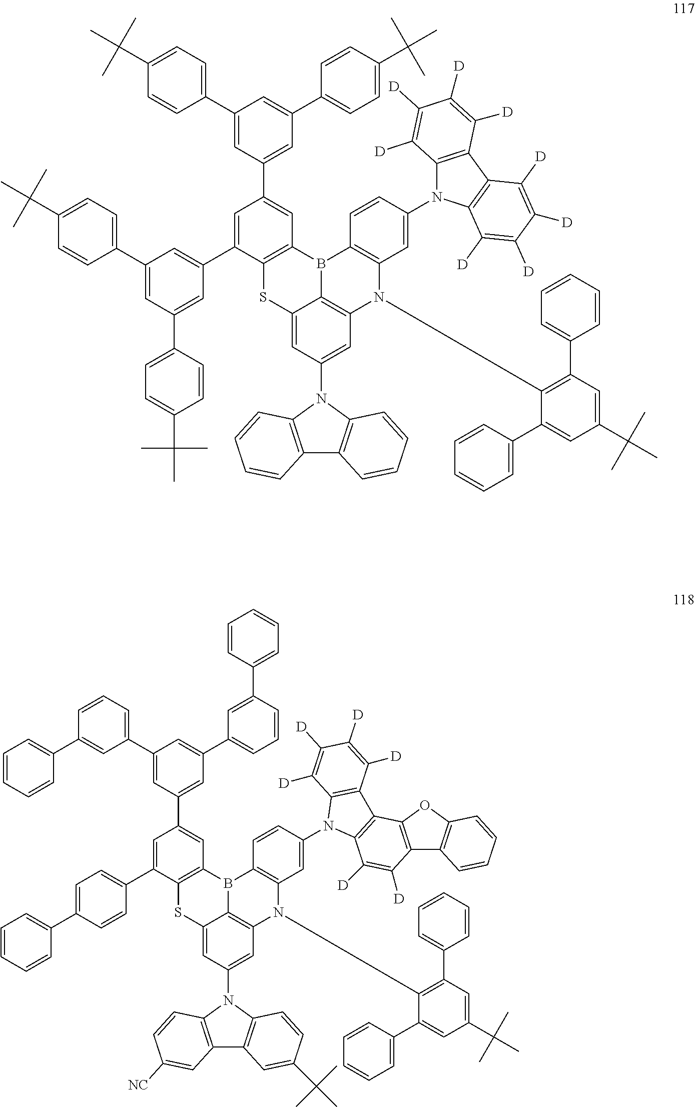

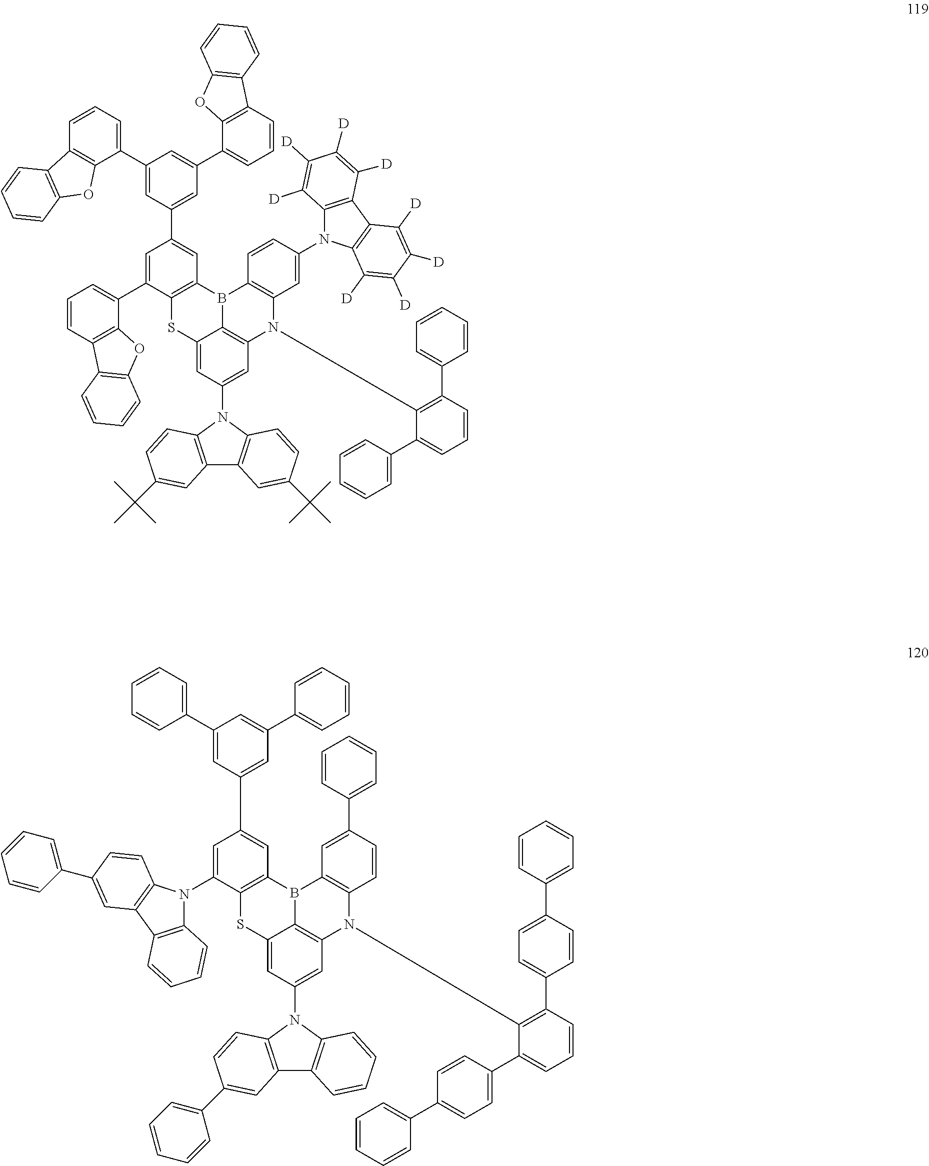 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-n3c4ccc(C(C)(C)C)cc4c4cc(C(C)(C)C)ccc43)cc3c1B2c1cc(-c2cc(-c4cccc5c4oc4ccccc45)cc(-c4cccc5c4oc4ccccc45)c2)cc(-c2cccc4c2oc2ccccc24)c1S3 ; c1ccc(-c2ccc(-c3cccc(-c4ccc(-c5ccccc5)cc4)c3N3c4ccc(-c5ccccc5)cc4B4c5cc(-c6cc(-c7ccccc7)cc(-c7ccccc7)c6)cc(-n6c7ccccc7c7cc(-c8ccccc8)ccc76)c5Sc5cc(-n6c7ccccc7c7cc(-c8ccccc8)ccc76)cc3c54)cc2)cc1]

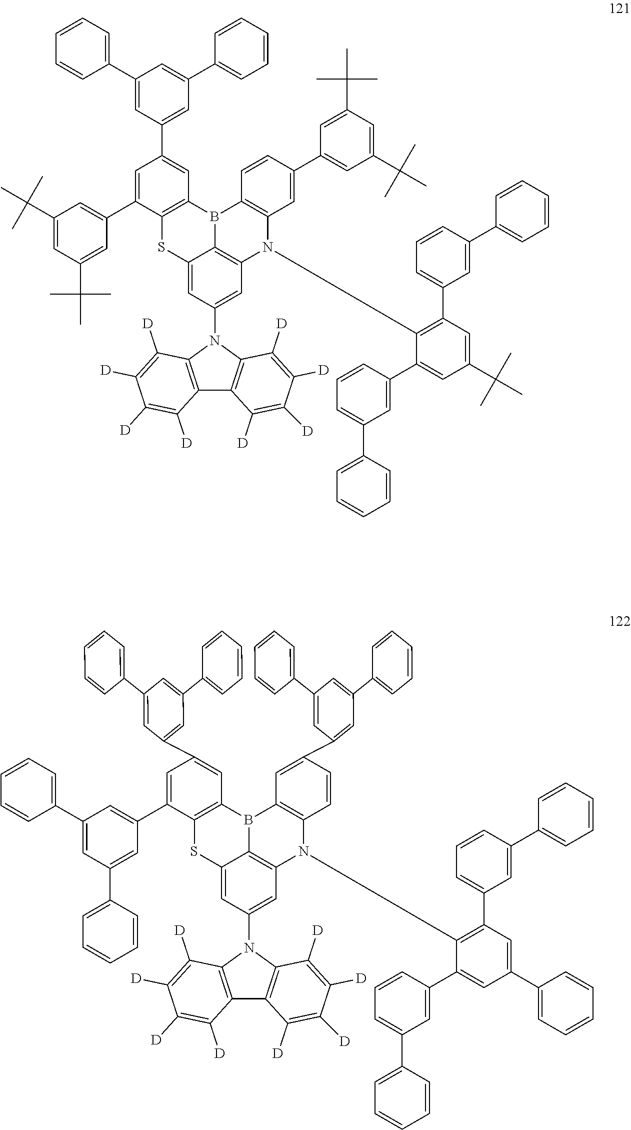

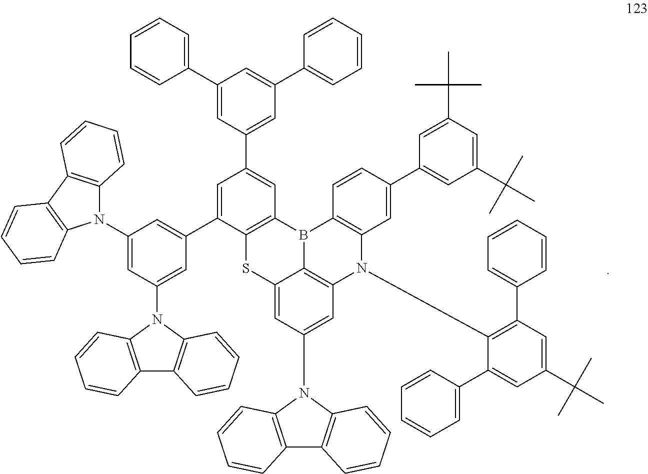 [SMILES: CC(C)(C)c1cc(-c2ccc3c(c2)N(c2c(-c4ccccc4)cc(C(C)(C)C)cc2-c2ccccc2)c2cc(-n4c5ccccc5c5ccccc54)cc4c2B3c2cc(-c3cc(-c5ccccc5)cc(-c5ccccc5)c3)cc(-c3cc(-n5c6ccccc6c6ccccc65)cc(-n5c6ccccc6c6ccccc65)c3)c2S4)cc(C(C)(C)C)c1]

In embodiments, the fused polycyclic compound may include, as a core structure, a pentacyclic fused ring including three heteroatoms as ring-forming atoms, and a meta-terphenyl (m-terphenyl) moiety and a biphenyl moiety may each be bonded to the core structure. Any one of the three heteroatoms may be a boron atom, another one may be a nitrogen atom, and the third one may be a nitrogen atom or a sulfur atom. The m-terphenyl moiety may be bonded at a meta position with respect to a boron atom, which is a ring-forming atom. The biphenyl moiety may be bonded (for example, directly bonded) to the nitrogen atom, which is a ring-forming atom.

The fused polycyclic compound according to an embodiment includes a m-terphenyl moiety, thus may have an increased volume, and may emit light with a shortened emission wavelength, and Dexter energy transfer may be inhibited. As a result, the light-emitting element ED containing the fused polycyclic compound according to an embodiment may exhibit long lifespan characteristics.

Calculations for Experimental Example Compounds were performed using Gaussian 09, and the calculated results are listed in Table 1. Experimental Example Compounds may include, as a core structure, a pentacyclic fused ring, which is the same as that of a fused polycyclic compound according to an embodiment. Experimental Example Compounds are compounds including a similar structure to a fused polycyclic compounds according to an embodiment.

The only difference between Experimental Example Compound A-1 and Experimental Example Compound A-2 is the presence or absence of the m-terphenyl moiety. Experimental Example Compound A-1 includes no m-terphenyl moiety and includes a phenyl group. Experimental Example Compound A-2 includes an m-terphenyl moiety. The only difference between Experimental Example Compound B-1 and Experimental Example Compound B-2 is the presence or absence of an m-terphenyl moiety. Experimental Example Compound B-1 includes no m-terphenyl moiety and includes a phenyl group. Experimental Example Compound B-2 includes an m-terphenyl moiety.

In Table 1, HOMO refers to an energy level of a highest occupied molecular orbital, and LUMO refers to an energy level of a lowest unoccupied molecular orbital. S1 (nm) exhibits an emission wavelength of a singlet, and T1 (nm) exhibits an emission wavelength of a triplet. T2-T1 exhibits an absolute value of an energy gap between a triplet excited state (T2) and a triplet ground state (T1). F1 exhibits oscillator strength, and ΔE_{ST} exhibits an absolute value of an energy gap between a singlet state and a triplet state.

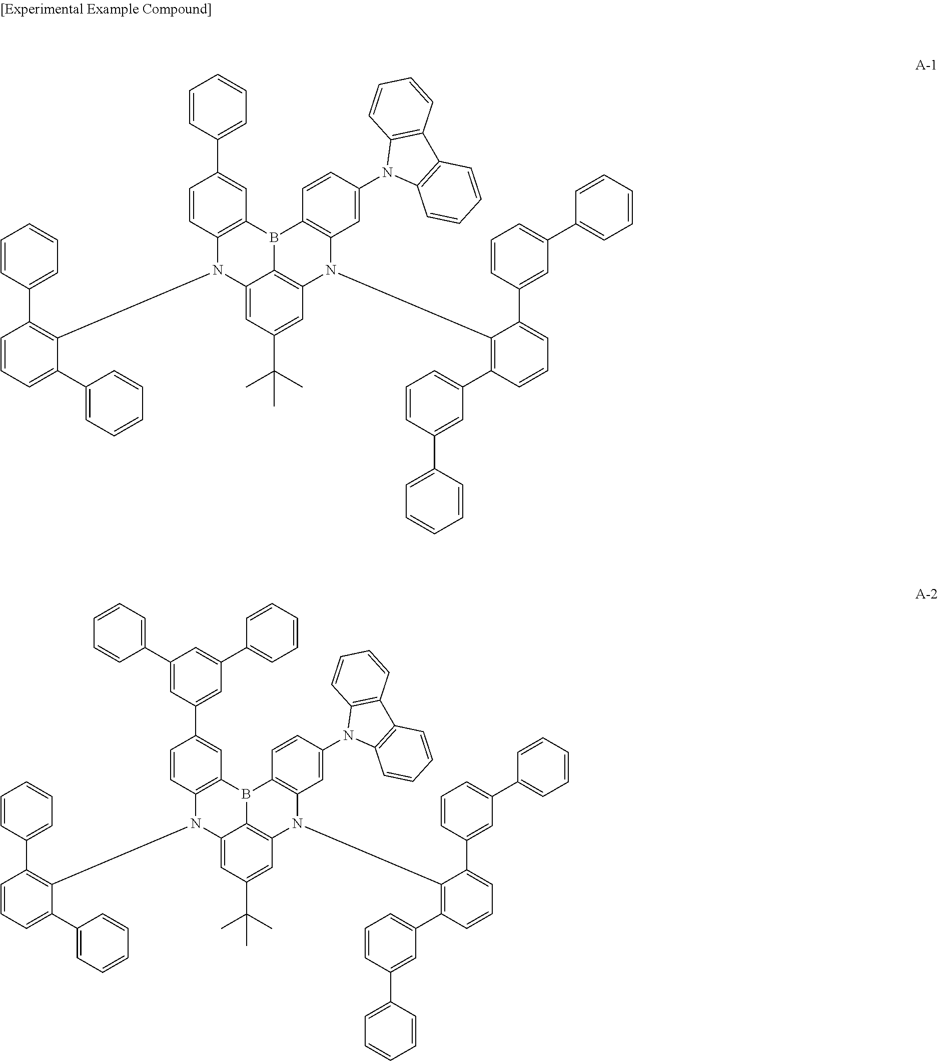 [SMILES: CC(C)(C)c1cc2c3c(c1)N(c1c(-c4cccc(-c5ccccc5)c4)cccc1-c1cccc(-c4ccccc4)c1)c1cc(-n4c5ccccc5c5ccccc54)ccc1B3c1cc(-c3ccccc3)ccc1N2c1c(-c2ccccc2)cccc1-c1ccccc1 ; CC(C)(C)c1cc2c3c(c1)N(c1c(-c4cccc(-c5ccccc5)c4)cccc1-c1cccc(-c4ccccc4)c1)c1cc(-n4c5ccccc5c5ccccc54)ccc1B3c1cc(-c3cc(-c4ccccc4)cc(-c4ccccc4)c3)ccc1N2c1c(-c2ccccc2)cccc1-c1ccccc1]

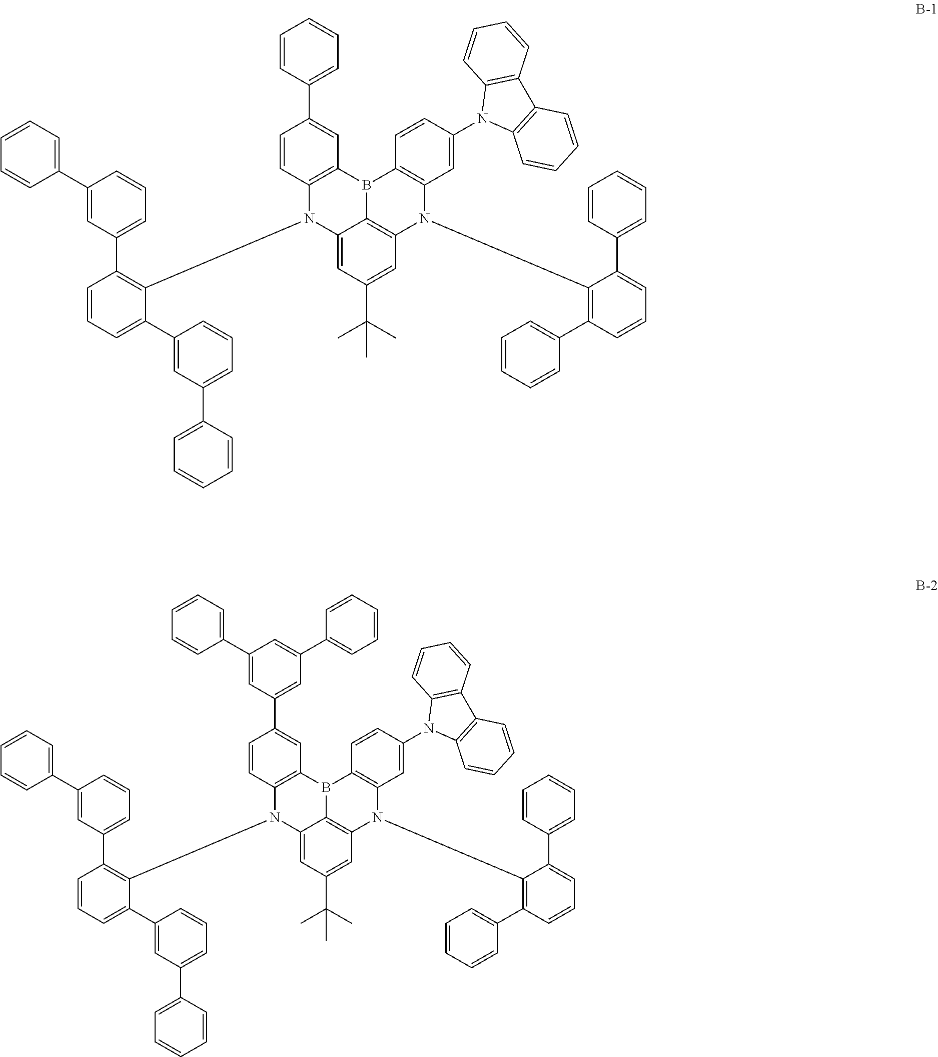 [SMILES: CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1c(-c2cccc(-c3ccccc3)c2)cccc1-c1cccc(-c2ccccc2)c1 ; CC(C)(C)c1cc2c3c(c1)N(c1c(-c4ccccc4)cccc1-c1ccccc1)c1cc(-n4c5ccccc5c5ccccc54)ccc1B3c1cc(-c3cc(-c4ccccc4)cc(-c4ccccc4)c3)ccc1N2c1c(-c2cccc(-c3ccccc3)c2)cccc1-c1cccc(-c2ccccc2)c1]

TABLE 1

| | HOMO (eV) | LUMO (eV) | S1(nm) | F1 | T1(nm) | T2 − T1 | ΔE_{ST} |
|---|---|---|---|---|---|---|---|
| Experimental | −5.04 | −1.54 | 420.4 | 0.257 | 484.8 | 0.453 | 0.392 |
| Example | | | | | | | |
| Compound A-1 | | | | | | | |
| Experimental | −5.02 | −1.5 | 418.2 | 0.262 | 481.7 | 0.376 | 0.391 |
| Example | | | | | | | |
| Compound A-2 | | | | | | | |
| Experimental | −5.05 | −1.57 | 423.9 | 0.211 | 489.7 | 0.470 | 0.393 |
| Example | | | | | | | |
| Compound B-1 | | | | | | | |
| Experimental | −5.05 | −1.54 | 420.4 | 0.25 | 485.4 | 0.423 | 0.395 |
| Example | | | | | | | |
| Compound B-2 | | | | | | | |

Referring to S1 (nm) in Table 1, it can be seen that Experimental Example Compound A-2 emits light with a shorter wavelength than Experimental Example Compound A-1 by about 2 nm to about 3 nm. Experimental Example Compound B-2 emits light with a shorter wavelength than Experimental Example Compound B-1 by about 3 nm to about 4 nm. As described above, the only difference between Experimental Example Compound A-1 and Experimental Example Compound A-2 is the presence or absence of the m-terphenyl moiety, and the only difference between Experimental Example Compound B-1 and Experimental Example Compound B-2 is the presence or absence of the m-terphenyl moiety. Therefore, the fused polycyclic compound according to an embodiment including the m-terphenyl moiety emits light with a relatively short wavelength.

The fused polycyclic compound according to an embodiment includes a m-terphenyl moiety, and thus a LUMO region within a molecule may be prevented from expanding and an interlayer LUMO-LUMO overlap may decrease. Therefore, electron transfer may be reduced, and thus Dexter energy transfer may be inhibited.

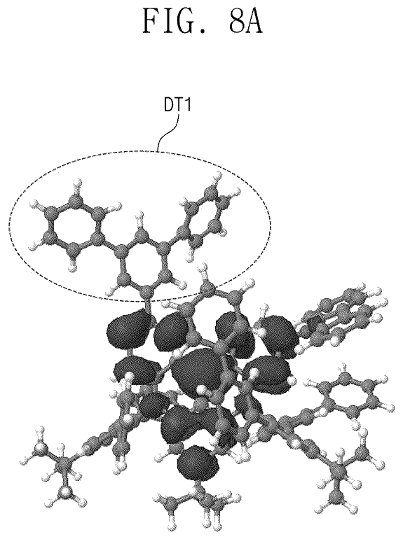

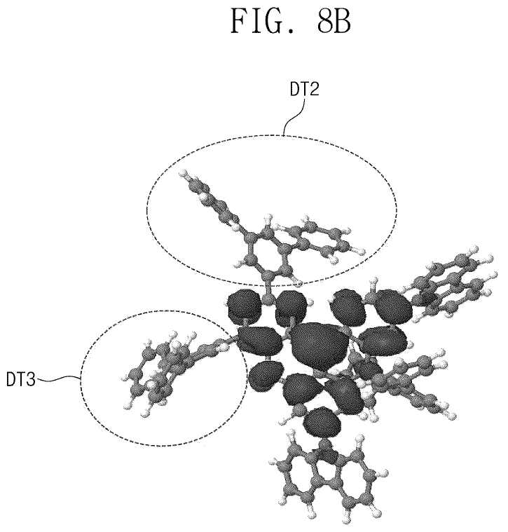

FIG. 8A shows a state of a lowest unoccupied molecular orbital (LUMO) of Experimental Example Compound B-2, and FIG. 8-B shows a state of a LUMO of Experimental Example Compound C-1. Experimental Example Compound C-1 has a similar structure to Compound 109, which is the fused polycyclic compound according to an embodiment.

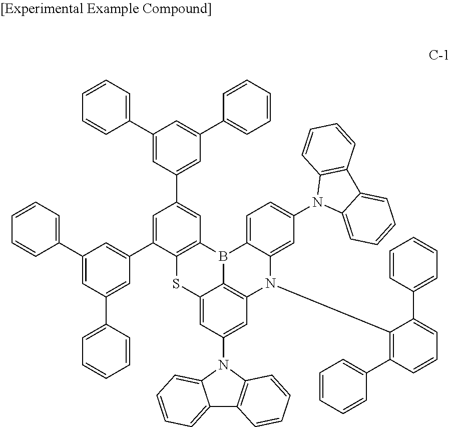 [SMILES: c1ccc(-c2cc(-c3ccccc3)cc(-c3cc4c(c(-c5cc(-c6ccccc6)cc(-c6ccccc6)c5)c3)Sc3cc(-n5c6ccccc6c6ccccc65)cc5c3B4c3ccc(-n4c6ccccc6c6ccccc64)cc3N5c3c(-c4ccccc4)cccc3-c3ccccc3)c2)cc1]

In FIG. 8A, DT1 represents a portion corresponding to the m-terphenyl group in Experimental Example Compound B-2. In FIG. 8B, DT2 and DT3 represent a portion corresponding to the m-terphenyl group in Experimental Example Compound C-1. Referring to FIG. 8A and FIG. 8B, it can be seen that the portions corresponding to the m-terphenyl group have no molecular orbital (that is, an orbital) distribution. Therefore, it is considered that in the fused polycyclic compound including m-terphenyl moiety, according to an embodiment, since the LUMO region may not be expanded, and an intermolecular LUMO-LUMO overlap may decrease, and thus Dexter energy transfer may be inhibited.

The emission layer EML may include the fused polycyclic compound according to an embodiment as a dopant. The emission layer EML may be a delayed fluorescent emission layer including a host and a dopant. The fused polycyclic compound according to an embodiment may be a thermally activated delayed fluorescent (TADF) material. The fused polycyclic compound according to an embodiment may be a thermally activated delayed fluorescent dopant of a multiple resonance (MR) type.

The fused polycyclic compound may emit blue light and the blue light may have a central wavelength in a range of about 430 nm to about 490 nm. The light-emitting element ED including the fused polycyclic compound may emit light having a central wavelength in a range of about 430 nm to about 490 nm. The light-emitting element ED including the fused polycyclic compound may emit blue light. For example, a third light-emitting element ED-3 (see FIG. 2) emitting blue light may include the fused polycyclic compound according to an embodiment.

In an embodiment, the emission layer EML may include the fused polycyclic compound as a first compound, and may further include at least one of a second compound represented by Formula HT-1, a third compound represented by Formula ET-1, or a fourth compound represented by Formula D-1.

In an embodiment, the emission layer EML may further include a second compound represented by Formula HT-1. In an embodiment, the second compound may be used as a hole-transporting host material in the emission layer EML.

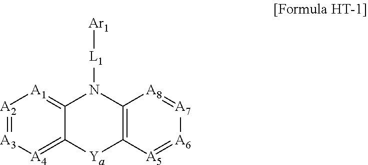

In Formula HT-1, A₁ to A₈ may each independently be N or C(R₅₁). For example, A₁ to A₈ may each be C(R₅₁). In an embodiment, any one of A₁ to A₈ may be N, and the remainder of A₁ to A₈ may each independently be C(R₅₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments are not limited thereto.

In Formula HT-1, Yₐ may be a direct linkage, C(R₅₂)(R₅₃), or Si(R₅₄)(R₅₅). For example, the two benzene rings that are bonded to the nitrogen atom in Formula HT-1 may be directly bonded to each other via a direct linkage,

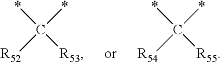

In Formula HT-1, when Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring. For example, R₅₁ to R₅₅ may each independently be a hydrogen atom or a deuterium atom. For example, R₅₁ to R₅₅ may each independently be an unsubstituted methyl group or an unsubstituted phenyl group.

In an embodiment, the second compound represented by Formula HT-1 may be selected from Compound Group 2. In an embodiment, in the light-emitting element ED, the second compound may include at least one compound selected from Compound Group 2.

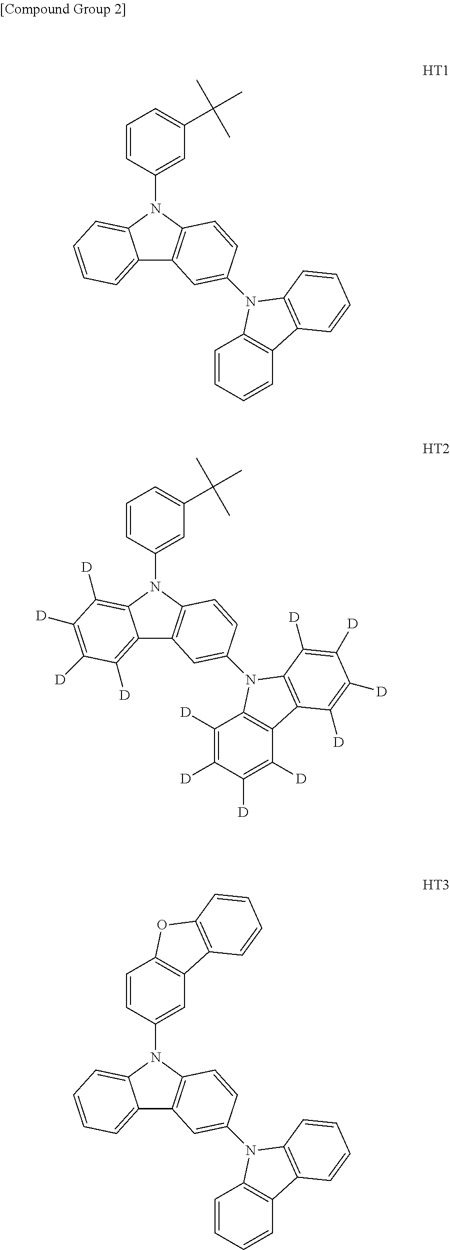 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

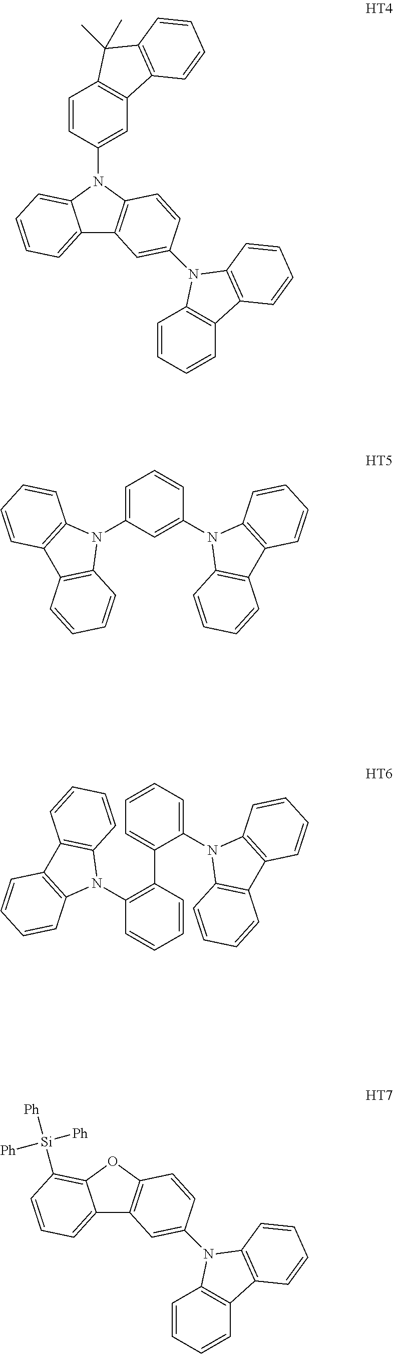 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

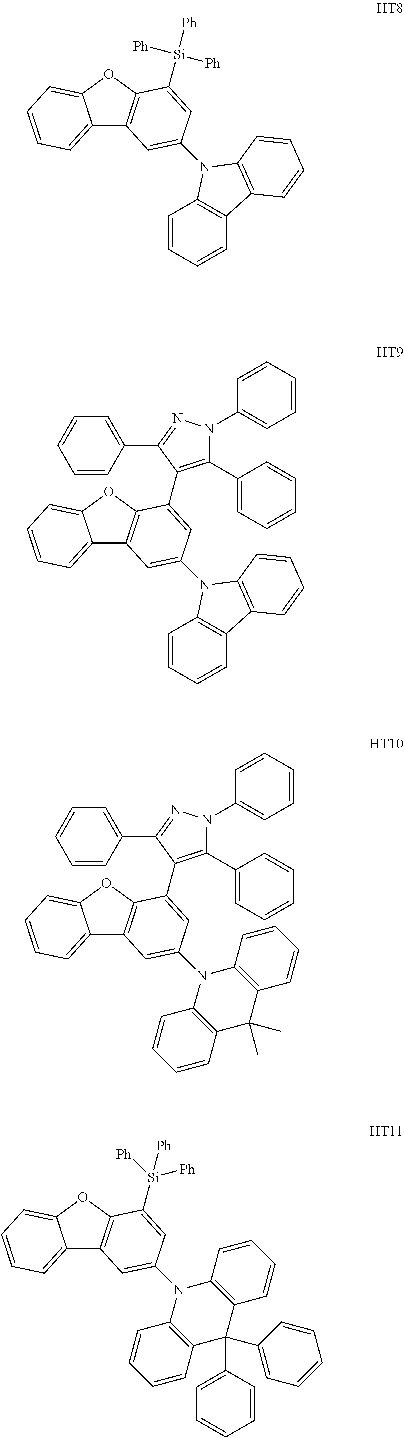 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

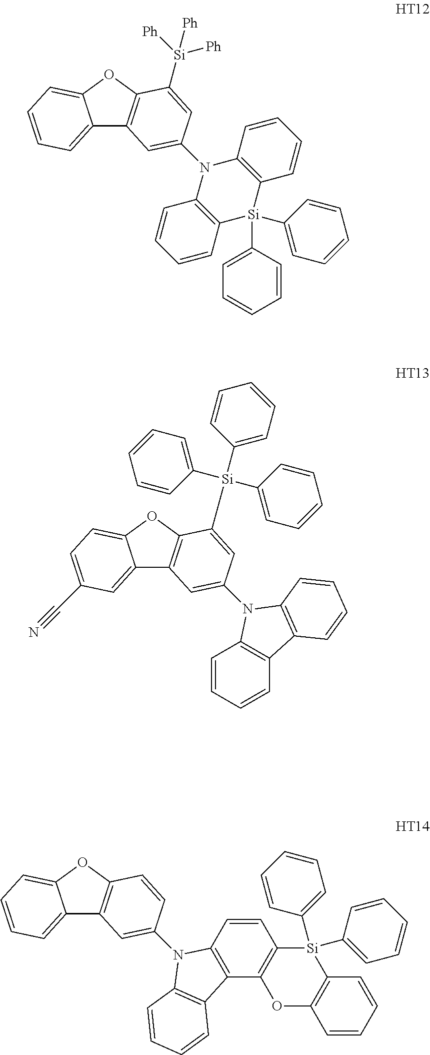 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1]

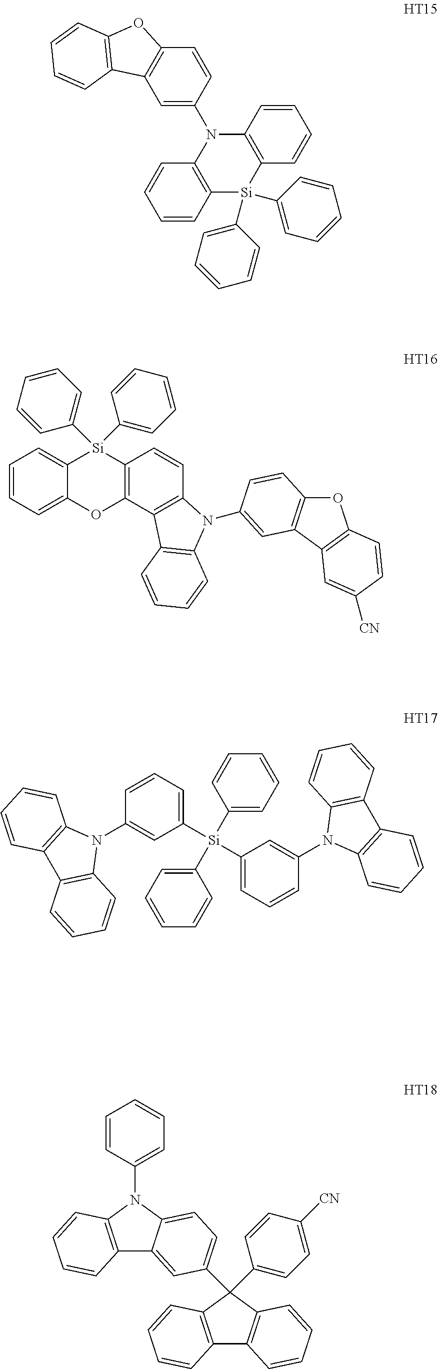 [SMILES: c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

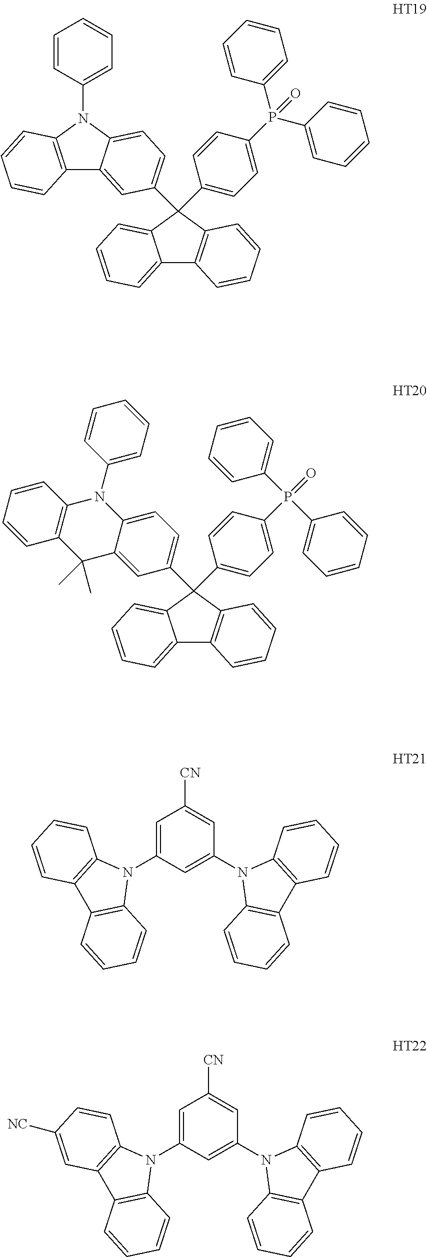 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

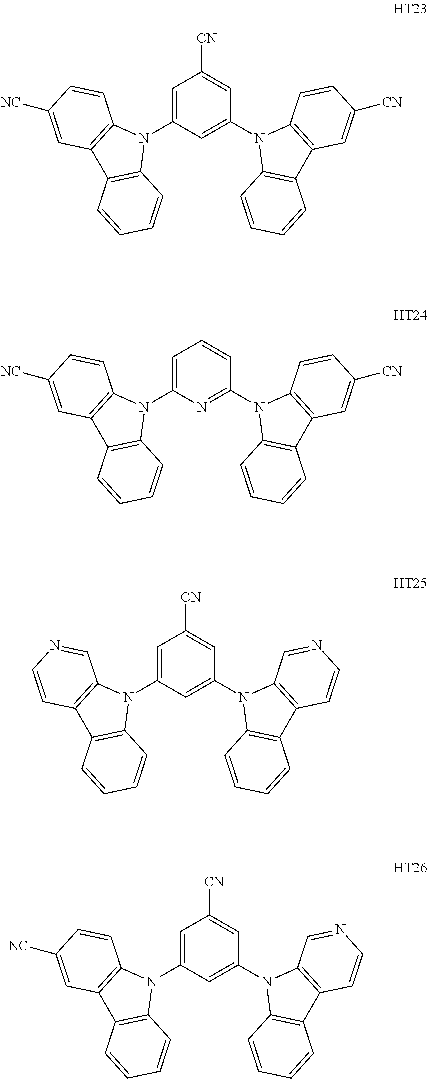 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

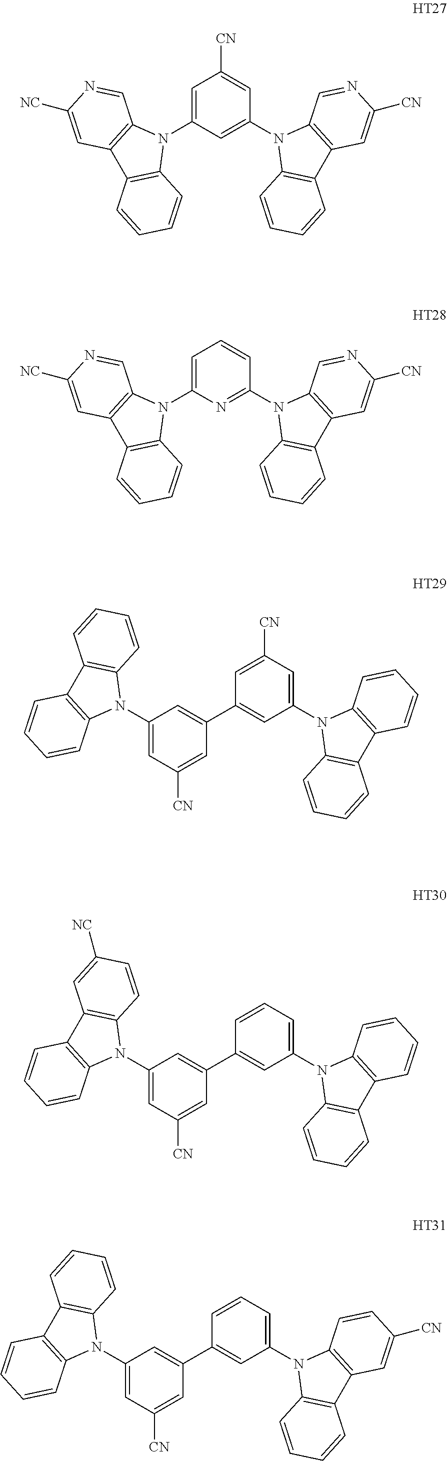 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

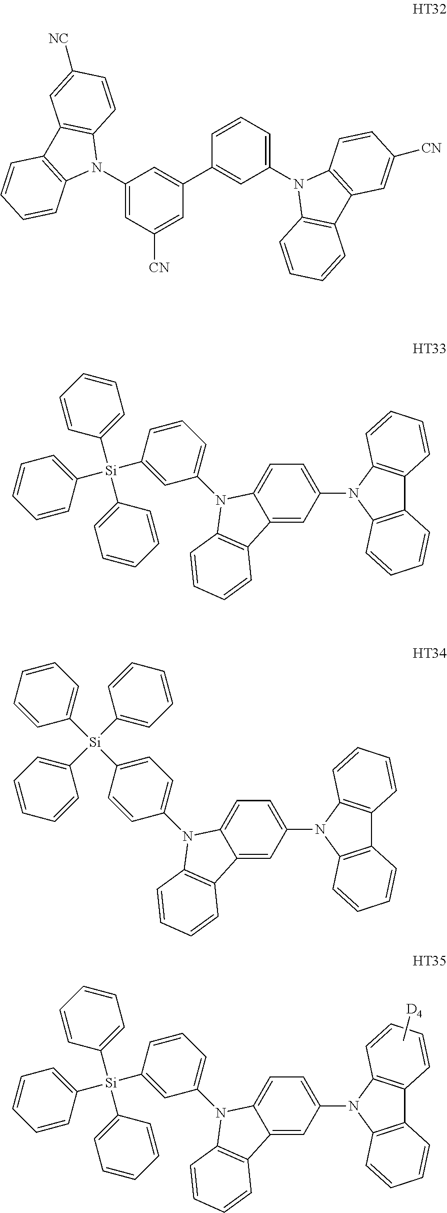

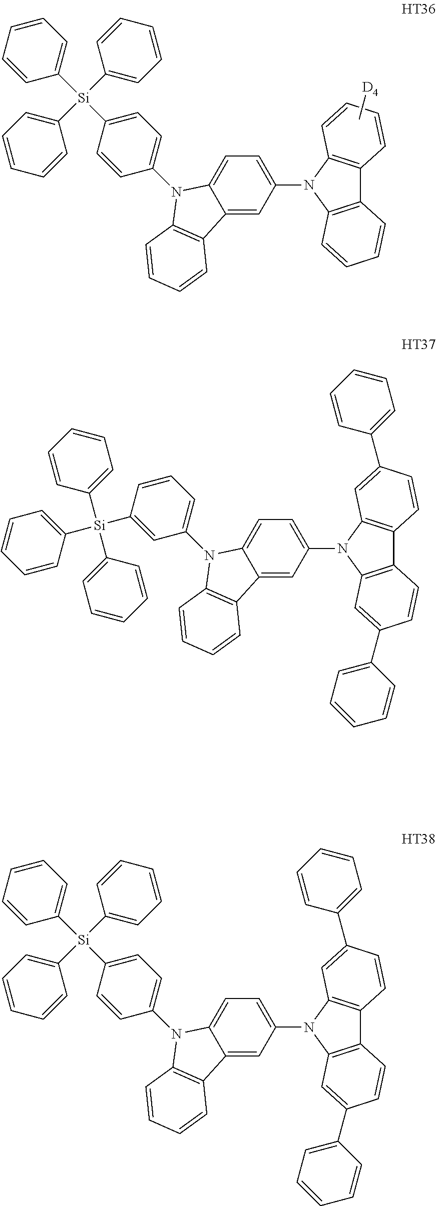

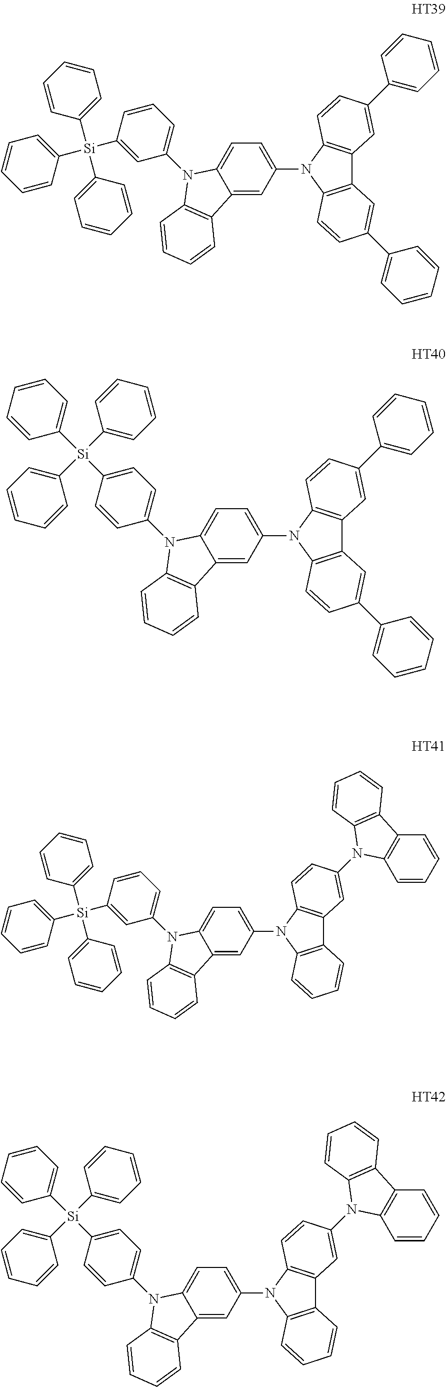 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

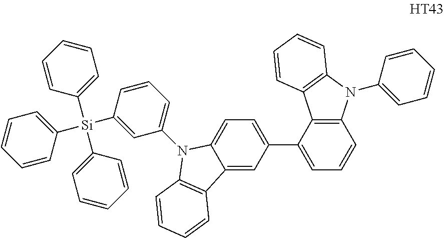 [SMILES: c1ccc(-n2c3ccccc3c3c(-c4ccc5c(c4)c4ccccc4n5-c4cccc([Si](c5ccccc5)(c5ccccc5)c5ccccc5)c4)cccc32)cc1]

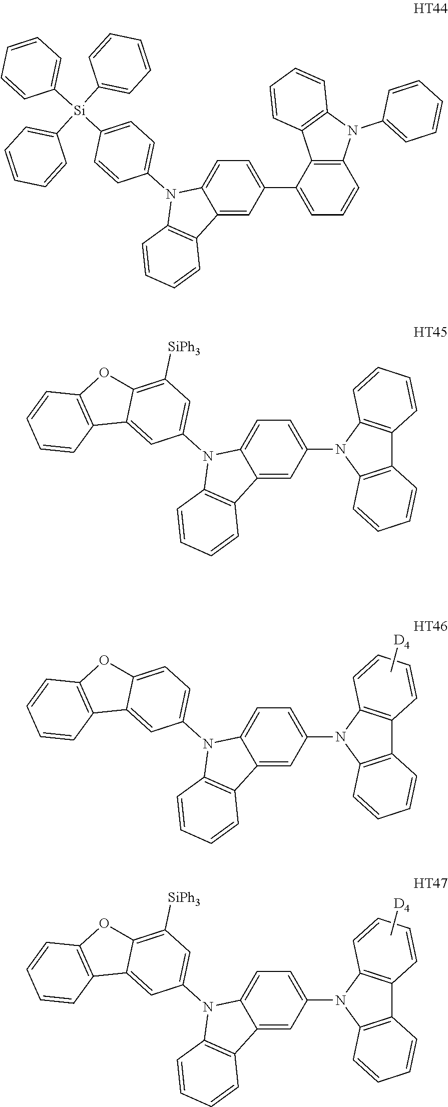

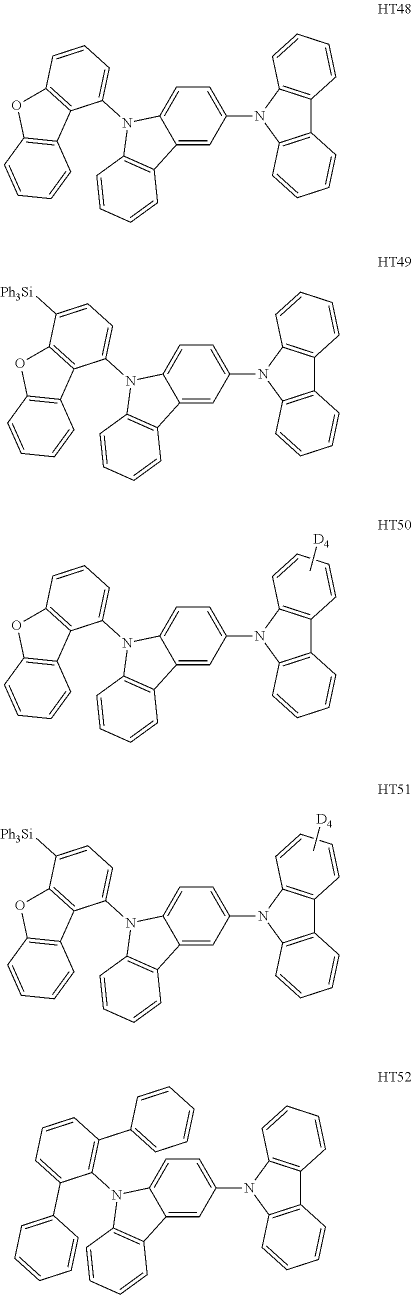

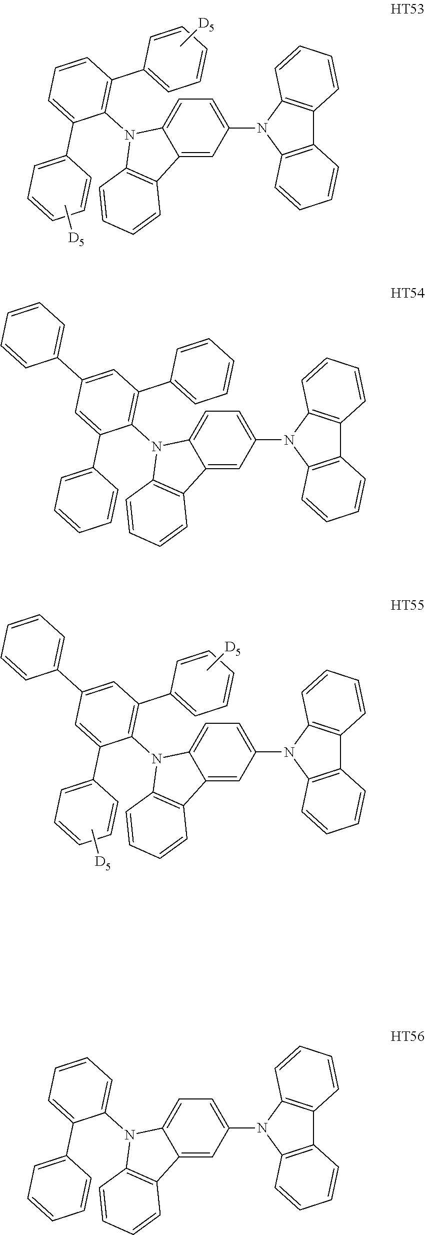

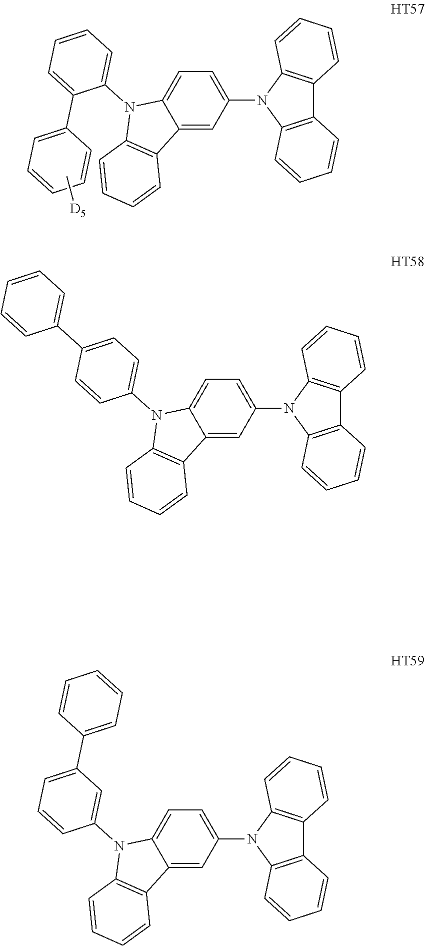

In Compound Group 2, D may represent a deuterium atom, and Ph may represent a substituted or unsubstituted phenyl group. For example, in Compound Group 2, Ph may represent an unsubstituted phenyl group.

In an embodiment, the emission layer EML may further include a third compound represented by Formula ET-1. In an embodiment, the third compound may be used as an electron transport host material in the emission layer EML.

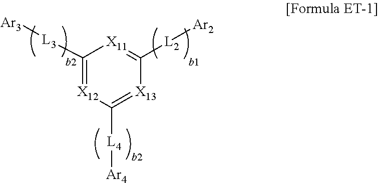

In Formula ET-1, at least one of X₁ to X₃ may each be N, and the remainder of X₁ to X₃ may each independently be C(R₅₆). For example, any one of X₁ to X₃ may be N, and the remainder of X₁ to X₃ may each independently be C(R₅₆). Thus, the third compound represented by Formula ET-1 may include a pyridine moiety. As another example, two of X₁ to X₃ may each be N, and the remainder of X₁ to X₃ may be C(R₅₆). Thus, the third compound represented by Formula ET-1 may include a pyrimidine moiety. As yet another example, X₁ to X₃ may each be N. Thus, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer from 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group, or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. When b1 to b3 are each 2 or greater, L₂ to L₄ may each independently be a substituted or unsubstituted arylene group having 6 to 30 ring-forming carbon atoms or a substituted or unsubstituted heteroarylene group having 2 to 30 ring-forming carbon atoms. The case where b1 is 0 may be the same as the case where b1 is 1 and L₂ is a direct linkage. The case where b2 is 0 may be the same as the case where b2 is 1 and L₃ is a direct linkage. The case where b3 is 0 may be the same as the case where b3 is 1 and L₄ is a direct linkage.

In an embodiment, the third compound represented by Formula ET-1 may be selected from Compound Group 3. In an embodiment, in the light-emitting element ED, the third compound may include at least one compound selected from Compound Group 3.

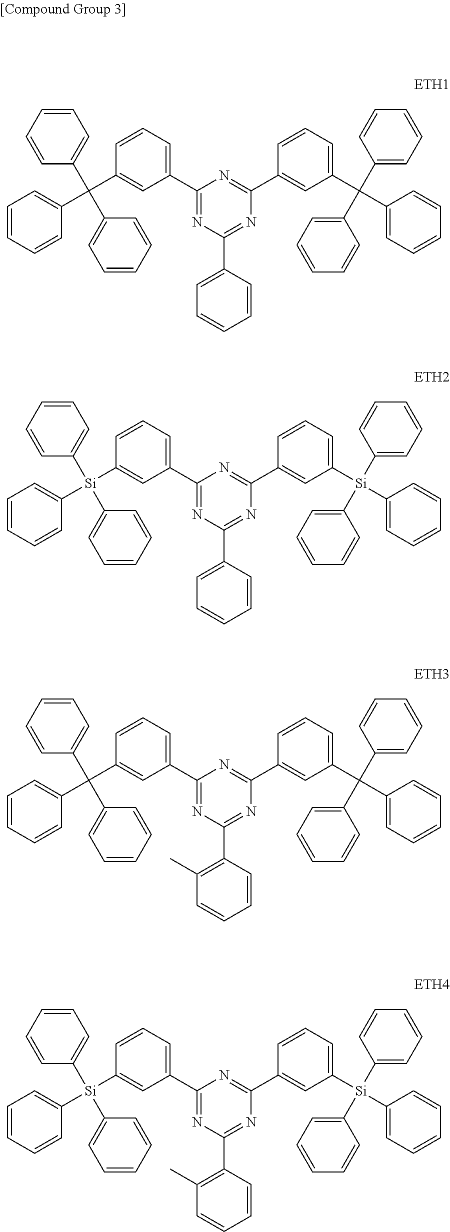 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

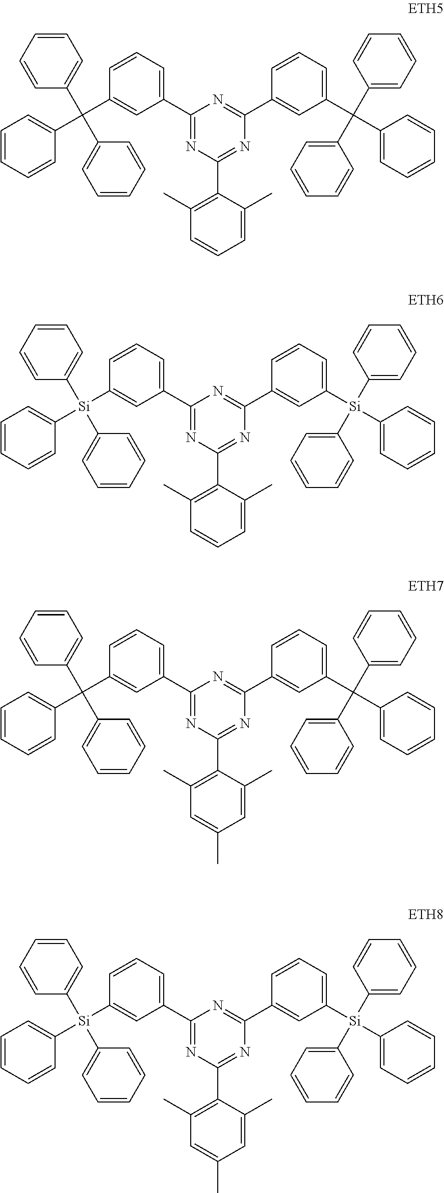 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

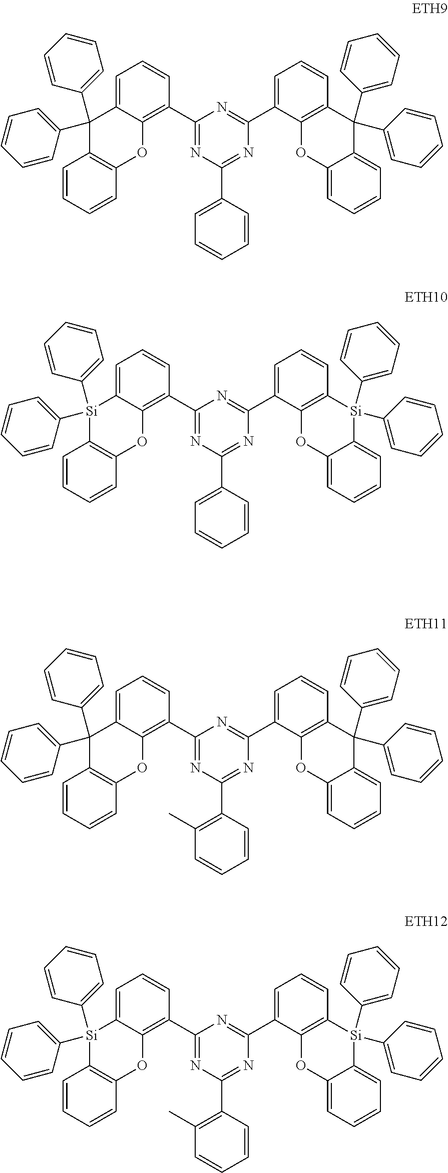 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

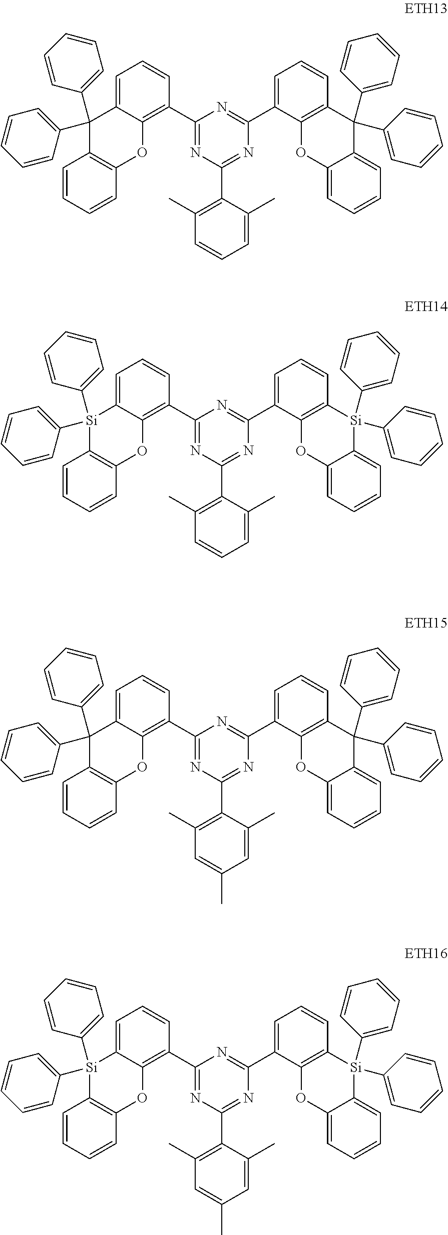 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

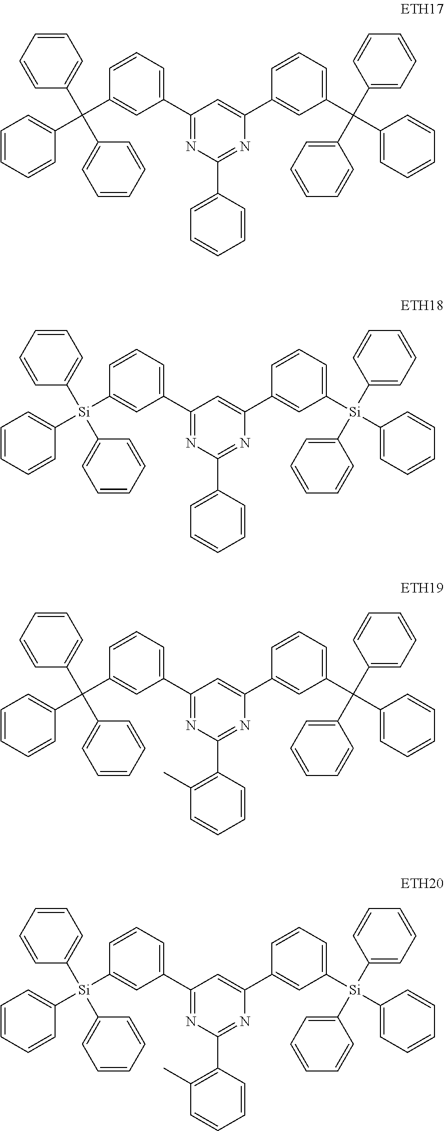 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

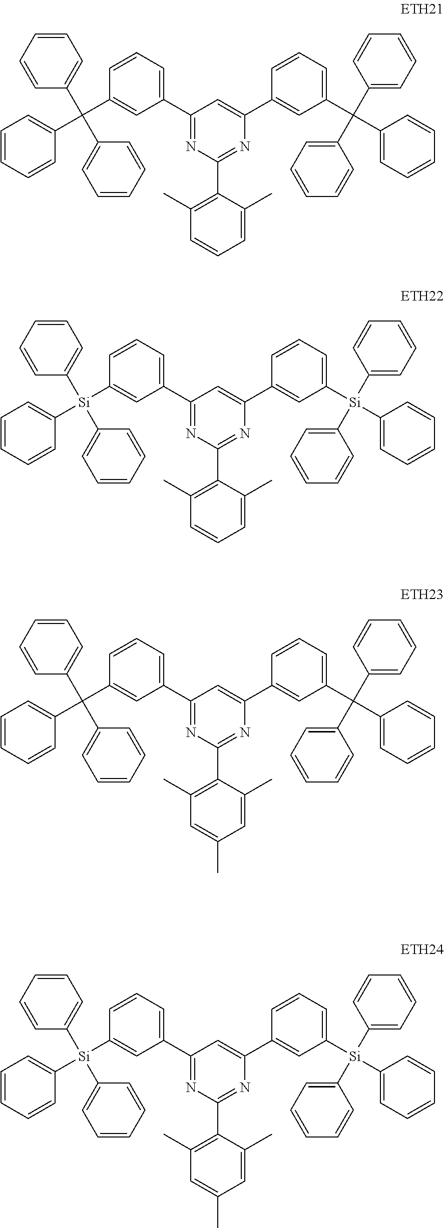 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

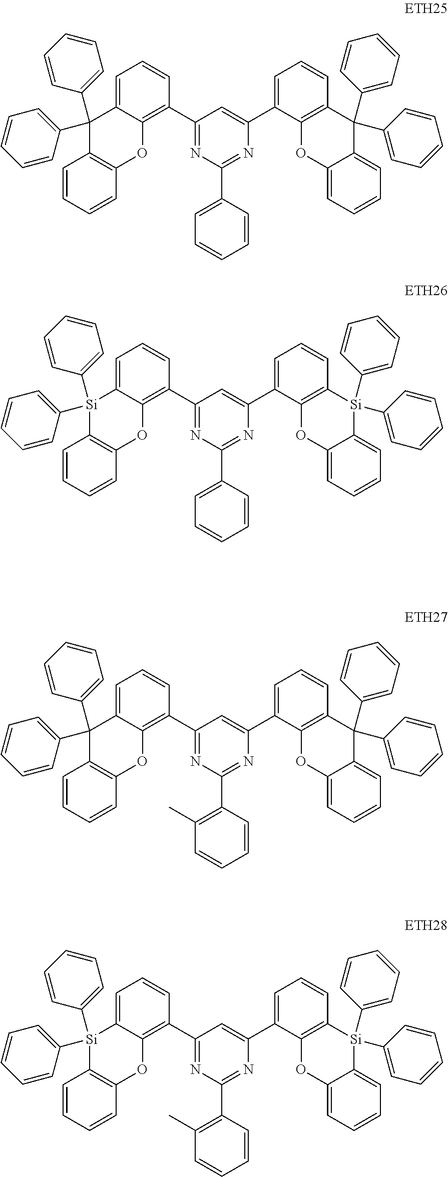 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

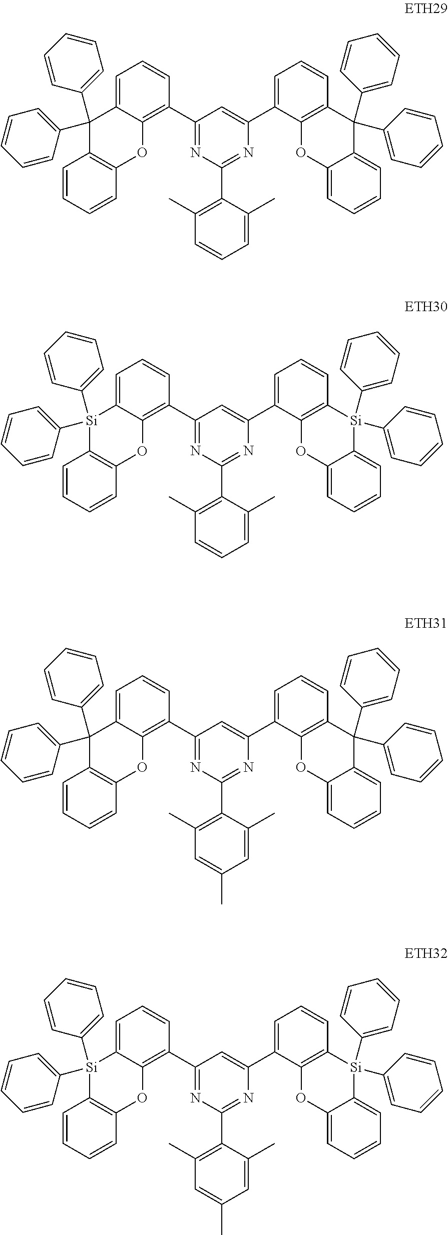 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

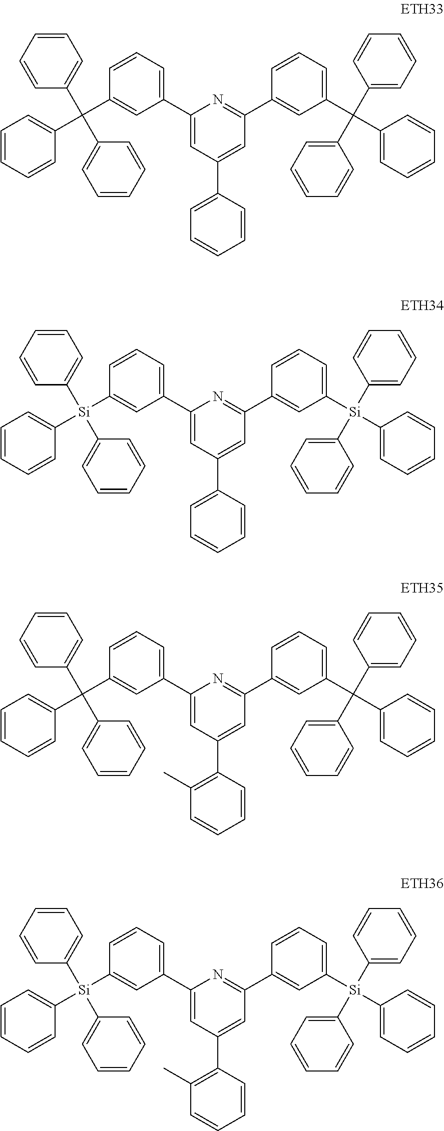 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

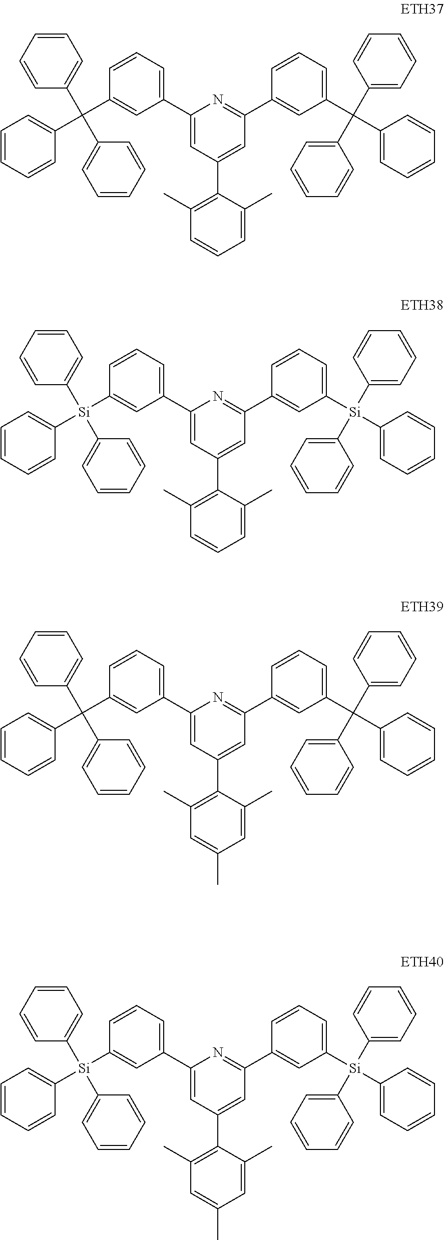 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

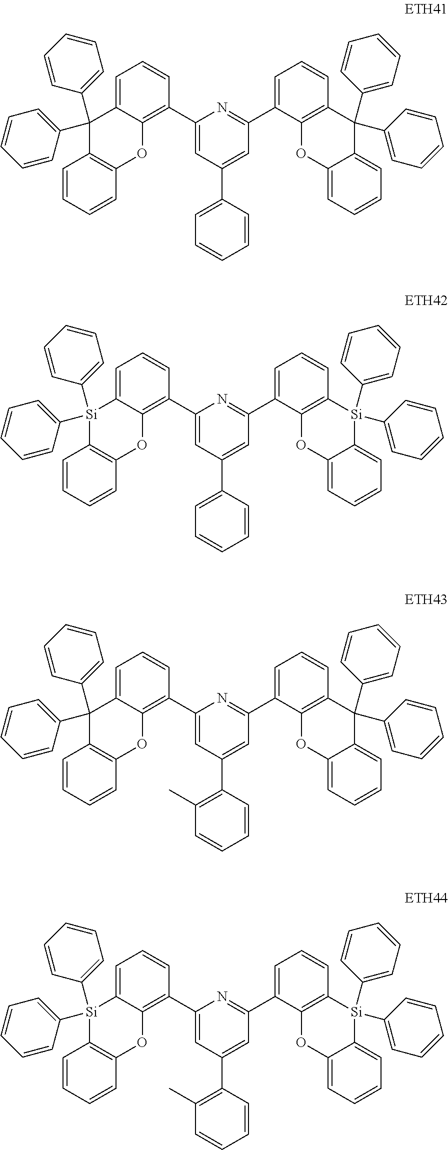 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

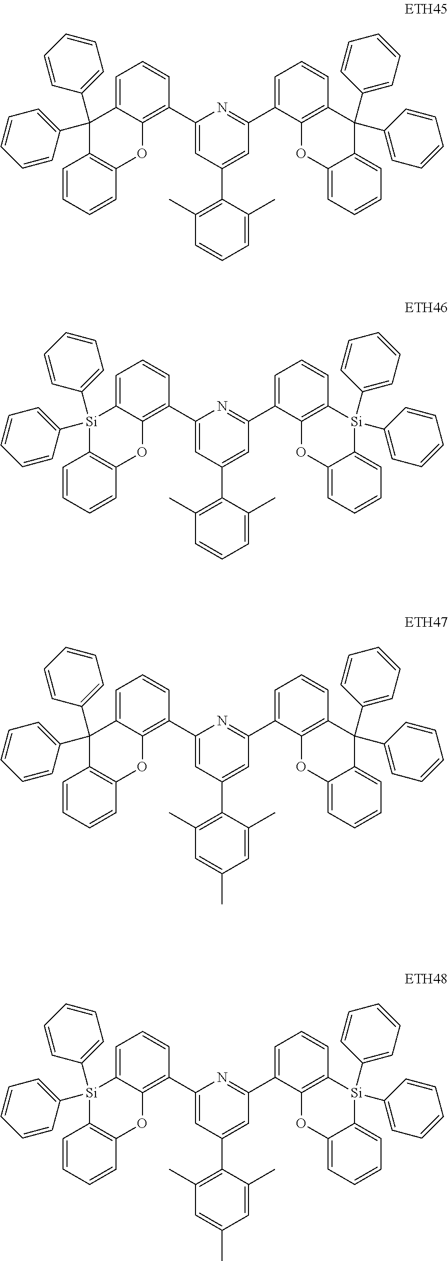 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

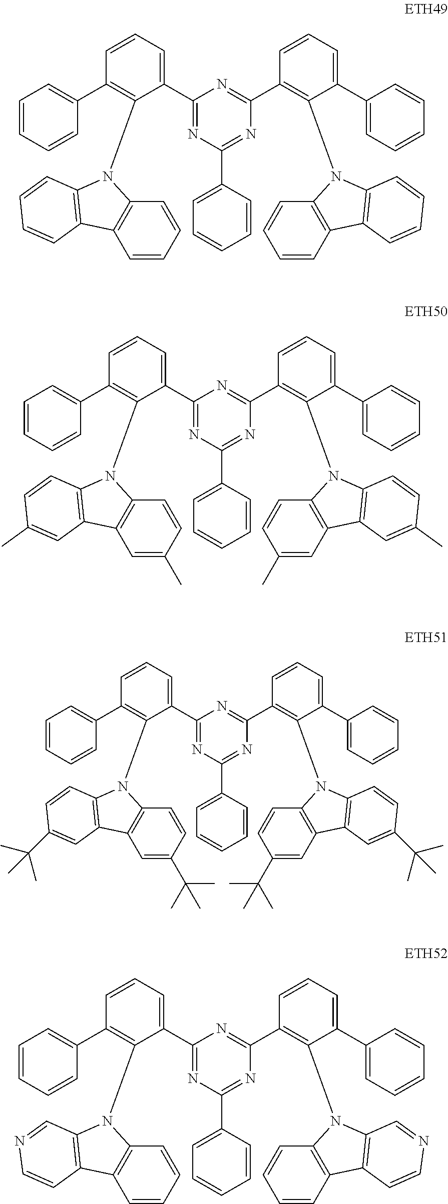

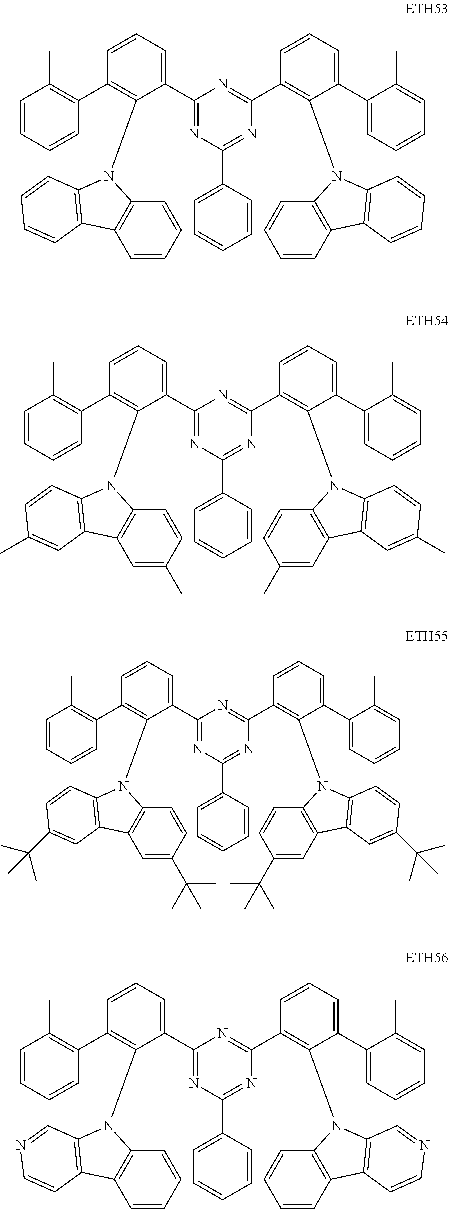

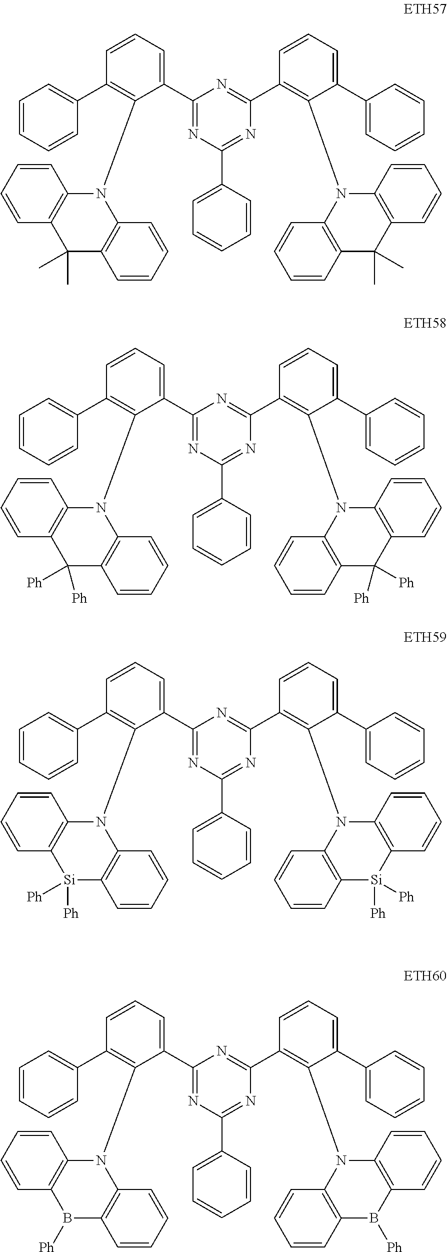

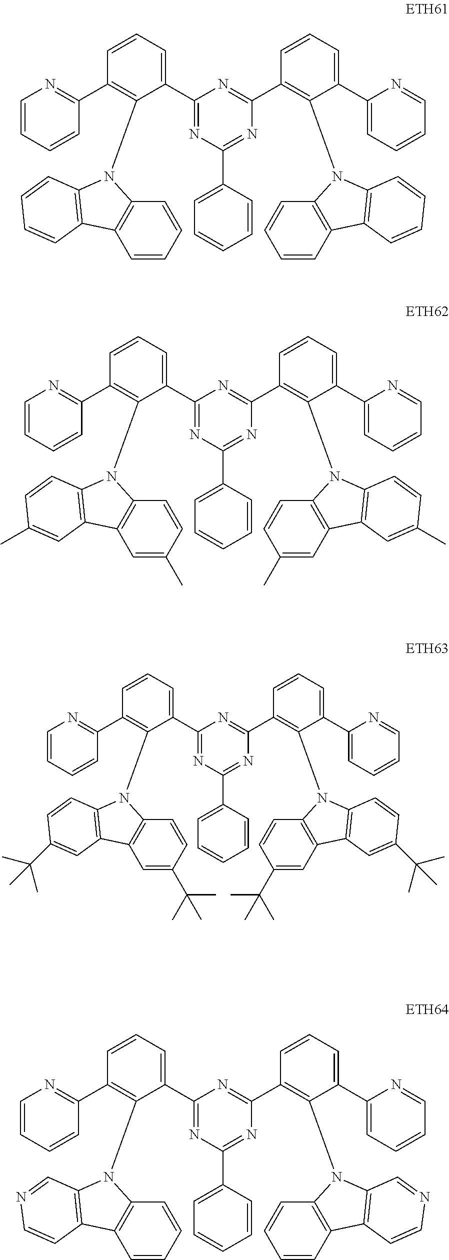

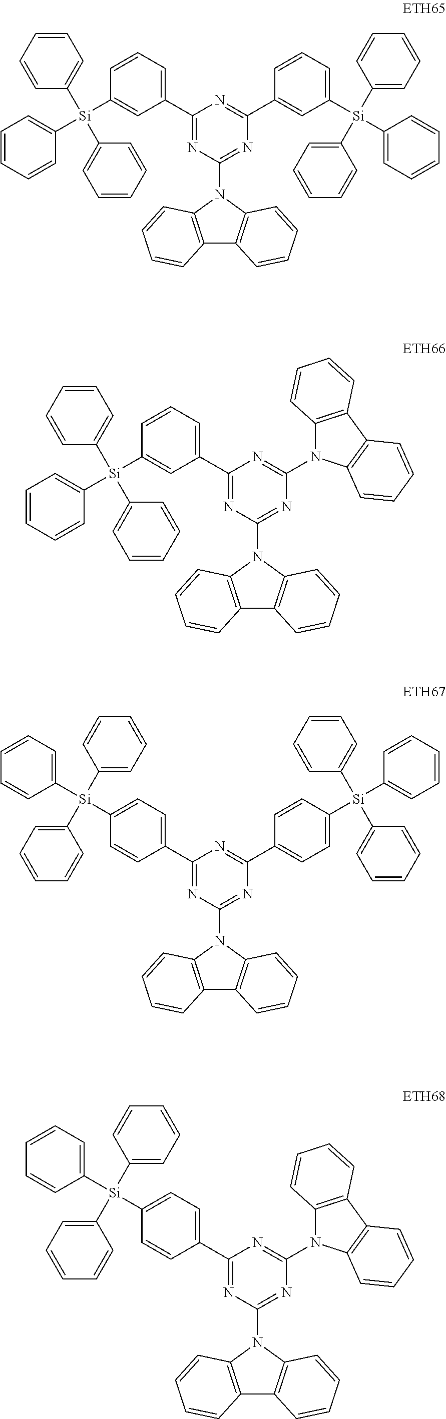 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

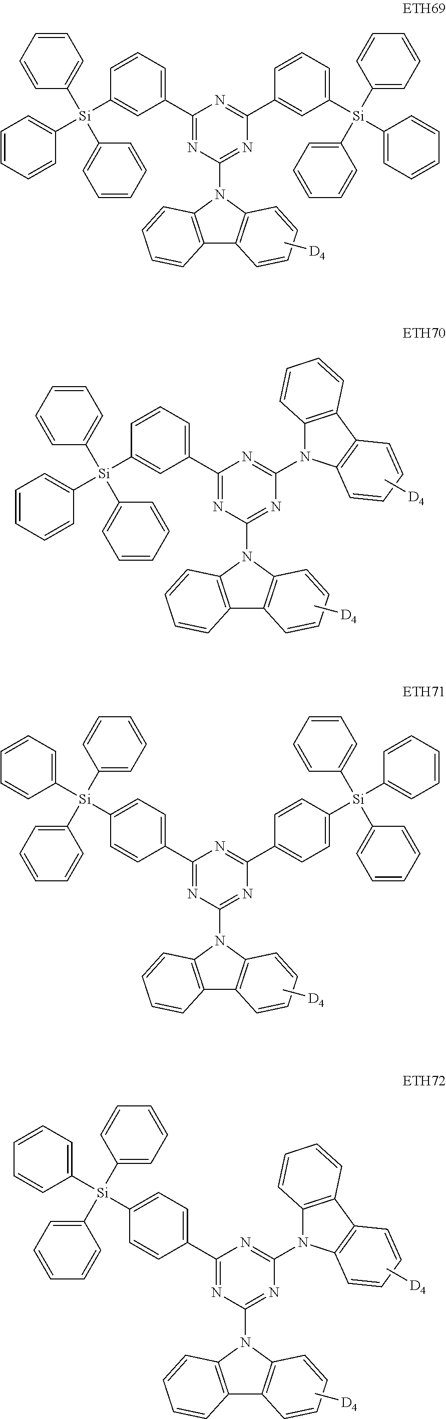

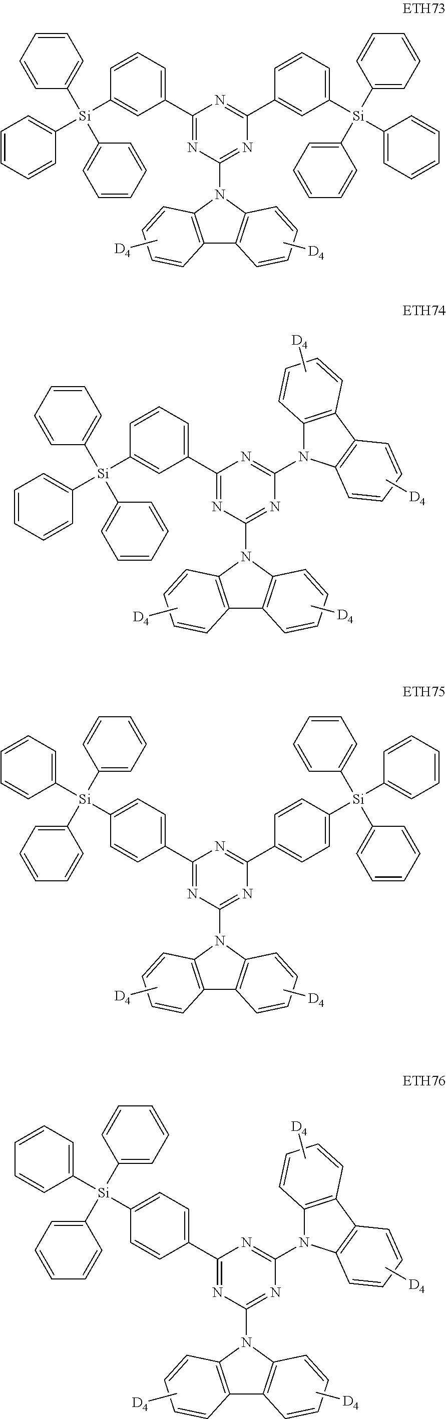

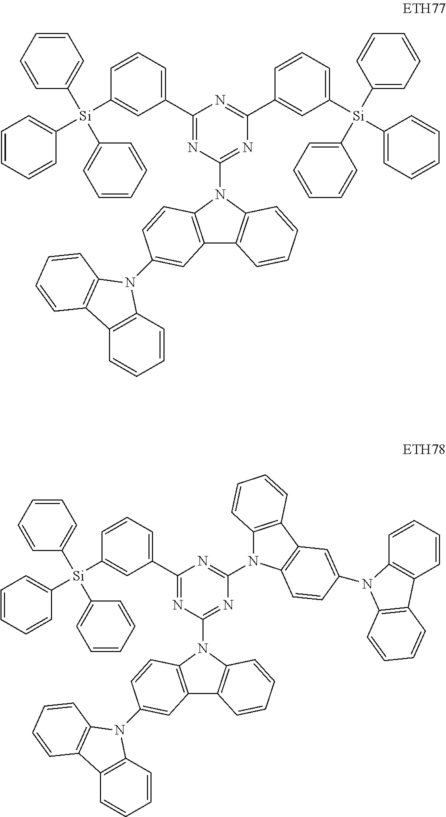 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1]

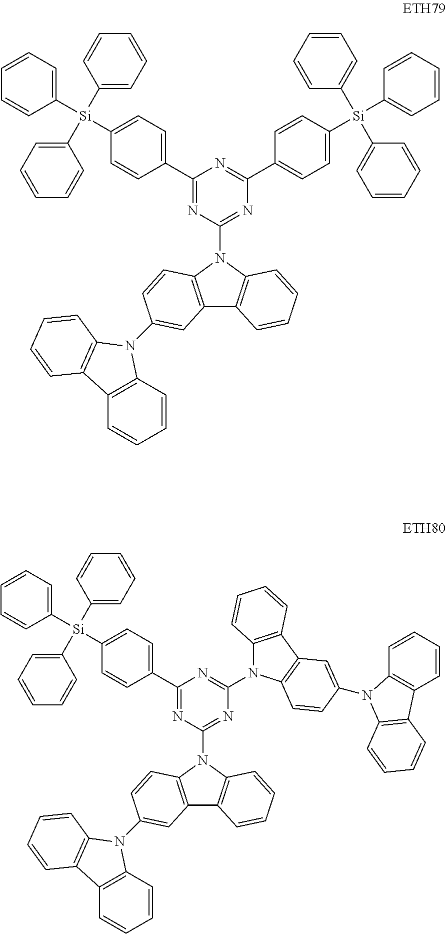

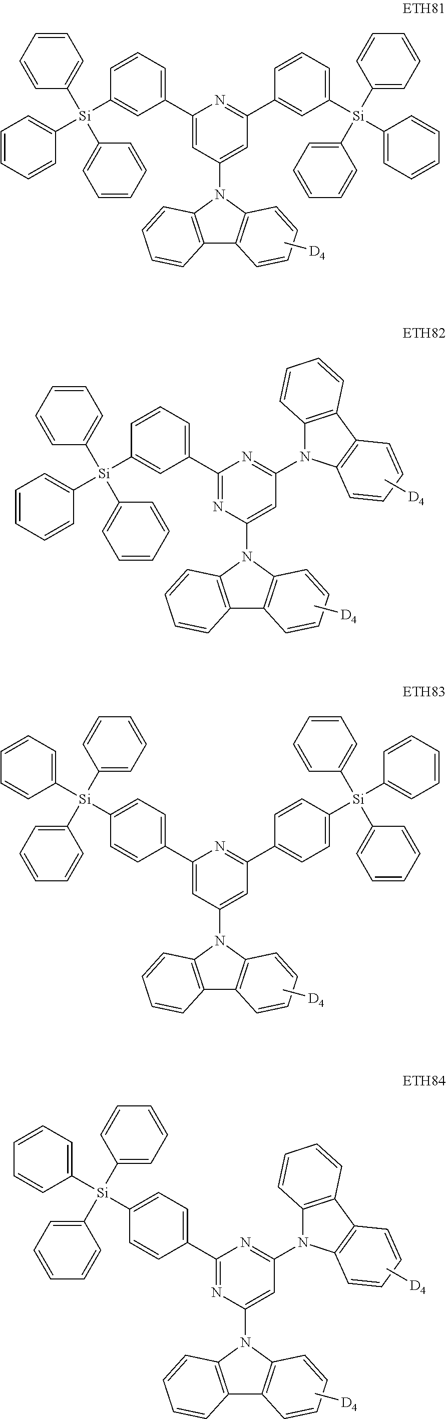

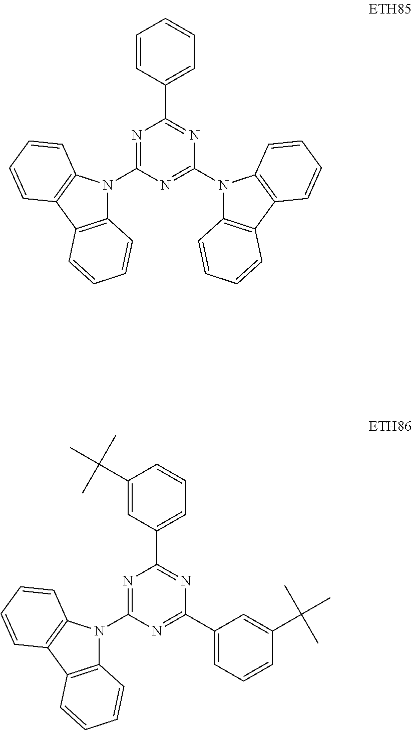 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In Compound Group 3, D represents a deuterium atom, and Ph represents an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy level of the exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, an absolute value of a triplet energy (T1) level of the exciplex formed by the hole transporting host and the electron transporting host may be in a range of about 2.4 eV to about 3.0 eV. The triplet energy level of the exciplex may have a value that is smaller than an energy gap of each host material. The exciplex may have a triplet energy level equal to or less than about 3.0 eV, which is an energy gap between the hole transporting host and the electron transporting host.

In an embodiment, the emission layer EML may include a fourth compound in addition to the first compound, the second compound, and the third compound as described above. The fourth compound may be used as a phosphorescent sensitizer in the emission layer EML. Energy may be transferred from the fourth compound to the first compound, thereby emitting light.

The emission layer EML may include, as a fourth compound, an organometallic complex that includes platinum (Pt) as a central metal atom and ligands connected to the central metal atom. In an embodiment, the emission layer EML may further include a fourth compound represented by Formula D-1:

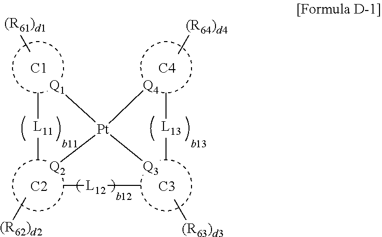

In Formula D-1, Q₁ to Q₄ may each independently be C or N.

In Formula D-1, C1 to C4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms.

In Formula D-1, L₁₁ to L₁₃ may each independently be a direct linkage,

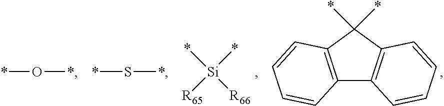

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, [symbol] represents a bond to one of C1 to C4.

In Formula D-1, b11 to b13 may each independently be 0 or 1. If b11 is 0, C1 and C2 may not be directly linked to each other. If b12 is 0, C2 and C3 may not be directly linked to each other. If b13 is 0, C3 and C4 may not be directly linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring. For example, R₆₁ to R₆₆ may each independently be a substituted or unsubstituted methyl group or a substituted or unsubstituted t-butyl group.

In Formula D-1, d1 to d4 may each independently be an integer from 0 to 4. In Formula D-1, if d1 to d4 are each 0, the fourth compound may not be substituted with any of R₆₁ to R₆₄. A case where d1 to d4 are each 4 and groups of each of R₆₁ to R₆₄ are hydrogen atoms may be the same as a case where d1 to d4 are each 0. When d1 to d4 are each 2 or more, multiple groups of each R₆₁ to R₆₄ may each be the same as each other, or at least one group thereof may be different from the remainder.

In an embodiment, in Formula D-1, C1 to C4 may each independently be a substituted or unsubstituted hydrocarbon ring or a substituted or unsubstituted heterocycle that is represented by any one of Formula C-1 to Formula C-4:

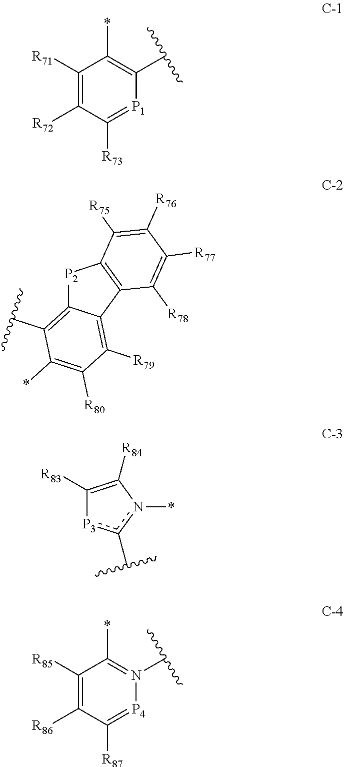

In Formula C-1 to Formula C-4, P₁ may be C—* or C(R₇₄), P₂ may be N—* or N(R₈₁), P₃ may be N—* or N(R₈₂), and P₄ may be C—* or C(R₈₈).

In Formula C-1 to Formula C-4, R₇₁ to R₈₈ may each independently be a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In addition, in Formula C-1 to Formula C-4,

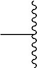

represents a bond to Pt, which is a central metal atom, and [symbol] represents a bond to a neighboring cyclic group (C1 to C4) or to a linker (L₁₁ to L₁₃).

In an embodiment, the emission layer EML may include the first compound represented by Formula 1, and at least one of the second compound, the third compound, and the fourth compound. In an embodiment, the emission layer EML may include the first compound, the second compound, and the third compound. In the emission layer EML, the second compound and the third compound may form an exciplex, and energy may be transferred from the exciplex to the first compound, thereby emitting light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby emitting light. In an embodiment, the fourth compound may be a sensitizer. The fourth compound included in the emission layer EML of the light-emitting element ED may serve as a sensitizer to transfer energy from the host to the first compound, which is a light emitting dopant. For example, the fourth compound, which serves as an auxiliary dopant, accelerates energy transfer to the first compound, which serves as a light emitting dopant, thereby increasing an emission ratio of the first compound. Therefore, the emission layer EML may improve luminous efficiency. When energy delivery to the first compound is increased, excitons formed in the emission layer EML may not accumulate inside the emission layer EML and may emit light rapidly, so that deterioration of the device may be reduced. Therefore, the service life of the light-emitting element ED may increase.

The light-emitting element ED may include the first compound, the second compound, the third compound, and the fourth compound, and the emission layer EML may include the combination of two host materials and two dopant materials. In the light-emitting element ED, the emission layer EML may include the second compound and the third compound, which are two different hosts, the first compound which emits delayed fluorescence, and the fourth compound which includes an organometallic complex, and thus the light-emitting element ED may exhibit excellent luminous efficiency characteristics.

In an embodiment, the fourth compound represented by Formula D-1 may be selected from Compound Group 4. In an embodiment, in the light-emitting element ED, the fourth compound may include at least one compound selected from Compound Group 4.

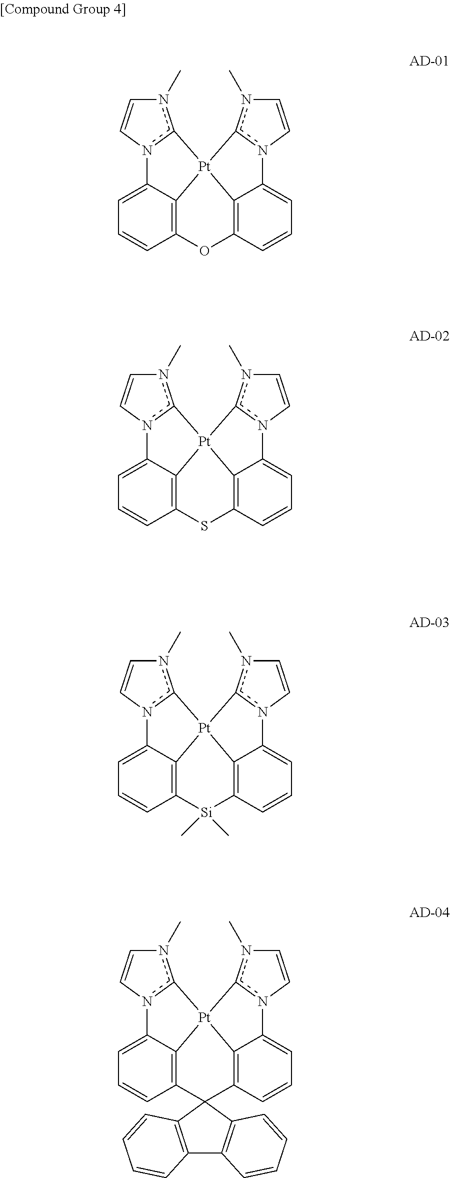

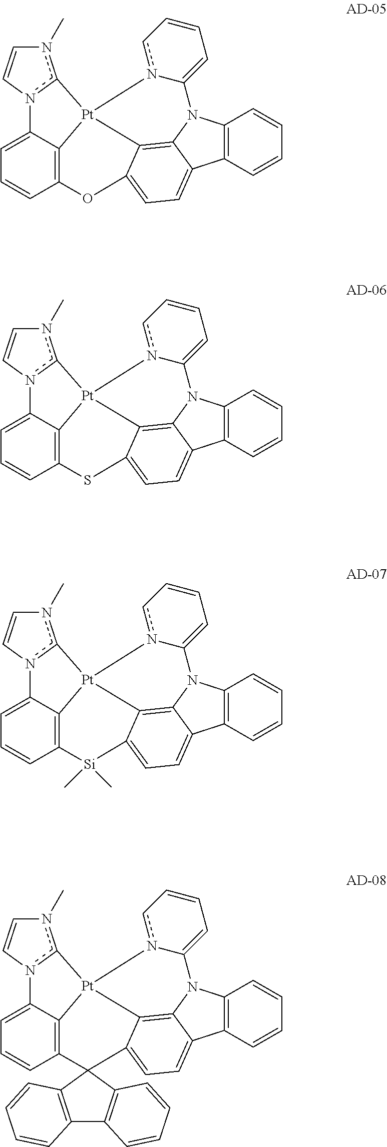

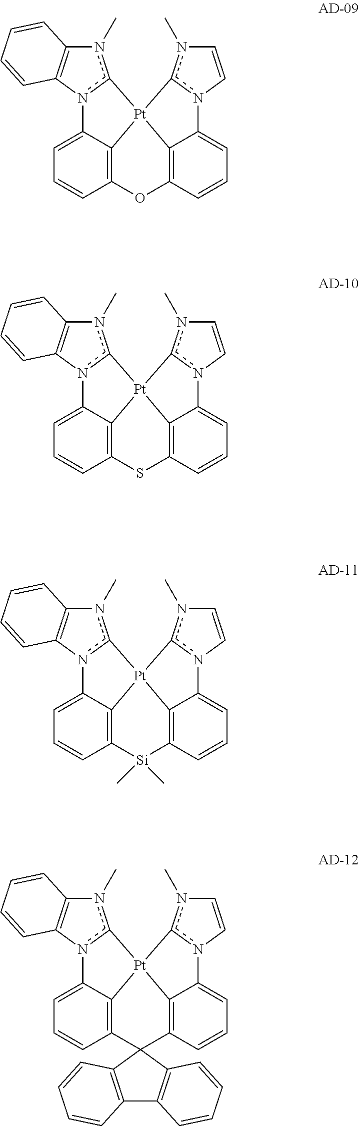

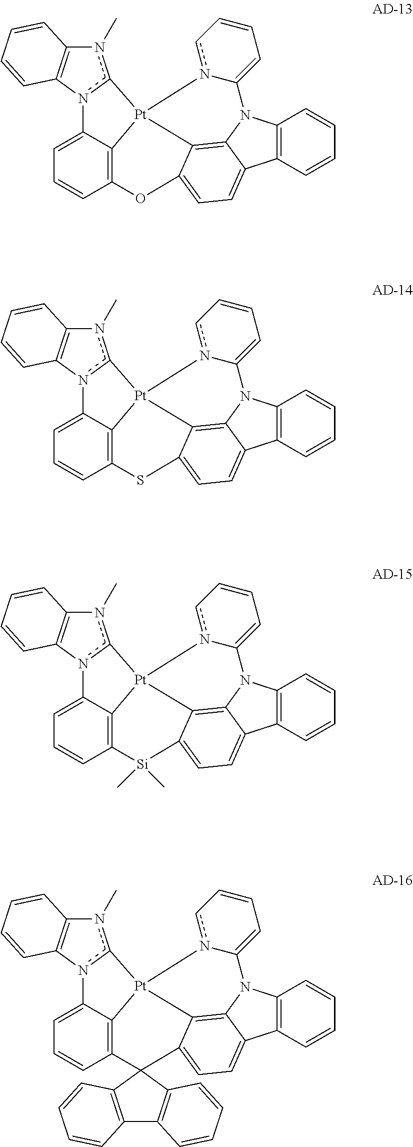

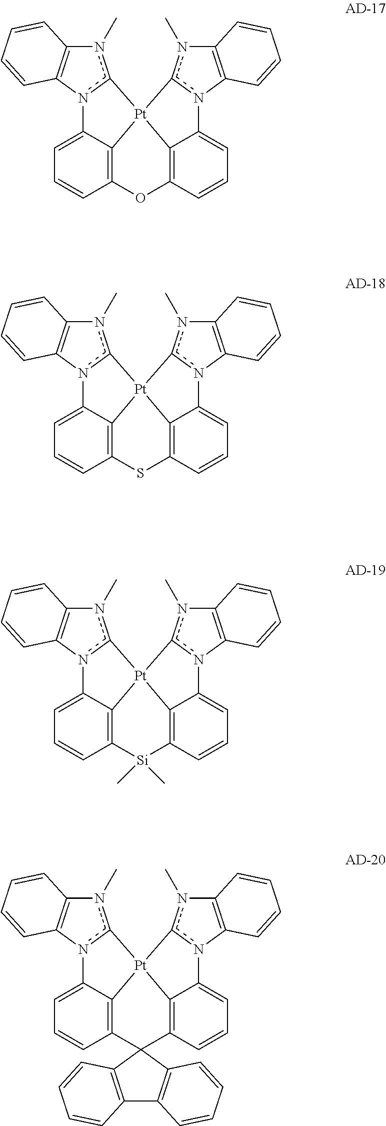

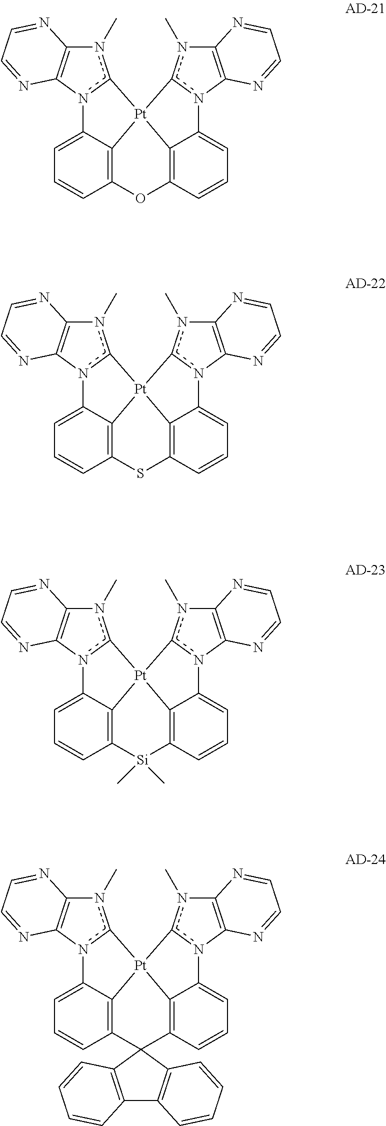

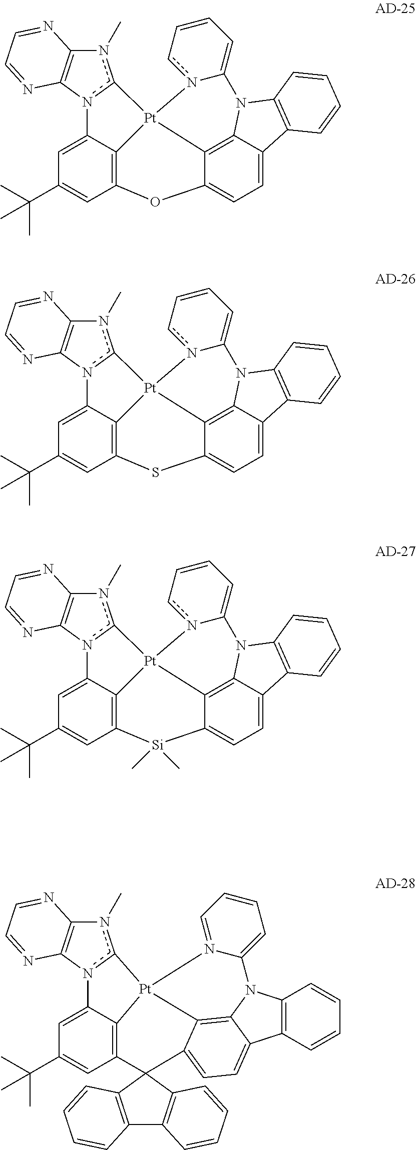

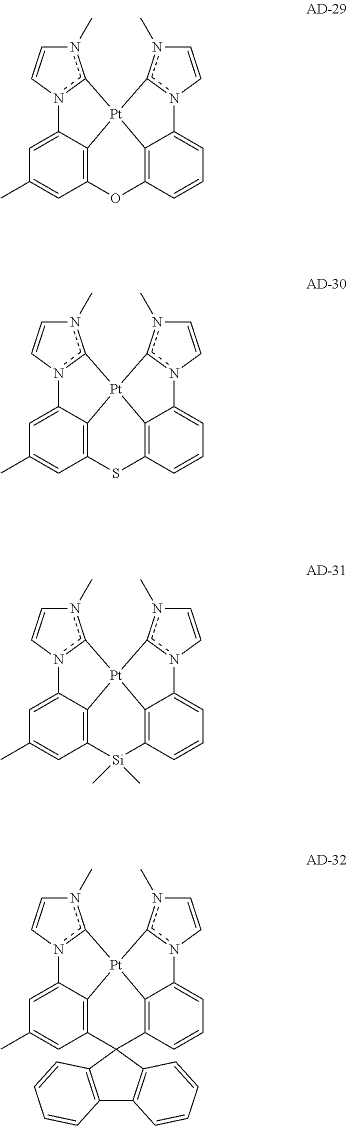

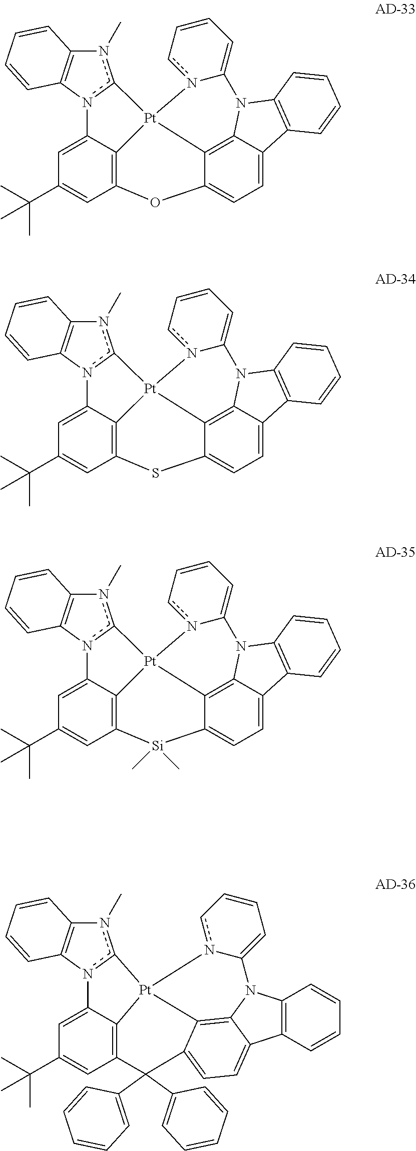

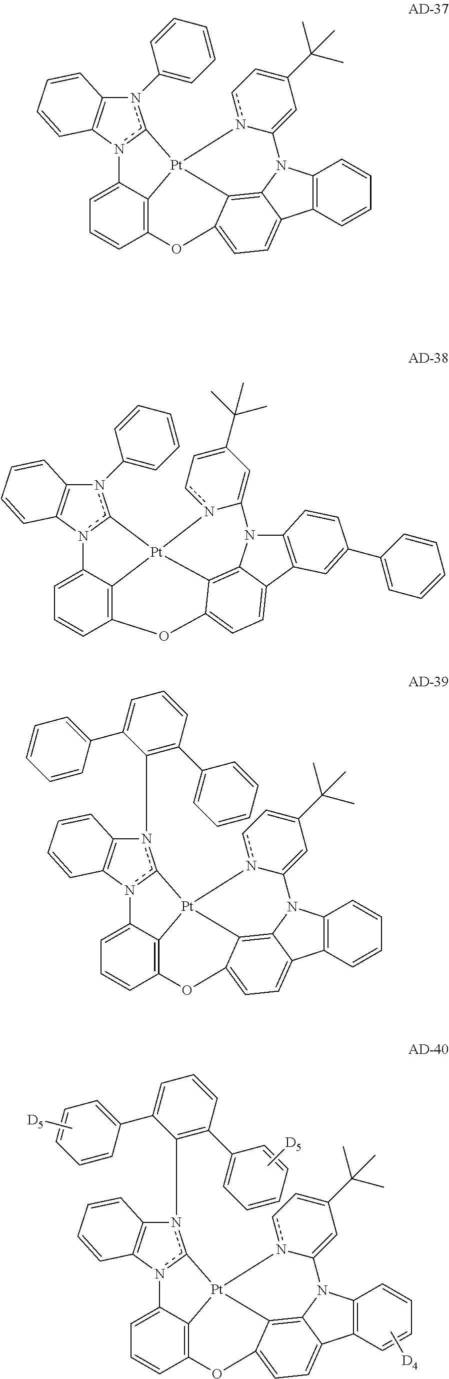

In Compound Group 4, D represents a deuterium atom.

When the emission layer EML in the light-emitting element ED includes the first compound, the second compound, and the third compound, an amount of the first compound may be in a range of about 0.1 wt % to about 5 wt %. However, embodiments are not limited thereto. When an amount of the first compound satisfies the above-described range, the energy transfer from the second compound and the third compound to the first compound may increase, and thus the luminous efficiency and device service life may increase.

The combined amounts of the second compound and the third compound in the emission layer EML may be the remainder of the total weight of the first compound, the second compound, and the third compound, excluding the amount of the first compound. For example, a total amount of the second compound and the third compound in the emission layer EML may be in a range of about 65 wt % to about 95 wt % with respect to a total weight of the first compound, the second compound, and the third compound.

Within the total amount of the second compound and the third compound in the emission layer EML, a weight ratio of the second compound to the third compound may be in a range of about 3:7 to about 7:3.

When the amounts of the second compound and the third compound satisfy the above-described ranges and ratios, charge balance characteristics in the emission layer EML may be improved, and thus the luminous efficiency and device service life may increase. When the amounts of the second compound and the third compound deviate from the above-described ranges and ratios, a charge balance in the emission layer EML may not be achieved, and thus the luminous efficiency may be reduced and the device may readily deteriorate.

When the emission layer EML includes the fourth compound, an amount of the fourth compound in the emission layer EML may be in a range of about 10 wt % to about 30 wt %, with respect to a total weight of the first compound, the second compound, the third compound, and the fourth compound. However, embodiments are not limited thereto. When an amount of the fourth compound satisfies the above-described range, energy transfer from the host to the first compound, which is a light emitting dopant, may increase, so that a luminous ratio may be improved, and thus the luminous efficiency of the emission layer EML may be improved. When the amounts of first compound, the second compound, the third compound, and the fourth compound included in the emission layer EML satisfy the above-described ranges and ratios, excellent luminous efficiency and long service life may be achieved.

The emission layer EML may be provided on the hole transport region HTR. A thickness of the emission layer EML may be in a range of about 100 Å to about 1,000 Å. For example, a thickness of the emission layer EML may be in a range of about 100 Å to about 300 Å.

The emission layer EML may be a layer consisting of a single material, a layer including different materials, or a structure having multiple layers including different materials.

In the light-emitting element ED, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light-emitting element ED according to embodiments as shown in each of FIGS. 3 to 7, the emission layer EML may further include a host and a dopant of the related art, in addition to the above-described host.

In an embodiment, the emission layer EML may include a compound represented by Formula E-1. The compound represented by Formula E-1 may be used as a fluorescent host material.

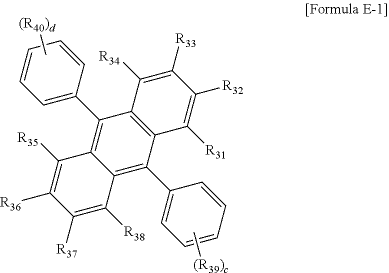

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, in Formula E-1, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19:

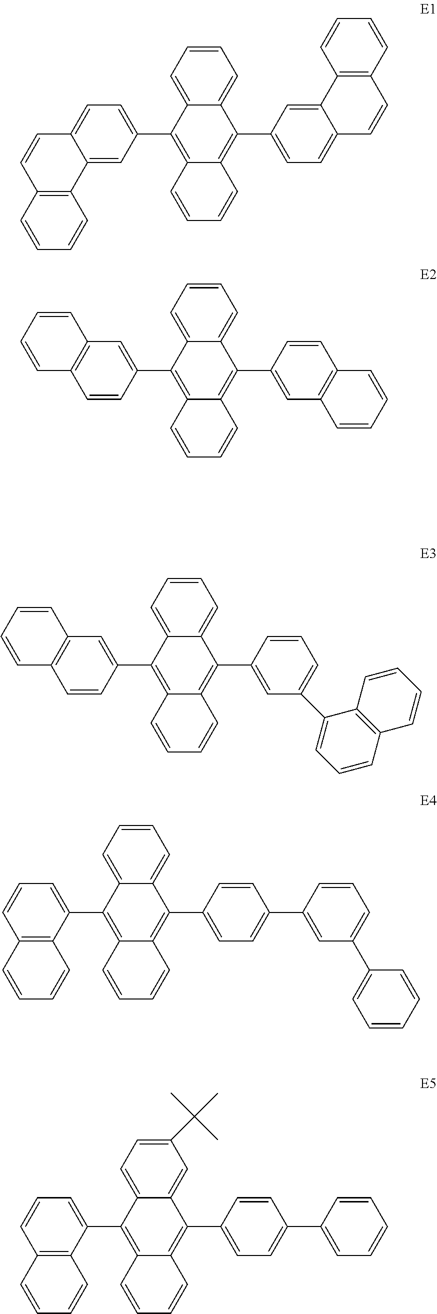

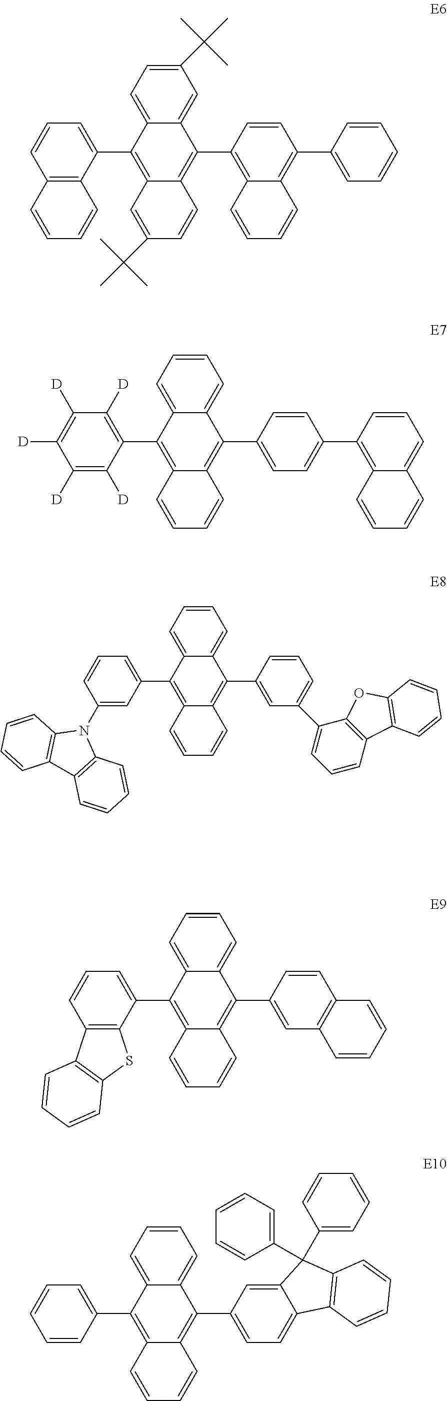

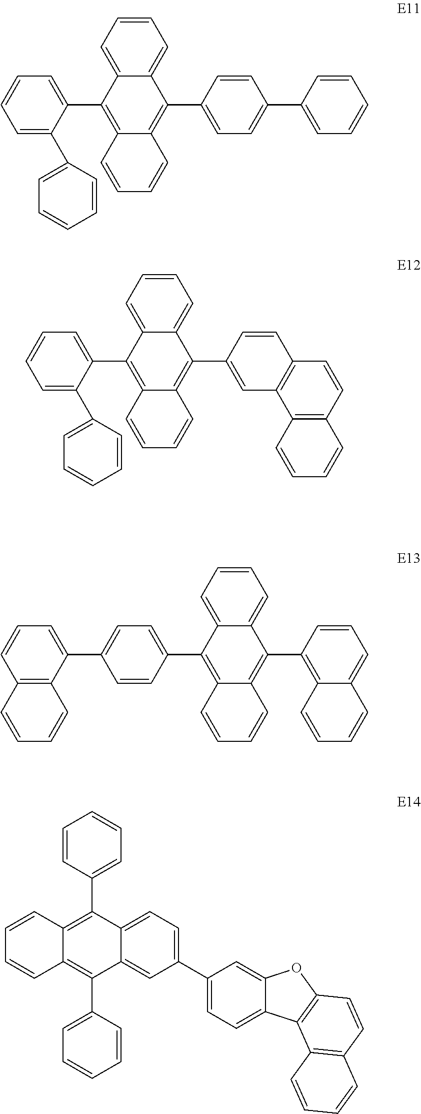

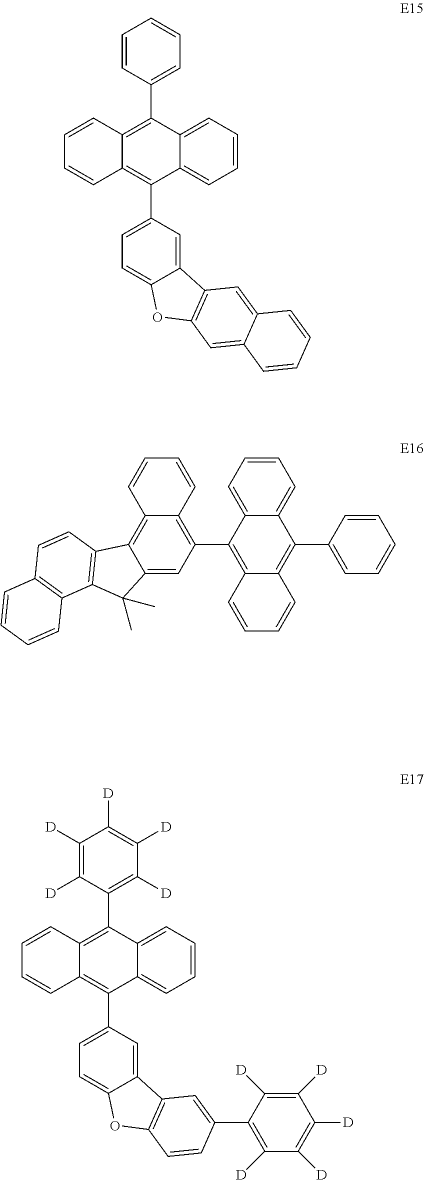

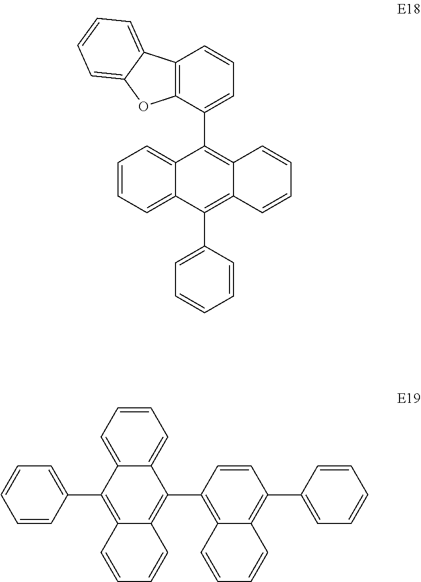

In an embodiment, the emission layer EML may include a compound represented by Formula E-2a or Formula E-2b. The compound represented by Formula E-2a or Formula E-2b may be used as a phosphorescent host material.

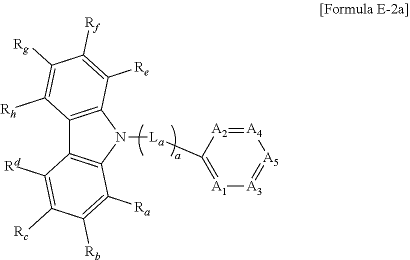

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple Lₐ's may each independently be a substituted or unsubstituted arylene group having 6 to 30 ring-forming carbon atoms, or a substituted or unsubstituted heteroarylene group having 2 to 30 ring-forming carbon atoms.

In addition, in Formula E-2a, A₁ to A₅ may each independently be N or C(Rᵢ). Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Rₐ to Rᵢ may be bonded to an adjacent group to form a hydrocarbon ring or a heterocycle containing N, O, S, etc., as a ring-forming atom.

In embodiments, in Formula E-2a, two or three selected from A₁ to A₅ may be N, and the remainder of A₁ to A₅ may be C(Rᵢ).

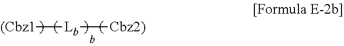

In Formula E-2b, Cbz1 and Cbz2 may each independently be an unsubstituted carbazole group, or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. In embodiments, b is an integer from 0 to 10, and when b is 2 or more, multiple L_{b} groups may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

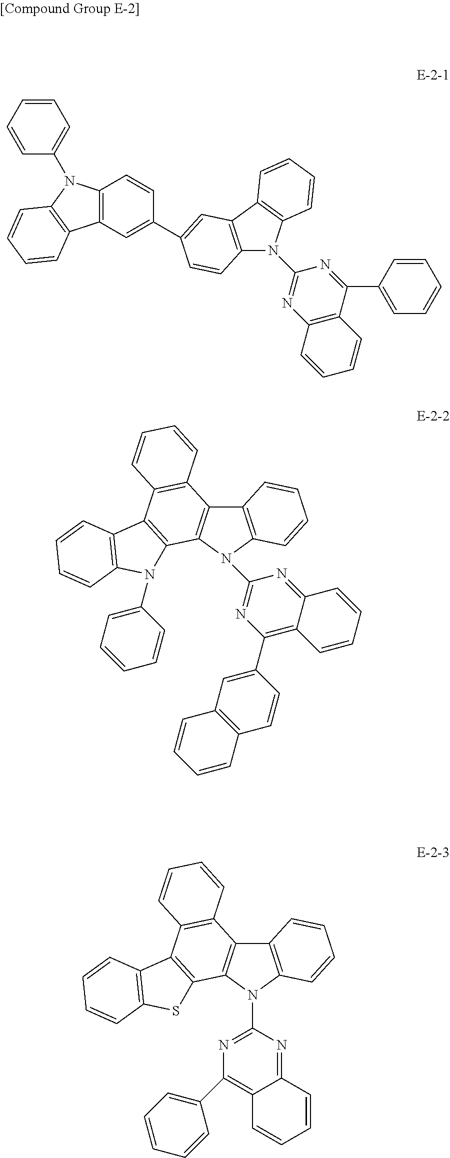 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

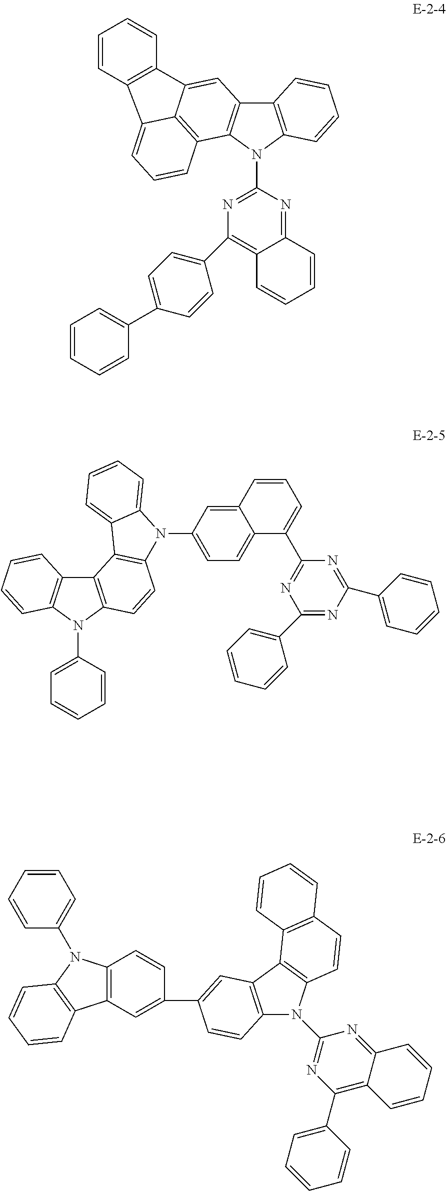 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

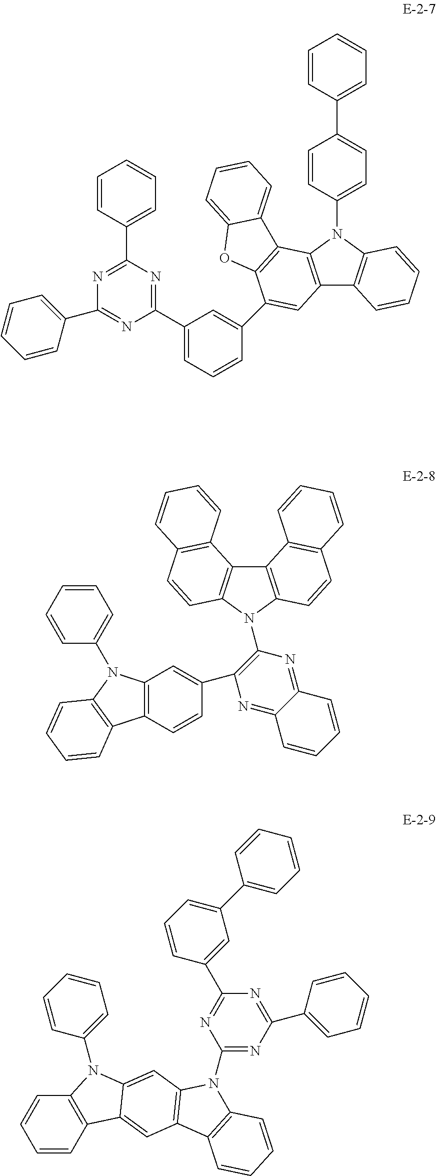 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

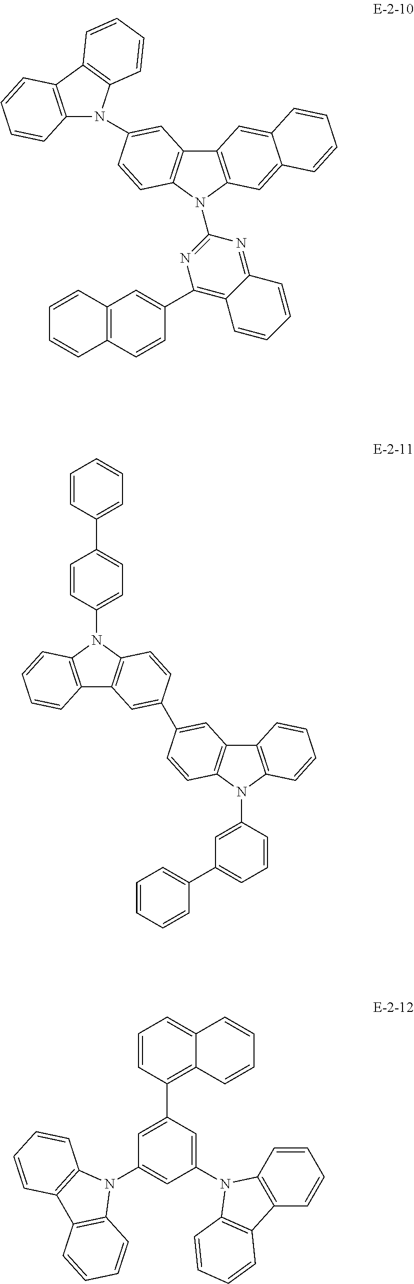 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

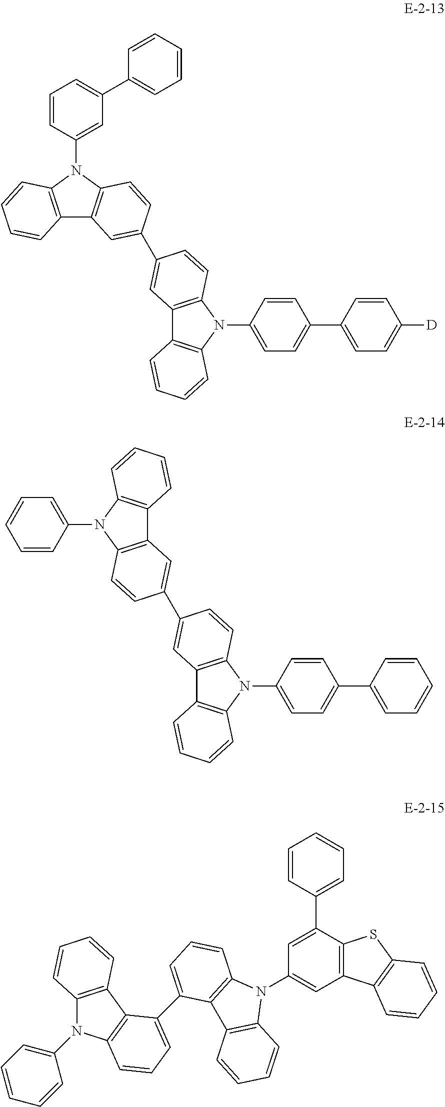 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

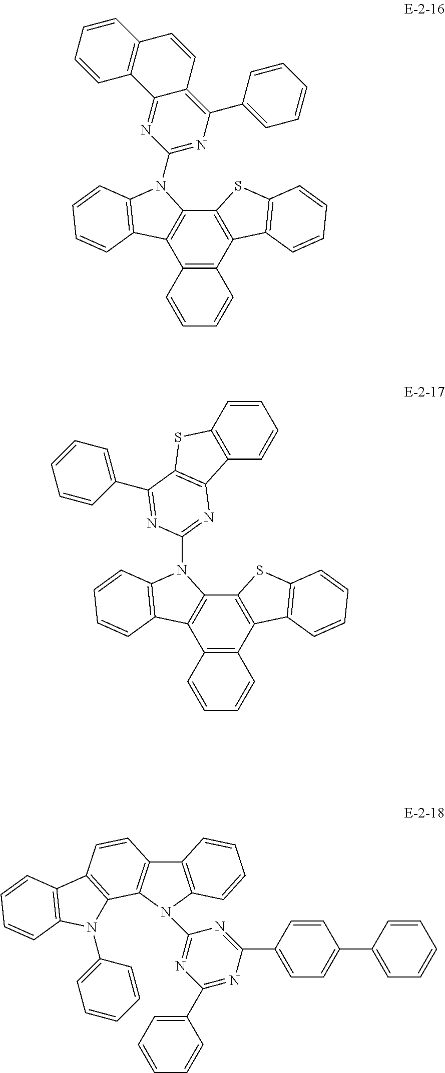 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

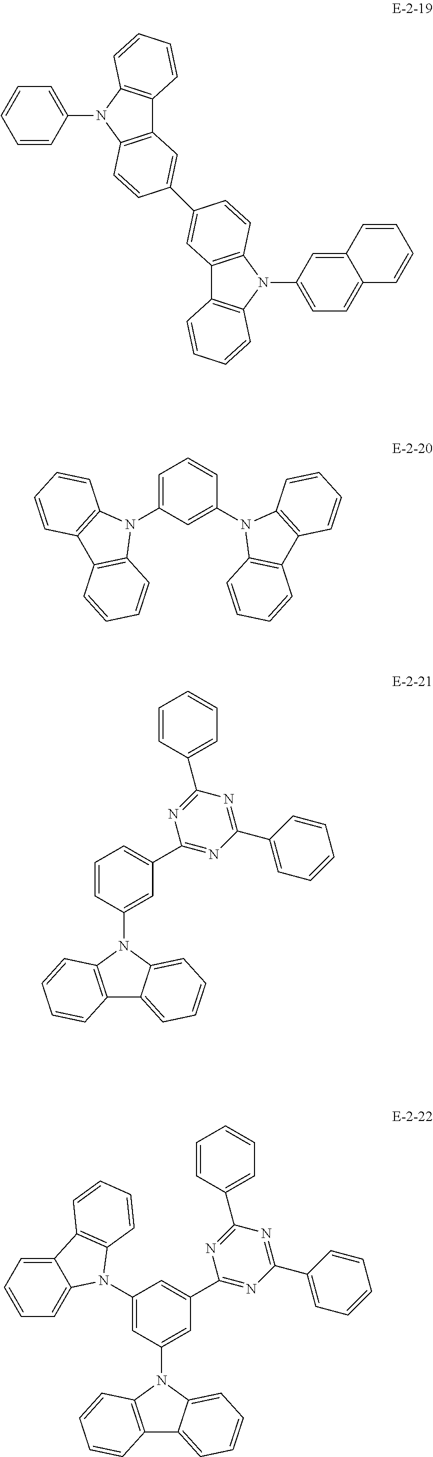 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

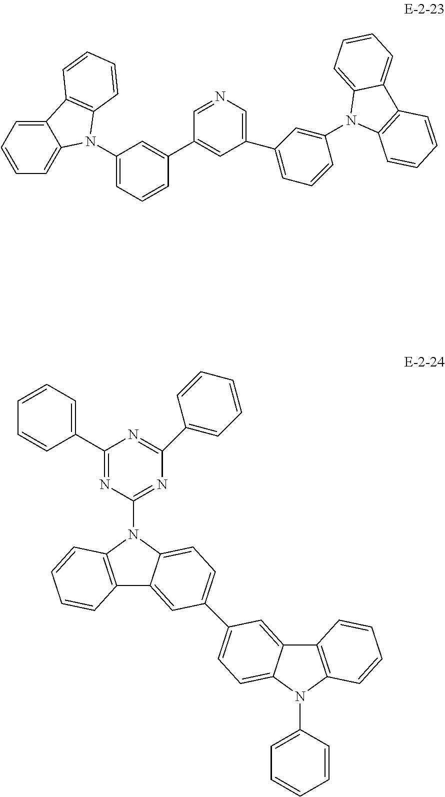 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolino)aluminum (Alq₃) 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

In an embodiment, the emission layer EML may include a compound represented by Formula M-a. The compound represented by Formula M-a may be used as a phosphorescent dopant material.

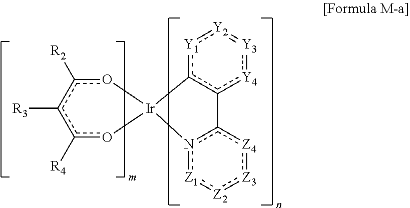

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

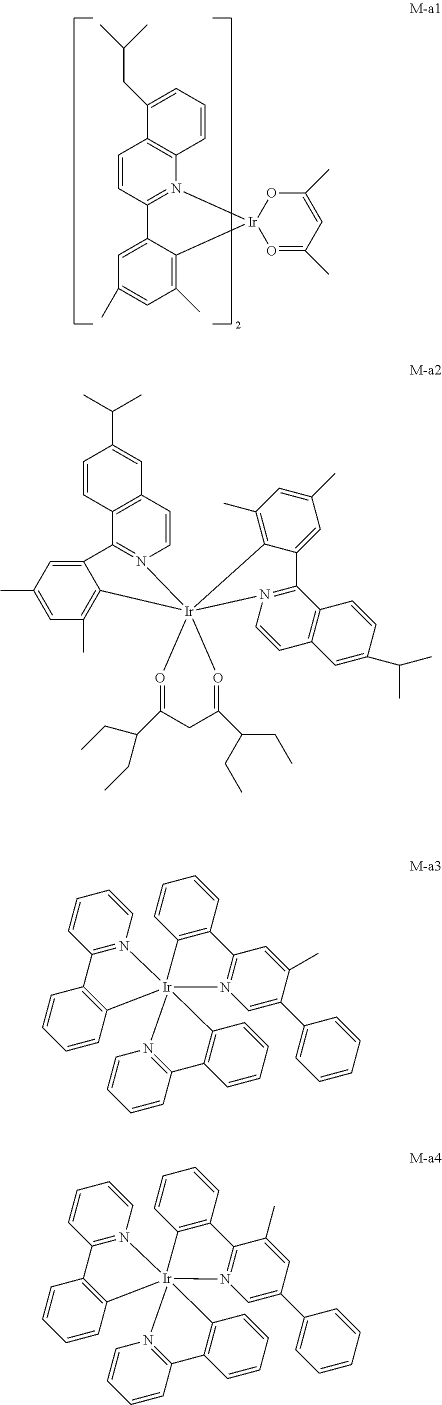

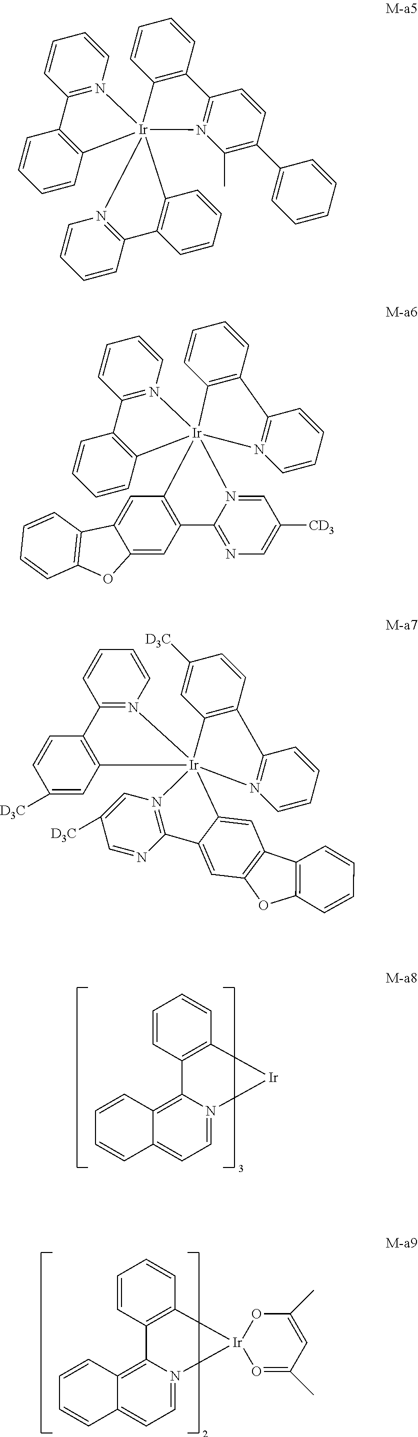

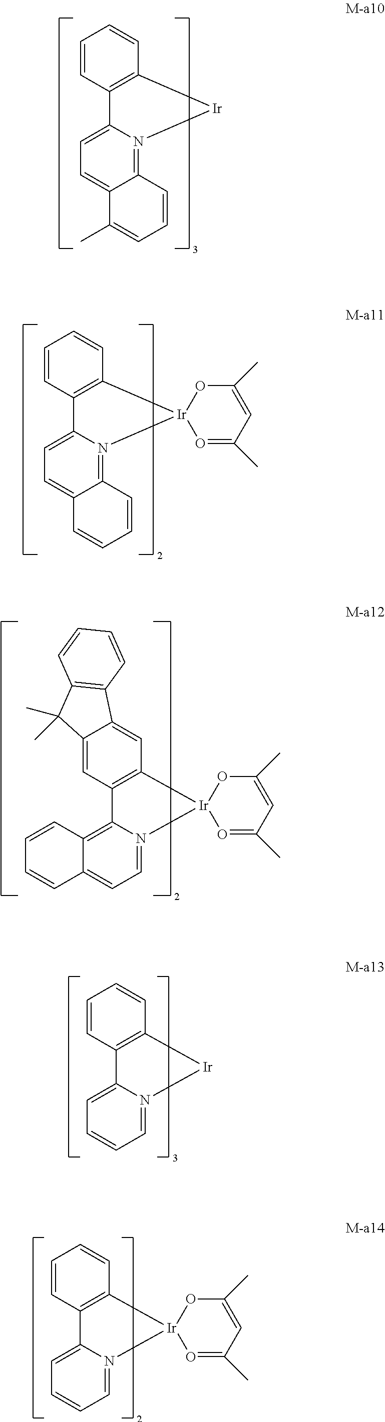

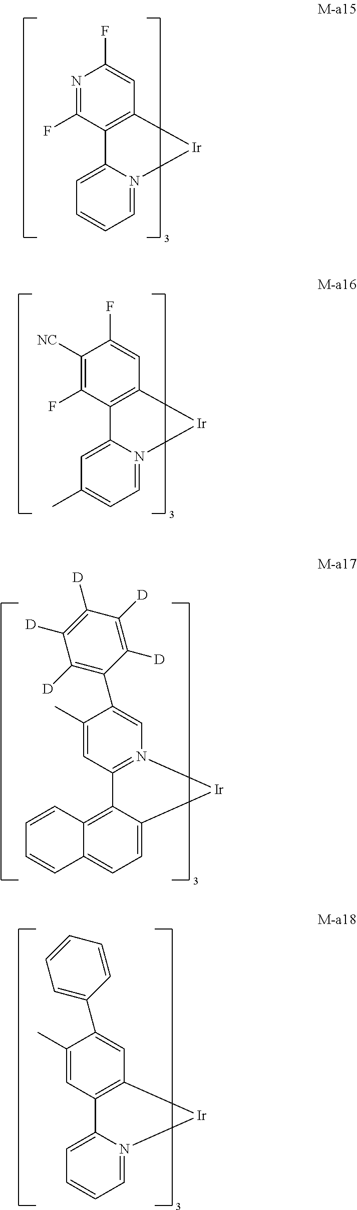

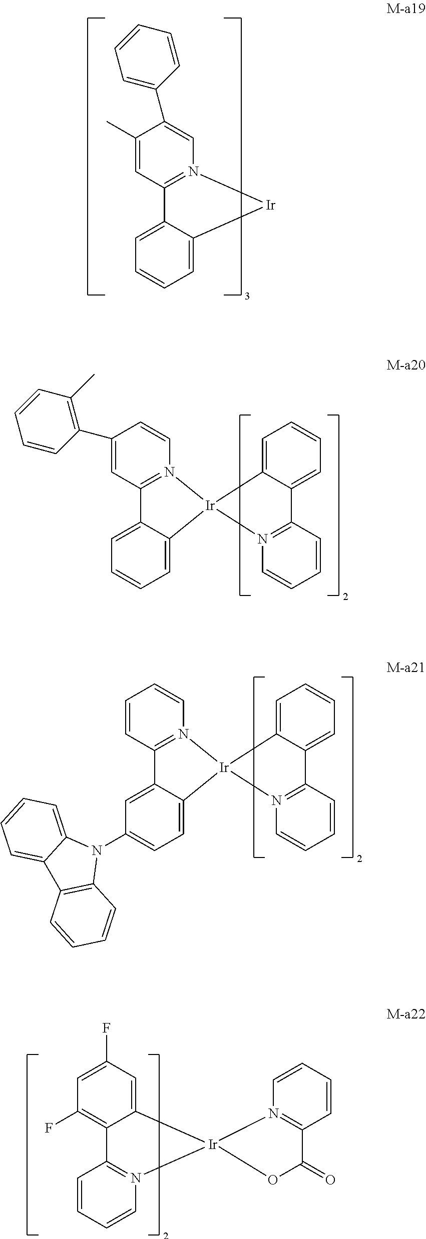

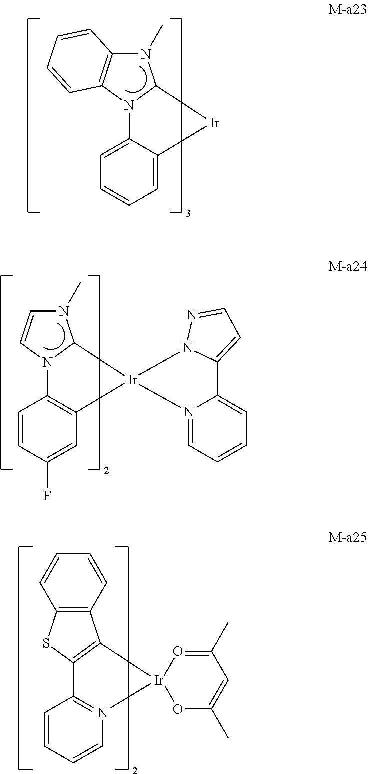

In an embodiment, the emission layer EML may include a compound represented by any one of Formula F-a to Formula F-c. The compound represented by one of Formula F-a to Formula F-c may be used as a fluorescence dopant material.

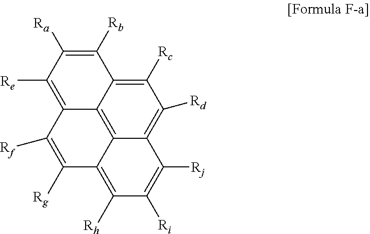

In Formula F-a, two of Rₐ to Rⱼ may each independently be substituted with a group represented by *—NAr₁Ar₂. The remainder of Rₐ to Rⱼ which are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ and Ar₂ may be a heteroaryl group including O or S as a ring-forming atom.

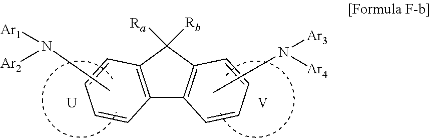

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ to Ar₄ may be a heteroaryl group including O or S as a ring-forming atom.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. When the number of U or V is 1, a fused ring may be present at a portion indicated by U or V, and when the number of U or V is 0, a fused ring may not be present at the portion indicated by U or V. When the number of U is 0 and the number of V is 1, or when the number of U is 1 and the number of V is 0, the fused ring having a fluorene core of Formula F-b may be a cyclic compound having four rings. When the number of U and V is each 0, a fused ring having a fluorene core of Formula F-b may be a cyclic compound having three rings. When the number of U and V is each 1, a fused ring having a fluorene core of Formula F-b may be a cyclic compound having five rings.

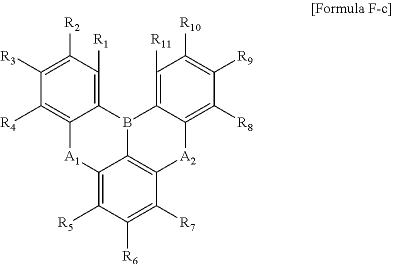

In Formula F-c, A₁ and A₂ may each independently be O, S, Se, or N(Rₘ), and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In Formula F-c, A₁ and A₂ may each independently be bonded to a substituent of an adjacent ring to form a fused ring. For example, when A₁ and A₂ are each independently N(Rₘ), A₁ may be bonded to R₄ or R₅ to form a ring. For example, A₂ may be bonded to R₇ or R₈ to form a ring.

In an embodiment, the emission layer EML may further include, as a dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex including iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2′)picolinate) (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

In an embodiment, the emission layer EML may include a quantum dot. A quantum dot may be Group II-VI compounds, Group I-II-VI compounds, Group II-IV-VI compounds, Group I-II-IV-VI compounds, Group II-IV-V compounds, Group III-VI compounds, Group I-III-VI compounds, Group III-V compounds, Group III-II-V compounds, Group IV-VI compounds, Group IV elements, Group IV compounds and a combination thereof.

Examples of a Group II-VI compound may include: binary compounds selected from the group consisting of CdSe, CdTe, CdS, ZnS, ZnSe, ZnTe, ZnO, HgS, HgSe, HgTe, MgSe, MgS, and a mixture thereof; ternary compounds selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compounds selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof; or any combination thereof.

Examples of a Group II-VI compound may include: a Group I metal and/or a Group IV element.

Examples of a Group I-II-VI compound may include CuSnS or CuZnS.

Examples of a Group II-IV-VI compound may include ZnSnS and the like.

Examples of a Group I-II-IV-VI compound may include a quaternary compound selected from the group consisting of Cu₂ZnSnS₂, Cu₂ZnSnS₄, Cu₂ZnSnSe₄, Ag₂ZnSnS₂, and a mixture thereof.

Examples of a Group II-IV-V compound may include ternary compounds selected from the group consisting of ZnSnP, ZnSnP₂, ZnSnAs₂, ZnGeP₂, ZnGeAs₂, CdSnP₂, CdGeP₂, and a mixture thereof.

Examples of a Group III-VI compound may include: a binary compound such as GaS, Ga₂S₃, GaSe, Ga₂Se₃, GaTe, InTe, InS, InSe, In₂S₃, In₂Se₃; a ternary compound such as InGaS₃, InGaSe₃; or any combination thereof.

Examples of a Group I-III-VI compound may include: a ternary compound selected from the group consisting of AgInS, AgInS₂, CuInS, CuInS₂, AgGaS₂, CuGaS₂ CuGaO₂, AgGaO₂, AgAlO₂; a quaternary compound such as AgInGaS₂, AgInGaSe₂, and CuInGaS₂; or any combination thereof.

Examples of a Group III-V compound may include: a binary compound selected from the group consisting of GaN, GaP, GaAs, GaSb, AlN, AlP, AlAs, AlSb, InN, InP, InAs, InSb; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb; or any combination thereof. In embodiments, the Group III-V compound may further include a Group II metal. Examples of the Group III-II-V compound may include InZnP and the like.

Examples of a Group IV-VI compound may be selected from the group consisting of: a binary compound selected from the group consisting of SnS, SnSe, SnTe, PbS, PbSe, PbTe; a ternary compound selected from the group consisting of SnSeS, SnSeTe, SnSTe, PbSeS, PbSeTe, PbSTe, SnPbS, SnPbSe, SnPbTe; and a quaternary compound selected from the group consisting of SnPbSSe, SnPbSeTe, SnPbSTe; or any combination thereof.

Examples of the Group IV element may include: a single element material, such as Si, Ge; a binary compound, such as SiC or SiGe; or any combination thereof.

Each element included in the multi-component compound, such as a binary compound, a ternary compound, or a quaternary compound may be present in a particle at a uniform concentration or at a non-uniform concentration. For example, a formula may indicate the elements included in a compound, but an element ratio in the compound may differ. For example, AgInGaS₂ may mean AgInₓGa₁₋ₓS₂ (where, x is a real number from 0 to 1).

In embodiments, a quantum dot may have a single structure, in which the concentration of each element included in the quantum dot is uniform, or a quantum dot may have a core-shell structure in which a quantum dot surrounds another quantum dot. For example, a material included in the core and a material included in the shell may be different from each other.

The shell of the quantum dot may serve as a protective layer for preventing the core from a chemical alteration to maintain semiconductor characteristics, and/or may serve as a charging layer for imparting electrophoretic characteristics to the quantum dot. The shell may be a single layer or a multilayer. An interface of the core and shell may have a concentration gradient that the concentration of the elements that is present in the shell decreases toward the core.

In embodiments, the quantum dot may have a core-shell structure, which includes a core including the-described nanocrystal and a shell surrounding the core. Examples of a shell of a quantum dot may include a metal oxide, a non-metal, a semiconductor compound, or a combination thereof.

Examples of a metal oxide or a non-metal may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound such as MgAl₂O₄, CoFe₂O₄, NiFe₂O₄, CoMn₂O₄; any combination thereof. However, embodiments are not limited thereto.

Examples of a semiconductor compound may include: CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc. However, embodiments are not limited thereto.

Each element included in multi-component compounds such as a binary compound, a ternary compound may be present in particles at a uniform concentration or a non-uniform concentration. For example, a formula may indicate the elements included in a compound, but an elemental ratio in the compound may differ.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. When FWHM falls within any of the above range, color purity or color reproducibility may be improved. Light emitted through a quantum dot may be emitted in all directions, so that an optical viewing angle may be improved.

The quantum dots may have a spherical shape, a pyramidal shape, a multi-shape arm, or a cubic shape, or the quantum dot may be in the form of a nanoparticle, a nanotube, a nanowire, a nanofiber, a nanoplatelet, and the like. However, embodiments are not limited thereto. Since the energy band gap may be adjusted by adjusting the size of the quantum dot or adjusting an elemental ratio in the quantum dot compound, light with various wavelength bands may be obtained from a quantum dot emission layer. Therefore, by using quantum dots having different sizes or having different elemental ratio in the quantum dot compound, a light-emitting element that emits light with various wavelengths may be achieved. For example, adjustments in the sizes of the quantum dot and an elemental ratio in the quantum dot compound may be selected to emit red light, green light, and/or blue light. In embodiments, the quantum dots may emit white light by combining various colors of light.

In the light-emitting elements ED according to embodiments shown in each of FIGS. 3 to 7, the electron transport region ETR may be provided on the emission layer EML. The electron transport region ETR may include at least one of a hole blocking layer HBL, an electron transport layer ETL, and an electron injection layer EIL, but embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure formed of multiple different materials, or may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto. The electron transport region ETR may have a thickness in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light-emitting element ED according to an embodiment, the electron transport region ETR may include a compound represented by Formula ET-2:

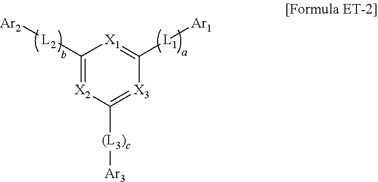

In formula ET-2, at least one of X₁ to X₃ may each be N; and the remainder of X₁ to X₃ may be C(Rₐ). In formula ET-2, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each independently 2 or more, multiple groups of each L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a mixture thereof.

In an embodiment, the electron transport region ETR may include at least one compound selected from Compound ET1 to Compound ET36:

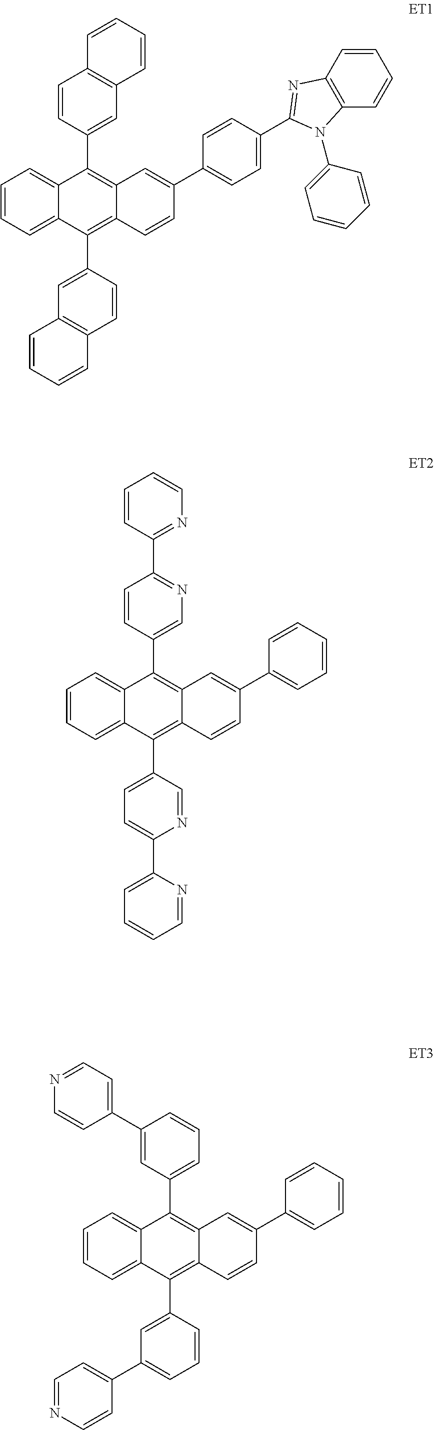 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

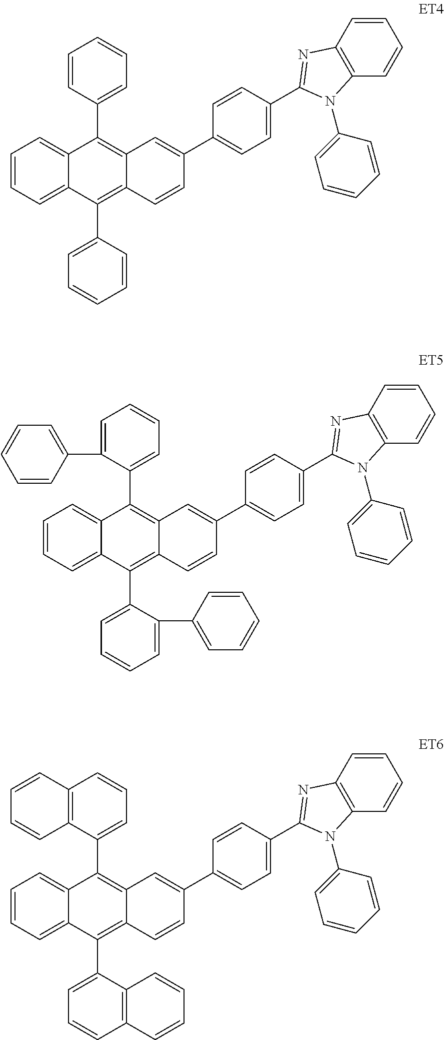 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

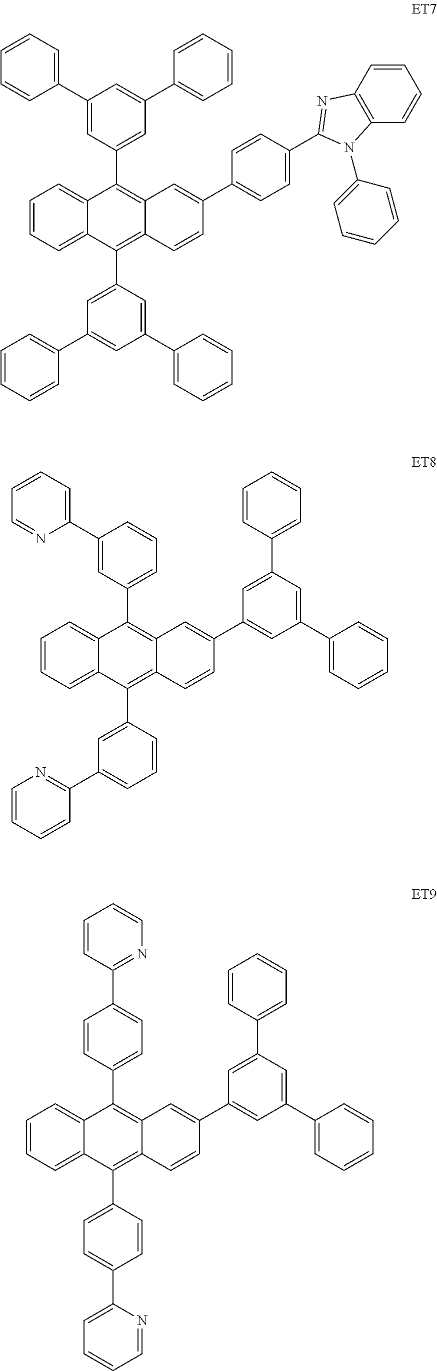 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

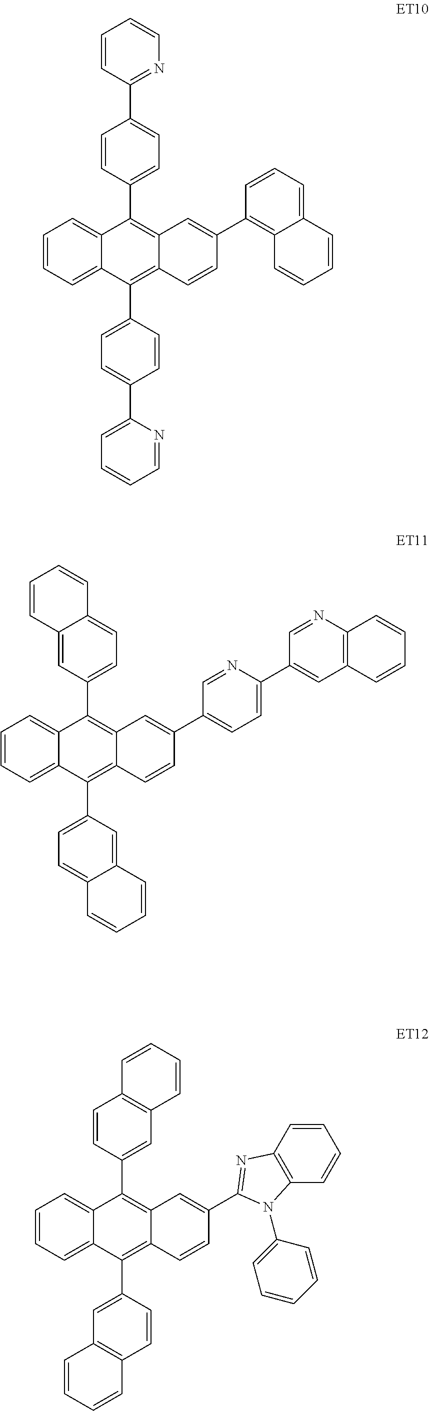 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

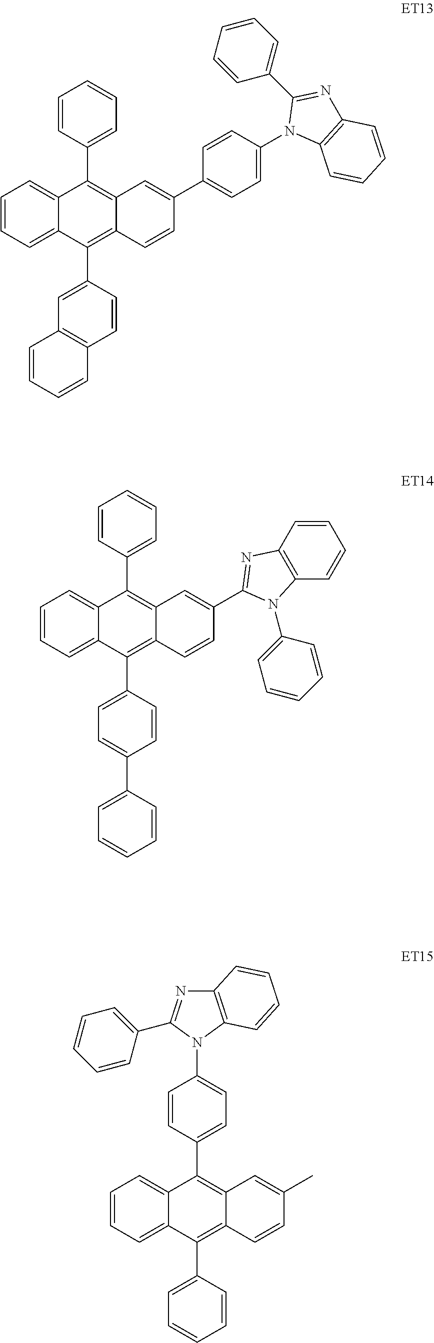 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

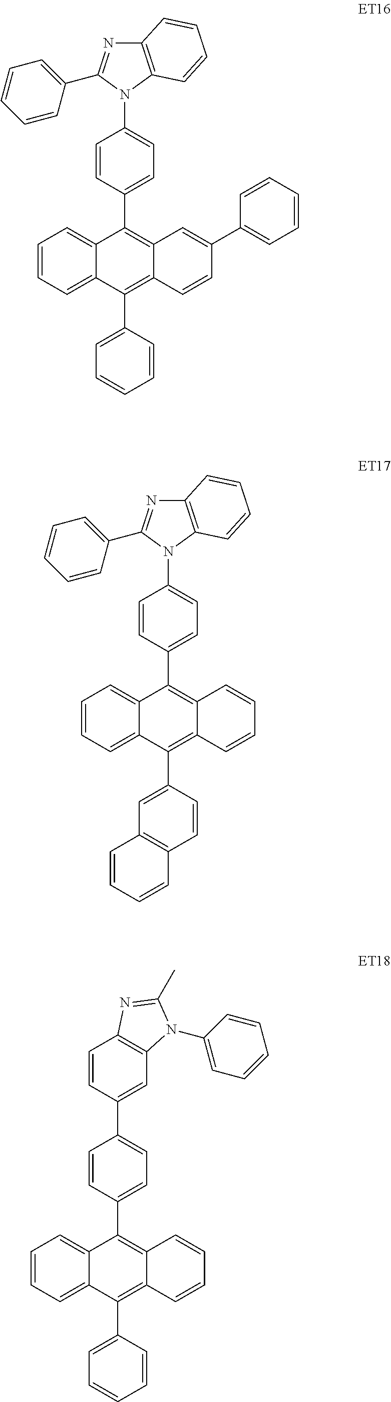 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

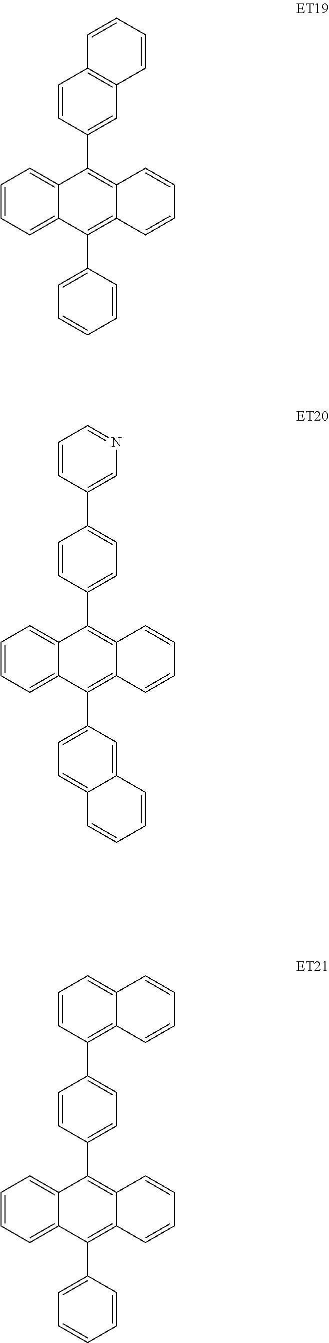

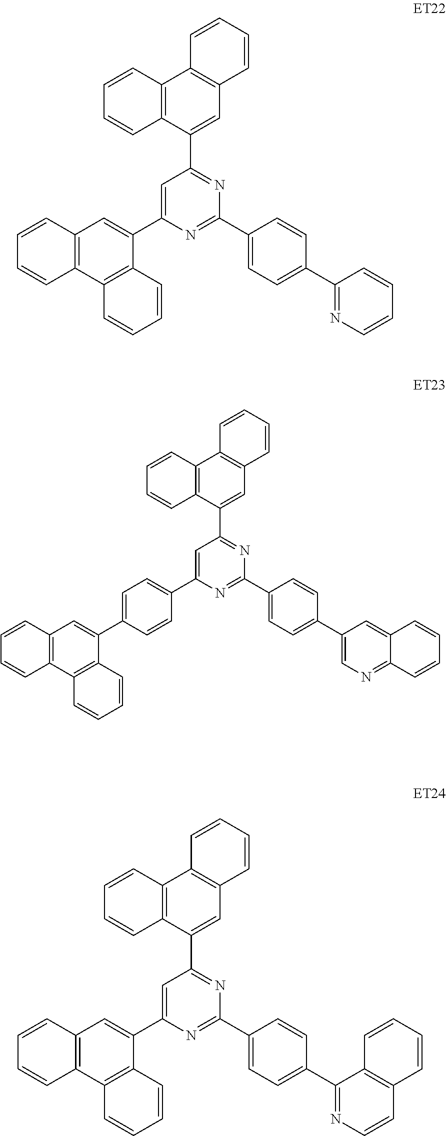 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

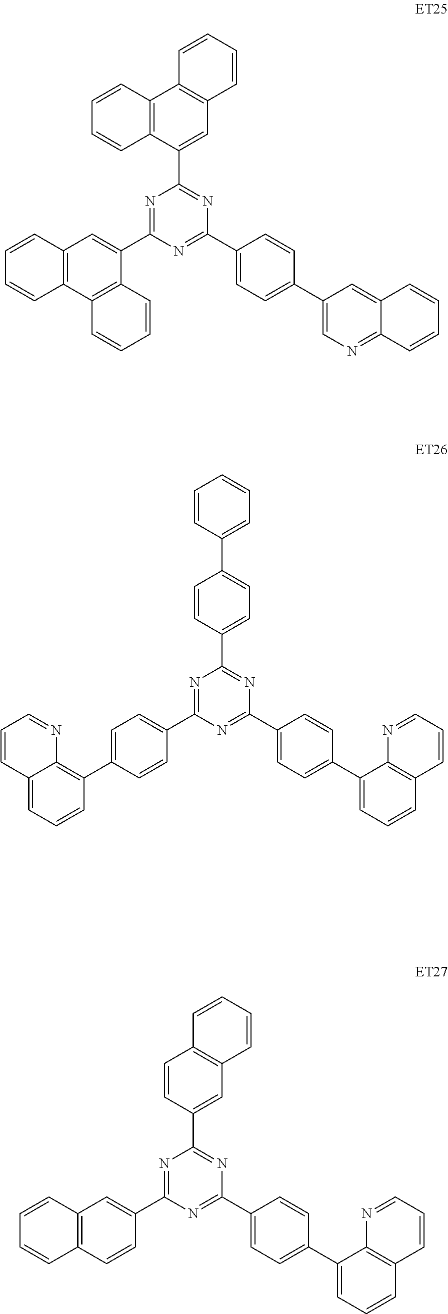 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

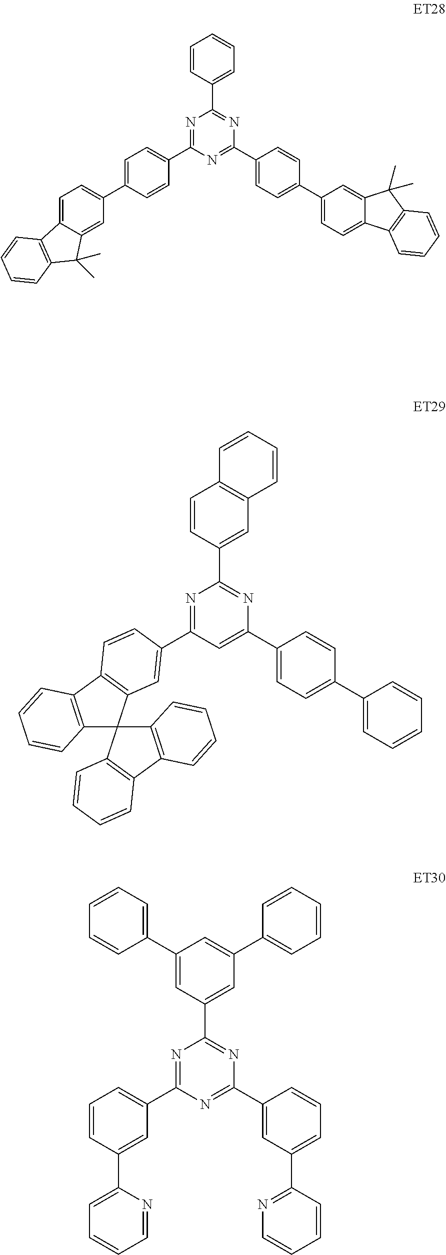 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

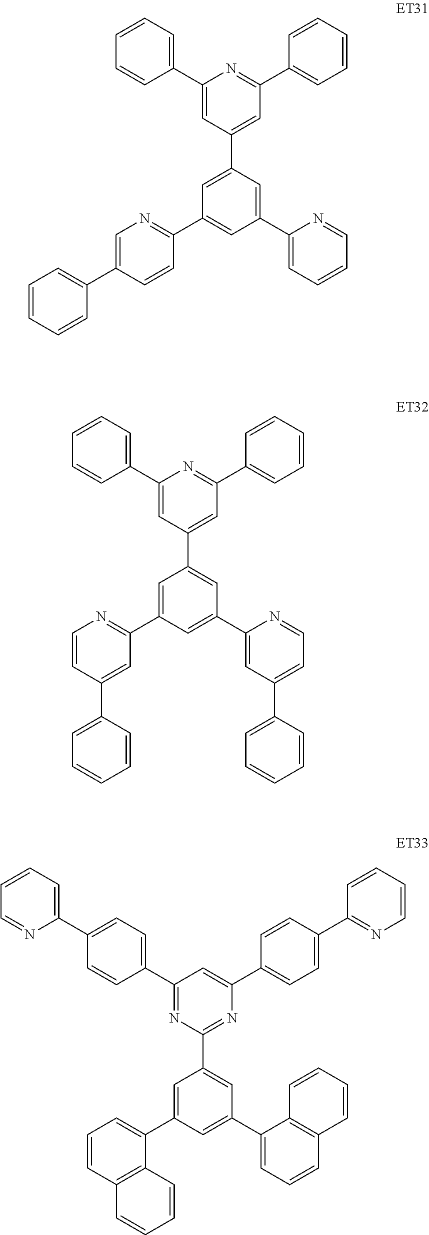 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

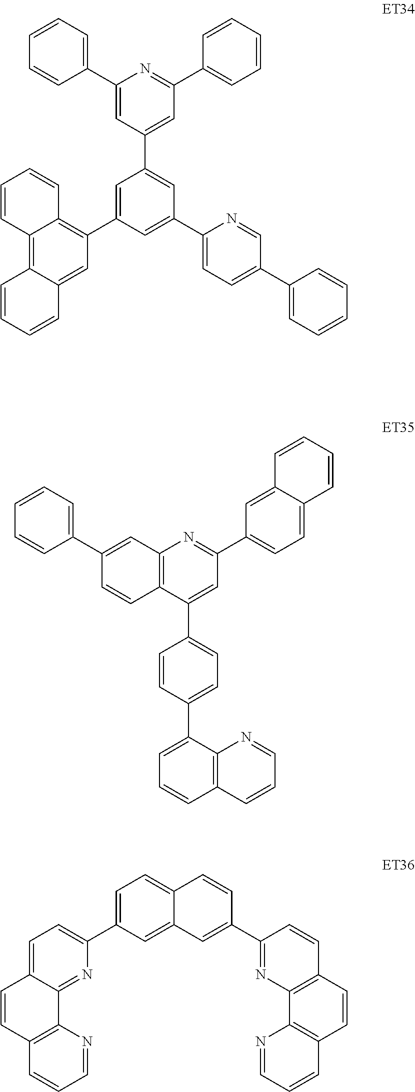 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include: a metal halide such as LiF, NaCl, CsF, RbCl, RbI, CuI, and KI; a lanthanide metal such as Yb, or a co-deposited material of a metal halide and a lanthanide metal. For example, the electron transport region ETR may include KI:Yb, RbI:Yb, LiF:Yb, etc., as a co-deposited material. The electron transport region ETR may be formed of a metal oxide such as Li₂O or BaO, or 8-hydroxyl-lithium quinolate (Liq), etc., but embodiments are not limited thereto. The electron transport region ETR may also be formed of a mixture material of an electron transport material and an insulating organometallic salt. The insulating organometallic salt may be a material having an energy band gap equal to or greater than about 4 eV. For example, the insulating organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, embodiments are not limited thereto.

The electron transport region ETR may include the above-described compounds of the hole transport region in at least one of and electron injection layer EIL, and electron transport layer ETL, and a hole blocking layer HBL.

When the electron transport region ETR includes the electron transport layer ETL, the electron transport layer ETL may have a thickness in a range of about 100 Å to about 1,000 Å. For example, the electron transport layer ETL may have a thickness of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof or a mixture thereof (e.g., AgMg, AgYb, or MgYb). In an embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to the auxiliary electrode, resistance of the second electrode EL2 may decrease.

In embodiments, the light-emitting element ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL includes an inorganic material, the inorganic material may include an alkaline metal compound (e.g., LiF), an alkaline earth metal compound (e.g., MgF₂), SiON, SiNₓ, SiO_{y}, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or may include an epoxy resin, or an acrylate such as methacrylate. However, embodiments are not limited thereto. In an embodiment, the capping layer CPL may include at least one of Compounds P1 to P5:

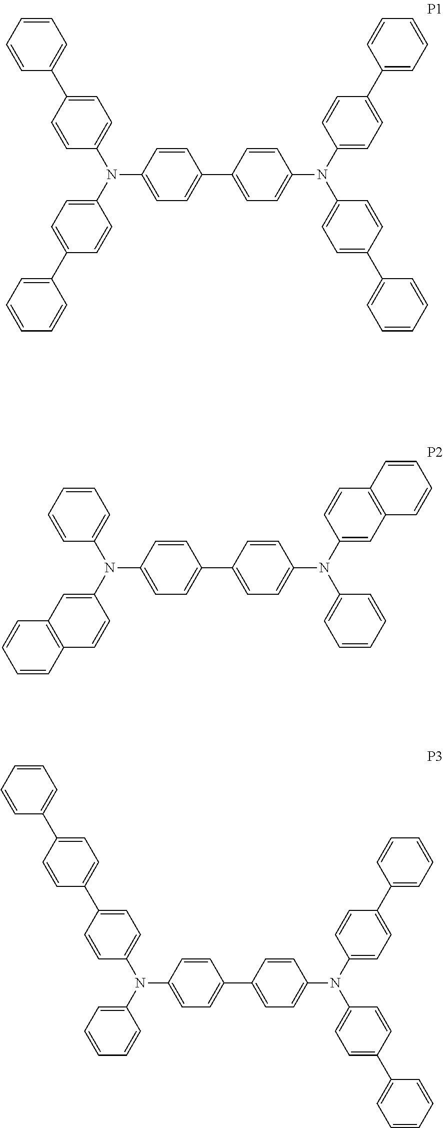 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

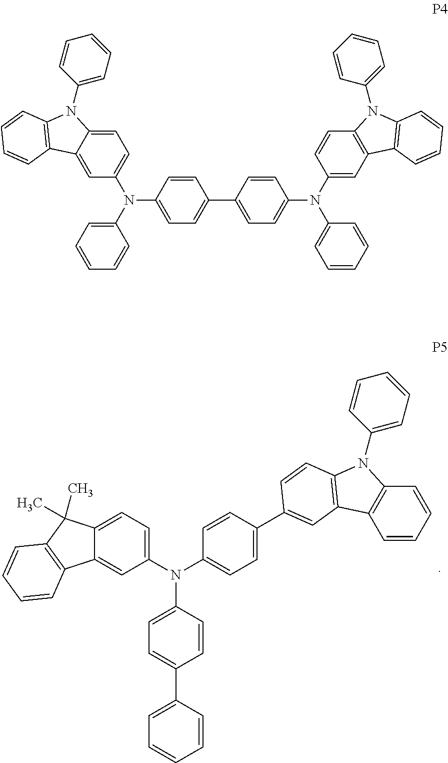 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6 with respect to light in a wavelength range of about 550 nm to about 660 nm.

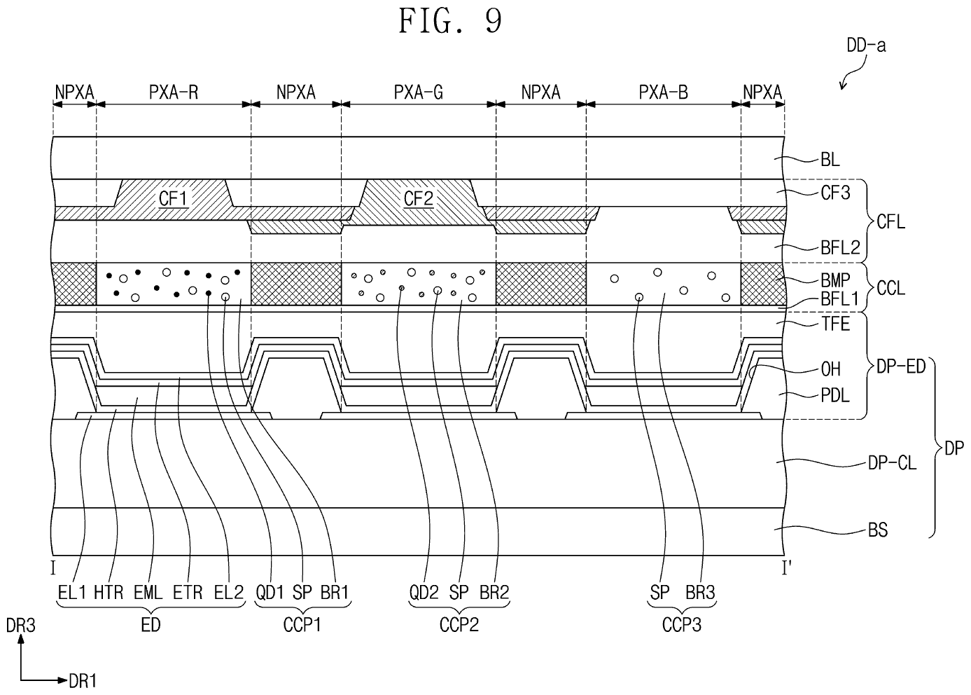

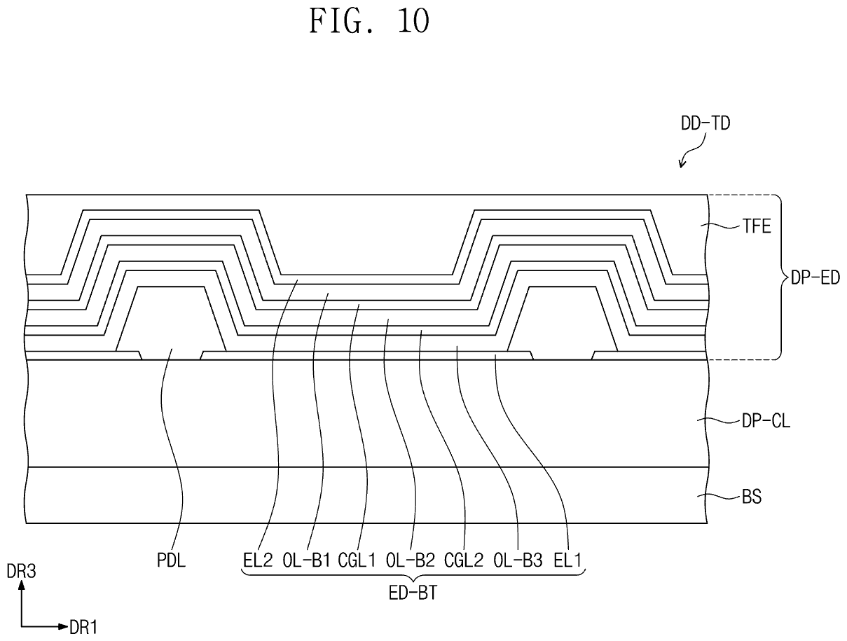

FIG. 9 to FIG. 12 are each a cross-sectional view of a display device according to an embodiment. In the descriptions of the display device according to an embodiment as shown in FIG. 9 to FIG. 12, the features which have been described above with respect to FIG. 1 to FIG. 7 will not be explained again, and the differing features will be described.

Referring to FIG. 9, a display device DD-a according to an embodiment may include a display panel DP including a display element layer DP-ED, a light control layer CCL, and a color filter layer CFL, each disposed on the display panel DP.

In an embodiment shown in FIG. 9, the display panel DP may include a circuit layer DP-CL and a display element layer DP-ED, each provided on a base layer BS, and the display element layer DP-ED may include a light-emitting element ED.

The light-emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light-emitting element ED shown in FIG. 3 to FIG. 7 may be the same as a structure of a light-emitting element ED according to one of FIG. 9 as described above. The light-emitting element ED illustrated in FIG. 9 may include the fused polycyclic compound according to an embodiment. The light-emitting element ED including the fused polycyclic compound according to an embodiment may exhibit long lifespan characteristics.

Referring to FIG. 9, the emission layer EML may be disposed in an opening OH defined in a pixel defining film PDL. For example, the emission layer EML which is separated by the pixel defining film PDL and correspondingly provided to each of the light emitting regions PXA-R, PXA-G, and PXA-B, may emit light in a same wavelength range. In the display device DD-a, the emission layer EML may emit blue light. Although not shown in the drawings, in an embodiment, the emission layer EML may be provided as a common layer for each of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and may emit the resulting light. For example, the light control layer CCL may be a layer including a quantum dot or a layer including a phosphor.

The light control layer CCL may include light control parts CCP1, CCP2, and CCP3. The light control parts CCP1, CCP2, and CCP3 may be spaced apart from each other.

Referring to FIG. 9, divided patterns BMP may be disposed between the light control parts CCP1, CCP2, and CCP3, which are spaced apart from each other, but embodiments are not limited thereto. In FIG. 9, it is shown that the divided patterns BMP do not overlap the light control parts CCP1, CCP2, and CCP3, but the edges of the light control parts CCP1, CCP2, and CCP3 may overlap at least a portion of the divided patterns BMP.

The light control layer CCL may include a first light control part CCP1 including a first quantum dot QD1 that converts first color light provided from the light-emitting element ED into second color light, a second light control part CCP2 including a second quantum dot QD2 that converts the first color light into third color light, and a third light control part CCP3 that transmits the first color light.

In an embodiment, the first light control part CCP1 may provide red light, which is the second color light, and the second light control part CCP2 may provide green light, which is the third color light. The third light control part CCP3 may provide blue light by transmitting the blue light which is the first color light provided from the light-emitting element ED. For example, the first quantum dot QD1 may be a red quantum dot, and the second quantum dot QD2 may be a green quantum dot. The quantum dots QD1 and QD2 may each be a quantum dot as described above.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include a quantum dot but may include the scatterer SP.

The scatterer SP may be inorganic particles. For example, the scatterer SP may include at least one of TiO₂, ZnO, Al₂O₃, SiO₂ and hollow sphere silica. The scatterer SP may include any one of TiO₂, ZnO, Al₂O₃, SiO₂, and hollow silica, or may be a mixture of at least two materials selected from TiO₂, ZnO, Al₂O₃, SiO₂, and hollow silica.

The first light control part CCP1, the second light control part CCP2, and the third light control part CCP3 may each include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may block the light control parts CCP1, CCP2 and CCP3 from exposure to moisture/oxygen. The barrier layer BFL1 may cover the light control parts CCP1, CCP2, and CCP3. A barrier layer BFL2 may be provided between the light control parts CCP1, CCP2, and CCP3 and the color filter layer CFL.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may each independently further include an organic film. The barrier layers BFL1 and BFL2 may each be formed of a single layer or of multiple layers.

In the display device DD-a, the color filter layer CFL may be disposed on the light control layer CCL. In an embodiment, the color filter layer CFL may be disposed on the light control layer CCL. For example, the barrier layer BFL2 may be omitted.

The color filter layer CFL may include filters CF1, CF2, and CF3. The color filter layer CFL may include a first filter CF1 that transmits second color light, a second filter CF2 that transmits the third color light, and a third filter CF3 that transmits the first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated but may be provided as one filter.

Although not shown in the drawings, the color filter layer CFL may further include a light shielding part (not shown). The light shielding part (not shown) may be a black matrix. The light shielding part (not shown) may include an organic light shielding material or an inorganic light shielding material, each including a black pigment or dye. The light shielding part (not shown) may prevent light leakage, and may separate boundaries between adjacent filters CF1, CF2, and CF3. The light shielding part may be formed of a blue filter.

The first to third filters CF1, CF2, and CF3 may be disposed to respectively correspond to the red light emitting region PXA-R, the green light emitting region PXA-G, and the blue light emitting region PXA-B.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

FIG. 10 is a schematic cross-sectional view of a portion of a display device according to an embodiment. In the display device DD-TD according to an embodiment, the light-emitting element ED-BT may include light emitting structures OL-B1, OL-B2, and OL-B3. The light-emitting element ED-BT may include a first electrode EL1 and a second electrode EL2, which face each other, and the light emitting structures OL-B1, OL-B2, and OL-B3 stacked in a thickness direction between the first electrode EL1 and the second electrode EL2. At least one of the light emitting structures OL-B1, OL-B2, and OL-B3 may each include the fused polycyclic compound according to an embodiment. The light-emitting element ED-BT including the fused polycyclic compound according to an embodiment may exhibit long lifespan characteristics. The light emitting structures OL-B1, OL-B2, and OL-B3 may each include an emission layer EML (FIG. 9), and a hole transport region HTR and an electron transport region ETR disposed with the emission layer EML (FIG. 9) therebetween.

For example, the light-emitting element ED-BT included in the display device DD-TD may have a tandem structure including multiple emission layers.

In an embodiment illustrated in FIG. 10, light emitted from each of the light emitting structures OL-B1, OL-B2, and OL-B3 may be blue light. However, embodiments are not limited thereto, and the light emitted from each of the light emitting structures OL-B1, OL-B2, and OL-B3 may have wavelength ranges that are different from each other. For example, the light-emitting element ED-BT that includes the light emitting structures OL-B1, OL-B2, and OL-B3, which emit light having wavelength ranges that are different from each other may emit white light.

Charge generation layers CGL1 and CGL2 may each be disposed between adjacent light emitting structures among the light emitting structures OL-B1, OL-B2, and OL-B3. Charge generation layers CGL1 and CGL2 may each independently include a p-type charge generation layer and/or an n-type charge generation layer.

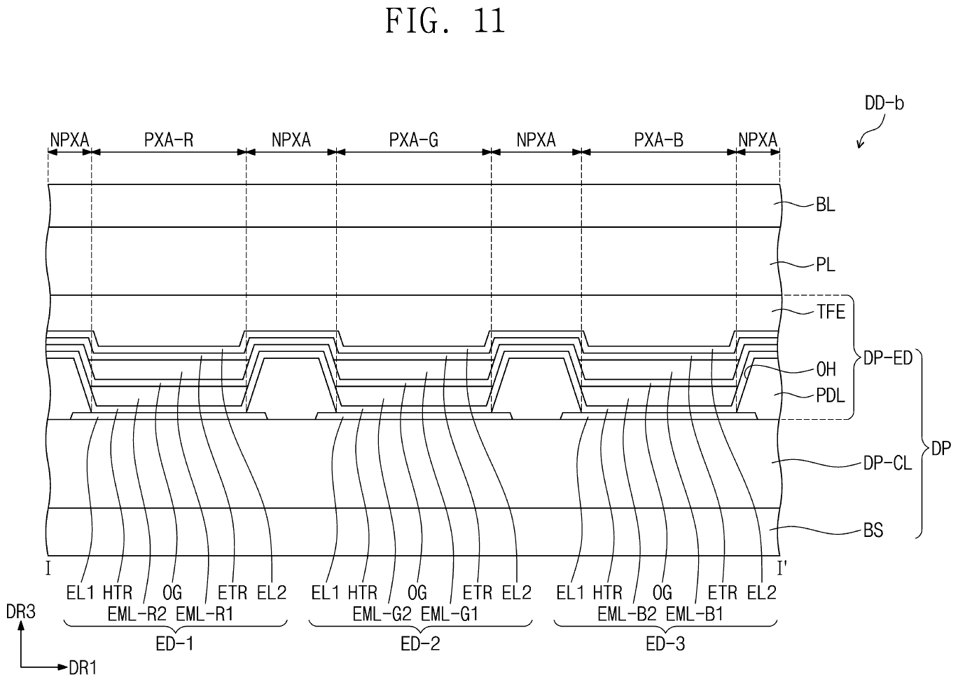

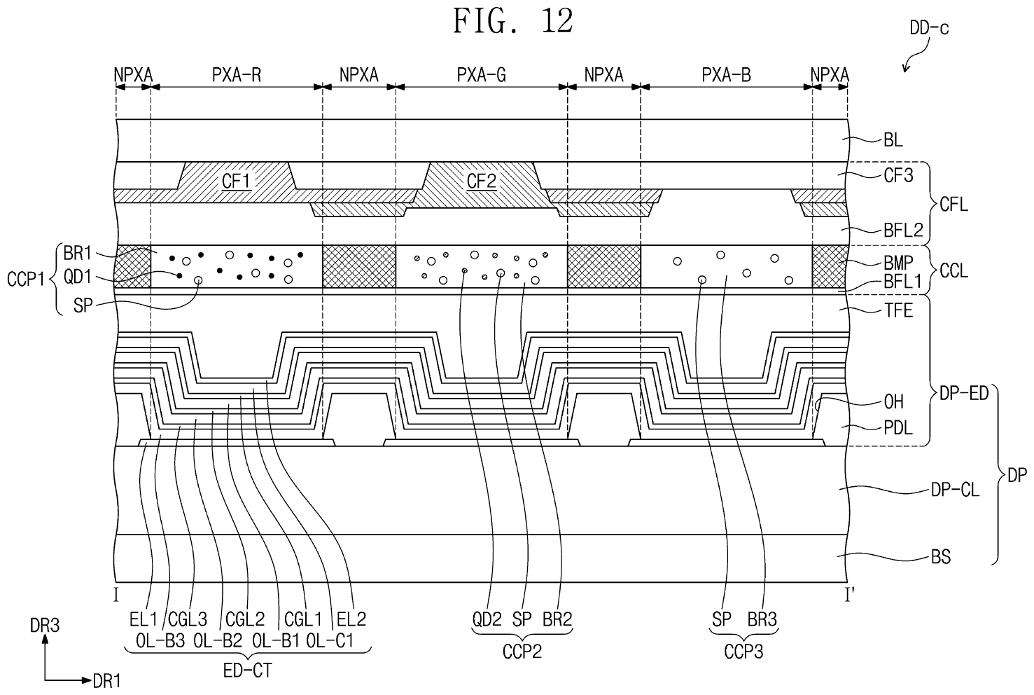

Referring to FIG. 11, a display device DD-b according to an embodiment may include light-emitting elements ED-1, ED-2, and ED-3, in which two emission layers are stacked. In comparison to the display device DD shown in FIG. 2, the embodiment shown in FIG. 11 is different at least in that the first to third light-emitting elements ED-1, ED-2, and ED-3 each include two emission layers stacked in the thickness direction In each of the first to third light-emitting elements ED-1, ED-2, and ED-3, the two emission layers may emit light in a same wavelength region.

At least one of the first light-emitting elements ED-1, the second light-emitting elements ED-2, and the third light-emitting elements ED-3 may include the fused polycyclic compound according to an embodiment. At least one of the light-emitting elements ED-1, ED-2, and ED-3 including the fused polycyclic compound according to an embodiment may exhibit long lifespan characteristics.

The first light-emitting element ED-1 may include a first red emission layer EML-R1 and a second red emission layer EML-R2. The second light-emitting element ED-2 may include a first green emission layer EML-G1 and a second green emission layer EML-G2. The third light-emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer for all of the first to third light-emitting elements ED-1, ED-2, and ED-3. However, embodiments are not limited thereto, and the emission auxiliary part OG may be provided by being patterned in the openings OH defined in the pixel defining film PDL.

The first red emission layer EML-R1, the first green emission layer EML-G1, and the first blue emission layer EML-B1 may be each disposed between the emission auxiliary part OG and the electron transport region ETR. The second red emission layer EML-R2, the second green emission layer EML-G2, and the second blue emission layer EML-B2 may each be disposed between the hole transport region HTR and the emission auxiliary part OG.

For example, the first light-emitting element ED-1 may include the first electrode EL1, the hole transport region HTR, the second red emission layer EML-R2, the emission auxiliary part OG, the first red emission layer EML-R1, the electron transport region ETR, and the second electrode EL2, which are stacked in that order. The second light-emitting element ED-2 may include the first electrode EL1, the hole transport region HTR, the second green emission layer EML-G2, the emission auxiliary part OG, the first green emission layer EML-G1, the electron transport region ETR, and the second electrode EL2, which are stacked in that order. The third light-emitting element ED-3 may include the first electrode EL1, the hole transport region HTR, the second blue emission layer EML-B2, the emission auxiliary part OG, the first blue emission layer EML-B1, the electron transport region ETR, and the second electrode EL2, which are stacked in that order.

An optical auxiliary layer PL may be disposed on the display element layer DP-ED. The optical auxiliary layer PL may include a polarizing layer. The optical auxiliary layer PL may be disposed on the display panel DP and may control that is reflected at the display panel DP from an external light. Although not shown in the drawings, in an embodiment, the optical auxiliary layer PL may be omitted from the display device DD-b.

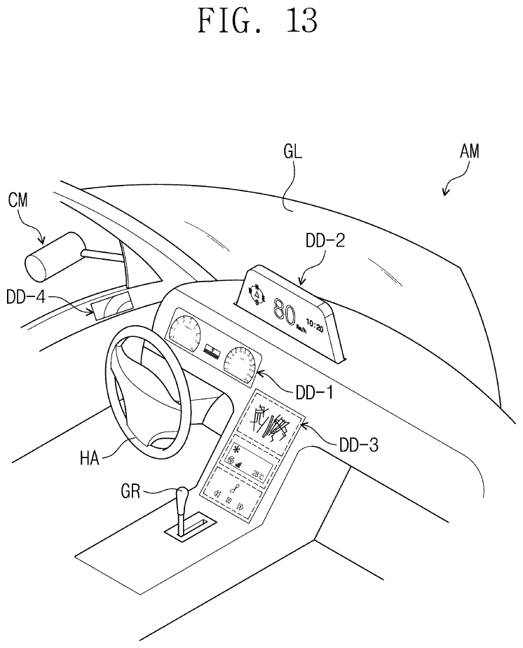

In contrast to FIG. 10 and FIG. 11, FIG. 12 shows a display device DD-c that is different at least in that it includes four light emitting structures OL-B1, OL-B2, OL-B3, and OL-C1. A light-emitting element ED-CT may include a first electrode EL1 and a second electrode EL2, facing each other, and the first to four light emitting structures OL-B1, OL-B2, OL-B3, and OL-C1 stacked in a thickness direction. Charge-generating layers CGL1, CGL2, and CGL3 may each be disposed between adjacent light emitting structures among the first to fourth emission structures OL-B1, OL-B2, OL-B3, and OL-C1.

At least one of the first to fourth light emitting structures OL-B1, OL-B2, OL-B3, and OL-C1 may include the fused polycyclic compound according to an embodiment. The light-emitting element ED-CT containing the fused polycyclic compound according to an embodiment may exhibit long lifespan characteristics.

Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelength regions from each other.

The charge generation layers CGL1, CGL2, and CGL3 which are disposed between adjacent light emitting structures among the first to fourth light emitting structures OL-B1, OL-B2, OL-B3, and OL-C1 may each independently include a p-type charge generation layer and/or an n-type charge generation layer.

In an embodiment, an electronic apparatus may include a display device that includes light-emitting elements and a control part controlling the display device. The electronic apparatus according to an embodiment may be activated in response to an electrical signal. The electronic apparatus may include display devices according to embodiments. For example, the electronic apparatus may include, in addition to large display devices such as televisions, monitors, or outdoor billboards, small and medium-sized display devices such as personal computers, laptop computers, personal digital assistants, in-vehicle displays, game consoles, portable electronic apparatuses, or cameras.

FIG. 13 is a schematic view of a vehicle AM in which first to fourth display devices DD-1, DD-2, DD-3, and DD-4 are disposed. In an embodiment, at least one of the first to fourth display devices DD-1, DD-2, DD-3, and DD-4 may have a structure according to one of the display devices DD, DD-TD, DD-a, DD-b, and DD-c described with reference to FIGS. 1, 2, and 9 to 12.

In FIG. 13, a car is shown as a vehicle AM, and the first to fourth display devices DD-1, DD-2, DD-3, and DD-4 may be disposed in various transportation such as bicycles, motorcycles, trains, boats, and airplanes. However, this is only an example. In an embodiment, at least one of the first to fourth display devices DD-1, DD-2, DD-3, and DD-4 having a structure according to one of display devices DD, DD-TD, DD-a, DD-b, DD-c may be used for personal computers, laptop computers, personal digital assistants, game consoles, portable electronic apparatuses, televisions, monitors, outdoor billboards, etc. However, these are presented as examples and thus may be display devices used in other electronic apparatuses.

At least one of the first to fourth display devices DD-1, DD-2, DD-3, and DD-4 may each independently include a light-emitting element ED according to an embodiment as described in reference to FIG. 3 to FIG. 7. At least one of the first to fourth display devices DD-1, DD-2, DD-3, and DD-4 may include the fused polycyclic compound according to an embodiment. At least one of display devices (at least one of DD-1, DD-2, DD-3, and DD-4) including the fused polycyclic compound according to an embodiment may exhibit an excellent display lifespan.

Referring to FIG. 13, the vehicle AM may include a steering wheel HA and a gearshift GR for driving the vehicle AM. The vehicle AM may include a front window GL that is disposed so as to face the driver.

The first display device DD-1 may be disposed in a first region that overlaps the steering wheel HA. For example, the first display device DD-1 may be a digital cluster which displays first information of the vehicle AM. The first information may include a first scale which indicates a driving speed of the vehicle AM, a second scale which indicates an engine speed (for example, as revolutions per minute (RPM)), a fuel gauge, etc. The first scale and the second scale may each be displayed as a digital image.

The second display device DD-2 may be disposed in a second region facing the driver's seat and overlapping the front window GL. The driver's seat may be a seat where the steering wheel HA is disposed. For example, the second display device DD-2 may be a head up display (HUD) that displays second information of the vehicle AM. The second display device DD-2 may be optically transparent. The second information may include digital numbers that indicate a driving speed, and may further include information such as the current time. Although not shown in the drawings, in an embodiment, the second information of the second display device DD-2 may be projected to the front window GL to be displayed.

The third display device DD-3 may be disposed in a third region adjacent to the gearshift GR. For example, the third display device DD-3 may be a center information display (CID) for a vehicle that displays third information, and the third display device DD-3 may be disposed between the driver's seat and the passenger seat. The passenger seat may be a seat that is spaced apart from the driver's seat with the gearshift GR disposed therebetween. The third information may include information about traffic (e.g., navigation information), playing music or radio or a video (or an image), temperatures inside the vehicle AM, etc.

The fourth display device DD-4 may be spaced apart from the steering wheel HA and the gearshift GR, and may be disposed in a fourth region adjacent to a side of the vehicle AM. For example, the fourth display device DD-4 may be a digital side-view mirror that displays fourth information. The fourth display device DD-4 may display an image outside the vehicle AM that is taken by a camera module CM disposed outside the vehicle AM. The fourth information may include an image outside of the vehicle AM.

The first to fourth information as described above are only presented as examples, and the first to fourth display devices DD-1, DD-2, DD-3, and DD-4 may further display information about the interior and Exterior of the vehicle AM. The first to fourth information may include information that is different from each other. However, embodiments are not limited thereto, and a part of the first to fourth information may include the same information as one another.

Hereinafter, a fused polycyclic compound according to an embodiment and a light-emitting element according to an embodiment will be described with reference to the Examples and the Comparative Examples. The Examples shown are only provided as illustrations to assist in understanding the disclosure, and the scope thereof is not limited thereto.

### EXAMPLES

### 1. Synthesis of Fused Polycyclic Compound According to Example

A synthesis method of a fused polycyclic compound according to this embodiment will be described by exemplifying synthesis methods of Compounds 12, 15, 109, 31, and 90. The synthesis methods of the fused polycyclic compound as explained below are provided as an example, but the synthesis methods of the compound according to embodiments is not limited to the Examples below.

### (1) Synthesis of Fused Polycyclic Compound 12

Fused Polycyclic Compound 12 according to an example may be synthesized by Reaction Scheme 1.

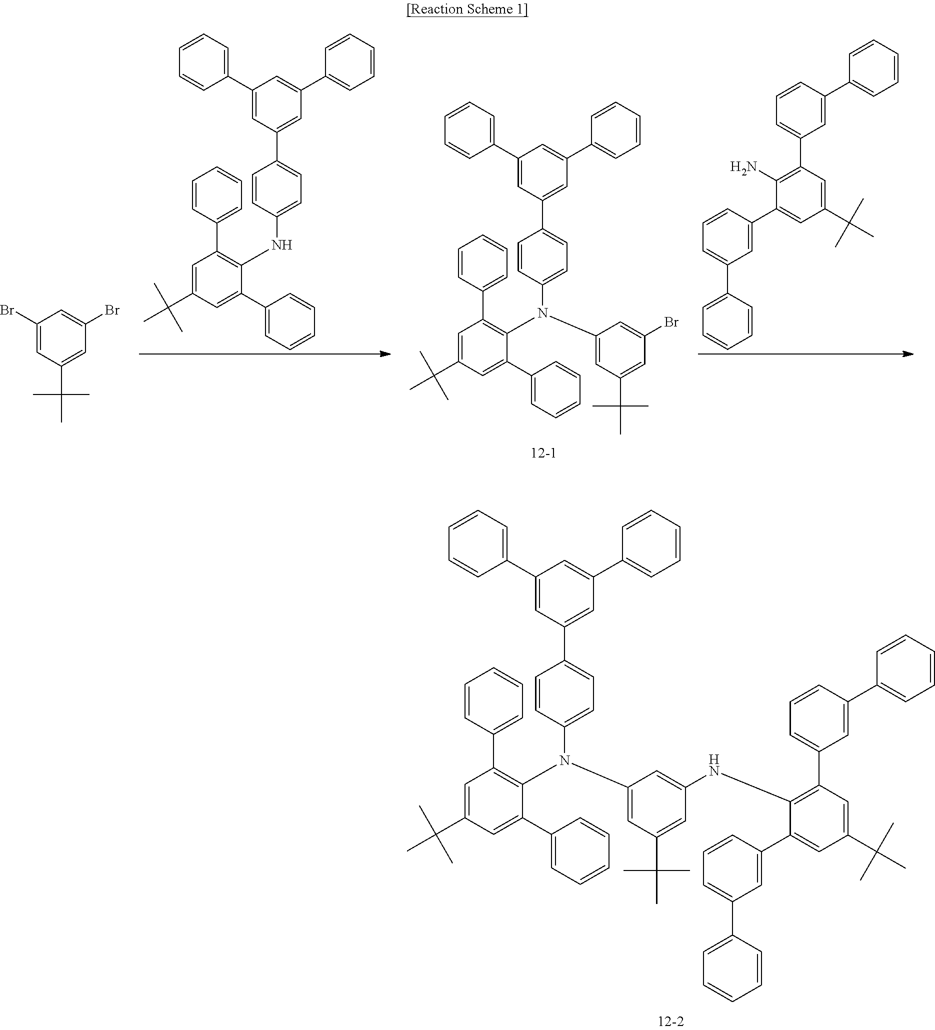

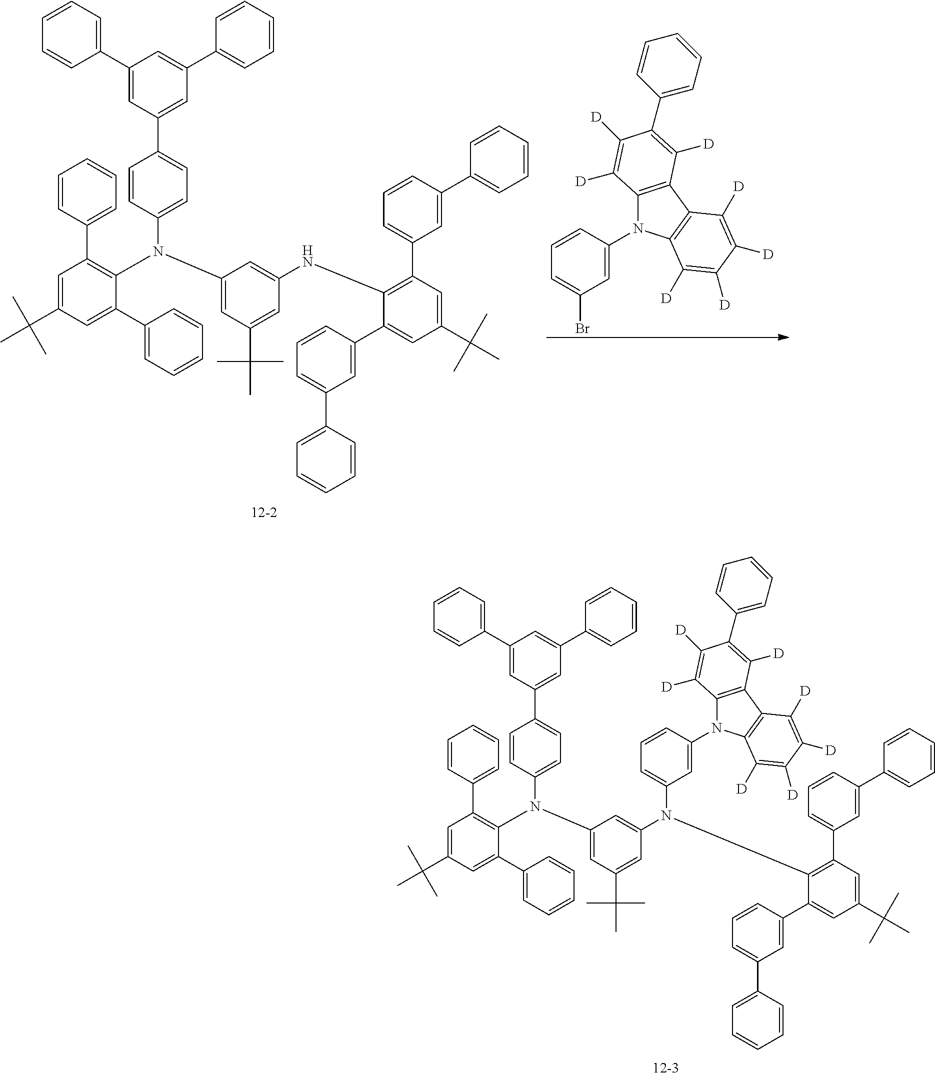 [SMILES: CC(C)(C)c1cc(Nc2c(-c3cccc(-c4ccccc4)c3)cc(C(C)(C)C)cc2-c2cccc(-c3ccccc3)c2)cc(N(c2ccc(-c3cc(-c4ccccc4)cc(-c4ccccc4)c3)cc2)c2c(-c3ccccc3)cc(C(C)(C)C)cc2-c2ccccc2)c1 ; [2H]c1c([2H])c([2H])c2c(c1[2H])c1c([2H])c(-c3ccccc3)c([2H])c([2H])c1n2-c1cccc(Br)c1 ; [2H]c1c([2H])c([2H])c2c(c1[2H])c1c([2H])c(-c3ccccc3)c([2H])c([2H])c1n2-c1cccc(N(c2cc(N(c3ccc(-c4cc(-c5ccccc5)cc(-c5ccccc5)c4)cc3)c3c(-c4ccccc4)cc(C(C)(C)C)cc3-c3ccccc3)cc(C(C)(C)C)c2)c2c(-c3cccc(-c4ccccc4)c3)cc(C(C)(C)C)cc2-c2cccc(-c3ccccc3)c2)c1]

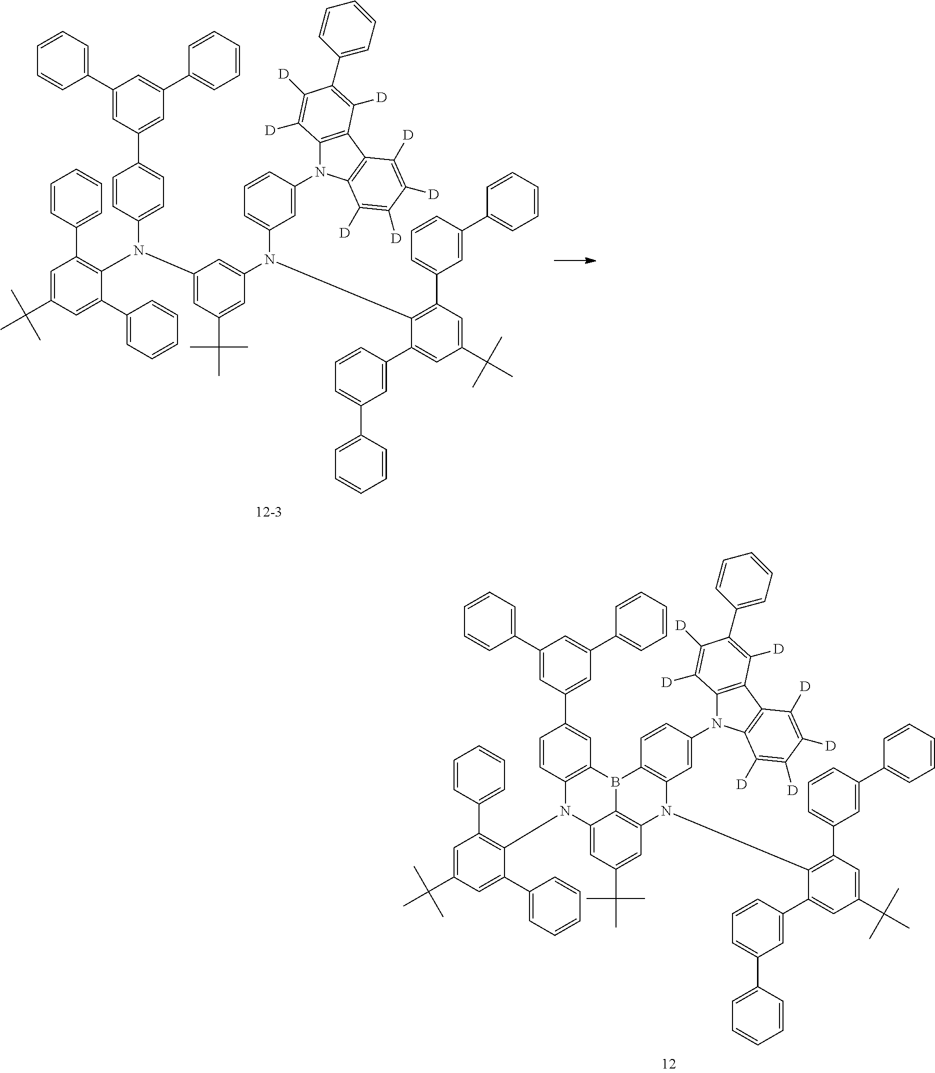 [SMILES: [2H]c1c([2H])c([2H])c2c(c1[2H])c1c([2H])c(-c3ccccc3)c([2H])c([2H])c1n2-c1cccc(N(c2cc(N(c3ccc(-c4cc(-c5ccccc5)cc(-c5ccccc5)c4)cc3)c3c(-c4ccccc4)cc(C(C)(C)C)cc3-c3ccccc3)cc(C(C)(C)C)c2)c2c(-c3cccc(-c4ccccc4)c3)cc(C(C)(C)C)cc2-c2cccc(-c3ccccc3)c2)c1 ; [2H]c1c([2H])c([2H])c2c(c1[2H])c1c([2H])c(-c3ccccc3)c([2H])c([2H])c1n2-c1ccc2c(c1)N(c1c(-c3cccc(-c4ccccc4)c3)cc(C(C)(C)C)cc1-c1cccc(-c3ccccc3)c1)c1cc(C(C)(C)C)cc3c1B2c1cc(-c2cc(-c4ccccc4)cc(-c4ccccc4)c2)ccc1N3c1c(-c2ccccc2)cc(C(C)(C)C)cc1-c1ccccc1]

### [Synthesis of Intermediate 12-1]

1,3-dibromo-5-(tert-butyl)benzene (1 eq), 5′-(tert-butyl)-N-(5′-phenyl-[1,1′: 3′,1″-terphenyl]-4-yl)-[1,1′: 3′,1″-terphenyl]-2′-amine (0.8 eq), tris(dibenzylideneacetone)dipalladium(0) (0.05 eq), tri-tert-butylphosphine (0.1 eq), and sodium tert-butoxide (3 eq) were dissolved in toluene, and stirred at about 100° C. for about 8 hours. After cooling, the reactant was washed with ethyl acetate and water three times and separated to obtain an organic layer. The obtained organic layer was dried over MgSO₄ and dried under reduced pressure. The resulting product was purified by column chromatography with methylene chloride (MC) and n-hexane to obtain Intermediate 12-1 (yield: 53%).

### [Synthesis of Intermediate 12-2]

Intermediate 12-1 (1 eq), 5″-(tert-butyl)-[1,1′:3′,1″:3″,1′″:3′″,1″″-quinquephenyl]-2″-amine (1.1 eq), tris(dibenzylideneacetone)dipalladium(0) (0.05 eq), tri-tert-butylphosphine (0.1 eq), and sodium tert-butoxide (3 eq) were dissolved in o-xylene, and stirred at about 140° C. for about 24 hours. After cooling, the reactant was washed with ethyl acetate and water three times and separated to obtain an organic layer. The obtained organic layer was dried over MgSO₄ and dried under reduced pressure. The resulting product was purified by column chromatography with MC and n-hexane to obtain Intermediate 12-2 (yield: 77%).

### [Synthesis of Intermediate 12-3]

Intermediate 12-2 (1 eq), 9-(3-bromophenyl)-3-phenyl-9H-carbazole-1,2,4,5,6,7,8-d7 (2 eq), tris(dibenzylideneacetone)dipalladium(0) (0.15 eq), tri-tert-butylphosphine (0.3 eq), and sodium tert-butoxide (4 eq) were dissolved in o-xylene and stirred at about 160° C. for about 48 hours. After cooling, the reactant was washed with ethyl acetate and water three times and separated to obtain an organic layer. The obtained organic layer was dried over MgSO₄ and dried under reduced pressure. The resulting product was purified by column chromatography with MC and n-hexane to obtain Intermediate 12-3 (yield: 26%).

### [Synthesis of Compound 12]

Intermediate 12-3 (1 eq) was dissolved in ortho dichlorobenzene and cooled to about 0° C., and BBr₃ (3 eq) was slowly injected in a nitrogen atmosphere. After completion of dropping, the temperature was raised to about 180° C., and the resultant was stirred for about 24 hours. After cooling the reactant, triethylamine was slowly dropped into the flask containing the reactant to terminate the reaction, ethyl alcohol was put into the reactant to precipitate solids, and the solid powder was obtained by filtration. The obtained solid powder was purified by column chromatography with MC and n-hexane and recrystallized using toluene and acetone to obtain Compound 12 (yield: 4%).

### (2) Synthesis of Fused Polycyclic Compound 15

Fused Polycyclic Compound 15 according to an example may be synthesized by, for example, Reaction Scheme 2.

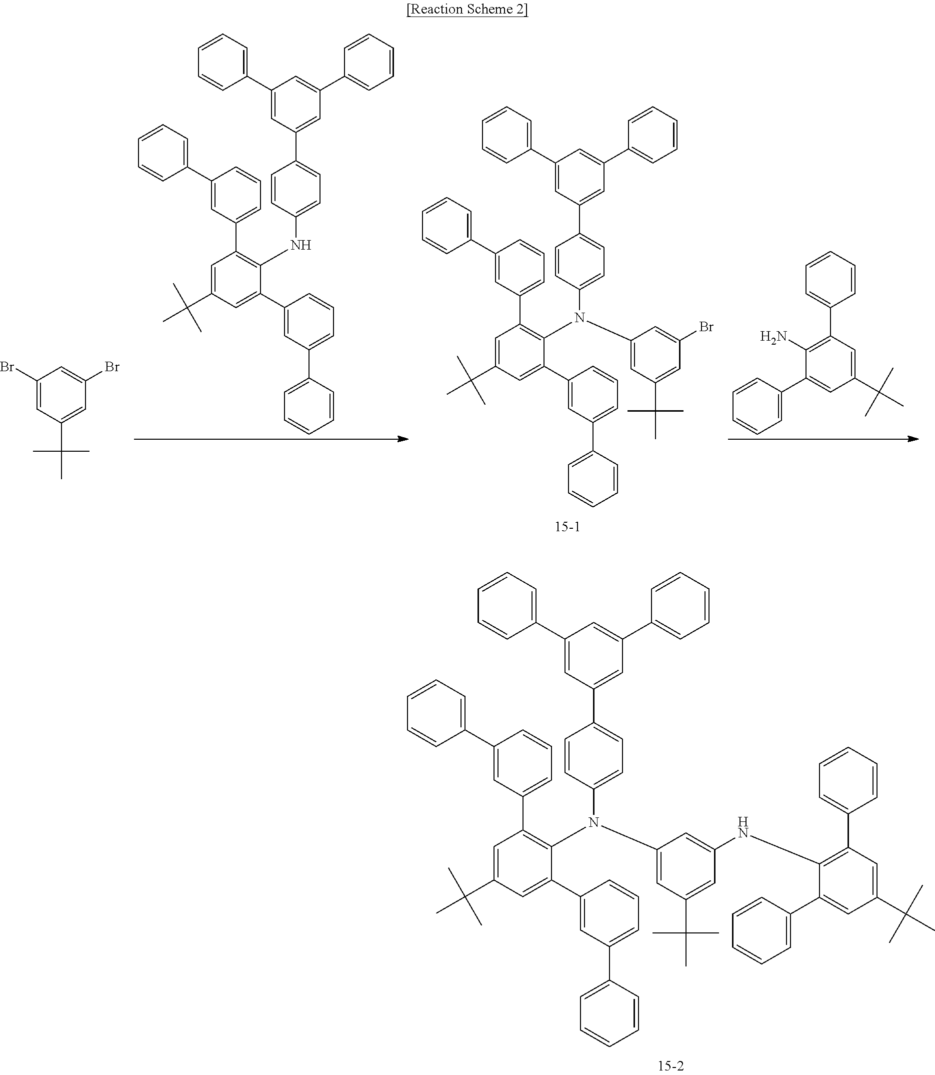 [SMILES: CC(C)(C)c1cc(Br)cc(Br)c1 ; CC(C)(C)c1cc(-c2cccc(-c3ccccc3)c2)c(Nc2ccc(-c3cc(-c4ccccc4)cc(-c4ccccc4)c3)cc2)c(-c2cccc(-c3ccccc3)c2)c1 ; CC(C)(C)c1cc(Br)cc(N(c2ccc(-c3cc(-c4ccccc4)cc(-c4ccccc4)c3)cc2)c2c(-c3cccc(-c4ccccc4)c3)cc(C(C)(C)C)cc2-c2cccc(-c3ccccc3)c2)c1 ; CC(C)(C)c1cc(-c2ccccc2)c(N)c(-c2ccccc2)c1 ; CC(C)(C)c1cc(Nc2c(-c3ccccc3)cc(C(C)(C)C)cc2-c2ccccc2)cc(N(c2ccc(-c3cc(-c4ccccc4)cc(-c4ccccc4)c3)cc2)c2c(-c3cccc(-c4ccccc4)c3)cc(C(C)(C)C)cc2-c2cccc(-c3ccccc3)c2)c1]

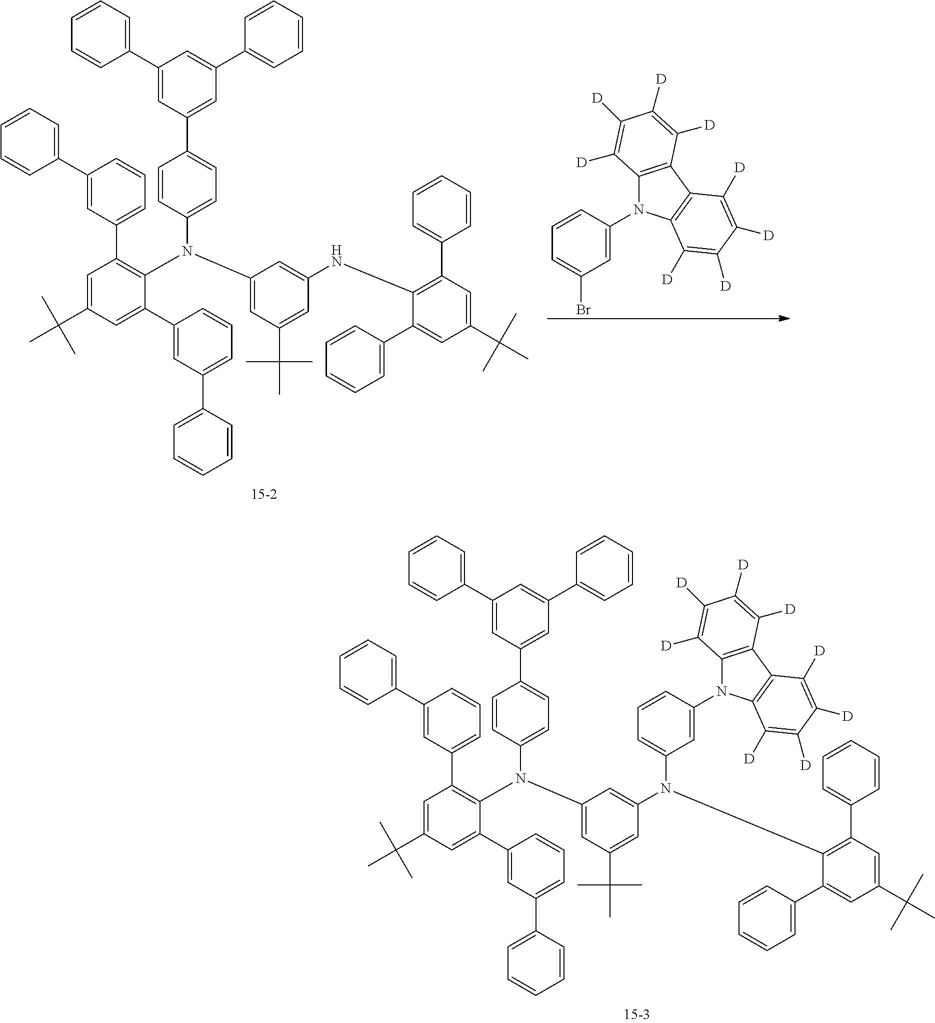 [SMILES: CC(C)(C)c1cc(Nc2c(-c3ccccc3)cc(C(C)(C)C)cc2-c2ccccc2)cc(N(c2ccc(-c3cc(-c4ccccc4)cc(-c4ccccc4)c3)cc2)c2c(-c3cccc(-c4ccccc4)c3)cc(C(C)(C)C)cc2-c2cccc(-c3ccccc3)c2)c1 ; [2H]c1c([2H])c([2H])c2c(c1[2H])c1c([2H])c([2H])c([2H])c([2H])c1n2-c1cccc(Br)c1 ; [2H]c1c([2H])c([2H])c2c(c1[2H])c1c([2H])c([2H])c([2H])c([2H])c1n2-c1cccc(N(c2cc(N(c3ccc(-c4cc(-c5ccccc5)cc(-c5ccccc5)c4)cc3)c3c(-c4cccc(-c5ccccc5)c4)cc(C(C)(C)C)cc3-c3cccc(-c4ccccc4)c3)cc(C(C)(C)C)c2)c2c(-c3ccccc3)cc(C(C)(C)C)cc2-c2ccccc2)c1]

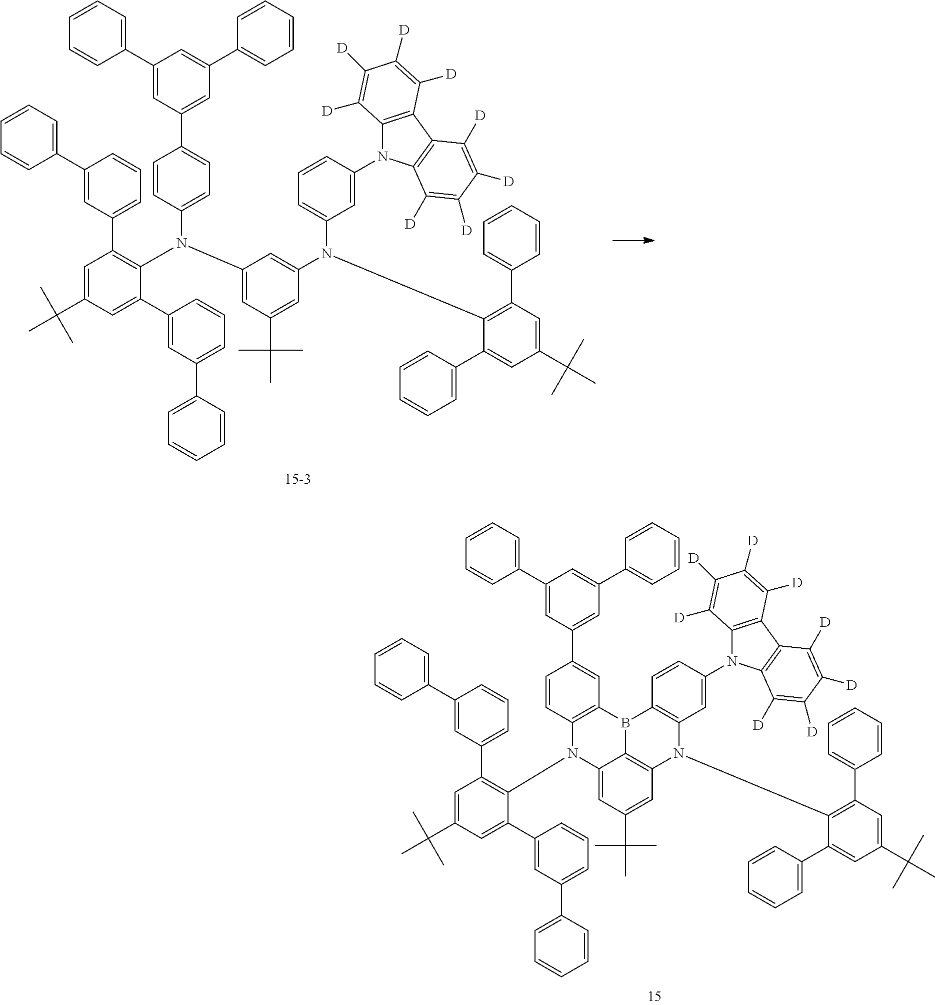 [SMILES: [2H]c1c([2H])c([2H])c2c(c1[2H])c1c([2H])c([2H])c([2H])c([2H])c1n2-c1cccc(N(c2cc(N(c3ccc(-c4cc(-c5ccccc5)cc(-c5ccccc5)c4)cc3)c3c(-c4cccc(-c5ccccc5)c4)cc(C(C)(C)C)cc3-c3cccc(-c4ccccc4)c3)cc(C(C)(C)C)c2)c2c(-c3ccccc3)cc(C(C)(C)C)cc2-c2ccccc2)c1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cc(-c4ccccc4)cc(-c4ccccc4)c2)ccc1N3c1c(-c2cccc(-c3ccccc3)c2)cc(C(C)(C)C)cc1-c1cccc(-c2ccccc2)c1]

### [Synthesis of Intermediate 15-1]

1,3-dibromo-5-(tert-butyl)benzene (1 eq), 5″-(tert-butyl)-N-(5′-phenyl-[1,1′:3′,1″-terphenyl]-4-yl)-[1,1′:3′,1″:3″,1′″:3′″,1″″-quinquephenyl]-2″-amine (0.8 eq), tris(dibenzylideneacetone)dipalladium(0) (0.05 eq), tri-tert-butylphosphine (0.1 eq), and sodium tert-butoxide (3 eq) were dissolved in toluene and stirred at about 100° C. for about 8 hours. After cooling, the reactant was washed with ethyl acetate and water three times and separated to obtain an organic layer. The obtained organic layer was dried over MgSO₄ and dried under reduced pressure. The resulting product was purified by column chromatography with MC and n-hexane to obtain Intermediate 15-1 (yield: 42%).

### [Synthesis of Intermediate 15-2]

Intermediate 15-1 (1 eq), 5′-(tert-butyl)-[1,1′:3′,1″-terphenyl]-2′-amine (1.1 eq), tris(dibenzylideneacetone)dipalladium(0) (0.05 eq), tri-tert-butylphosphine (0.1 eq), and sodium tert-butoxide (3 eq) were dissolved in o-xylene and stirred at about 140° C. for about 24 hours. After cooling, the reactant was washed with ethyl acetate and water three times and separated to obtain an organic layer. The obtained organic layer was dried over MgSO₄ and dried under reduced pressure. The resulting product was purified by column chromatography with MC and n-hexane to obtain Intermediate 15-2 (yield: 80%).

### [Synthesis of Intermediate 15-3]

Intermediate 15-2 (1 eq), 9-(3-bromophenyl)-9H-carbazole-1,2,3,4,5,6,7,8-d8 (2 eq), tris(dibenzylideneacetone)dipalladium(0) (0.15 eq), tri-tert-butylphosphine (0.3 eq), and sodium tert-butoxide (4 eq) were dissolved in o-xylene and stirred at about 160° C. for about 48 hours. After cooling, the reactant was washed with ethyl acetate and water three times and separated to obtain an organic layer. The obtained organic layer was dried over MgSO₄ and dried under reduced pressure. The resulting product was purified by column chromatography with MC and n-hexane to obtain Intermediate 15-3 (yield: 31%).

### [Synthesis of Compound 15]

Intermediate 15-3 (1 eq) was dissolved in ortho dichlorobenzene and cooled to about 0° C., and BBr₃ (3 eq) was slowly injected in a nitrogen atmosphere. After completion of dropping, the temperature was raised to 180° C., and the resultant was stirred for about 24 hours. After cooling the reactant, triethylamine was slowly dropped into the flask containing the reactant to terminate the reaction, ethyl alcohol was put into the reactant to precipitate solids, and the solid powder was obtained by filtration. The obtained solid powder was purified by column chromatography with MC and n-hexane and recrystallized using toluene and acetone to obtain Compound 15 (yield: 5%).

### (3) Synthesis of Fused Polycyclic Compound 109

Fused Polycyclic Compound 109 according to an example may be synthesized by, for example, Reaction Scheme 3.

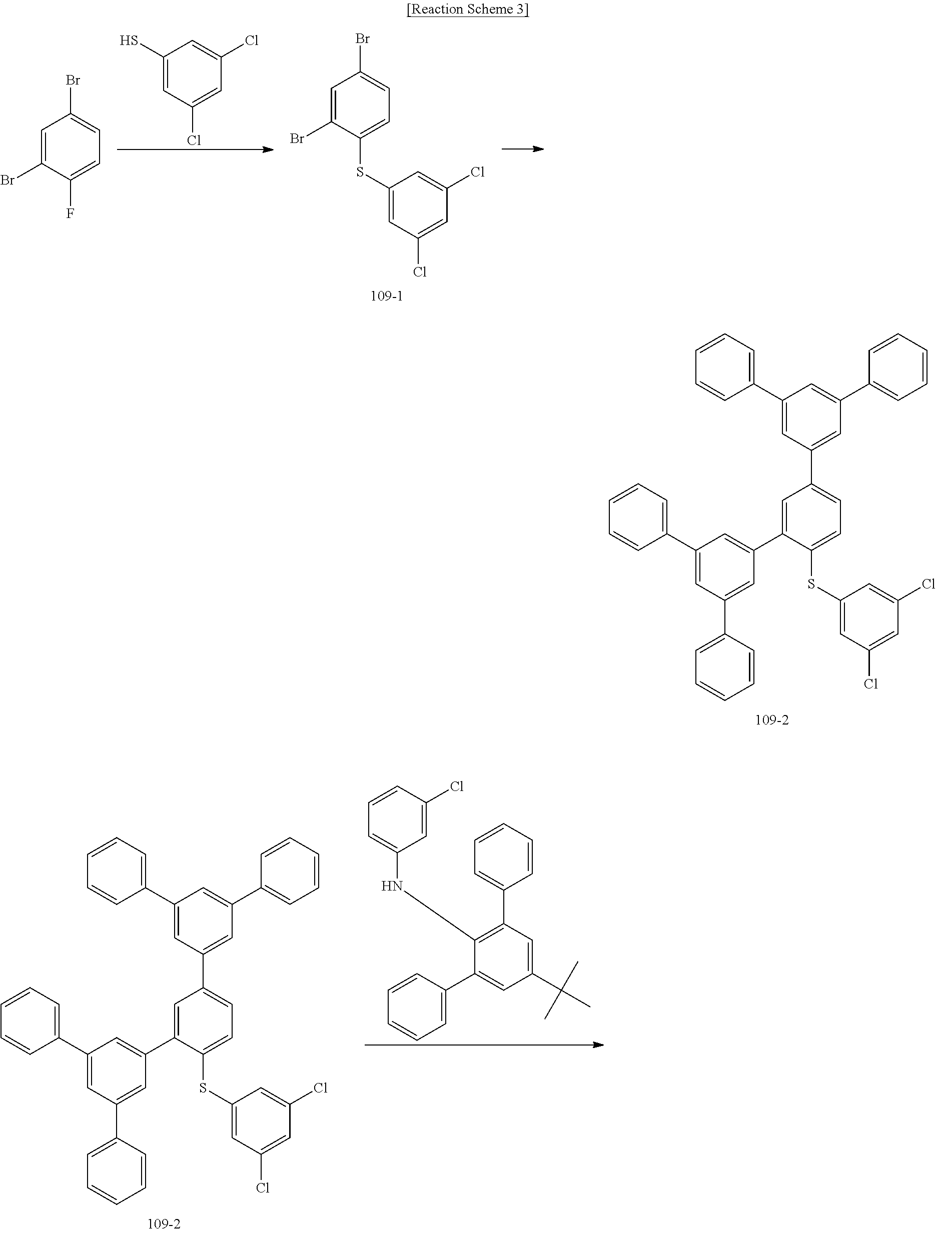 [SMILES: Fc1ccc(Br)cc1Br ; Sc1cc(Cl)cc(Cl)c1 ; Clc1cc(Cl)cc(Sc2ccc(Br)cc2Br)c1 ; Clc1cc(Cl)cc(Sc2ccc(-c3cc(-c4ccccc4)cc(-c4ccccc4)c3)cc2-c2cc(-c3ccccc3)cc(-c3ccccc3)c2)c1 ; Clc1cc(Cl)cc(Sc2ccc(-c3cc(-c4ccccc4)cc(-c4ccccc4)c3)cc2-c2cc(-c3ccccc3)cc(-c3ccccc3)c2)c1 ; CC(C)(C)c1cc(-c2ccccc2)c(Nc2cccc(Cl)c2)c(-c2ccccc2)c1]

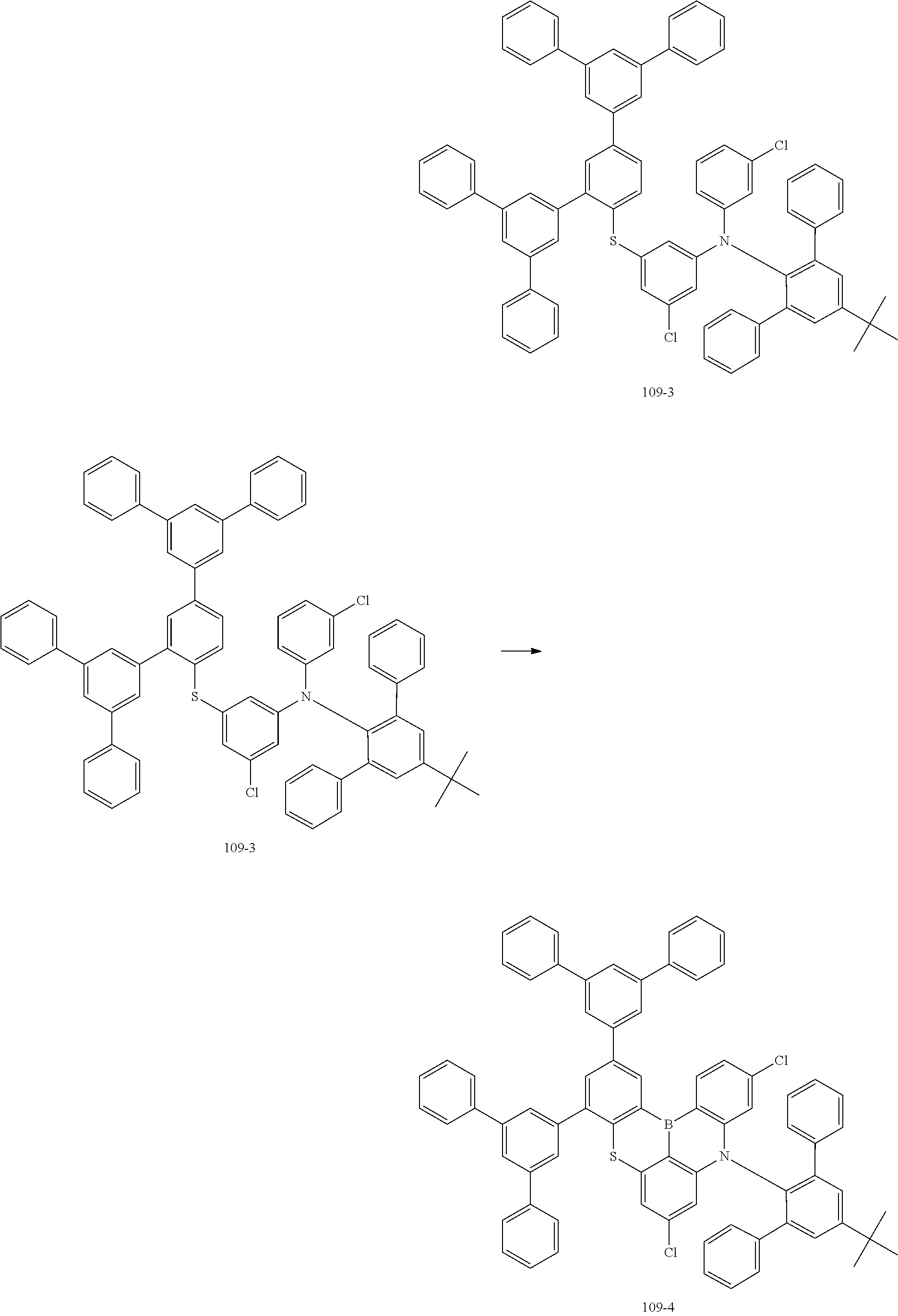 [SMILES: CC(C)(C)c1cc(-c2ccccc2)c(N(c2cccc(Cl)c2)c2cc(Cl)cc(Sc3ccc(-c4cc(-c5ccccc5)cc(-c5ccccc5)c4)cc3-c3cc(-c4ccccc4)cc(-c4ccccc4)c3)c2)c(-c2ccccc2)c1 ; CC(C)(C)c1cc(-c2ccccc2)c(N(c2cccc(Cl)c2)c2cc(Cl)cc(Sc3ccc(-c4cc(-c5ccccc5)cc(-c5ccccc5)c4)cc3-c3cc(-c4ccccc4)cc(-c4ccccc4)c3)c2)c(-c2ccccc2)c1 ; CC(C)(C)c1cc(-c2ccccc2)c(N2c3cc(Cl)ccc3B3c4cc(-c5cc(-c6ccccc6)cc(-c6ccccc6)c5)cc(-c5cc(-c6ccccc6)cc(-c6ccccc6)c5)c4Sc4cc(Cl)cc2c43)c(-c2ccccc2)c1]

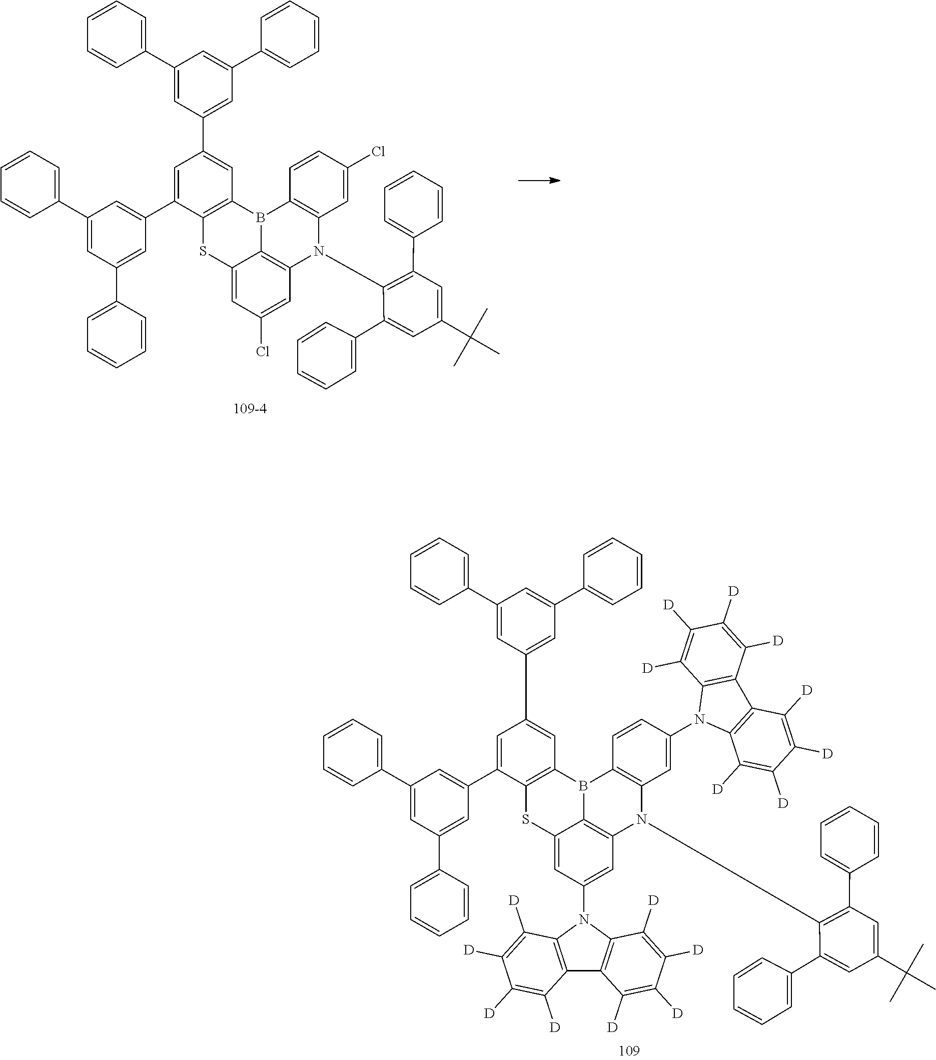 [SMILES: CC(C)(C)c1cc(-c2ccccc2)c(N2c3cc(Cl)ccc3B3c4cc(-c5cc(-c6ccccc6)cc(-c6ccccc6)c5)cc(-c5cc(-c6ccccc6)cc(-c6ccccc6)c5)c4Sc4cc(Cl)cc2c43)c(-c2ccccc2)c1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-n3c4c([2H])c([2H])c([2H])c([2H])c4c4c([2H])c([2H])c([2H])c([2H])c43)cc3c1B2c1cc(-c2cc(-c4ccccc4)cc(-c4ccccc4)c2)cc(-c2cc(-c4ccccc4)cc(-c4ccccc4)c2)c1S3]

### [Synthesis of Intermediate 109-1]

2,4-dibromo-1-fluorobenzene (1 eq), 3,5-dichlorobenzenethiol (1.2 eq), and K₃PO₄ (2 eq) were dissolved in DMF and stirred at about 160° C. for about 12 hours. After cooling the reactant, a solvent was removed under reduced pressure, the resultant was washed with ethyl acetate and water three times and separated to obtain an organic layer. The obtained organic layer was dried over MgSO₄ and dried under reduced pressure. The resulting product was purified by column chromatography with MC and n-hexane to obtain Intermediate 109-1 (yield: 73%).

### [Synthesis of Intermediate 109-2]

Intermediate 109-2 (1 eq), [1,1′:3′,1″-terphenyl]-5′-ylboronic acid (2.5 eq), Pd(PPh₃)₄ (0.1 eq), and K₂CO₃ (3 eq) were dissolved in a mixture of water and tetrahydrofuran (THF) (weight ratio of 2:1) and stirred at about 80° C. for about 24 hours. After cooling, the reactant was washed with ethyl acetate and water three times and separated to obtain an organic layer. The obtained organic layer was dried over MgSO₄ and dried under reduced pressure. The resulting product was purified by column chromatography with MC and n-hexane to obtain Intermediate 109-2 (yield: 62%).

### [Synthesis of Intermediate 109-3]

Intermediate 109-2 (1 eq), 5′-(tert-butyl)-N-(3-chlorophenyl)-[1,1′:3′,1″-terphenyl]-2′-amine (1 eq), tris(dibenzylideneacetone)dipalladium(0) (0.05 eq), tri-tert-butylphosphine (0.1 eq), and sodium tert-butoxide (4 eq) were dissolved in toluene and stirred at about 90° C. for about 8 hours. After cooling, the reactant was washed with ethyl acetate and water three times and separated to obtain an organic layer. The obtained organic layer was dried over MgSO₄ and dried under reduced pressure. The resulting product was purified by column chromatography with MC and n-hexane to obtain Intermediate 109-3 (yield: 42%).

### [Synthesis of Intermediate 109-4]

Intermediate 109-3 (1 eq) was dissolved in ortho dichlorobenzene and cooled to about 0° C., and BBr₃ (3 eq) was slowly injected, in a nitrogen atmosphere. After completion of dropping, the temperature was raised to 180° C., and the resultant was stirred for about 24 hours. After cooling the reactant, triethylamine was slowly dropped into the flask containing the reactant to terminate the reaction, ethyl alcohol was put into the reactant to precipitate solids, and the solid powder was obtained by filtration. The obtained solid powder was purified by column chromatography with MC and n-hexane and recrystallized using toluene and acetone to obtain Intermediate 109-4 (yield: 5%).

### [Synthesis of Compound 109]

Intermediate 109-4 (1 eq), 9H-carbazole-1,2,3,4,5,6,7,8-d8 (2 eq), tris(dibenzylideneacetone)dipalladium(0) (0.20 eq), tri-tert-butylphosphine (0.5 eq), and sodium tert-butoxide (3 eq) were dissolved in o-xylene, and the resultant was stirred at about 150° C. for about 48 hours. After cooling, the reactant was washed with ethyl acetate and water three times and separated to obtain an organic layer. The obtained organic layer was dried over MgSO₄ and dried under reduced pressure. The resulting product was purified by column chromatography with MC and n-hexane to obtain Compound 109 (yield: 58%).

### (4) Synthesis of Fused Polycyclic Compound 31

Fused Polycyclic Compound 31 according to an example may be synthesized by, for example, Reaction Scheme 4.

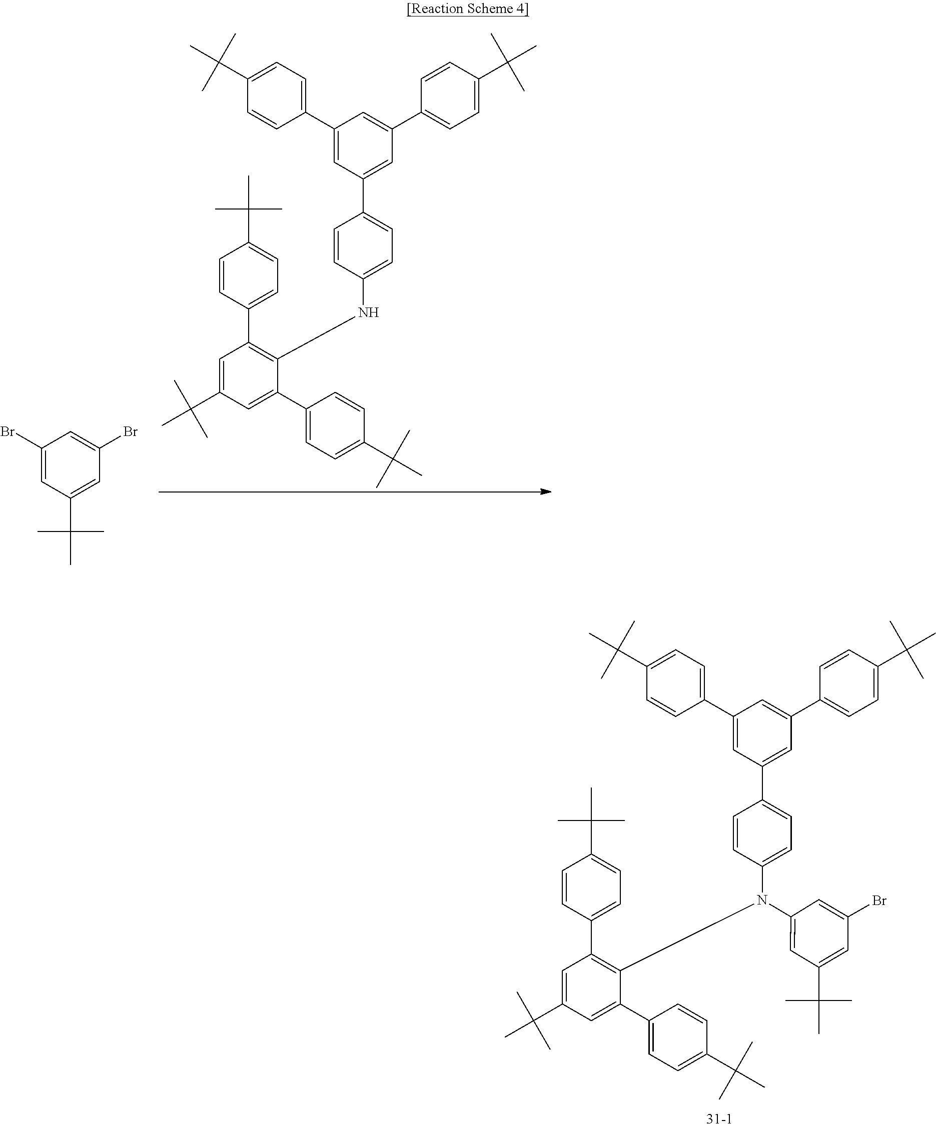

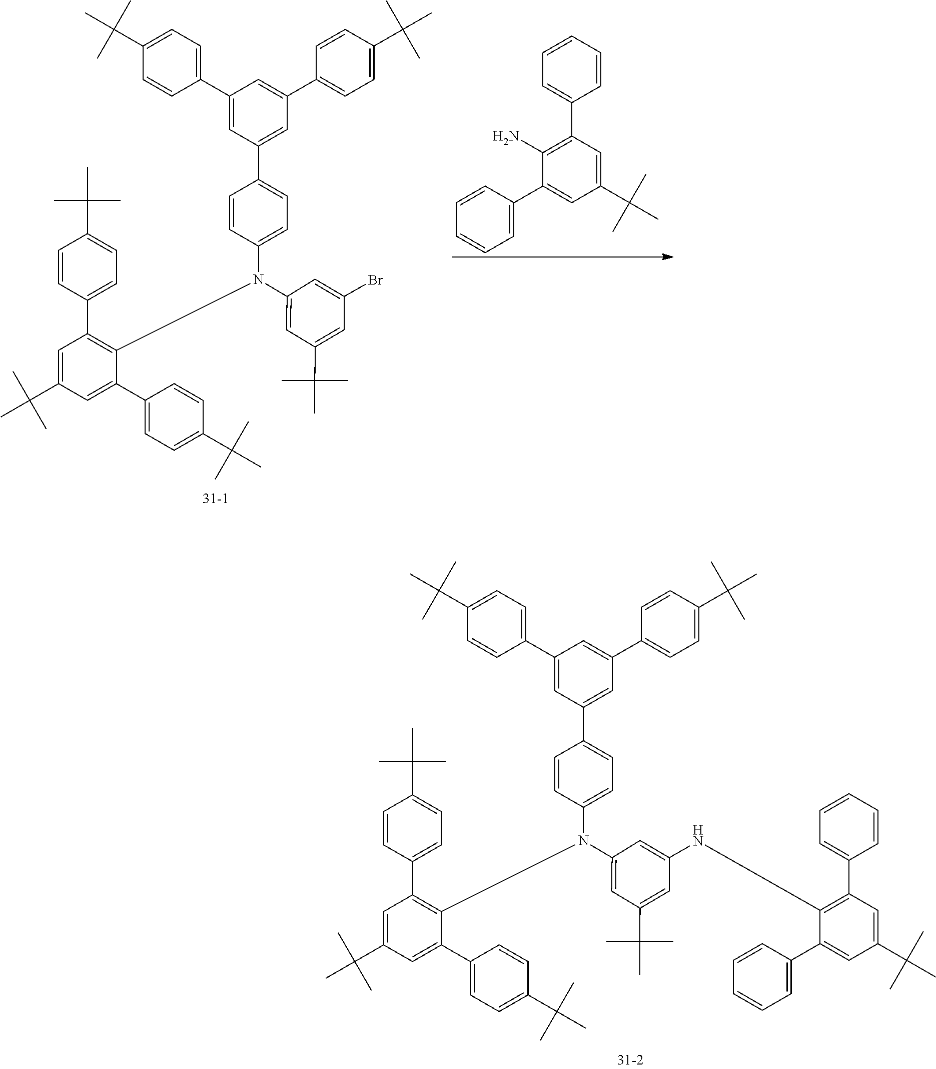 [SMILES: CC(C)(C)c1ccc(-c2cc(-c3ccc(N(c4cc(Br)cc(C(C)(C)C)c4)c4c(-c5ccc(C(C)(C)C)cc5)cc(C(C)(C)C)cc4-c4ccc(C(C)(C)C)cc4)cc3)cc(-c3ccc(C(C)(C)C)cc3)c2)cc1 ; CC(C)(C)c1cc(-c2ccccc2)c(N)c(-c2ccccc2)c1 ; CC(C)(C)c1ccc(-c2cc(-c3ccc(N(c4cc(Nc5c(-c6ccccc6)cc(C(C)(C)C)cc5-c5ccccc5)cc(C(C)(C)C)c4)c4c(-c5ccc(C(C)(C)C)cc5)cc(C(C)(C)C)cc4-c4ccc(C(C)(C)C)cc4)cc3)cc(-c3ccc(C(C)(C)C)cc3)c2)cc1]

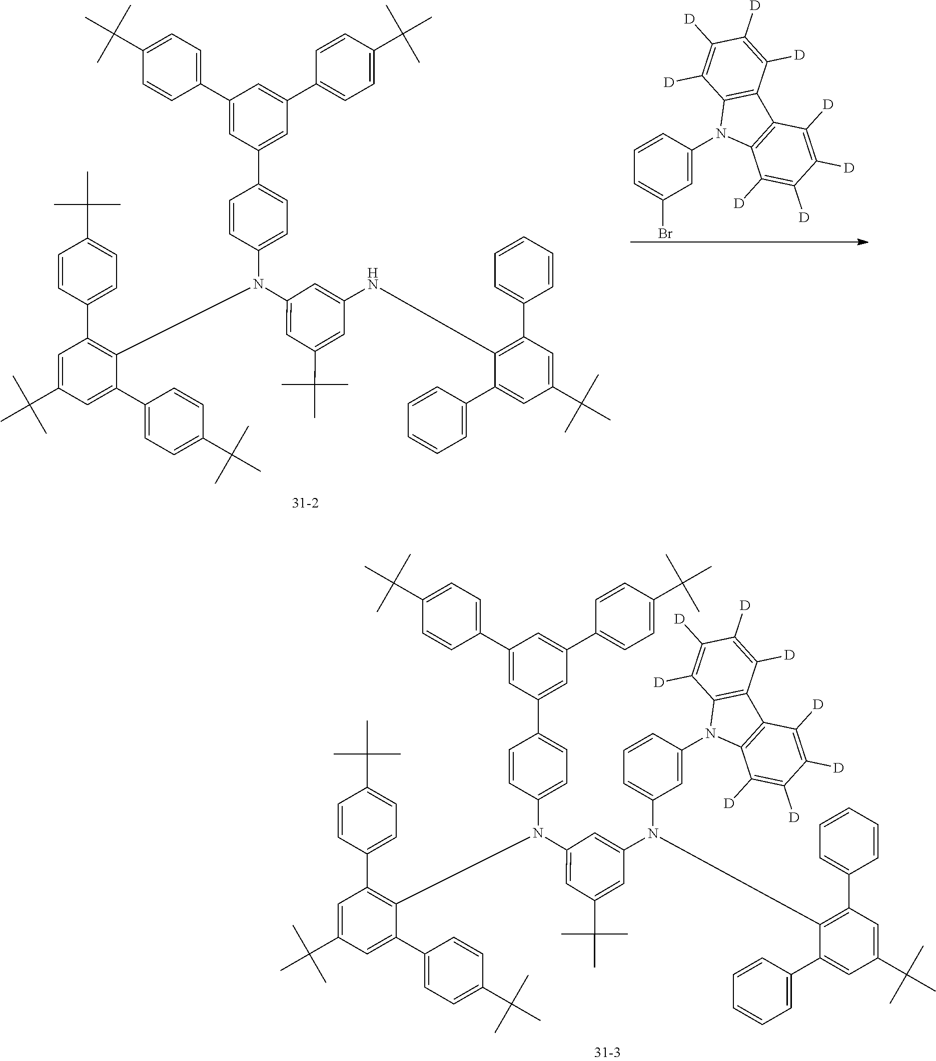

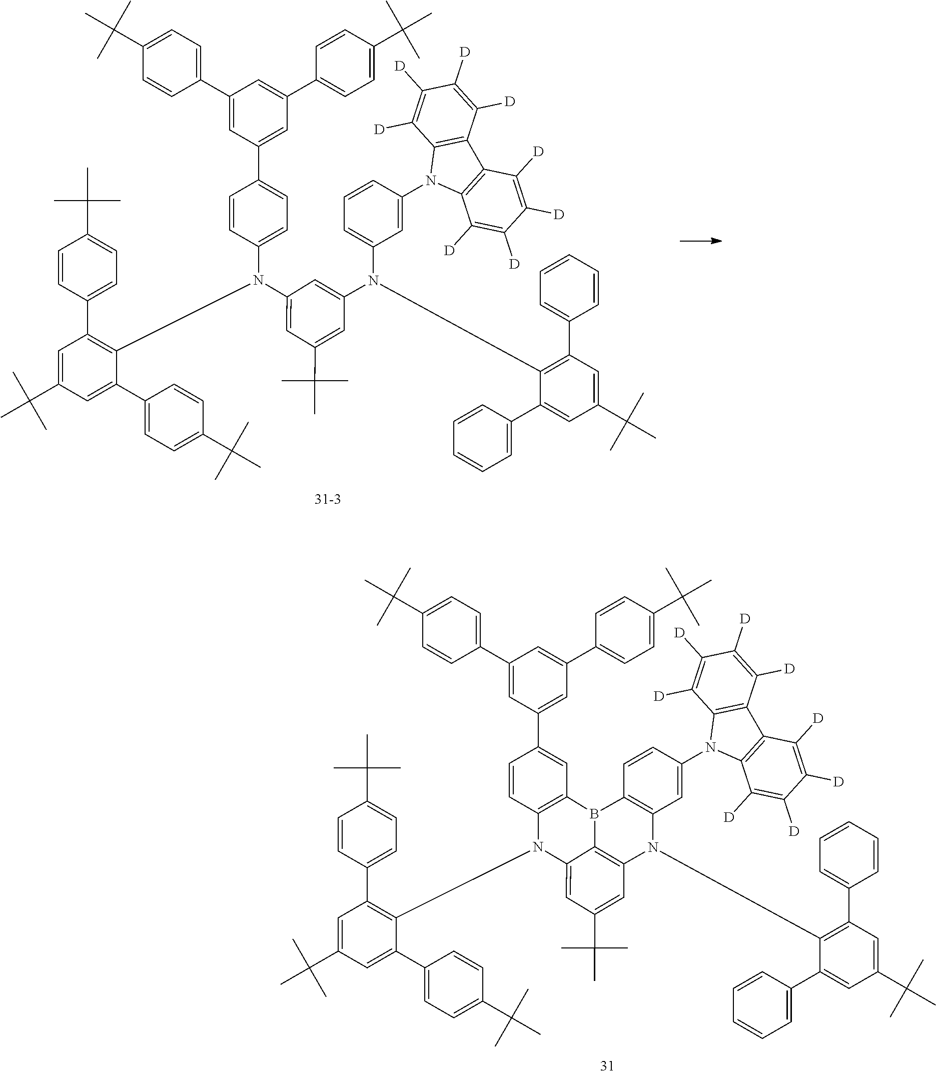

### [Synthesis of Intermediate 31-1]

1,3-dibromo-5-(tert-butyl)benzene (1 eq), 4,4″,5′-tri-tert-butyl-N-(4″-(tert-butyl)-5′-(4-(tert-butyl)phenyl)-[1,1′:3′,1″-terphenyl]-4-yl)-[1,1′:3′,1″-terphenyl]-2′-amine (0.8 eq), tris(dibenzylideneacetone)dipalladium(0) (0.05 eq), tri-tert-butylphosphine (0.1 eq), and sodium tert-butoxide (3 eq) were dissolved in toluene and stirred at about 80° C. for about 8 hours. After cooling, the reactant was washed with ethyl acetate and water three times and separated to obtain an organic layer. The obtained organic layer was dried over MgSO₄ and dried under reduced pressure. The resulting product was purified by column chromatography with MC and n-hexane to obtain Intermediate 31-1 (yield: 58%).

### [Synthesis of Intermediate 31-2]

Intermediate 31-1 (1 eq), 5′-(tert-butyl)-[1,1′:3′,1″-terphenyl]-2′-amine (1.1 eq), Tris(dibenzylideneacetone)dipalladium(0) (0.05 eq), tri-tert-butylphosphine (0.1 eq), and sodium tert-butoxide (3 eq) were dissolved in toluene and stirred at about 110° C. for about 24 hours. After cooling, the reactant was washed with ethyl acetate and water three times and separated to obtain an organic layer. The obtained organic layer was dried over MgSO₄ and dried under reduced pressure. The resulting product was purified by column chromatography with MC and n-hexane to obtain Intermediate 31-2 (yield: 81%).

### [Synthesis of Intermediate 31-3]

Intermediate 31-2 (1 eq), 9-(3-bromophenyl)-9H-carbazole-1,2,3,4,5,6,7,8-d8 (2 eq), tris(dibenzylideneacetone)dipalladium(0) (0.15 eq), tri-tert-butylphosphine (0.3 eq), and sodium tert-butoxide (4 eq) were dissolved in o-xylene and was stirred at about 160° C. for about 48 hours. After cooling, the reactant was washed with ethyl acetate and water three times and separated to obtain an organic layer. The obtained organic layer was dried over MgSO₄ and dried under reduced pressure. The resulting product was purified by column chromatography with MC and n-hexane to obtain Intermediate 31-3 (yield: 33%).

### [Synthesis of Intermediate 31]

Intermediate 31-3 (1 eq) was dissolved in ortho dichlorobenzene and cooled to about 0° C., and BBr₃ (3 eq) was slowly injected in a nitrogen atmosphere. After completion of dropping, the temperature was raised to 180° C., and the resultant was stirred for about 24 hours. After cooling the reactant, triethylamine was slowly dropped into the flask containing the reactant to terminate the reaction, ethyl alcohol was put into the reactant to precipitate solids, and the solid powder was obtained by filtration. The obtained solid powder was purified by column chromatography with MC and n-hexane and recrystallized using toluene and acetone to obtain Compound 31 (yield: 11%).

### (5) Synthesis of Fused Polycyclic Compound 90

Fused Polycyclic Compound 90 according to an example may be synthesized by, for example, Reaction Scheme 5.

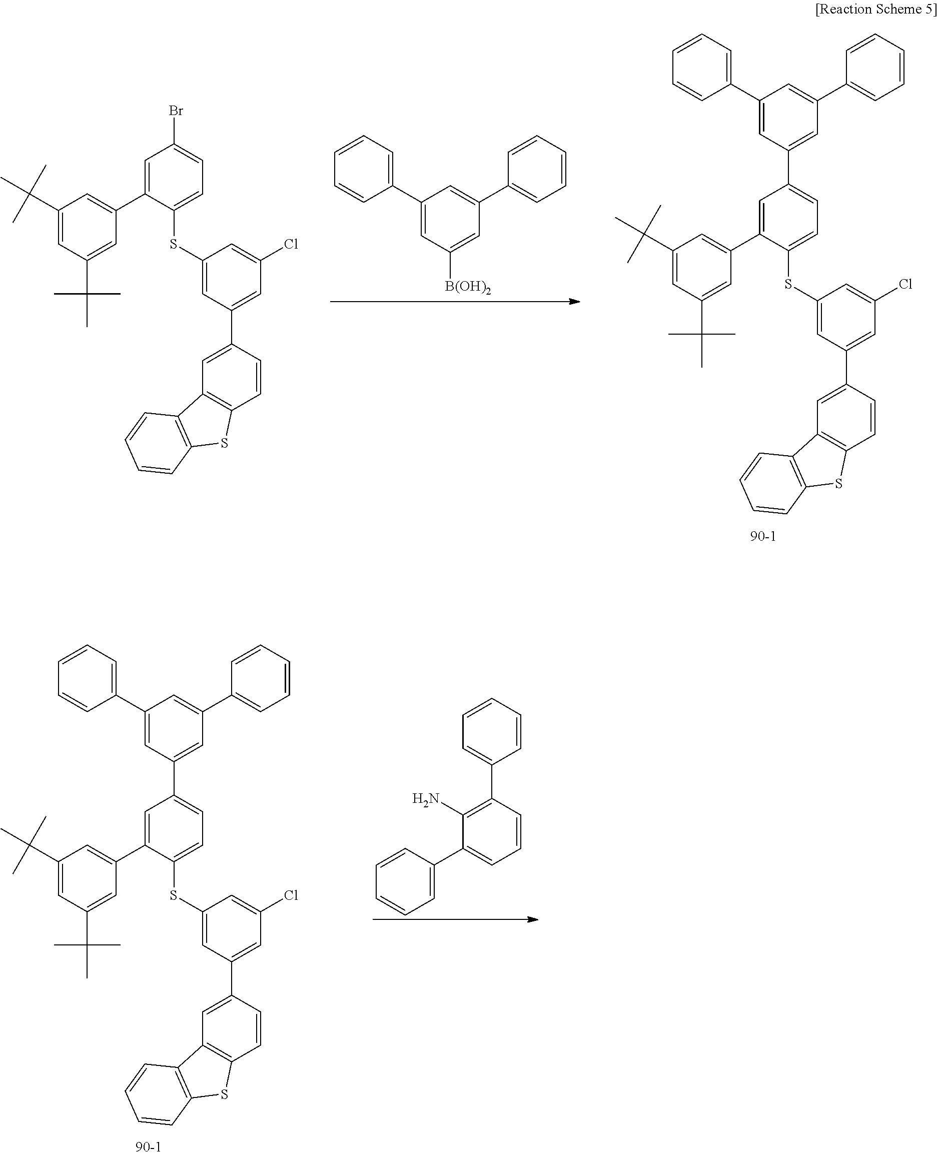 [SMILES: CC(C)(C)c1cc(-c2cc(Br)ccc2Sc2cc(Cl)cc(-c3ccc4sc5ccccc5c4c3)c2)cc(C(C)(C)C)c1 ; OB(O)c1cc(-c2ccccc2)cc(-c2ccccc2)c1 ; CC(C)(C)c1cc(-c2cc(-c3cc(-c4ccccc4)cc(-c4ccccc4)c3)ccc2Sc2cc(Cl)cc(-c3ccc4sc5ccccc5c4c3)c2)cc(C(C)(C)C)c1 ; CC(C)(C)c1cc(-c2cc(-c3cc(-c4ccccc4)cc(-c4ccccc4)c3)ccc2Sc2cc(Cl)cc(-c3ccc4sc5ccccc5c4c3)c2)cc(C(C)(C)C)c1 ; Nc1c(-c2ccccc2)cccc1-c1ccccc1]

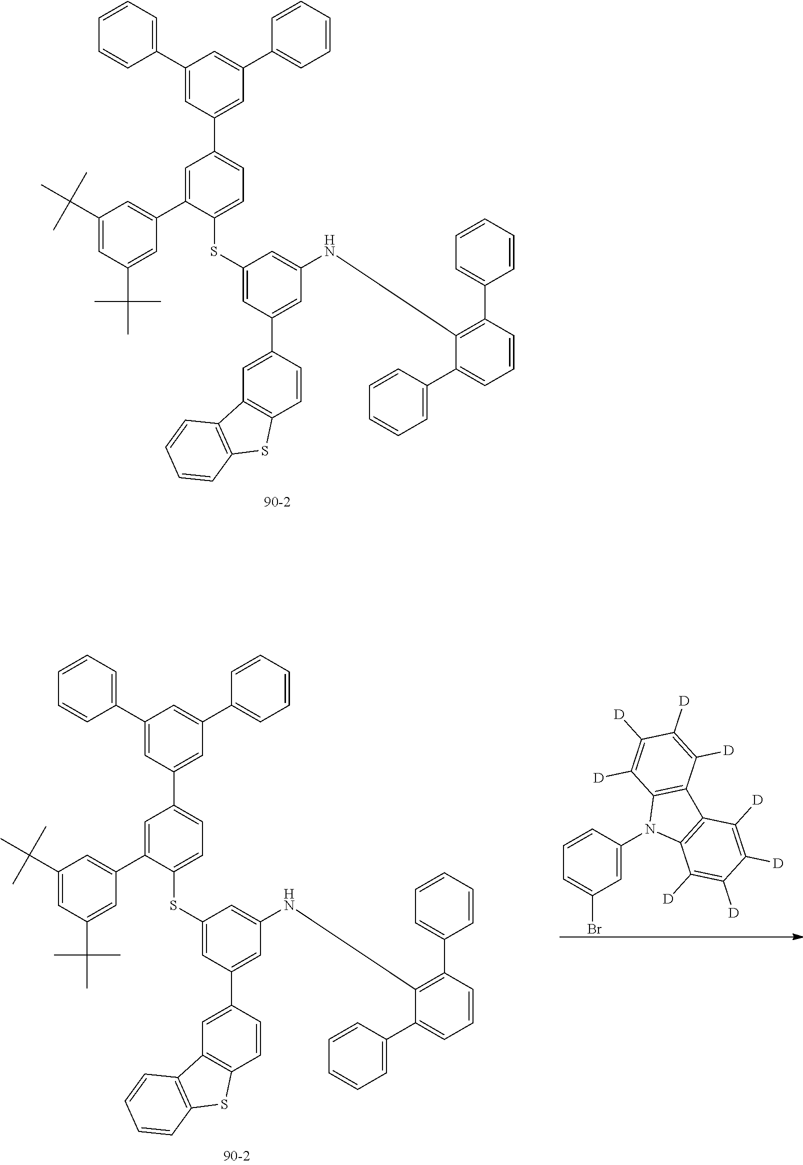 [SMILES: CC(C)(C)c1cc(-c2cc(-c3cc(-c4ccccc4)cc(-c4ccccc4)c3)ccc2Sc2cc(Nc3c(-c4ccccc4)cccc3-c3ccccc3)cc(-c3ccc4sc5ccccc5c4c3)c2)cc(C(C)(C)C)c1 ; CC(C)(C)c1cc(-c2cc(-c3cc(-c4ccccc4)cc(-c4ccccc4)c3)ccc2Sc2cc(Nc3c(-c4ccccc4)cccc3-c3ccccc3)cc(-c3ccc4sc5ccccc5c4c3)c2)cc(C(C)(C)C)c1 ; [2H]c1c([2H])c([2H])c2c(c1[2H])c1c([2H])c([2H])c([2H])c([2H])c1n2-c1cccc(Br)c1]

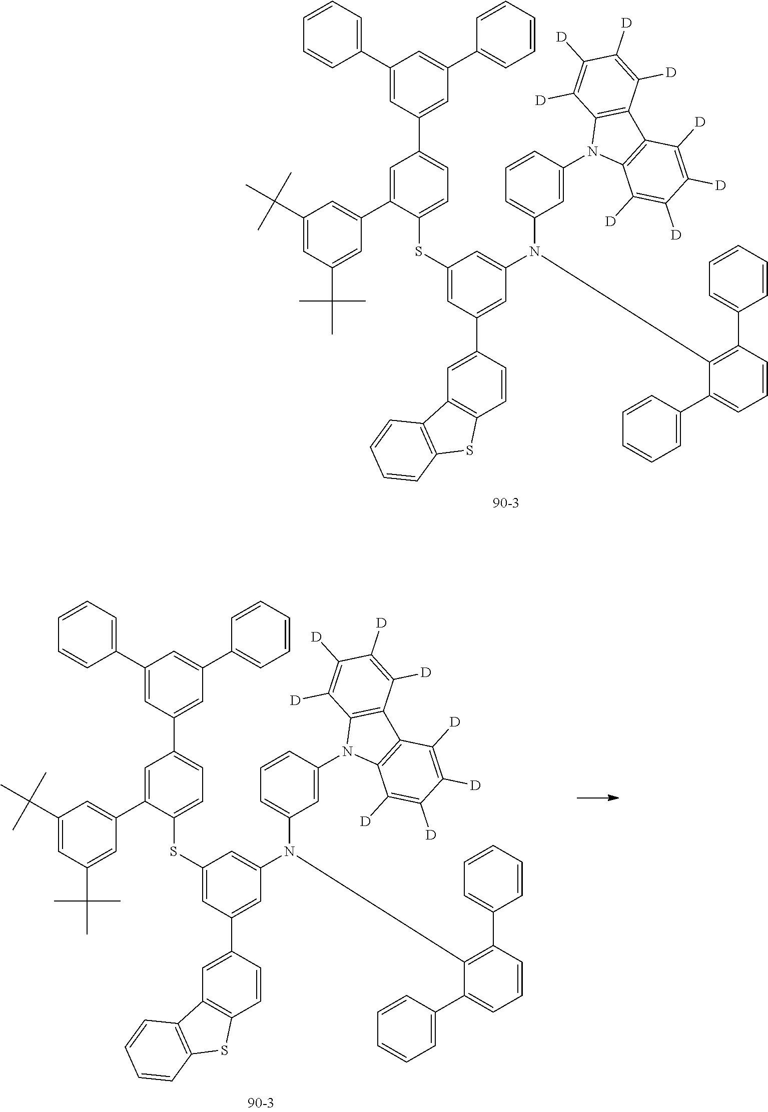 [SMILES: [2H]c1c([2H])c([2H])c2c(c1[2H])c1c([2H])c([2H])c([2H])c([2H])c1n2-c1cccc(N(c2cc(Sc3ccc(-c4cc(-c5ccccc5)cc(-c5ccccc5)c4)cc3-c3cc(C(C)(C)C)cc(C(C)(C)C)c3)cc(-c3ccc4sc5ccccc5c4c3)c2)c2c(-c3ccccc3)cccc2-c2ccccc2)c1 ; [2H]c1c([2H])c([2H])c2c(c1[2H])c1c([2H])c([2H])c([2H])c([2H])c1n2-c1cccc(N(c2cc(Sc3ccc(-c4cc(-c5ccccc5)cc(-c5ccccc5)c4)cc3-c3cc(C(C)(C)C)cc(C(C)(C)C)c3)cc(-c3ccc4sc5ccccc5c4c3)c2)c2c(-c3ccccc3)cccc2-c2ccccc2)c1]

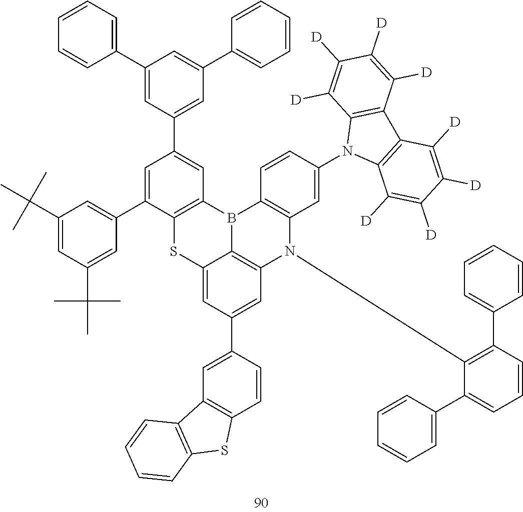 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4sc5ccccc5c4c3)cc3c1B2c1cc(-c2cc(-c4ccccc4)cc(-c4ccccc4)c2)cc(-c2cc(C(C)(C)C)cc(C(C)(C)C)c2)c1S3]

### [Synthesis of Intermediate 90-1]

2-(3-((5-bromo-3′,5′-di-tert-butyl-[1,1′-biphenyl]-2-yl)thio)-5-chlorophenyl)dibenzo[b,d]thiophene (1 eq), [1,1′:3′,1″-terphenyl]-5′-ylboronic acid (1.2 eq), Pd(PPh₃)₄ (0.05 eq), and K₂CO₃ (3 eq) were dissolved in a mixture of water and THF (weight ratio of 2:1) and stirred at about 80° C. for about 12 hours. After cooling, the reactant was washed with ethyl acetate and water three times and separated to obtain an organic layer. The obtained organic layer was dried over MgSO₄ and dried under reduced pressure. The resulting product was purified by column chromatography with MC and n-hexane to obtain Intermediate 90-1 (yield: 62%).

### [Synthesis of Intermediate 90-2]

Intermediate 90-1 (1 eq), [1,1′:3′,1″-terphenyl]-2′-amine (1 eq), tris(dibenzylideneacetone)dipalladium(0) (0.05 eq), tri-tert-butylphosphine (0.1 eq), and sodium tert-butoxide (3 eq) were dissolved in toluene and stirred at about 110° C. for about 12 hours. After cooling, the reactant was washed with ethyl acetate and water three times and separated to obtain an organic layer. The obtained organic layer was dried over MgSO₄ and dried under reduced pressure. The resulting product was purified by column chromatography with MC and n-hexane to obtain Intermediate 90-2 (yield: 78%).

### [Synthesis of Intermediate 90-3]

Intermediate 90-2 (1 eq), 9-(3-bromophenyl)-9H-carbazole-1,2,3,4,5,6,7,8-d8 (2 eq), tris(dibenzylideneacetone)dipalladium(0) (0.15 eq), tri-tert-butylphosphine (0.3 eq), and sodium tert-butoxide (4 eq) were dissolved in o-xylene and stirred at about 160° C. for about 48 hours. After cooling, the reactant was washed with ethyl acetate and water three times and separated to obtain an organic layer. The obtained organic layer was dried over MgSO₄ and dried under reduced pressure. The resulting product was purified by column chromatography with MC and n-hexane to obtain Intermediate 90-3 (yield: 27%).

### [Synthesis of Compound 90]

Intermediate 90-3 (1 eq) was dissolved in ortho dichlorobenzene and cooled to about 0° C., and BBr₃ (3 eq) was slowly injected in a nitrogen atmosphere. After completion of dropping, the temperature was raised to 180° C., and the resultant was stirred for about 24 hours. After cooling the reactant, triethylamine was slowly dropped into the flask containing the reactant to terminate the reaction, ethyl alcohol was put into the reactant to precipitate solids, and the solid powder was obtained by filtration. The obtained solid powder was purified by column chromatography with MC and n-hexane and recrystallized using toluene and acetone to obtain Compound 90 (yield: 4%).

### 2. Manufacture and Evaluation of Light-Emitting Element

### (1) Manufacture of Light-Emitting Elements

The light-emitting elements including a polycyclic compound according to an example, or a comparative example compound in an emission layer were manufactured by the method described below. Compounds 12, 15, 109, 31, and 90, which are polycyclic compounds according to embodiments were used as a dopant material for the emission layer to manufacture the light-emitting elements according to Examples 1 to 5, respectively. Comparative Example Compounds CX1 to CX6 were each respectively used as dopant materials of the emission layer to manufacture light-emitting elements according to Comparative Examples 1 to 6.

A glass substrate (made by Corning Co.), on which an ITO electrode of about 15 Ω/cm² (thickness of about 1,200 Å) was formed as a first electrode, was cut to a size of about 50 mm×50 mm×0.7 mm, cleansed by ultrasonic waves using isopropyl alcohol and pure water for about five minutes each, irradiated with ultraviolet rays for about 30 minutes, and exposed to ozone. The glass substrate was mounted on a vacuum deposition apparatus.

NPD was deposited on the first electrode to form a hole injection layer having a thickness of 300 Å, and Compound H-1-1 was deposited on the hole injection layer to form a hole transport layer having a thickness of 200 Å. CzSi was deposited on the hole transport layer to form an emission auxiliary layer having a thickness of 100 Å.

A host mixture, in which a first host HT and a second host ET were mixed at a weight ratio of 5:5 as listed in Table 2, a sensitizer, and a dopant were co-deposited on the emission auxiliary layer at a weight ratio of about 85:14:1 to form an emission layer having a thickness of 350 Å. As the dopant, Example Compound or Comparative Example Compound was used.

ETH2 was deposited on the emission layer to form a hole-blocking layer having a thickness of 50 Å, and a mixed layer of CNNPTRZ and LiQ (weight ratio of 4.0:6.0) was deposited on the hole-blocking layer to form an electron transport layer having a thickness of 310 Å, and Yb was deposited on the electron transport layer to form an electron injection layer having a thickness of 15 Å. Mg was deposited in a vacuum to form a second electrode having a thickness of 800 Å, thereby manufacturing a light-emitting element.

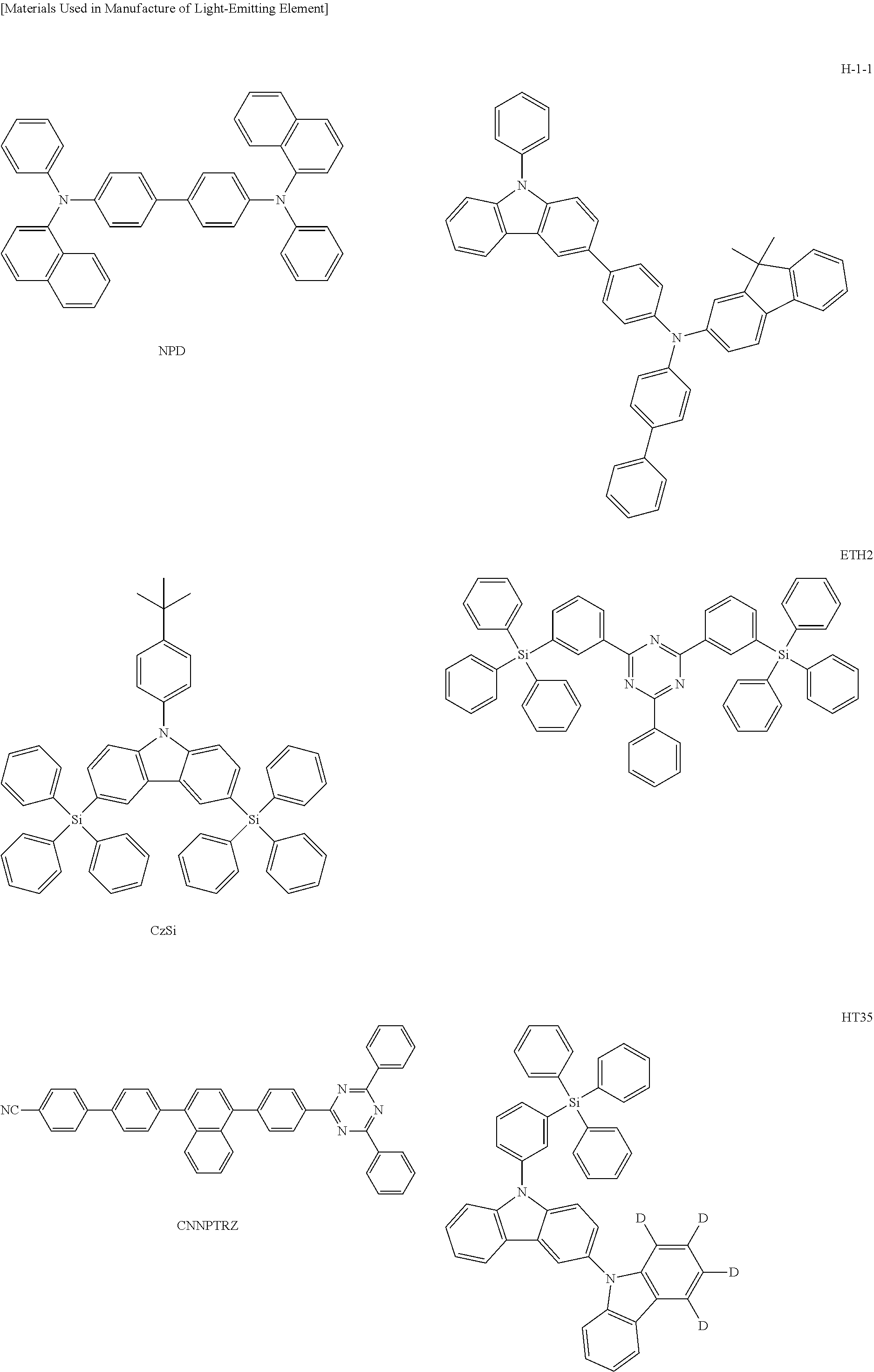

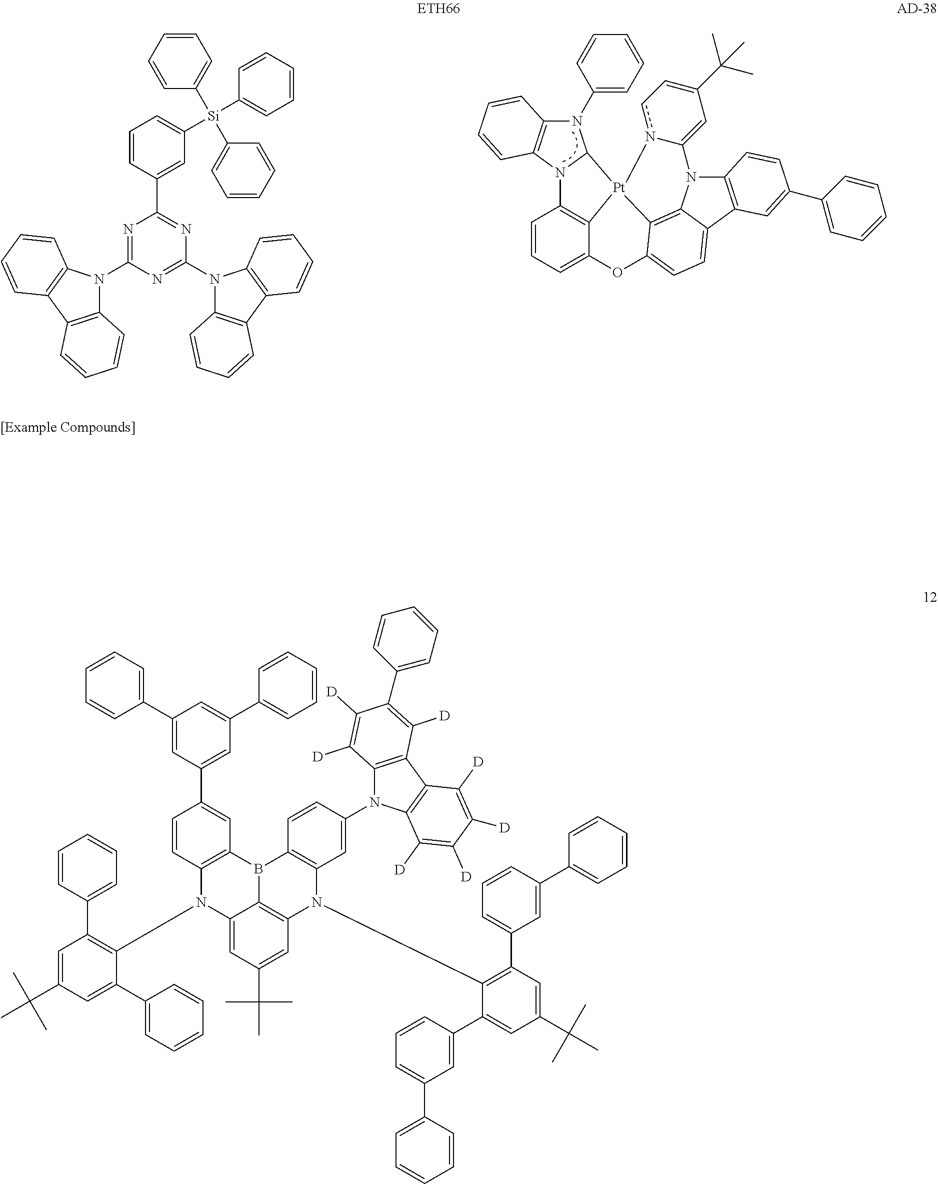

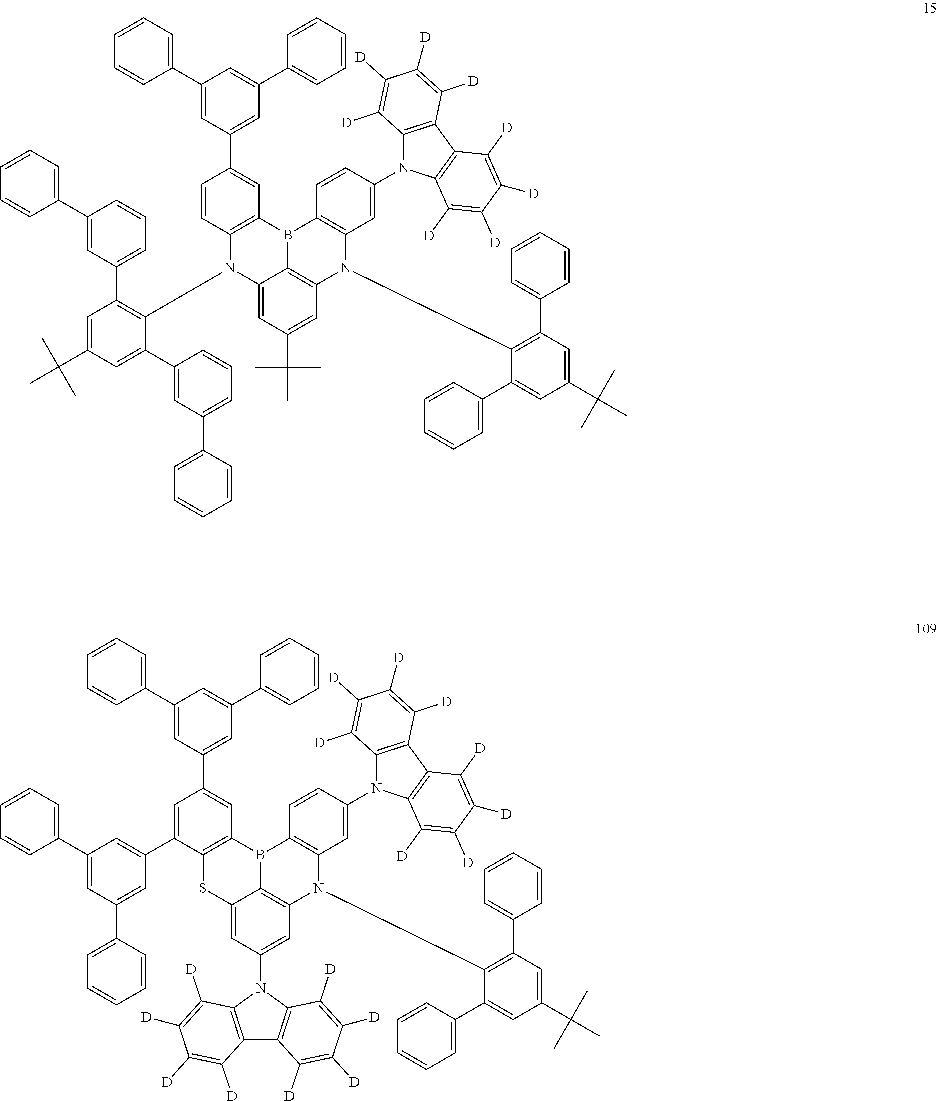

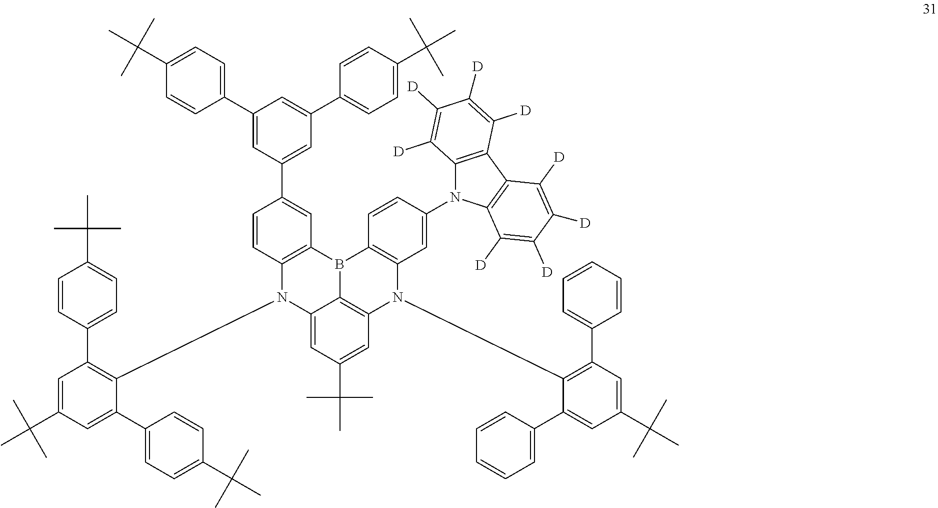 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cc(-c4ccc(C(C)(C)C)cc4)cc(-c4ccc(C(C)(C)C)cc4)c2)ccc1N3c1c(-c2ccc(C(C)(C)C)cc2)cc(C(C)(C)C)cc1-c1ccc(C(C)(C)C)cc1]

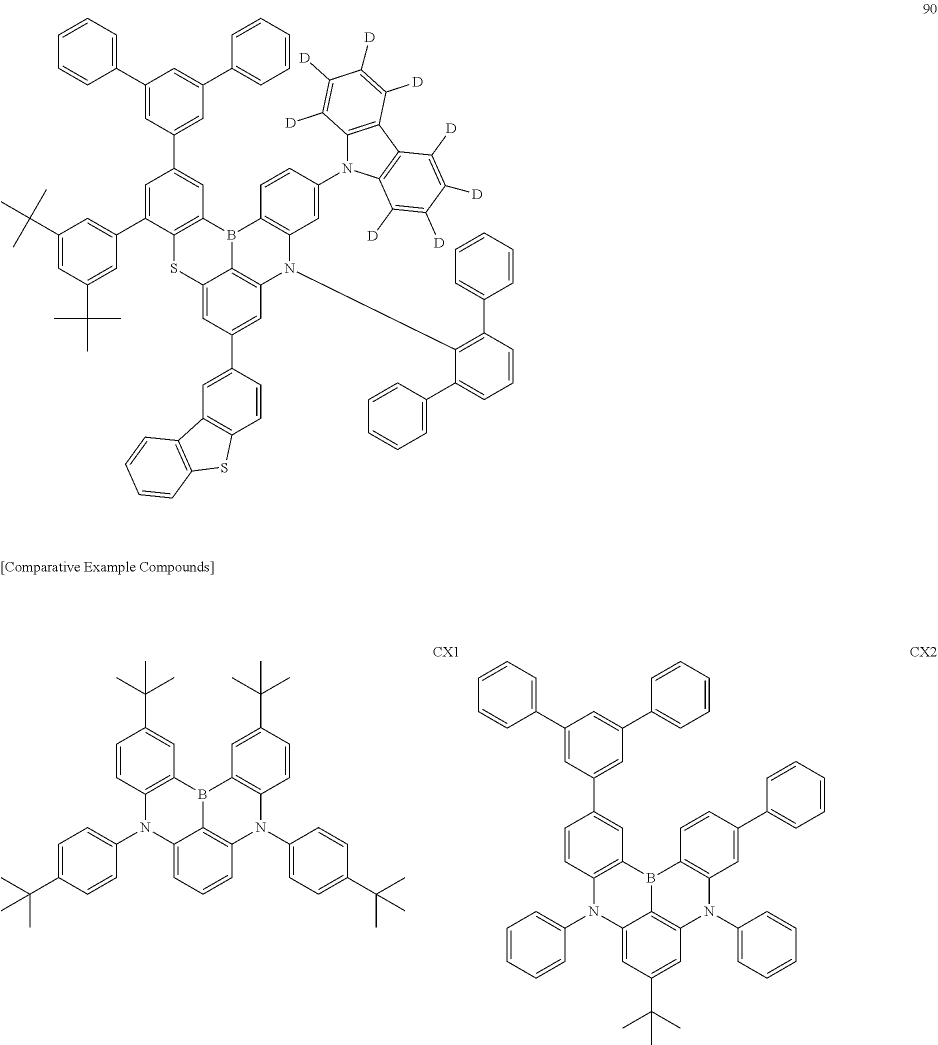 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4sc5ccccc5c4c3)cc3c1B2c1cc(-c2cc(-c4ccccc4)cc(-c4ccccc4)c2)cc(-c2cc(C(C)(C)C)cc(C(C)(C)C)c2)c1S3 ; CC(C)(C)c1ccc(N2c3ccc(C(C)(C)C)cc3B3c4cc(C(C)(C)C)ccc4N(c4ccc(C(C)(C)C)cc4)c4cccc2c43)cc1 ; CC(C)(C)c1cc2c3c(c1)N(c1ccccc1)c1cc(-c4ccccc4)ccc1B3c1cc(-c3cc(-c4ccccc4)cc(-c4ccccc4)c3)ccc1N2c1ccccc1]

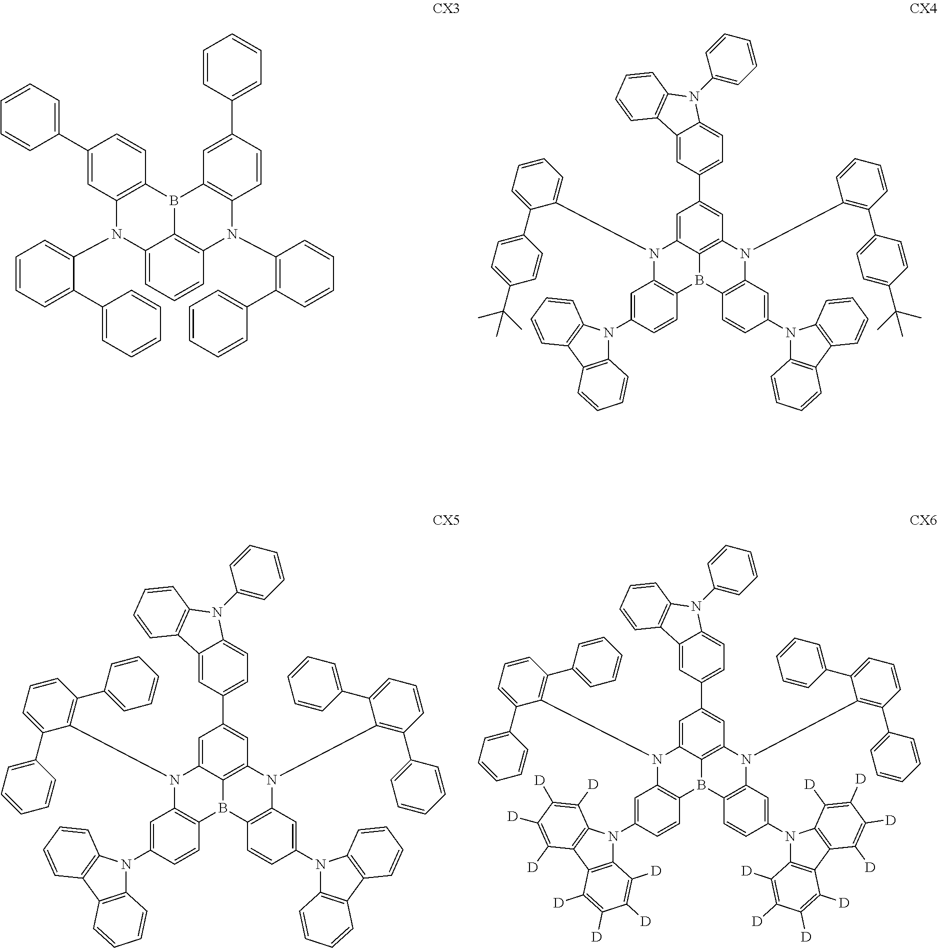

### (2) Evaluation of Light-Emitting Element

The light-emitting elements according to Examples and Comparative Examples were evaluated and the results were listed in Table 2. A driving voltage, emission efficiency, emission wavelength, and lifespan at a current density of 10 mA/cm² were measured using a luminance meter PR650. The time taken for the luminance to decrease to 95% of an initial luminance was measured as a lifespan (T95). Relative lifespans were calculated with respect to the lifespan of the light-emitting element according to Comparative Example 1, and the results were listed.

TABLE 2

| | | | | Driving | Emission | Emission | |
|---|---|---|---|---|---|---|---|
| | Host | | | Voltage | efficiency | wavelength | Lifespan |
| | (HT:ET = 5:5) | Sensitizer | Dopant | (V) | (cd/A) | (nm) | (T95) |
| Example 1 | HT35/ETH66 | AD-38 | Compound 12 | 4.6 | 24.8 | 459 | 7.4 |
| Example 2 | HT35/ETH66 | AD-38 | Compound 15 | 4.4 | 26.1 | 460 | 7.8 |
| Example 3 | HT35/ETH66 | AD-38 | Compound 109 | 4.5 | 25.7 | 459 | 6.9 |
| Example 4 | HT35/ETH66 | AD-38 | Compound 31 | 4.6 | 26.4 | 461 | 6.5 |
| Example 5 | HT35/ETH66 | AD-38 | Compound 90 | 4.6 | 25.3 | 462 | 6.8 |
| Comparative | HT35/ETH66 | AD-38 | Comparative | 5.2 | 19.8 | 465 | 1 |
| Example 1 | | | Example | | | | |
| | | | Compound CX1 | | | | |
| Comparative | HT35/ETH66 | AD-38 | Comparative | 5.1 | 18.7 | 468 | 1.2 |
| Example 2 | | | Example | | | | |
| | | | Compound CX2 | | | | |
| Comparative | HT35/ETH66 | AD-38 | Comparative | 5.2 | 19.6 | 467 | 1.6 |
| Example 3 | | | Example | | | | |
| | | | Compound CX3 | | | | |
| Comparative | HT35/ETH66 | AD-38 | Comparative | 4.7 | 23.1 | 463 | 4.4 |
| Example 4 | | | Example | | | | |
| | | | Compound CX4 | | | | |
| Comparative | HT35/ETH66 | AD-38 | Comparative | 4.6 | 24.5 | 461 | 5.6 |
| Example 5 | | | Example | | | | |
| | | | Compound CX5 | | | | |
| Comparative | HT35/ETH66 | AD-38 | Comparative | 4.5 | 24.8 | 461 | 5.9 |
| Example 6 | | | Example | | | | |
| | | | Compound CX6 | | | | |

Referring to Table 2, it can be seen that the light-emitting elements according to Comparative Examples 1 to 6 and Examples 1 to 5 may emit light in a wavelength region in a range of about 430 nm to about 490 nm. The light-emitting elements according to Comparative Example 5, Comparative Example 6, and Examples 1 to 5 have a lower driving voltage than the light-emitting elements according to Comparative Examples 1 to 4. The light-emitting elements according to Comparative Example 6 and Examples 1 to 5 have higher emission efficiency than the light-emitting elements according to Comparative Examples 1 to 5. The light-emitting elements according to Examples 1 to 5 have a longer lifespan than the light-emitting elements according to Comparative Examples 1 to 6. The light-emitting elements according to Examples 1 to 5 include Compounds 12, 15, 109, 31, and 90, respectively, and Compounds 12, 15, 109, 31, and 90 are fused polycyclic compounds according to embodiments. Therefore, the light-emitting element according to an embodiment containing the fused polycyclic compound according to an embodiment has long lifespan characteristics.

Compounds 12, 15, 109, 31, and 90 include a pentacyclic fused ring as a core structure and include a m-terphenyl moiety and a biphenyl moiety, each bonded to the core structure. The m-terphenyl moiety and the biphenyl moiety are bulky substituents. The fused polycyclic compound according to an embodiment, including the m-terphenyl moiety and the biphenyl moiety, may emit light with a shortened emission wavelength, and Dexter energy transfer thereof may be inhibited. Therefore, the light-emitting element including the fused polycyclic compound according to an embodiment may exhibit long lifespan characteristics.

The light-emitting element according to Comparative Example 1 contains Comparative Example Compound CX1, and Comparative Example Compound CX1 includes no m-terphenyl moiety and no biphenyl moiety. Therefore, the light-emitting element according to Comparative Example 1 has a relatively high driving voltage, low efficiency, and short lifespan.

The light-emitting element according to Comparative Example 2 contains Comparative Example Compound CX2, and Comparative Example Compound CX2 includes no biphenyl moiety. Therefore, the light-emitting element according to Comparative Example 2 has a relatively high driving voltage, low efficiency, and short lifespan.

The light-emitting element according to Comparative Example 3 contains Comparative Example Compound CX3, and Comparative Example Compound CX3 includes no m-terphenyl moiety. Comparative Example Compound CX3 has insufficient substituents protecting the pentacyclic fused ring, which is the core structure, has a shallow HOMO energy level, and emits light with a short emission wavelength. Therefore, the light-emitting element according to Comparative Example 3 has a relatively high driving voltage, low efficiency, and short lifespan.

The light-emitting element according to Comparative Example 4 contains Comparative Example Compound CX4, and Comparative Example Compound CX4 includes no m-terphenyl moiety. Therefore, the light-emitting element according to Comparative Example 4 has a relatively high driving voltage, low efficiency, and short lifespan.

The light-emitting element according to Comparative Example 5 contains Comparative Example Compound CX5, and Comparative Example Compound CX5 includes no m-terphenyl moiety. Therefore, the light-emitting element according to Comparative Example 5 has relatively low efficiency and short lifespan.

The light-emitting element according to Comparative Example 6 contains Comparative Example Compound CX6, and Comparative Example Compound CX6 includes no m-terphenyl moiety. Therefore, the light-emitting element according to Comparative Example 6 has a relatively short lifespan.

The display device according to an embodiment may include the light-emitting element according to an embodiment. In the light-emitting element according to an embodiment, the emission layer may contain the fused polycyclic compound according to an embodiment. The fused polycyclic compound according to an embodiment may include a pentacyclic fused ring containing three heteroatoms as ring-forming atoms, and a m-terphenyl moiety and a biphenyl moiety may be bonded to the pentacyclic fused ring. Any one of the three heteroatoms may be a boron atom, another one is a nitrogen atom, and the third one may be a sulfur atom or a nitrogen atom. Therefore, the fused polycyclic compound according to an embodiment may be relatively bulky, may emit light with a shortened emission wavelength, and Dexter energy transfer thereof may be inhibited. The light-emitting element including the fused polycyclic compound according to an embodiment may exhibit long lifespan characteristics.

The light-emitting element according to an embodiment and the display device including the same includes the fused polycyclic compound according to an embodiment, and thus may exhibit long lifespan characteristics.

The fused polycyclic compound according to an embodiment may contribute to improvements in the long lifespan of the light-emitting element.

Embodiments have been disclosed herein, and although terms are employed, they are used and are to be interpreted in a generic and descriptive sense only and not for purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A light-emitting element comprising:
a first electrode;
a second electrode disposed on the first electrode; and
an emission layer disposed between the first electrode and the second electrode, wherein
the emission layer comprises a first compound represented by Formula 1: 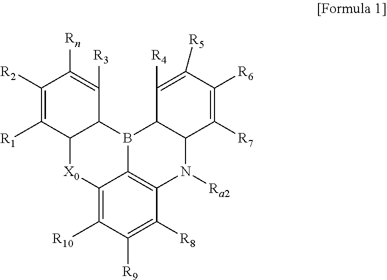
wherein in Formula 1,
Rₙ is a group represented by Formula 2,
X₀ is S or N(Rₐ₁),
Rₐ₁ and Rₐ₂ are each independently a group represented by Formula 3, and
R₁ to R₁₀ are each independently a hydrogen atom, a deuterium atom, a cyano group, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms; 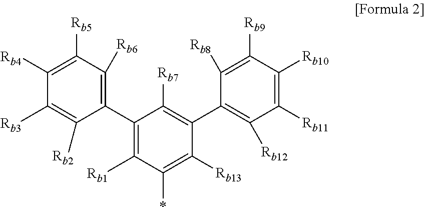
wherein in Formula 2,
R_{b1} to R_{b13} are each independently a hydrogen atom, a deuterium atom, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring; 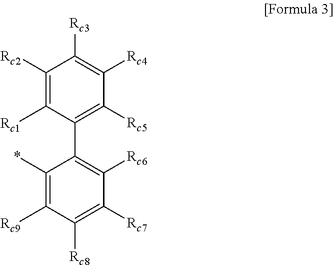
wherein in Formula 3,
R_{c1} to R_{c9} are each independently a hydrogen atom, a deuterium atom, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

2. The light-emitting element of claim 1, wherein the emission layer further comprises at least one of a second compound represented by Formula HT-1, a third compound represented by Formula ET-1, and a fourth compound represented by Formula D-1: 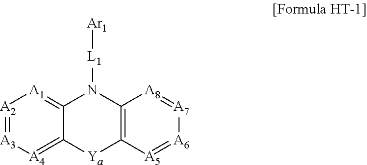
wherein in Formula HT-1,
A₁ to A₈ are each independently N or C(R₅₁),
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, C(R₅₂)(R₅₃), or Si(R₅₄)(R₅₅),
Ar₁ is a substituted or unsubstituted aryl group having 6 to 30 ring-forming carbon atoms or a substituted or unsubstituted heteroaryl group having 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring; 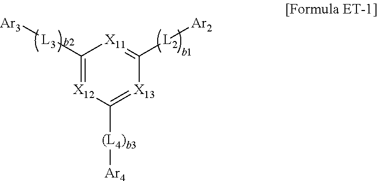
wherein in Formula ET-1,
at least one of X₁₁ to X₁₃ is each N,
the remainder of X₁₁ to X₁₃ is each independently C(R₅₆),
R₅₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer from 0 to 10,
Ar₂ to Ar₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms; 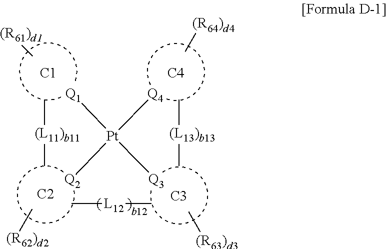
wherein in Formula D-1,
Q₁ to Q₄ are each independently C or N,
C1 to C4 are each independently a substituted or unsubstituted hydrocarbon ring having 5 to 30 ring-forming carbon atoms, a substituted or unsubstituted aryl group having 6 to 30 ring-forming carbon atoms, or a substituted or unsubstituted hetero ring having 2 to 30 ring-forming carbon atoms,
L₁₁ to L₁₃ are each independently a direct linkage, 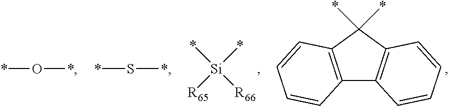
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 are each independently an integer from 0 to 4.

3. The light-emitting element of claim 1, wherein the first compound is represented by Formula 1-1 or Formula 1-2: 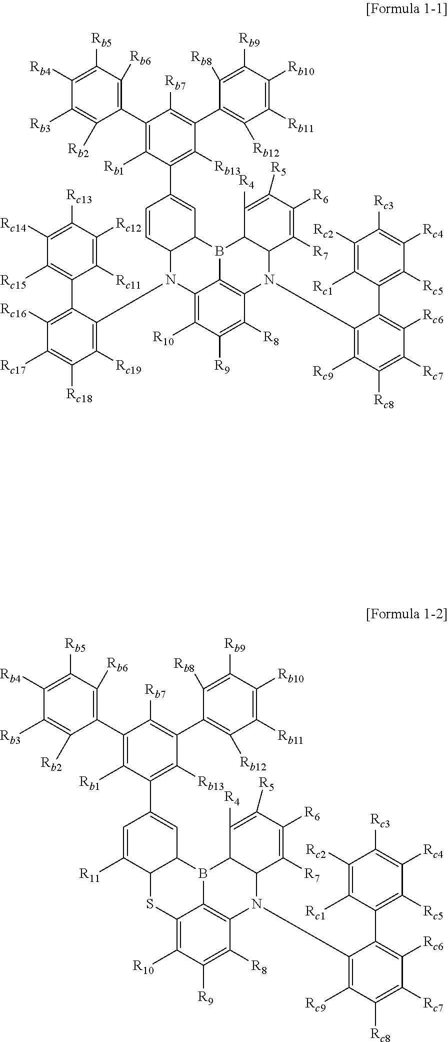
wherein in Formula 1-1,
R_{c11} to R_{c19} are each independently a hydrogen atom, a deuterium atom, a substituted or unsubstituted oxy group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms,
wherein in Formula 1-2,
R₁₁ is a hydrogen atom, a deuterium atom, a substituted or unsubstituted aryl group having 6 to 30 ring-forming carbon atoms, or a substituted or unsubstituted heteroaryl group having 2 to 30 ring-forming carbon atoms, and
wherein in Formula 1-1 and Formula 1-2,
R₄ to R₁₀, R_{b1} to R_{b13}, and R_{c1} to R_{c9} are the same as defined in Formula 1, Formula 2, and Formula 3.

4. The light-emitting element of claim 3, wherein in Formula 1-2, R₁₁ is a substituted or unsubstituted phenyl group, a substituted or unsubstituted dibenzofuran group, or a substituted or unsubstituted carbazole group.

5. The light-emitting element of claim 3, wherein in Formula 1-2, R₁₁ is a group represented by one of Formula R11-1 to Formula R11-13:

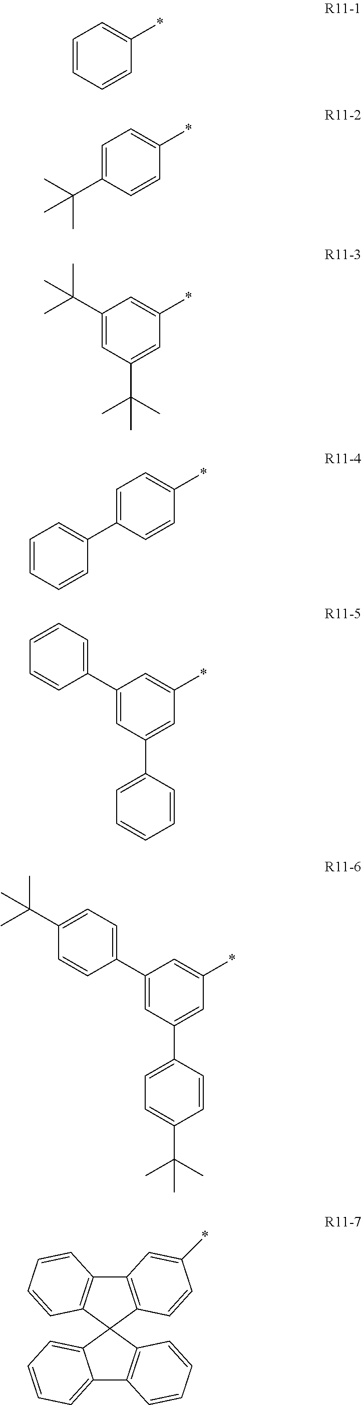

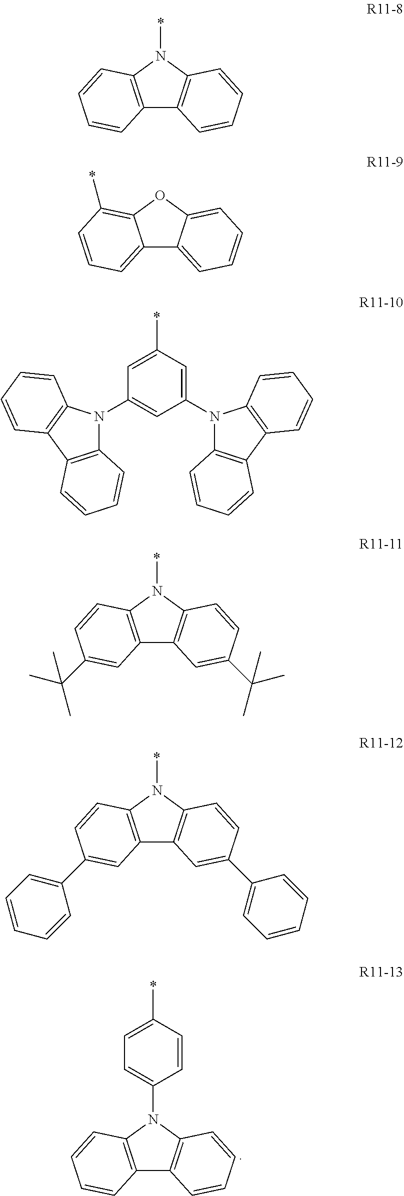 [SMILES: *n1c2ccccc2c2ccccc21 ; *c1cccc2c1oc1ccccc12 ; *c1cc(-n2c3ccccc3c3ccccc32)cc(-n2c3ccccc3c3ccccc32)c1 ; *n1c2ccc(C(C)(C)C)cc2c2cc(C(C)(C)C)ccc21 ; *n1c2ccc(-c3ccccc3)cc2c2cc(-c3ccccc3)ccc21 ; *c1ccc(-n2c3ccccc3c3ccccc32)cc1]

6. The light-emitting element of claim 1, wherein the first compound is represented by Formula 1-A or Formula 1-B: 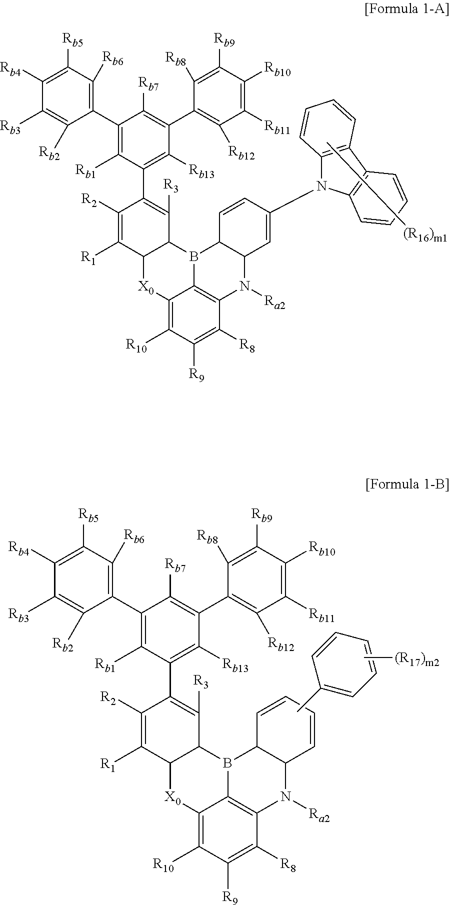
wherein in Formula 1-A,
m1 is an integer from 0 to 8, and
R₁₆ is a hydrogen atom, a deuterium atom, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring,
wherein in Formula 1-B,
m2 is an integer from 0 to 5, and
R₁₇ is a hydrogen atom, a deuterium atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and
wherein in Formula 1-A and Formula 1-B,
R₁ to R₃, R₈ to R₁₀, R_{b1} to R_{b13}, X₀, and Rₐ₂ are the same as defined in Formula 1 and Formula 2.

7. The light-emitting element of claim 1, wherein the group represented by Formula 2 is a group represented by one of Formula 2-1 to Formula 2-6:

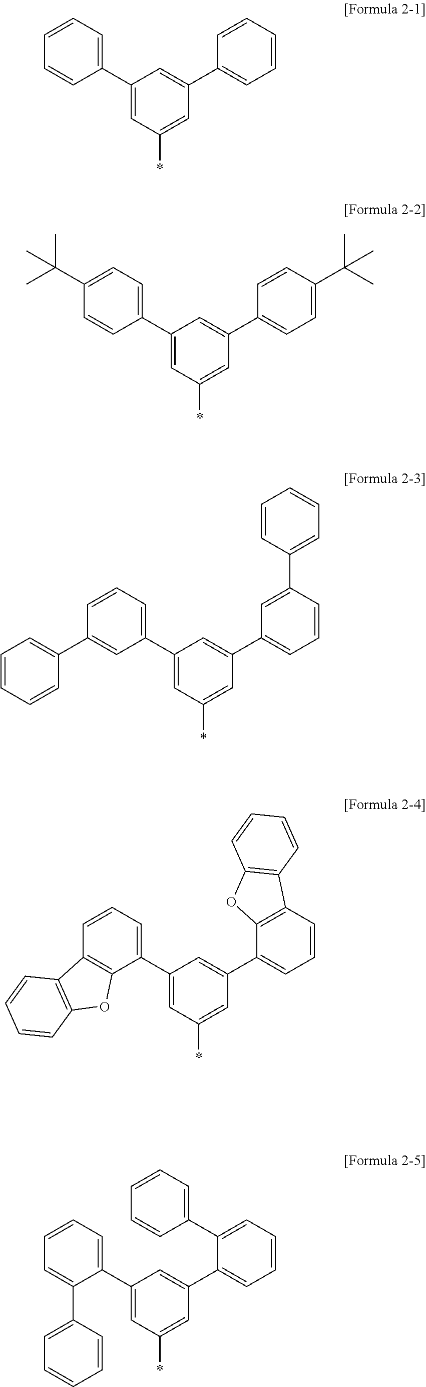 [SMILES: *c1cc(-c2ccccc2)cc(-c2ccccc2)c1 ; *c1cc(-c2ccc(C(C)(C)C)cc2)cc(-c2ccc(C(C)(C)C)cc2)c1 ; *c1cc(-c2cccc(-c3ccccc3)c2)cc(-c2cccc(-c3ccccc3)c2)c1 ; *c1cc(-c2cccc3c2oc2ccccc23)cc(-c2cccc3c2oc2ccccc23)c1 ; *c1cc(-c2ccccc2-c2ccccc2)cc(-c2ccccc2-c2ccccc2)c1]

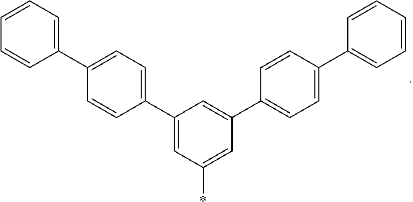 [SMILES: *c1cc(-c2ccc(-c3ccccc3)cc2)cc(-c2ccc(-c3ccccc3)cc2)c1]

8. The light-emitting element of claim 1, wherein the group represented by Formula 3 is a group represented by one of Formula 3-1 to Formula 3-18:

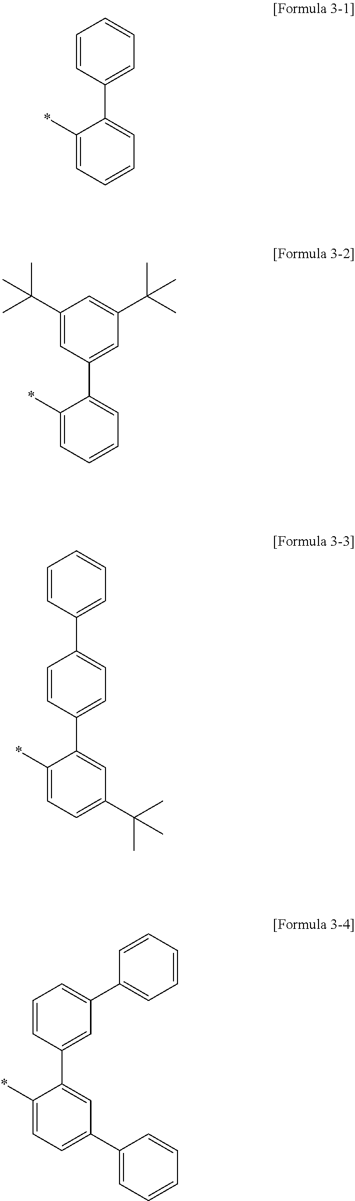 [SMILES: *c1ccccc1-c1ccccc1 ; *c1ccccc1-c1cc(C(C)(C)C)cc(C(C)(C)C)c1 ; *c1ccc(C(C)(C)C)cc1-c1ccc(-c2ccccc2)cc1 ; *c1ccc(-c2ccccc2)cc1-c1cccc(-c2ccccc2)c1]

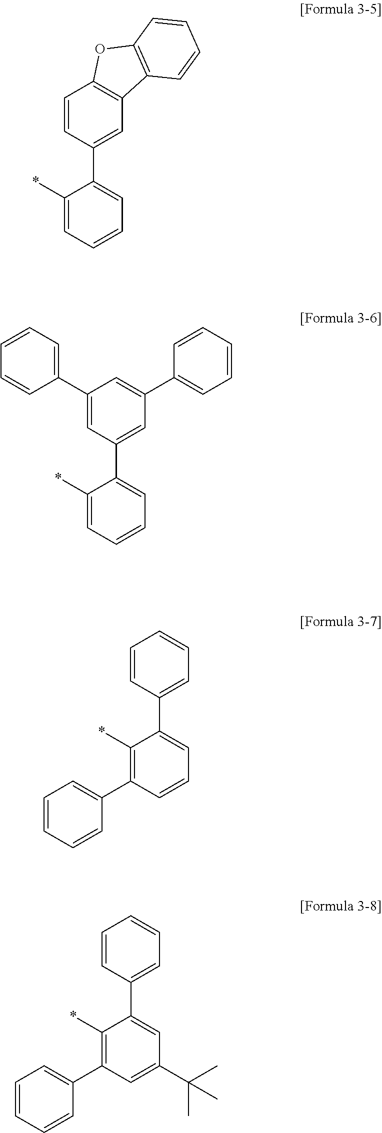 [SMILES: *c1ccccc1-c1ccc2oc3ccccc3c2c1 ; *c1ccccc1-c1cc(-c2ccccc2)cc(-c2ccccc2)c1 ; *c1c(-c2ccccc2)cccc1-c1ccccc1 ; *c1c(-c2ccccc2)cc(C(C)(C)C)cc1-c1ccccc1]

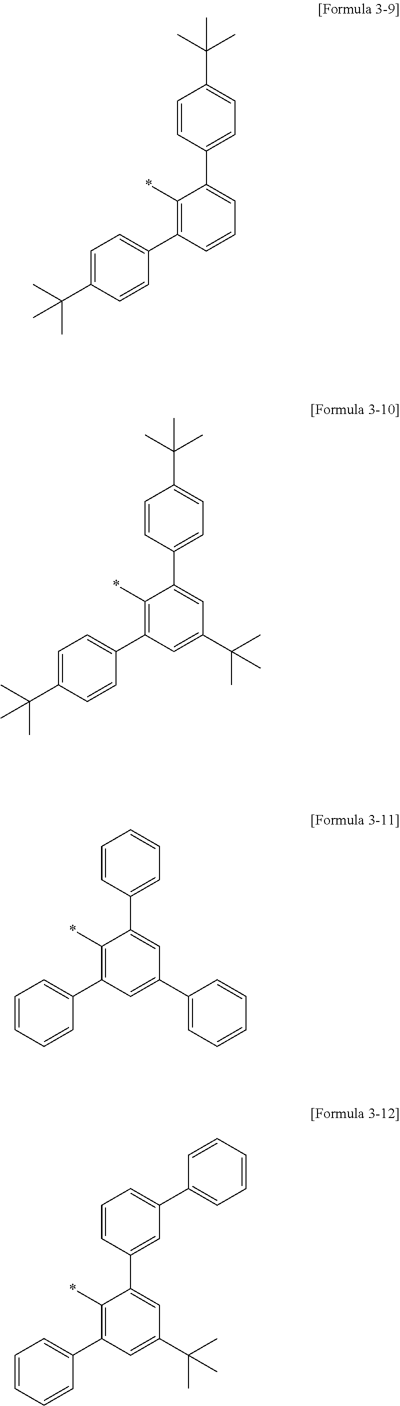

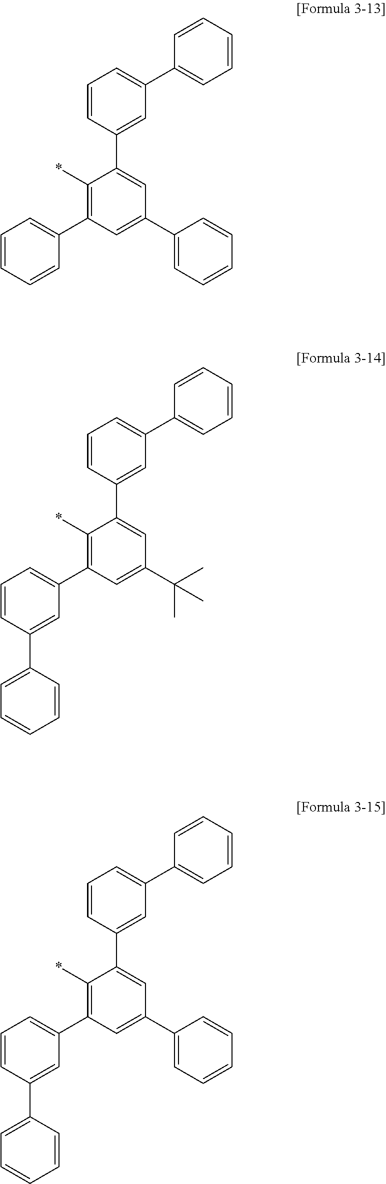 [SMILES: *c1c(-c2ccccc2)cc(-c2ccccc2)cc1-c1cccc(-c2ccccc2)c1 ; *c1c(-c2cccc(-c3ccccc3)c2)cc(C(C)(C)C)cc1-c1cccc(-c2ccccc2)c1 ; *c1c(-c2cccc(-c3ccccc3)c2)cc(-c2ccccc2)cc1-c1cccc(-c2ccccc2)c1]

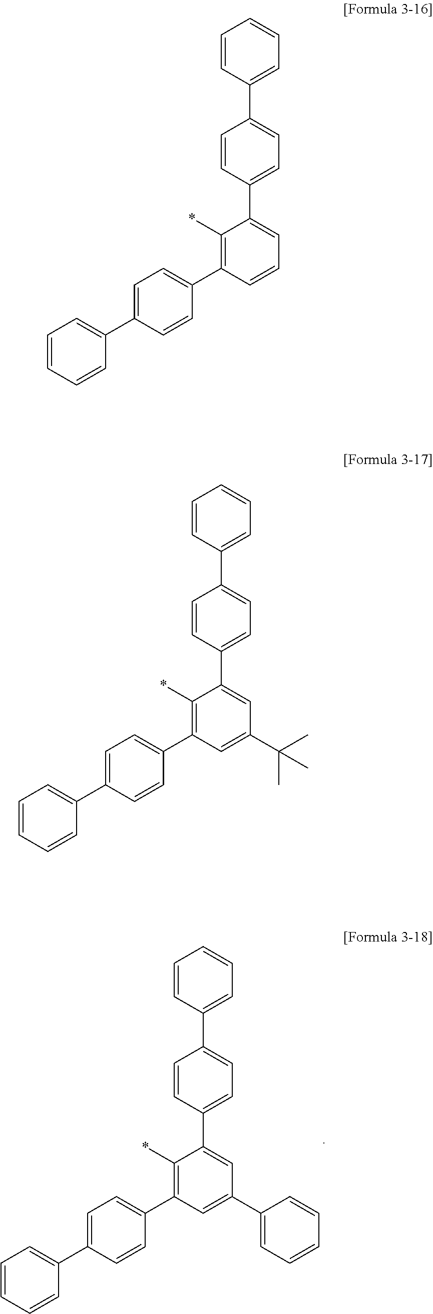 [SMILES: *c1c(-c2ccc(-c3ccccc3)cc2)cccc1-c1ccc(-c2ccccc2)cc1 ; *c1c(-c2ccc(-c3ccccc3)cc2)cc(C(C)(C)C)cc1-c1ccc(-c2ccccc2)cc1 ; *c1c(-c2ccc(-c3ccccc3)cc2)cc(-c2ccccc2)cc1-c1ccc(-c2ccccc2)cc1]

9. The light-emitting element of claim 1, wherein in Formula 1, R₉ is a group represented by one of Formula R9-1 to Formula R9-18: 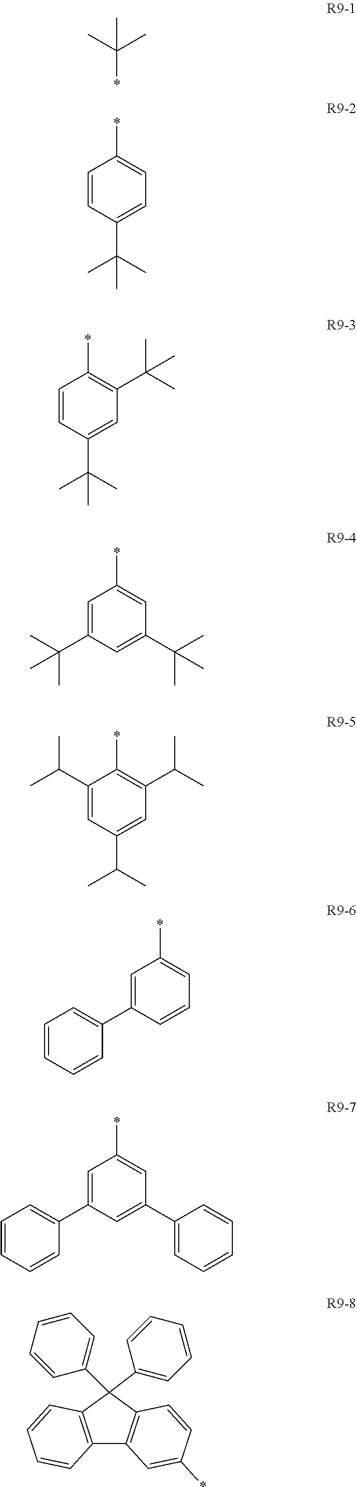 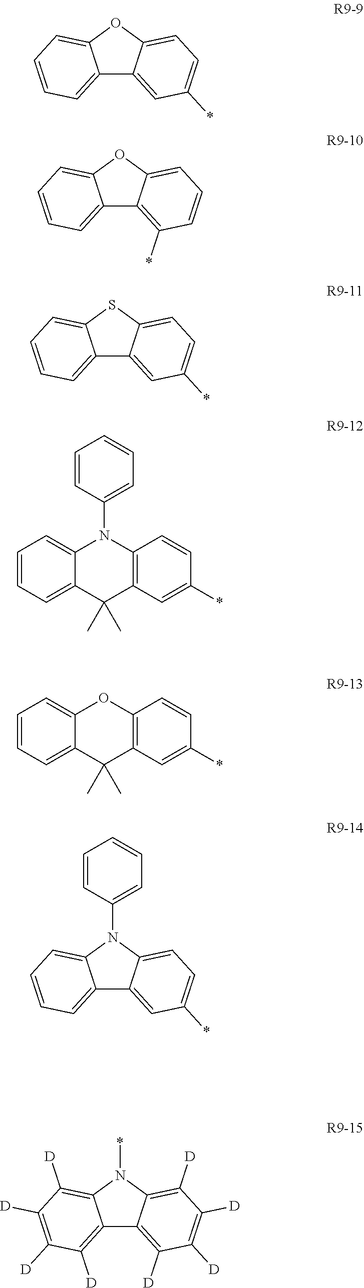 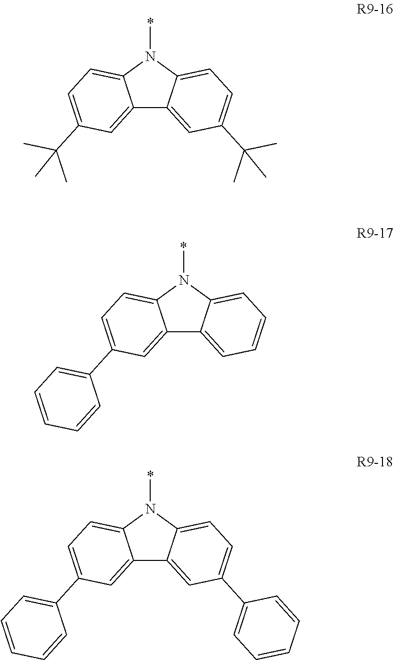 [SMILES: *n1c2ccc(C(C)(C)C)cc2c2cc(C(C)(C)C)ccc21 ; *n1c2ccccc2c2cc(-c3ccccc3)ccc21 ; *n1c2ccc(-c3ccccc3)cc2c2cc(-c3ccccc3)ccc21]
wherein in Formula R9-15,
D represents a deuterium atom.

10. The light-emitting element of claim 1, wherein the first compound comprises at least one compound selected from Compound Group 1: 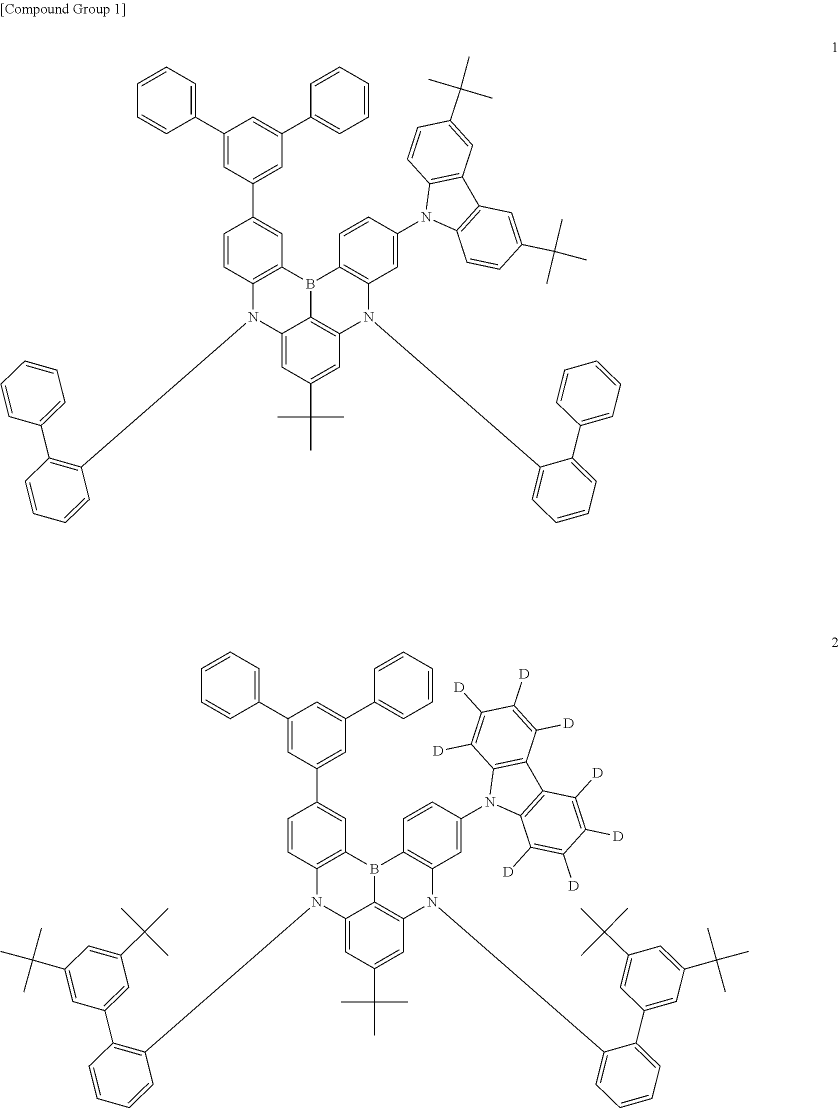 [SMILES: CC(C)(C)c1cc2c3c(c1)N(c1ccccc1-c1ccccc1)c1cc(-n4c5ccc(C(C)(C)C)cc5c5cc(C(C)(C)C)ccc54)ccc1B3c1cc(-c3cc(-c4ccccc4)cc(-c4ccccc4)c3)ccc1N2c1ccccc1-c1ccccc1 ; [2H]c1c([2H])c([2H])c2c(c1[2H])c1c([2H])c([2H])c([2H])c([2H])c1n2-c1ccc2c(c1)N(c1ccccc1-c1cc(C(C)(C)C)cc(C(C)(C)C)c1)c1cc(C(C)(C)C)cc3c1B2c1cc(-c2cc(-c4ccccc4)cc(-c4ccccc4)c2)ccc1N3c1ccccc1-c1cc(C(C)(C)C)cc(C(C)(C)C)c1] 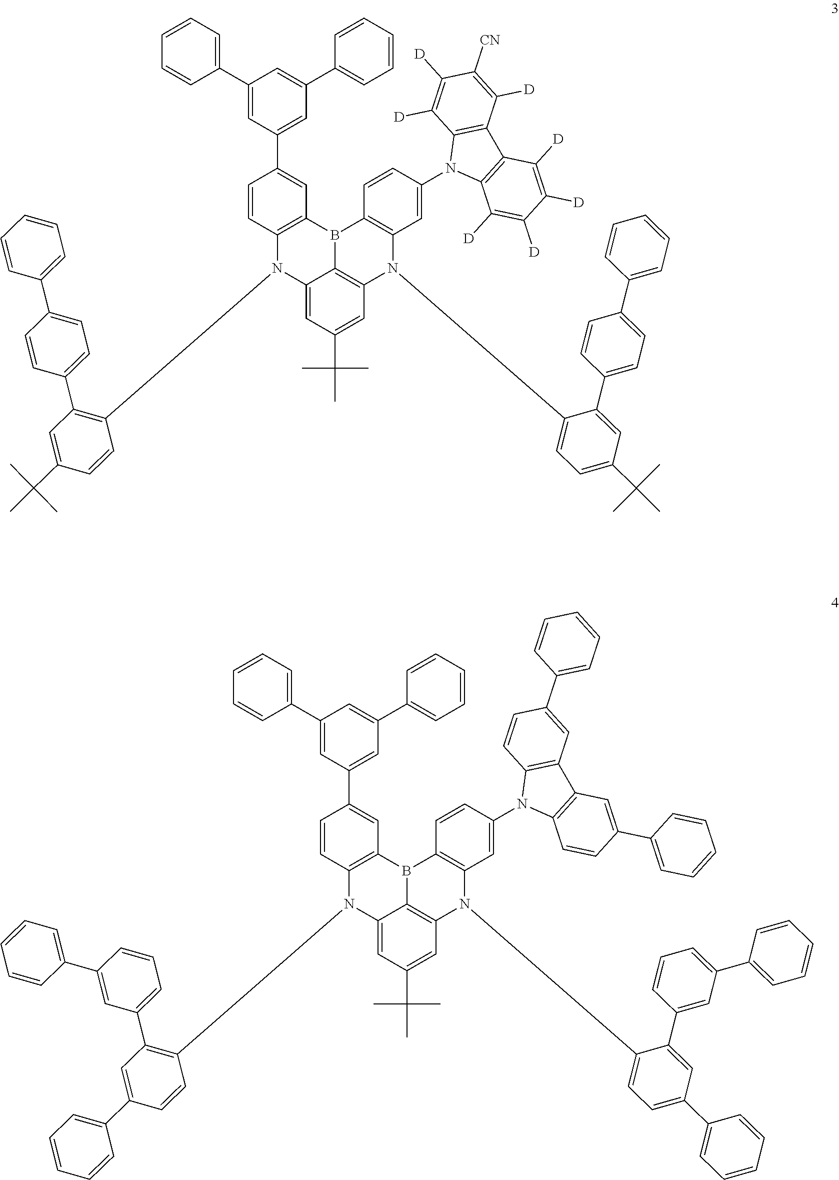 [SMILES: [2H]c1c([2H])c([2H])c2c(c1[2H])c1c([2H])c(C#N)c([2H])c([2H])c1n2-c1ccc2c(c1)N(c1ccc(C(C)(C)C)cc1-c1ccc(-c3ccccc3)cc1)c1cc(C(C)(C)C)cc3c1B2c1cc(-c2cc(-c4ccccc4)cc(-c4ccccc4)c2)ccc1N3c1ccc(C(C)(C)C)cc1-c1ccc(-c2ccccc2)cc1 ; CC(C)(C)c1cc2c3c(c1)N(c1ccc(-c4ccccc4)cc1-c1cccc(-c4ccccc4)c1)c1cc(-n4c5ccc(-c6ccccc6)cc5c5cc(-c6ccccc6)ccc54)ccc1B3c1cc(-c3cc(-c4ccccc4)cc(-c4ccccc4)c3)ccc1N2c1ccc(-c2ccccc2)cc1-c1cccc(-c2ccccc2)c1] 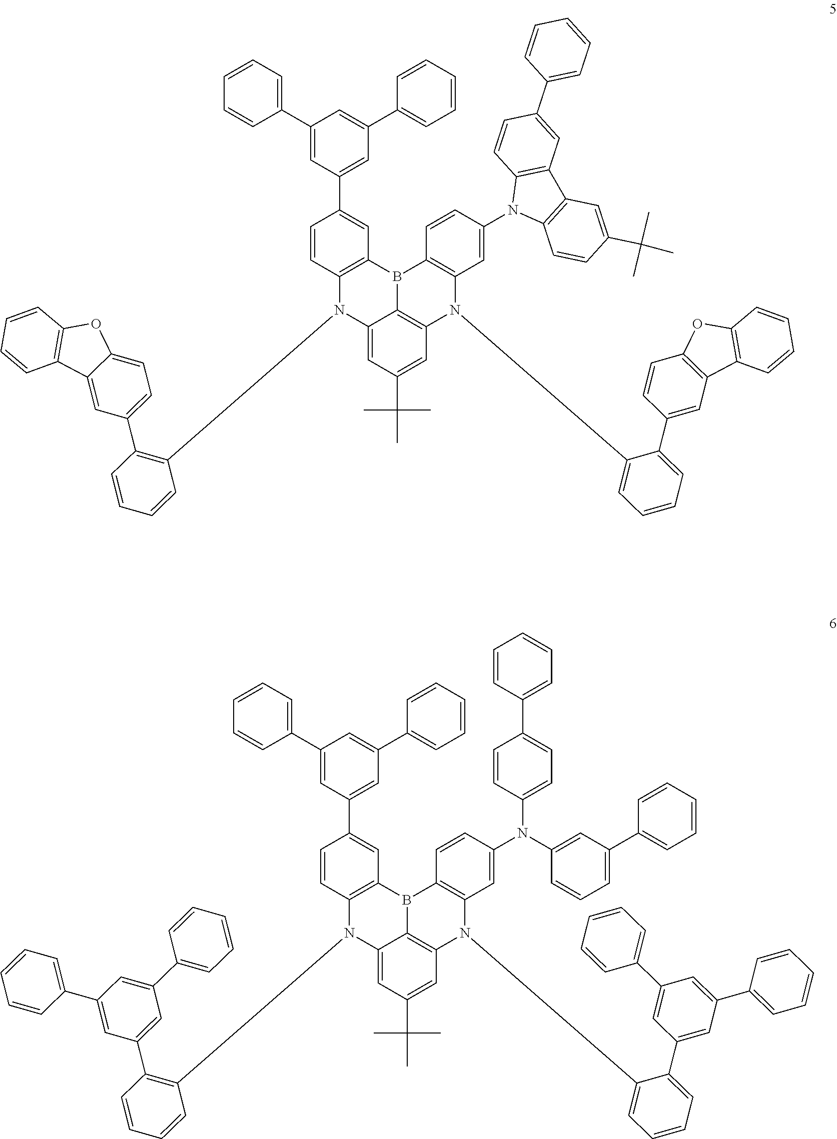 [SMILES: CC(C)(C)c1cc2c3c(c1)N(c1ccccc1-c1ccc4oc5ccccc5c4c1)c1cc(-n4c5ccc(-c6ccccc6)cc5c5cc(C(C)(C)C)ccc54)ccc1B3c1cc(-c3cc(-c4ccccc4)cc(-c4ccccc4)c3)ccc1N2c1ccccc1-c1ccc2oc3ccccc3c2c1 ; CC(C)(C)c1cc2c3c(c1)N(c1ccccc1-c1cc(-c4ccccc4)cc(-c4ccccc4)c1)c1cc(N(c4ccc(-c5ccccc5)cc4)c4cccc(-c5ccccc5)c4)ccc1B3c1cc(-c3cc(-c4ccccc4)cc(-c4ccccc4)c3)ccc1N2c1ccccc1-c1cc(-c2ccccc2)cc(-c2ccccc2)c1] 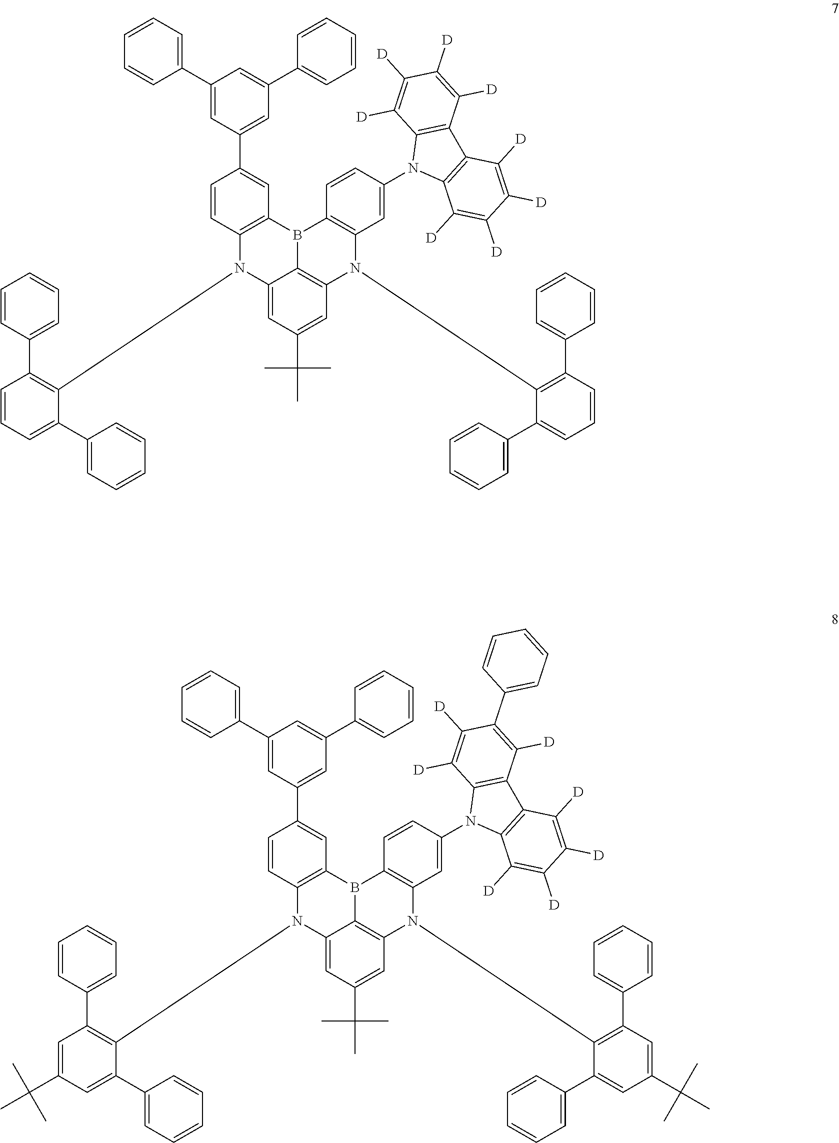 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1cc(-c2cc(-c4ccccc4)cc(-c4ccccc4)c2)ccc1N3c1c(-c2ccccc2)cccc1-c1ccccc1 ; [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cc(-c4ccccc4)cc(-c4ccccc4)c2)ccc1N3c1c(-c2ccccc2)cc(C(C)(C)C)cc1-c1ccccc1] 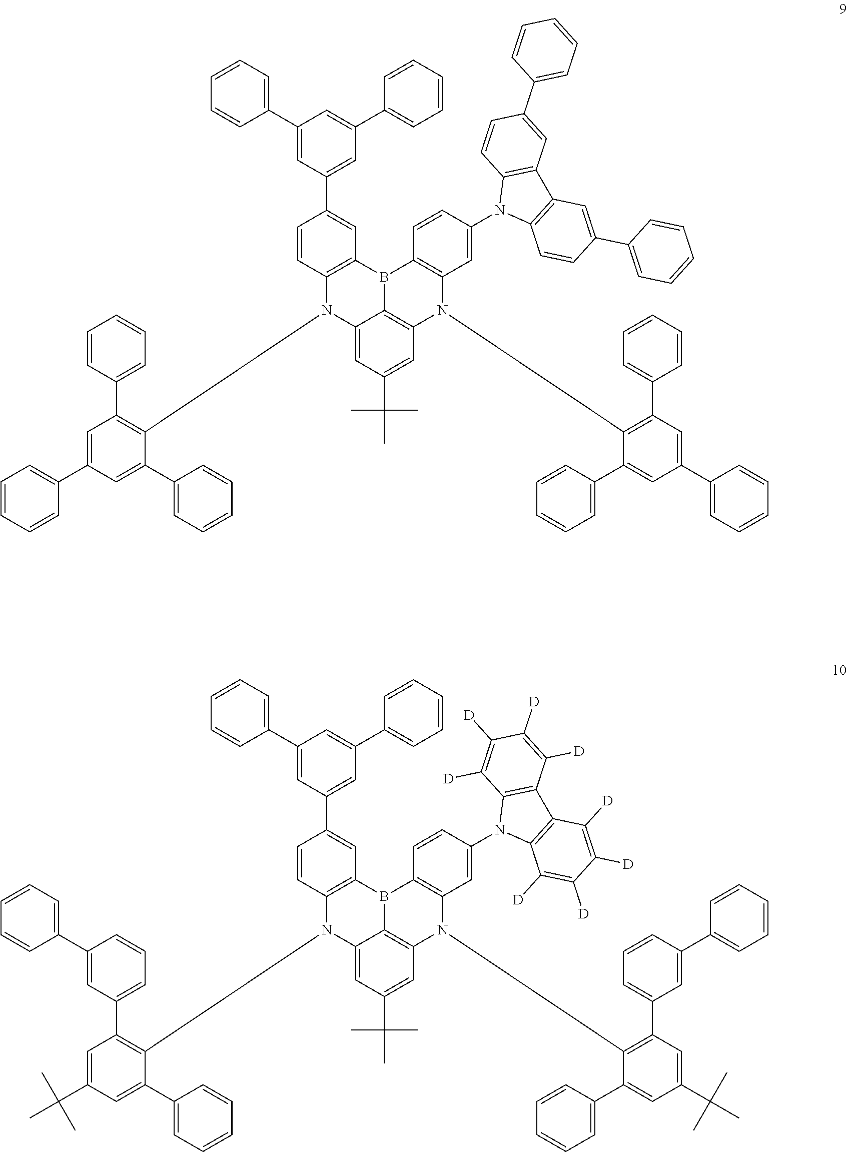 [SMILES: CC(C)(C)c1cc2c3c(c1)N(c1c(-c4ccccc4)cc(-c4ccccc4)cc1-c1ccccc1)c1cc(-n4c5ccc(-c6ccccc6)cc5c5cc(-c6ccccc6)ccc54)ccc1B3c1cc(-c3cc(-c4ccccc4)cc(-c4ccccc4)c3)ccc1N2c1c(-c2ccccc2)cc(-c2ccccc2)cc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc(-c3ccccc3)c1)c1cc(C(C)(C)C)cc3c1B2c1cc(-c2cc(-c4ccccc4)cc(-c4ccccc4)c2)ccc1N3c1c(-c2ccccc2)cc(C(C)(C)C)cc1-c1cccc(-c2ccccc2)c1] 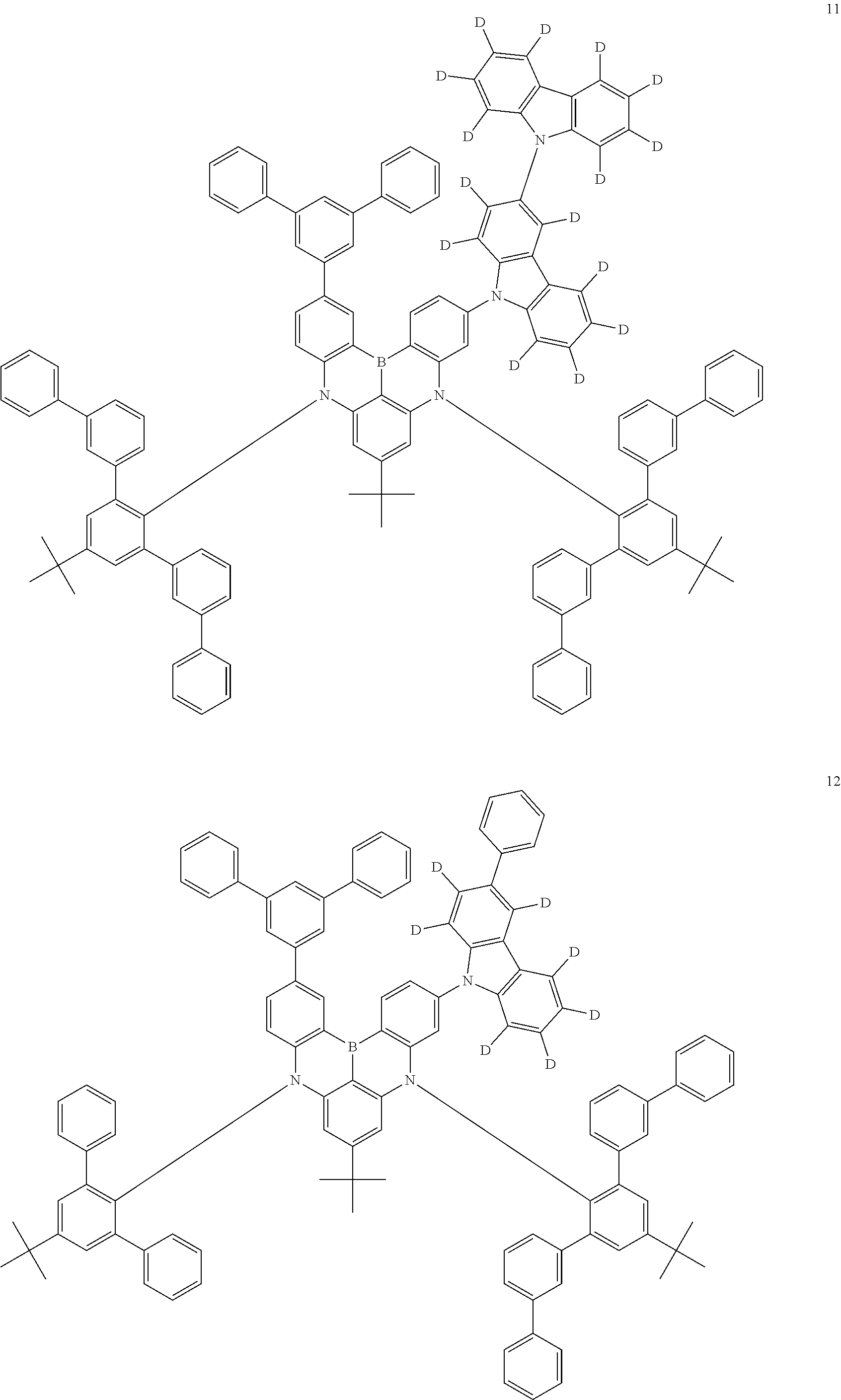 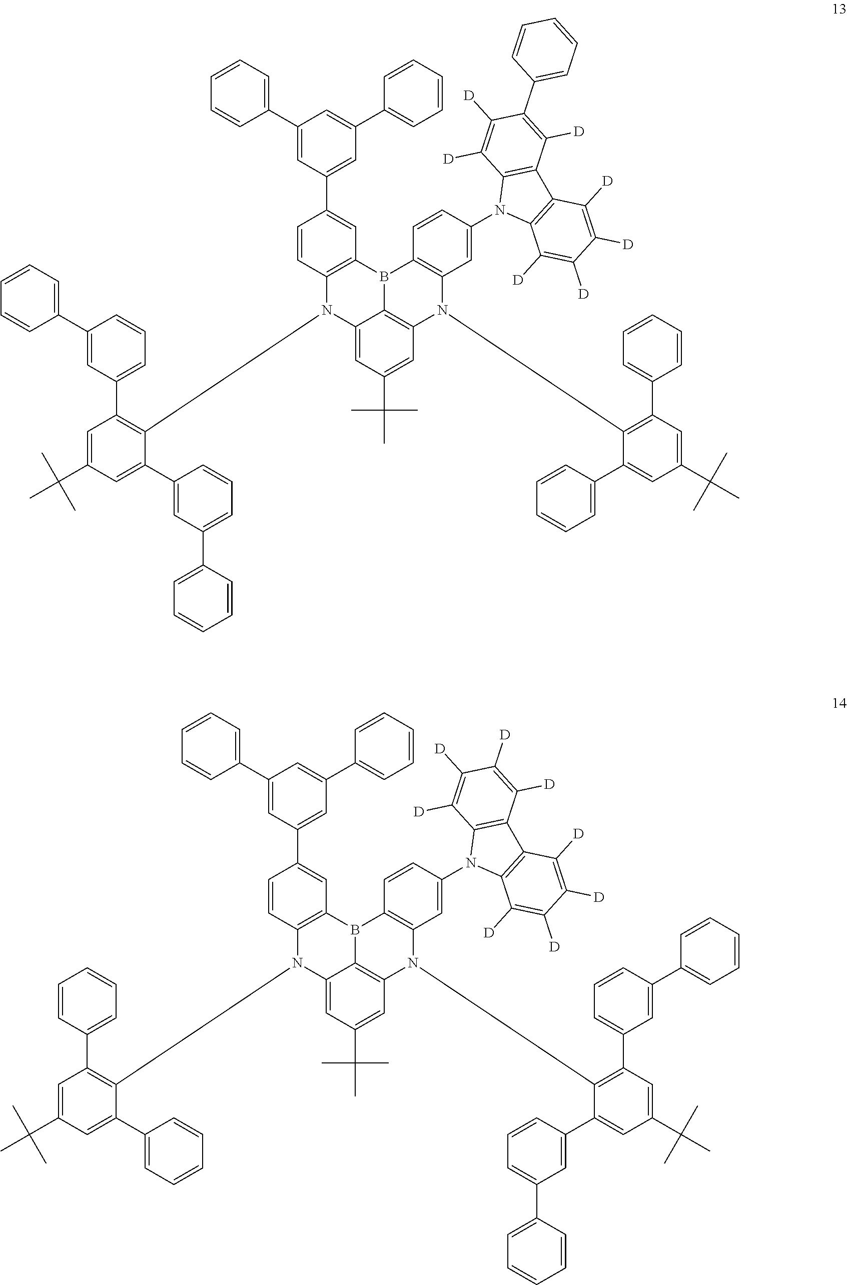 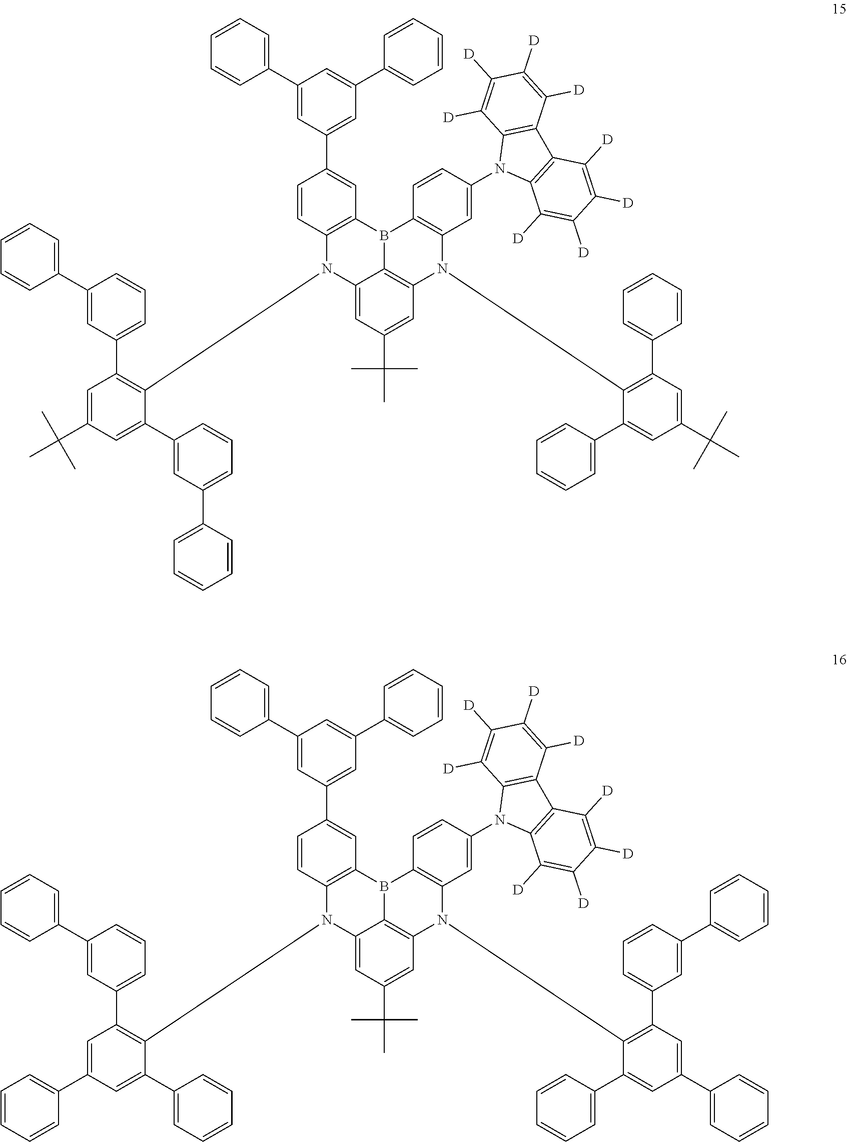 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cc(-c4ccccc4)cc(-c4ccccc4)c2)ccc1N3c1c(-c2cccc(-c3ccccc3)c2)cc(C(C)(C)C)cc1-c1cccc(-c2ccccc2)c1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc(-c3ccccc3)c1)c1cc(C(C)(C)C)cc3c1B2c1cc(-c2cc(-c4ccccc4)cc(-c4ccccc4)c2)ccc1N3c1c(-c2ccccc2)cc(-c2ccccc2)cc1-c1cccc(-c2ccccc2)c1] 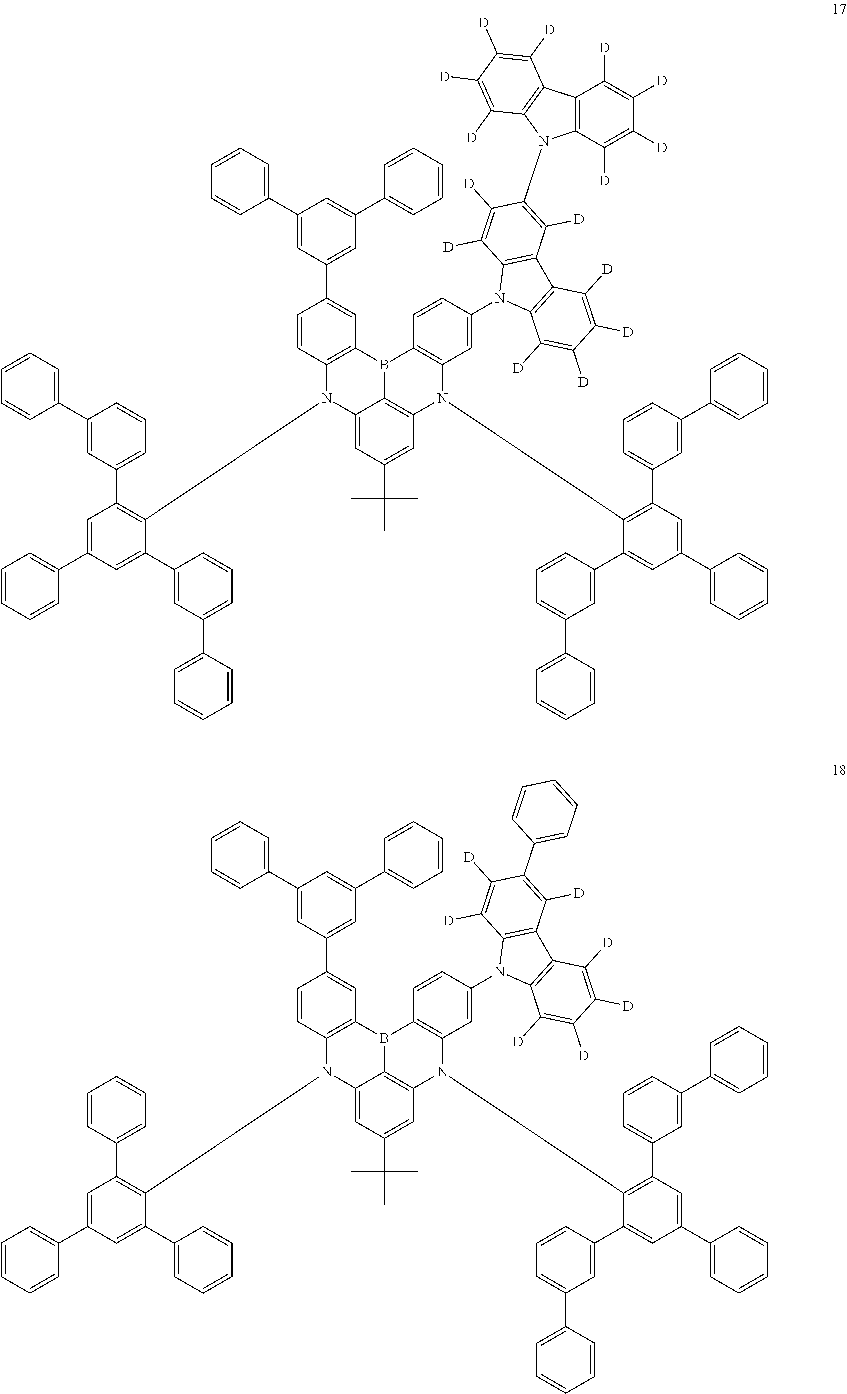 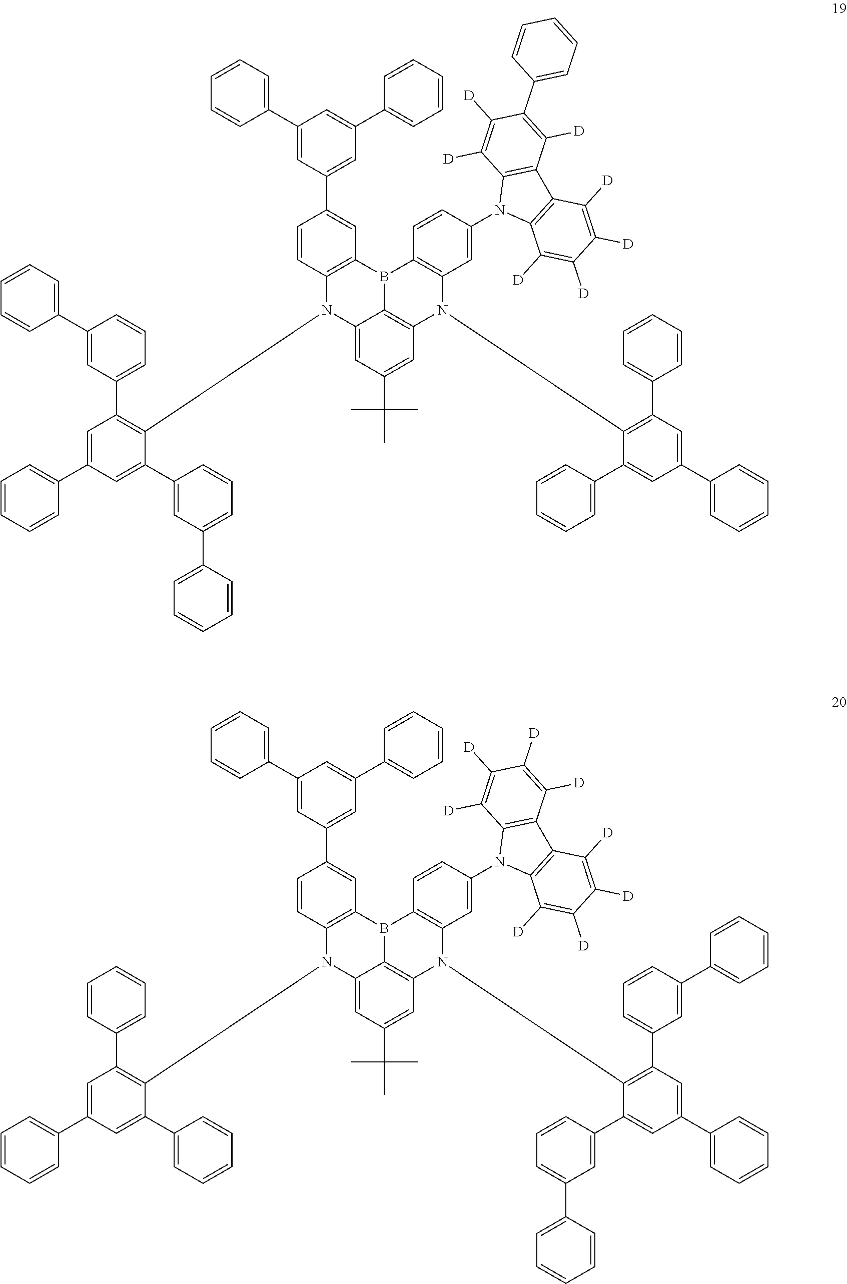 [SMILES: [2H]c1c([2H])c([2H])c2c(c1[2H])c1c([2H])c(-c3ccccc3)c([2H])c([2H])c1n2-c1ccc2c(c1)N(c1c(-c3ccccc3)cc(-c3ccccc3)cc1-c1ccccc1)c1cc(C(C)(C)C)cc3c1B2c1cc(-c2cc(-c4ccccc4)cc(-c4ccccc4)c2)ccc1N3c1c(-c2cccc(-c3ccccc3)c2)cc(-c2ccccc2)cc1-c1cccc(-c2ccccc2)c1 ; [2H]c1c([2H])c([2H])c2c(c1[2H])c1c([2H])c([2H])c([2H])c([2H])c1n2-c1ccc2c(c1)N(c1c(-c3cccc(-c4ccccc4)c3)cc(-c3ccccc3)cc1-c1cccc(-c3ccccc3)c1)c1cc(C(C)(C)C)cc3c1B2c1cc(-c2cc(-c4ccccc4)cc(-c4ccccc4)c2)ccc1N3c1c(-c2ccccc2)cc(-c2ccccc2)cc1-c1ccccc1] 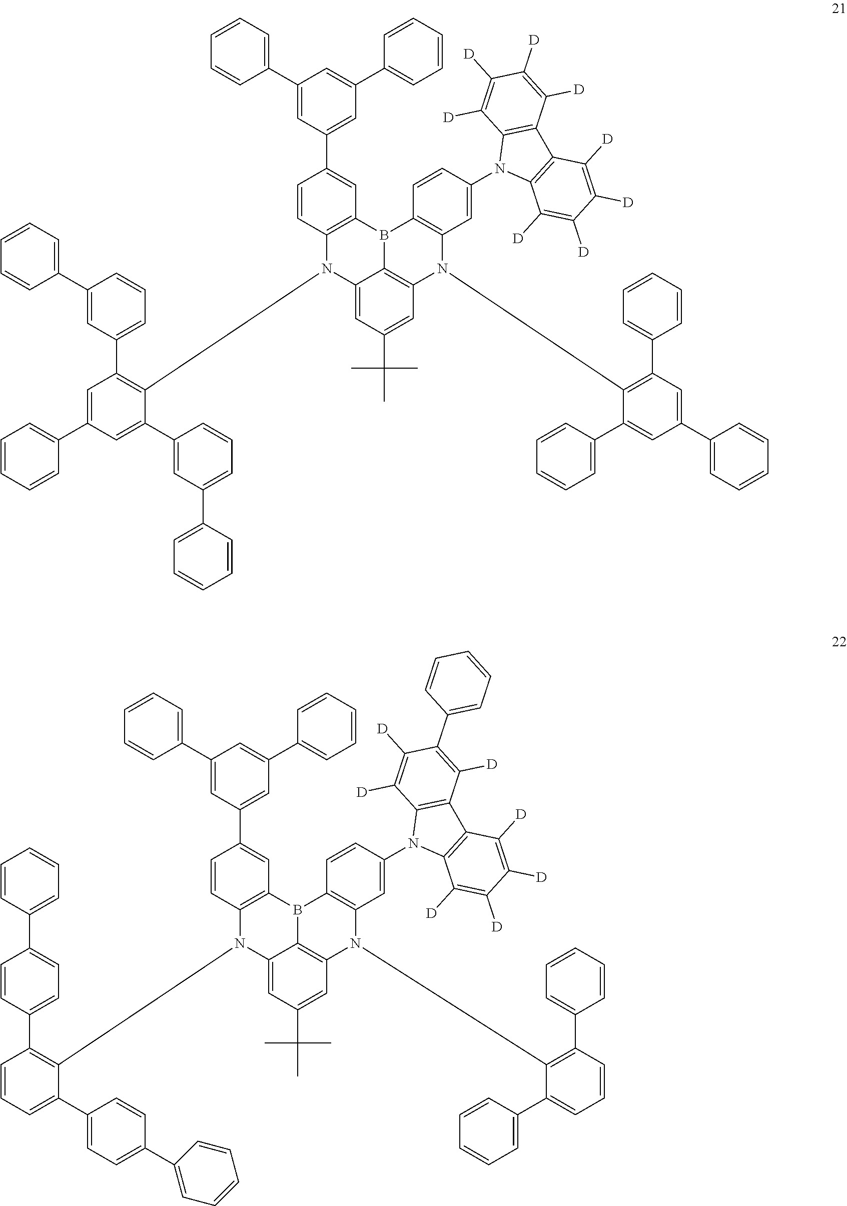 [SMILES: [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1ccccc1)c1cc(C(C)(C)C)cc3c1B2c1cc(-c2cc(-c4ccccc4)cc(-c4ccccc4)c2)ccc1N3c1c(-c2cccc(-c3ccccc3)c2)cc(-c2ccccc2)cc1-c1cccc(-c2ccccc2)c1 ; [2H]c1c([2H])c([2H])c2c(c1[2H])c1c([2H])c(-c3ccccc3)c([2H])c([2H])c1n2-c1ccc2c(c1)N(c1c(-c3ccccc3)cccc1-c1ccccc1)c1cc(C(C)(C)C)cc3c1B2c1cc(-c2cc(-c4ccccc4)cc(-c4ccccc4)c2)ccc1N3c1c(-c2ccc(-c3ccccc3)cc2)cccc1-c1ccc(-c2ccccc2)cc1] 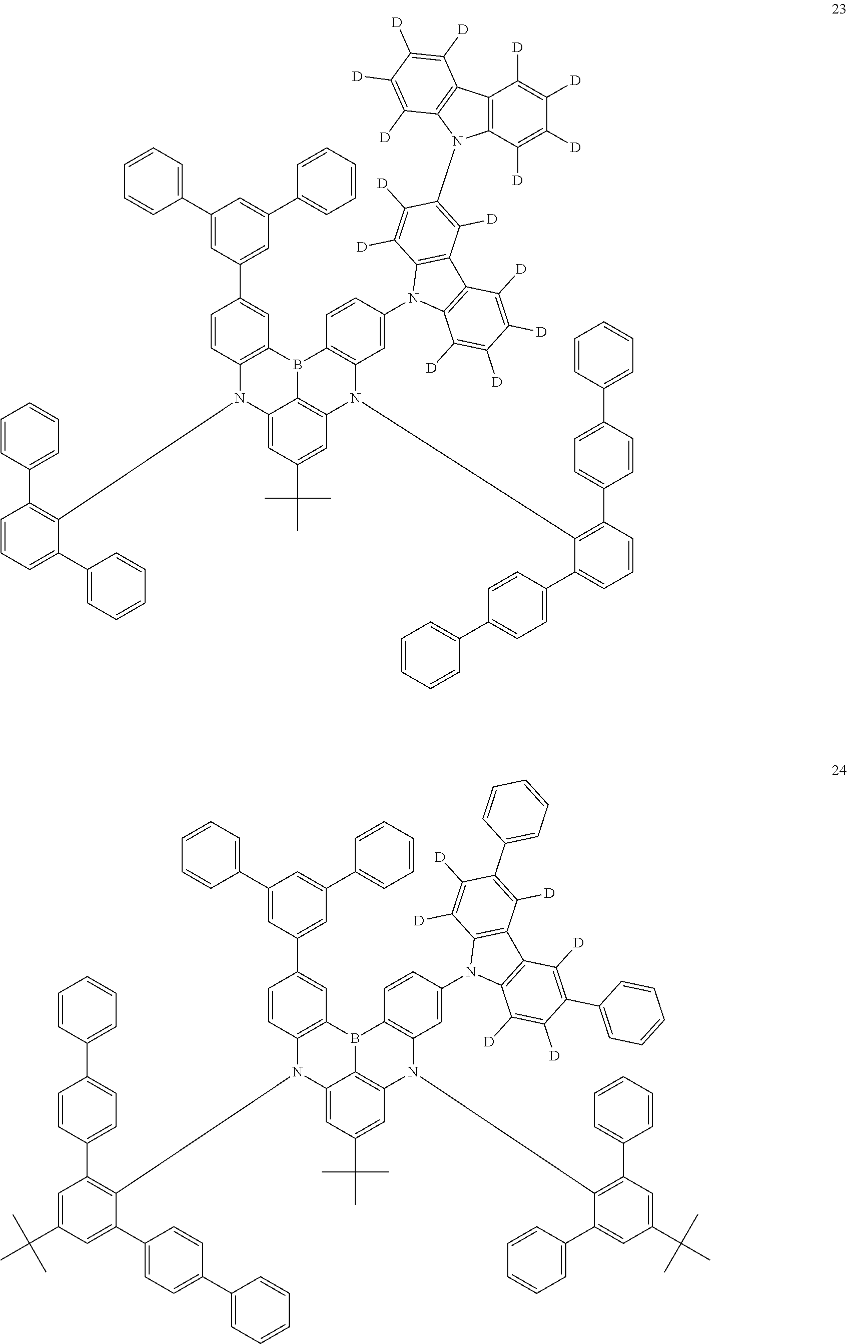 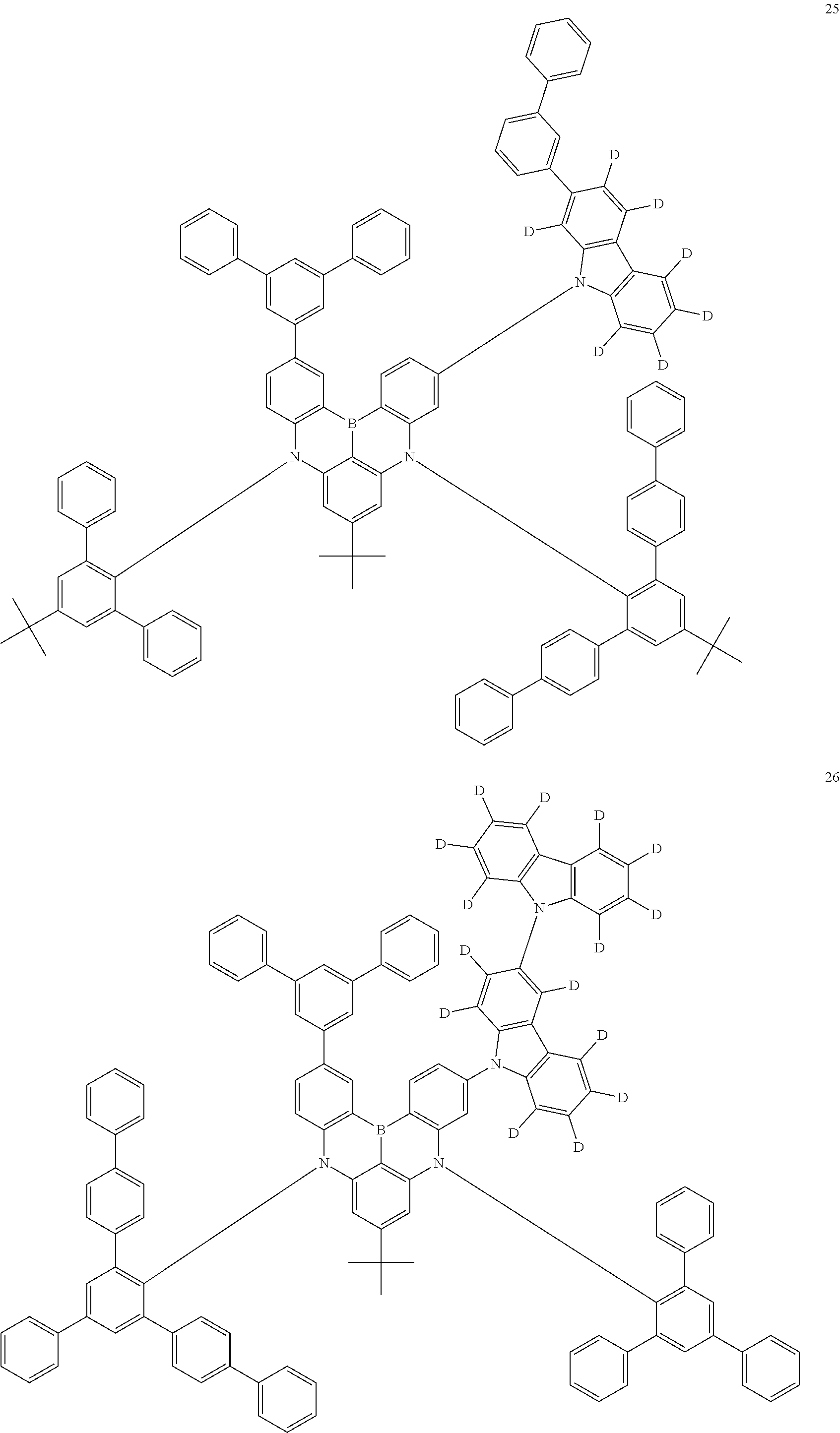 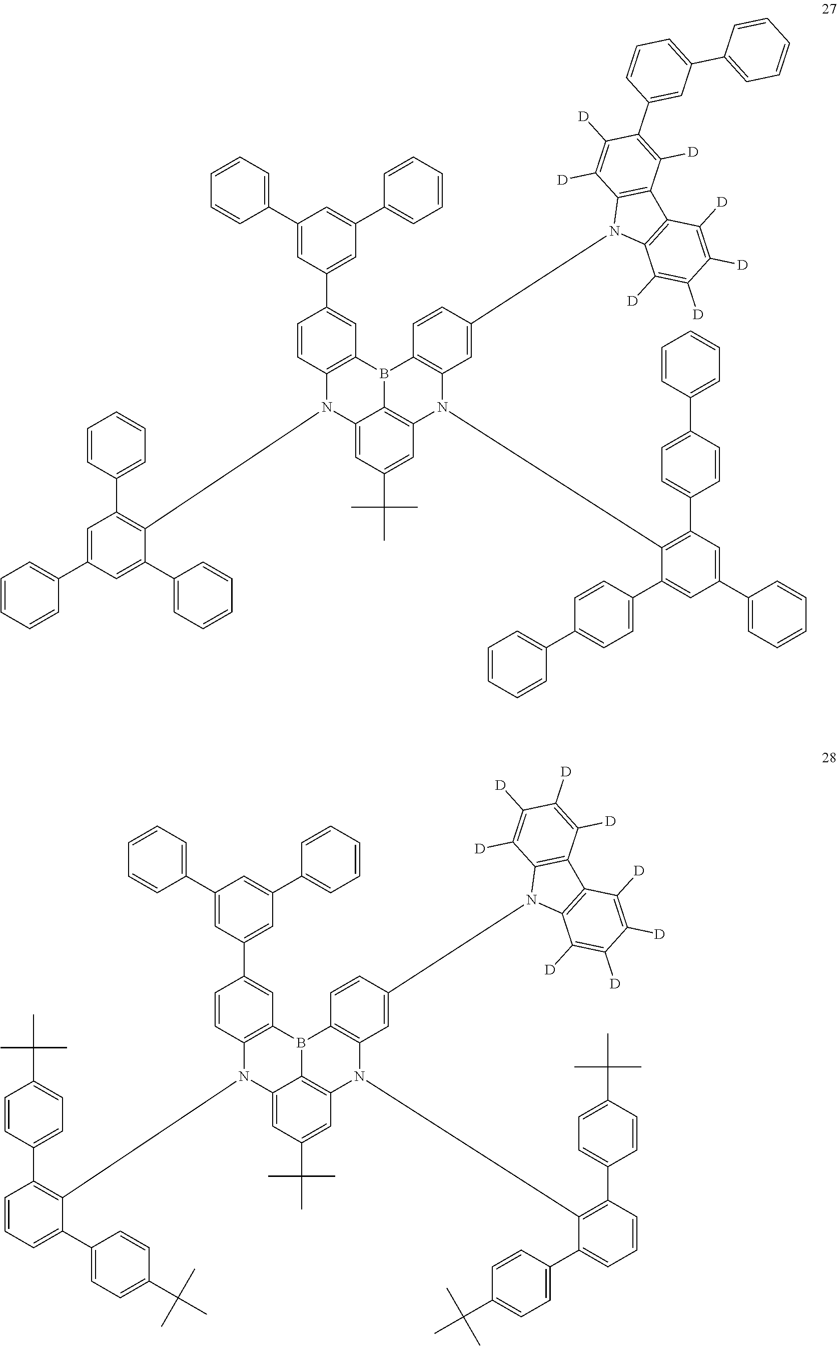 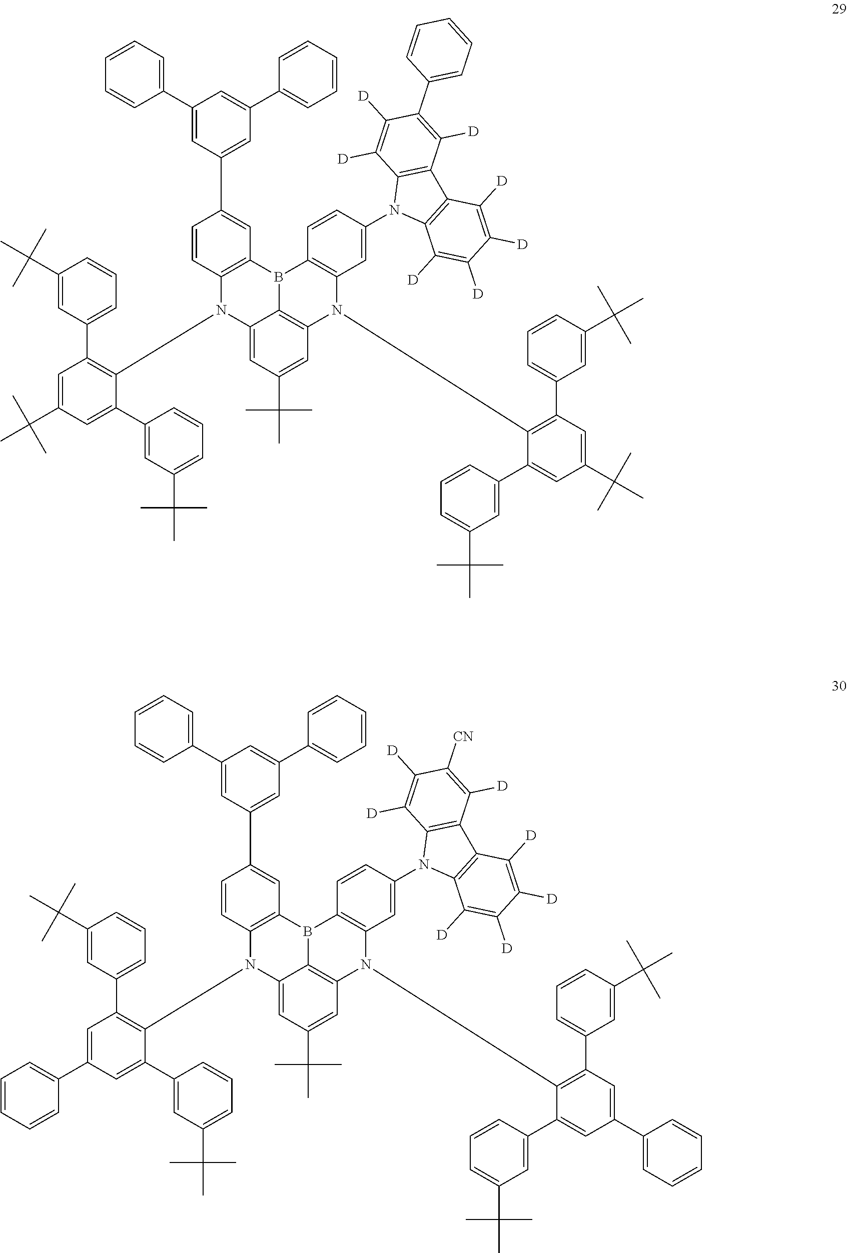 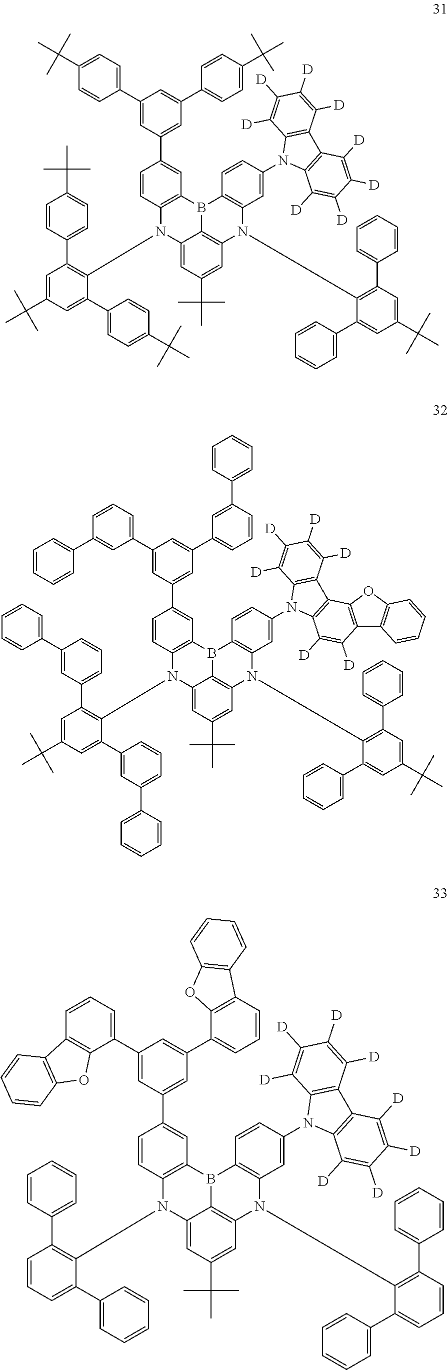 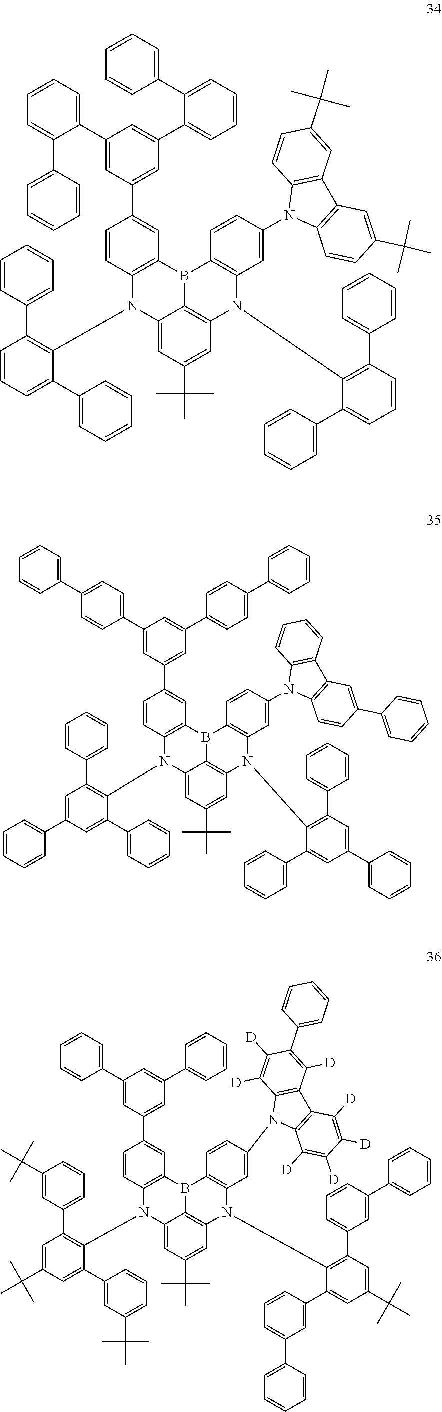 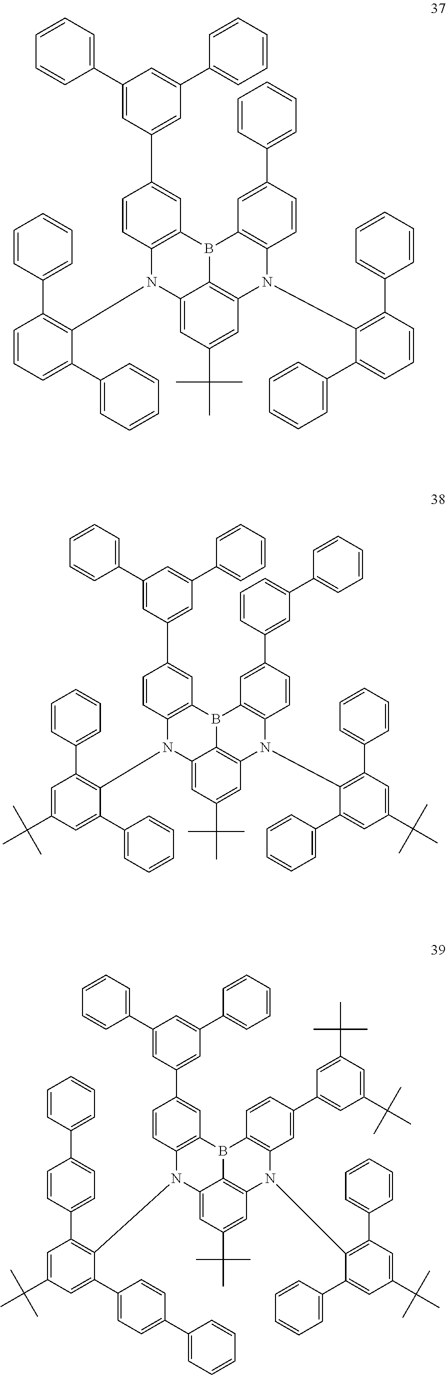 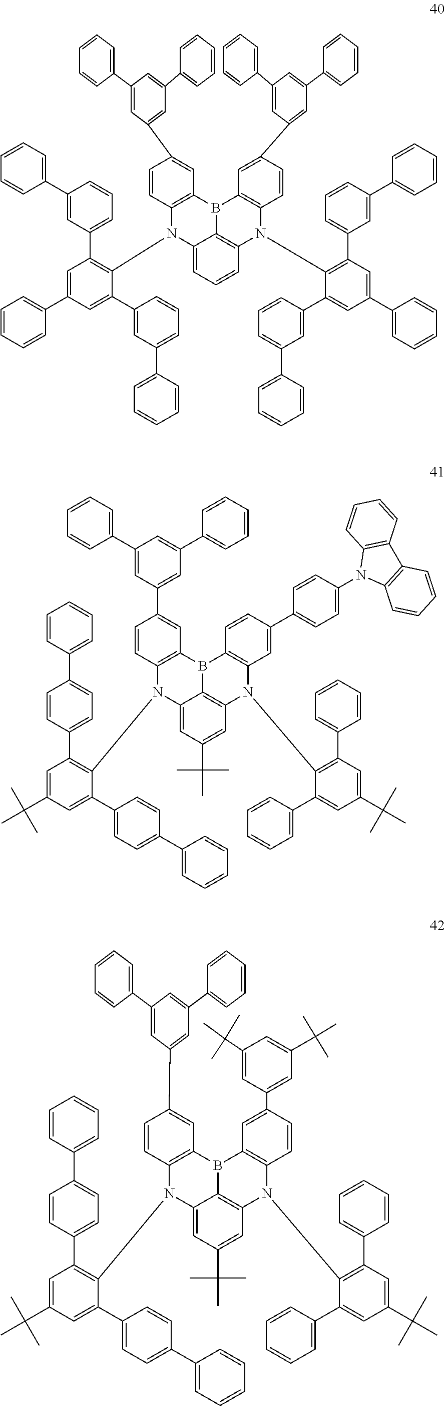 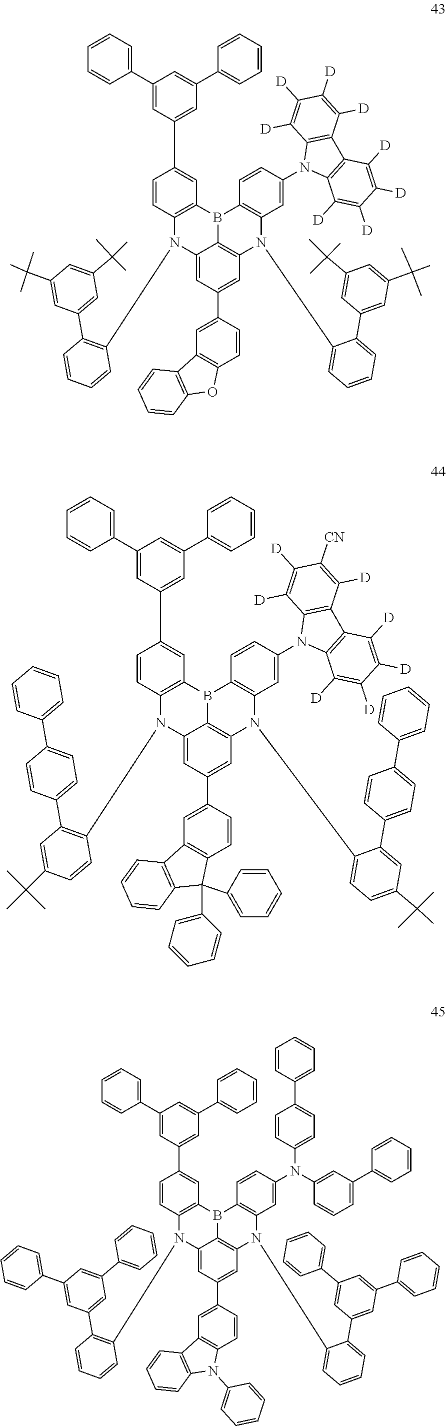 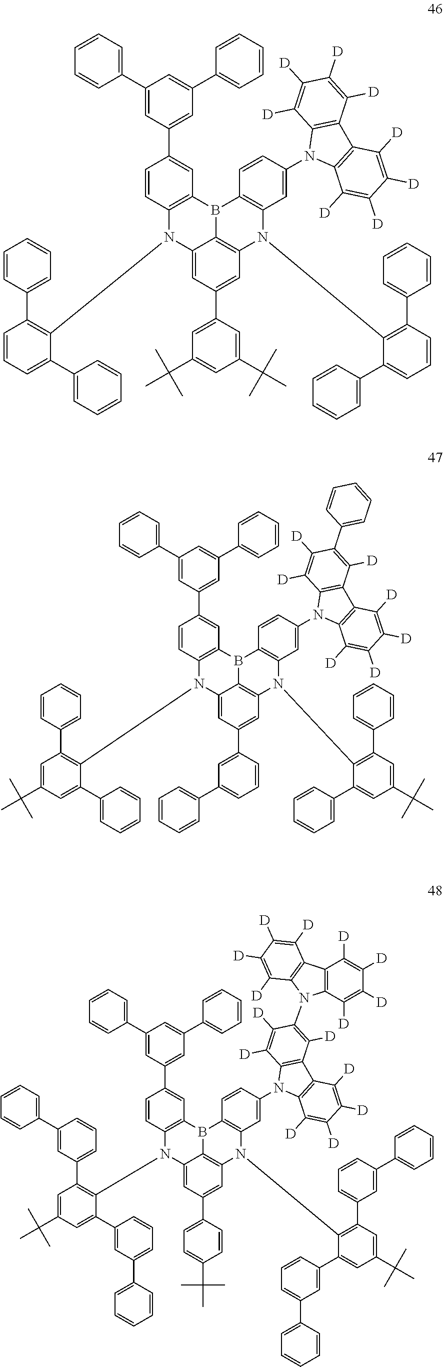 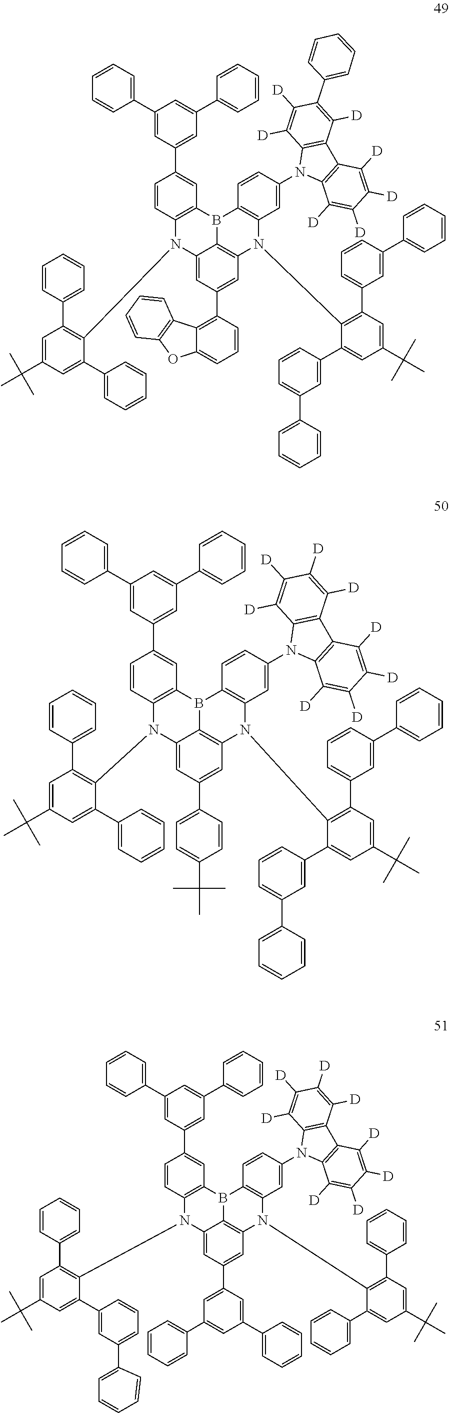 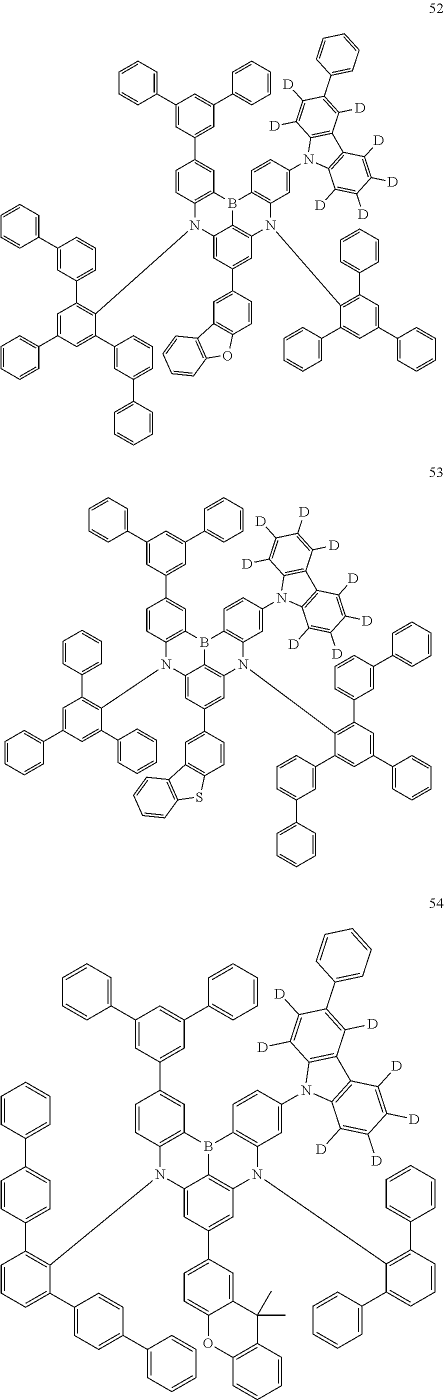 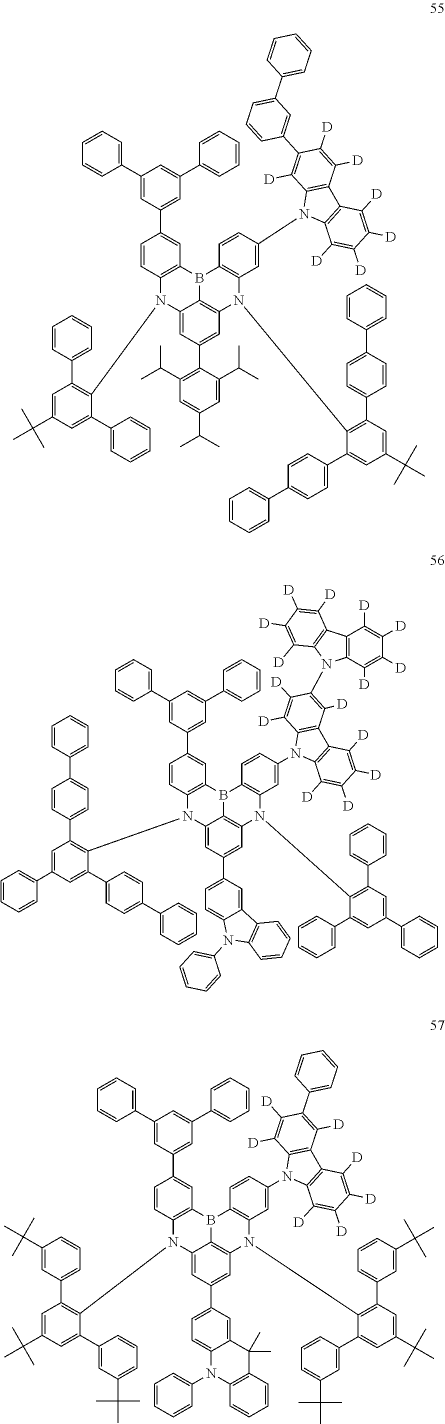 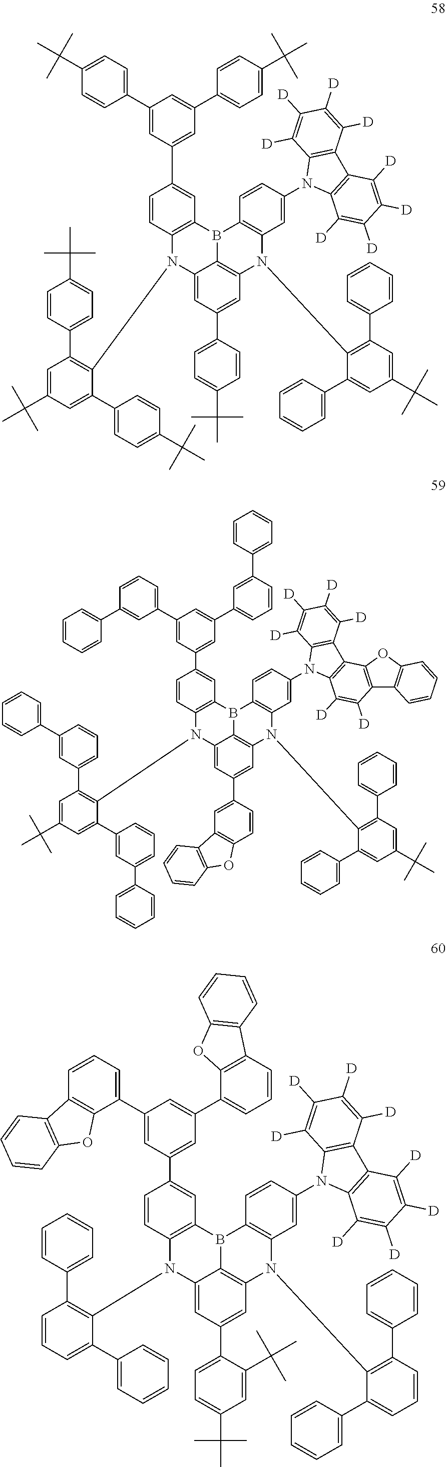 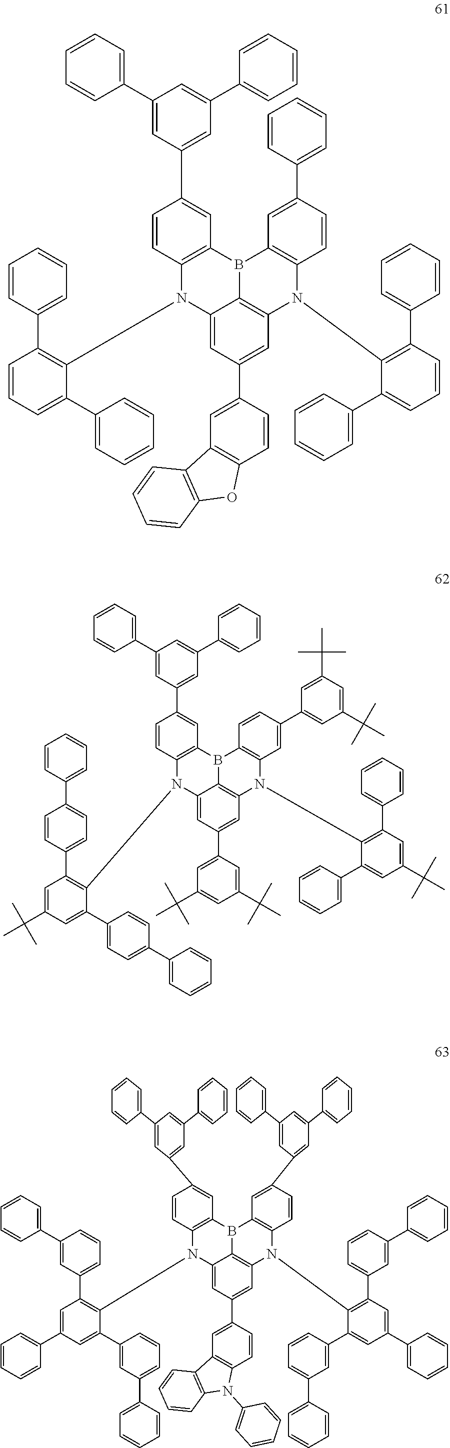 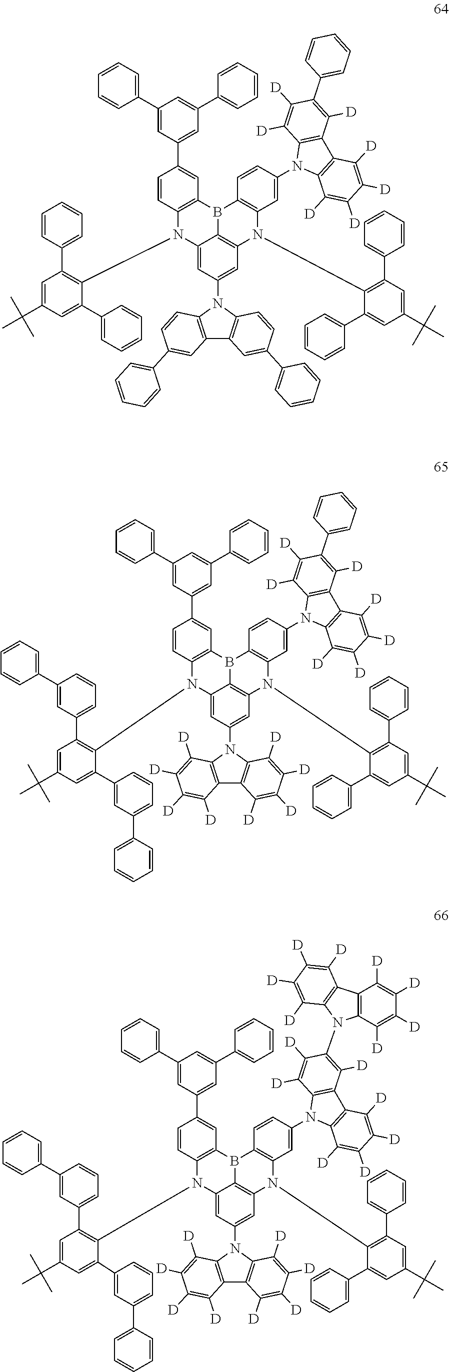 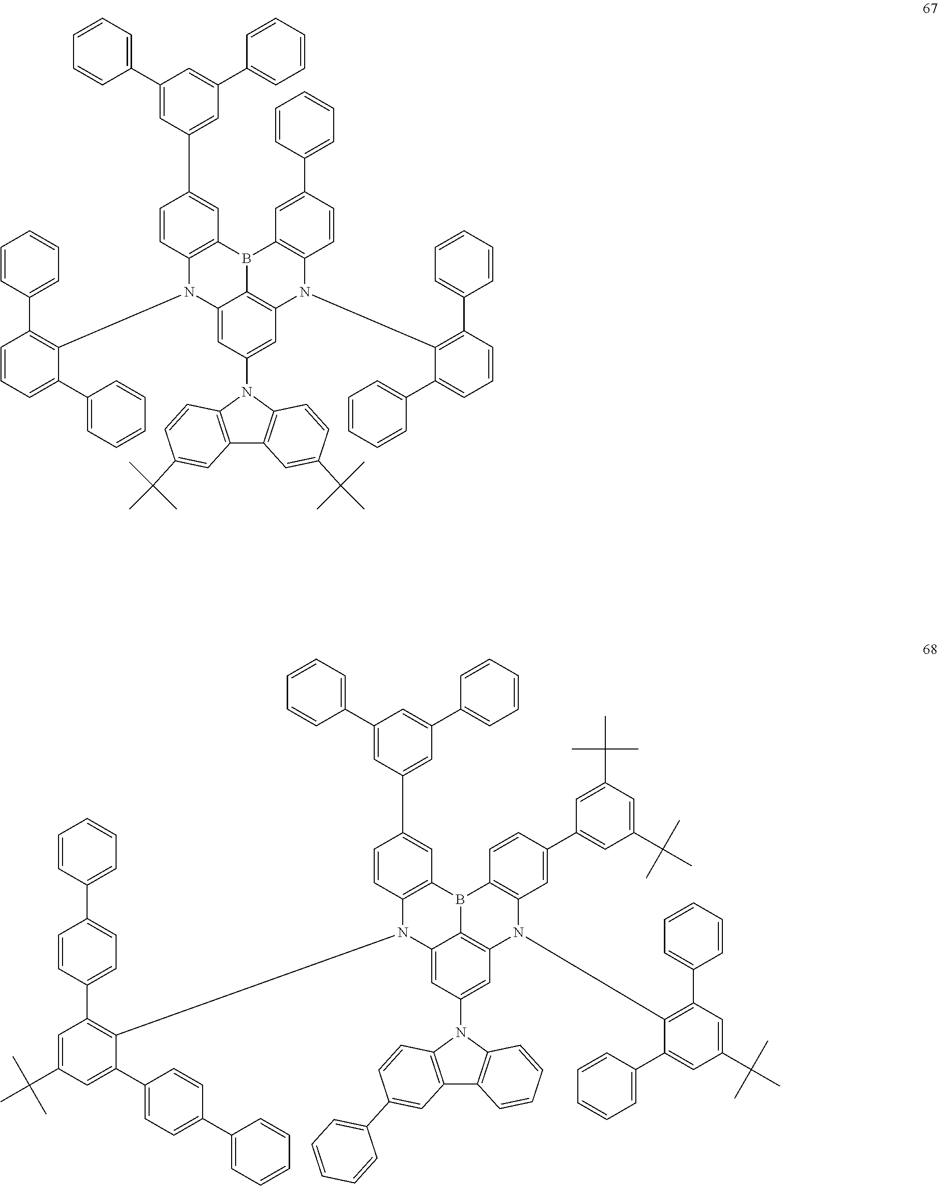 [SMILES: CC(C)(C)c1ccc2c(c1)c1cc(C(C)(C)C)ccc1n2-c1cc2c3c(c1)N(c1c(-c4ccccc4)cccc1-c1ccccc1)c1ccc(-c4cc(-c5ccccc5)cc(-c5ccccc5)c4)cc1B3c1cc(-c3ccccc3)ccc1N2c1c(-c2ccccc2)cccc1-c1ccccc1 ; CC(C)(C)c1cc(-c2ccc3c(c2)N(c2c(-c4ccccc4)cc(C(C)(C)C)cc2-c2ccccc2)c2cc(-n4c5ccccc5c5cc(-c6ccccc6)ccc54)cc4c2B3c2cc(-c3cc(-c5ccccc5)cc(-c5ccccc5)c3)ccc2N4c2c(-c3ccc(-c4ccccc4)cc3)cc(C(C)(C)C)cc2-c2ccc(-c3ccccc3)cc2)cc(C(C)(C)C)c1] 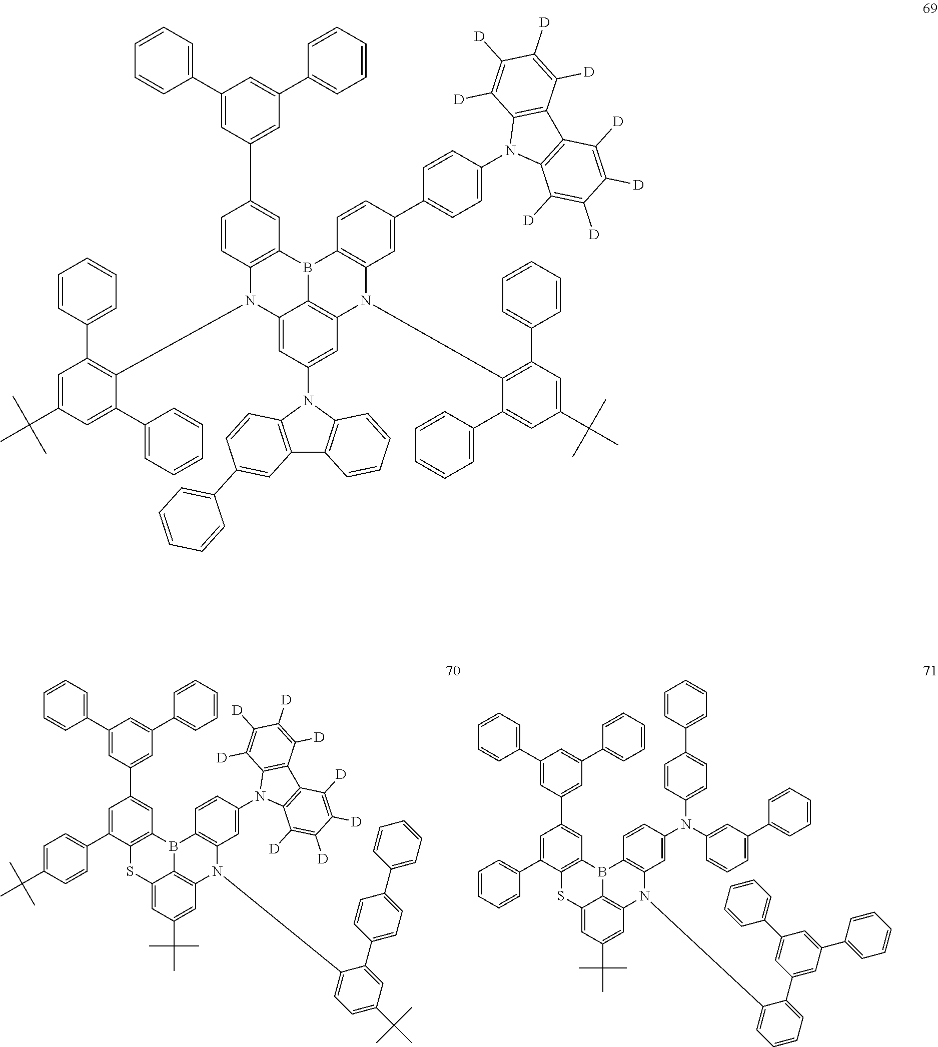 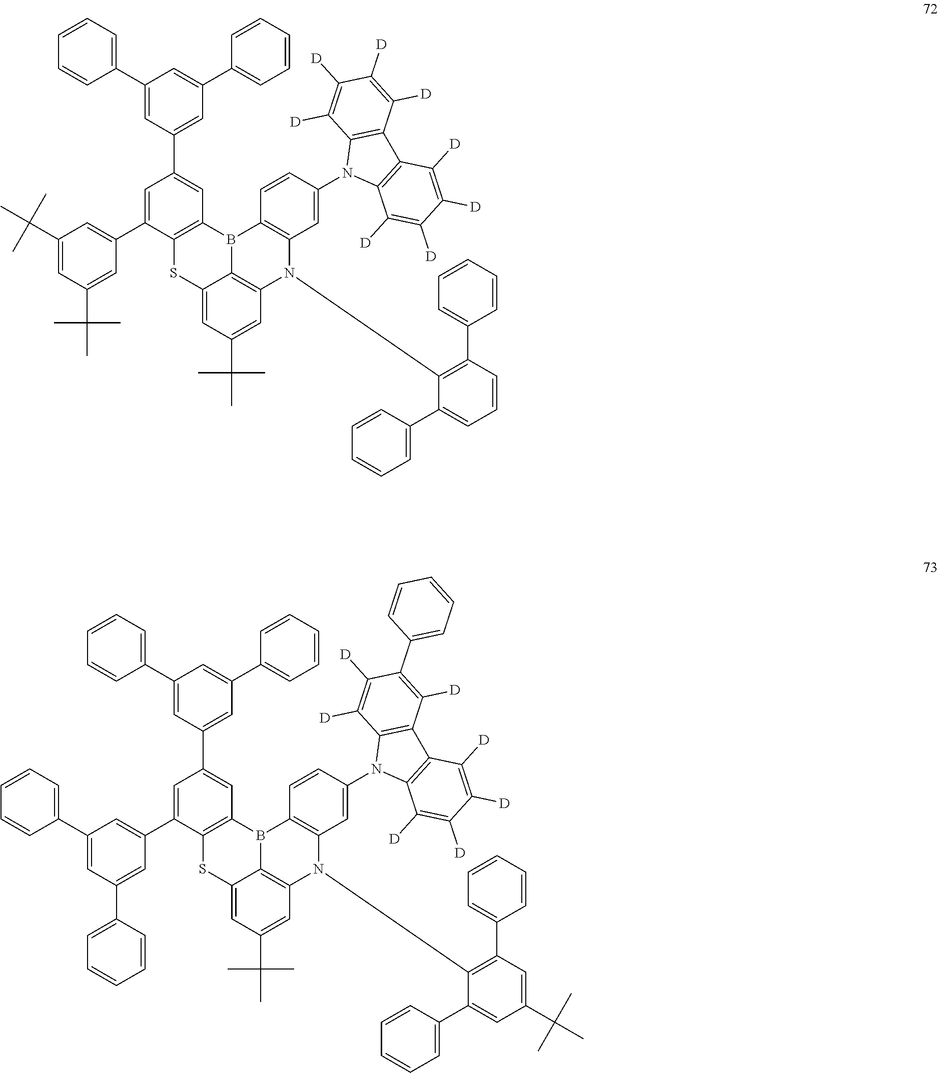 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1cc(-c2cc(-c4ccccc4)cc(-c4ccccc4)c2)cc(-c2cc(C(C)(C)C)cc(C(C)(C)C)c2)c1S3 ; [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cc(-c4ccccc4)cc(-c4ccccc4)c2)cc(-c2cc(-c4ccccc4)cc(-c4ccccc4)c2)c1S3] 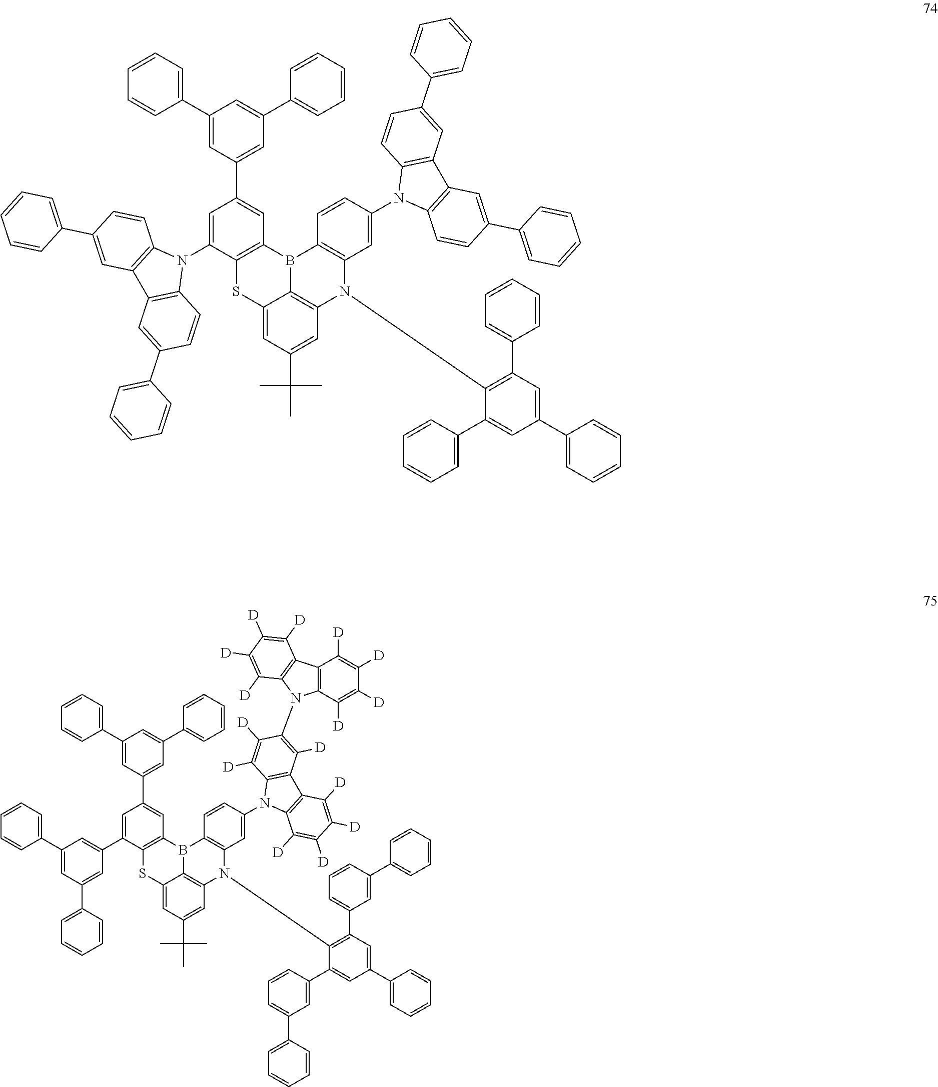 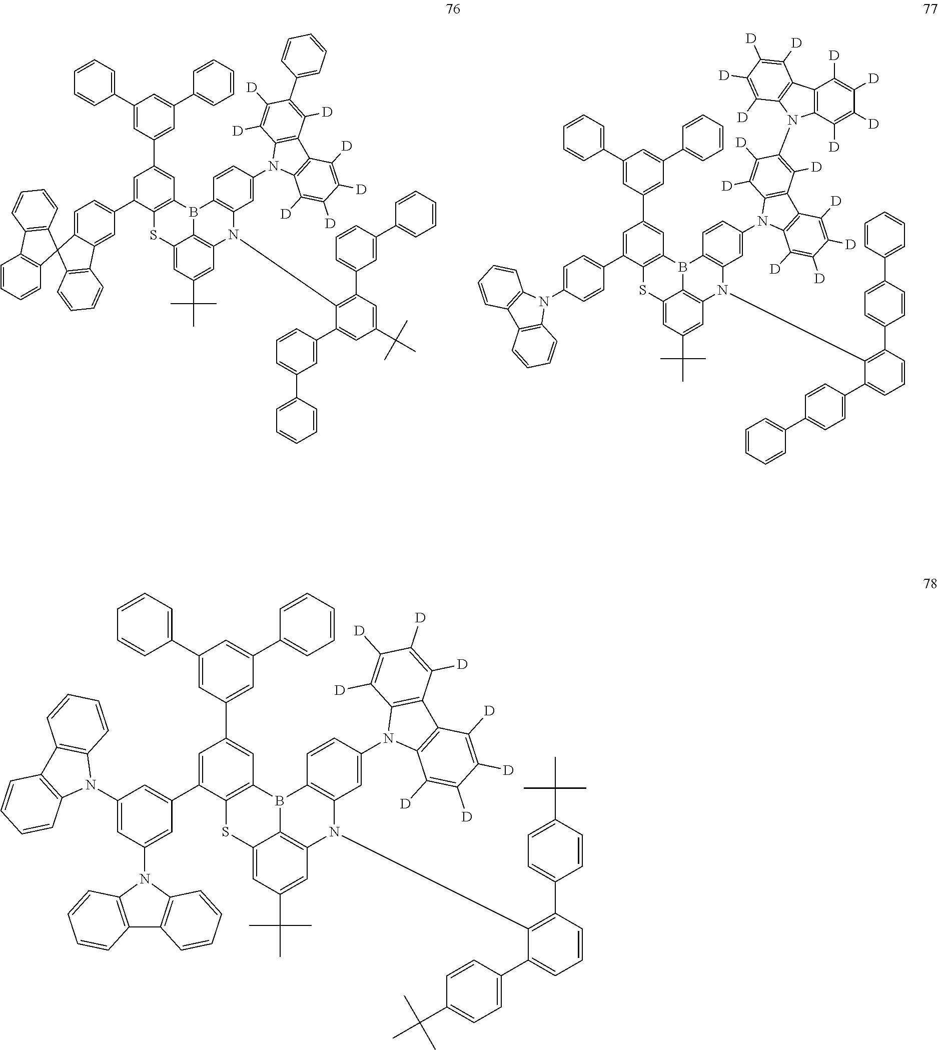 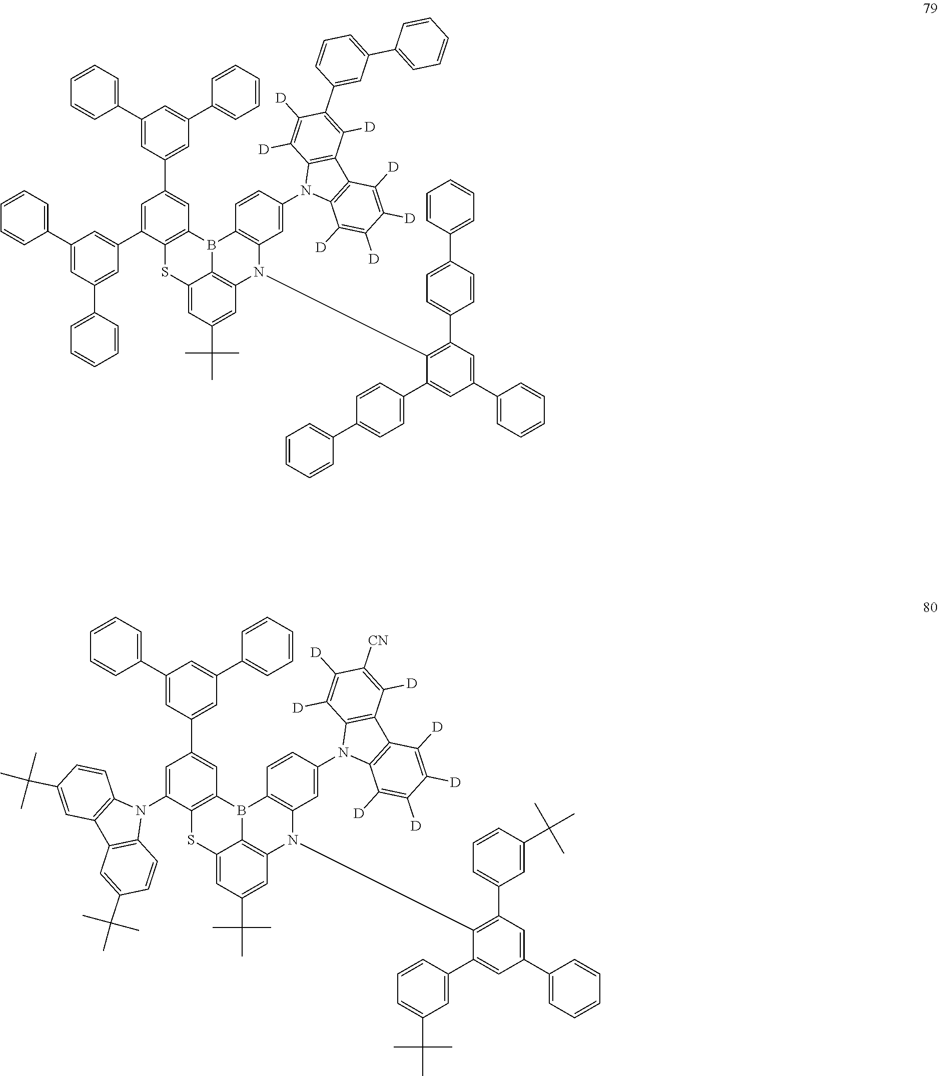 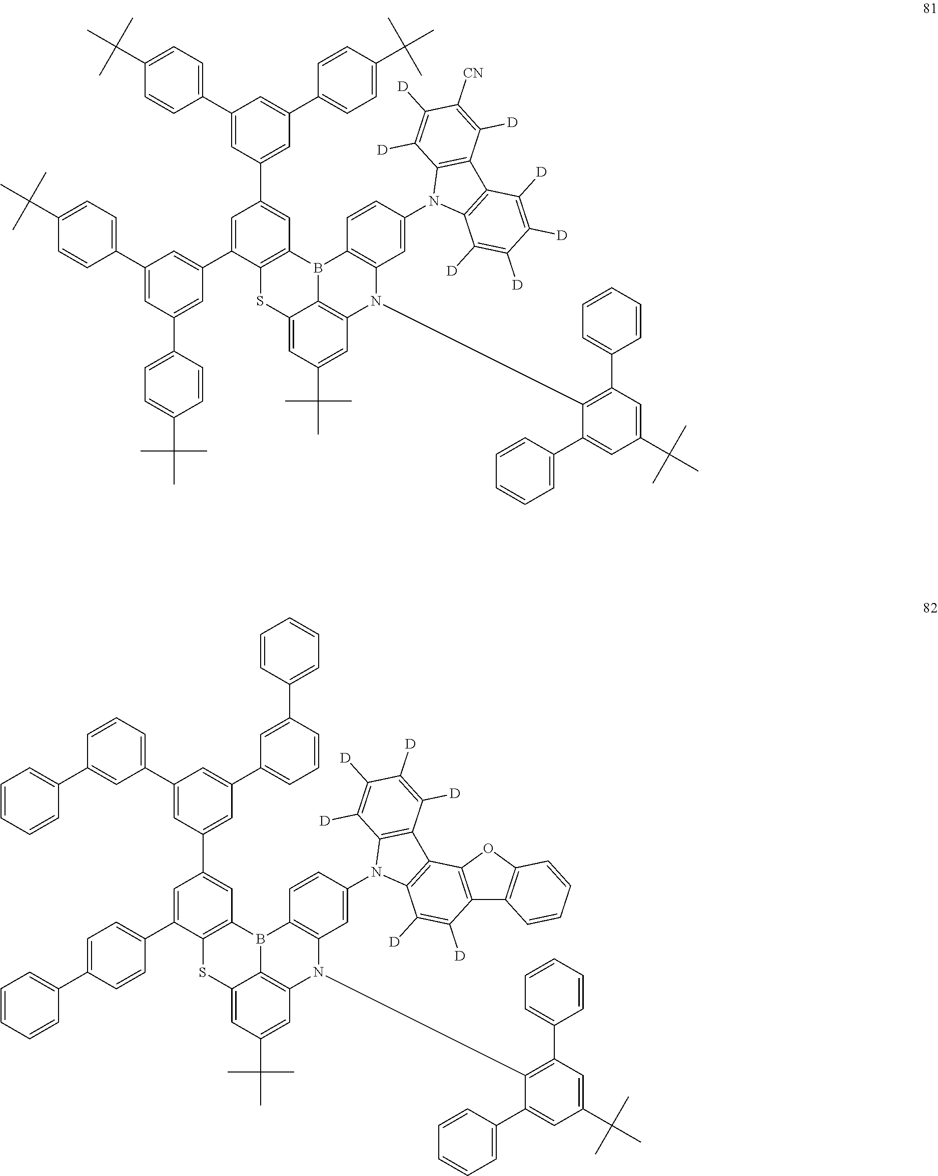 [SMILES: [2H]c1c([2H])c([2H])c2c(c1[2H])c1c([2H])c(C#N)c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cc(-c4ccc(C(C)(C)C)cc4)cc(-c4ccc(C(C)(C)C)cc4)c2)cc(-c2cc(-c4ccc(C(C)(C)C)cc4)cc(-c4ccc(C(C)(C)C)cc4)c2)c1S3 ; [2H]c1c([2H])c([2H])c2c(c1[2H])c1c3oc4ccccc4c3c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cc(-c4cccc(-c5ccccc5)c4)cc(-c4cccc(-c5ccccc5)c4)c2)cc(-c2ccc(-c4ccccc4)cc2)c1S3] 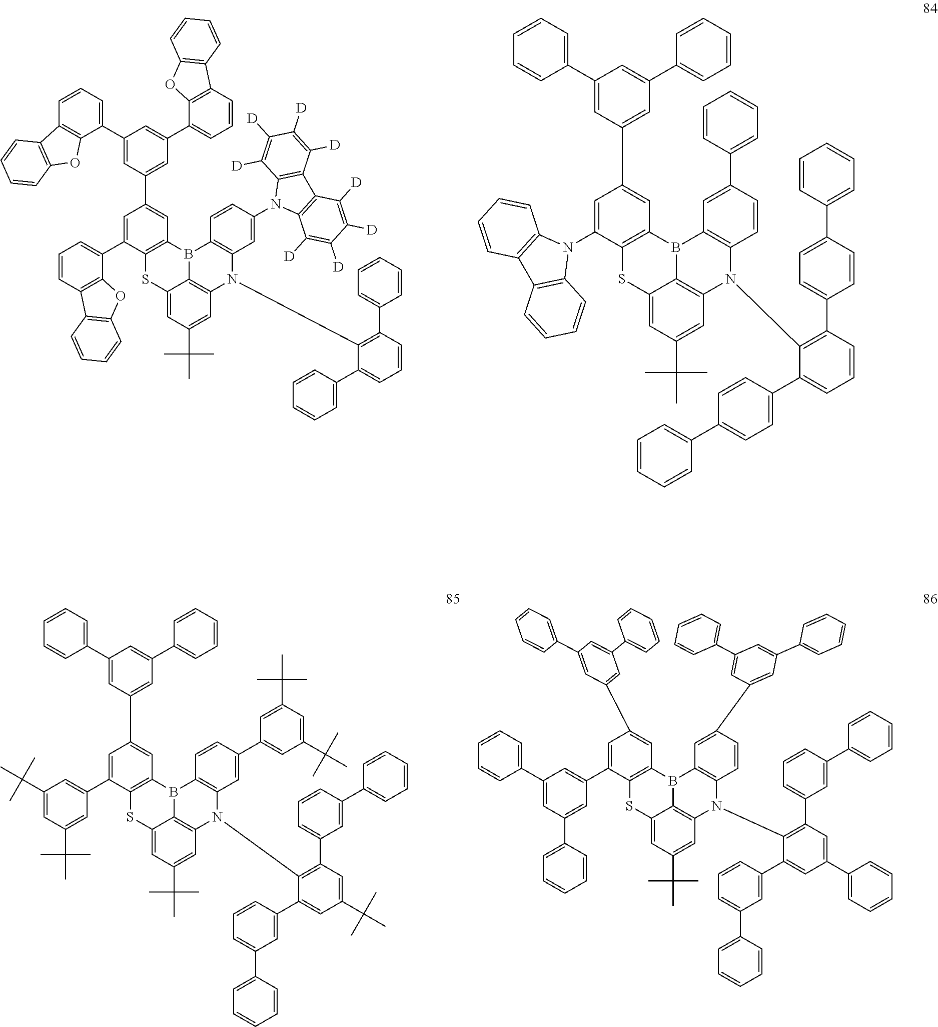 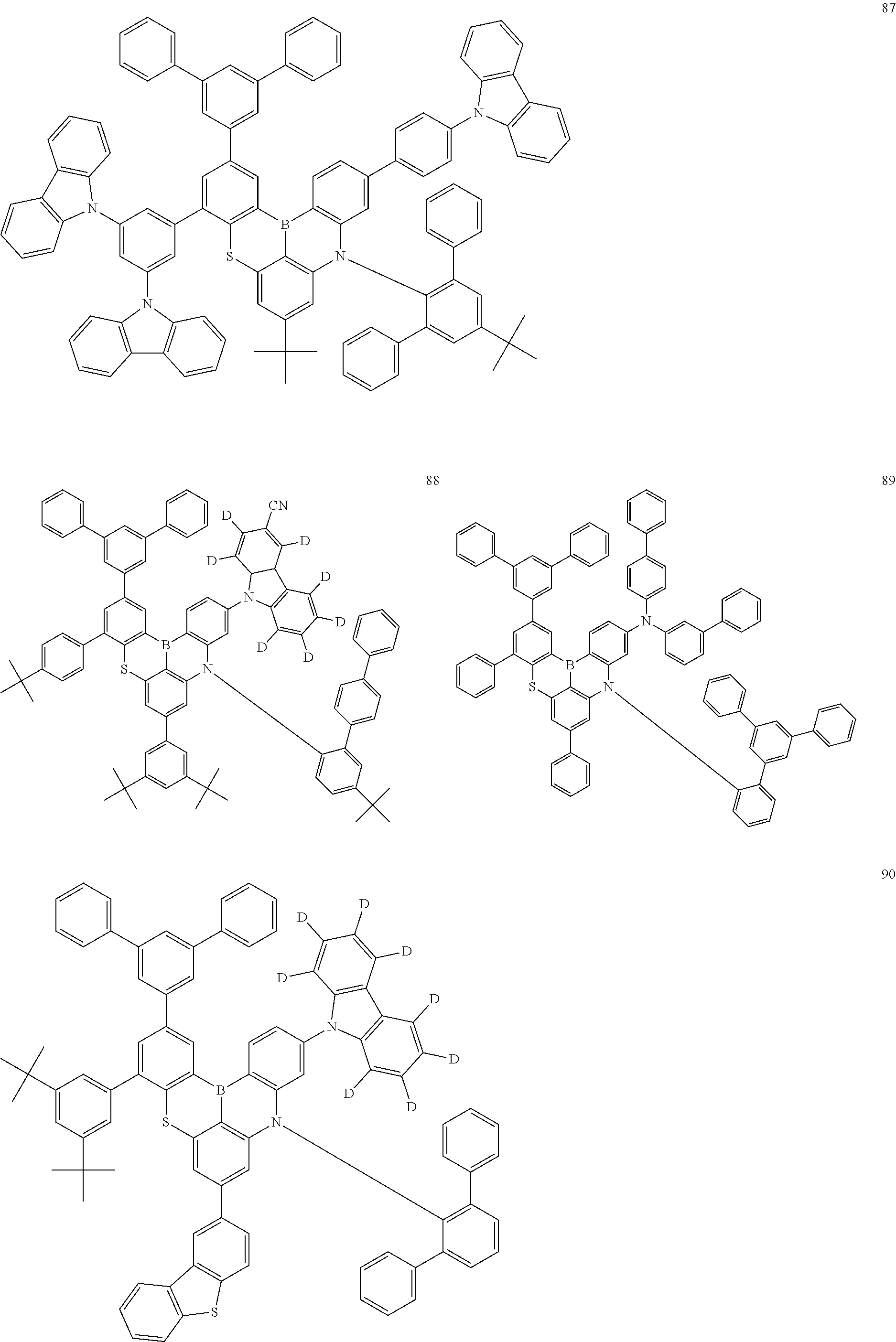 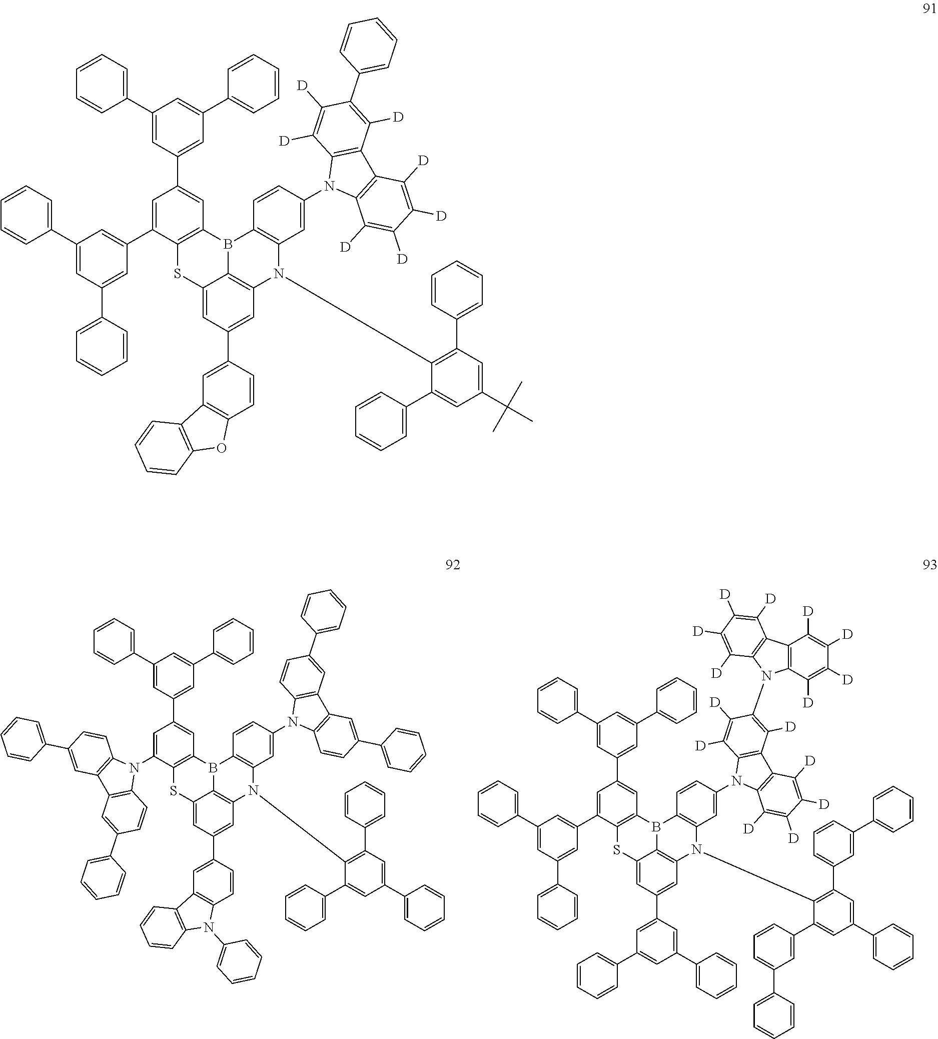 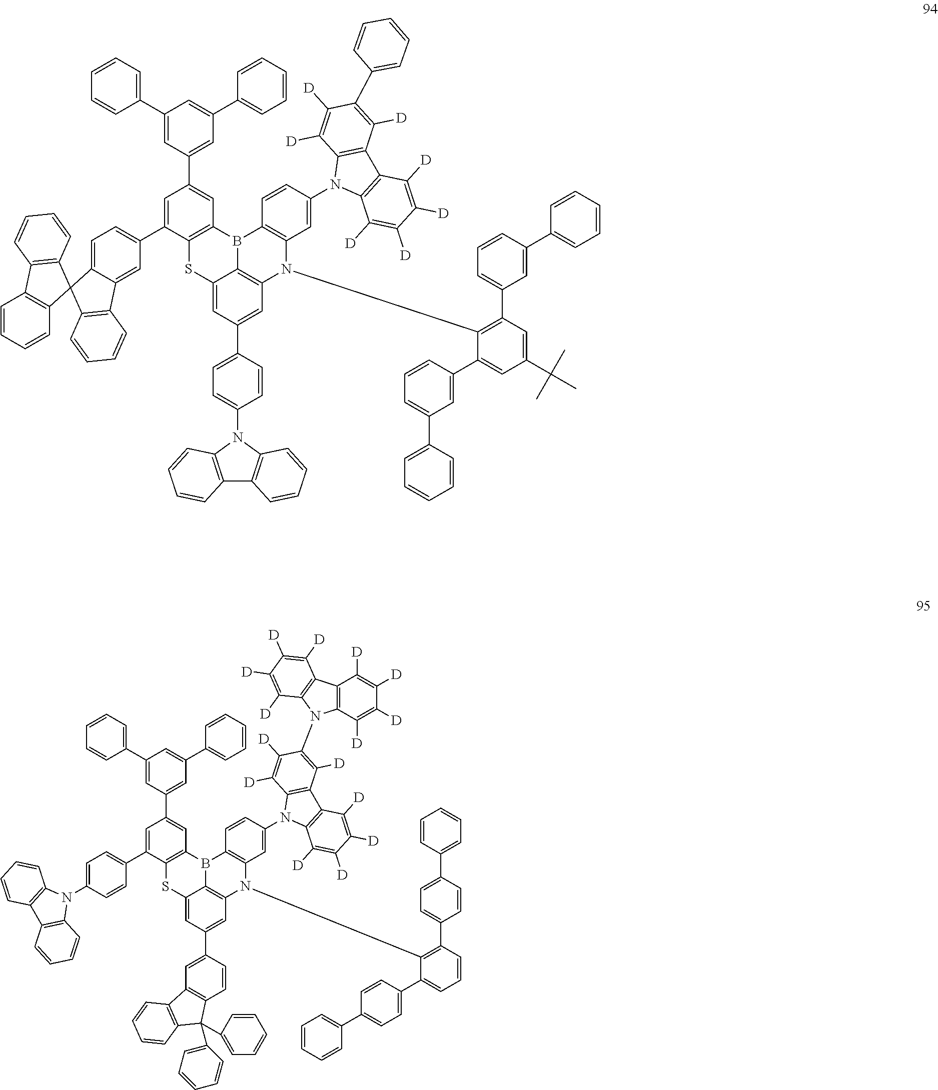 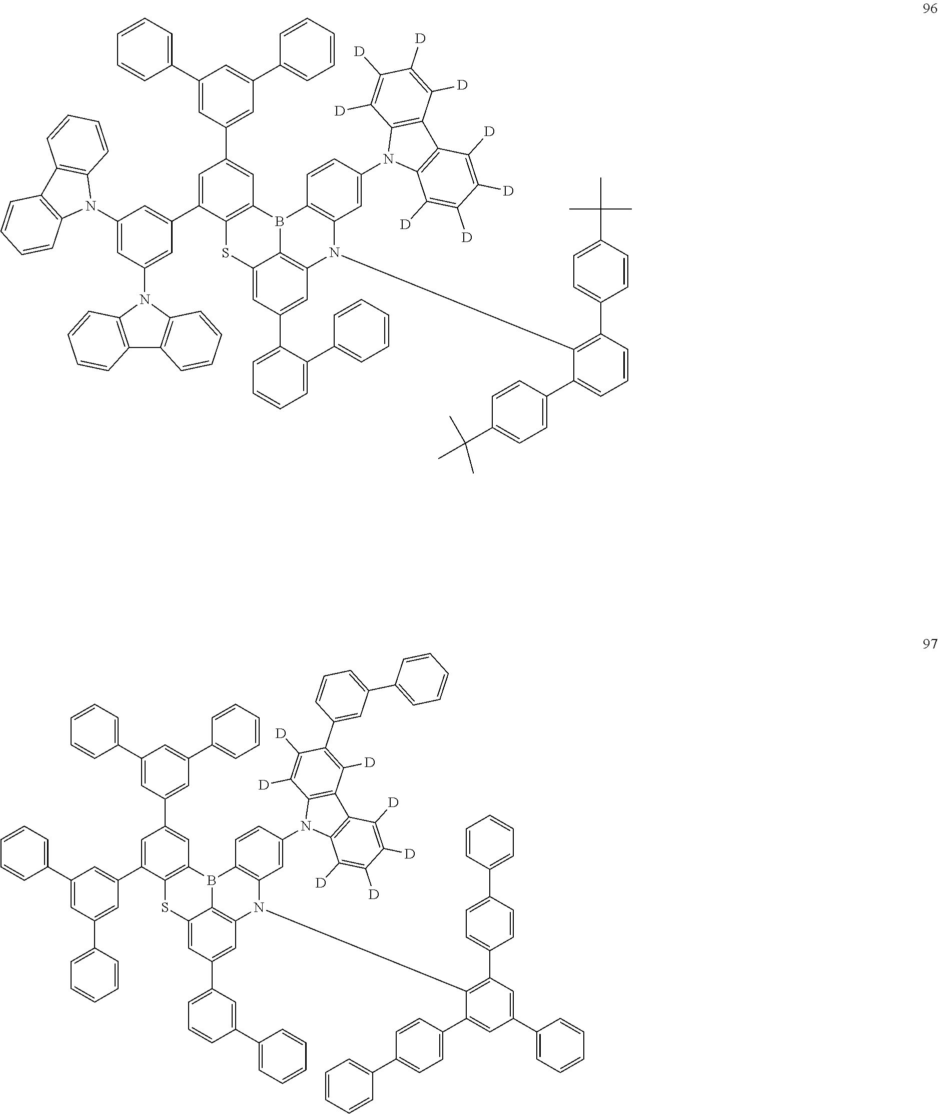 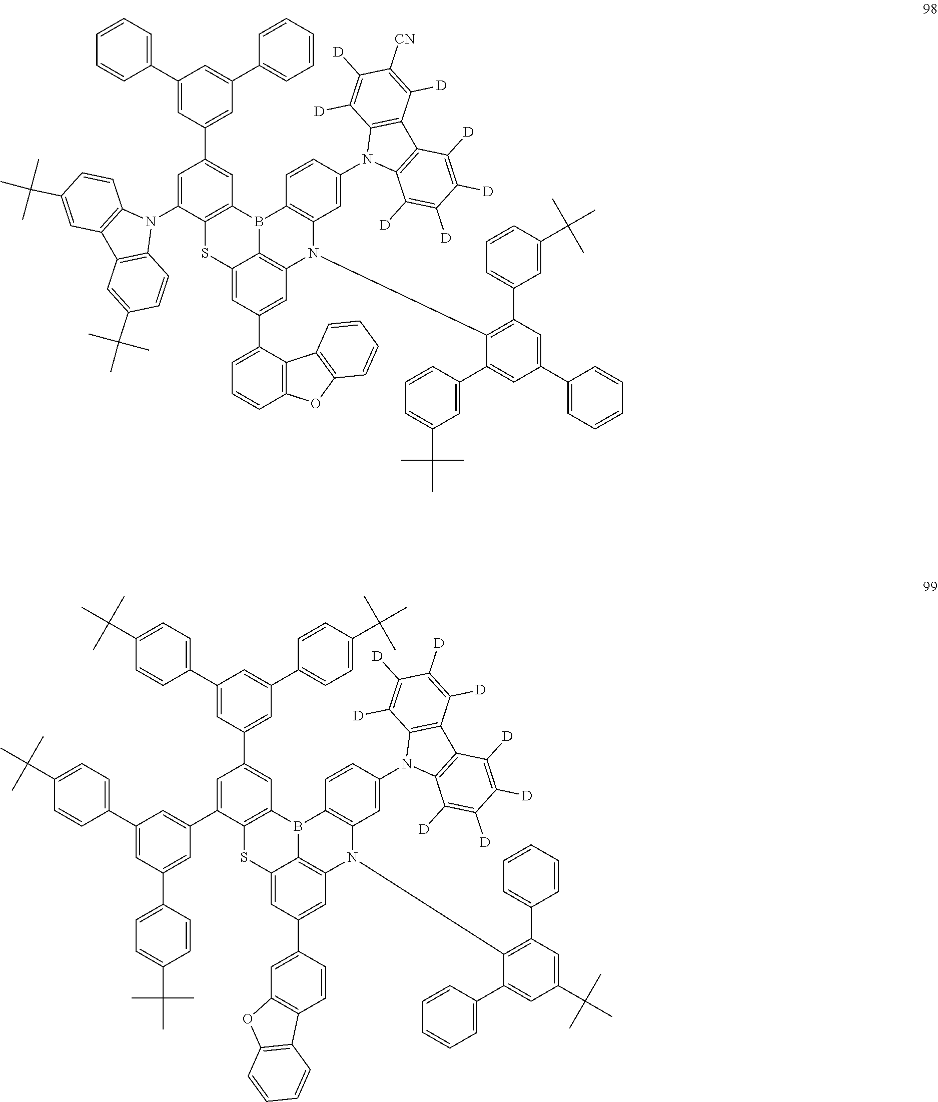 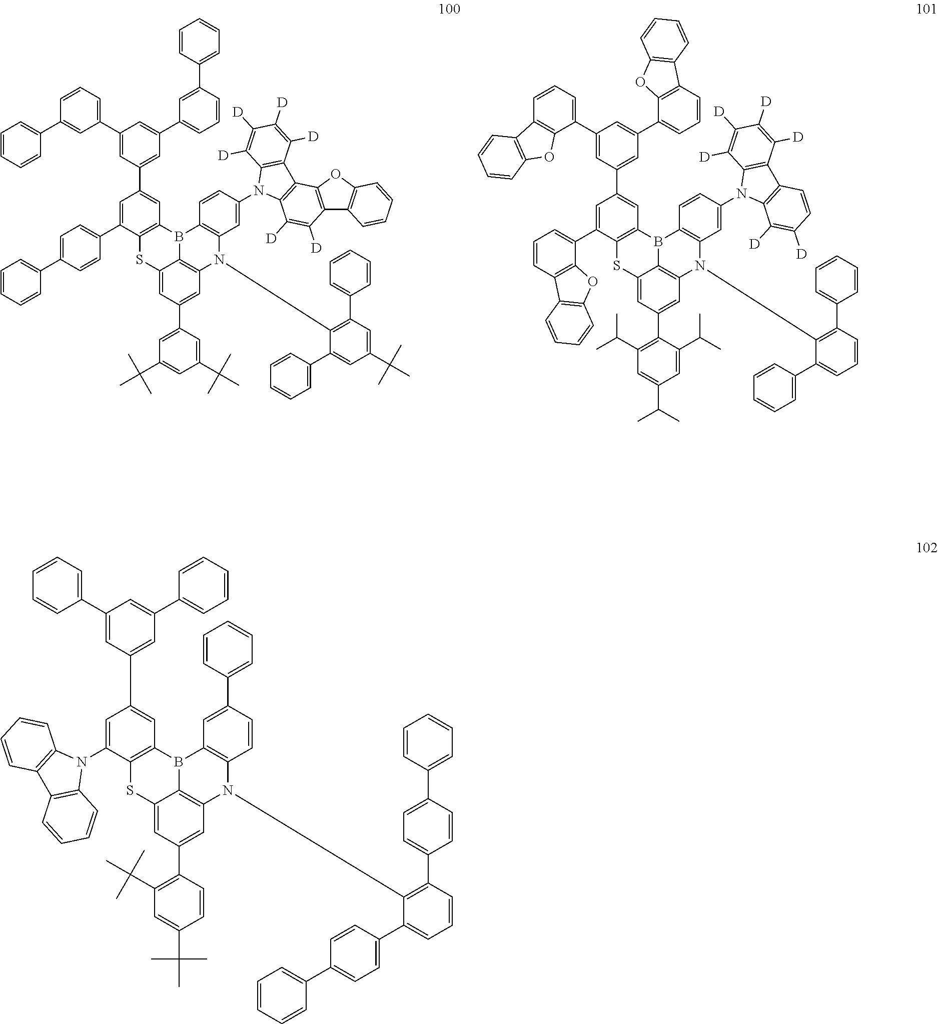 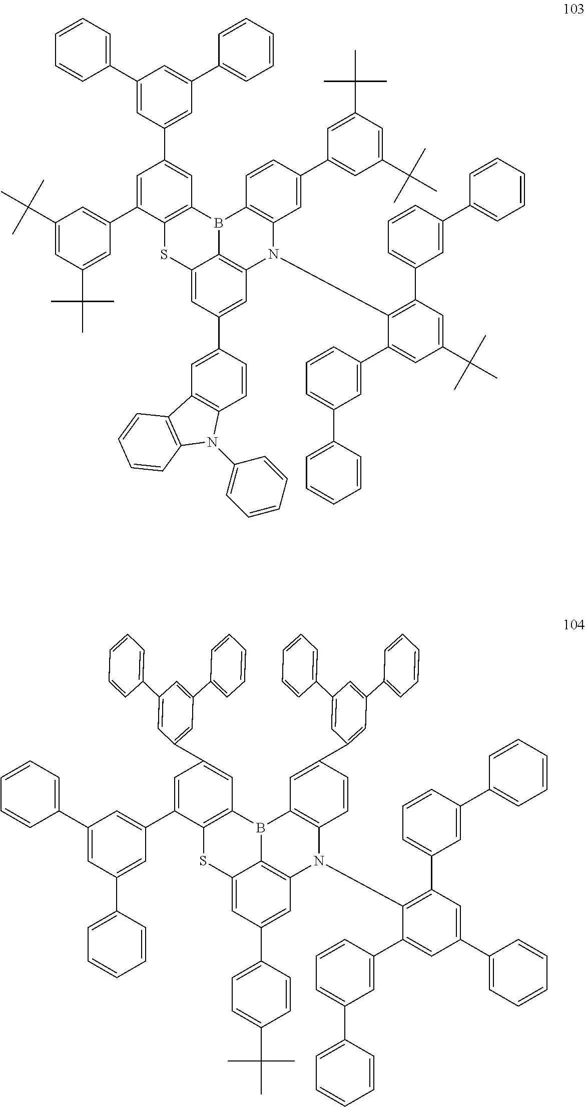 [SMILES: CC(C)(C)c1cc(-c2ccc3c(c2)N(c2c(-c4cccc(-c5ccccc5)c4)cc(C(C)(C)C)cc2-c2cccc(-c4ccccc4)c2)c2cc(-c4ccc5c(c4)c4ccccc4n5-c4ccccc4)cc4c2B3c2cc(-c3cc(-c5ccccc5)cc(-c5ccccc5)c3)cc(-c3cc(C(C)(C)C)cc(C(C)(C)C)c3)c2S4)cc(C(C)(C)C)c1 ; CC(C)(C)c1ccc(-c2cc3c4c(c2)N(c2c(-c5cccc(-c6ccccc6)c5)cc(-c5ccccc5)cc2-c2cccc(-c5ccccc5)c2)c2ccc(-c5cc(-c6ccccc6)cc(-c6ccccc6)c5)cc2B4c2cc(-c4cc(-c5ccccc5)cc(-c5ccccc5)c4)cc(-c4cc(-c5ccccc5)cc(-c5ccccc5)c4)c2S3)cc1] 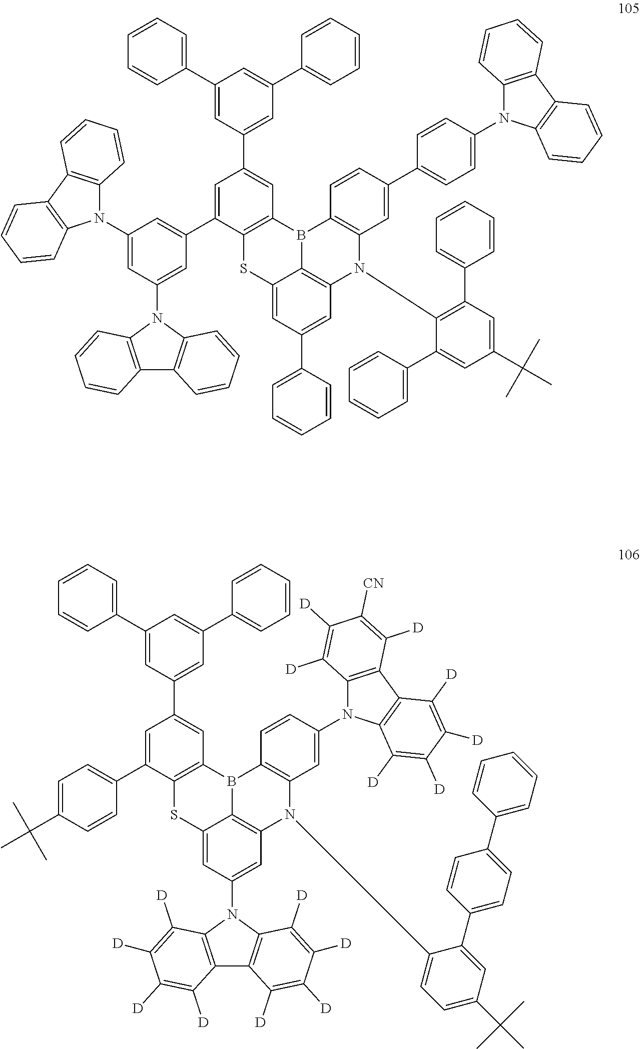 [SMILES: CC(C)(C)c1cc(-c2ccccc2)c(N2c3cc(-c4ccc(-n5c6ccccc6c6ccccc65)cc4)ccc3B3c4cc(-c5cc(-c6ccccc6)cc(-c6ccccc6)c5)cc(-c5cc(-n6c7ccccc7c7ccccc76)cc(-n6c7ccccc7c7ccccc76)c5)c4Sc4cc(-c5ccccc5)cc2c43)c(-c2ccccc2)c1 ; [2H]c1c([2H])c([2H])c2c(c1[2H])c1c([2H])c([2H])c([2H])c([2H])c1n2-c1cc2c3c(c1)N(c1ccc(C(C)(C)C)cc1-c1ccc(-c4ccccc4)cc1)c1cc(-n4c5c([2H])c([2H])c([2H])c([2H])c5c5c([2H])c(C#N)c([2H])c([2H])c54)ccc1B3c1cc(-c3cc(-c4ccccc4)cc(-c4ccccc4)c3)cc(-c3ccc(C(C)(C)C)cc3)c1S2] 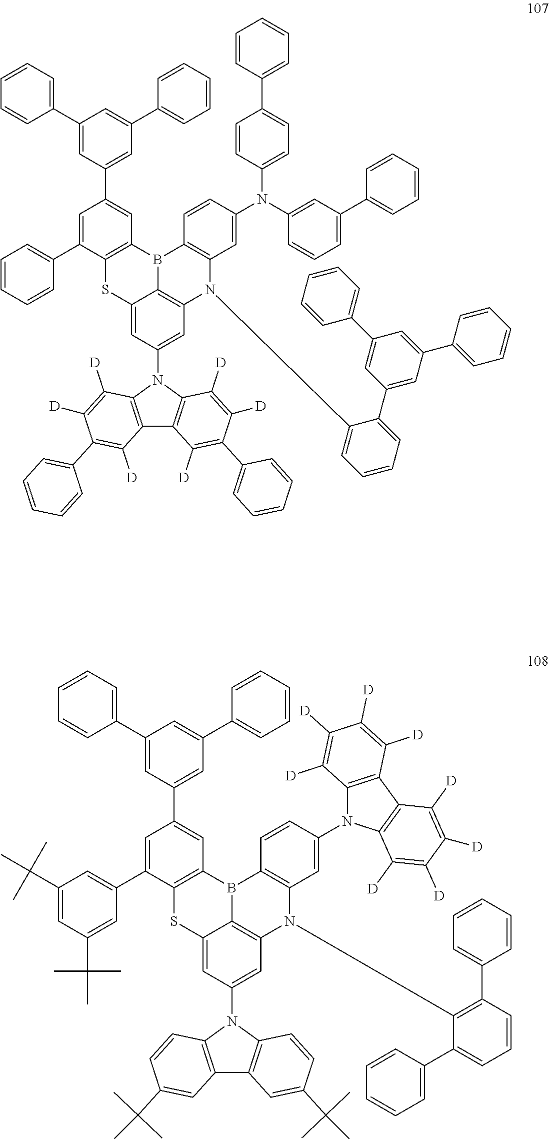 [SMILES: [2H]c1c(-c2ccccc2)c([2H])c2c3c([2H])c(-c4ccccc4)c([2H])c([2H])c3n(-c3cc4c5c(c3)N(c3ccccc3-c3cc(-c6ccccc6)cc(-c6ccccc6)c3)c3cc(N(c6ccc(-c7ccccc7)cc6)c6cccc(-c7ccccc7)c6)ccc3B5c3cc(-c5cc(-c6ccccc6)cc(-c6ccccc6)c5)cc(-c5ccccc5)c3S4)c2c1[2H] ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-n3c4ccc(C(C)(C)C)cc4c4cc(C(C)(C)C)ccc43)cc3c1B2c1cc(-c2cc(-c4ccccc4)cc(-c4ccccc4)c2)cc(-c2cc(C(C)(C)C)cc(C(C)(C)C)c2)c1S3] 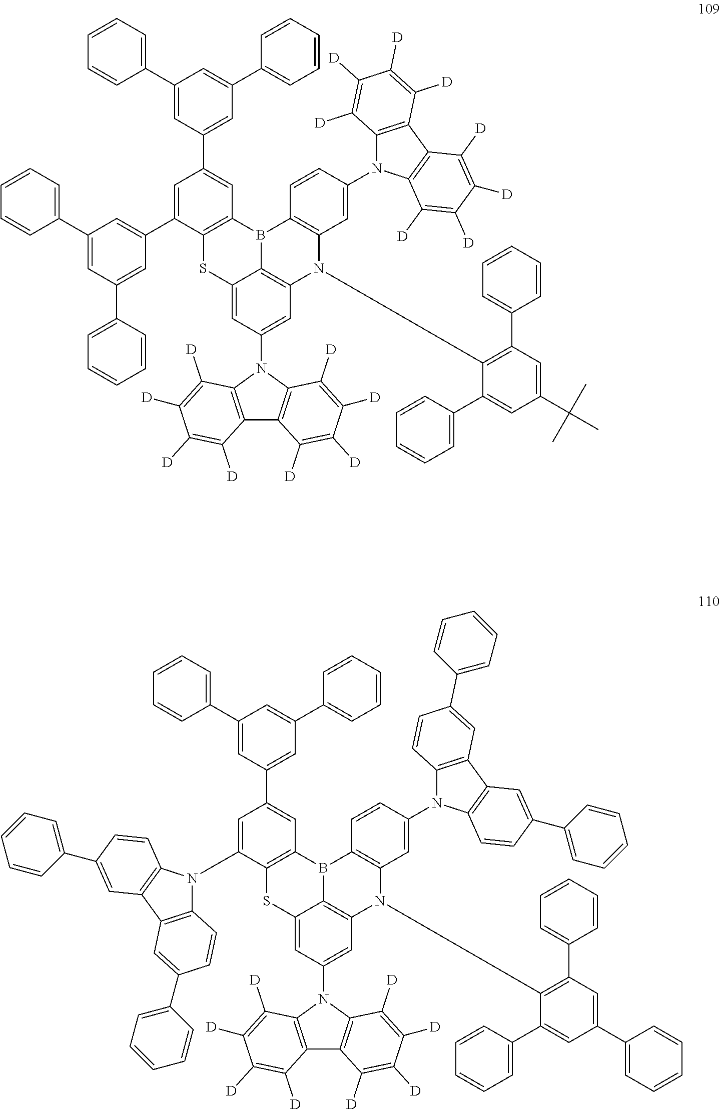 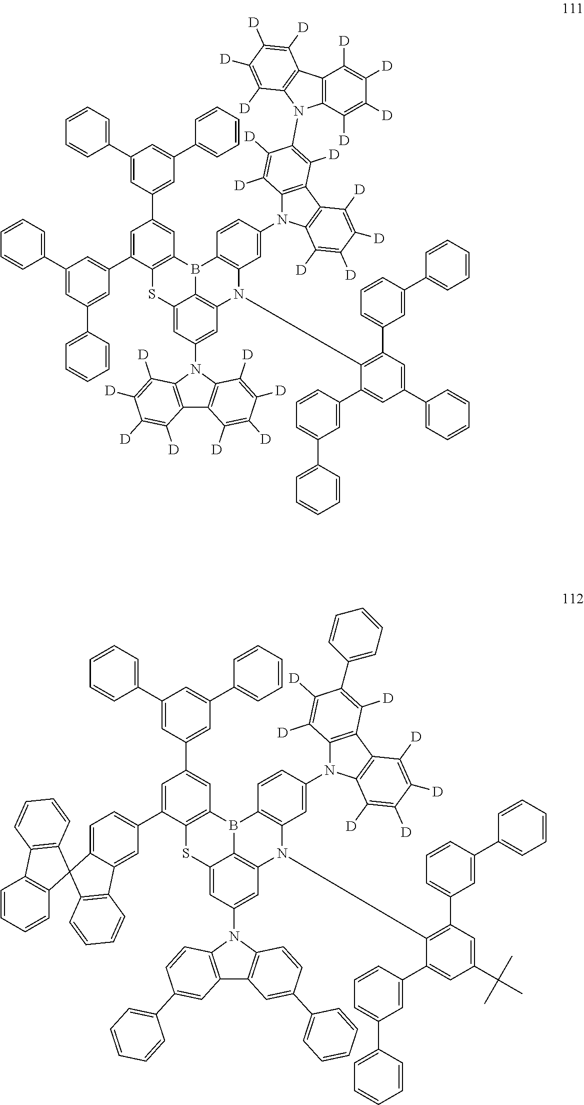 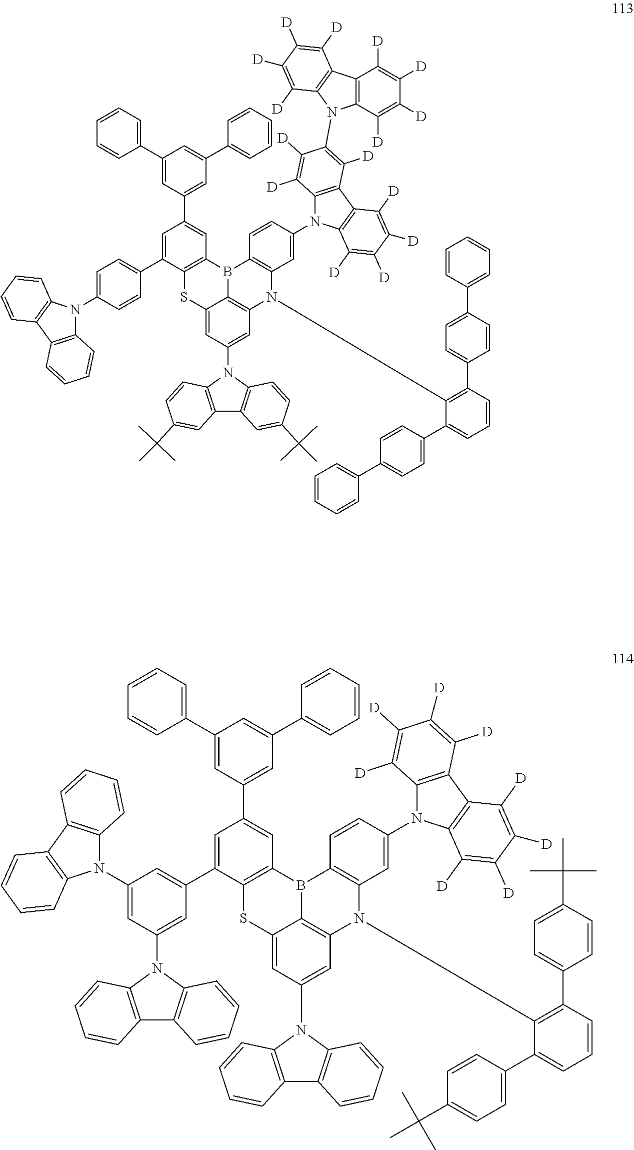 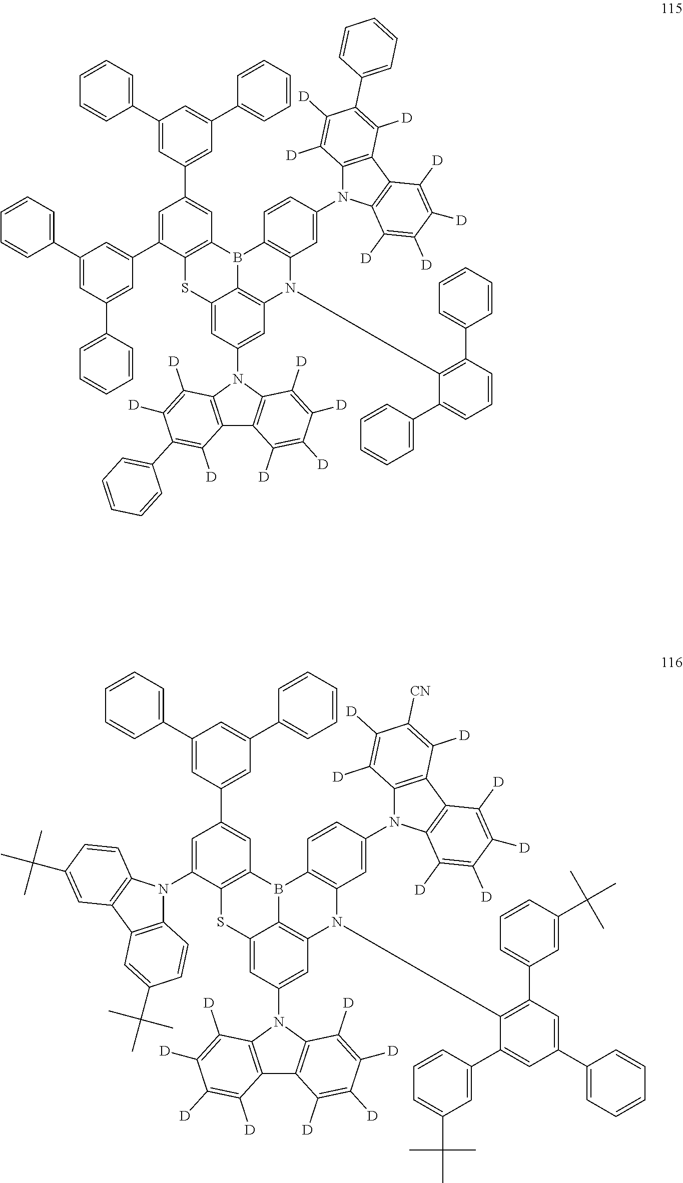 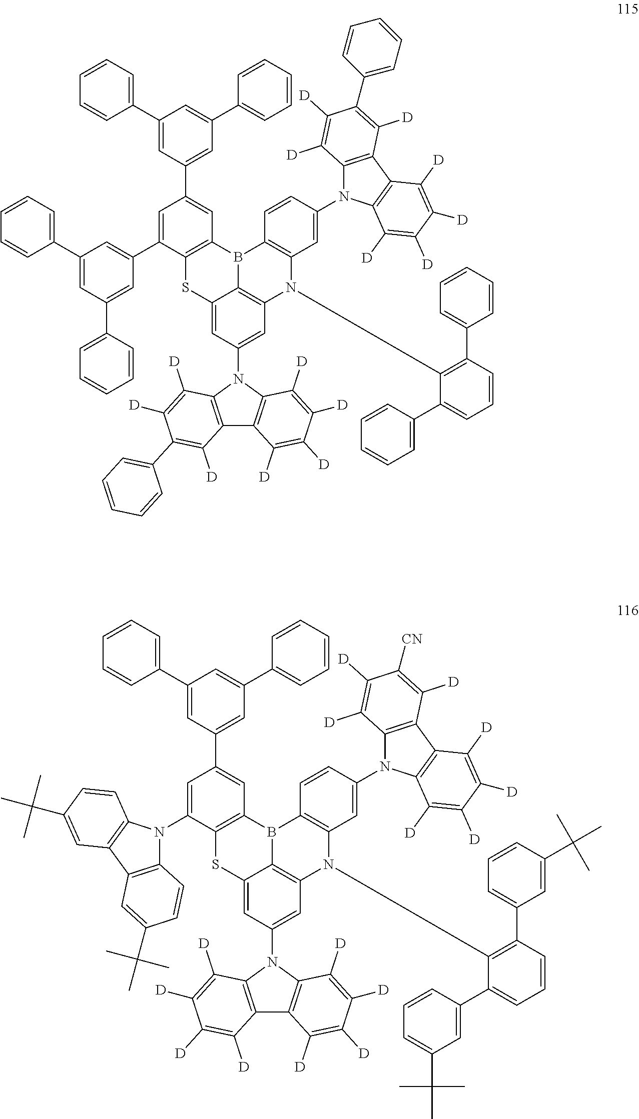 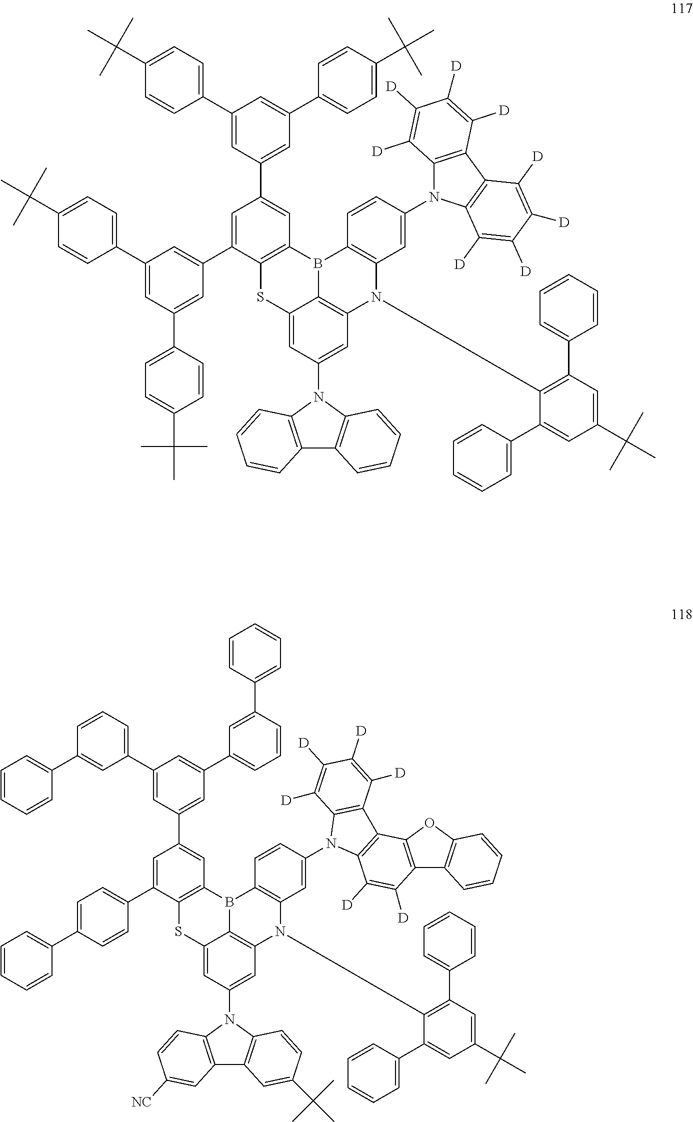 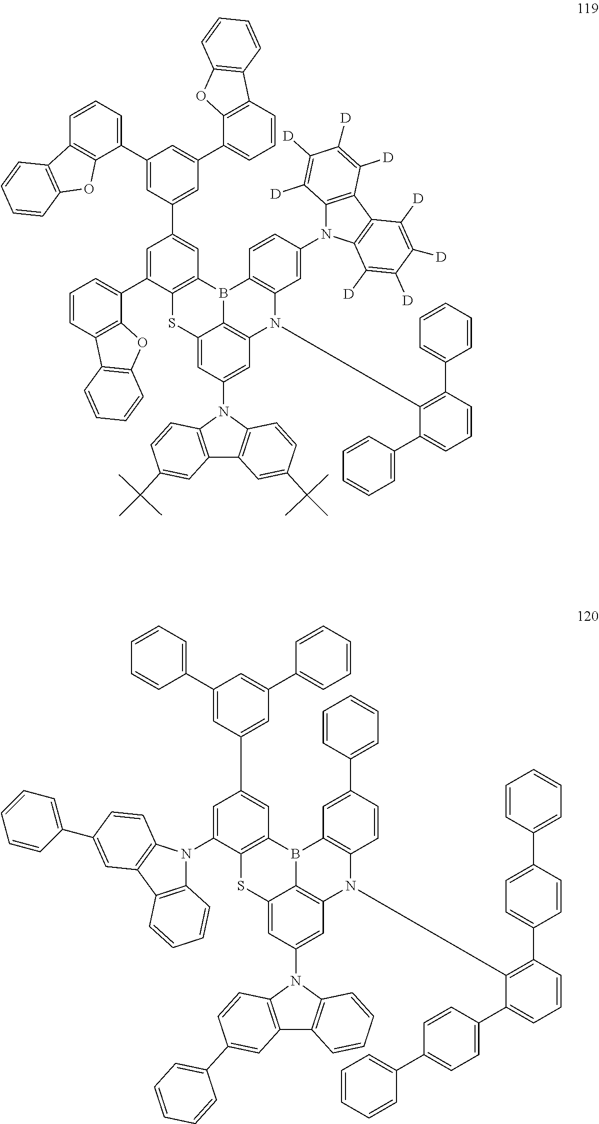 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-n3c4ccc(C(C)(C)C)cc4c4cc(C(C)(C)C)ccc43)cc3c1B2c1cc(-c2cc(-c4cccc5c4oc4ccccc45)cc(-c4cccc5c4oc4ccccc45)c2)cc(-c2cccc4c2oc2ccccc24)c1S3 ; c1ccc(-c2ccc(-c3cccc(-c4ccc(-c5ccccc5)cc4)c3N3c4ccc(-c5ccccc5)cc4B4c5cc(-c6cc(-c7ccccc7)cc(-c7ccccc7)c6)cc(-n6c7ccccc7c7cc(-c8ccccc8)ccc76)c5Sc5cc(-n6c7ccccc7c7cc(-c8ccccc8)ccc76)cc3c54)cc2)cc1] 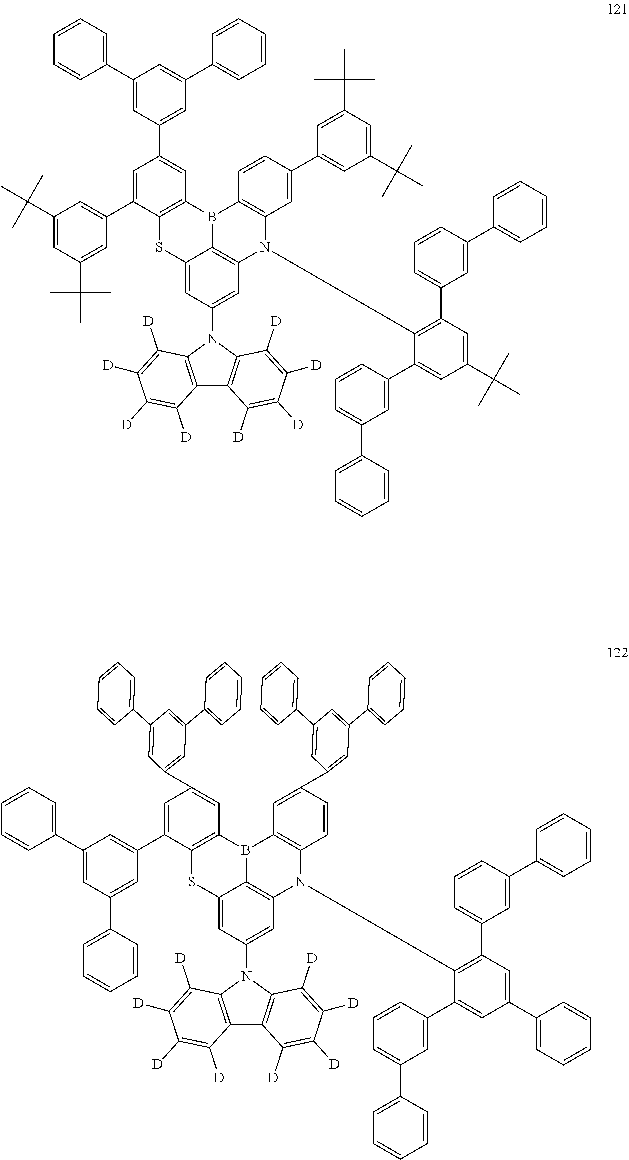 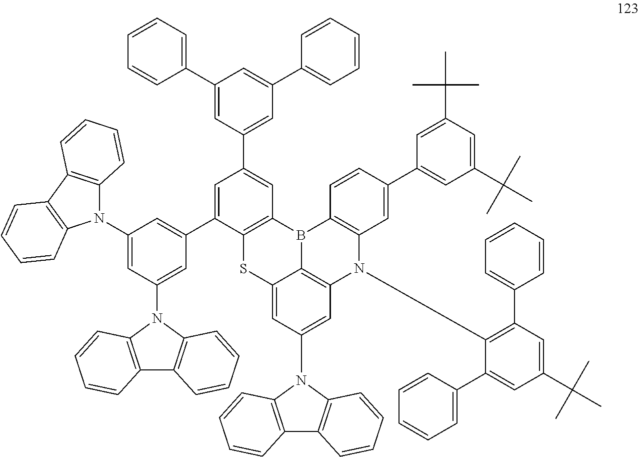 [SMILES: CC(C)(C)c1cc(-c2ccc3c(c2)N(c2c(-c4ccccc4)cc(C(C)(C)C)cc2-c2ccccc2)c2cc(-n4c5ccccc5c5ccccc54)cc4c2B3c2cc(-c3cc(-c5ccccc5)cc(-c5ccccc5)c3)cc(-c3cc(-n5c6ccccc6c6ccccc65)cc(-n5c6ccccc6c6ccccc65)c3)c2S4)cc(C(C)(C)C)c1]
wherein in Compound Group 1,
D represents a deuterium atom.

11. A fused polycyclic compound represented by Formula 1: 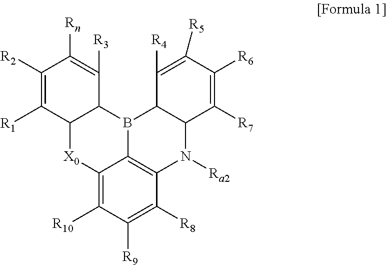
wherein in Formula 1,
Rₙ is a group represented by Formula 2,
X₀ is S or N(Rₐ₁),
Rₐ₁ and Rₐ₂ are each independently a group represented by Formula 3, and
R₁ to R₁₀ are each independently a hydrogen atom, a deuterium atom, a cyano group, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms; 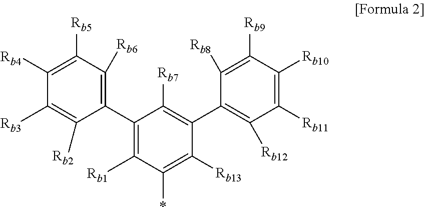
wherein in Formula 2,
R_{b1} to R_{b13} are each independently a hydrogen atom, a deuterium atom, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring, 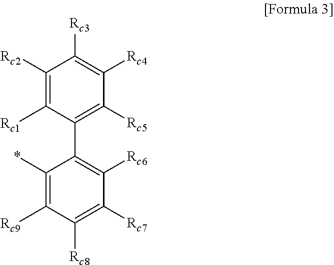
wherein in Formula 3,
R_{c1} to R_{c9} are each independently a hydrogen atom, a deuterium atom, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

12. The fused polycyclic compound of claim 11, wherein the fused polycyclic compound represented by Formula 1 is represented by Formula 1-1 or Formula 1-2: 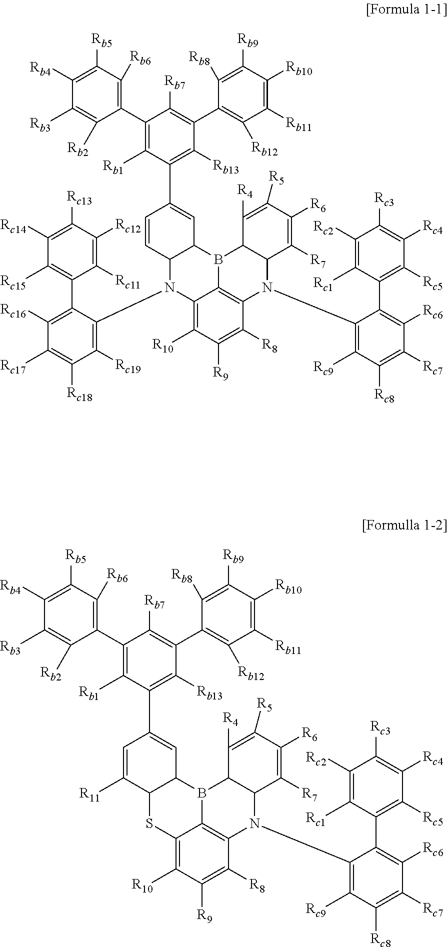
wherein in Formula 1-1,
R_{c11} to R_{c19} are each independently a hydrogen atom, a deuterium atom, a substituted or unsubstituted oxy group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms,
wherein in Formula 1-2,
R₁₁ is a hydrogen atom, a deuterium atom, a substituted or unsubstituted aryl group having 6 to 30 ring-forming carbon atoms, or a substituted or unsubstituted heteroaryl group having 2 to 30 ring-forming carbon atoms, and
wherein in Formula 1-1 and Formula 1-2,
R₄ to R₁₀, R_{b1} to R_{b13}, and R_{c1} to R_{c9} are the same as defined in Formula 1 to Formula 3.

13. The fused polycyclic compound of claim 12, wherein in Formula 1-2, R₁₁ is a substituted or unsubstituted phenyl group, a substituted or unsubstituted dibenzofuran group, or a substituted or unsubstituted carbazole group.

14. The fused polycyclic compound of claim 12, wherein in Formula 1-2, R₁₁ is a group represented by one of Formula R11-1 to Formula R11-13:

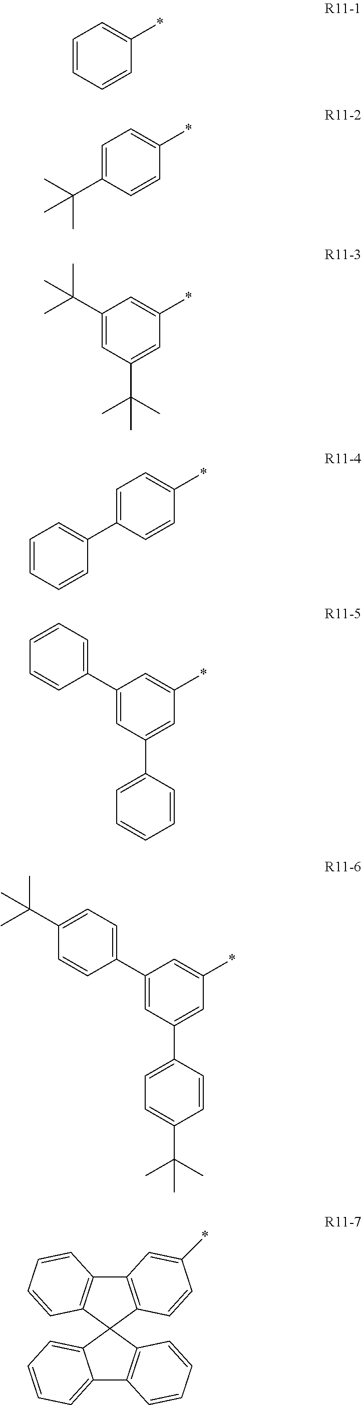

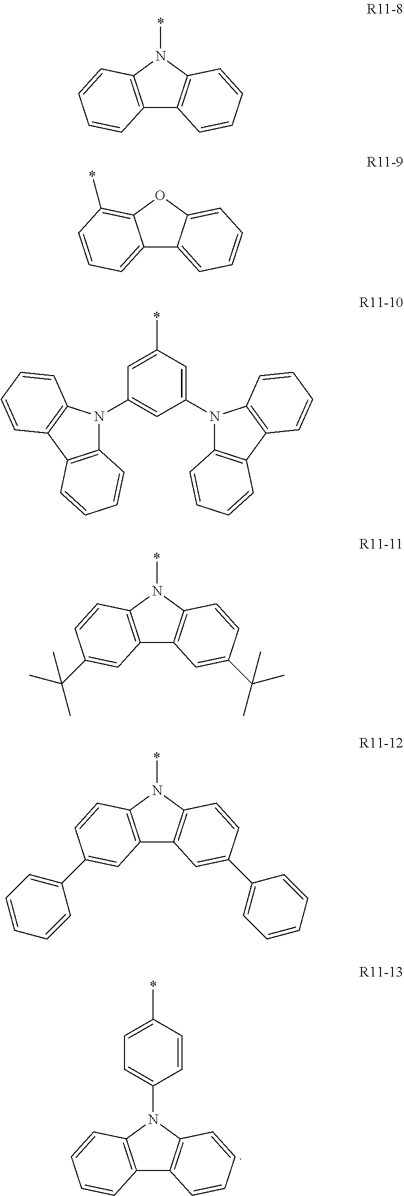 [SMILES: *n1c2ccccc2c2ccccc21 ; *c1cccc2c1oc1ccccc12 ; *c1cc(-n2c3ccccc3c3ccccc32)cc(-n2c3ccccc3c3ccccc32)c1 ; *n1c2ccc(C(C)(C)C)cc2c2cc(C(C)(C)C)ccc21 ; *n1c2ccc(-c3ccccc3)cc2c2cc(-c3ccccc3)ccc21 ; *c1ccc(-n2c3ccccc3c3ccccc32)cc1]

15. The fused polycyclic compound of claim 11, wherein the fused polycyclic compound represented by Formula 1 is represented by Formula 1-A or Formula 1-B: 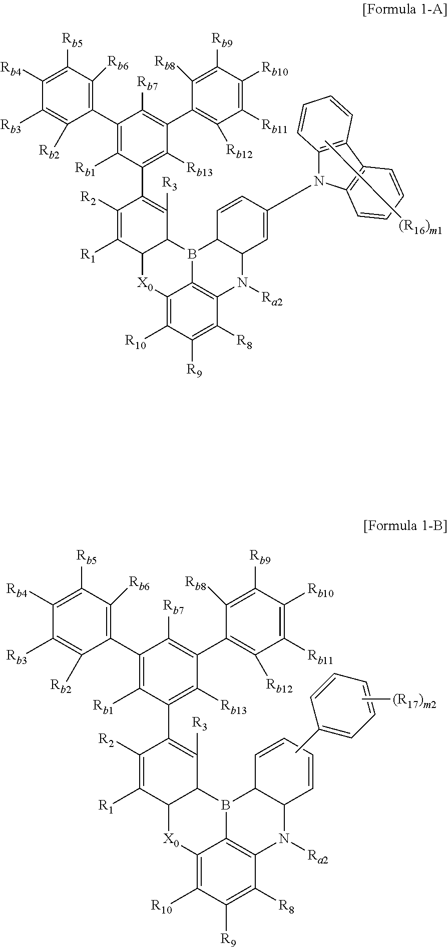
wherein in Formula 1-A,
m1 is an integer from 0 to 8, and
R₁₆ is a hydrogen atom, a deuterium atom, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring,
wherein in Formula 1-B,
m2 is an integer from 0 to 5, and
R₁₇ is a hydrogen atom, a deuterium atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and
wherein in Formula 1-A and Formula 1-B,
R₁ to R₃, R₈ to R₁₀, R_{b1} to R_{b13}, X₀, and Rₐ₂ are the same as defined in Formula 1 and Formula 2.

16. The fused polycyclic compound of claim 11, wherein the group represented by Formula 2 is a group represented by one of Formula 2-1 to Formula 2-6:

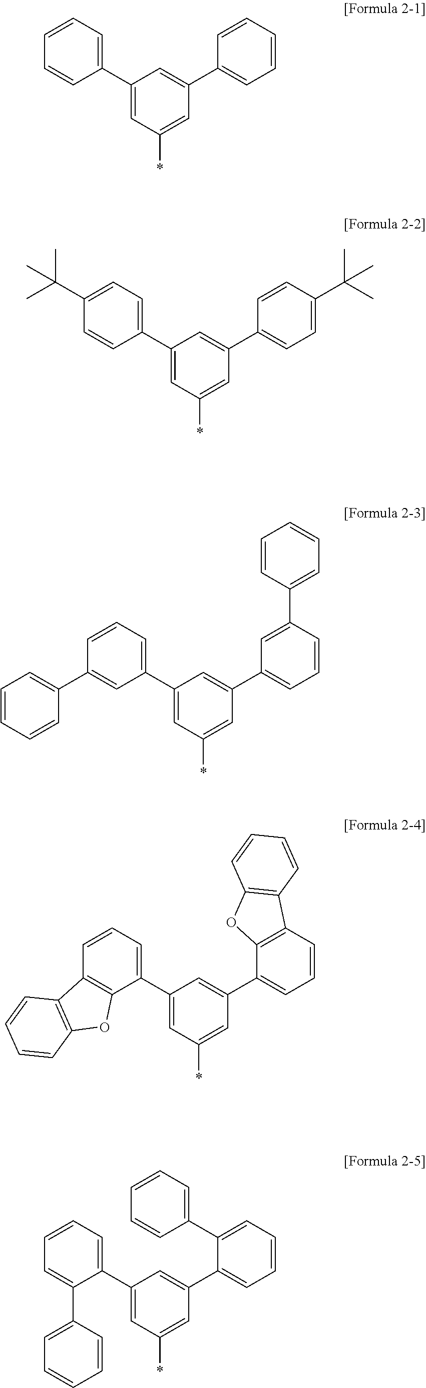 [SMILES: *c1cc(-c2ccccc2)cc(-c2ccccc2)c1 ; *c1cc(-c2ccc(C(C)(C)C)cc2)cc(-c2ccc(C(C)(C)C)cc2)c1 ; *c1cc(-c2cccc(-c3ccccc3)c2)cc(-c2cccc(-c3ccccc3)c2)c1 ; *c1cc(-c2cccc3c2oc2ccccc23)cc(-c2cccc3c2oc2ccccc23)c1 ; *c1cc(-c2ccccc2-c2ccccc2)cc(-c2ccccc2-c2ccccc2)c1]

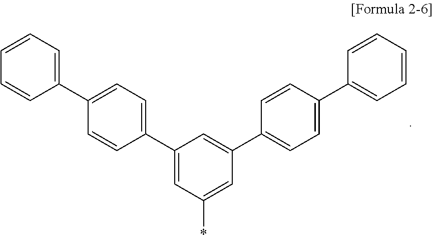 [SMILES: *c1cc(-c2ccc(-c3ccccc3)cc2)cc(-c2ccc(-c3ccccc3)cc2)c1]

17. The fused polycyclic compound of claim 11, wherein the group represented by Formula 3 is a group represented by one of Formula 3-1 to Formula 3-18:

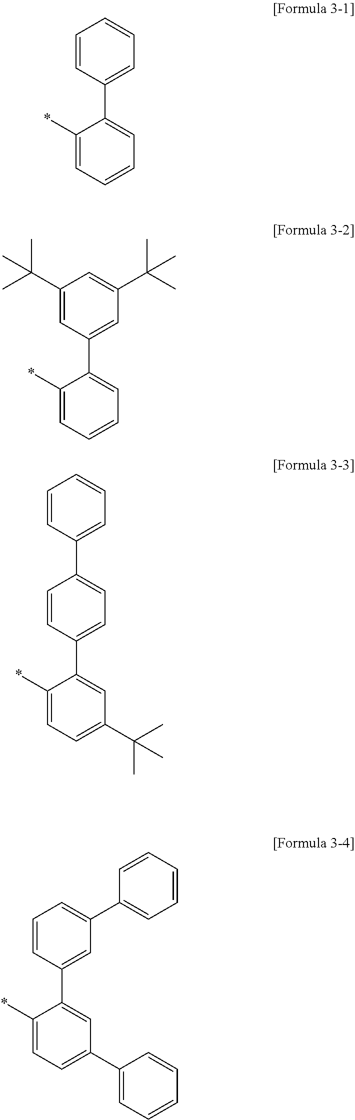

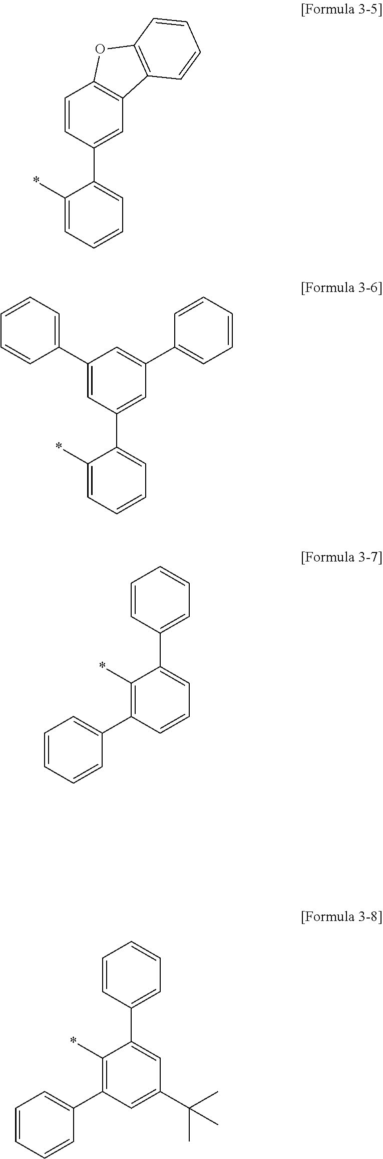 [SMILES: *c1ccccc1-c1ccc2oc3ccccc3c2c1 ; *c1ccccc1-c1cc(-c2ccccc2)cc(-c2ccccc2)c1 ; *c1c(-c2ccccc2)cccc1-c1ccccc1 ; *c1c(-c2ccccc2)cc(C(C)(C)C)cc1-c1ccccc1]

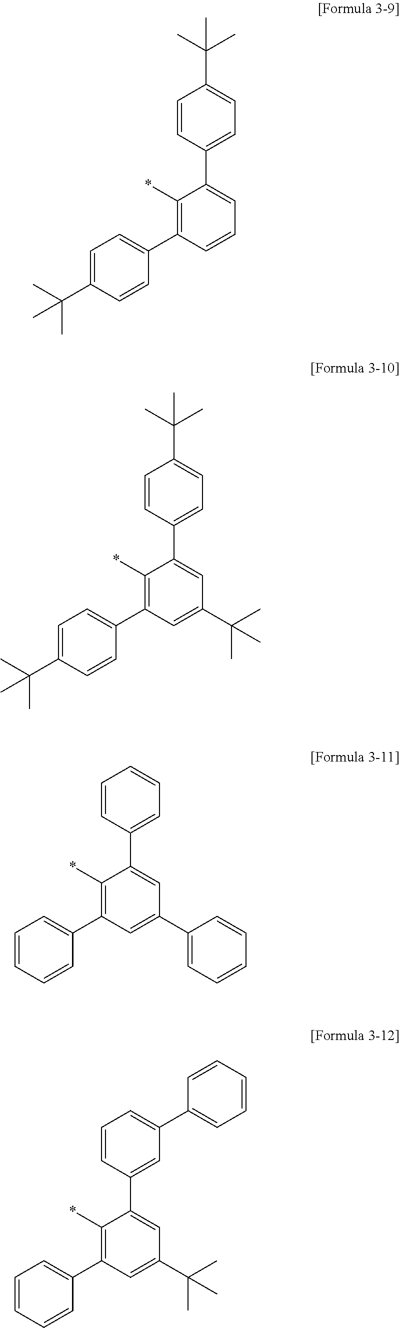

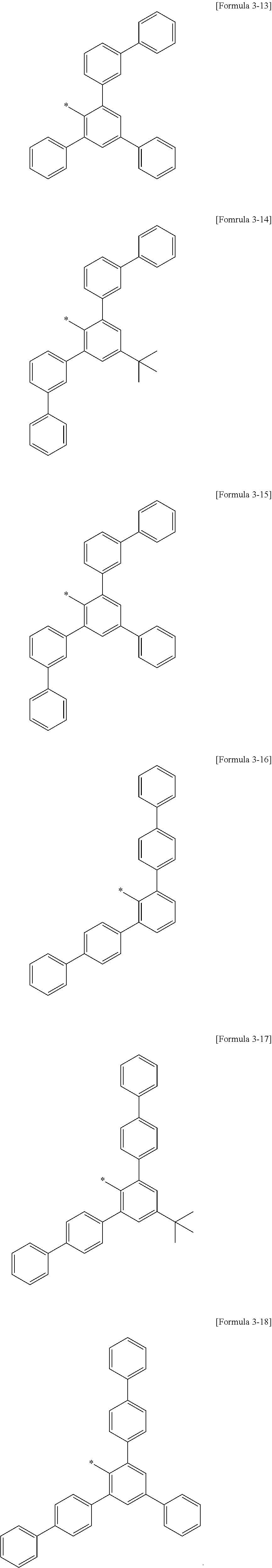 [SMILES: *c1c(-c2ccccc2)cc(-c2ccccc2)cc1-c1cccc(-c2ccccc2)c1 ; *c1c(-c2cccc(-c3ccccc3)c2)cc(C(C)(C)C)cc1-c1cccc(-c2ccccc2)c1 ; *c1c(-c2cccc(-c3ccccc3)c2)cc(-c2ccccc2)cc1-c1cccc(-c2ccccc2)c1 ; *c1c(-c2ccc(-c3ccccc3)cc2)cccc1-c1ccc(-c2ccccc2)cc1 ; *c1c(-c2ccc(-c3ccccc3)cc2)cc(C(C)(C)C)cc1-c1ccc(-c2ccccc2)cc1 ; *c1c(-c2ccc(-c3ccccc3)cc2)cc(-c2ccccc2)cc1-c1ccc(-c2ccccc2)cc1]

18. The fused polycyclic compound of claim 11, wherein in Formula 1, R₉ is a group represented by one of Formula R9-1 to Formula R9-18: 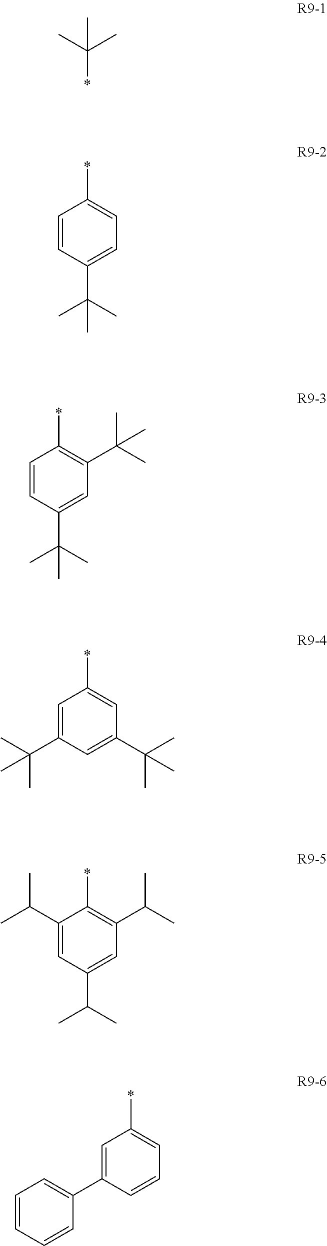 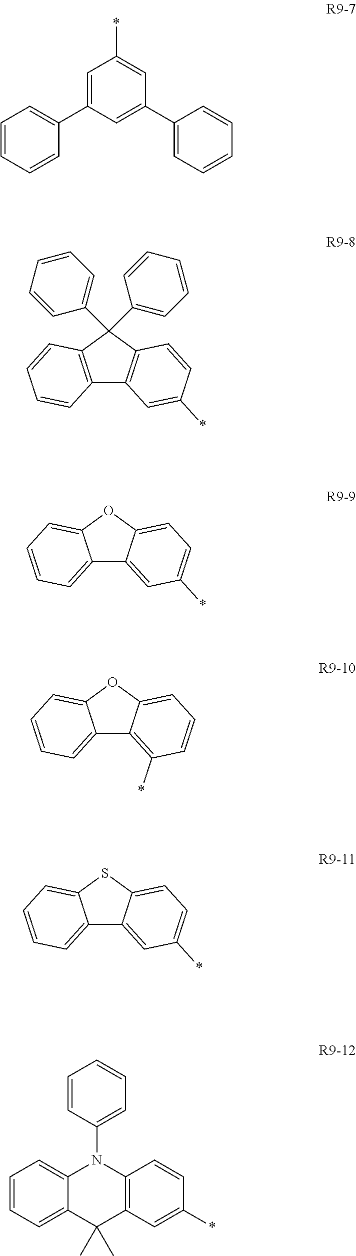 [SMILES: *c1cc(-c2ccccc2)cc(-c2ccccc2)c1 ; *c1ccc2c(c1)-c1ccccc1C2(c1ccccc1)c1ccccc1 ; *c1ccc2oc3ccccc3c2c1 ; *c1cccc2oc3ccccc3c12 ; *c1ccc2sc3ccccc3c2c1 ; *c1ccc2c(c1)C(C)(C)c1ccccc1N2c1ccccc1] 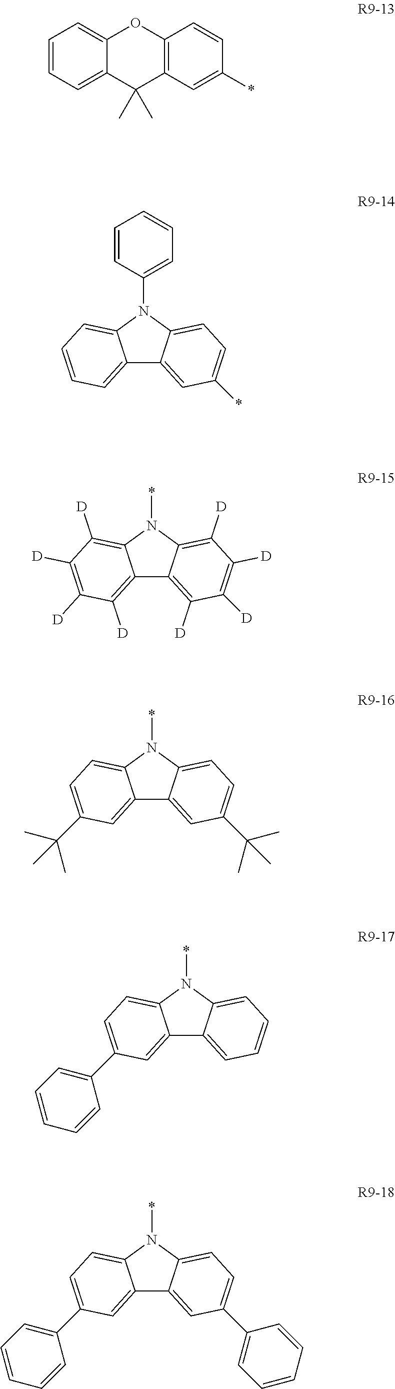 [SMILES: *c1ccc2c(c1)C(C)(C)c1ccccc1O2 ; *c1ccc2c(c1)c1ccccc1n2-c1ccccc1 ; *n1c2c([2H])c([2H])c([2H])c([2H])c2c2c([2H])c([2H])c([2H])c([2H])c21 ; *n1c2ccc(C(C)(C)C)cc2c2cc(C(C)(C)C)ccc21 ; *n1c2ccccc2c2cc(-c3ccccc3)ccc21 ; *n1c2ccc(-c3ccccc3)cc2c2cc(-c3ccccc3)ccc21]
wherein in Formula R9-15,
D represents a deuterium atom.

19. The fused polycyclic compound of claim 11, wherein the fused polycyclic compound represented by Formula 1 is selected from Compound Group 1: 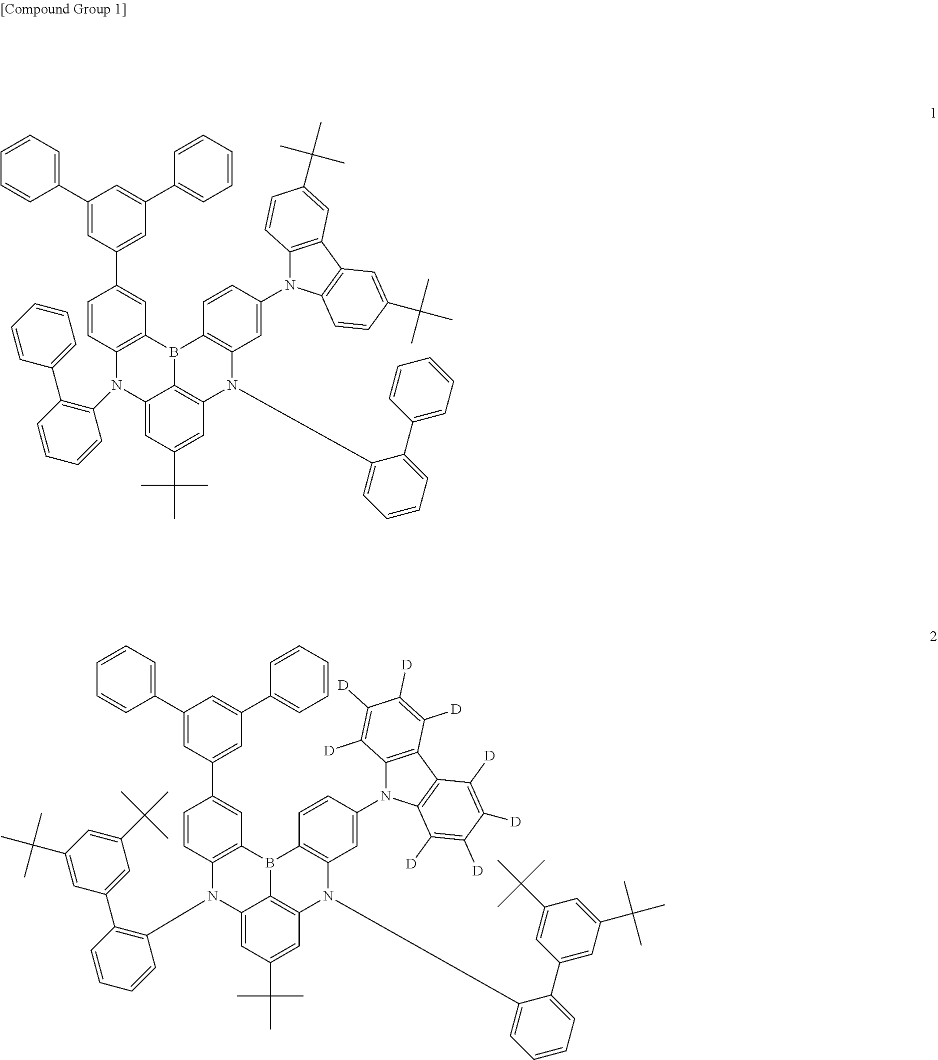 [SMILES: CC(C)(C)c1cc2c3c(c1)N(c1ccccc1-c1ccccc1)c1cc(-n4c5ccc(C(C)(C)C)cc5c5cc(C(C)(C)C)ccc54)ccc1B3c1cc(-c3cc(-c4ccccc4)cc(-c4ccccc4)c3)ccc1N2c1ccccc1-c1ccccc1 ; [2H]c1c([2H])c([2H])c2c(c1[2H])c1c([2H])c([2H])c([2H])c([2H])c1n2-c1ccc2c(c1)N(c1ccccc1-c1cc(C(C)(C)C)cc(C(C)(C)C)c1)c1cc(C(C)(C)C)cc3c1B2c1cc(-c2cc(-c4ccccc4)cc(-c4ccccc4)c2)ccc1N3c1ccccc1-c1cc(C(C)(C)C)cc(C(C)(C)C)c1] 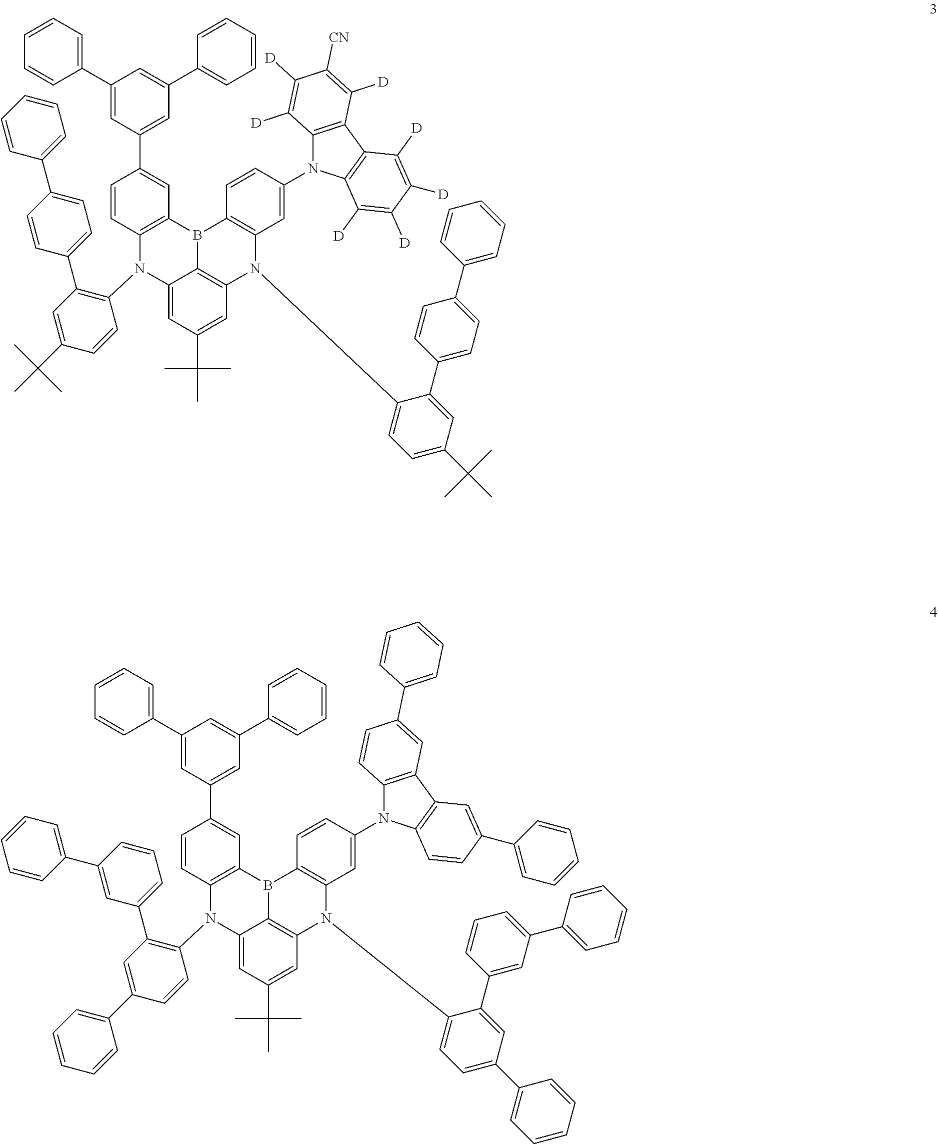 [SMILES: [2H]c1c([2H])c([2H])c2c(c1[2H])c1c([2H])c(C#N)c([2H])c([2H])c1n2-c1ccc2c(c1)N(c1ccc(C(C)(C)C)cc1-c1ccc(-c3ccccc3)cc1)c1cc(C(C)(C)C)cc3c1B2c1cc(-c2cc(-c4ccccc4)cc(-c4ccccc4)c2)ccc1N3c1ccc(C(C)(C)C)cc1-c1ccc(-c2ccccc2)cc1 ; CC(C)(C)c1cc2c3c(c1)N(c1ccc(-c4ccccc4)cc1-c1cccc(-c4ccccc4)c1)c1cc(-n4c5ccc(-c6ccccc6)cc5c5cc(-c6ccccc6)ccc54)ccc1B3c1cc(-c3cc(-c4ccccc4)cc(-c4ccccc4)c3)ccc1N2c1ccc(-c2ccccc2)cc1-c1cccc(-c2ccccc2)c1] 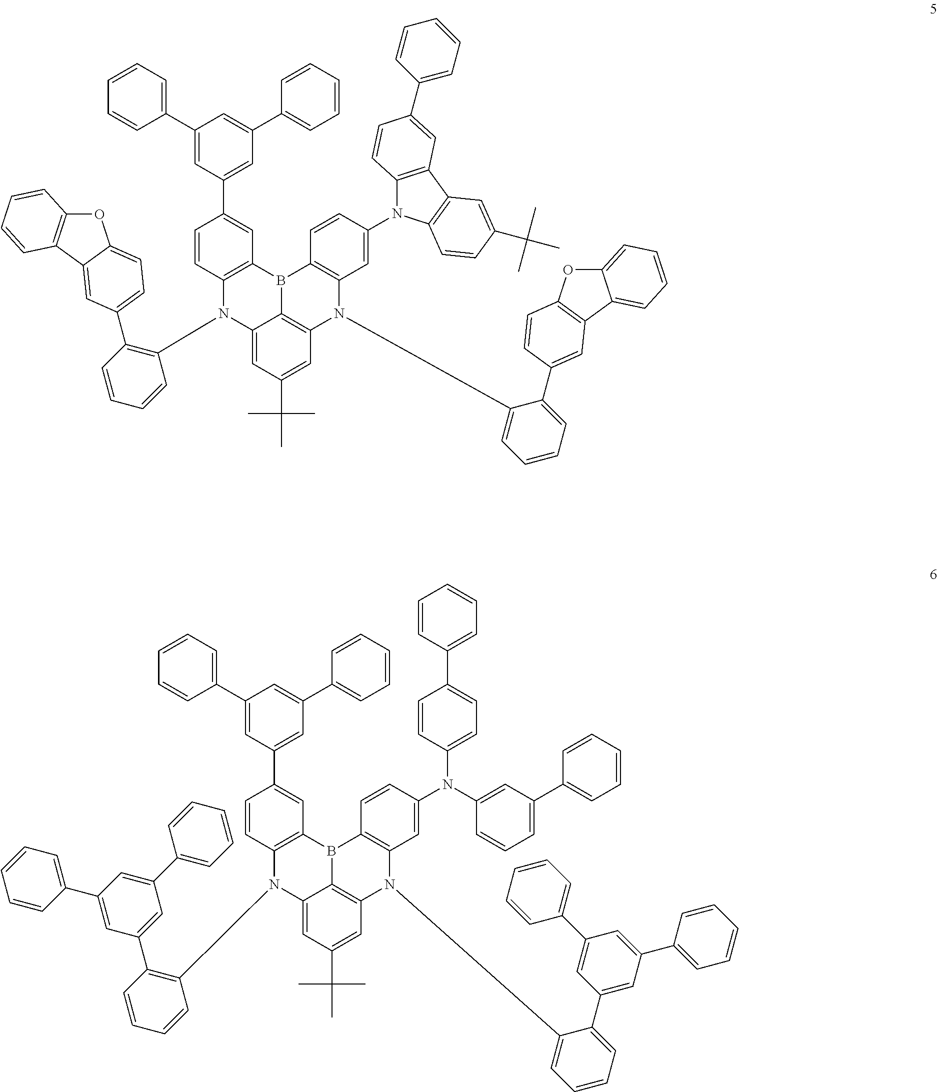 [SMILES: CC(C)(C)c1cc2c3c(c1)N(c1ccccc1-c1ccc4oc5ccccc5c4c1)c1cc(-n4c5ccc(-c6ccccc6)cc5c5cc(C(C)(C)C)ccc54)ccc1B3c1cc(-c3cc(-c4ccccc4)cc(-c4ccccc4)c3)ccc1N2c1ccccc1-c1ccc2oc3ccccc3c2c1 ; CC(C)(C)c1cc2c3c(c1)N(c1ccccc1-c1cc(-c4ccccc4)cc(-c4ccccc4)c1)c1cc(N(c4ccc(-c5ccccc5)cc4)c4cccc(-c5ccccc5)c4)ccc1B3c1cc(-c3cc(-c4ccccc4)cc(-c4ccccc4)c3)ccc1N2c1ccccc1-c1cc(-c2ccccc2)cc(-c2ccccc2)c1] 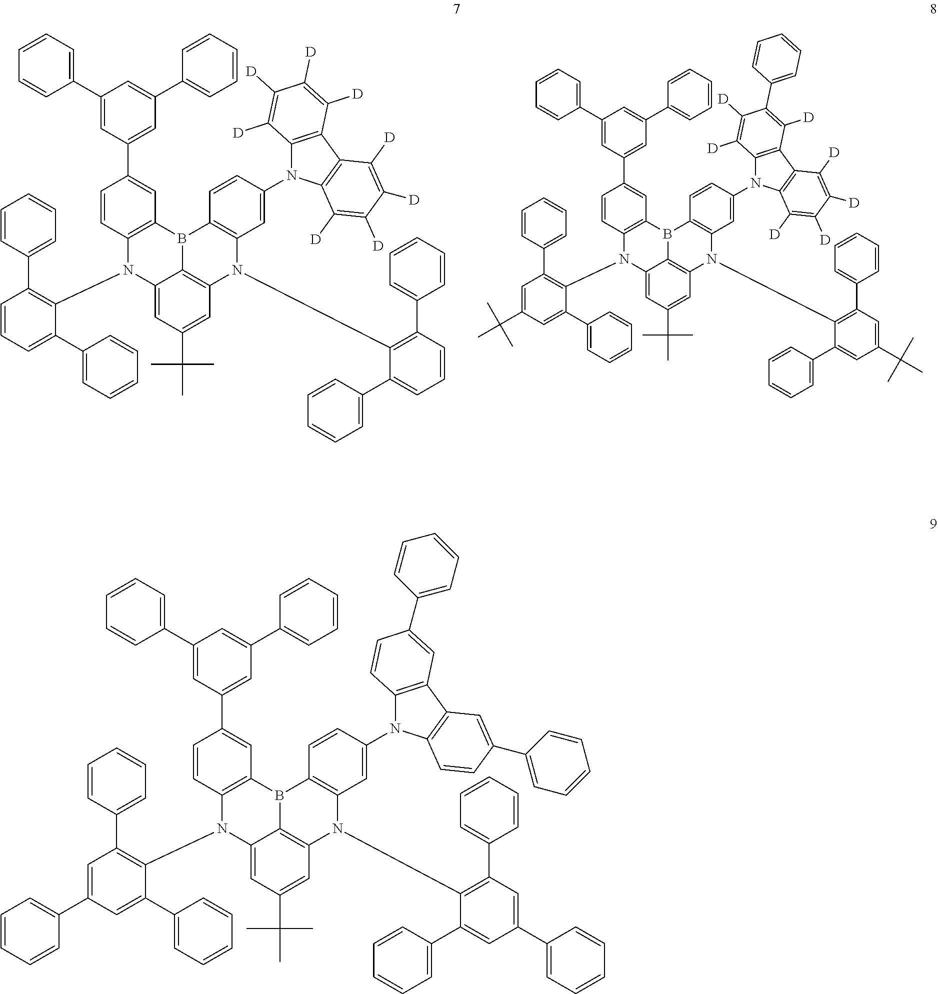 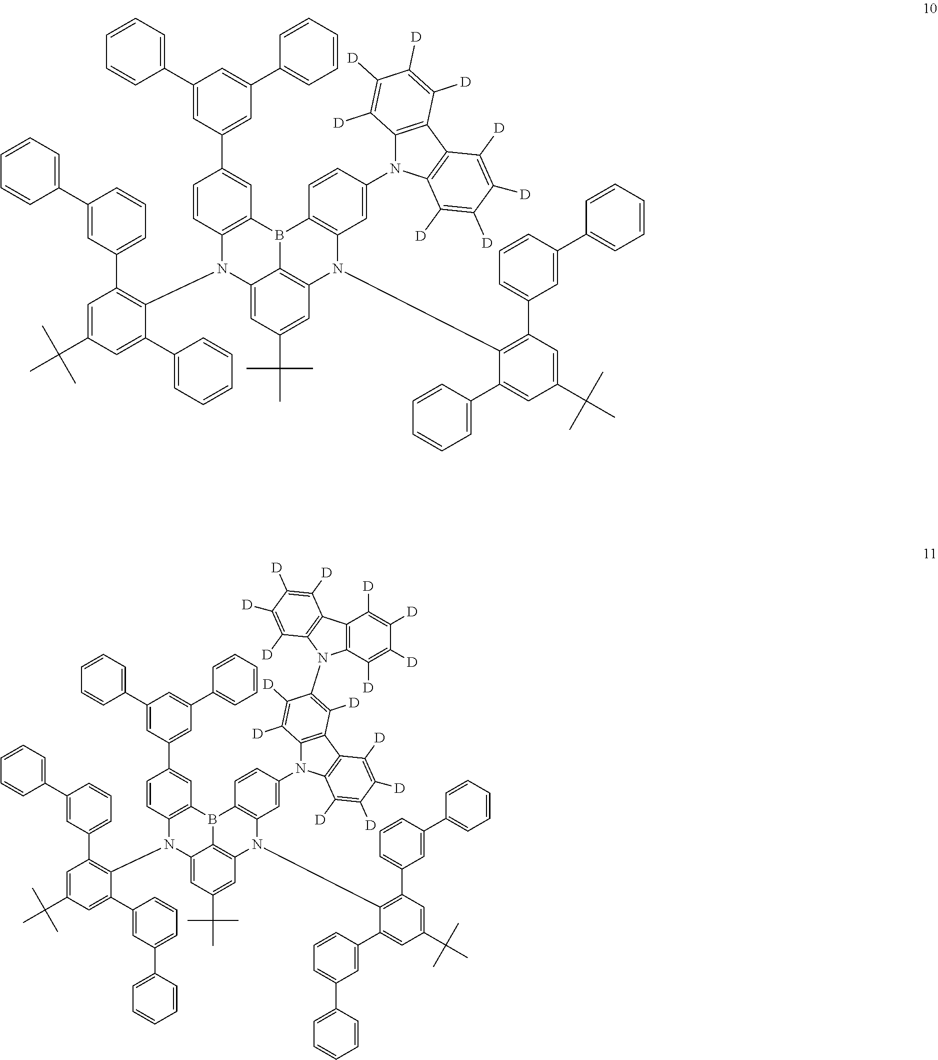 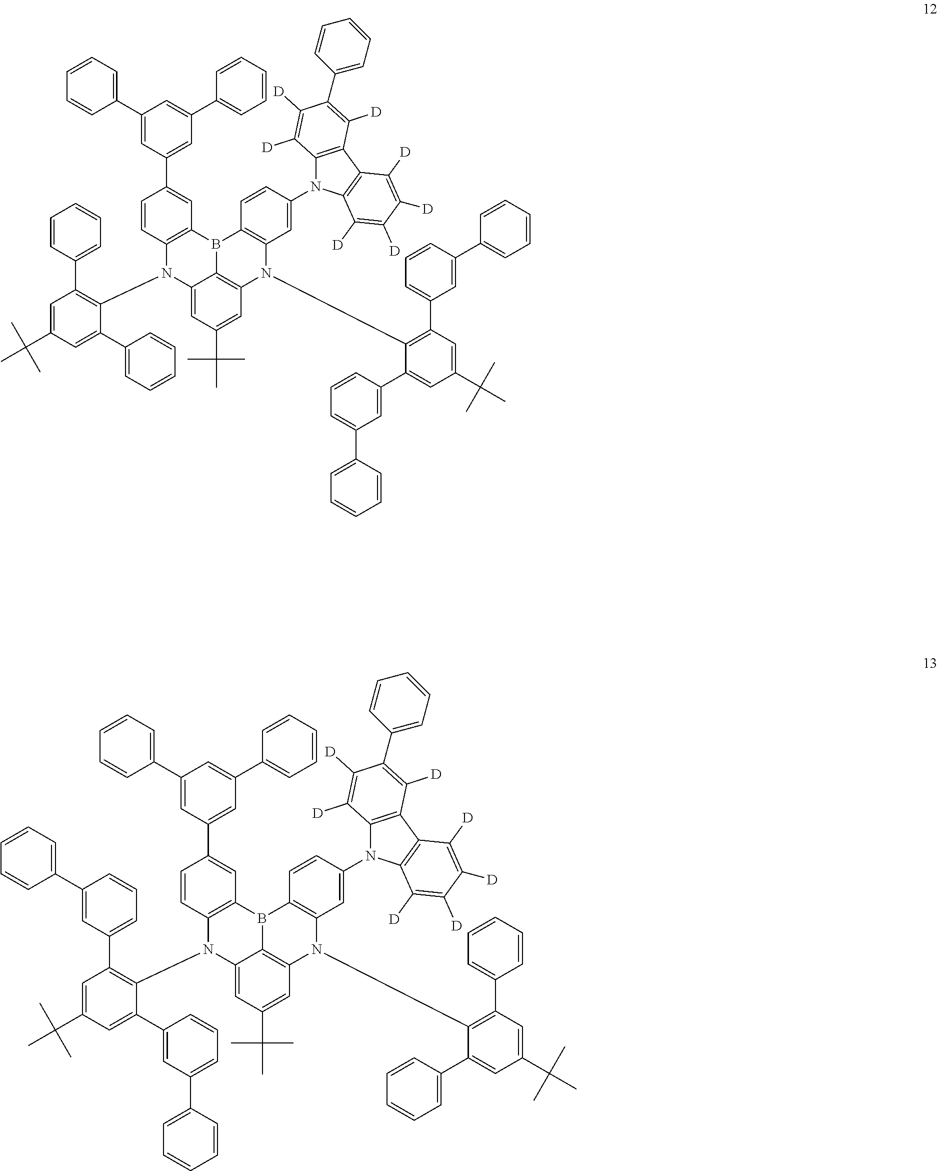 [SMILES: [2H]c1c([2H])c([2H])c2c(c1[2H])c1c([2H])c(-c3ccccc3)c([2H])c([2H])c1n2-c1ccc2c(c1)N(c1c(-c3cccc(-c4ccccc4)c3)cc(C(C)(C)C)cc1-c1cccc(-c3ccccc3)c1)c1cc(C(C)(C)C)cc3c1B2c1cc(-c2cc(-c4ccccc4)cc(-c4ccccc4)c2)ccc1N3c1c(-c2ccccc2)cc(C(C)(C)C)cc1-c1ccccc1 ; [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cc(-c4ccccc4)cc(-c4ccccc4)c2)ccc1N3c1c(-c2cccc(-c3ccccc3)c2)cc(C(C)(C)C)cc1-c1cccc(-c2ccccc2)c1] 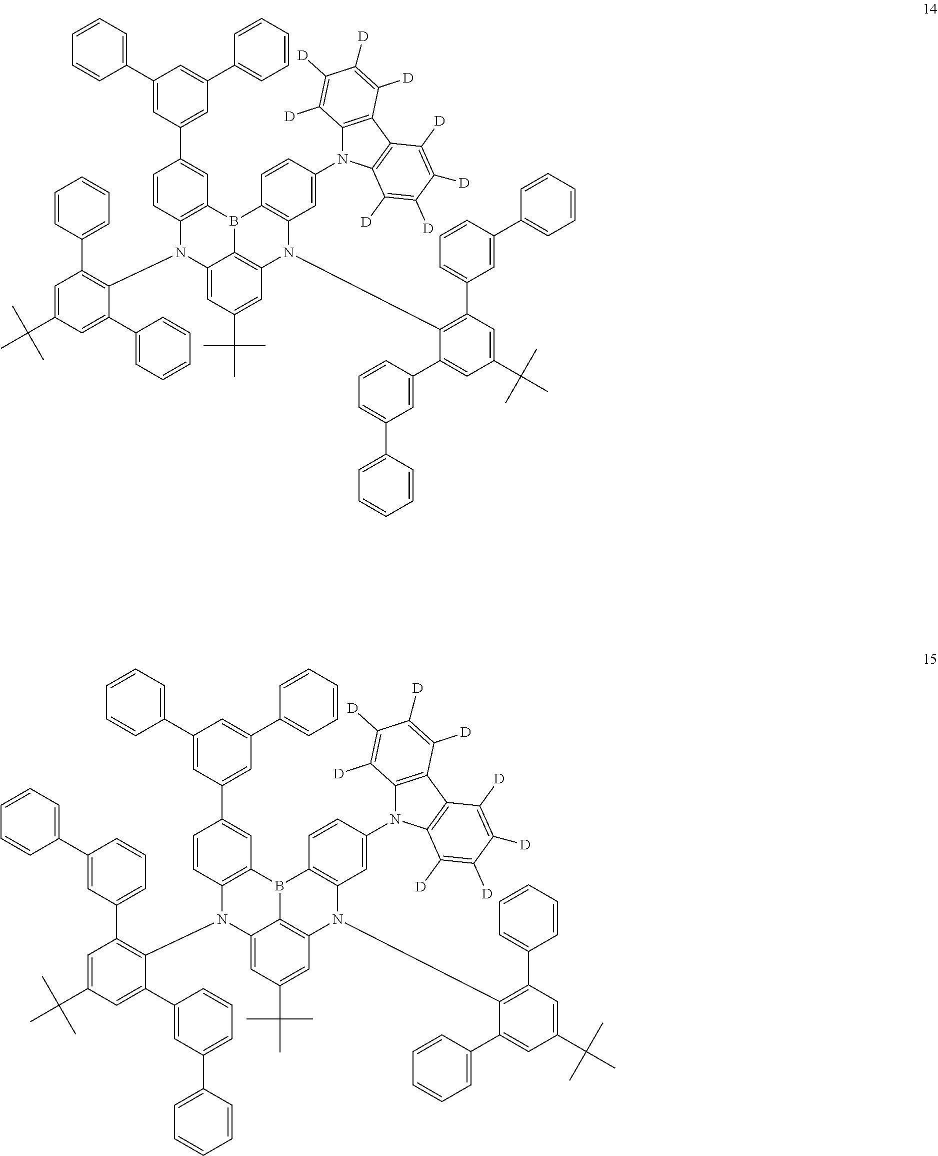 [SMILES: [2H]c1c([2H])c([2H])c2c(c1[2H])c1c([2H])c([2H])c([2H])c([2H])c1n2-c1ccc2c(c1)N(c1c(-c3cccc(-c4ccccc4)c3)cc(C(C)(C)C)cc1-c1cccc(-c3ccccc3)c1)c1cc(C(C)(C)C)cc3c1B2c1cc(-c2cc(-c4ccccc4)cc(-c4ccccc4)c2)ccc1N3c1c(-c2ccccc2)cc(C(C)(C)C)cc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cc(-c4ccccc4)cc(-c4ccccc4)c2)ccc1N3c1c(-c2cccc(-c3ccccc3)c2)cc(C(C)(C)C)cc1-c1cccc(-c2ccccc2)c1] 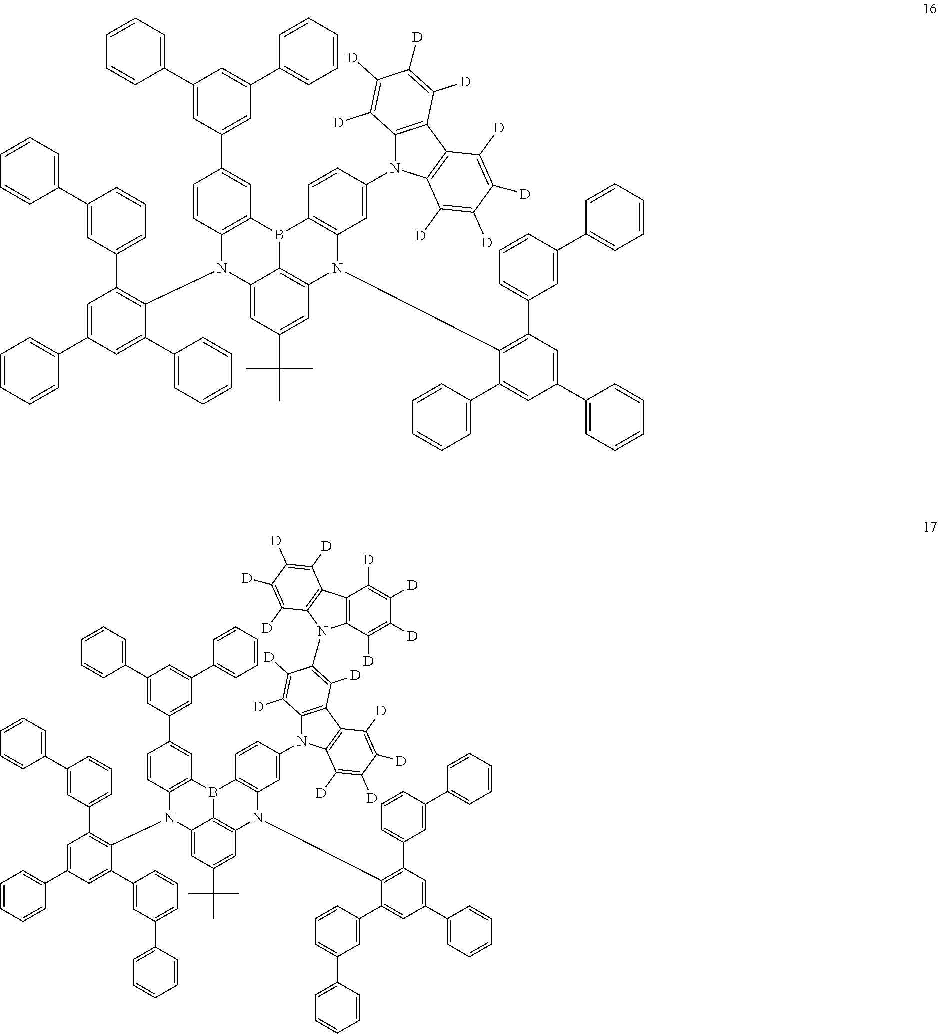 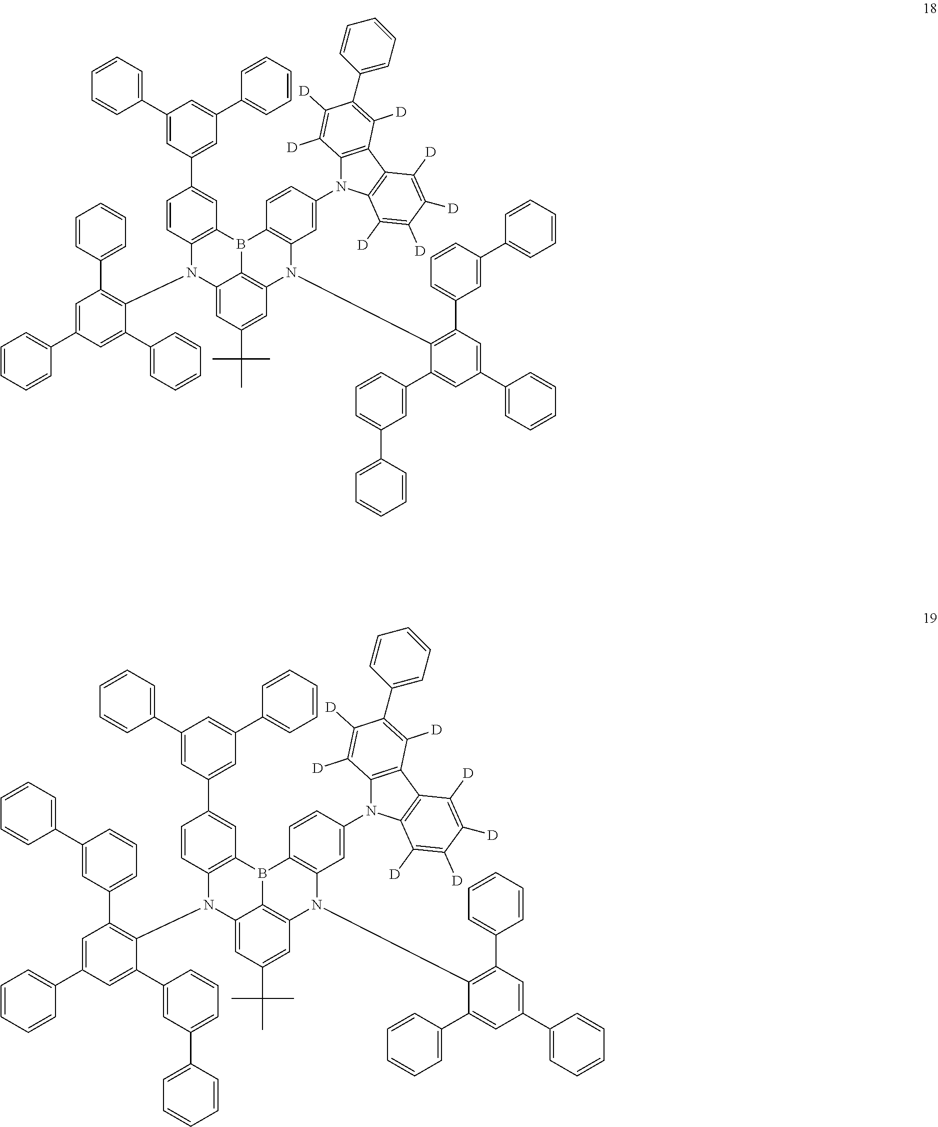 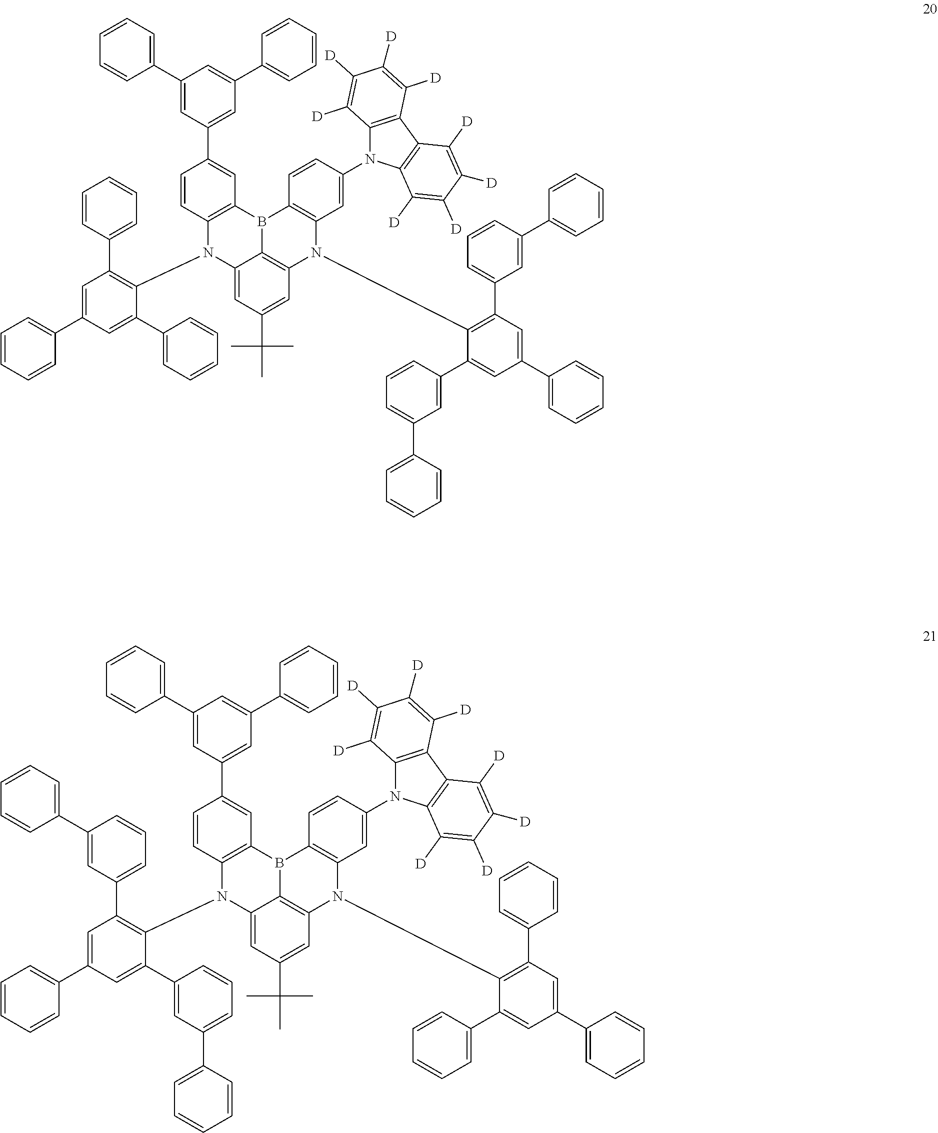 [SMILES: [2H]c1c([2H])c([2H])c2c(c1[2H])c1c([2H])c([2H])c([2H])c([2H])c1n2-c1ccc2c(c1)N(c1c(-c3cccc(-c4ccccc4)c3)cc(-c3ccccc3)cc1-c1cccc(-c3ccccc3)c1)c1cc(C(C)(C)C)cc3c1B2c1cc(-c2cc(-c4ccccc4)cc(-c4ccccc4)c2)ccc1N3c1c(-c2ccccc2)cc(-c2ccccc2)cc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1ccccc1)c1cc(C(C)(C)C)cc3c1B2c1cc(-c2cc(-c4ccccc4)cc(-c4ccccc4)c2)ccc1N3c1c(-c2cccc(-c3ccccc3)c2)cc(-c2ccccc2)cc1-c1cccc(-c2ccccc2)c1] 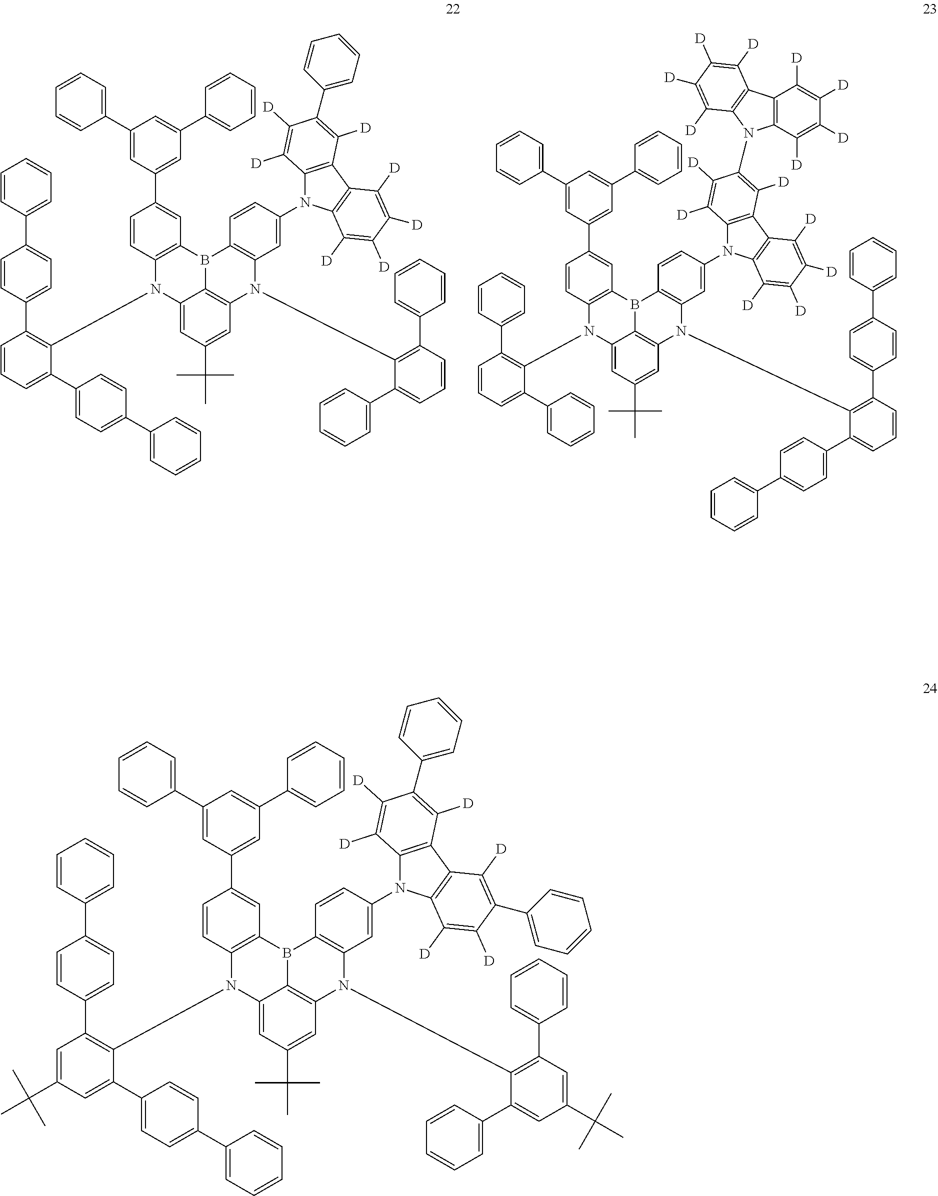 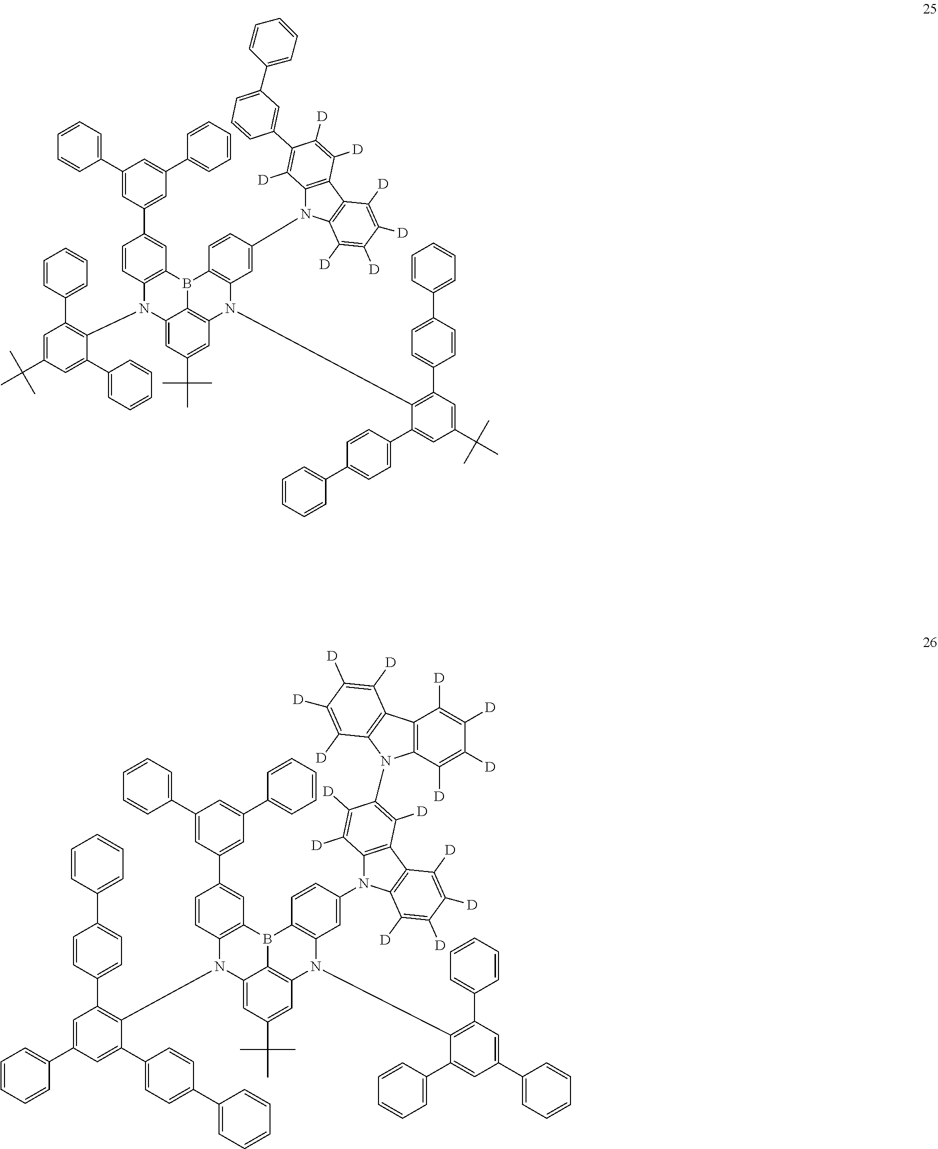 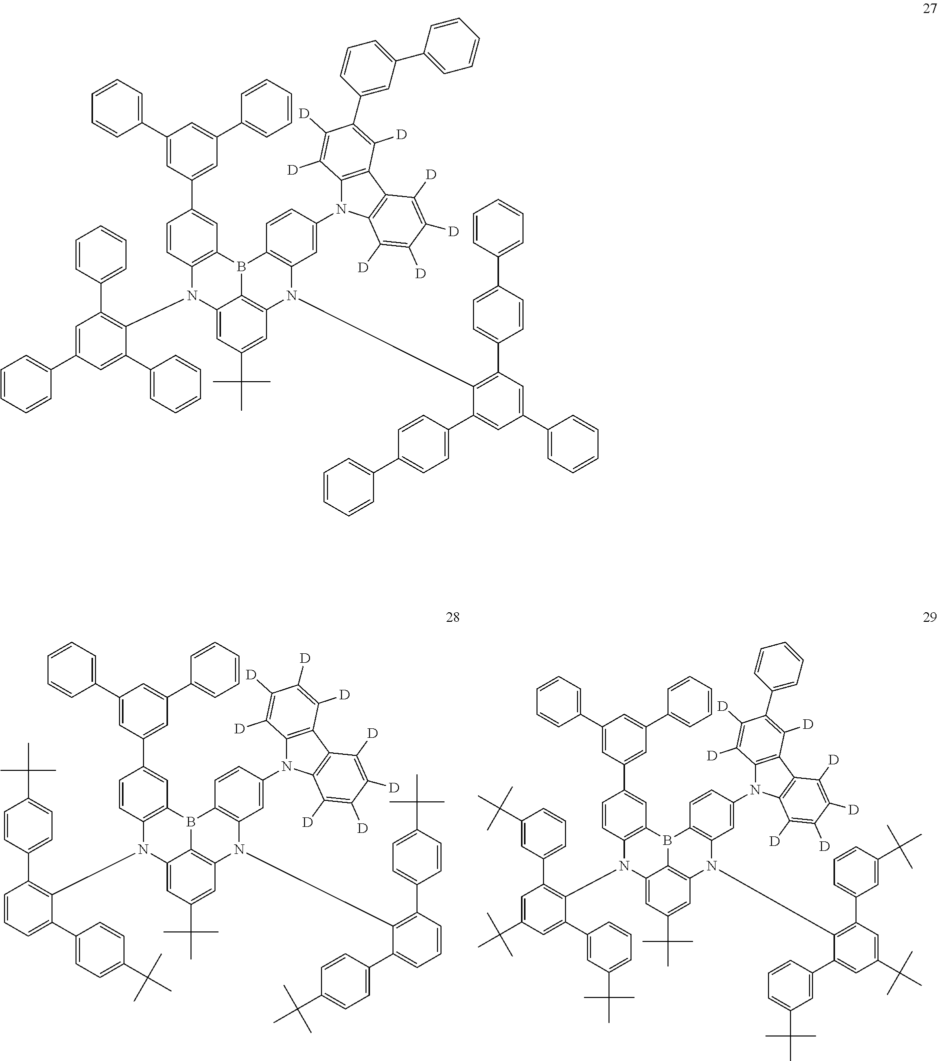 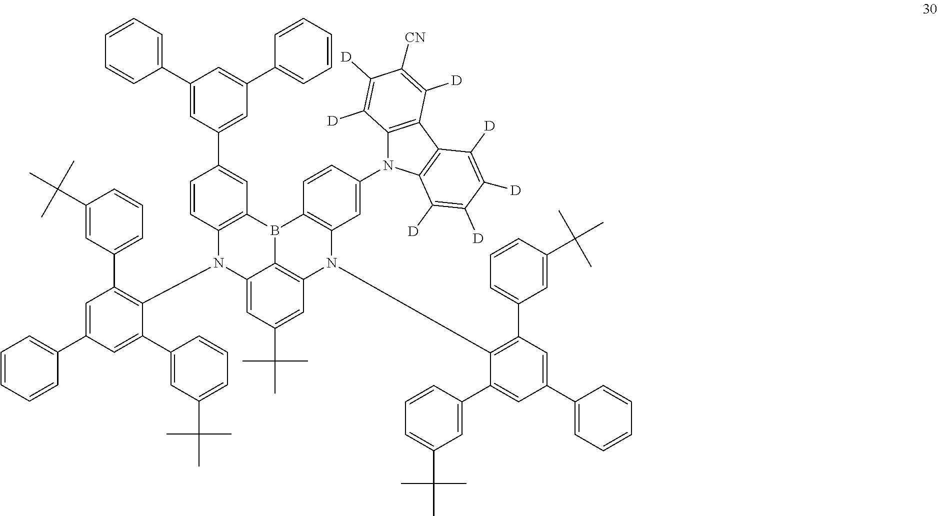 [SMILES: [2H]c1c([2H])c([2H])c2c(c1[2H])c1c([2H])c(C#N)c([2H])c([2H])c1n2-c1ccc2c(c1)N(c1c(-c3cccc(C(C)(C)C)c3)cc(-c3ccccc3)cc1-c1cccc(C(C)(C)C)c1)c1cc(C(C)(C)C)cc3c1B2c1cc(-c2cc(-c4ccccc4)cc(-c4ccccc4)c2)ccc1N3c1c(-c2cccc(C(C)(C)C)c2)cc(-c2ccccc2)cc1-c1cccc(C(C)(C)C)c1] 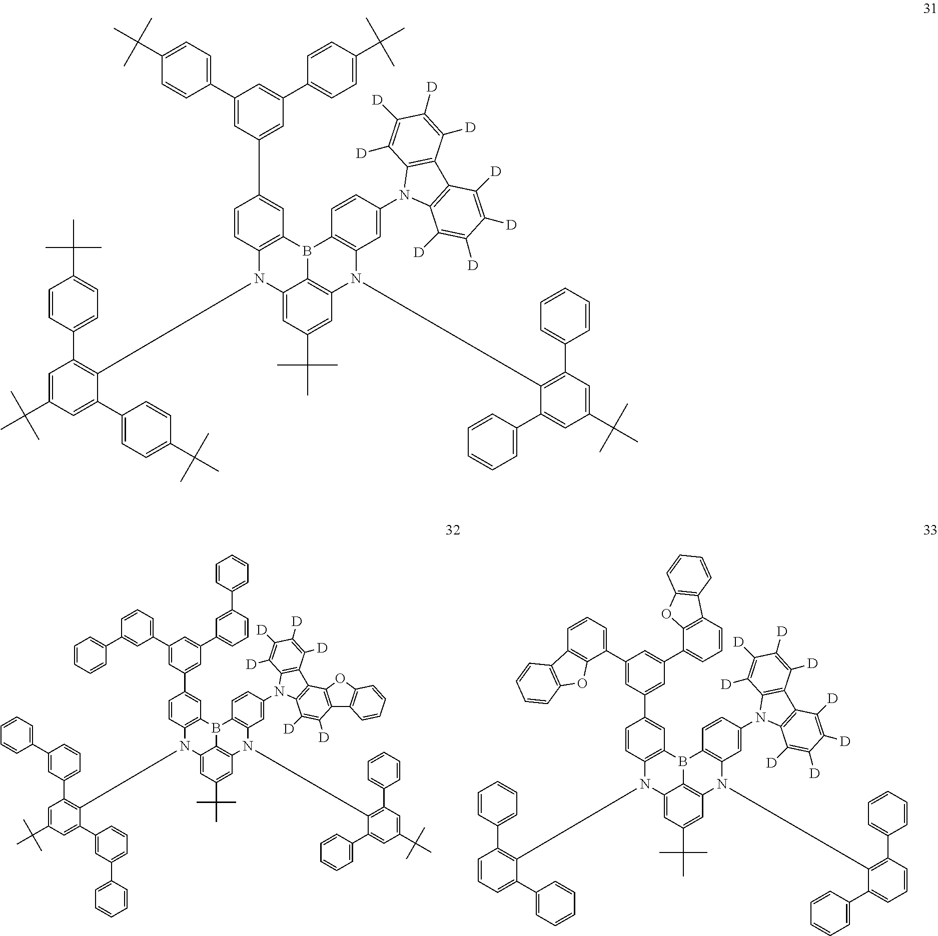 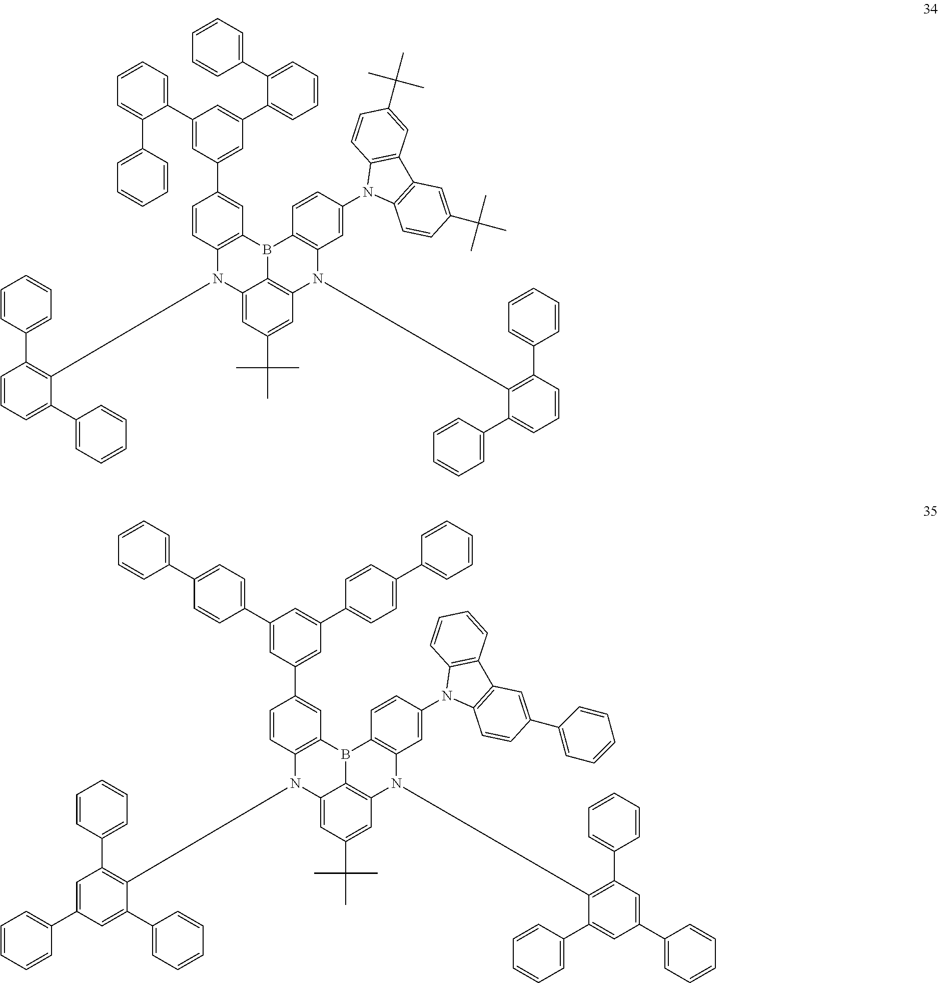 [SMILES: CC(C)(C)c1cc2c3c(c1)N(c1c(-c4ccccc4)cccc1-c1ccccc1)c1cc(-n4c5ccc(C(C)(C)C)cc5c5cc(C(C)(C)C)ccc54)ccc1B3c1cc(-c3cc(-c4ccccc4-c4ccccc4)cc(-c4ccccc4-c4ccccc4)c3)ccc1N2c1c(-c2ccccc2)cccc1-c1ccccc1 ; CC(C)(C)c1cc2c3c(c1)N(c1c(-c4ccccc4)cc(-c4ccccc4)cc1-c1ccccc1)c1cc(-n4c5ccccc5c5cc(-c6ccccc6)ccc54)ccc1B3c1cc(-c3cc(-c4ccc(-c5ccccc5)cc4)cc(-c4ccc(-c5ccccc5)cc4)c3)ccc1N2c1c(-c2ccccc2)cc(-c2ccccc2)cc1-c1ccccc1] 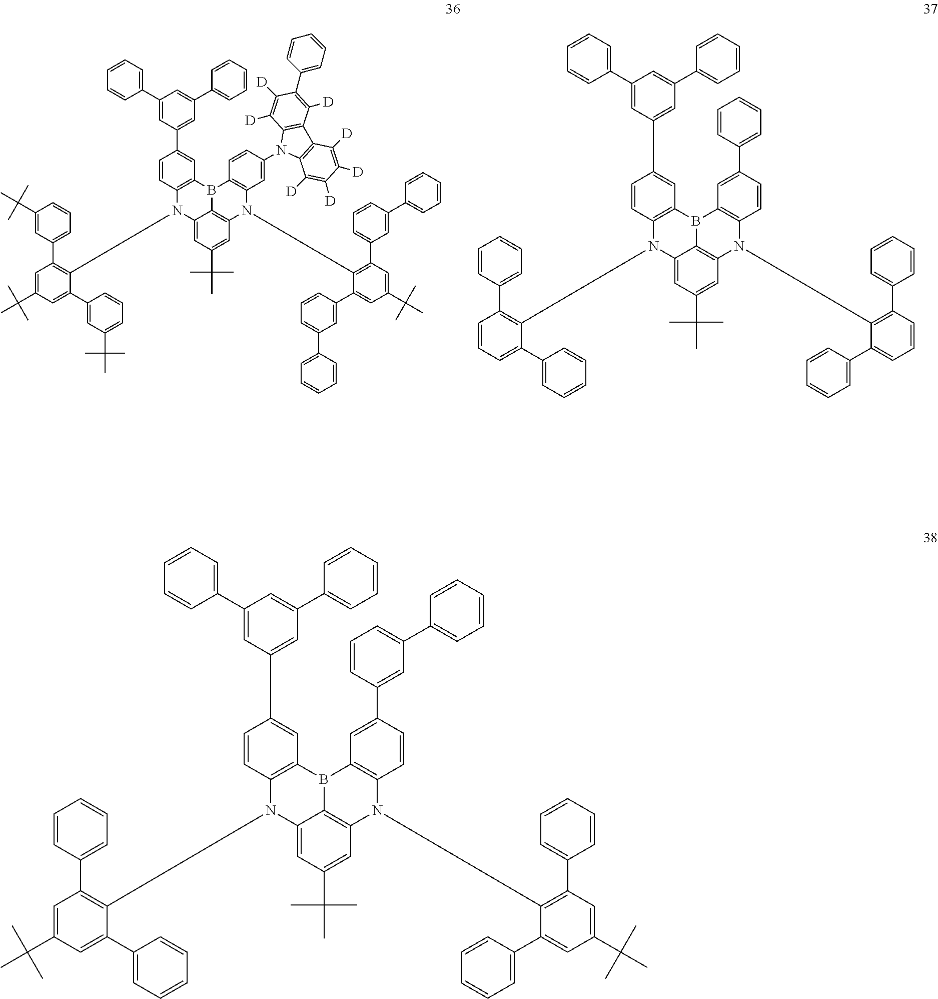 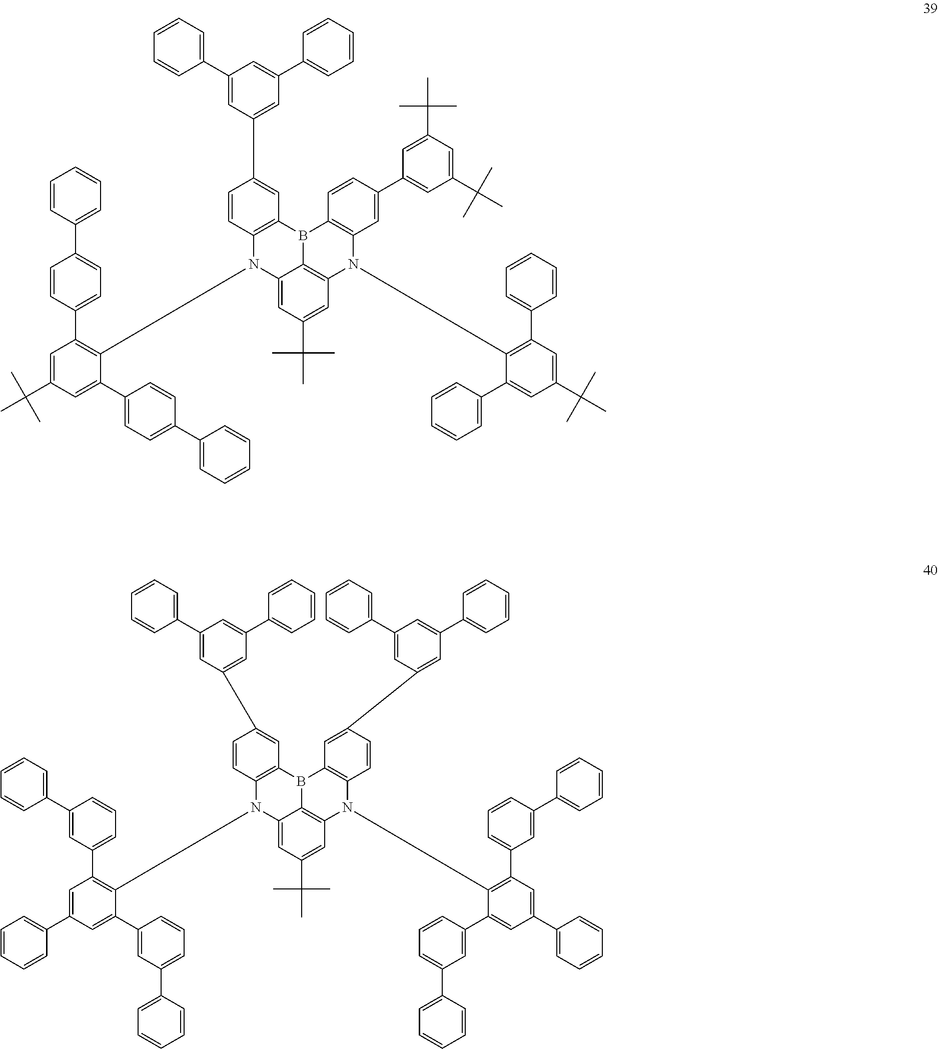 [SMILES: CC(C)(C)c1cc(-c2ccc3c(c2)N(c2c(-c4ccccc4)cc(C(C)(C)C)cc2-c2ccccc2)c2cc(C(C)(C)C)cc4c2B3c2cc(-c3cc(-c5ccccc5)cc(-c5ccccc5)c3)ccc2N4c2c(-c3ccc(-c4ccccc4)cc3)cc(C(C)(C)C)cc2-c2ccc(-c3ccccc3)cc2)cc(C(C)(C)C)c1 ; CC(C)(C)c1cc2c3c(c1)N(c1c(-c4cccc(-c5ccccc5)c4)cc(-c4ccccc4)cc1-c1cccc(-c4ccccc4)c1)c1ccc(-c4cc(-c5ccccc5)cc(-c5ccccc5)c4)cc1B3c1cc(-c3cc(-c4ccccc4)cc(-c4ccccc4)c3)ccc1N2c1c(-c2cccc(-c3ccccc3)c2)cc(-c2ccccc2)cc1-c1cccc(-c2ccccc2)c1] 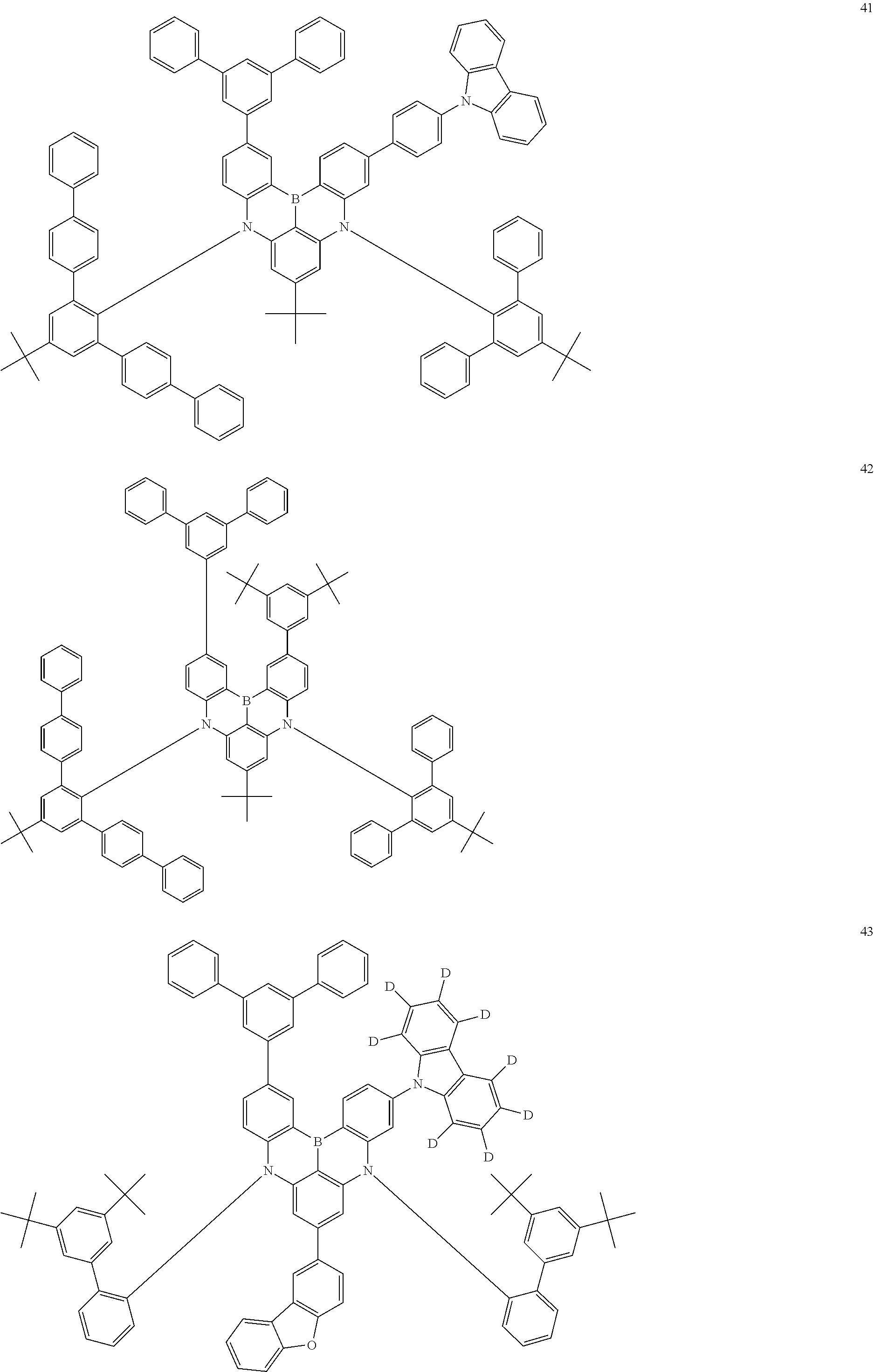 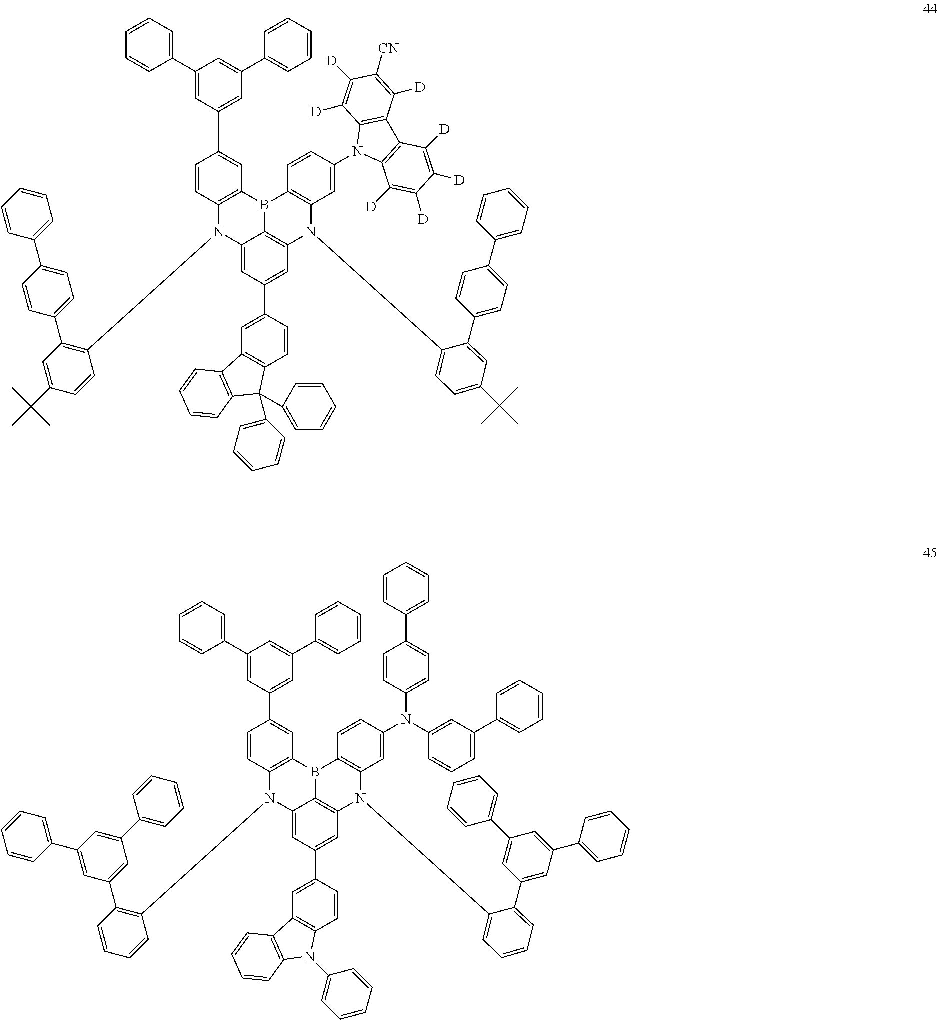 [SMILES: [2H]c1c([2H])c([2H])c2c(c1[2H])c1c([2H])c(C#N)c([2H])c([2H])c1n2-c1ccc2c(c1)N(c1ccc(C(C)(C)C)cc1-c1ccc(-c3ccccc3)cc1)c1cc(-c3ccc4c(c3)-c3ccccc3C4(c3ccccc3)c3ccccc3)cc3c1B2c1cc(-c2cc(-c4ccccc4)cc(-c4ccccc4)c2)ccc1N3c1ccc(C(C)(C)C)cc1-c1ccc(-c2ccccc2)cc1 ; c1ccc(-c2ccc(N(c3cccc(-c4ccccc4)c3)c3ccc4c(c3)N(c3ccccc3-c3cc(-c5ccccc5)cc(-c5ccccc5)c3)c3cc(-c5ccc6c(c5)c5ccccc5n6-c5ccccc5)cc5c3B4c3cc(-c4cc(-c6ccccc6)cc(-c6ccccc6)c4)ccc3N5c3ccccc3-c3cc(-c4ccccc4)cc(-c4ccccc4)c3)cc2)cc1] 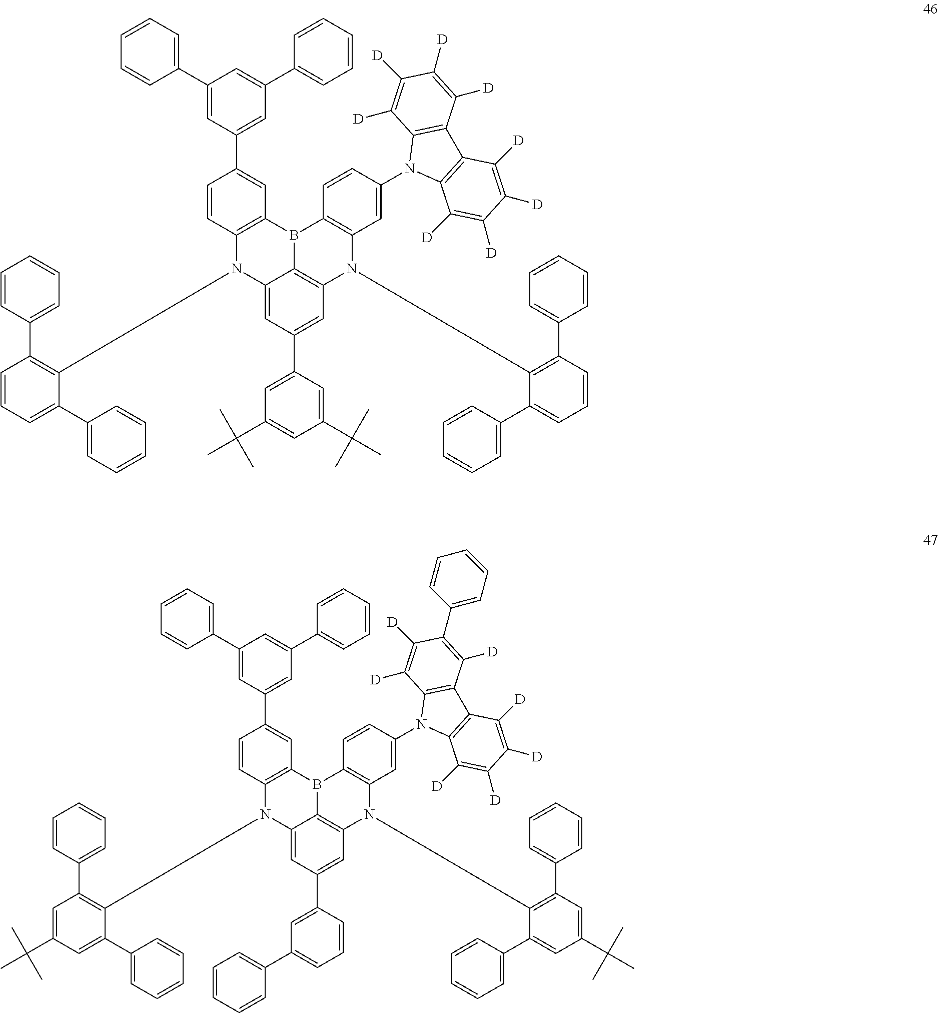 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3cc(C(C)(C)C)cc(C(C)(C)C)c3)cc3c1B2c1cc(-c2cc(-c4ccccc4)cc(-c4ccccc4)c2)ccc1N3c1c(-c2ccccc2)cccc1-c1ccccc1 ; [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccccc1)c1cc(-c3cccc(-c4ccccc4)c3)cc3c1B2c1cc(-c2cc(-c4ccccc4)cc(-c4ccccc4)c2)ccc1N3c1c(-c2ccccc2)cc(C(C)(C)C)cc1-c1ccccc1] 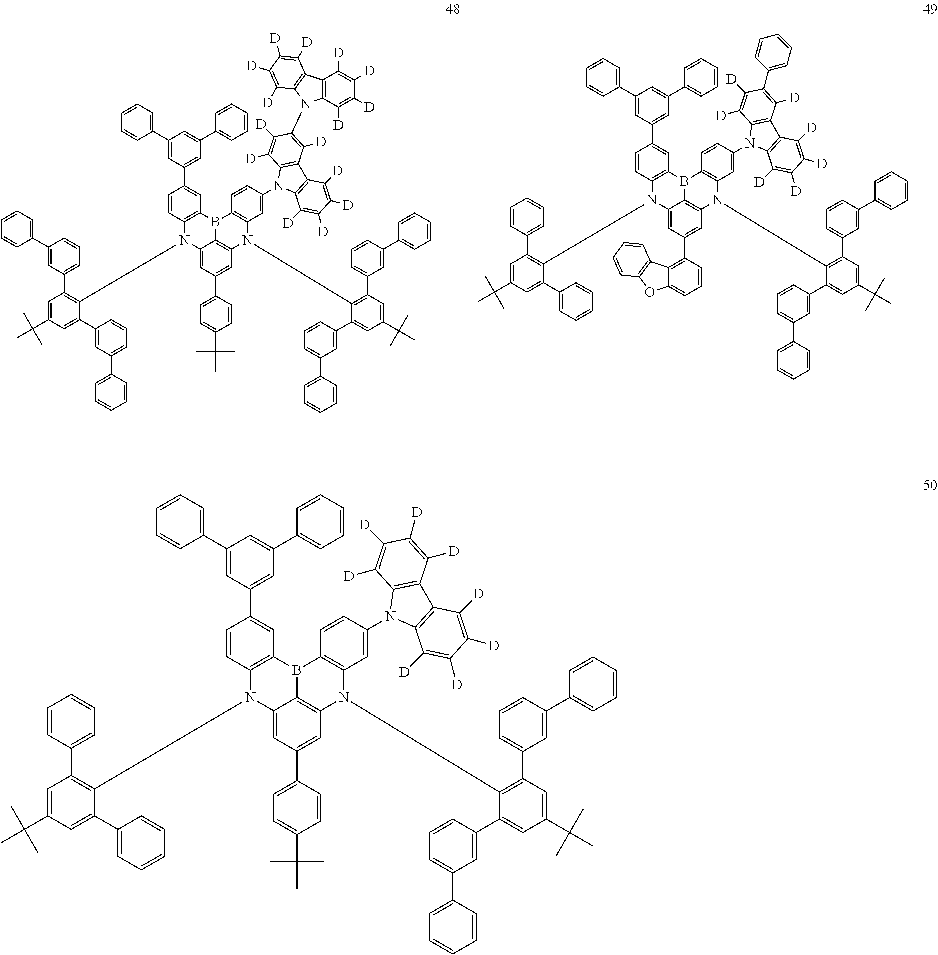 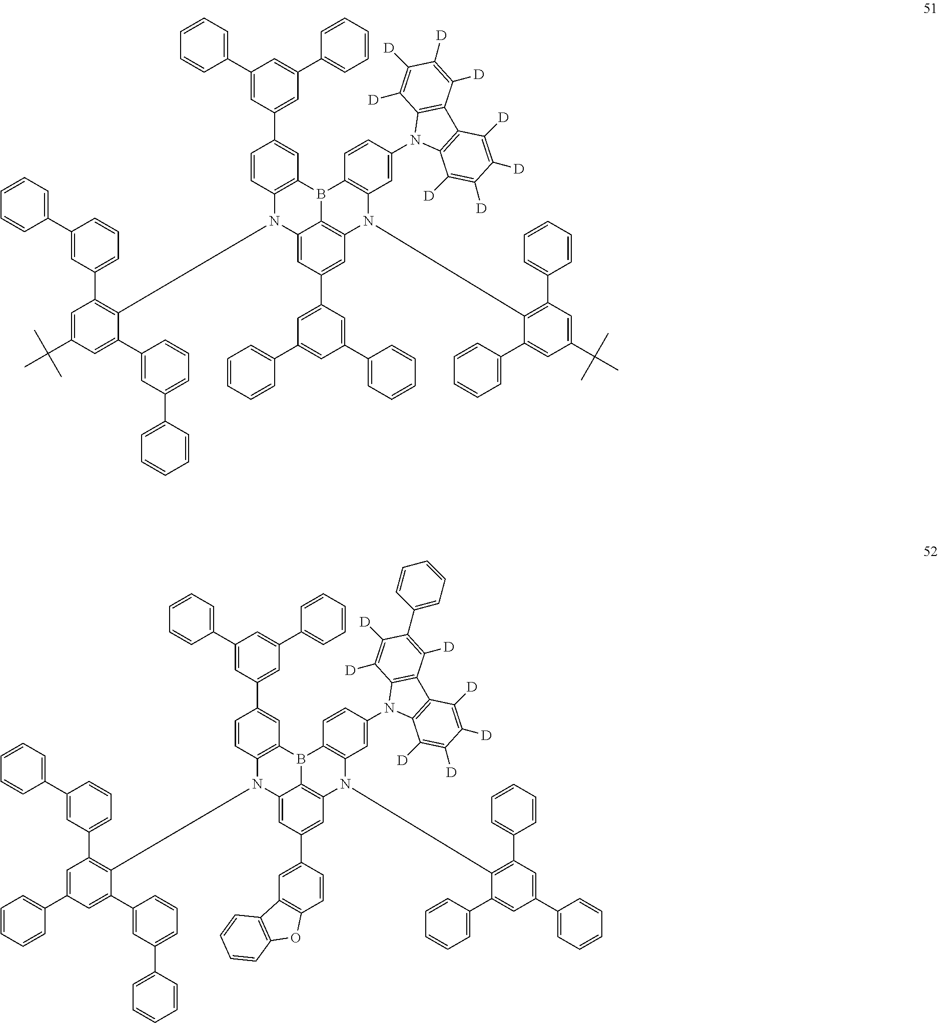 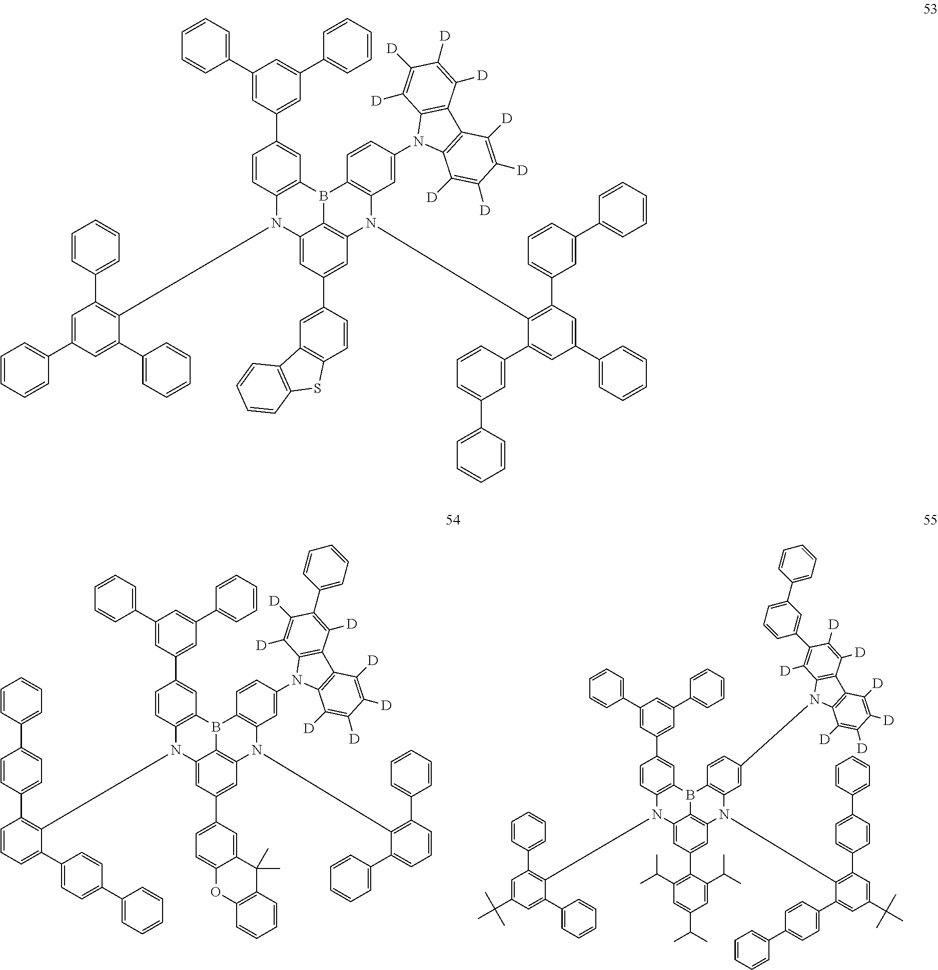 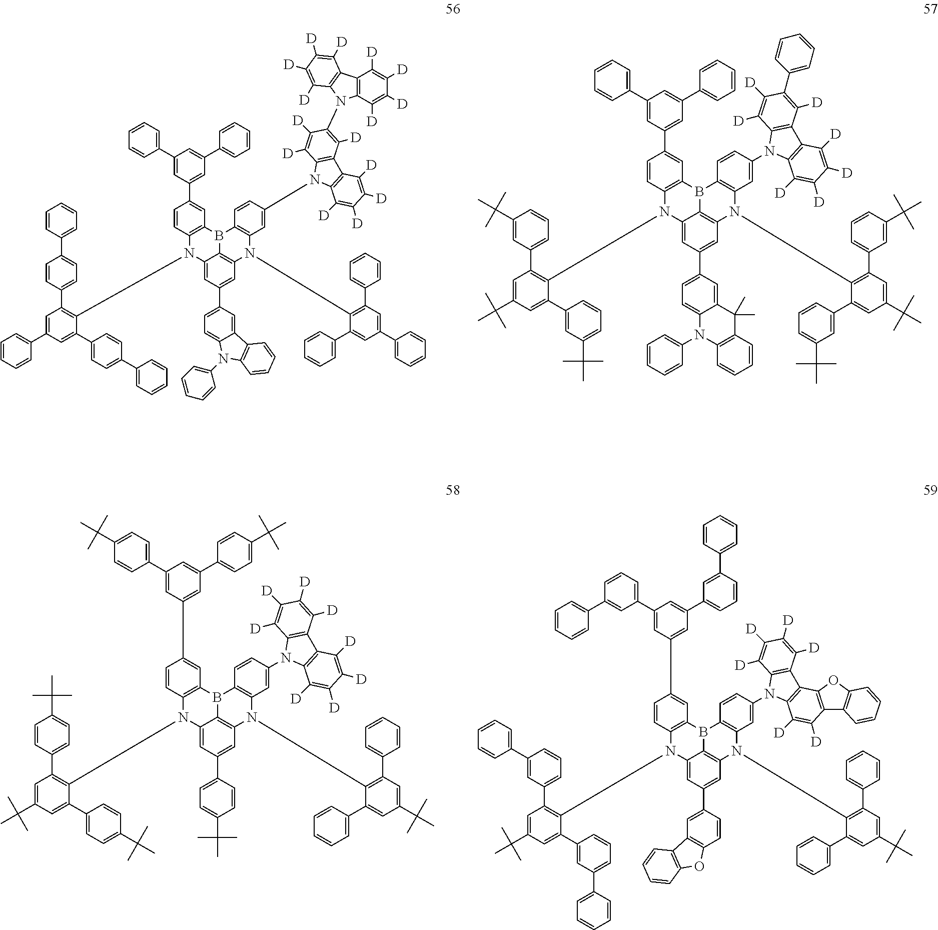 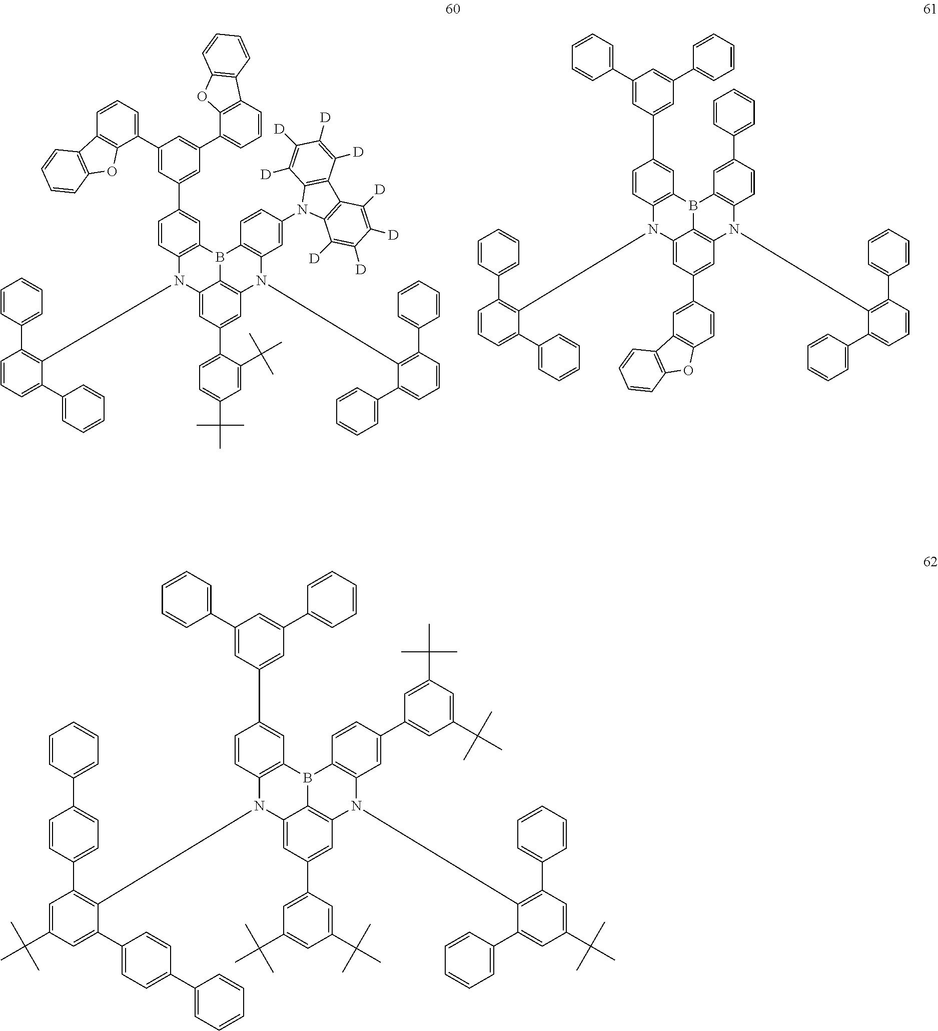 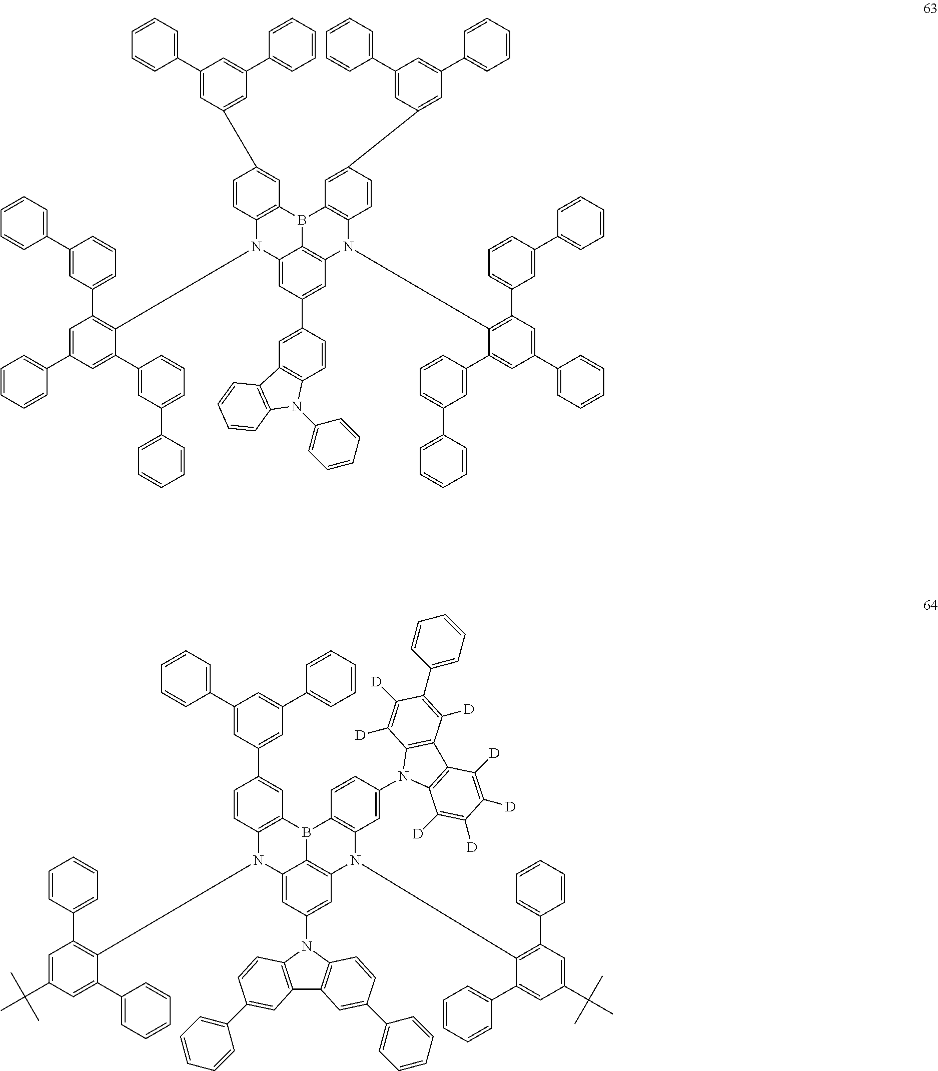 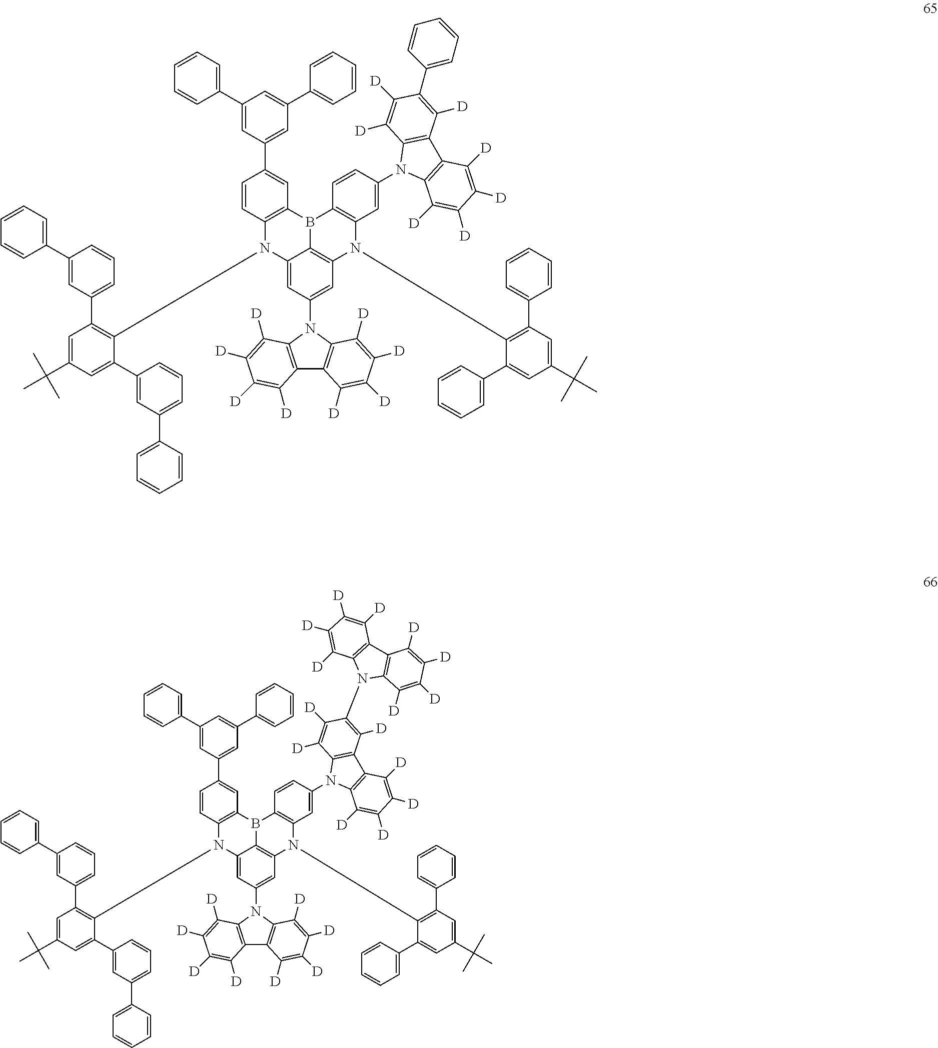 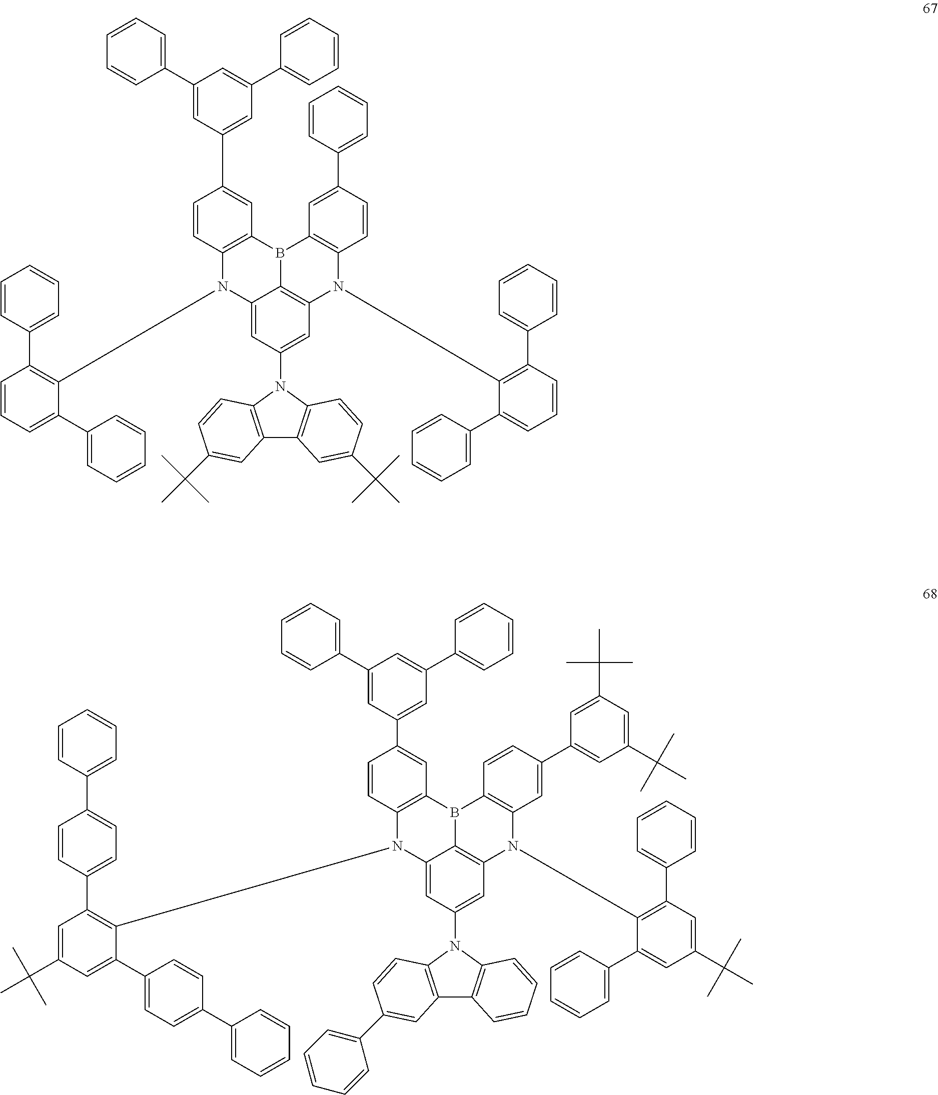 [SMILES: CC(C)(C)c1ccc2c(c1)c1cc(C(C)(C)C)ccc1n2-c1cc2c3c(c1)N(c1c(-c4ccccc4)cccc1-c1ccccc1)c1ccc(-c4cc(-c5ccccc5)cc(-c5ccccc5)c4)cc1B3c1cc(-c3ccccc3)ccc1N2c1c(-c2ccccc2)cccc1-c1ccccc1 ; CC(C)(C)c1cc(-c2ccc3c(c2)N(c2c(-c4ccccc4)cc(C(C)(C)C)cc2-c2ccccc2)c2cc(-n4c5ccccc5c5cc(-c6ccccc6)ccc54)cc4c2B3c2cc(-c3cc(-c5ccccc5)cc(-c5ccccc5)c3)ccc2N4c2c(-c3ccc(-c4ccccc4)cc3)cc(C(C)(C)C)cc2-c2ccc(-c3ccccc3)cc2)cc(C(C)(C)C)c1] 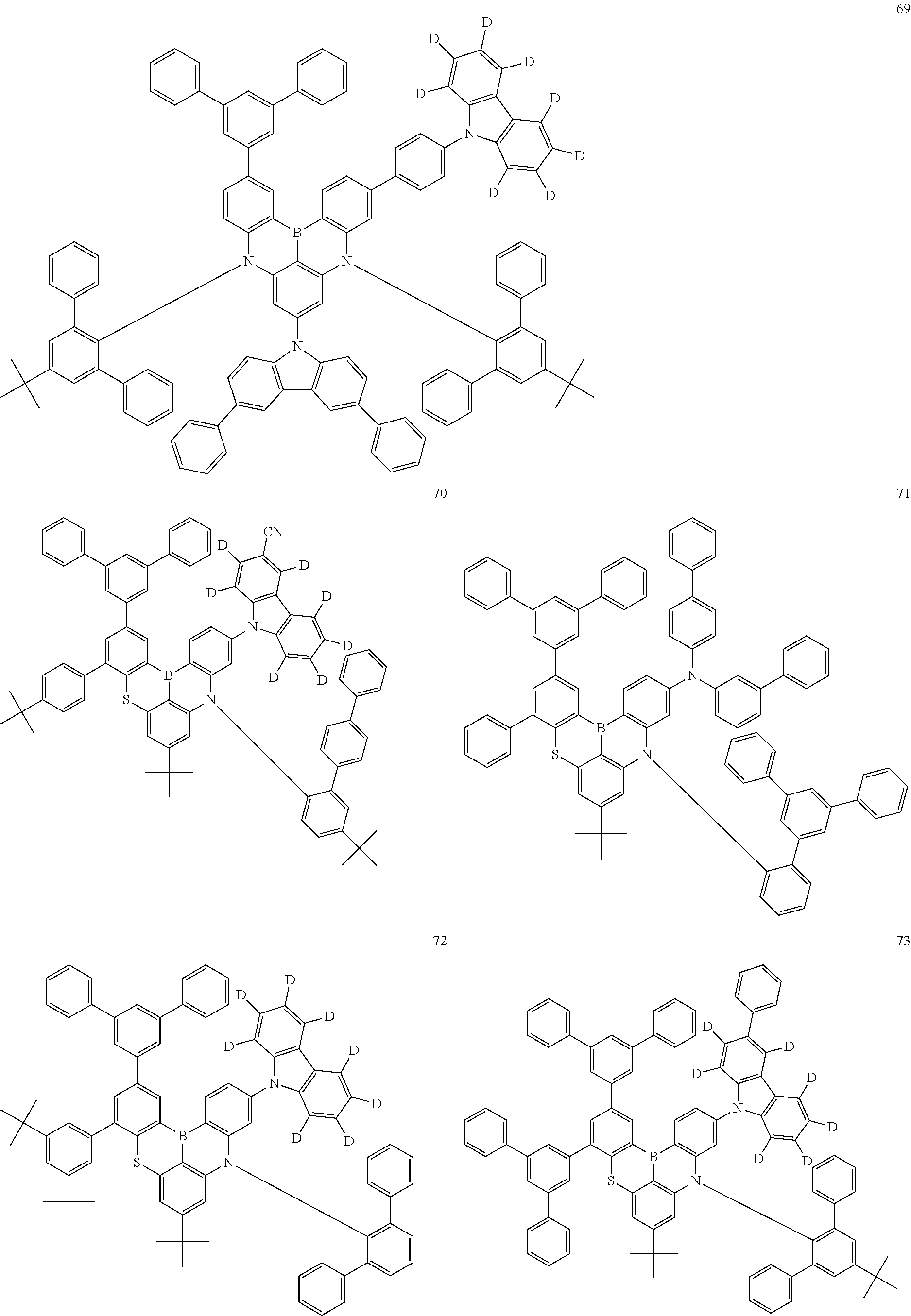 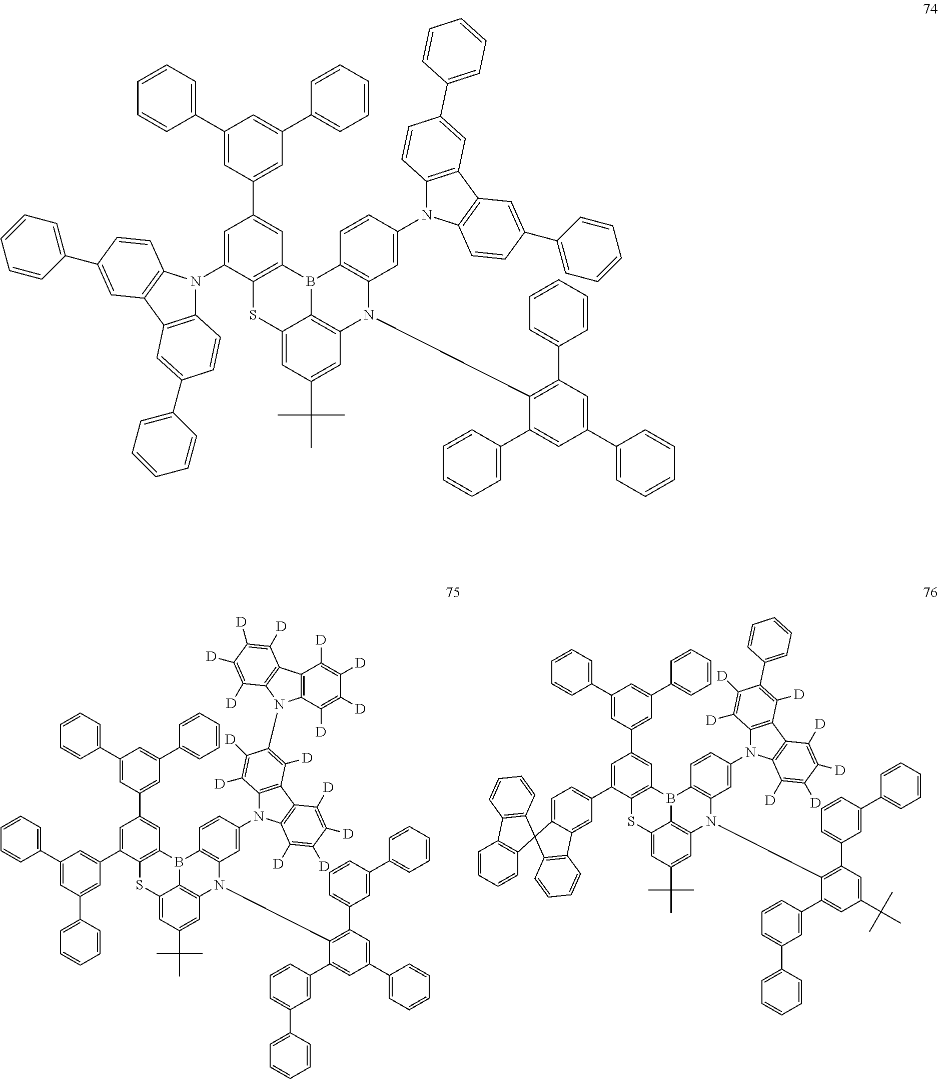 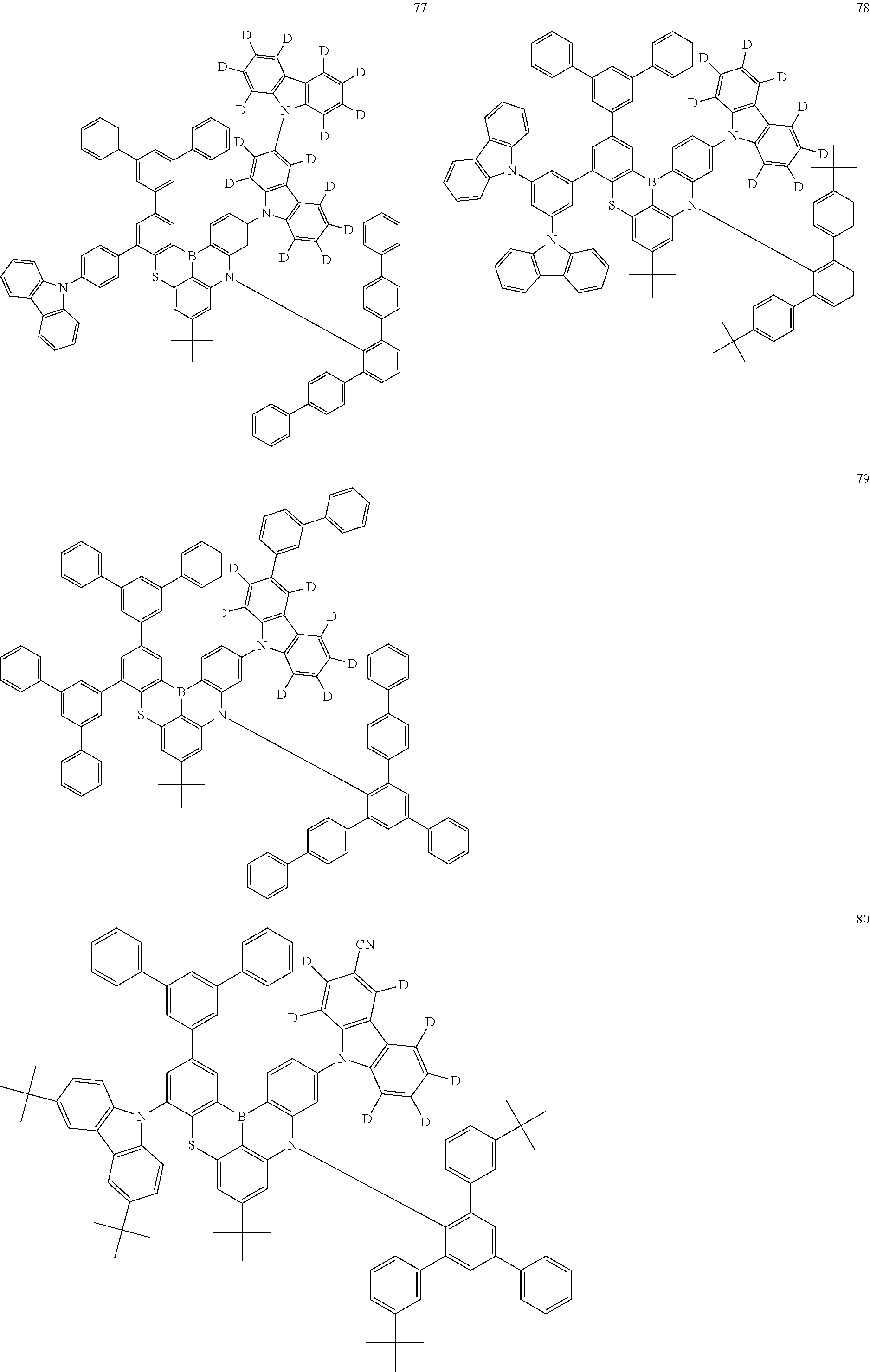 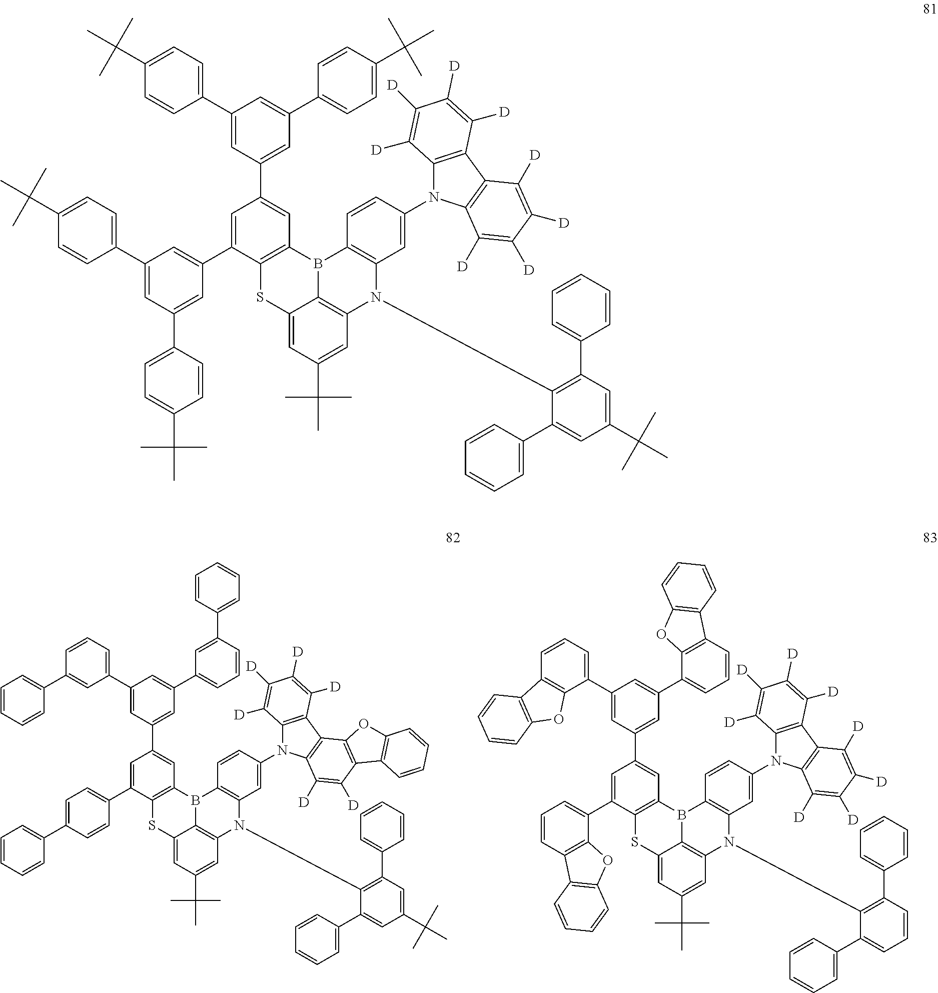 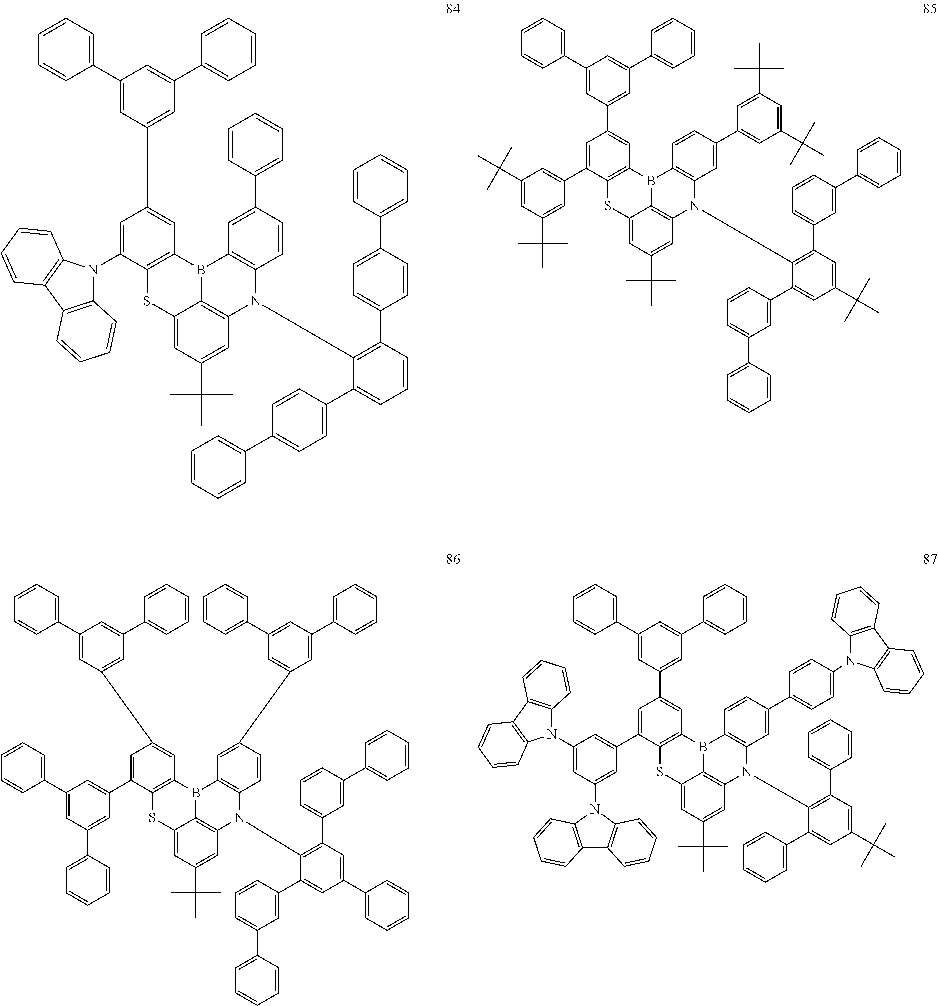 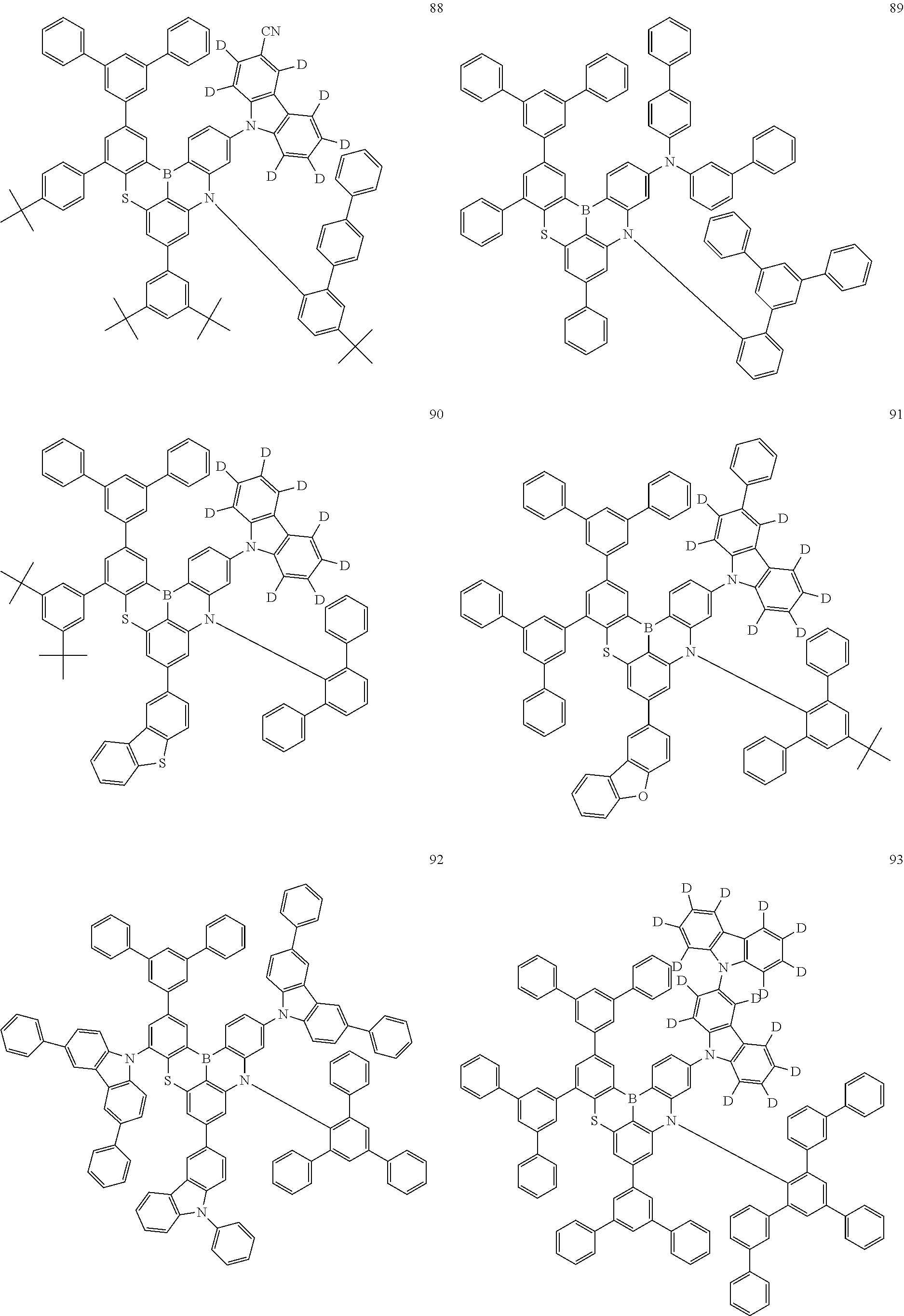 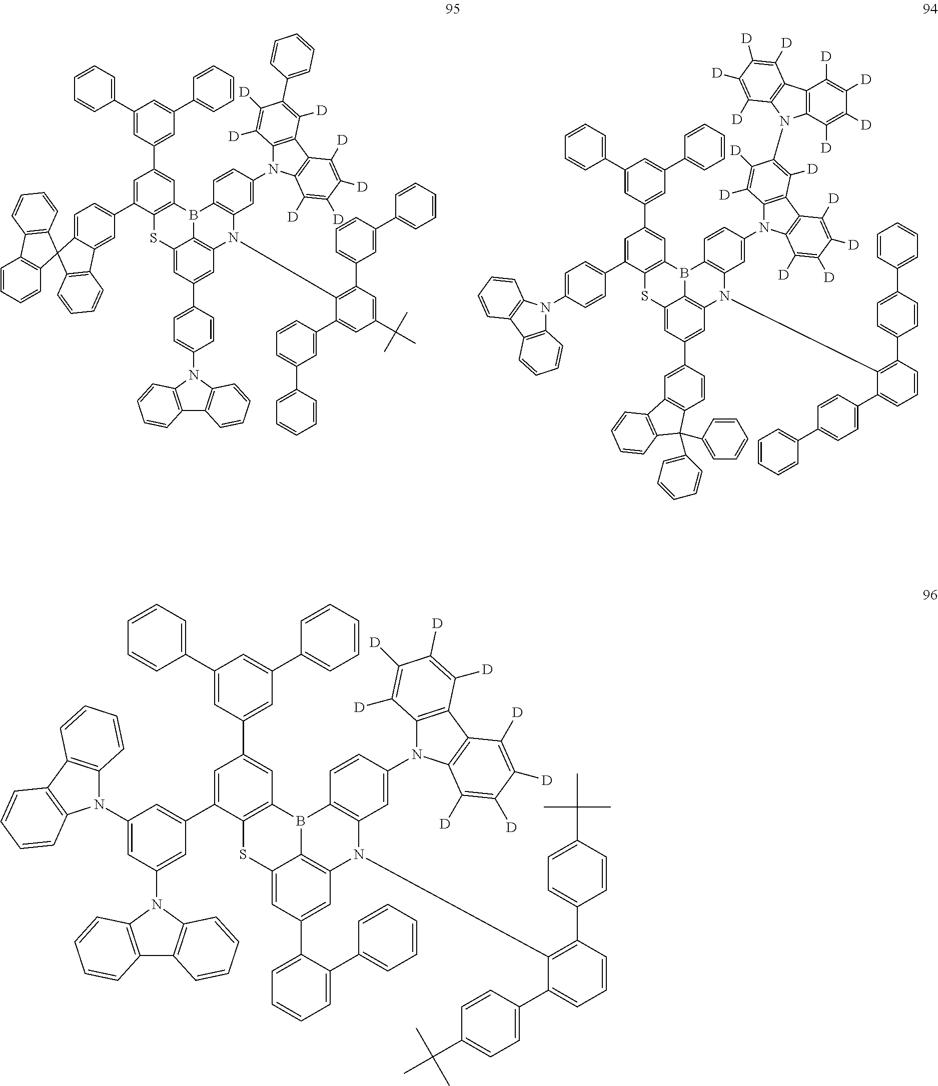 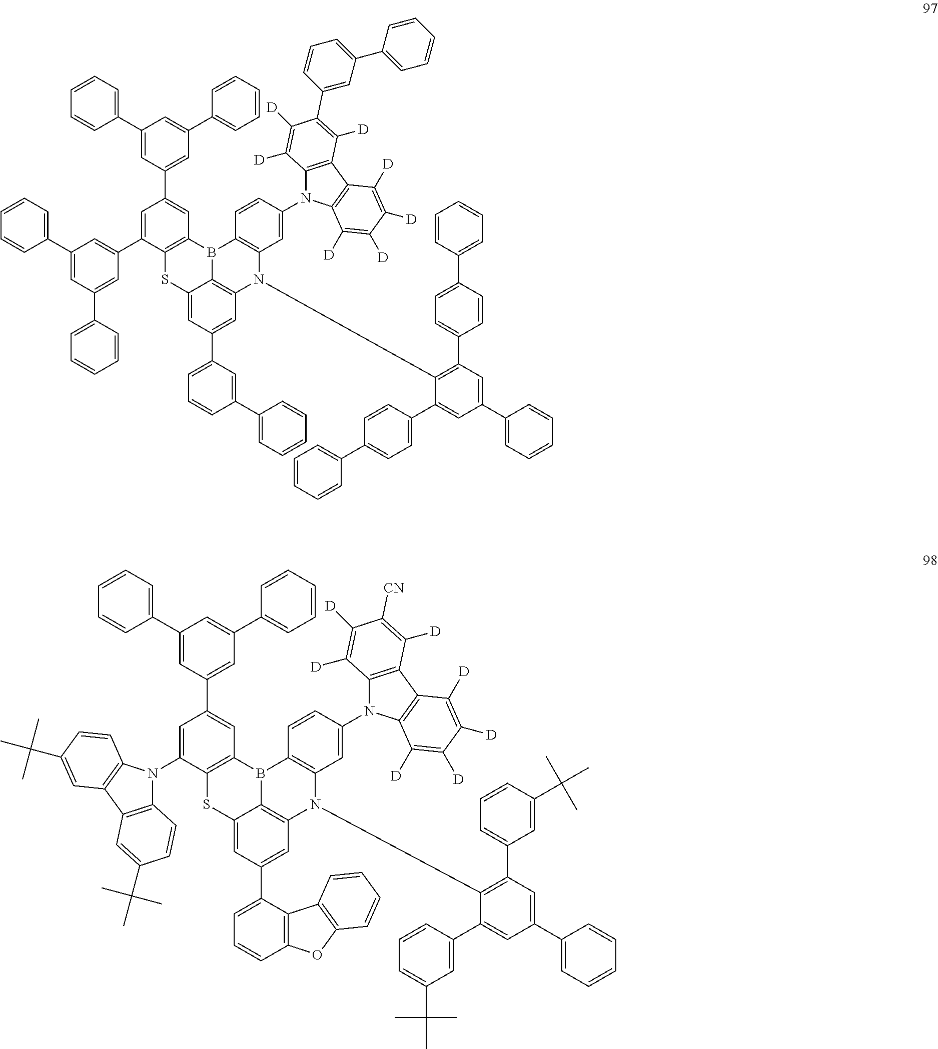 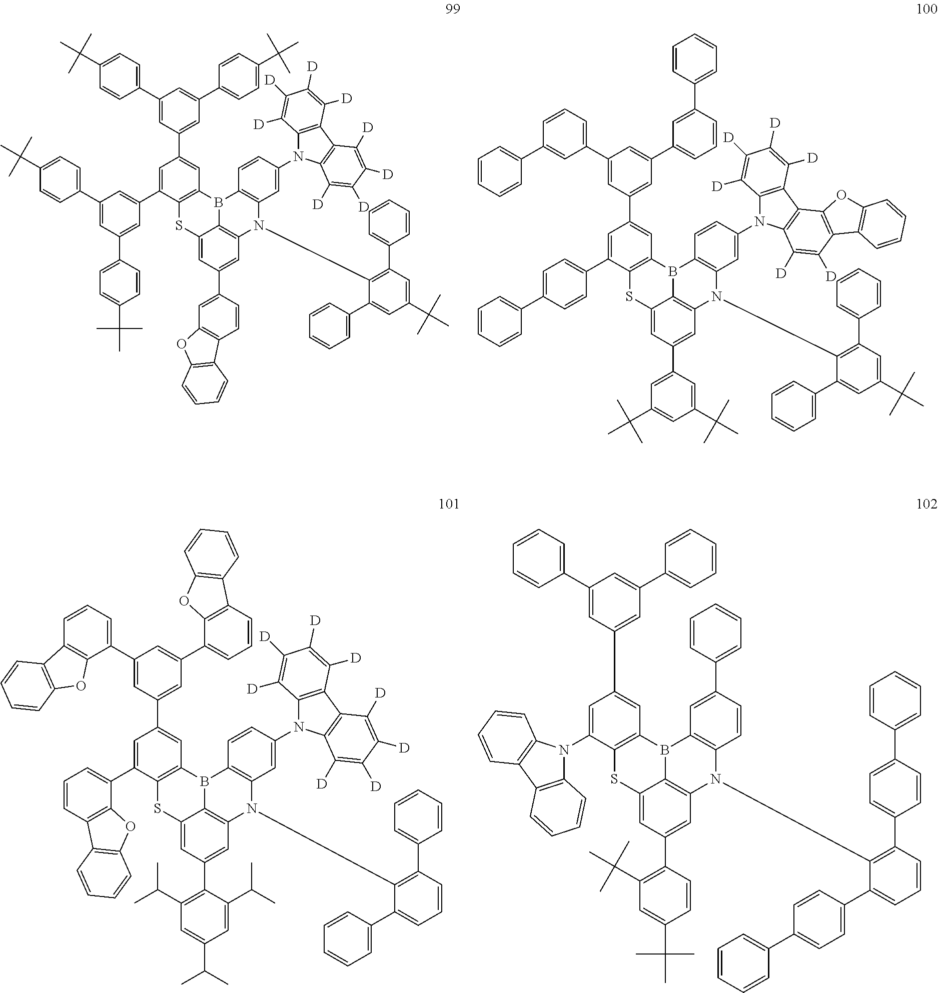 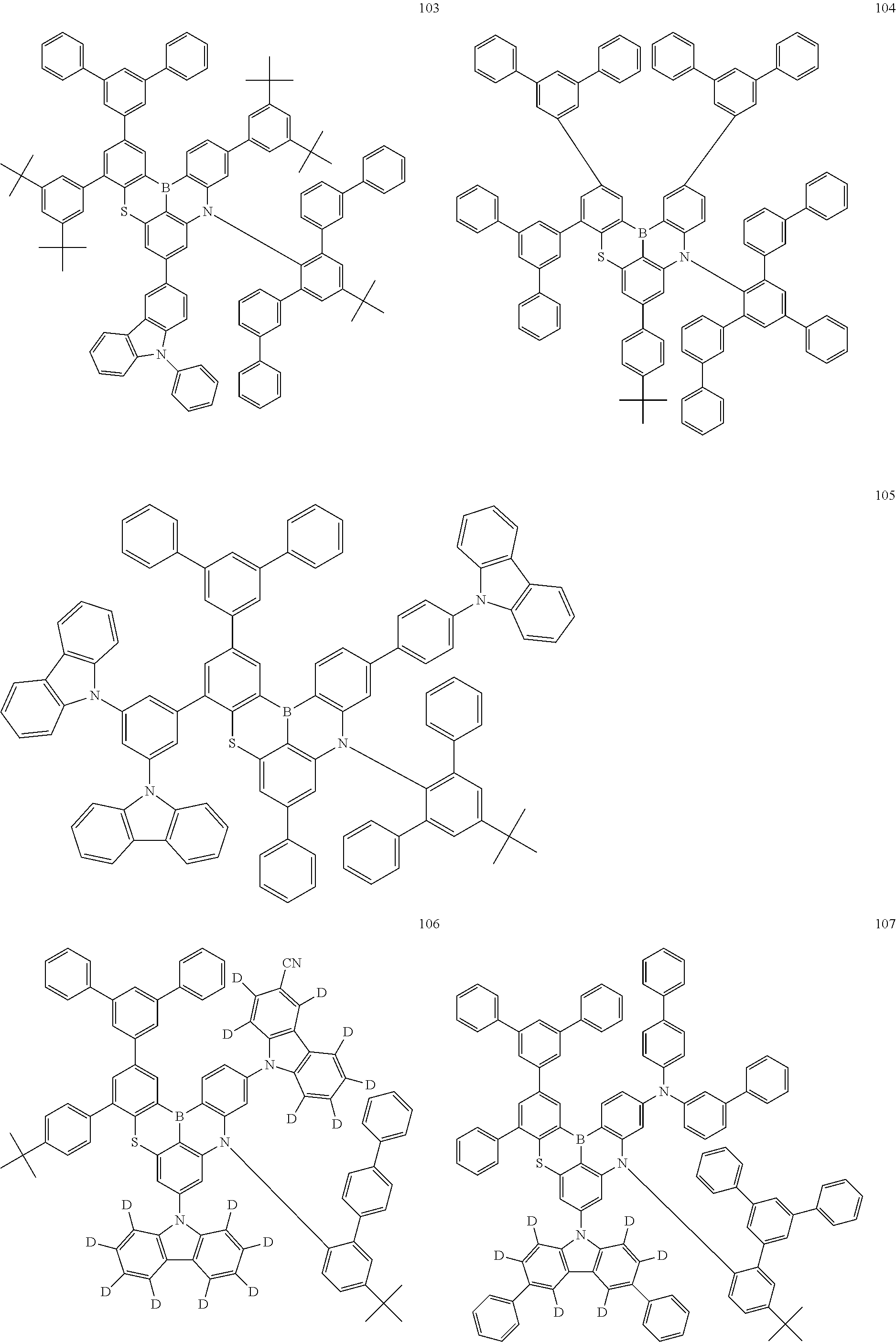 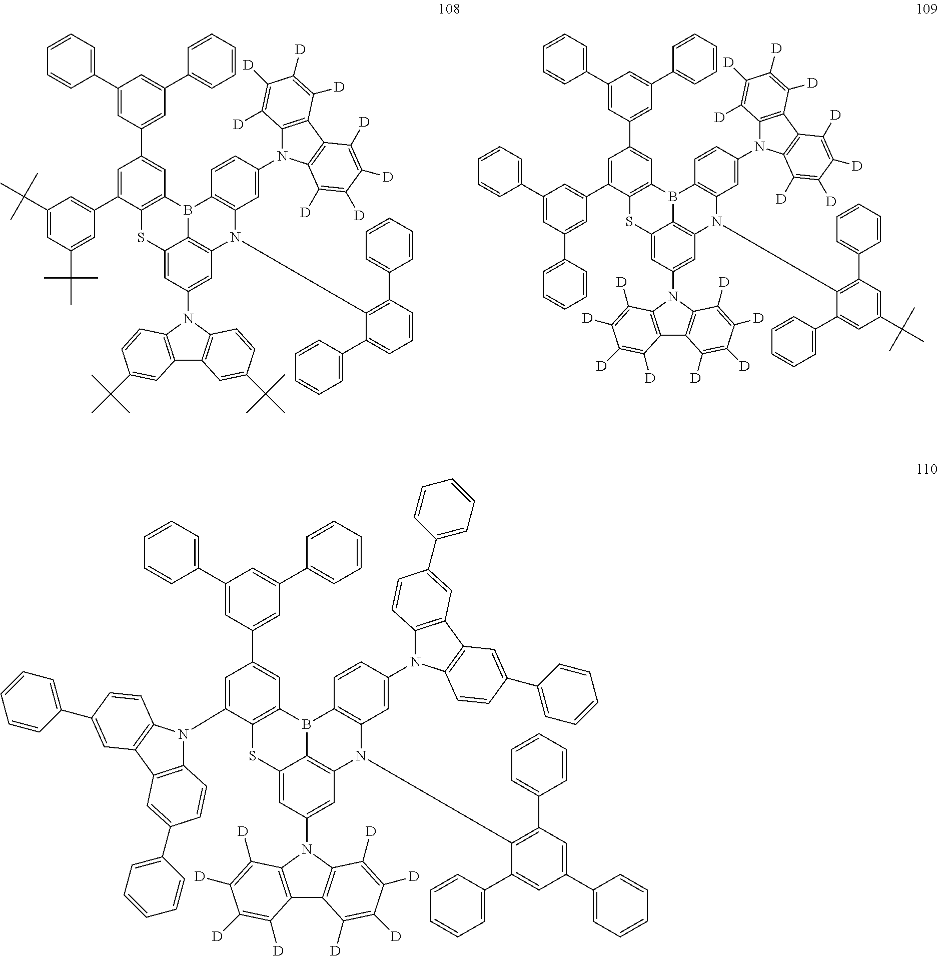 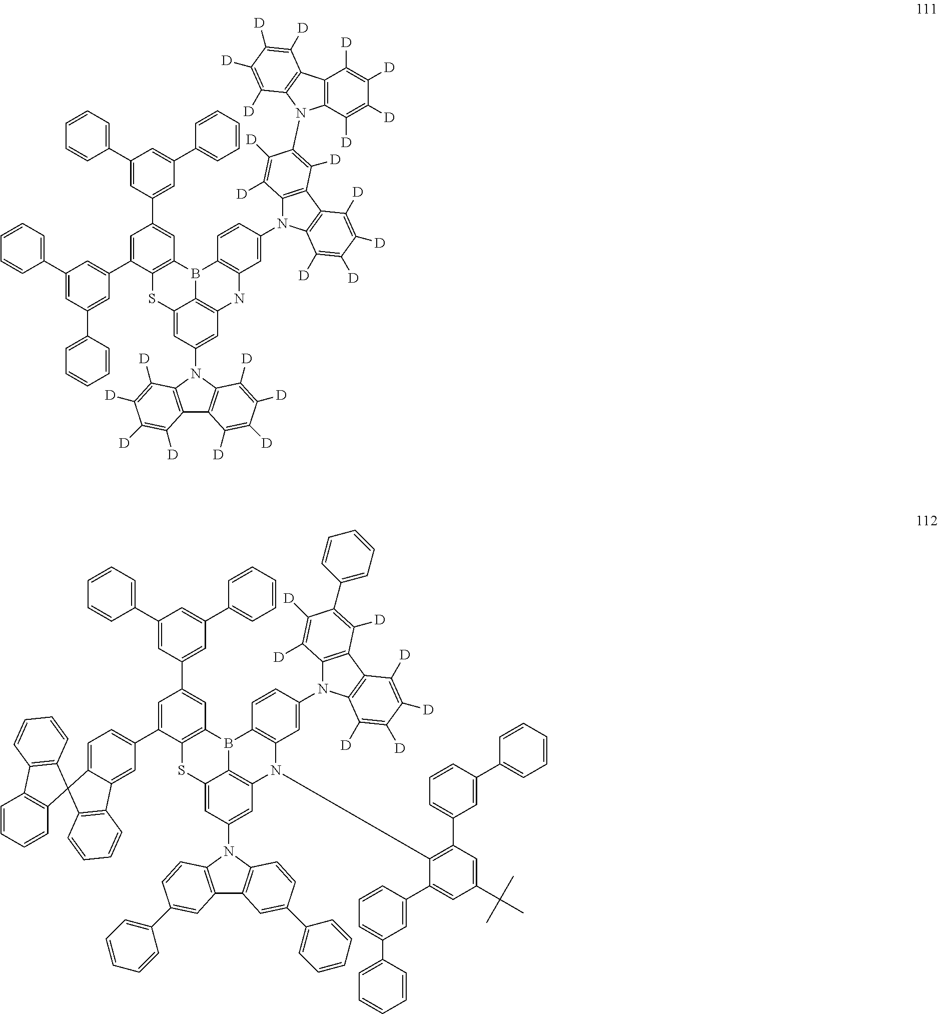 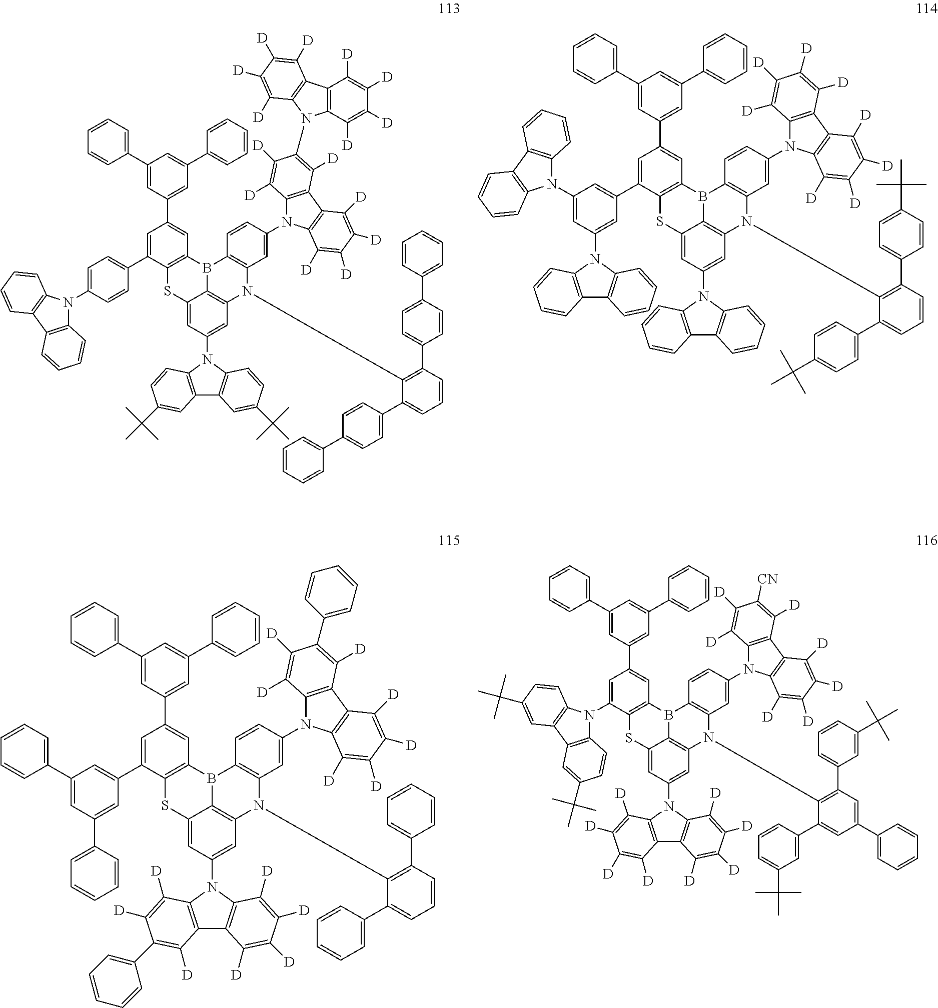 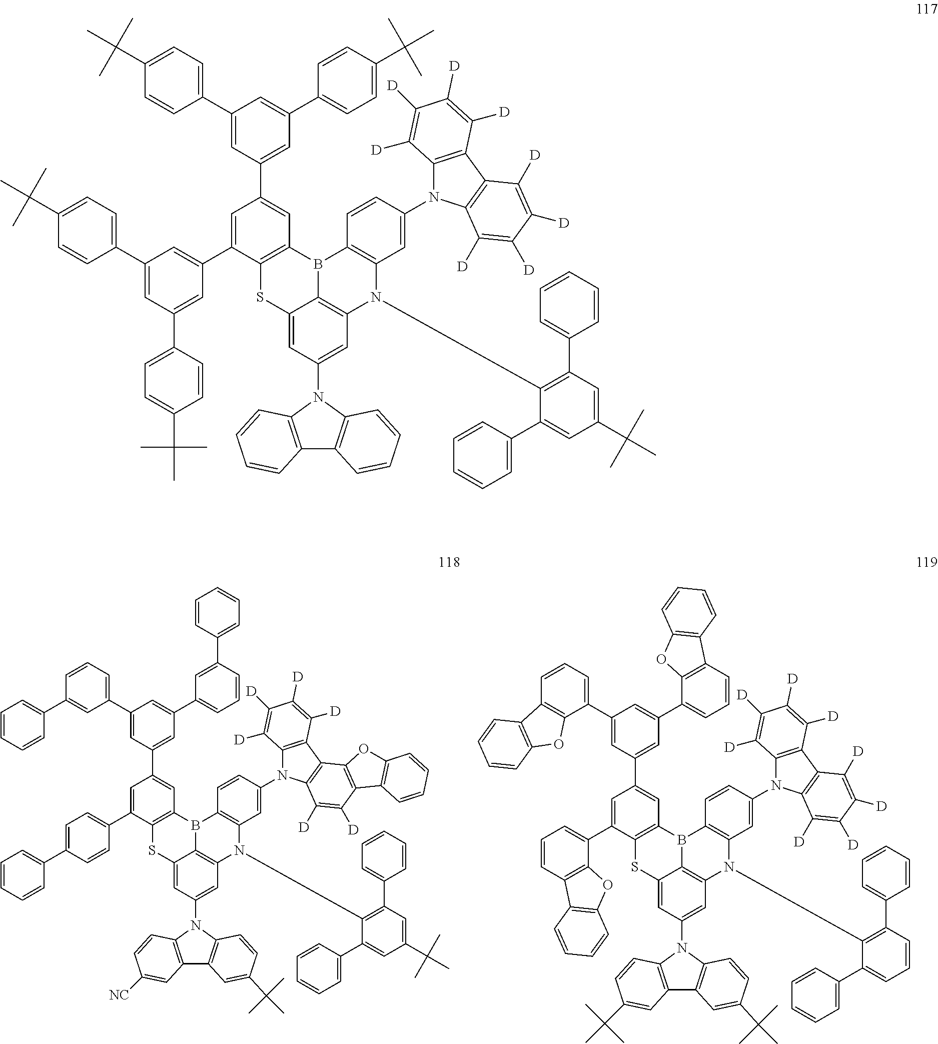 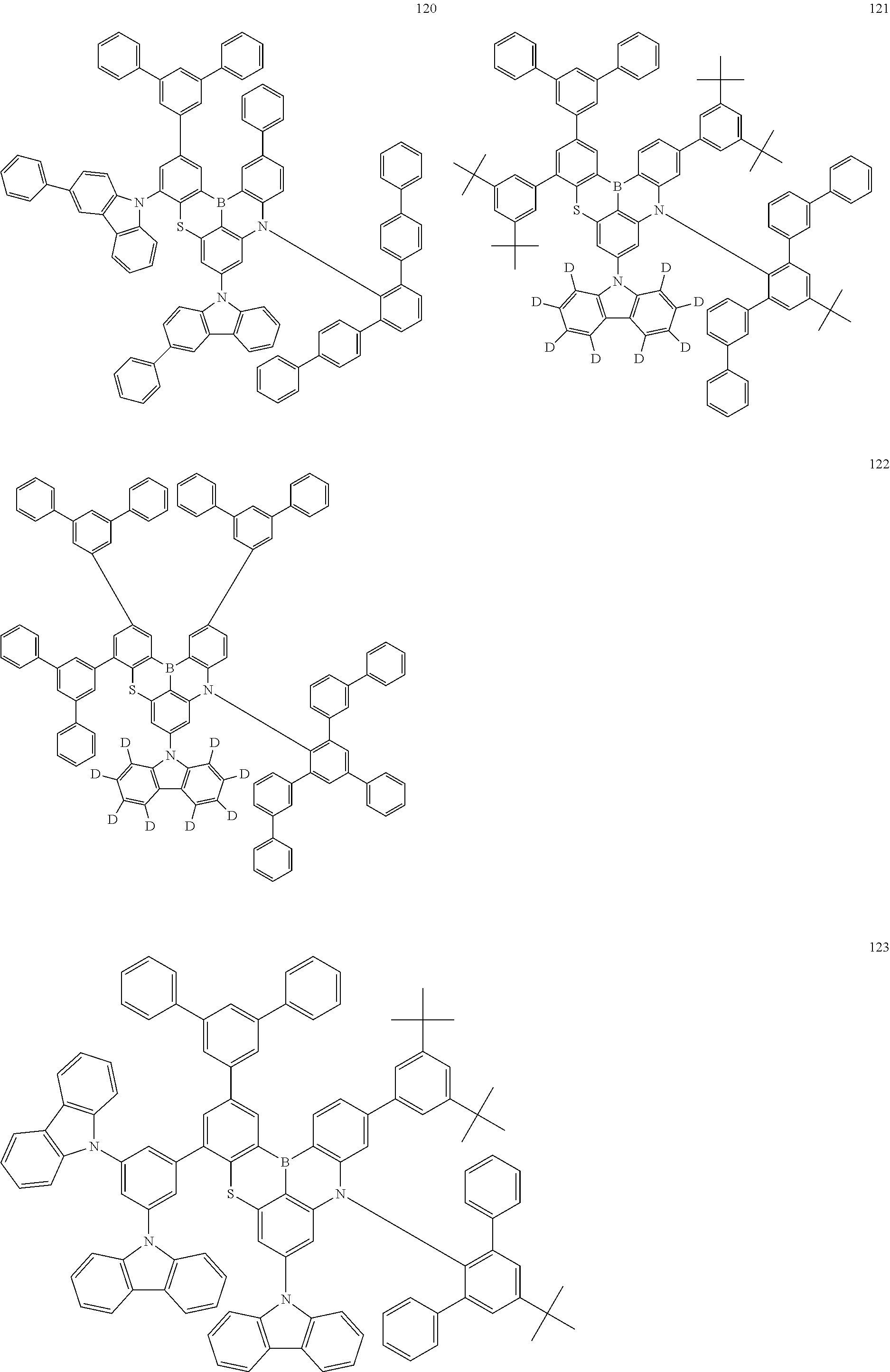
wherein in Compound Group 1,
D represents a deuterium atom.

20. A display device comprising:
a circuit layer disposed on a base layer; and
a display element layer disposed on the circuit layer and including a light-emitting element, wherein
the light-emitting element comprises:
a first electrode;
a second electrode disposed on the first electrode; and
an emission layer disposed between the first electrode and the second electrode, and
the emission layer comprises a fused polycyclic compound represented by Formula 1: 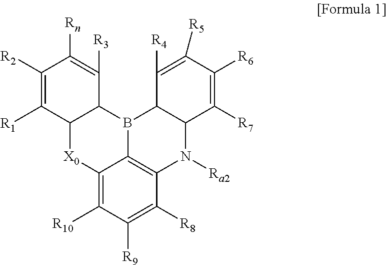
wherein in Formula 1,
Rₙ is a group represented by Formula 2,
X₀ is S or N(Rₐ₁),
Rₐ₁ and Rₐ₂ are each independently a group represented by Formula 3, and
R₁ to R₁₀ are each independently a hydrogen atom, a deuterium atom, a cyano group, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms; 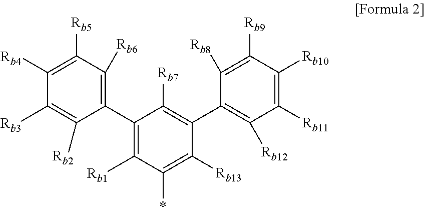
wherein in Formula 2,
R_{b1} to R_{b13} are each independently a hydrogen atom, a deuterium atom, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring; 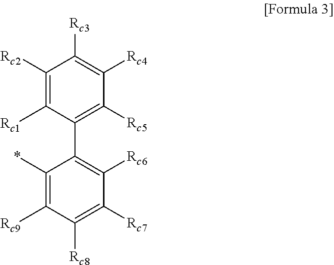
wherein in Formula 3,
R_{c1} to R_{c9} are each independently a hydrogen atom, a deuterium atom, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

21. The display device of claim 20, wherein
the light-emitting element comprises:
a first light-emitting element that emits red light;
a second light-emitting element that emits green light; and
a third light-emitting element that emits blue light; and
the third light-emitting element comprises the fused polycyclic compound.

22. The display device of claim 20, wherein the light-emitting element emits blue light.

23. The display device of claim 20, further comprising:
a light control layer disposed on the display element layer and including a quantum dot.
